(19) United States
(12) Patent Application Publication
(10) Pub. No.: US 2025/0311532 A1
(43) Pub. Date: Oct. 2, 2025

(54) ORGANIC LIGHT-EMITTING DEVICE

(71) Applicant: LG CHEM, LTD., Seoul (KR)

(72) Inventors: Sujeong GEUM, Daejeon (KR); Seonwoo KIM, Daejeon (KR); Jongsoo SONG, Daejeon (KR); Woochul LEE, Daejeon (KR); Jae Seung HA, Daejeon (KR); Sunghyun HWANG, Daejeon (KR)

(21) Appl. No.: 18/859,633

(22) PCT Filed: Oct. 12, 2023
(86) PCT No.: PCT/KR2023/015747

§ 371 Date: Oct. 24, 2024

(30) Foreign Application Priority Data
Oct. 12, 2022 (KR) 10-2022-0130866

(51) Int. Cl. H10K 50/12; H10K 85/40; H10K 85/60

(52) U.S. Cl. CPC H10K 50/12; H10K 85/40; H10K 85/626; H10K 85/631; H10K 85/654; H10K 85/6572; H10K 85/6574; H10K 85/6576; H10K 85/658

(57) ABSTRACT

An organic light emitting device including a compound of Chemical Formula 1 and a compound of Chemical Formula 2 or 3:

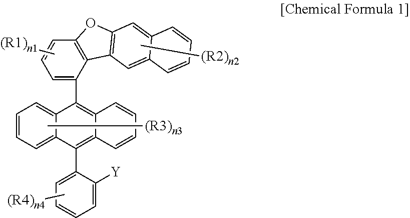

where Y is a substituted or unsubstituted aryl or heteroaryl group, or is bonded to an adjacent substituent to form a substituted or unsubstituted ring;

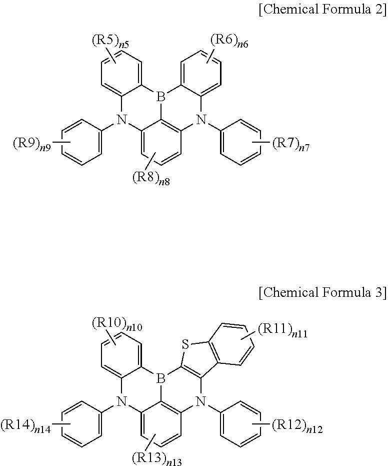

and Chemical Formulae 2 and 3 necessarily include the following Ring A or Ring B:

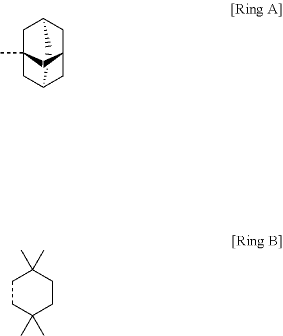

where in Rings A and B, the dotted line (---) is a site linked to or condensed to Chemical Formula 2 or 3; and the other substituents are as defined in the specification. The device exhibits excellent performance in terms of lower voltage, higher efficiency and/or longer service life compared to devices including only the compound of Chemical Formula 1, 2, or 3.

### CROSS-REFERENCE TO RELATED APPLICATION(S)

This application is a National Stage Application of International Application No. PCT/KR2023/015747 filed on Oct. 12, 2023, which claims priority to and the benefit of Korean Patent Application No. 10-2022-0130866 filed in the Korean Intellectual Property Office on Oct. 12, 2022, the entire contents of which are incorporated herein by reference.

### TECHNICAL FIELD

The present specification relates to an organic light emitting device.

### BACKGROUND ART

An organic light emission phenomenon generally refers to a phenomenon converting electrical energy to light energy using an organic material. An organic light emitting device using an organic light emission phenomenon normally has a structure including a positive electrode, a negative electrode, and an organic material layer therebetween. Here, the organic material layer has in many cases a multi-layered structure composed of different materials in order to improve the efficiency and stability of the organic light emitting device, and for example, may be composed of a hole injection layer, a hole transport layer, a light emitting layer, an electron transport layer, an electron injection layer, and the like. In such a structure of the organic light emitting device, if a voltage is applied between the two electrodes, holes are injected from the positive electrode into the organic material layer and electrons are injected from the negative electrode into the organic material layer, and when the injected holes and electrons meet each other, an exciton is formed, and light is emitted when the exciton falls down again to a ground state.

There is a continuous need for developing a new material for the aforementioned organic light emitting device.

### RELATED ART DOCUMENTS

### Patent Document

(Patent Document 1) Korean Patent Application Laid-Open No. 10-2007-0091540

### BRIEF DESCRIPTION

### Technical Problem

The present application has been made in an effort to provide an organic light emitting device.

### Technical Solution

An exemplary embodiment of the present specification provides an organic light emitting device including: an anode; a cathode; and a light emitting layer provided between the anode and the cathode, in which the light emitting layer includes a compound of the following Chemical Formula 1 and a compound of the following Chemical Formula 2 or the following Chemical Formula 3.

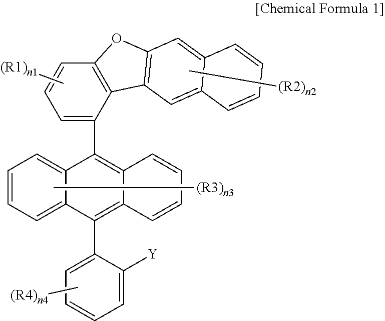

In Chemical Formula 1,
Y is a substituted or unsubstituted aryl group; or a substituted or unsubstituted heteroaryl group, or is bonded to an adjacent substituent to form a substituted or unsubstituted ring,
R1 and R2 are the same as or different from each other, and are each independently hydrogen; deuterium; a substituted or unsubstituted alkyl group; a substituted or unsubstituted silyl group; a substituted or unsubstituted aryl group; or a substituted or unsubstituted heteroaryl group,
R3 is hydrogen; or deuterium,
R4 is hydrogen; deuterium; a substituted or unsubstituted alkyl group; a substituted or unsubstituted silyl group; a substituted or unsubstituted aryl group; or a substituted or unsubstituted heteroaryl group, or is bonded to an adjacent substituent to form a substituted or unsubstituted ring,
n1 is an integer from 0 to 3,
n2 is an integer from 0 to 6,
n3 is an integer from 0 to 8,
n4 is an integer from 0 to 4,
when n1 to n4 are each 2 or higher, two or more of R1 to R4 are each the same as or different from each other,

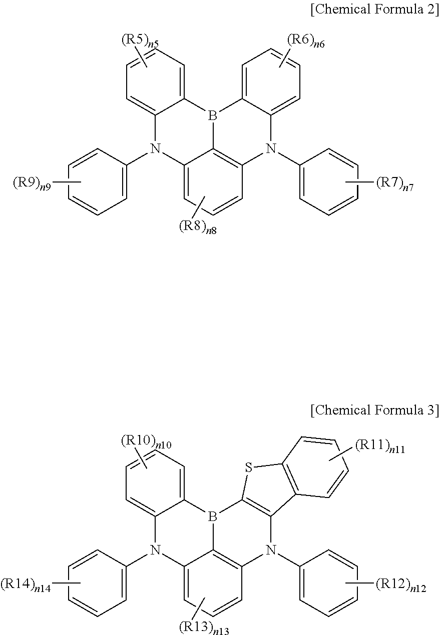

in Chemical Formulae 2 and 3,
R5 to R14 are the same as or different from each other, and are each independently hydrogen; deuterium; a halogen group; a cyano group; a substituted or unsubstituted alkyl group; a substituted or unsubstituted cycloalkyl group; a substituted or unsubstituted silyl group; a substituted or unsubstituted alkenyl group; a substituted or unsubstituted aryl group; a substituted or unsubstituted heterocyclic group; a substituted or unsubstituted alkoxy group; a substituted or unsubstituted aryloxy group; a substituted or unsubstituted alkylthio group; a substituted or unsubstituted arylthio group; or a substituted or unsubstituted amine group, or are bonded to an adjacent substituent to form a substituted or unsubstituted ring,
Chemical Formulae 2 and 3 necessarily include the following Ring A or Ring B,
n5, n6, n10 and n11 are each an integer from 0 to 4,
n8 and n13 are each an integer from 0 to 3,
n7, n9, n12 and n14 are each an integer from 0 to 5,
when n5 to n14 are each 2 or higher, two or more of R5 to R14 are each the same as or different from each other, and

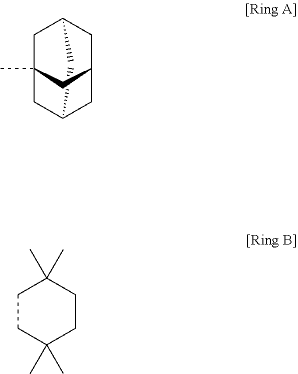

in Rings A and B, the dotted line (---) is a site linked to or condensed to Chemical Formula 2 or 3, and an additional substituent may be linked to or an additional ring may be condensed to Ring A or B.

### Advantageous Effects

The organic light emitting device described in the present specification has effects of low driving voltage, high efficiency and/or long service life because the light emitting layer includes a compound of Chemical Formula 1 and a compound of Chemical Formula 2 or the following Chemical Formula 3.

### BRIEF DESCRIPTION OF DRAWINGS

FIGS. 1, 2, and 8 illustrate an example of an organic light emitting device according to an exemplary embodiment of the present specification.

FIGS. 3 to 7 illustrate an example of an organic light emitting device including two or more stacks according to an exemplary embodiment of the present specification.

FIGS. 9 and 10 are light emission graphs illustrating the wavelength values (nm) of the maximum light emission peaks of the compounds measured in Experimental Example 1.

### DETAILED DESCRIPTION

Hereinafter, the present specification will be described in more detail.

When one part “includes” one constituent element in the present specification, unless otherwise specifically described, this does not mean that another constituent element is excluded, but means that another constituent element may be further included.

When one member is disposed “on” another member in the present specification, this includes not only a case where the one member is brought into contact with another member, but also a case where still another member is present between the two members.

In the present specification, “dotted line (---)” means a position bonded or condensed to a chemical formula or a compound.

In the present specification,

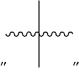

means a position bonded to a formula or a compound.

In the present specification, “*” means a position condensed to a chemical formula or a compound.

In the present specification, the deuterium substitution rate of a compound may be understood by a method of calculating the substitution rate based on the max. value of the distribution which molecular weights form at the end point of a reaction using thin-layer chromatography/mass spectrometry (TLC-MS) or a quantitative analysis method using NMR, and a method of adding DMF as an internal standard and calculating the D-substitution rate from the integrated amount of the total peak using the integration rate on 1H NMR.

In the present specification, “energy level” means a size of energy. Therefore, the energy level is interpreted to mean the absolute value of the corresponding energy value. For example, a low or deep energy level means that the absolute value increases in the negative direction from the vacuum level.

In the present specification, the highest occupied molecular orbital (HOMO) means a molecular orbital (highest occupied molecular orbital) in the highest energy region in regions in which electrons can participate in bonding, the lowest unoccupied molecular orbital (LUMO) means the molecular orbital (lowest unoccupied molecular orbital) in which electrons are present in the lowest energy region among the semi-bonded regions, and the HOMO energy level means the distance from the vacuum level to the HOMO. Furthermore, the LUMO energy level means the distance from the vacuum level to the LUMO.

In the present specification, a bandgap means a difference in energy level between HOMO and LUMO, that is, a HOMO-LUMO gap (Gap).

In the present specification, the HOMO energy level may be measured using a photoelectron spectrometer under the atmosphere (manufactured by RIKEN KEIKI Co., Ltd.: AC3), and the LUMO energy level may be calculated from wavelength values measured through photoluminescence (PL).

Examples of the substituents in the present specification will be described below, but are not limited thereto.

The term “substitution” means that a hydrogen atom bonded to a carbon atom of a compound is changed into another substituent, and a position to be substituted is not limited as long as the position is a position at which the hydrogen atom is substituted, that is, a position at which the substituent may be substituted, and when two or more are substituted, the two or more substituents may be the same as or different from each other.

In the present invention, the term “substituted or unsubstituted” means being substituted with one or two or more substituents selected from the group consisting of deuterium, a halogen group, a cyano group (—CN), a nitro group, a hydroxyl group, an alkyl group, a cycloalkyl group, an alkoxy group, a phosphine oxide group, an aryloxy group, an alkylthioxy group, an arylthioxy group, an alkylsulfoxy group, an arylsulfoxy group, an alkenyl group, a silyl group, a boron group, an amine group, an aryl group, or a heterocyclic group, being substituted with a substituent in which two or more substituents among the exemplified substituents are linked together, or having no substituent. For example, “the substituent in which two or more substituents are linked together” may be a biphenyl group. That is, the biphenyl group may also be an aryl group, and may be interpreted as a substituent in which two phenyl groups are linked together.

In the present specification, the term “substituted or unsubstituted” means being substituted with one or two or more substituents selected from the group consisting of deuterium, a halogen group, a cyano group, a silyl group, an alkoxy group, an aryloxy group, an alkyl group, an aryl group, and a heterocyclic group, being substituted with a substituent in which two or more substituents among the exemplified substituents are linked together, or having no substituent.

In the present specification, the term “substituted or unsubstituted” means being substituted with one or two or more substituents selected from the group consisting of deuterium, an alkyl group, an aryl group, and a heterocyclic group, being substituted with a substituent in which two or more substituents among the exemplified substituents are linked together, or having no substituent.

Examples of the substituents will be described below, but are not limited thereto.

In the present specification, examples of a halogen group include fluorine (—F), chlorine (—Cl), bromine —Br) or iodine (—I).

In the present specification, an alkyl group includes a straight chain or a branched chain, and the number of carbon atoms thereof is not particularly limited, but is 1 to 60, 1 to 30, or 1 to 20. Specific examples of the alkyl group include a methyl group, an ethyl group, a propyl group, a butyl group, a pentyl group, a hexyl group, a heptyl group, an octyl group, a nonyl group, and the like, the alkyl group may be straight-chained or branched, and according to an exemplary embodiment, the propyl group includes an n-propyl group and an isopropyl group and the butyl group includes an n-butyl group, an isobutyl group and a tert-butyl group.

In the present specification, the number of the carbon atoms of the cycloalkyl group is not limited, but is 3 to 60, 3 to 30, 3 to 20, or 3 to 10. The cycloalkyl group includes not only a single ring group, but also a double ring group such as a bridgehead, a fused ring, and a spiro ring. Specific examples thereof include a cyclopropyl group, a cyclobutyl group, a cyclopentyl group, a cyclohexyl group, a cycloheptyl group, a cyclooctyl group, an adamantyl group, and the like, but are not limited thereto.

In the present specification, cycloalkene is a ring group in which a double bond is present in a hydrocarbon ring, but is a non-aromatic ring group, and the number of carbon atoms thereof is not particularly limited, but is 3 to 60, 3 to 30, 3 to 20, or 3 to 10. The cycloalkene includes not only a single ring group, but also a double ring group such as a bridgehead, a fused ring, and a spiro ring. Examples of the cycloalkene include cyclopropene, cyclobutene, cyclopentene, cyclohexene, and the like, but are not limited thereto.

In the present specification, the alkoxy group is one in which an alkyl group is linked to an oxygen atom, the alkylthio group is one in which an alkyl group is linked to a sulfur atom, and the above-described description on the alkyl group may be applied to the alkyl group of the alkoxy group and the alkylthio group.

In the present specification, the aryl group may be a monocyclic aryl group or a polycyclic aryl group, and the number of carbon atoms thereof is not particularly limited, but is 6 to 60, 6 to 30, or 6 to 20. Examples of the monocyclic aryl group include a phenyl group, a biphenyl group, a terphenyl group, a quaterphenyl group, and the like, but are not limited thereto. Examples of the polycyclic aryl group include a naphthyl group, an anthracenyl group, a phenanthrenyl group, a pyrenyl group, a perylenyl group, a triphenyl group, a chrysenyl group, a fluorenyl group, a fluoranthenyl group, a triphenylenyl group, and the like, but are not limited thereto.

In the present specification, No. 9 carbon atom (C) of a fluorenyl group may be substituted with an alkyl group, an aryl group, or the like, and two substituents may be bonded to each other to form a spiro structure such as cyclopentane or fluorene.

In the present specification, the substituted aryl group may also include a form in which an aliphatic ring is condensed to the aryl group. For example, a tetrahydronaphthalene group having the following structure is included in the substituted aryl group. In the following structure, one of the carbons of a benzene ring may be linked to another position.

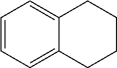

In the present specification, the aryloxy group is one in which an aryl group is linked to an oxygen atom, the arylthio group is one in which an aryl group is linked to a sulfur atom, and the above-described description on the aryl group may be applied to the aryl group of the aryloxy group and the arylthio group. An aryl group of an aryloxy group is the same as the above-described examples of the aryl group. Specifically, examples of the aryloxy group include a phenoxy group, a p-tolyloxy group, an m-tolyloxy group, a 3,5-dimethyl-phenoxy group, a 2,4,6-trimethylphenoxy group, a p-tert-butylphenoxy group, a 3-biphenyloxy group, a 4-biphenyloxy group, a 1-naphthyloxy group, a 2-naphthyloxy group, a 4-methyl-1-naphthyloxy group, a 5-methyl-2-naphthyloxy group, a 1-anthryloxy group, a 2-anthryloxy group, a 9-anthryloxy group, a 1-phenanthryloxy group, a 3-phenanthryloxy group, a 9-phenanthryloxy group, and the like, and examples of the arylthioxy group include a phenylthioxy group, a 2-methylphenylthioxy group, a 4-tert-butylphenylthioxy group, and the like, but the examples are not limited thereto.

In the present specification, a silyl group may be presented by a chemical formula of —SiYₐY_{b}Y_{c}, and Yₐ, Y_{b}, and Y_{c} may be each hydrogen; a substituted or unsubstituted alkyl group; a substituted or unsubstituted cycloalkyl group; or a substituted or unsubstituted aryl group. Specific examples of the silyl group include a trimethylsilyl group, a triethylsilyl group, a tert-butyldimethylsilyl group, a vinyldimethylsilyl group, a propyldimethylsilyl group, a dimethylphenylsilyl group, a triphenylsilyl group, a diphenylsilyl group, a phenylsilyl group, and the like, but are not limited thereto.

In the present specification, a boron group may be presented by a chemical formula of —BY_{d}Yₑ, and Y_{d} and Yₑ may be each hydrogen; a substituted or unsubstituted alkyl group; a substituted or unsubstituted cycloalkyl group; or a substituted or unsubstituted aryl group. Specific examples of the boron group include a dimethylboron group, a diethylboron group, a tert-butylmethylboron group, a vinylmethylboron group, a propylmethylboron group, a methylphenylboron group, a diphenylboron group, a phenylboron group, and the like, but are not limited thereto.

In the present specification, an amine group may be represented by —NRaRb, and Ra and Rb may be each hydrogen; a substituted or unsubstituted alkyl group; a substituted or unsubstituted aryl group; or a substituted or unsubstituted heteroaryl group, but are not limited thereto. The amine group may be selected from the group consisting of an alkylamine group, an alkylarylamine group, an arylamine group, a heteroarylamine group, an alkylheteroarylamine group, and an arylheteroarylamine group, depending on the type of substituent (Ra, Rb) to be bonded.

In the present specification, an alkylamine group means an amine group substituted with an alkyl group, and the number of carbon atoms thereof is not particularly limited, but may be 1 to 40, or 1 to 20. Specific examples of the alkylamine group include a methylamine group, a dimethylamine group, an ethylamine group, a diethylamine group, and the like, but are not limited thereto.

In the present specification, examples of an arylamine group include a substituted or unsubstituted monoarylamine group, a substituted or unsubstituted diarylamine group, or a substituted or unsubstituted arylheteroarylamine group. The aryl group in the arylamine group may be a monocyclic or polycyclic aryl group. Specific examples of the arylamine group include a phenylamine group, a naphthylamine group, a biphenylamine group, an anthracenylamine group, a diphenylamine group, a phenylnaphthylamine group, a bis(tert-butylphenyl)amine group, and the like, but are not limited thereto.

In the present specification, examples of a heteroarylamine group include a substituted or unsubstituted monoheteroarylamine group, a substituted or unsubstituted diheteroarylamine group, or a substituted or unsubstituted arylheteroarylamine group.

In the present specification, the arylheteroarylamine group means an amine group substituted with an aryl group and a heteroaryl group, and a description on the above-described aryl group and a heteroaryl group to be described below may be applied.

In the present specification, a heterocyclic group is a ring group including one or more of N, O, S, and Si as a heteroatom, and the number of carbon atoms thereof is not particularly limited, but is 2 to 60, or 2 to 30. Examples of the heterocyclic group include a pyridyl group; a quinoline group; a thiophene group; a dibenzothiophene group; a furan group; a dibenzofuran group; a naphthobenzofuran group; a carbazole group; a benzocarbazole group; a naphthobenzothiophene group; a hexahydrocarbazole group; dihydroacridine group; a dihydrodibenzoazasiline group; a phenoxazine group; a phenothiazine group; a spiro(dibenzosilole-dibenzoazasiline) group; a spiro(acridine-fluorene) group, and the like, but are not limited thereto.

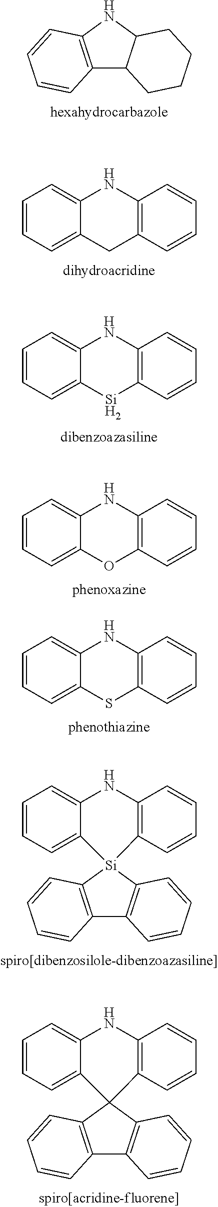

In the present specification, the above-described description on the heterocyclic group may be applied to a heteroaryl group except for an aromatic heteroaryl group.

In the present specification, an “adjacent” group may mean a substituent substituting an atom directly linked to an atom substituted by the corresponding substituent, a substituent sterically closely positioned to the corresponding substituent, or another substituent substituting an atom substituted by the corresponding substituent.

In the present specification, “the ring formed by bonding adjacent substituents” means a hydrocarbon ring; or a hetero ring.

In the present specification, “a five-membered or six-membered ring formed by bonding adjacent substituents” means that a ring including a substituent participating in the ring formation is five-membered or six-membered. It is possible to include an additional ring condensed to the ring including the substituent participating in the ring formation.

In the present specification, a hydrocarbon ring may be an aromatic ring, an aliphatic ring, or a condensed ring of an aromatic ring and an aliphatic ring, the above-described description on the aryl group may be applied to the aromatic hydrocarbon ring except that the aromatic hydrocarbon ring is not monovalent, and the above-described description on the cycloalkyl group may be applied to the aliphatic hydrocarbon ring except that the aliphatic hydrocarbon ring is not monovalent. Examples of the condensed ring of the aromatic ring and the aliphatic ring include a 1,2,3,4-tetrahydronaphthalene group, a 2,3-dihydro-1H-indene group, and the like, but are not limited thereto.

In the present specification, the description on the heterocyclic group may be applied to a hetero ring except that the hetero ring is not monovalent.

In the present specification, an aromatic hydrocarbon ring means a planar ring in which pi electrons are completely conjugated, and the above-described description on the aryl group may be applied to an aromatic hydrocarbon ring except for a divalent aromatic hydrocarbon ring.

In the present specification, an aliphatic hydrocarbon ring means all hydrocarbon rings except for aromatic hydrocarbon rings, and may include a cycloalkyl ring. The above-described description on the cycloalkyl group may be applied to the cycloalkyl ring except for a divalent cycloalkyl ring. A substituted aliphatic hydrocarbon ring also includes an aliphatic hydrocarbon ring in which aromatic rings are condensed.

In the present specification, the above-described description on the aryl group may be applied to an arylene group except for a divalent arylene group.

In the present specification, the above-described description on the cycloalkyl group may be applied to a cycloalkylene group except for a divalent cycloalkylene group.

Hereinafter, preferred exemplary embodiments of the present invention will be described in detail. However, the exemplary embodiments of the present invention may be modified into various other forms, and the scope of the present invention is not limited to the exemplary embodiments which will be described below.

The organic light emitting device of the present invention has effects of low driving voltage, high efficiency and/or long service life by including both the compound of Chemical Formula 1 and the compound of Chemical Formula 2 or Chemical Formula 3 in a light emitting layer.

Specifically, by using the compound of Chemical Formula 1 with a small Stoke shift together with the compounds of Chemical Formulae 2 and 3 including an aliphatic hydrocarbon ring, the effect of extending the distance between the compounds may be further strengthened without degrading other properties, and the average distance between a host and a dopant may be effectively increased to reduce the Dexter transition between molecules. Therefore, a device using the compound of Chemical Formula 1 according to the present invention and the compound of Chemical Formula 2 or 3 according to the present invention together may have remarkably strengthened characteristics of low voltage, high efficiency and/or long service life of the device due to a synergistic effect in the organic light emitting device.

Hereinafter, Chemical Formula 1 will be described in detail.

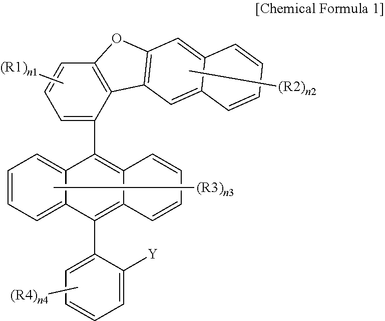

In Chemical Formula 1,
Y is a substituted or unsubstituted aryl group; or a substituted or unsubstituted heteroaryl group, or is bonded to an adjacent substituent to form a substituted or unsubstituted ring,
R1 and R2 are the same as or different from each other, and are each independently hydrogen; deuterium; a substituted or unsubstituted alkyl group; a substituted or unsubstituted silyl group; a substituted or unsubstituted aryl group; or a substituted or unsubstituted heteroaryl group,
R3 is hydrogen; or deuterium,
R4 is hydrogen; deuterium; a substituted or unsubstituted alkyl group; a substituted or unsubstituted silyl group; a substituted or unsubstituted aryl group; or a substituted or unsubstituted heteroaryl group, or is bonded to an adjacent substituent to form a substituted or unsubstituted ring,
n1 is an integer from 0 to 3,
n2 is an integer from 0 to 6,
n3 is an integer from 0 to 8,
n4 is an integer from 0 to 4, and
when n1 to n4 are each 2 or higher, two or more of R1 to R4 are each the same as or different from each other.

In an exemplary embodiment of the present specification, Y is a substituted or unsubstituted aryl group; or a substituted or unsubstituted heteroaryl group, or is bonded to an adjacent substituent to form a substituted or unsubstituted ring.

In an exemplary embodiment of the present specification, Y is a substituted or unsubstituted aryl group having 6 to 60 carbon atoms; or a substituted or unsubstituted heteroaryl group having 2 to 60 carbon atoms, or is bonded to an adjacent substituent to form a substituted or unsubstituted ring.

In an exemplary embodiment of the present specification, Y is a substituted or unsubstituted aryl group having 6 to 30 carbon atoms; or a substituted or unsubstituted heteroaryl group having 2 to 30 carbon atoms, or is bonded to an adjacent substituent to form a substituted or unsubstituted ring.

In an exemplary embodiment of the present specification, Y is a substituted or unsubstituted aryl group having 6 to 20 carbon atoms; or a substituted or unsubstituted heteroaryl group having 2 to 20 carbon atoms, or is bonded to an adjacent substituent to form a substituted or unsubstituted ring.

In an exemplary embodiment of the present specification, Y is a substituted or unsubstituted aryl group having 6 to 60 carbon atoms; or a substituted or unsubstituted heteroaryl group having 2 to 60 carbon atoms and containing O, S or N, or is bonded to an adjacent substituent to form a substituted or unsubstituted ring.

In an exemplary embodiment of the present specification, Y is a substituted or unsubstituted aryl group having 6 to 30 carbon atoms; or a substituted or unsubstituted heteroaryl group having 2 to 30 carbon atoms and containing O, S or N, or is bonded to an adjacent substituent to form a substituted or unsubstituted ring.

In an exemplary embodiment of the present specification, Y is a substituted or unsubstituted aryl group having 6 to 20 carbon atoms; or a substituted or unsubstituted heteroaryl group having 2 to 20 carbon atoms and containing O, S or N, or is bonded to an adjacent substituent to form a substituted or unsubstituted ring.

In an exemplary embodiment of the present specification, Y is an aryl group having 6 to 60 carbon atoms, which is unsubstituted or substituted with deuterium; or a heteroaryl group having 2 to 60 carbon atoms, which is unsubstituted or substituted with deuterium, or is bonded to an adjacent substituent to form a ring that is unsubstituted or substituted with deuterium.

In an exemplary embodiment of the present specification, Y is an aryl group having 6 to 30 carbon atoms, which is unsubstituted or substituted with deuterium; or a heteroaryl group having 2 to 30 carbon atoms, which is unsubstituted or substituted with deuterium, or is bonded to an adjacent substituent to form a ring that is unsubstituted or substituted with deuterium.

In an exemplary embodiment of the present specification, Y is an aryl group having 6 to 20 carbon atoms, which is unsubstituted or substituted with deuterium; or a heteroaryl group having 2 to 20 carbon atoms, which is unsubstituted or substituted with deuterium, or is bonded to an adjacent substituent to form a ring that is unsubstituted or substituted with deuterium.

In an exemplary embodiment of the present specification, Y is a substituted or unsubstituted phenyl group; a substituted or unsubstituted biphenyl group; a substituted or unsubstituted terphenyl group; a substituted or unsubstituted quaterphenyl group; a substituted or unsubstituted naphthyl group; a substituted or unsubstituted phenanthrenyl group; a substituted or unsubstituted fluorenyl group; a substituted or unsubstituted spirobifluorenyl group; a substituted or unsubstituted triphenylenyl group; a substituted or unsubstituted furan group; a substituted or unsubstituted benzofuran group; a substituted or unsubstituted dibenzofuran group; a substituted or unsubstituted naphthobenzofuran group; a substituted or unsubstituted thiophene group; a substituted or unsubstituted benzothiophene group; a substituted or unsubstituted dibenzothiophene group; a substituted or unsubstituted naphthobenzothiophene group; or a substituted or unsubstituted carbazole group, or is bonded to an adjacent substituent to form a substituted or unsubstituted benzene ring; a substituted or unsubstituted naphthalene ring; a substituted or unsubstituted indene ring; a substituted or unsubstituted furan ring; a substituted or unsubstituted benzofuran ring; a substituted or unsubstituted dibenzofuran ring; a substituted or unsubstituted naphthofuran ring; a substituted or unsubstituted thiophene ring; a substituted or unsubstituted benzothiophene ring; a substituted or unsubstituted dibenzothiophene ring; or a substituted or unsubstituted naphthothiophene ring.

In an exemplary embodiment of the present specification, Y is a substituted or unsubstituted aryl group or a substituted or unsubstituted heteroaryl group containing O, S or N, or is bonded to an adjacent substituent to form a substituted or unsubstituted aromatic hydrocarbon ring; or a substituted or unsubstituted aromatic hetero ring.

In an exemplary embodiment of the present specification, Y is an aryl group that is unsubstituted or substituted with deuterium or an aryl group or a heteroaryl group containing O, S or N, which is unsubstituted or substituted with deuterium or an aryl group, or is bonded to an adjacent substituent to form an aromatic hydrocarbon ring, which is unsubstituted or substituted with deuterium or an aryl group; or an aromatic hetero ring containing O, S or N, which is unsubstituted or substituted with deuterium or an aryl group.

In an exemplary embodiment of the present specification, Y is a substituted or unsubstituted phenyl group; a substituted or unsubstituted biphenyl group; a substituted or unsubstituted naphthyl group; a substituted or unsubstituted furan group; a substituted or unsubstituted thiophene group; a substituted or unsubstituted benzofuran group; a substituted or unsubstituted benzothiophene group; a substituted or unsubstituted dibenzofuran group; a substituted or unsubstituted dibenzothiophene group; or a substituted or unsubstituted carbazole group, or is bonded to an adjacent substituent to form a substituted or unsubstituted benzene ring; a substituted or unsubstituted naphthalene ring; a substituted or unsubstituted indene ring; a substituted or unsubstituted spirofluoreneindene ring; a substituted or unsubstituted furan ring; a substituted or unsubstituted benzofuran ring; a substituted or unsubstituted dibenzofuran ring; a substituted or unsubstituted naphthofuran ring

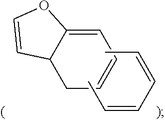

a substituted or unsubstituted thiophene ring; a substituted or unsubstituted benzothiophene ring; a substituted or unsubstituted dibenzothiophene ring; or a substituted or unsubstituted naphthothiophene ring

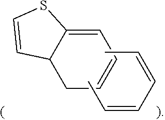

In an exemplary embodiment of the present specification, Y is a phenyl group that is unsubstituted or substituted with deuterium or an aryl group; a biphenyl group that is unsubstituted or substituted with deuterium or an aryl group; a naphthyl group that is unsubstituted or substituted with deuterium or an aryl group; a furan group that is unsubstituted or substituted with deuterium or an aryl group; a thiophene group that is unsubstituted or substituted with deuterium or an aryl group; a benzofuran group that is unsubstituted or substituted with deuterium or an aryl group; a benzothiophene group that is unsubstituted or substituted with deuterium or an aryl group; a dibenzofuran group that is unsubstituted or substituted with deuterium or an aryl group; a dibenzothiophene group that is unsubstituted or substituted with deuterium or an aryl group; or a carbazole group that is unsubstituted or substituted with deuterium or an aryl group, or is bonded to an adjacent substituent to form a benzene ring that is unsubstituted or substituted with deuterium or an aryl group; a naphthalene ring unsubstituted or substituted with deuterium or an aryl group; an indene ring that is unsubstituted or substituted with deuterium or an aryl group; a spirofluoreneindene ring that is unsubstituted or substituted with deuterium or an aryl group; a furan ring that is unsubstituted or substituted with deuterium or an aryl group; a benzofuran ring that is unsubstituted or substituted with deuterium or an aryl group; a dibenzofuran ring that is unsubstituted or substituted with deuterium or an aryl group; a naphthofuran ring that is unsubstituted or substituted with deuterium or an aryl group; a thiophene ring that is unsubstituted or substituted with deuterium or an aryl group; a benzothiophene ring that is unsubstituted or substituted with deuterium or an aryl group; a dibenzothiophene ring that is unsubstituted or substituted with deuterium or an aryl group; or a naphthothiophene ring that is unsubstituted or substituted with deuterium or an aryl group.

In an exemplary embodiment of the present specification, Y is a phenyl group that is unsubstituted or substituted with deuterium; a biphenyl group that is unsubstituted or substituted with deuterium; a naphthyl group that is unsubstituted or substituted with deuterium; a benzofuran group that is unsubstituted or substituted with a phenyl group; or a benzothiophene group that is unsubstituted or substituted with a phenyl group, or is bonded to an adjacent substituent to form a benzene ring that is unsubstituted or substituted with deuterium, a phenyl group or a naphthyl group; a naphthalene ring that is unsubstituted or substituted with deuterium, a phenyl group or a naphthyl group; an indene ring that is unsubstituted or substituted with deuterium, a phenyl group, a naphthyl group or a fluorenyl group; a spiro[fluorene-9,1′-indene] ring that is unsubstituted or substituted with deuterium, a phenyl group or a naphthyl group; a furan ring that is unsubstituted or substituted with deuterium, a phenyl group or a naphthyl group; a benzofuran ring that is unsubstituted or substituted with deuterium, a phenyl group or a naphthyl group; a dibenzofuran ring that is unsubstituted or substituted with deuterium, a phenyl group or a naphthyl group; a naphthofuran group that is unsubstituted or substituted with deuterium, a phenyl group or a naphthyl group; a thiophene ring that is unsubstituted or substituted with deuterium, a phenyl group or a naphthyl group; a benzothiophene ring that is unsubstituted or substituted with deuterium, a phenyl group or a naphthyl group; a dibenzothiophene ring that is unsubstituted or substituted with deuterium, a phenyl group or a naphthyl group; or a naphthothiophene ring that is unsubstituted or substituted with deuterium, a phenyl group or a naphthyl group.

In an exemplary embodiment of the present specification, Y is a phenyl group that is unsubstituted or substituted with deuterium; a naphthyl group that is unsubstituted or substituted with deuterium; or a benzofuran group that is unsubstituted or substituted with a phenyl group, or is bonded to an adjacent substituent to form a benzene ring that is unsubstituted or substituted with deuterium; a naphthalene ring that is unsubstituted or substituted with deuterium; a spiro[fluorene-9,1′-indene] ring that is unsubstituted or substituted with deuterium; or a benzofuran group that is unsubstituted or substituted with deuterium or a phenyl group.

In an exemplary embodiment of the present specification, Y is a phenyl group that is unsubstituted or substituted with deuterium; or a naphthyl group that is unsubstituted or substituted with deuterium.

In an exemplary embodiment of the present specification,

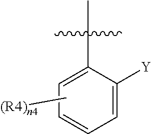

of Chemical Formula 1 is represented by the following Formula Y-1 or Y-2.

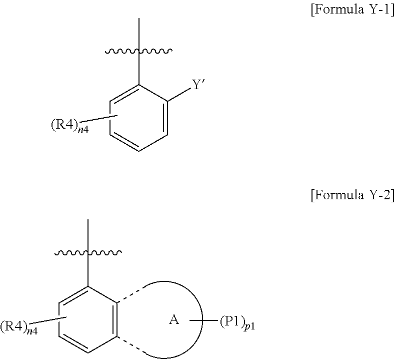

In Formula Y-1 or Y-2,
R4 and n4 are the same as the definitions in Chemical Formula 1,
Y′ is a substituted or unsubstituted aryl group; or a substituted or unsubstituted heteroaryl group,
A is an aromatic hydrocarbon ring; or an aromatic hetero ring,
P1 is deuterium; or a substituted or unsubstituted aryl group,
n4′ is 0 to 3,
p1 is 0 to 6,
when n4′ is 2 or higher, two or more R4's are the same as or different from each other,
when p1 is 2 or higher, two or more p1's are the same as or different from each other, and

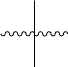

means a position linked to Chemical Formula 1.

In an exemplary embodiment of the present specification, Y′ is a substituted or unsubstituted aryl group; or a substituted or unsubstituted heteroaryl group.

In an exemplary embodiment of the present specification, Y′ is a substituted or unsubstituted aryl group having 6 to 60 carbon atoms; or a substituted or unsubstituted heteroaryl group having 2 to 60 carbon atoms.

In an exemplary embodiment of the present specification, Y′ is a substituted or unsubstituted aryl group having 6 to 30 carbon atoms; or a substituted or unsubstituted heteroaryl group having 2 to 30 carbon atoms.

In an exemplary embodiment of the present specification, Y′ is a substituted or unsubstituted aryl group having 6 to 20 carbon atoms; or a substituted or unsubstituted heteroaryl group having 2 to 20 carbon atoms.

In an exemplary embodiment of the present specification, Y′ is a substituted or unsubstituted aryl group having 6 to 60 carbon atoms; or a substituted or unsubstituted heteroaryl group having 2 to 60 carbon atoms and containing O, S or N.

In an exemplary embodiment of the present specification, Y′ is a substituted or unsubstituted aryl group having 6 to 30 carbon atoms; or a substituted or unsubstituted heteroaryl group having 2 to 30 carbon atoms and containing O, S or N.

In an exemplary embodiment of the present specification, Y′ is a substituted or unsubstituted aryl group having 6 to 20 carbon atoms; or a substituted or unsubstituted heteroaryl group having 2 to 20 carbon atoms and containing O, S or N.

In an exemplary embodiment of the present specification, Y′ is an aryl group having 6 to 60 carbon atoms, which is unsubstituted or substituted with deuterium; or a heteroaryl group having 2 to 60 carbon atoms, which is unsubstituted or substituted with deuterium.

In an exemplary embodiment of the present specification, Y′ is an aryl group having 6 to 30 carbon atoms, which is unsubstituted or substituted with deuterium; or a heteroaryl group having 2 to 30 carbon atoms, which is unsubstituted or substituted with deuterium.

In an exemplary embodiment of the present specification, Y′ is an aryl group having 6 to 20 carbon atoms, which is unsubstituted or substituted with deuterium; or a heteroaryl group having 2 to 20 carbon atoms, which is unsubstituted or substituted with deuterium.

In an exemplary embodiment of the present specification, Y′ is a substituted or unsubstituted phenyl group; a substituted or unsubstituted biphenyl group; a substituted or unsubstituted terphenyl group; a substituted or unsubstituted quaterphenyl group; a substituted or unsubstituted naphthyl group; a substituted or unsubstituted phenanthrenyl group; a substituted or unsubstituted fluorenyl group; a substituted or unsubstituted spirobifluorenyl group; a substituted or unsubstituted triphenylenyl group; a substituted or unsubstituted furan group; a substituted or unsubstituted benzofuran group; a substituted or unsubstituted dibenzofuran group; a substituted or unsubstituted naphthobenzofuran group; a substituted or unsubstituted thiophene group; a substituted or unsubstituted benzothiophene group; a substituted or unsubstituted dibenzothiophene group; a substituted or unsubstituted naphthobenzothiophene group; or a substituted or unsubstituted carbazole group.

In an exemplary embodiment of the present specification, Y′ is a substituted or unsubstituted aryl group or a substituted or unsubstituted heteroaryl group containing O, S or N.

In an exemplary embodiment of the present specification, Y′ is an aryl group that is unsubstituted or substituted with deuterium or an aryl group or a heteroaryl group containing O, S or N, which is unsubstituted or substituted with deuterium or an aryl group.

In an exemplary embodiment of the present specification, Y′ is a substituted or unsubstituted phenyl group; a substituted or unsubstituted biphenyl group; a substituted or unsubstituted naphthyl group; a substituted or unsubstituted furan group; a substituted or unsubstituted thiophene group; a substituted or unsubstituted benzofuran group; a substituted or unsubstituted benzothiophene group; a substituted or unsubstituted dibenzofuran group; a substituted or unsubstituted dibenzothiophene group; or a substituted or unsubstituted carbazole group.

In an exemplary embodiment of the present specification, Y′ is a phenyl group that is unsubstituted or substituted with deuterium or an aryl group; a biphenyl group that is unsubstituted or substituted with deuterium or an aryl group; a naphthyl group that is unsubstituted or substituted with deuterium or an aryl group; a furan group that is unsubstituted or substituted with deuterium or an aryl group; a thiophene group that is unsubstituted or substituted with deuterium or an aryl group; a benzofuran group that is unsubstituted or substituted with deuterium or an aryl group; a benzothiophene group that is unsubstituted or substituted with deuterium or an aryl group; a dibenzofuran group that is unsubstituted or substituted with deuterium or an aryl group; a dibenzothiophene group that is unsubstituted or substituted with deuterium or an aryl group; or a carbazole group that is unsubstituted or substituted with deuterium or an aryl group.

In an exemplary embodiment of the present specification, Y′ is a phenyl group that is unsubstituted or substituted with deuterium; a biphenyl group that is unsubstituted or substituted with deuterium; a naphthyl group that is unsubstituted or substituted with deuterium; a benzofuran group that is unsubstituted or substituted with a phenyl group; or a benzothiophene group that is unsubstituted or substituted with a phenyl group.

In an exemplary embodiment of the present specification, Y′ is a phenyl group that is unsubstituted or substituted with deuterium; a naphthyl group that is unsubstituted or substituted with deuterium; or a benzofuran group that is unsubstituted or substituted with a phenyl group.

In an exemplary embodiment of the present specification, Y′ is a phenyl group that is unsubstituted or substituted with deuterium; or a naphthyl group that is unsubstituted or substituted with deuterium.

In an exemplary embodiment of the present specification, A is an aromatic hydrocarbon ring having 6 to 60 carbon atoms; or an aromatic hetero ring having 2 to 60 carbon atoms.

In an exemplary embodiment of the present specification, A is an aromatic hydrocarbon ring having 6 to 30 carbon atoms; or an aromatic hetero ring having 2 to 30 carbon atoms and containing N, O or S.

In an exemplary embodiment of the present specification, A is a benzene ring; a naphthalene ring; an indene ring; a spirofluoreneindene ring; a furan ring; a benzofuran ring; a dibenzofuran ring; a naphthofuran ring; a thiophene ring; a benzothiophene ring; a dibenzothiophene ring; or a naphthothiophene ring.

In an exemplary embodiment of the present specification, P1 is deuterium; or a substituted or unsubstituted aryl group having 6 to 30 carbon atoms.

In an exemplary embodiment of the present specification, P1 is deuterium; or a substituted or unsubstituted aryl group having 6 to 20 carbon atoms.

In an exemplary embodiment of the present specification, P1 is deuterium; or an aryl group having 6 to 20 carbon atoms, which is unsubstituted or substituted with deuterium.

In an exemplary embodiment of the present specification, P1 is deuterium; a phenyl group that is unsubstituted or substituted with deuterium; a biphenyl group unsubstituted or substituted with deuterium; or a naphthyl group that is unsubstituted or substituted with deuterium.

In an exemplary embodiment of the present specification, R1 and R2 are the same as or different from each other, and are each independently hydrogen; deuterium; a substituted or unsubstituted silyl group; a substituted or unsubstituted alkyl group; a substituted or unsubstituted aryl group; or a substituted or unsubstituted heteroaryl group.

In an exemplary embodiment of the present specification, R1 and R2 are the same as or different from each other, and are each independently hydrogen; deuterium; a substituted or unsubstituted silyl group; a substituted or unsubstituted alkyl group having 1 to 60 carbon atoms; a substituted or unsubstituted aryl group having 6 to 60 carbon atoms; or a substituted or unsubstituted heteroaryl group having 2 to 60 carbon atoms.

In an exemplary embodiment of the present specification, R1 and R2 are the same as or different from each other, and are each independently hydrogen; deuterium; a substituted or unsubstituted silyl group; a substituted or unsubstituted alkyl group having 1 to 30 carbon atoms; a substituted or unsubstituted aryl group having 6 to 30 carbon atoms; or a substituted or unsubstituted heteroaryl group having 2 to 30 carbon atoms.

In an exemplary embodiment of the present specification, R1 and R2 are the same as or different from each other, and are each independently hydrogen; deuterium; a substituted or unsubstituted silyl group; a substituted or unsubstituted alkyl group having 1 to 20 carbon atoms; a substituted or unsubstituted aryl group having 6 to 20 carbon atoms; or a substituted or unsubstituted heteroaryl group having 2 to 20 carbon atoms.

In an exemplary embodiment of the present specification, R1 and R2 are the same as or different from each other, and are each independently hydrogen; deuterium; a substituted or unsubstituted silyl group; a substituted or unsubstituted alkyl group having 1 to 60 carbon atoms; a substituted or unsubstituted aryl group having 6 to 60 carbon atoms; or a substituted or unsubstituted heteroaryl group having 2 to 60 carbon atoms and containing O, S or N.

In an exemplary embodiment of the present specification, R1 and R2 are the same as or different from each other, and are each independently hydrogen; deuterium; a substituted or unsubstituted silyl group; a substituted or unsubstituted alkyl group having 1 to 30 carbon atoms; a substituted or unsubstituted aryl group having 6 to 30 carbon atoms; or a substituted or unsubstituted heteroaryl group having 2 to 30 carbon atoms and containing O, S or N.

In an exemplary embodiment of the present specification, R1 and R2 are the same as or different from each other, and are each independently hydrogen; deuterium; a substituted or unsubstituted silyl group; a substituted or unsubstituted alkyl group having 1 to 20 carbon atoms; a substituted or unsubstituted aryl group having 6 to 20 carbon atoms; or a substituted or unsubstituted heteroaryl group having 2 to 20 carbon atoms and containing O, S or N.

In an exemplary embodiment of the present specification, R1 and R2 are the same as or different from each other, and are each independently hydrogen; deuterium; a substituted or unsubstituted alkylsilyl group; a substituted or unsubstituted arylsilyl group; a substituted or unsubstituted phenyl group; a substituted or unsubstituted biphenyl group; a substituted or unsubstituted terphenyl group; a substituted or unsubstituted quaterphenyl group; a substituted or unsubstituted naphthyl group; a substituted or unsubstituted phenanthrenyl group; a substituted or unsubstituted fluorenyl group; a substituted or unsubstituted spirobifluorenyl group; a substituted or unsubstituted triphenylenyl group; a substituted or unsubstituted furan group; a substituted or unsubstituted benzofuran group; a substituted or unsubstituted dibenzofuran group; a substituted or unsubstituted naphthobenzofuran group; a substituted or unsubstituted thiophene group; a substituted or unsubstituted benzothiophene group; a substituted or unsubstituted dibenzothiophene group; a substituted or unsubstituted naphthobenzothiophene group; or a substituted or unsubstituted carbazole group.

In an exemplary embodiment of the present specification, R1 is hydrogen; deuterium; a substituted or unsubstituted arylsilyl group; a substituted or unsubstituted phenyl group; a substituted or unsubstituted biphenyl group; or a substituted or unsubstituted naphthyl group.

In an exemplary embodiment of the present specification, R1 is hydrogen; deuterium; a triarylsilyl group that is unsubstituted or substituted with deuterium; a phenyl group that is unsubstituted or substituted with deuterium; a biphenyl group that is unsubstituted or substituted with deuterium; or a naphthyl group that is unsubstituted or substituted with deuterium.

In an exemplary embodiment of the present specification, R1 is hydrogen; deuterium; a triphenylsilyl group; a phenyl group that is unsubstituted or substituted with deuterium; a biphenyl group that is unsubstituted or substituted with deuterium; or a naphthyl group that is unsubstituted or substituted with deuterium.

In an exemplary embodiment of the present specification, R1 is hydrogen; deuterium; a phenyl group that is unsubstituted or substituted with deuterium; or a triphenylsilyl group.

In an exemplary embodiment of the present specification, R2 is hydrogen; or deuterium.

In an exemplary embodiment of the present specification, R4 is hydrogen; deuterium; a substituted or unsubstituted silyl group; a substituted or unsubstituted alkyl group; a substituted or unsubstituted aryl group; or a substituted or unsubstituted heteroaryl group, or is bonded to an adjacent substituent to form a substituted or unsubstituted ring.

In an exemplary embodiment of the present specification, R4 is hydrogen; deuterium; a substituted or unsubstituted silyl group; a substituted or unsubstituted alkyl group; a substituted or unsubstituted aryl group; or a substituted or unsubstituted heteroaryl group, or is bonded to an adjacent substituent to form a substituted or unsubstituted aromatic hydrocarbon ring; or a substituted or unsubstituted aromatic hetero ring.

In an exemplary embodiment of the present specification, R4 is hydrogen; deuterium; a substituted or unsubstituted silyl group; a substituted or unsubstituted alkyl group having 1 to 60 carbon atoms; a substituted or unsubstituted aryl group having 6 to 60 carbon atoms; or a substituted or unsubstituted heteroaryl group having 2 to 60 carbon atoms, or is bonded to an adjacent substituent to form a substituted or unsubstituted aromatic hydrocarbon ring having 6 to 60 carbon atoms; or a substituted or unsubstituted aromatic hetero ring having 2 to 60 carbon atoms.

In an exemplary embodiment of the present specification, R4 is hydrogen; deuterium; a substituted or unsubstituted silyl group; a substituted or unsubstituted alkyl group having 1 to 30 carbon atoms; a substituted or unsubstituted aryl group having 6 to 30 carbon atoms; or a substituted or unsubstituted heteroaryl group having 2 to 30 carbon atoms, or is bonded to an adjacent substituent to form a substituted or unsubstituted aromatic hydrocarbon ring having 6 to 30 carbon atoms; or a substituted or unsubstituted aromatic hetero ring having 2 to 30 carbon atoms.

In an exemplary embodiment of the present specification, R4 is hydrogen; deuterium; a substituted or unsubstituted silyl group; a substituted or unsubstituted alkyl group having 1 to 20 carbon atoms; a substituted or unsubstituted aryl group having 6 to 20 carbon atoms; or a substituted or unsubstituted heteroaryl group having 2 to 20 carbon atoms, or is bonded to an adjacent substituent to form a substituted or unsubstituted aromatic hydrocarbon ring having 6 to 20 carbon atoms; or a substituted or unsubstituted aromatic hetero ring having 2 to 20 carbon atoms.

In an exemplary embodiment of the present specification, R4 is hydrogen; deuterium; a substituted or unsubstituted silyl group; a substituted or unsubstituted alkyl group having 1 to 60 carbon atoms; a substituted or unsubstituted aryl group having 6 to 60 carbon atoms; or a substituted or unsubstituted heteroaryl group having 2 to 60 carbon atoms and containing O, S or N, or is bonded to an adjacent substituent to form a substituted or unsubstituted aromatic hydrocarbon ring having 6 to 60 carbon atom; or a substituted or unsubstituted aromatic hetero ring having 2 to 60 carbon atoms and containing O, S or N.

In an exemplary embodiment of the present specification, R4 is hydrogen; deuterium; a substituted or unsubstituted silyl group; a substituted or unsubstituted alkyl group having 1 to 30 carbon atoms; a substituted or unsubstituted aryl group having 6 to 30 carbon atoms; or a substituted or unsubstituted heteroaryl group having 2 to 30 carbon atoms and containing O, S or N, or is bonded to an adjacent substituent to form a substituted or unsubstituted aromatic hydrocarbon ring having 6 to 30 carbon atom; or a substituted or unsubstituted aromatic hetero ring having 2 to 30 carbon atoms and containing O, S or N.

In an exemplary embodiment of the present specification, R4 is hydrogen; deuterium; a substituted or unsubstituted silyl group; a substituted or unsubstituted alkyl group having 1 to 20 carbon atoms; a substituted or unsubstituted aryl group having 6 to 20 carbon atoms; or a substituted or unsubstituted heteroaryl group having 2 to 20 carbon atoms and containing O, S or N, or is bonded to an adjacent substituent to form a substituted or unsubstituted aromatic hydrocarbon ring having 6 to 20 carbon atoms; or a substituted or unsubstituted aromatic hetero ring having 2 to 20 carbon atoms and containing O, S or N.

In an exemplary embodiment of the present specification, R4 is hydrogen; deuterium; a substituted or unsubstituted alkylsilyl group; a substituted or unsubstituted arylsilyl group; a substituted or unsubstituted phenyl group; a substituted or unsubstituted biphenyl group; a substituted or unsubstituted terphenyl group; a substituted or unsubstituted quaterphenyl group; a substituted or unsubstituted naphthyl group; a substituted or unsubstituted phenanthrenyl group; a substituted or unsubstituted fluorenyl group; a substituted or unsubstituted spirobifluorenyl group; a substituted or unsubstituted triphenylenyl group; a substituted or unsubstituted furan group; a substituted or unsubstituted benzofuran group; a substituted or unsubstituted dibenzofuran group; a substituted or unsubstituted naphthobenzofuran group; a substituted or unsubstituted thiophene group; a substituted or unsubstituted benzothiophene group; a substituted or unsubstituted dibenzothiophene group; a substituted or unsubstituted naphthobenzothiophene group; or a substituted or unsubstituted carbazole group, or is bonded to an adjacent substituent to form a substituted or unsubstituted benzene ring, naphthalene ring, benzofuran ring or benzothiophene ring.

In an exemplary embodiment of the present specification, R4 is hydrogen; deuterium; a triphenylsilyl group; a phenyl group; or a naphthyl group, or is bonded to an adjacent substituent to form a benzene ring, and the substituent is unsubstituted or substituted with one or more selected from the group consisting of deuterium, a phenyl group and a naphthyl group or a group in which two or more groups selected from the above group are linked together.

In an exemplary embodiment of the present specification, R4 is hydrogen; deuterium; or a phenyl group that is unsubstituted or substituted with deuterium.

In an exemplary embodiment of the present specification, R1, R2 and R4 are the same as or different from each other, and are each independently hydrogen; or deuterium.

In an exemplary embodiment of the present specification, R1, R2 and R4 are hydrogen.

In an exemplary embodiment of the present specification, R1, R2 and R4 are deuterium.

In an exemplary embodiment of the present specification, R3 is hydrogen; or deuterium.

In an exemplary embodiment of the present specification, R3 is hydrogen.

In an exemplary embodiment of the present specification, R3 is deuterium.

In an exemplary embodiment of the present specification, n1 is an integer from 0 to 3, n2 is an integer from 0 to 6, n3 is an integer from 0 to 8, n4 is an integer from 0 to 4, and when n1 to n4 are each 2 or higher, two or more of R1 to R4 are each the same as or different from each other.

In an exemplary embodiment of the present specification, n1 is an integer from 0 to 3.

In an exemplary embodiment of the present specification, n1 is an integer from 1 to 3.

In an exemplary embodiment of the present specification, n1 is 0.

In an exemplary embodiment of the present specification, n1 is 1.

In an exemplary embodiment of the present specification, n1 is 2.

In an exemplary embodiment of the present specification, n1 is 3.

In an exemplary embodiment of the present specification, n1 is 3, and R1 is all deuterium.

In an exemplary embodiment of the present specification, n1 is 3, and two of three R1's are deuterium.

In an exemplary embodiment of the present specification, n1 is 3, and one of three R1's is deuterium.

In an exemplary embodiment of the present specification, n2 is an integer from 0 to 6.

In an exemplary embodiment of the present specification, n2 is an integer from 1 to 6.

In an exemplary embodiment of the present specification, n2 is 0.

In an exemplary embodiment of the present specification, n2 is 1.

In an exemplary embodiment of the present specification, n2 is 2.

In an exemplary embodiment of the present specification, n2 is 3.

In an exemplary embodiment of the present specification, n2 is 4.

In an exemplary embodiment of the present specification, n2 is 5.

In an exemplary embodiment of the present specification, n2 is 6.

In an exemplary embodiment of the present specification, n2 is 6, and R2 is all deuterium.

In an exemplary embodiment of the present specification, n2 is 6, and five of six R2's are deuterium.

In an exemplary embodiment of the present specification, n2 is 6, and four of six R2's are deuterium.

In an exemplary embodiment of the present specification, n2 is 6, and three of six R2's are deuterium.

In an exemplary embodiment of the present specification, n2 is 6, and two of six R2's are deuterium.

In an exemplary embodiment of the present specification, n2 is 6, and one of six R2's is deuterium.

In an exemplary embodiment of the present specification, n3 is an integer from 0 to 8.

In an exemplary embodiment of the present specification, n3 is an integer from 1 to 8.

In an exemplary embodiment of the present specification, n3 is 0.

In an exemplary embodiment of the present specification, n3 is 1.

In an exemplary embodiment of the present specification, n3 is 2.

In an exemplary embodiment of the present specification, n3 is 3.

In an exemplary embodiment of the present specification, n3 is 4.

In an exemplary embodiment of the present specification, n3 is 5.

In an exemplary embodiment of the present specification, n3 is 6.

In an exemplary embodiment of the present specification, n3 is 7.

In an exemplary embodiment of the present specification, n3 is 8.

In an exemplary embodiment of the present specification, n3 is 8, and R3 is all deuterium.

In an exemplary embodiment of the present specification, n3 is 8, and seven of eight R3's are deuterium.

In an exemplary embodiment of the present specification, n3 is 8, and six of eight R3's are deuterium.

In an exemplary embodiment of the present specification, n3 is 8, and five of eight R3's are deuterium.

In an exemplary embodiment of the present specification, n3 is 8, and four of eight R3's are deuterium.

In an exemplary embodiment of the present specification, n3 is 8, and three of eight R3's are deuterium.

In an exemplary embodiment of the present specification, n3 is 8, and two of eight R3's are deuterium.

In an exemplary embodiment of the present specification, n3 is 8, and one of eight R3's is deuterium.

In an exemplary embodiment of the present specification, n4 is an integer from 0 to 4.

In an exemplary embodiment of the present specification, n4 is an integer from 1 to 4.

In an exemplary embodiment of the present specification, n4 is 0.

In an exemplary embodiment of the present specification, n4 is 1.

In an exemplary embodiment of the present specification, n4 is 2.

In an exemplary embodiment of the present specification, n4 is 3.

In an exemplary embodiment of the present specification, n4 is 4.

In an exemplary embodiment of the present specification, n4 is 4, and R4 is all deuterium.

In an exemplary embodiment of the present specification, n4 is 4, and three of four R4's are deuterium.

In an exemplary embodiment of the present specification, n4 is 4, and two of four R4's are deuterium.

In an exemplary embodiment of the present specification, n4 is 4, and one of four R4's is deuterium.

In an exemplary embodiment of the present specification, Chemical Formula 1 includes at least one or more deuterium(s).

In an exemplary embodiment of the present specification, at least 30% of the compound of Chemical Formula 1 is substituted with deuterium. In another exemplary embodiment, 40% or more of the compound of Chemical Formula 1 is substituted with deuterium. In another exemplary embodiment, 50% or more of the compound of Chemical Formula 1 is substituted with deuterium. In still another exemplary embodiment, 60% or more of the compound of Chemical Formula 1 is substituted with deuterium. In yet another exemplary embodiment, 70% or more of the compound of Chemical Formula 1 is substituted with deuterium. In still yet another exemplary embodiment, 80% or more of the compound of Chemical Formula 1 is substituted with deuterium. In a further exemplary embodiment, 90% or more of the compound of Chemical Formula 1 is substituted with deuterium. In another further exemplary embodiment, 100% of the compound of Chemical Formula 1 is substituted with deuterium.

In an exemplary embodiment of the present specification, the compound of Chemical Formula 1 includes 40% to 60% of deuterium. In another exemplary embodiment, the compound of Chemical Formula 1 includes 40% to 80% of deuterium. In still another exemplary embodiment, the compound of Chemical Formula 1 includes 60% to 80% of deuterium. In yet another exemplary embodiment, the compound of Chemical Formula 1 includes 80% to 100% of deuterium.

In an exemplary embodiment of the present specification, Chemical Formula 1 is any one of the following compounds.

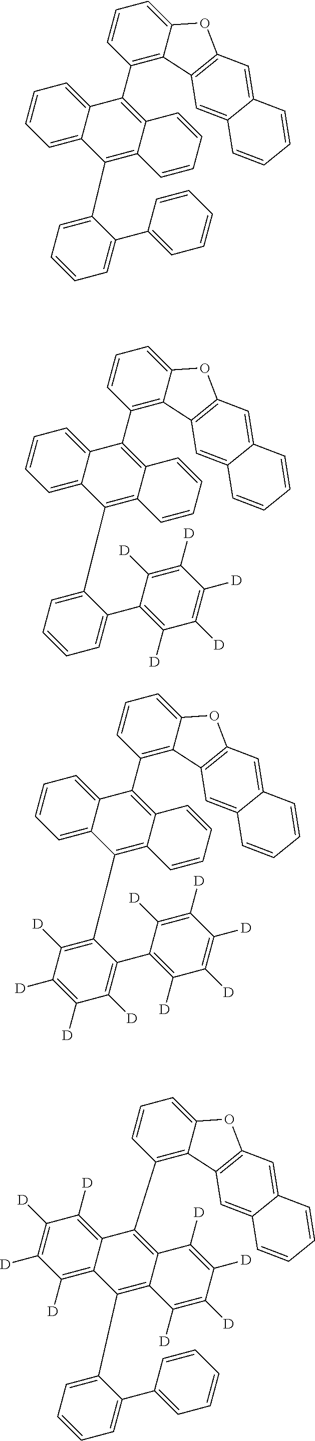

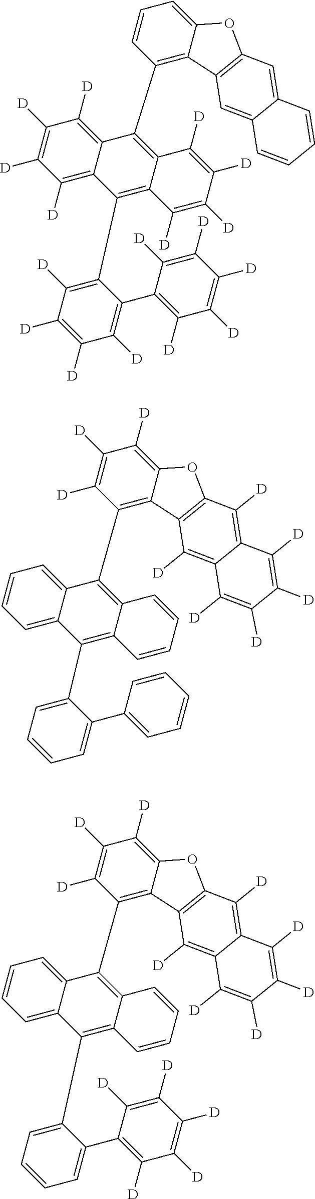 [SMILES: [2H]c1c([2H])c([2H])c(-c2c([2H])c([2H])c([2H])c([2H])c2-c2c3c([2H])c([2H])c([2H])c([2H])c3c(-c3cccc4oc5cc6ccccc6cc5c34)c3c([2H])c([2H])c([2H])c([2H])c23)c([2H])c1[2H] ; [2H]c1c([2H])c(-c2c3ccccc3c(-c3ccccc3-c3ccccc3)c3ccccc23)c2c(oc3c([2H])c4c([2H])c([2H])c([2H])c([2H])c4c([2H])c32)c1[2H] ; [2H]c1c([2H])c([2H])c(-c2ccccc2-c2c3ccccc3c(-c3c([2H])c([2H])c([2H])c4oc5c([2H])c6c([2H])c([2H])c([2H])c([2H])c6c([2H])c5c34)c3ccccc23)c([2H])c1[2H]]

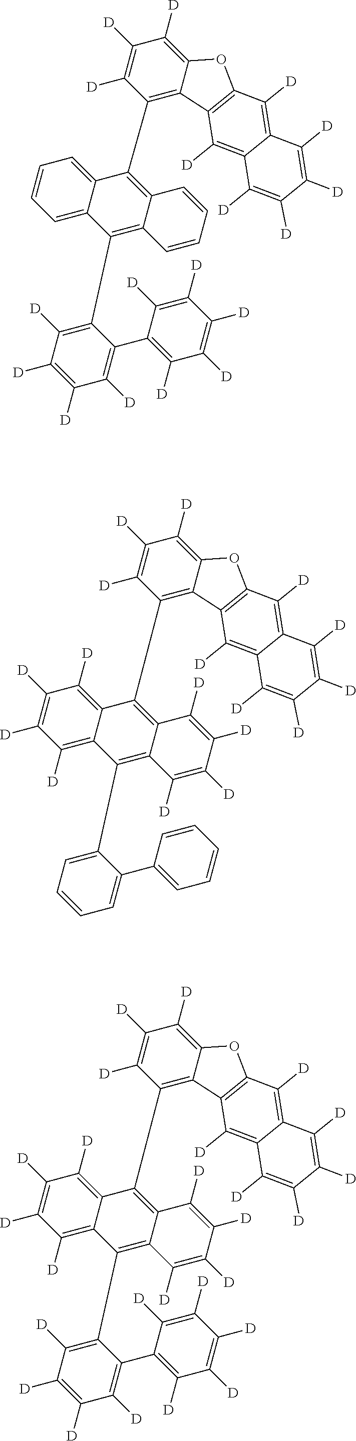

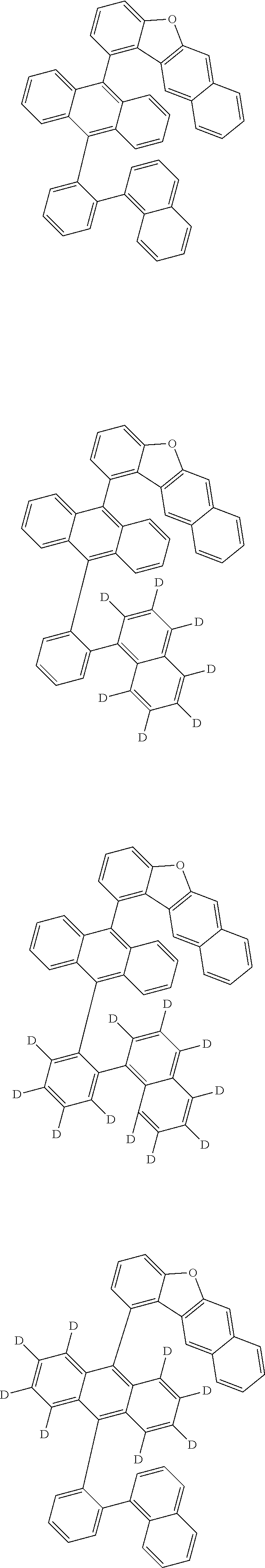 [SMILES: c1ccc(-c2c3ccccc3c(-c3cccc4oc5cc6ccccc6cc5c34)c3ccccc23)c(-c2cccc3ccccc23)c1 ; [2H]c1c([2H])c([2H])c2c(-c3ccccc3-c3c4ccccc4c(-c4cccc5oc6cc7ccccc7cc6c45)c4ccccc34)c([2H])c([2H])c([2H])c2c1[2H] ; [2H]c1c([2H])c([2H])c(-c2c([2H])c([2H])c([2H])c3c([2H])c([2H])c([2H])c([2H])c23)c(-c2c3ccccc3c(-c3cccc4oc5cc6ccccc6cc5c34)c3ccccc23)c1[2H] ; [2H]c1c([2H])c([2H])c2c(-c3cccc4oc5cc6ccccc6cc5c34)c3c([2H])c([2H])c([2H])c([2H])c3c(-c3ccccc3-c3cccc4ccccc34)c2c1[2H]]

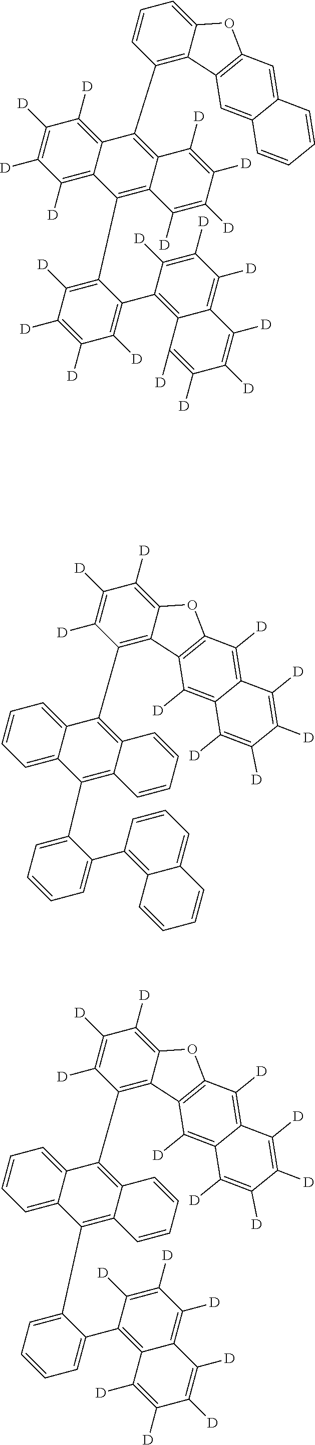 [SMILES: [2H]c1c([2H])c([2H])c(-c2c3c([2H])c([2H])c([2H])c([2H])c3c(-c3cccc4oc5cc6ccccc6cc5c34)c3c([2H])c([2H])c([2H])c([2H])c23)c(-c2c([2H])c([2H])c([2H])c3c([2H])c([2H])c([2H])c([2H])c23)c1[2H] ; [2H]c1c([2H])c(-c2c3ccccc3c(-c3ccccc3-c3cccc4ccccc34)c3ccccc23)c2c(oc3c([2H])c4c([2H])c([2H])c([2H])c([2H])c4c([2H])c32)c1[2H] ; [2H]c1c([2H])c(-c2c3ccccc3c(-c3ccccc3-c3c([2H])c([2H])c([2H])c4c([2H])c([2H])c([2H])c([2H])c34)c3ccccc23)c2c(oc3c([2H])c4c([2H])c([2H])c([2H])c([2H])c4c([2H])c32)c1[2H]]

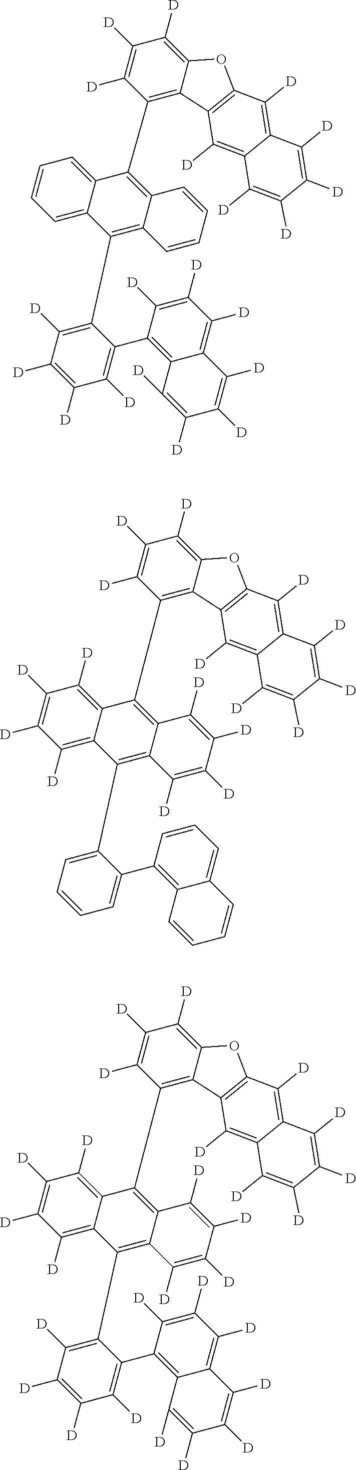

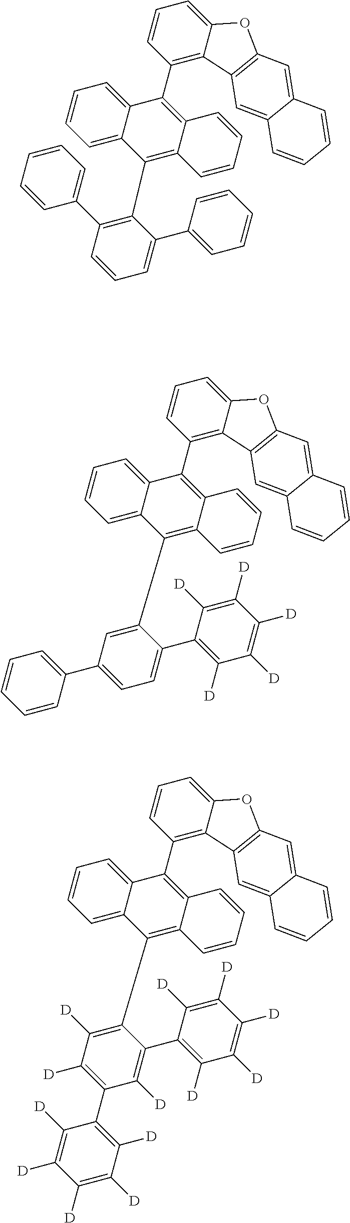 [SMILES: c1ccc(-c2cccc(-c3ccccc3)c2-c2c3ccccc3c(-c3cccc4oc5cc6ccccc6cc5c34)c3ccccc23)cc1 ; [2H]c1c([2H])c([2H])c(-c2ccc(-c3ccccc3)cc2-c2c3ccccc3c(-c3cccc4oc5cc6ccccc6cc5c34)c3ccccc23)c([2H])c1[2H] ; [2H]c1c([2H])c([2H])c(-c2c([2H])c([2H])c(-c3c4ccccc4c(-c4cccc5oc6cc7ccccc7cc6c45)c4ccccc34)c(-c3c([2H])c([2H])c([2H])c([2H])c3[2H])c2[2H])c([2H])c1[2H]]

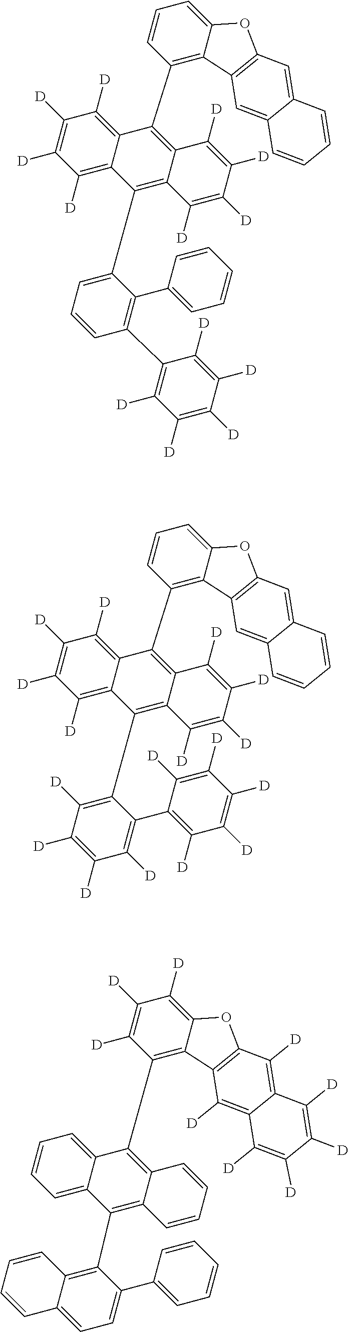 [SMILES: [2H]c1c([2H])c([2H])c(-c2cccc(-c3c4c([2H])c([2H])c([2H])c([2H])c4c(-c4cccc5oc6cc7ccccc7cc6c45)c4c([2H])c([2H])c([2H])c([2H])c34)c2-c2ccccc2)c([2H])c1[2H] ; [2H]c1c([2H])c([2H])c(-c2c([2H])c([2H])c([2H])c([2H])c2-c2c3c([2H])c([2H])c([2H])c([2H])c3c(-c3cccc4oc5cc6ccccc6cc5c34)c3c([2H])c([2H])c([2H])c([2H])c23)c([2H])c1[2H] ; [2H]c1c([2H])c(-c2c3ccccc3c(-c3c(-c4ccccc4)ccc4ccccc34)c3ccccc23)c2c(oc3c([2H])c4c([2H])c([2H])c([2H])c([2H])c4c([2H])c32)c1[2H]]

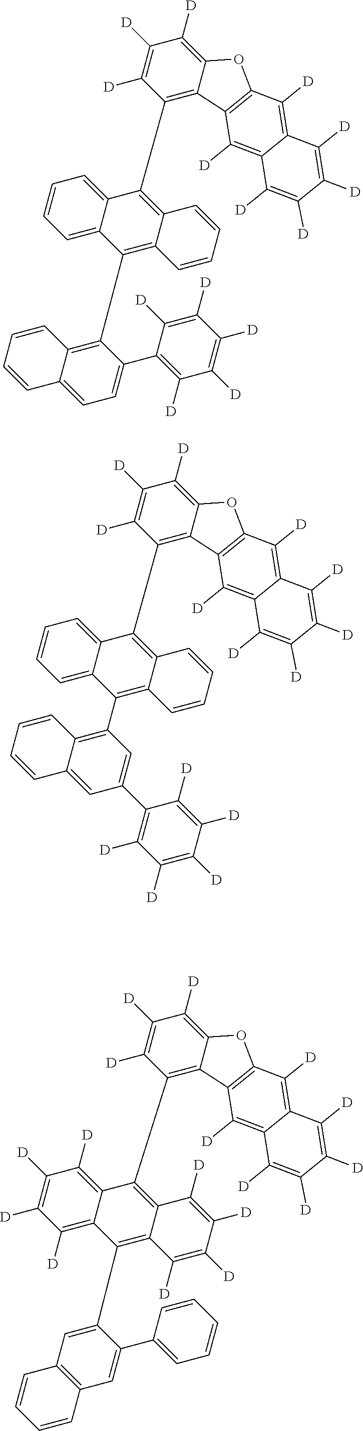

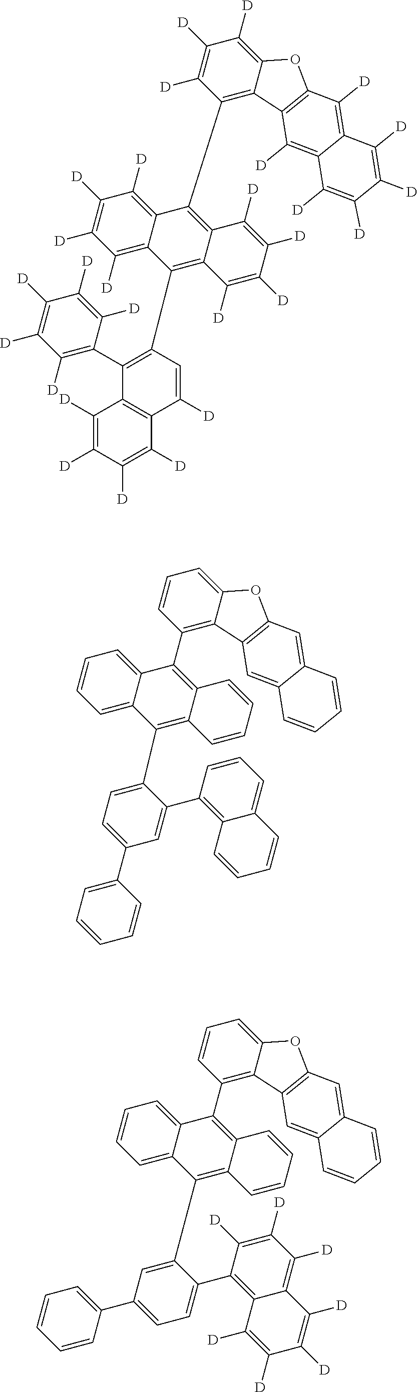 [SMILES: [2H]c1c([2H])c([2H])c(-c2c(-c3c4c([2H])c([2H])c([2H])c([2H])c4c(-c4c([2H])c([2H])c([2H])c5oc6c([2H])c7c([2H])c([2H])c([2H])c([2H])c7c([2H])c6c45)c4c([2H])c([2H])c([2H])c([2H])c34)cc([2H])c3c([2H])c([2H])c([2H])c([2H])c23)c([2H])c1[2H] ; c1ccc(-c2ccc(-c3c4ccccc4c(-c4cccc5oc6cc7ccccc7cc6c45)c4ccccc34)c(-c3cccc4ccccc34)c2)cc1 ; [2H]c1c([2H])c([2H])c2c(-c3ccc(-c4ccccc4)cc3-c3c4ccccc4c(-c4cccc5oc6cc7ccccc7cc6c45)c4ccccc34)c([2H])c([2H])c([2H])c2c1[2H]]

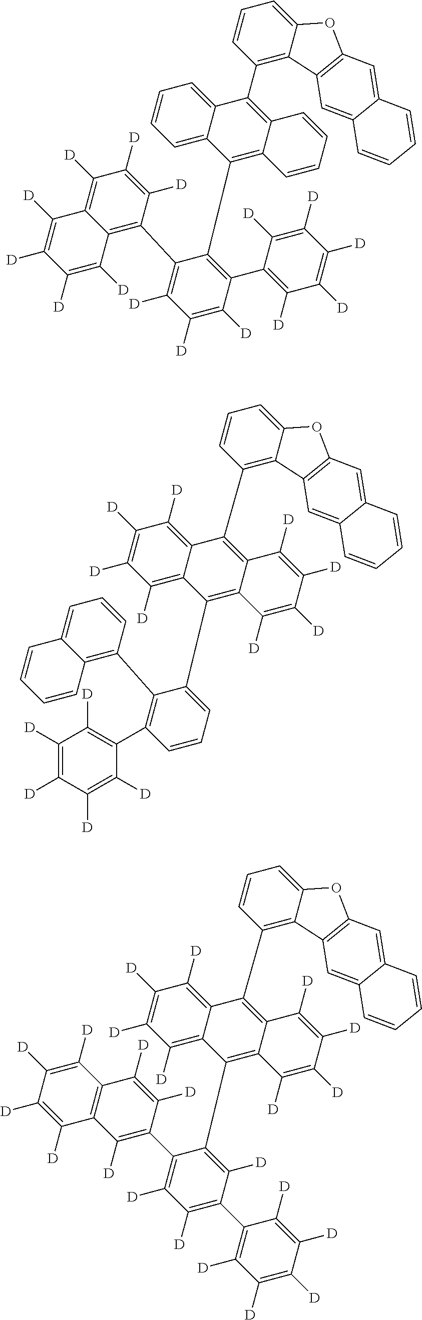

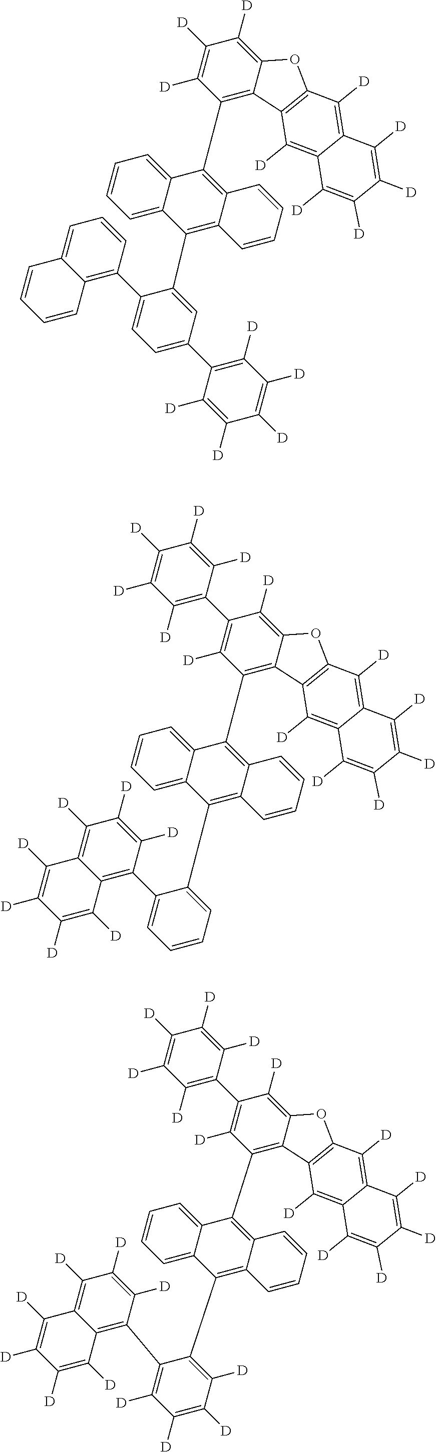

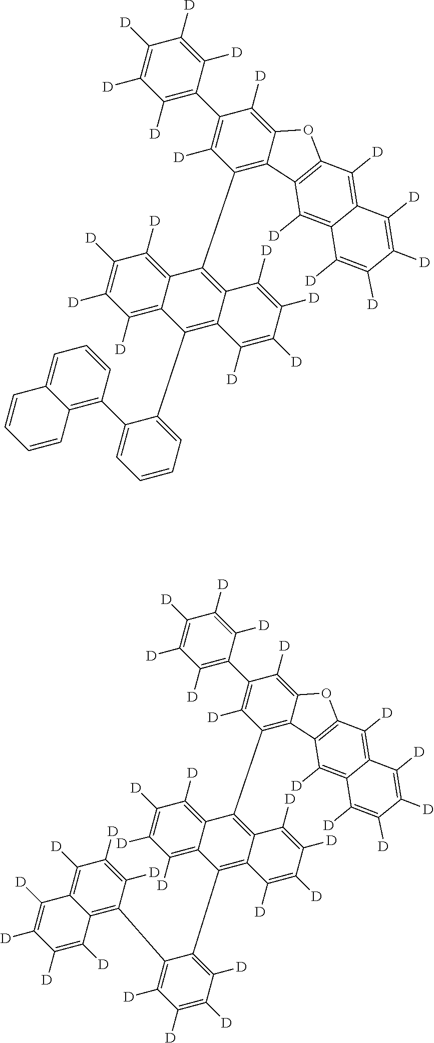 [SMILES: [2H]c1c([2H])c([2H])c(-c2c([2H])c(-c3c4c([2H])c([2H])c([2H])c([2H])c4c(-c4ccccc4-c4cccc5ccccc45)c4c([2H])c([2H])c([2H])c([2H])c34)c3c(oc4c([2H])c5c([2H])c([2H])c([2H])c([2H])c5c([2H])c43)c2[2H])c([2H])c1[2H] ; [2H]c1c([2H])c([2H])c(-c2c([2H])c(-c3c4c([2H])c([2H])c([2H])c([2H])c4c(-c4c([2H])c([2H])c([2H])c([2H])c4-c4c([2H])c([2H])c([2H])c5c([2H])c([2H])c([2H])c([2H])c45)c4c([2H])c([2H])c([2H])c([2H])c34)c3c(oc4c([2H])c5c([2H])c([2H])c([2H])c([2H])c5c([2H])c43)c2[2H])c([2H])c1[2H]]

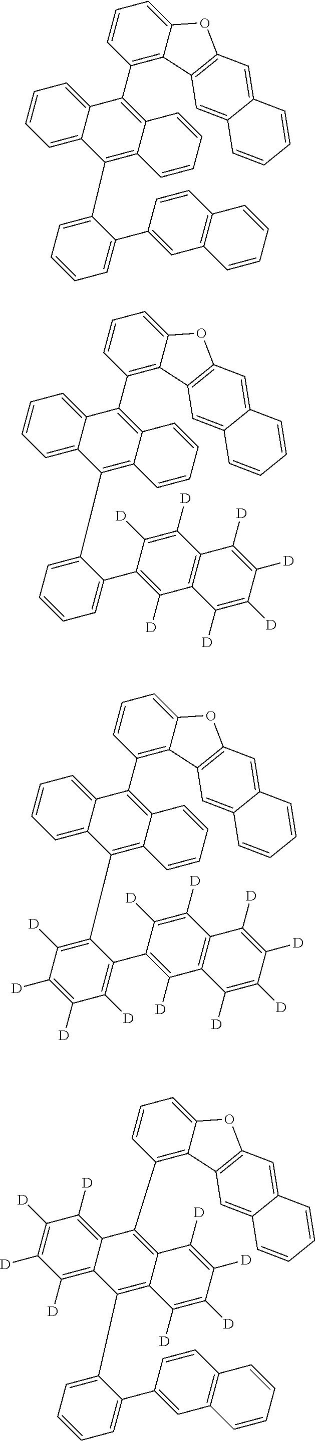 [SMILES: c1ccc(-c2c3ccccc3c(-c3cccc4oc5cc6ccccc6cc5c34)c3ccccc23)c(-c2ccc3ccccc3c2)c1 ; [2H]c1c([2H])c([2H])c2c([2H])c(-c3ccccc3-c3c4ccccc4c(-c4cccc5oc6cc7ccccc7cc6c45)c4ccccc34)c([2H])c([2H])c2c1[2H] ; [2H]c1c([2H])c([2H])c(-c2c3ccccc3c(-c3cccc4oc5cc6ccccc6cc5c34)c3ccccc23)c(-c2c([2H])c([2H])c3c([2H])c([2H])c([2H])c([2H])c3c2[2H])c1[2H] ; [2H]c1c([2H])c([2H])c2c(-c3cccc4oc5cc6ccccc6cc5c34)c3c([2H])c([2H])c([2H])c([2H])c3c(-c3ccccc3-c3ccc4ccccc4c3)c2c1[2H]]

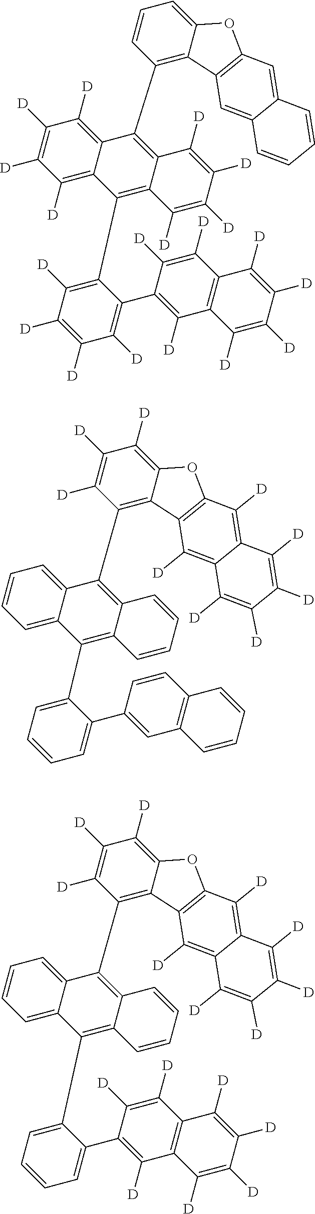 [SMILES: [2H]c1c([2H])c([2H])c(-c2c3c([2H])c([2H])c([2H])c([2H])c3c(-c3cccc4oc5cc6ccccc6cc5c34)c3c([2H])c([2H])c([2H])c([2H])c23)c(-c2c([2H])c([2H])c3c([2H])c([2H])c([2H])c([2H])c3c2[2H])c1[2H] ; [2H]c1c([2H])c(-c2c3ccccc3c(-c3ccccc3-c3ccc4ccccc4c3)c3ccccc23)c2c(oc3c([2H])c4c([2H])c([2H])c([2H])c([2H])c4c([2H])c32)c1[2H] ; [2H]c1c([2H])c(-c2c3ccccc3c(-c3ccccc3-c3c([2H])c([2H])c4c([2H])c([2H])c([2H])c([2H])c4c3[2H])c3ccccc23)c2c(oc3c([2H])c4c([2H])c([2H])c([2H])c([2H])c4c([2H])c32)c1[2H]]

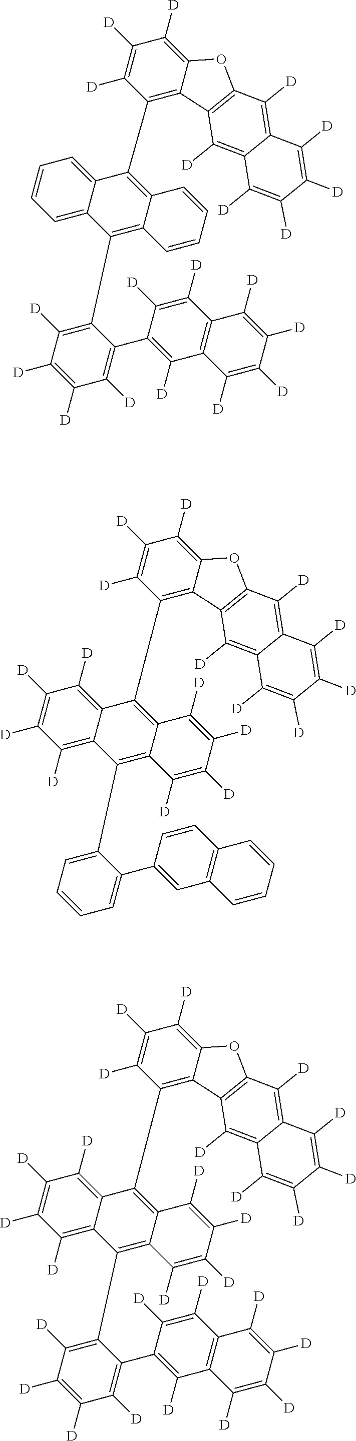

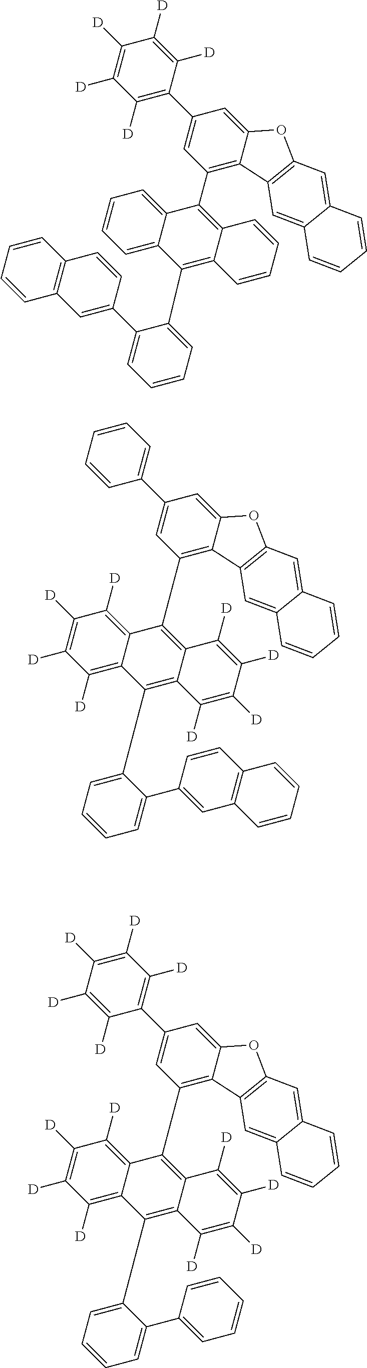

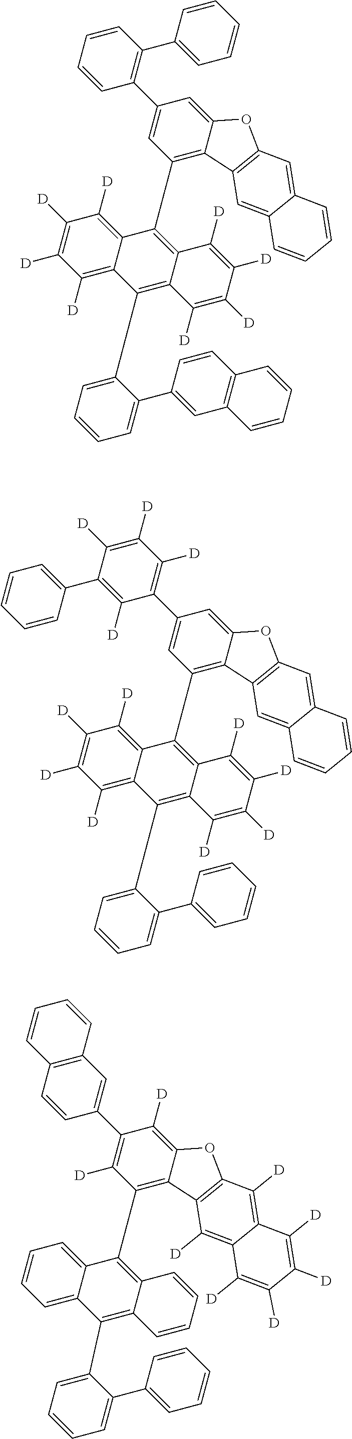 [SMILES: [2H]c1c([2H])c([2H])c2c(-c3cc(-c4ccccc4-c4ccccc4)cc4oc5cc6ccccc6cc5c34)c3c([2H])c([2H])c([2H])c([2H])c3c(-c3ccccc3-c3ccc4ccccc4c3)c2c1[2H] ; [2H]c1c([2H])c(-c2ccccc2)c([2H])c(-c2cc(-c3c4c([2H])c([2H])c([2H])c([2H])c4c(-c4ccccc4-c4ccccc4)c4c([2H])c([2H])c([2H])c([2H])c34)c3c(c2)oc2cc4ccccc4cc23)c1[2H] ; [2H]c1c([2H])c([2H])c2c([2H])c3c(oc4c([2H])c(-c5ccc6ccccc6c5)c([2H])c(-c5c6ccccc6c(-c6ccccc6-c6ccccc6)c6ccccc56)c43)c([2H])c2c1[2H]]

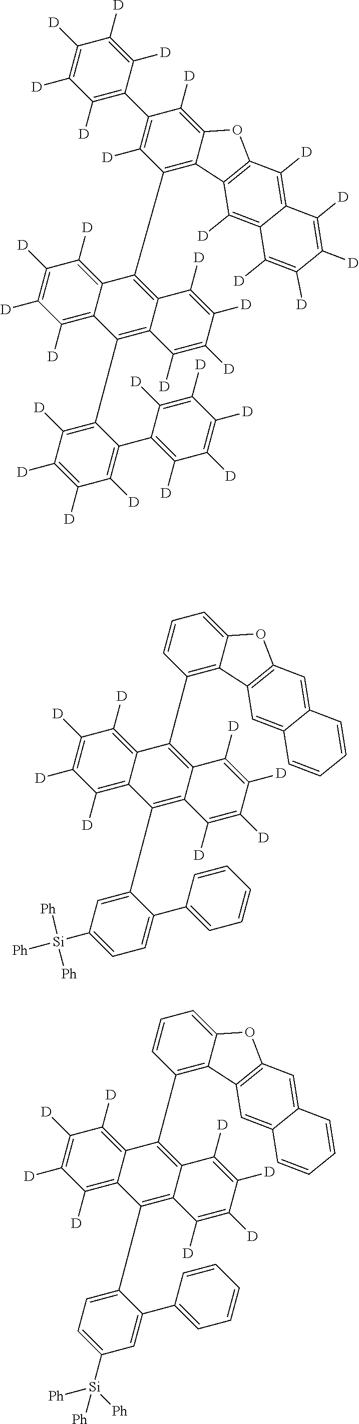

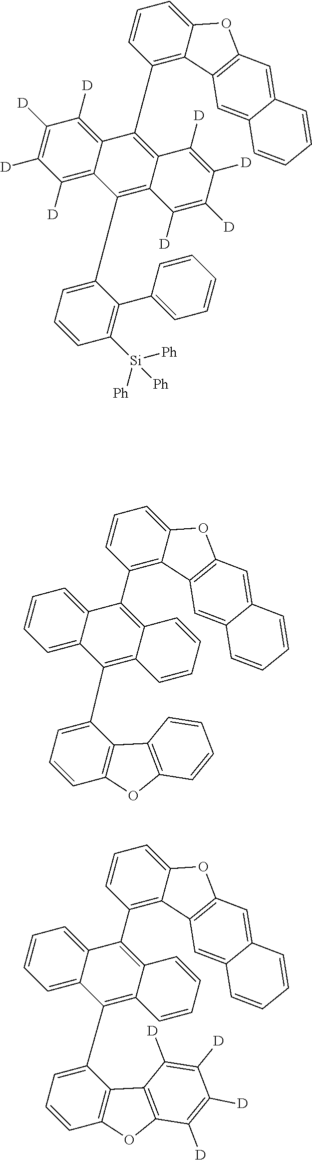 [SMILES: [2H]c1c([2H])c([2H])c2c(-c3cccc4oc5cc6ccccc6cc5c34)c3c([2H])c([2H])c([2H])c([2H])c3c(-c3cccc([Si](c4ccccc4)(c4ccccc4)c4ccccc4)c3-c3ccccc3)c2c1[2H] ; c1ccc2cc3c(cc2c1)oc1cccc(-c2c4ccccc4c(-c4cccc5oc6ccccc6c45)c4ccccc24)c13 ; [2H]c1c([2H])c([2H])c2c(oc3cccc(-c4c5ccccc5c(-c5cccc6oc7cc8ccccc8cc7c56)c5ccccc45)c32)c1[2H]]

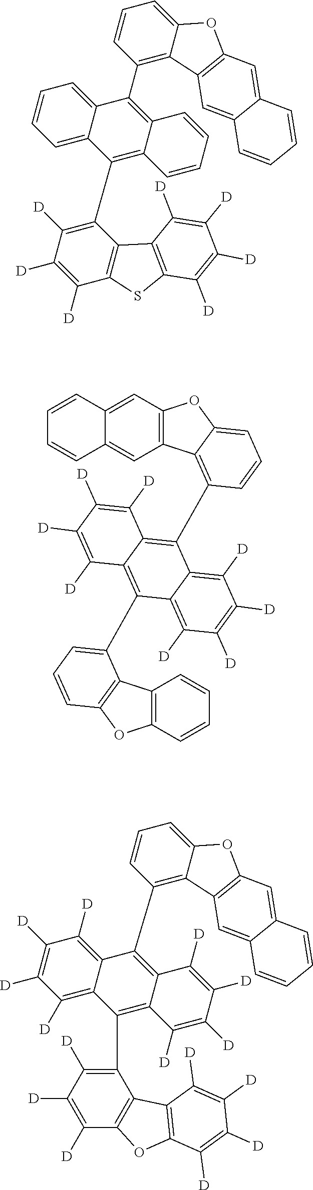 [SMILES: [2H]c1c([2H])c([2H])c2c(sc3c([2H])c([2H])c([2H])c(-c4c5ccccc5c(-c5cccc6oc7cc8ccccc8cc7c56)c5ccccc45)c32)c1[2H] ; [2H]c1c([2H])c([2H])c2c(-c3cccc4oc5cc6ccccc6cc5c34)c3c([2H])c([2H])c([2H])c([2H])c3c(-c3cccc4oc5ccccc5c34)c2c1[2H] ; [2H]c1c([2H])c([2H])c2c(oc3c([2H])c([2H])c([2H])c(-c4c5c([2H])c([2H])c([2H])c([2H])c5c(-c5cccc6oc7cc8ccccc8cc7c56)c5c([2H])c([2H])c([2H])c([2H])c45)c32)c1[2H]]

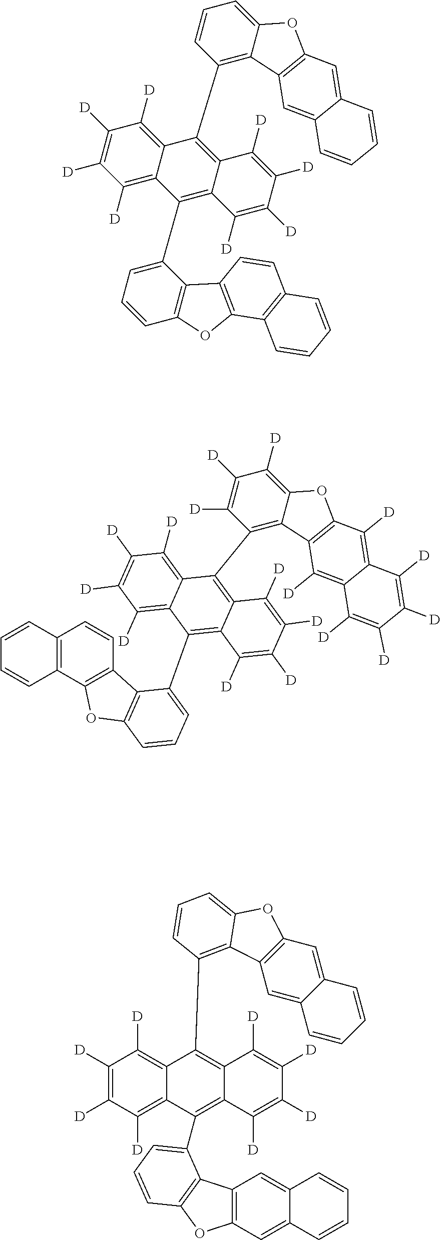 [SMILES: [2H]c1c([2H])c([2H])c2c(-c3cccc4oc5c6ccccc6ccc5c34)c3c([2H])c([2H])c([2H])c([2H])c3c(-c3cccc4oc5cc6ccccc6cc5c34)c2c1[2H] ; [2H]c1c([2H])c(-c2c3c([2H])c([2H])c([2H])c([2H])c3c(-c3cccc4oc5c6ccccc6ccc5c34)c3c([2H])c([2H])c([2H])c([2H])c23)c2c(oc3c([2H])c4c([2H])c([2H])c([2H])c([2H])c4c([2H])c32)c1[2H] ; [2H]c1c([2H])c([2H])c2c(-c3cccc4oc5cc6ccccc6cc5c34)c3c([2H])c([2H])c([2H])c([2H])c3c(-c3cccc4oc5cc6ccccc6cc5c34)c2c1[2H]]

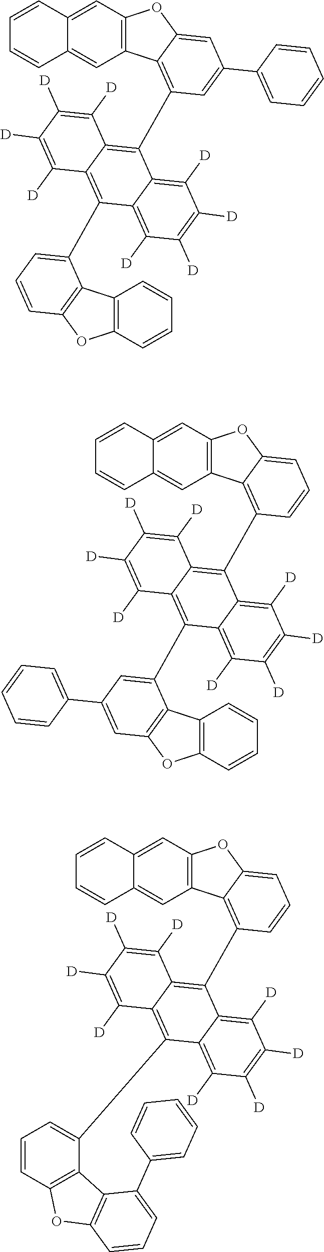 [SMILES: [2H]c1c([2H])c([2H])c2c(-c3cc(-c4ccccc4)cc4oc5cc6ccccc6cc5c34)c3c([2H])c([2H])c([2H])c([2H])c3c(-c3cccc4oc5ccccc5c34)c2c1[2H] ; [2H]c1c([2H])c([2H])c2c(-c3cccc4oc5cc6ccccc6cc5c34)c3c([2H])c([2H])c([2H])c([2H])c3c(-c3cc(-c4ccccc4)cc4oc5ccccc5c34)c2c1[2H] ; [2H]c1c([2H])c([2H])c2c(-c3cccc4oc5cccc(-c6ccccc6)c5c34)c3c([2H])c([2H])c([2H])c([2H])c3c(-c3cccc4oc5cc6ccccc6cc5c34)c2c1[2H]]

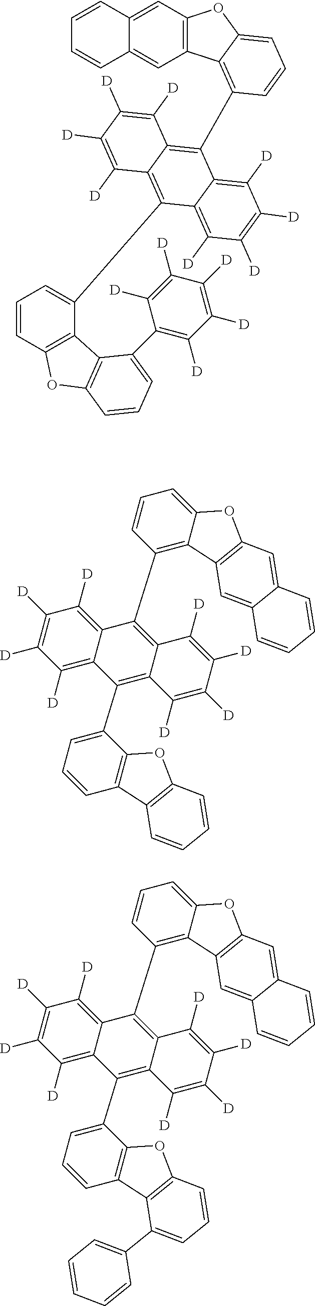

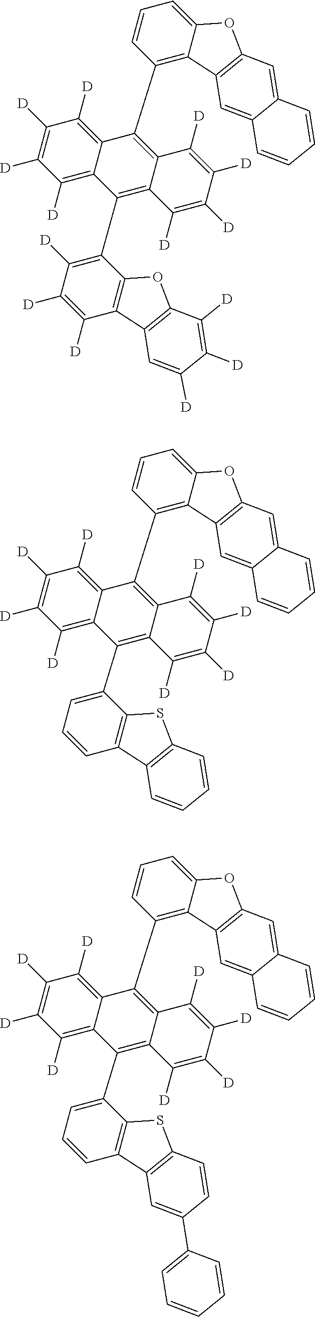

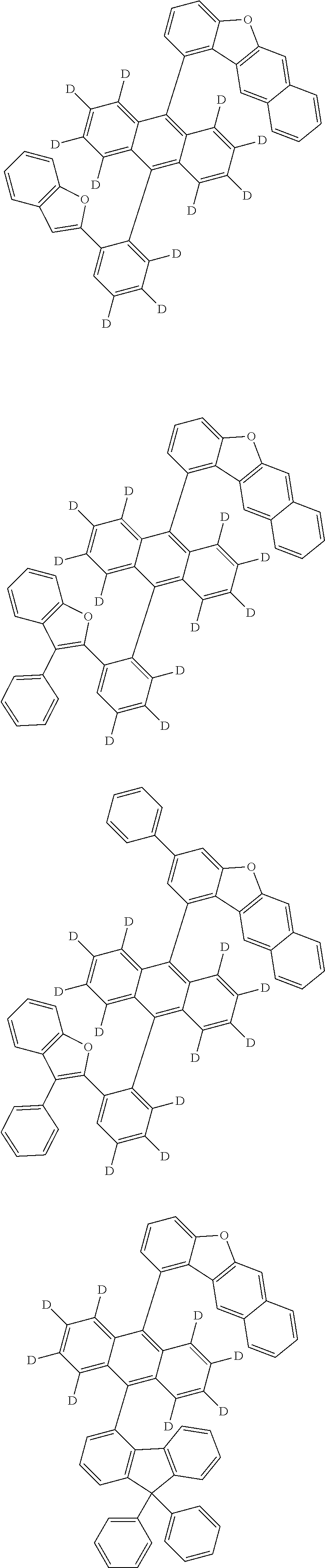

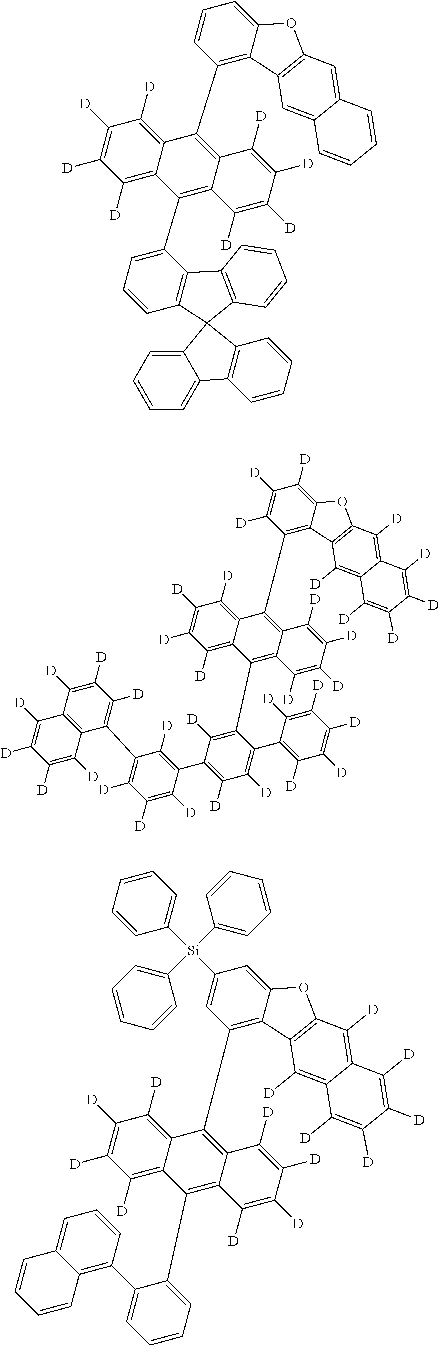

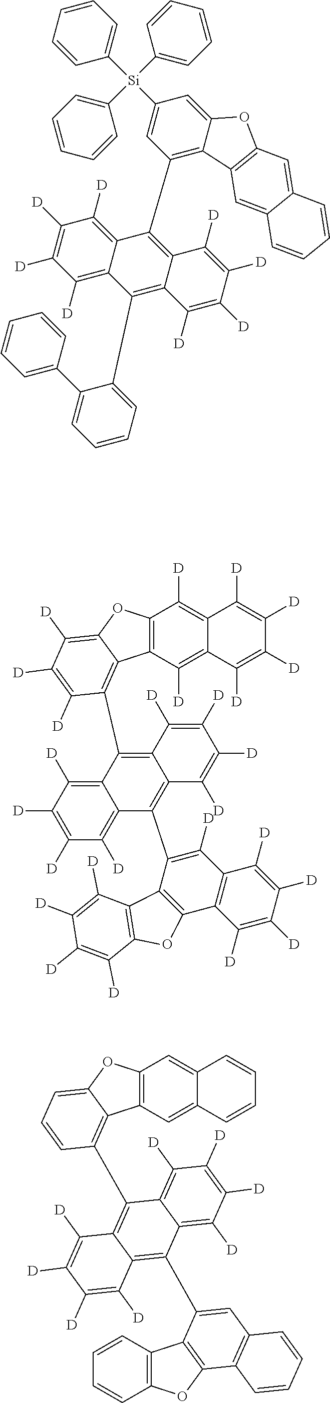

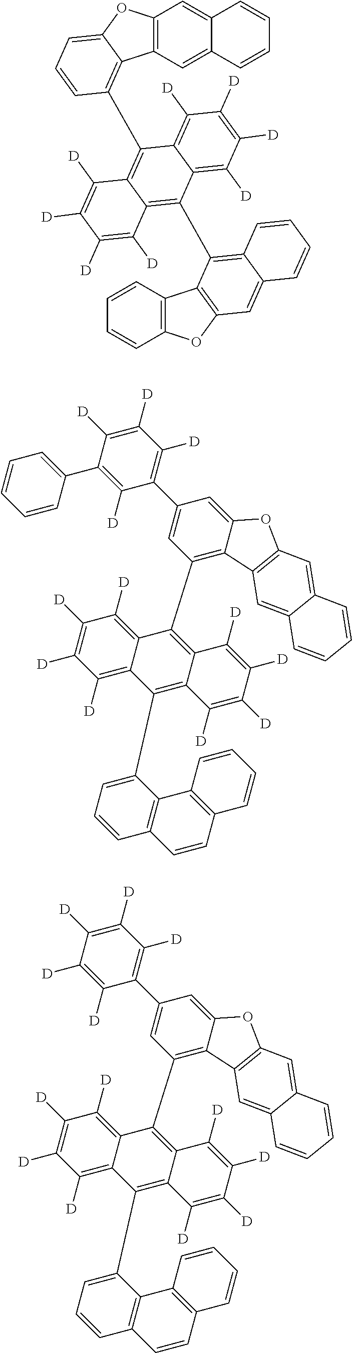 [SMILES: [2H]c1c([2H])c([2H])c2c(-c3c4ccccc4cc4oc5ccccc5c34)c3c([2H])c([2H])c([2H])c([2H])c3c(-c3cccc4oc5cc6ccccc6cc5c34)c2c1[2H] ; [2H]c1c([2H])c(-c2ccccc2)c([2H])c(-c2cc(-c3c4c([2H])c([2H])c([2H])c([2H])c4c(-c4cccc5ccc6ccccc6c45)c4c([2H])c([2H])c([2H])c([2H])c34)c3c(c2)oc2cc4ccccc4cc23)c1[2H] ; [2H]c1c([2H])c([2H])c(-c2cc(-c3c4c([2H])c([2H])c([2H])c([2H])c4c(-c4cccc5ccc6ccccc6c45)c4c([2H])c([2H])c([2H])c([2H])c34)c3c(c2)oc2cc4ccccc4cc23)c([2H])c1[2H]]

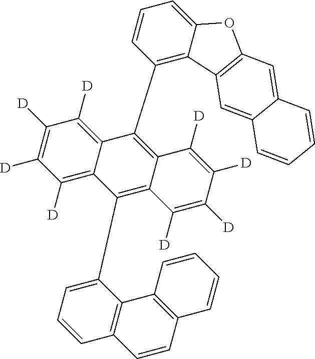 [SMILES: [2H]c1c([2H])c([2H])c2c(-c3cccc4oc5cc6ccccc6cc5c34)c3c([2H])c([2H])c([2H])c([2H])c3c(-c3cccc4ccc5ccccc5c34)c2c1[2H]]

Hereinafter, Chemical Formulae 2 and 3 will be described in detail.

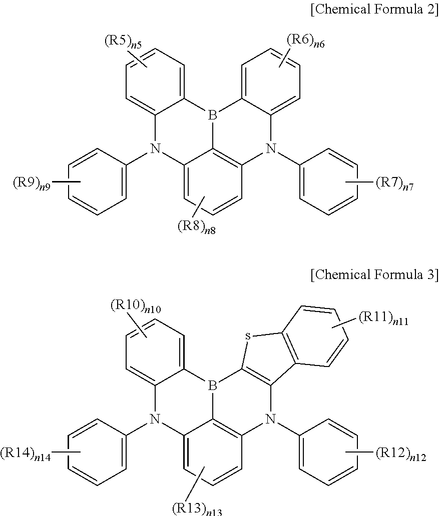

In Chemical Formulae 2 and 3,
R5 to R14 are the same as or different from each other, and are each independently hydrogen; deuterium; a halogen group; a cyano group; a substituted or unsubstituted alkyl group; a substituted or unsubstituted cycloalkyl group; a substituted or unsubstituted silyl group; a substituted or unsubstituted alkenyl group; a substituted or unsubstituted aryl group; a substituted or unsubstituted heterocyclic group; a substituted or unsubstituted alkoxy group; a substituted or unsubstituted aryloxy group; a substituted or unsubstituted alkylthio group; a substituted or unsubstituted arylthio group; or a substituted or unsubstituted amine group, or are bonded to an adjacent substituent to form a substituted or unsubstituted ring,
Chemical Formulae 2 and 3 necessarily include the following Ring A or Ring B,
n5, n6, n10 and n11 are each an integer from 0 to 4,
n8 and n13 are each an integer from 0 to 3,
n7, n9, n12 and n14 are each an integer from 0 to 5,
when n5 to n14 are each 2 or higher, two or more of R5 to R14 are each the same as or different from each other, and

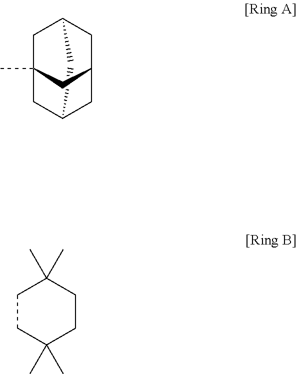

in Rings A and B, the dotted line (---) is a site linked to or condensed to Chemical Formula 2 or 3, and an additional substituent may be linked to or an additional ring may be condensed to Ring A or B.

In an exemplary embodiment of the present specification, R5 to R14 are the same as or different from each other, and are each independently hydrogen; deuterium; a halogen group; a cyano group; a substituted or unsubstituted alkyl group; a substituted or unsubstituted cycloalkyl group; a substituted or unsubstituted silyl group; a substituted or unsubstituted alkenyl group; a substituted or unsubstituted aryl group; a substituted or unsubstituted heterocyclic group; a substituted or unsubstituted alkoxy group; a substituted or unsubstituted aryloxy group; a substituted or unsubstituted alkylthio group; a substituted or unsubstituted arylthio group; or a substituted or unsubstituted amine group, or are bonded to an adjacent substituent to form a substituted or unsubstituted ring.

In an exemplary embodiment of the present specification, R5 to R14 are the same as or different from each other, and are each independently hydrogen; deuterium; a halogen group; a cyano group; a substituted or unsubstituted alkyl group; a substituted or unsubstituted cycloalkyl group; a substituted or unsubstituted silyl group; a substituted or unsubstituted alkenyl group; a substituted or unsubstituted aryl group; a substituted or unsubstituted heterocyclic group; a substituted or unsubstituted alkoxy group; a substituted or unsubstituted aryloxy group; a substituted or unsubstituted alkylthio group; a substituted or unsubstituted arylthio group; or a substituted or unsubstituted amine group, or are bonded to an adjacent substituent to form a substituted or unsubstituted hydrocarbon ring or hetero ring.

In an exemplary embodiment of the present specification, R5 to R14 are the same as or different from each other, and are each independently hydrogen; deuterium; a halogen group; a cyano group; a substituted or unsubstituted alkyl group; a substituted or unsubstituted cycloalkyl group; a substituted or unsubstituted silyl group; a substituted or unsubstituted alkenyl group; a substituted or unsubstituted aryl group; a substituted or unsubstituted heterocyclic group; a substituted or unsubstituted alkoxy group; a substituted or unsubstituted aryloxy group; a substituted or unsubstituted alkylthio group; a substituted or unsubstituted arylthio group; a substituted or unsubstituted amine group; or a substituted or unsubstituted amine group, or a substituted or unsubstituted Ring A, or are bonded to an adjacent substituent to form a substituted or unsubstituted Ring B.

In an exemplary embodiment of the present specification, R5 to R14 are the same as or different from each other, and are each independently hydrogen; deuterium; a halogen group; a cyano group; a substituted or unsubstituted alkyl group having 1 to 60 carbon atoms; a substituted or unsubstituted cycloalkyl group having 3 to 60 carbon atoms; a substituted or unsubstituted silyl group; a substituted or unsubstituted alkenyl group having 2 to 60 carbon atoms; a substituted or unsubstituted aryl group having 6 to 60 carbon atoms; a substituted or unsubstituted heterocyclic group having 2 to 60 carbon atoms; a substituted or unsubstituted alkoxy group having 1 to 60 carbon atoms; a substituted or unsubstituted aryloxy group having 6 to 60 carbon atoms; a substituted or unsubstituted alkylthio group having 1 to 60 carbon atoms; a substituted or unsubstituted arylthio group having 6 to 60 carbon atoms; or a substituted or unsubstituted amine group, or are bonded to an adjacent substituent to form a substituted or unsubstituted ring.

In an exemplary embodiment of the present specification, R5 to R14 are the same as or different from each other, and are each independently hydrogen; deuterium; a halogen group; a cyano group; a substituted or unsubstituted alkyl group having 1 to 30 carbon atoms; a substituted or unsubstituted cycloalkyl group having 3 to 30 carbon atoms; a substituted or unsubstituted silyl group; a substituted or unsubstituted alkenyl group having 2 to 30 carbon atoms; a substituted or unsubstituted aryl group having 6 to 30 carbon atoms; a substituted or unsubstituted heterocyclic group having 2 to 30 carbon atoms; a substituted or unsubstituted alkoxy group having 1 to 30 carbon atoms; a substituted or unsubstituted aryloxy group having 6 to 30 carbon atoms; a substituted or unsubstituted alkylthio group having 1 to 30 carbon atoms; a substituted or unsubstituted arylthio group having 6 to 30 carbon atoms; a substituted or unsubstituted amine group; or a substituted or unsubstituted Ring A, or are bonded to an adjacent substituent to form a substituted or unsubstituted ring having 5 to 30 carbon atoms; or a substituted or unsubstituted Ring B.

In an exemplary embodiment of the present specification, R5 to R14 are the same as or different from each other, and are each independently hydrogen; deuterium; a halogen group; a cyano group; a substituted or unsubstituted alkyl group having 1 to 20 carbon atoms; a substituted or unsubstituted cycloalkyl group having 3 to 20 carbon atoms; a substituted or unsubstituted silyl group; a substituted or unsubstituted alkenyl group having 2 to 20 carbon atoms; a substituted or unsubstituted aryl group having 6 to 20 carbon atoms; a substituted or unsubstituted heterocyclic group having 2 to 20 carbon atoms; a substituted or unsubstituted alkoxy group having 1 to 20 carbon atoms; a substituted or unsubstituted aryloxy group having 6 to 20 carbon atoms; a substituted or unsubstituted alkylthio group having 1 to 20 carbon atoms; a substituted or unsubstituted arylthio group having 6 to 20 carbon atoms; a substituted or unsubstituted amine group; or a substituted or unsubstituted Ring A, or are bonded to an adjacent substituent to form a substituted or unsubstituted ring having 5 to 30 carbon atoms; or a substituted or unsubstituted Ring B.

In an exemplary embodiment of the present specification, R5 to R14 are the same as or different from each other, and are each independently hydrogen; deuterium; a halogen group; a cyano group; a substituted or unsubstituted alkyl group having 1 to 10 carbon atoms; a substituted or unsubstituted cycloalkyl group having 3 to 18 carbon atoms; a substituted or unsubstituted silyl group; a substituted or unsubstituted alkenyl group having 2 to 10 carbon atoms; a substituted or unsubstituted aryl group having 6 to 18 carbon atoms; a substituted or unsubstituted heterocyclic group having 2 to 18 carbon atoms; a substituted or unsubstituted alkoxy group having 1 to 10 carbon atoms; a substituted or unsubstituted aryloxy group having 6 to 18 carbon atoms; a substituted or unsubstituted alkylthio group having 1 to 10 carbon atoms; a substituted or unsubstituted arylthio group having 6 to 18 carbon atoms; a substituted or unsubstituted amine group; or a substituted or unsubstituted Ring A, or are bonded to an adjacent substituent to form a substituted or unsubstituted ring having 5 to 20 carbon atoms; or a substituted or unsubstituted Ring B.

In an exemplary embodiment of the present specification, R5 to R14 are the same as or different from each other, and are each independently hydrogen; deuterium; a halogen group; a cyano group; a substituted or unsubstituted alkyl group having 1 to 10 carbon atoms; a substituted or unsubstituted cycloalkyl group having 3 to 18 carbon atoms; a substituted or unsubstituted silyl group; a substituted or unsubstituted alkenyl group having 2 to 10 carbon atoms; a substituted or unsubstituted aryl group having 6 to 18 carbon atoms; a substituted or unsubstituted heterocyclic group having 2 to 18 carbon atoms; a substituted or unsubstituted alkoxy group having 1 to 10 carbon atoms; a substituted or unsubstituted aryloxy group having 6 to 18 carbon atoms; a substituted or unsubstituted alkylthio group having 1 to 10 carbon atoms; a substituted or unsubstituted arylthio group having 6 to 18 carbon atoms; a substituted or unsubstituted amine group; or a substituted or unsubstituted Ring A, or are bonded to an adjacent substituent to form a substituted or unsubstituted Ring B.

In an exemplary embodiment of the present specification, n5, n6, n8, n10, n11 and n13 are each an integer from 0 to 4, n8 and n13 are each an integer from 0 to 3, n7, n9, n12 and n14 are each an integer from 0 to 5, and when n5 to n14 are each 2 or higher, two or more of R5 to R14 are each the same as or different from each other.

In an exemplary embodiment of the present specification, Chemical Formulae 2 and 3 necessarily include the following Ring A or Ring B.

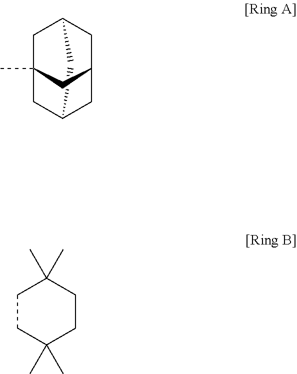

In Rings A and B, the dotted line (---) is a site linked to or condensed to Chemical Formula 2 or 3, and an additional substituent may be linked to or an additional ring may be condensed to Ring A or B.

In an exemplary embodiment of the present specification, an additional ring may be condensed to Ring B. The additional ring may be an aromatic hydrocarbon ring, specifically an aromatic hydrocarbon ring having 6 to 30 carbon atoms, and more specifically a benzene ring.

In an exemplary embodiment of the present specification, Chemical Formulae 2 and 3 necessarily include Ring A and Ring B.

In an exemplary embodiment of the present specification, Chemical Formulae 2 and 3 include two or more Ring A's or Ring B's.

In an exemplary embodiment of the present specification, at least one of R5 to R9 includes a substituent represented by Ring A.

In an exemplary embodiment of the present specification, at least one of R5, R6, R7 and R9 includes a substituent represented by Ring A.

In an exemplary embodiment of the present specification, at least one of R10, R11, R12 and R14 includes a substituent represented by Ring A.

In an exemplary embodiment of the present specification, at least one of R10 to R14 includes a substituent represented by Ring A.

In an exemplary embodiment of the present specification, when Chemical Formula 2 or Chemical Formula 3 has a structure in which Ring B is condensed to a ring including a double bond, Ring B may be represented by the following ring B-1, and the following * means a position where Ring B-1 is condensed to a ring including a double bond.

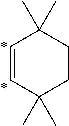

In Ring B-1, the * means a position where Formula C is condensed.

In an exemplary embodiment of the present specification, in Chemical Formula 2 or Chemical Formula 3, Ring B may be condensed to a benzene ring.

In an exemplary embodiment of the present specification, Chemical Formula 2 or Chemical Formula 3 may include at least one of a structure represented by the following Formula D-1 or a structure represented by the following Formula D-2.

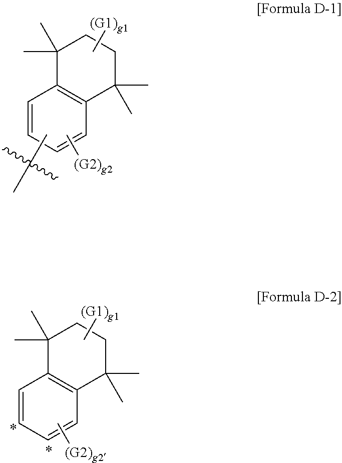

In Formulae D-1 and D-2,
G1 and G2 are the same as or different from each other, and are each independently hydrogen; deuterium; a halogen group; a cyano group; a substituted or unsubstituted alkyl group; a substituted or unsubstituted cycloalkyl group; a substituted or unsubstituted silyl group; a substituted or unsubstituted alkenyl group; a substituted or unsubstituted aryl group; a substituted or unsubstituted heterocyclic group; a substituted or unsubstituted alkoxy group; a substituted or unsubstituted aryloxy group; a substituted or unsubstituted alkylthio group; a substituted or unsubstituted arylthio group; or a substituted or unsubstituted amine group, or are bonded to an adjacent substituent to form a substituted or unsubstituted ring,
g1 is an integer from 0 to 4, and when g1 is 2 or higher, two or more G1's are the same as or different from each other,
g2 is an integer from 0 to 3, and when g2 is 2 or higher, two or more G2's are the same as or different from each other,
g2′ is an integer from 0 to 2, and when g2′ is 2, two G2's are the same as or different from each other,
the

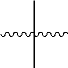

means a position linked to Chemical Formula 2 or 3, and
the * means a position condensed to Chemical Formula 2 or 3.

In an exemplary embodiment of the present specification, Chemical Formula 2 or Chemical Formula 3 may include at least two of a structure represented by the following Formula D-1 or a structure represented by the following Formula D-2.

In an exemplary embodiment of the present specification, Chemical Formula 2 or Chemical Formula 3 may include at least three of a structure represented by the following Formula D-1 or a structure represented by the following Formula D-2.

In an exemplary embodiment of the present specification, Chemical Formula 2 or Chemical Formula 3 may include at least four of a structure represented by the following Formula D-1 or a structure represented by the following Formula D-2.

In an exemplary embodiment of the present specification, Chemical Formula 2 or Chemical Formula 3 may include at least five of a structure represented by the following Formula D-1 or a structure represented by the following Formula D-2.

In an exemplary embodiment of the present specification, Chemical Formula 2 or Chemical Formula 3 may include at least six of a structure of the following Formula D-1 or a structure of the following Formula D-2.

In an exemplary embodiment of the present specification, at least one of R5, R6, R7 and R9 is bonded to an adjacent substituent to form a ring represented by the following Formula C.

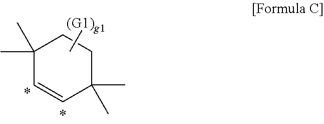

In Formula C,
G1 is hydrogen; deuterium; a halogen group; a cyano group; a substituted or unsubstituted alkyl group; a substituted or unsubstituted cycloalkyl group; a substituted or unsubstituted silyl group; a substituted or unsubstituted alkenyl group; a substituted or unsubstituted aryl group; a substituted or unsubstituted heterocyclic group; a substituted or unsubstituted alkoxy group; a substituted or unsubstituted aryloxy group; a substituted or unsubstituted alkylthio group; a substituted or unsubstituted arylthio group; or a substituted or unsubstituted amine group, or are bonded to an adjacent substituent to form a substituted or unsubstituted ring,
g1 is an integer from 0 to 4, and when g1 is 2 or higher, two or more G1's are the same as or different from each other, and
the * means a position where Formula C is condensed.

In an exemplary embodiment of the present specification, at least one of R10, R11, R12 and R14 is bonded to an adjacent substituent to form the ring represented by Formula C.

In an exemplary embodiment of the present specification, at least one of R5 to R9 includes an adamantyl group.

In an exemplary embodiment of the present specification, at least two of R5 to R9 include an adamantyl group.

In an exemplary embodiment of the present specification, at least one of R5, R6, R7 and R9 includes an adamantyl group.

In an exemplary embodiment of the present specification, at least two of R5, R6, R7 and R9 includes an adamantyl group.

In an exemplary embodiment of the present specification, at least one of R10 to R14 includes an adamantyl group.

In an exemplary embodiment of the present specification, at least two of R10 to R14 include an adamantyl group.

In an exemplary embodiment of the present specification, at least one of R10, R11, R12 and R14 includes an adamantyl group.

In an exemplary embodiment of the present specification, at least two of R10, R11, R12 and R14 includes an adamantyl group.

In an exemplary embodiment of the present specification, Chemical Formula 2 is the following Chemical Formula 2-A or 2-B.

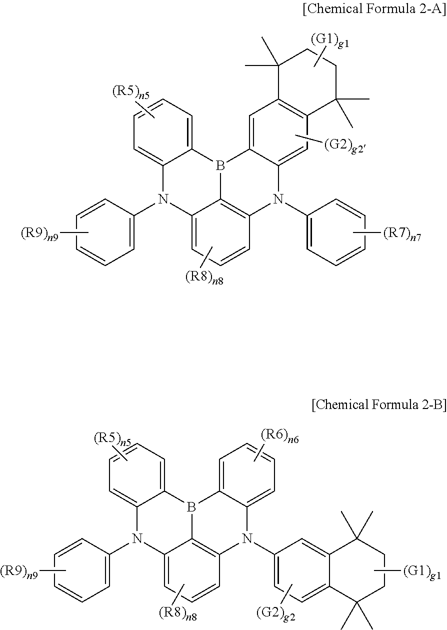

In Chemical Formula 2-A or 2-B,
the definitions of R5 to R8 and n5 to n8 are the same as the definitions in Chemical Formula 2,
G1 and G2 are the same as or different from each other, and are each independently hydrogen; deuterium; a halogen group; a cyano group; a substituted or unsubstituted alkyl group; a substituted or unsubstituted cycloalkyl group; a substituted or unsubstituted silyl group; a substituted or unsubstituted alkenyl group; a substituted or unsubstituted aryl group; a substituted or unsubstituted heterocyclic group; a substituted or unsubstituted alkoxy group; a substituted or unsubstituted aryloxy group; a substituted or unsubstituted alkylthio group; a substituted or unsubstituted arylthio group; or a substituted or unsubstituted amine group, or are bonded to an adjacent substituent to form a substituted or unsubstituted ring,
g1 is an integer from 0 to 4, and when g1 is 2 or higher, two or more G1's are the same as or different from each other,
g2 is an integer from 0 to 3, and when g2 is 2 or higher, two or more G2's are the same as or different from each other, and
g2′ is an integer from 0 to 2, and when g2′ is 2, two G2's are the same as or different from each other.

In an exemplary embodiment of the present specification, Chemical Formula 3 is the following Chemical Formula 3-A or 3-B.

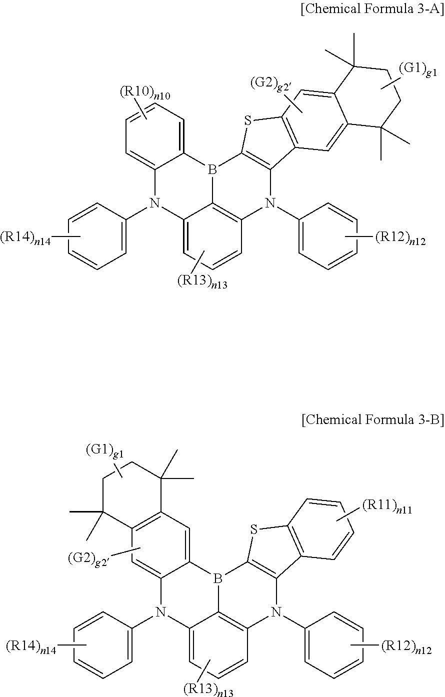

In Chemical Formulae 3-A and 3-B,
the definitions of R10 to R14 and n10 to n14 are the same as the definitions in Chemical Formula 3,
G1 and G2 are the same as or different from each other, and are each independently hydrogen; deuterium; a halogen group; a cyano group; a substituted or unsubstituted alkyl group; a substituted or unsubstituted cycloalkyl group; a substituted or unsubstituted silyl group; a substituted or unsubstituted alkenyl group; a substituted or unsubstituted aryl group; a substituted or unsubstituted heterocyclic group; a substituted or unsubstituted alkoxy group; a substituted or unsubstituted aryloxy group; a substituted or unsubstituted alkylthio group; a substituted or unsubstituted arylthio group; or a substituted or unsubstituted amine group, or are bonded to an adjacent substituent to form a substituted or unsubstituted ring,
g1 is an integer from 0 to 4, and when g1 is 2 or higher, two or more G1's are the same as or different from each other, and
g2′ is an integer from 0 to 2, and when g2′ is 2, two G2's are the same as or different from each other.

In an exemplary embodiment of the present specification, R5 to R14 are the same as or different from each other, and are each independently hydrogen; deuterium; a halogen group; a cyano group; a substituted or unsubstituted silyl group; a substituted or unsubstituted alkoxy group; a substituted or unsubstituted alkylthio group; a substituted or unsubstituted aryloxy group; a substituted or unsubstituted arylthio group; a substituted or unsubstituted alkyl group; a substituted or unsubstituted cycloalkyl group; a substituted or unsubstituted aryl group; or a substituted or unsubstituted heterocyclic group, or may be bonded to an adjacent substituent to form a substituted or unsubstituted aliphatic hydrocarbon ring; a substituted or unsubstituted aromatic hydrocarbon ring; a substituted or unsubstituted hetero ring; or a condensed ring of a substituted or unsubstituted aromatic hydrocarbon ring and an aliphatic hydrocarbon ring.

In an exemplary embodiment of the present specification, R5 to R14 are the same as or different from each other, and are each independently hydrogen; deuterium; a halogen group; a cyano group; a substituted or unsubstituted silyl group; a substituted or unsubstituted C1-C60 alkoxy group; a substituted or unsubstituted C1-C60 alkylthio group; a substituted or unsubstituted C6-C60 aryloxy group; a substituted or unsubstituted C6-C60 arylthio group; a substituted or unsubstituted C1-C60 alkyl group; a substituted or unsubstituted C3-C60 cycloalkyl group; a substituted or unsubstituted C6-C60 aryl group; or a substituted or unsubstituted C2-C60 heterocyclic group, or may be bonded to an adjacent substituent to form a substituted or unsubstituted C3-C60 aliphatic hydrocarbon ring; a substituted or unsubstituted C6-C30 aromatic hydrocarbon ring; a substituted or unsubstituted C2-C60 hetero ring; or a condensed ring of a substituted or unsubstituted C6-C60 aromatic hydrocarbon ring and a C3-C60 aliphatic hydrocarbon ring.

In an exemplary embodiment of the present specification, R5 to R14 are the same as or different from each other, and are each independently hydrogen; deuterium; a halogen group; a cyano group; a substituted or unsubstituted silyl group; a substituted or unsubstituted C1-C30 alkoxy group; a substituted or unsubstituted C1-C30 alkylthio group; a substituted or unsubstituted C6-C30 aryloxy group; a substituted or unsubstituted C6-C30 arylthio group; a substituted or unsubstituted C1-C30 alkyl group; a substituted or unsubstituted C3-C30 cycloalkyl group; a substituted or unsubstituted C6-C30 aryl group; or a substituted or unsubstituted C2-C30 heterocyclic group, or may be bonded to an adjacent substituent to form a substituted or unsubstituted C3-C30 aliphatic hydrocarbon ring; a substituted or unsubstituted C6-C30 aromatic hydrocarbon ring; a substituted or unsubstituted C2-C30 hetero ring; or a condensed ring of a substituted or unsubstituted C6-C30 aromatic hydrocarbon ring and a C3-C30 aliphatic hydrocarbon ring.

In an exemplary embodiment of the present specification, R5 to R14 are the same as or different from each other, and are each independently hydrogen; deuterium; —F; a cyano group; a substituted or unsubstituted silyl group; a substituted or unsubstituted methyl group; a substituted or unsubstituted ethyl group; a substituted or unsubstituted propyl group; a substituted or unsubstituted butyl group; a substituted or unsubstituted cyclopentyl group; a substituted or unsubstituted cyclohexyl group; a substituted or unsubstituted adamantyl group; a substituted or unsubstituted phenyl group; a substituted or unsubstituted biphenyl group; a substituted or unsubstituted terphenyl group; a substituted or unsubstituted naphthyl group; a substituted or unsubstituted fluorenyl group; a substituted or unsubstituted tetrahydronaphthalene group; a substituted or unsubstituted dibenzofuran group; a substituted or unsubstituted dibenzothiophene group; a substituted or unsubstituted carbazole group; a substituted or unsubstituted hexahydrocarbazole group; a hexahydrocarbazole group to which a substituted or unsubstituted cyclohexene is condensed; a hexahydrocarbazole group to which a substituted or unsubstituted benzene is condensed; a substituted or unsubstituted phenoxazine group

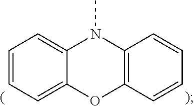

a substituted or unsubstituted phenothiazine group

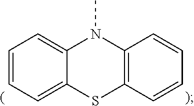

a substituted or unsubstituted amine group; a substituted or unsubstituted dihydroacridine group

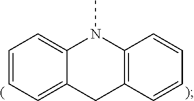

a substituted or unsubstituted dihydrodibenzoazasiline group

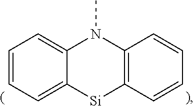

or are bonded to an adjacent substituent to form a substituted or unsubstituted cyclohexene ring; a substituted or unsubstituted tetrahydronaphthalene ring; a substituted or unsubstituted benzene ring; a substituted or unsubstituted benzenofuran ring; a substituted or unsubstituted naphthofuran ring; a substituted or unsubstituted benzothiophene ring; a substituted or unsubstituted naphthothiophene ring; a substituted or unsubstituted benzosilole ring; a substituted or unsubstituted indene ring; a substituted or unsubstituted spiro[fluorene-9,1′-indene]ring or a substituted or unsubstituted benzopyran ring.

In an exemplary embodiment of the present specification, R5 to R14 are the same as or different from each other, and are each independently hydrogen; deuterium; a substituted or unsubstituted methyl group; a substituted or unsubstituted butyl group; a substituted or unsubstituted cyclohexyl group; a substituted or unsubstituted adamantyl group; a substituted or unsubstituted phenyl group; a substituted or unsubstituted biphenyl group; a substituted or unsubstituted terphenyl group; a substituted or unsubstituted naphthyl group; or a substituted or unsubstituted tetrahydronaphthalene group, or are bonded to an adjacent substituent to form a substituted or unsubstituted cyclohexene ring.

In an exemplary embodiment of the present specification, R5 to R14 are the same as or different from each other, and are each independently hydrogen; deuterium; a methyl group; a t-butyl group; an adamantyl group; or a phenyl group that is unsubstituted or substituted with an alkyl group or a cycloalkyl group, or are bonded to an adjacent substituent to form a cyclohexene ring that is unsubstituted or substituted with an alkyl group.

In an exemplary embodiment of the present specification, R5 to R14 are the same as or different from each other, and are each independently hydrogen; deuterium; a methyl group; a t-butyl group; an adamantyl group; or a phenyl group that is unsubstituted or substituted with a methyl group, t-butyl or an adamantyl group, or are bonded to an adjacent substituent to form a cyclohexene ring substituted with a methyl group.

In an exemplary embodiment of the present specification, R5 to R14 are the same as or different from each other, and are each independently unsubstituted or substituted with one or more groups selected from the group consisting of deuterium; a halogen group; a cyano group; a silyl group; an alkyl group; a cycloalkyl group; an aryl group; and a heterocyclic group having 2 to 30 carbon atoms or a group in which two or more selected from the above group are linked together.

In an exemplary embodiment of the present specification, R5 to R14 are the same as or different from each other, and are each independently unsubstituted or substituted with one or more groups selected from the group consisting of deuterium; a halogen group; a cyano group; a silyl group; an alkyl group having 1 to 30 carbon atoms; a cycloalkyl group having 3 to 30 carbon atoms; an aryl group having 6 to 30 carbon atoms; and a heterocyclic group having 2 to 30 carbon atoms and containing O, S, Si or N or a group in which two or more selected from the above group are linked together.

In an exemplary embodiment of the present specification, R5 to R14 are the same as or different from each other, and are each independently unsubstituted or substituted with one or more groups selected from the group consisting of deuterium; —F; a cyano group; a silyl group; a methyl group; an ethyl group; a propyl group; a butyl group; a cyclopentyl group; a cyclohexyl group; an adamantyl group; a phenyl group; a biphenyl group; a terphenyl group; a naphthyl group; a fluorenyl group; a tetrahydronaphthalene group; a dibenzofuran group; a dibenzothiophene group; a carbazole group; a hexahydrocarbazole group; a hexahydrocarbazole group to which cyclohexene is condensed; a hexahydrocarbazole group to which benzene is condensed; a phenoxazine group; a phenothiazine group; an amine group; a dihydroacridine group; and a dihydrodibenzoazasiline group or a group in which two or more selected from the above group are linked together.

In an exemplary embodiment of the present specification, R5 to R14 are the same as or different from each other, and are each independently unsubstituted or substituted with one or more groups selected from the group consisting of deuterium; —F; a cyano group; a silyl group; a methyl group; an ethyl group; a propyl group; a butyl group; a cyclohexyl group; an adamantyl group; a phenyl group; a biphenyl group; a terphenyl group; a naphthyl group; a fluorenyl group; a tetrahydronaphthalene group; and an amine group or a group in which two or more selected from the above group are linked together.

In an exemplary embodiment of the present specification, R5 to R14 are the same as or different from each other, and are each independently unsubstituted or substituted with one or more groups selected from the group consisting of deuterium; —F; a cyano group; a silyl group; a methyl group; an ethyl group; an i-propyl group; a t-butyl group; a cyclohexyl group; an adamantyl group; a phenyl group; a biphenyl group; a terphenyl group; a naphthyl group; a tetrahydronaphthalene group; and an amine group or a group in which two or more selected from the above group are linked together.

In an exemplary embodiment of the present specification, G1 and G2 are the same as or different from each other, and are each independently hydrogen; deuterium; a halogen group; a cyano group; a substituted or unsubstituted silyl group; a substituted or unsubstituted alkoxy group; a substituted or unsubstituted alkylthio group; a substituted or unsubstituted aryloxy group; a substituted or unsubstituted arylthio group; a substituted or unsubstituted alkyl group; a substituted or unsubstituted cycloalkyl group; a substituted or unsubstituted aryl group; or a substituted or unsubstituted heterocyclic group, or may be bonded to an adjacent substituent to form a substituted or unsubstituted aliphatic hydrocarbon ring; a substituted or unsubstituted aromatic hydrocarbon ring; a substituted or unsubstituted hetero ring; or a condensed ring of a substituted or unsubstituted aromatic hydrocarbon ring and an aliphatic hydrocarbon ring.

In an exemplary embodiment of the present specification, G1 and G2 are the same as or different from each other, and are each independently hydrogen; deuterium; a halogen group; a cyano group; a substituted or unsubstituted silyl group; a substituted or unsubstituted C1-C60 alkyl group; a substituted or unsubstituted C3-C60 cycloalkyl group; a substituted or unsubstituted C6-C60 aryl group; or a substituted or unsubstituted C2-C60 heterocyclic group, or may be bonded to an adjacent substituent to form a substituted or unsubstituted C3-C60 aliphatic hydrocarbon ring; a substituted or unsubstituted C6-C30 aromatic hydrocarbon ring; a substituted or unsubstituted C2-C60 hetero ring; or a condensed ring of a substituted or unsubstituted C6-C60 aromatic hydrocarbon ring and a C3-C60 aliphatic hydrocarbon ring.

In an exemplary embodiment of the present specification, G1 and G2 are the same as or different from each other, and are each independently hydrogen; deuterium; a halogen group; a cyano group; a substituted or unsubstituted silyl group; a substituted or unsubstituted C1-C30 alkyl group; a substituted or unsubstituted C3-C30 cycloalkyl group; a substituted or unsubstituted C6-C30 aryl group; or a substituted or unsubstituted C2-C30 heterocyclic group, or may be bonded to an adjacent substituent to form a substituted or unsubstituted C3-C30 aliphatic hydrocarbon ring; a substituted or unsubstituted C6-C30 aromatic hydrocarbon ring; a substituted or unsubstituted C2-C30 hetero ring; or a condensed ring of a substituted or unsubstituted C6-C30 aromatic hydrocarbon ring and a C3-C30 aliphatic hydrocarbon ring.

In an exemplary embodiment of the present specification, G1 and G2 are the same as or different from each other, and are each independently hydrogen; deuterium; —F; a cyano group; a substituted or unsubstituted silyl group; a substituted or unsubstituted methyl group; a substituted or unsubstituted ethyl group; a substituted or unsubstituted propyl group; a substituted or unsubstituted butyl group; a substituted or unsubstituted cyclopentyl group; a substituted or unsubstituted cyclohexyl group; a substituted or unsubstituted adamantyl group; a substituted or unsubstituted phenyl group; a substituted or unsubstituted biphenyl group; a substituted or unsubstituted terphenyl group; a substituted or unsubstituted naphthyl group; a substituted or unsubstituted fluorenyl group; a substituted or unsubstituted tetrahydronaphthalene group; a substituted or unsubstituted dibenzofuran group; a substituted or unsubstituted dibenzothiophene group; a substituted or unsubstituted carbazole group; a substituted or unsubstituted hexahydrocarbazole group; a hexahydrocarbazole group to which a substituted or unsubstituted cyclohexene is condensed; a hexahydrocarbazole group to which a substituted or unsubstituted benzene is condensed; a substituted or unsubstituted phenoxazine group

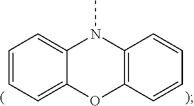

a substituted or unsubstituted phenothiazine group

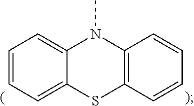

a substituted or unsubstituted amine group; a substituted or unsubstituted dihydroacridine group

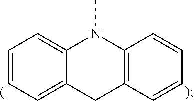

a substituted or unsubstituted dihydrodibenzoazasiline group

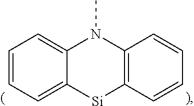

or are bonded to an adjacent substituent to form a substituted or unsubstituted cyclohexene ring; a substituted or unsubstituted tetrahydronaphthalene ring; a substituted or unsubstituted benzene ring; a substituted or unsubstituted benzenofuran ring; a substituted or unsubstituted naphthofuran ring; a substituted or unsubstituted benzothiophene ring; a substituted or unsubstituted naphthothiophene ring; a substituted or unsubstituted benzosilole ring; a substituted or unsubstituted indene ring; a substituted or unsubstituted spiro[fluorene-9,1′-indene]ring or a substituted or unsubstituted benzopyran ring.

In an exemplary embodiment of the present specification, G1 and G2 are the same as or different from each other, and are each independently hydrogen; deuterium; a methyl group; or a phenyl group that is unsubstituted or substituted with a t-butyl group.

In an exemplary embodiment of the present specification, G1 and G2 are the same as or different from each other, and are each independently unsubstituted or substituted with one or more groups selected from the group consisting of deuterium; a halogen group; a cyano group; a silyl group; an alkyl group; a cycloalkyl group; an aryl group; and a heterocyclic group having 2 to 30 carbon atoms or a group in which two or more selected from the above group are linked together.

In an exemplary embodiment of the present specification, R5 and R14 are the same as or different from each other, and are each independently unsubstituted or substituted with one or more groups selected from the group consisting of deuterium; a halogen group; a cyano group; a silyl group; an alkyl group having 1 to 30 carbon atoms; a cycloalkyl group having 3 to 30 carbon atoms; an aryl group having 6 to 30 carbon atoms; and a heterocyclic group having 2 to 30 carbon atoms and containing O, S, Si or N or a group in which two or more selected from the above group are linked together.

In an exemplary embodiment of the present specification, G1 and G2 are the same as or different from each other, and are each independently unsubstituted or substituted with one or more groups selected from the group consisting of deuterium; —F; a cyano group; a silyl group; a methyl group; an ethyl group; a propyl group; a butyl group; a cyclopentyl group; a cyclohexyl group; an adamantyl group; a phenyl group; a biphenyl group; a terphenyl group; a naphthyl group; a fluorenyl group; a tetrahydronaphthalene group; a dibenzofuran group; a dibenzothiophene group; a carbazole group; a hexahydrocarbazole group; a hexahydrocarbazole group to which cyclohexene is condensed; a hexahydrocarbazole group to which benzene is condensed; a phenoxazine group; a phenothiazine group; an amine group; a dihydroacridine group; and a dihydrodibenzoazasiline group or a group in which two or more selected from the above group are linked together.

In an exemplary embodiment of the present specification, G1 and G2 are the same as or different from each other, and are each independently unsubstituted or substituted with one or more groups selected from the group consisting of deuterium; —F; a cyano group; a silyl group; a methyl group; an ethyl group; a propyl group; a butyl group; a cyclohexyl group; an adamantyl group; a phenyl group; a biphenyl group; a terphenyl group; a naphthyl group; a fluorenyl group; a tetrahydronaphthalene group; and an amine group or a group in which two or more selected from the above group are linked together.

In an exemplary embodiment of the present specification, G1 and G2 are the same as or different from each other, and are each independently unsubstituted or substituted with one or more groups selected from the group consisting of deuterium; —F; a cyano group; a silyl group; a methyl group; an ethyl group; an i-propyl group; a t-butyl group; a cyclohexyl group; an adamantyl group; a phenyl group; a biphenyl group; a terphenyl group; a naphthyl group; a tetrahydronaphthalene group; and an amine group or a group in which two or more selected from the above group are linked together.

In an exemplary embodiment of the present specification, R8 and R13 are the same as or different from each other, and are each independently any one of the following Chemical Formulae 1-B-1 to 1-B-4.

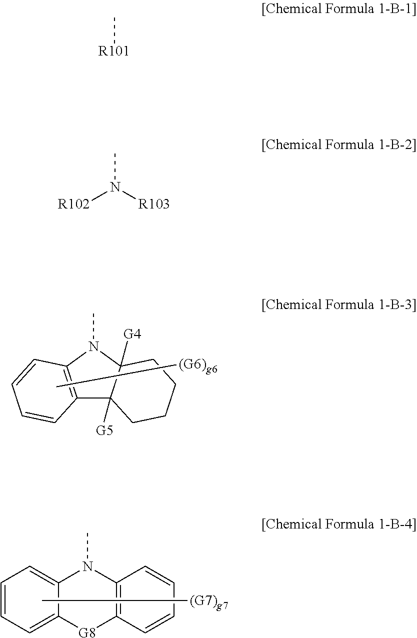

In Chemical Formulae 1-B-1 to 1-B-4,
G8 is a direct bond; —O—; —S—; —CG9G10-; or —SiG9G10-,
R101 to R103 and G4 to G7 are the same as or different from each other, and are each independently hydrogen; deuterium; a cyano group; a halogen group; a substituted or unsubstituted alkyl group; a substituted or unsubstituted alkoxy group; a substituted or unsubstituted alkylthio group; a substituted or unsubstituted cycloalkyl group; a substituted or unsubstituted silyl group; a substituted or unsubstituted aryl group; a substituted or unsubstituted aryloxy group; a substituted or unsubstituted arylthio group; a substituted or unsubstituted heterocyclic group; or a substituted or unsubstituted amine group, or are bonded to an adjacent substituent to form a substituted or unsubstituted ring,
G9 and G10 are the same as or different from each other, and are each independently hydrogen; deuterium; a substituted or unsubstituted alkyl group; or a substituted or unsubstituted aryl group, or are bonded to an adjacent substituent to form a substituted or unsubstituted ring,
g6 is an integer from 0 to 12, and g7 is an integer from 0 to 8,
when g6 and g7 are each 2 or higher, substituents in the parenthesis are the same as or different from each other, and
the dotted line means a position bonded to Chemical Formula 1.

In an exemplary embodiment of the present specification, G8 is a direct bond.

In an exemplary embodiment of the present specification, G8 is —O—; or —S—.

In an exemplary embodiment of the present specification, G8 is —CG9G10-; or —SiG9G10-.

In an exemplary embodiment of the present specification, G9 and G10 are the same as or different from each other, and are each independently hydrogen; deuterium; a substituted or unsubstituted alkyl group; or a substituted or unsubstituted aryl group.

In an exemplary embodiment of the present specification, G9 and G10 are the same as or different from each other, and are each independently a substituted or unsubstituted C1-C10 alkyl group; or a substituted or unsubstituted C6-C30 aryl group.

In an exemplary embodiment of the present specification, G9 and G10 are the same as or different from each other, and are each independently a substituted or unsubstituted methyl group; or a substituted or unsubstituted phenyl group.

In an exemplary embodiment of the present specification, G9 and G10 are the same as or different from each other, and are each independently a methyl group; or a phenyl group.

In an exemplary embodiment of the present specification, R101 to R103 and G4 to G7 are the same as or different from each other, and are each independently hydrogen; deuterium; a substituted or unsubstituted alkyl group; a substituted or unsubstituted cycloalkyl group; a substituted or unsubstituted silyl group; a substituted or unsubstituted aryl group; or a substituted or unsubstituted heterocyclic group, or are bonded to an adjacent substituent to form a substituted or unsubstituted ring.

In an exemplary embodiment of the present specification, R101 to R103 and G4 to G7 are the same as or different from each other, and are each independently hydrogen; deuterium; a substituted or unsubstituted C1-C60 alkyl group; a substituted or unsubstituted C3-C60 cycloalkyl group; a substituted or unsubstituted silyl group; a substituted or unsubstituted C6-C60 aryl group; or a substituted or unsubstituted C2-C60 heterocyclic group, or are bonded to an adjacent substituent to form a substituted or unsubstituted C2-C60 ring.

In an exemplary embodiment of the present specification, R101 to R103 and G4 to G7 are the same as or different from each other, and are each independently hydrogen; deuterium; a substituted or unsubstituted C1-C30 alkyl group; a substituted or unsubstituted C3-C30 cycloalkyl group; a substituted or unsubstituted silyl group; a substituted or unsubstituted C6-C30 aryl group; or a substituted or unsubstituted C2-C30 heterocyclic group, or are bonded to an adjacent substituent to form a substituted or unsubstituted C2-C30 ring.

In an exemplary embodiment of the present specification, R101 to R103 and G4 to G7 are the same as or different from each other, and are each independently hydrogen; deuterium; a substituted or unsubstituted C1-C20 alkyl group; a substituted or unsubstituted C3-C20 cycloalkyl group; a substituted or unsubstituted silyl group; a substituted or unsubstituted C6-C20 aryl group; or a substituted or unsubstituted C2-C20 heterocyclic group, or are bonded to an adjacent substituent to form a substituted or unsubstituted C2-C20 ring.

In an exemplary embodiment of the present specification, R101 to R103 and G4 to G7 are the same as or different from each other, and are each independently hydrogen; deuterium; a C1-C30 alkyl group that is unsubstituted or substituted with one or more groups selected from the group consisting of deuterium, a cyano group, a halogen group, a C1-C20 alkyl group, a C1-C20 alkoxy group, a silyl group and a C6-C20 aryl group or a group in which two or more selected from the above group are linked together; a C3-C30 cycloalkyl group that is unsubstituted or substituted with one or more groups selected from the group consisting of deuterium, a cyano group, a halogen group, a C1-C20 alkyl group, a C1-C20 alkoxy group, a silyl group and a C6-C20 aryl group or a group in which two or more selected from the above group are linked together; a silyl group that is unsubstituted or substituted with one or more groups selected from the group consisting of deuterium, a cyano group, a halogen group, a C1-C20 alkyl group, a C1-C20 alkoxy group, a silyl group and a C6-C20 aryl group or a group in which two or more selected from the above group are linked together; a C6-C30 aryl group that is unsubstituted or substituted with one or more groups selected from the group consisting of deuterium, a cyano group, a halogen group, a C1-C20 alkyl group, a C1-C20 alkoxy group, a silyl group and a C6-C20 aryl group or a group in which two or more selected from the above group are linked together; or a C2-C30 heterocyclic group that is unsubstituted or substituted with one or more groups selected from the group consisting of deuterium, a cyano group, a halogen group, a C1-C20 alkyl group, a C1-C20 alkoxy group, a silyl group and a C6-C20 aryl group or a group in which two or more selected from the above group are linked together, or are bonded to an adjacent substituent to form a C2-C30 ring that is unsubstituted or substituted with one or more groups selected from the group consisting of deuterium, a cyano group, a halogen group, a C1-C20 alkyl group, a C1-C20 alkoxy group, a silyl group and a C6-C20 aryl group or a group in which two or more selected from the above group are linked together.

In an exemplary embodiment of the present specification, R101 is hydrogen; deuterium; a substituted or unsubstituted alkyl group; a substituted or unsubstituted cycloalkyl group; a substituted or unsubstituted aryl group; or a substituted or unsubstituted heterocyclic group.

In an exemplary embodiment of the present specification, R101 is hydrogen; deuterium; a substituted or unsubstituted methyl group; a substituted or unsubstituted ethyl group; a substituted or unsubstituted propyl group; a substituted or unsubstituted butyl group; a substituted or unsubstituted cyclohexyl group; a substituted or unsubstituted adamantyl group; a substituted or unsubstituted phenyl group; a substituted or unsubstituted biphenyl group; a substituted or unsubstituted naphthyl group; a substituted or unsubstituted fluorenyl group; a substituted or unsubstituted tetrahydronaphthalene group; a substituted or unsubstituted dibenzofuran group; or a substituted or unsubstituted dibenzothiophene group.

In an exemplary embodiment of the present specification, R101 is hydrogen; deuterium; a methyl group that is unsubstituted or substituted with deuterium; an ethyl group that is unsubstituted or substituted with deuterium; a propyl group that is unsubstituted or substituted with deuterium; a butyl group that is unsubstituted or substituted with deuterium; a cyclohexyl group that is unsubstituted or substituted with deuterium; an adamantyl group that is unsubstituted or substituted with deuterium; a phenyl group that is unsubstituted or substituted with one or more groups selected from the group consisting of deuterium, a cyano group, a fluoro group, a methyl group, a propyl group, a butyl group, a methoxy group, a silyl group and a phenyl group or a group in which two or more selected from the above group are linked together; a biphenyl group that is unsubstituted or substituted with one or more groups selected from the group consisting of deuterium, a cyano group, a fluoro group, a methyl group, a propyl group, a butyl group, a methoxy group, a silyl group and a phenyl group or a group in which two or more selected from the above group are linked together; a naphthyl group that is unsubstituted or substituted with one or more groups selected from the group consisting of deuterium, a cyano group, a fluoro group, a methyl group, a propyl group, a butyl group, a methoxy group, a silyl group and a phenyl group or a group in which two or more selected from the above group are linked together; a fluorenyl group that is unsubstituted or substituted with one or more groups selected from the group consisting of deuterium, a cyano group, a fluoro group, a methyl group, a propyl group, a butyl group, a methoxy group, a silyl group and a phenyl group or a group in which two or more selected from the above group are linked together; a tetrahydronaphthalene group that is unsubstituted or substituted with deuterium, a methyl group or a butyl group; a dibenzofuran group that is unsubstituted or substituted with deuterium, a methyl group or a butyl group; or a dibenzothiophene group that is unsubstituted or substituted with deuterium, a methyl group or a butyl group.

In an exemplary embodiment of the present specification, R101 is hydrogen; deuterium; a methyl group; CD₃; an ethyl group; an i-propyl group; a t-butyl group; a cyclohexyl group; an adamantyl group; a phenyl group that is unsubstituted or substituted with one or more groups selected from the group consisting of deuterium, a cyano group, a fluoro group, a methyl group, a t-butyl group, —OCF₃, a trimethylsilyl group, a triphenylsilyl group and a phenyl group or a group in which two or more selected from the above group are linked together; a biphenyl group; a naphthyl group that is unsubstituted or substituted with deuterium; a fluorenyl group unsubstituted or substituted with a methyl group or a phenyl group; a tetrahydronaphthalene group that is unsubstituted or substituted with a methyl group; a dibenzofuran group; or a dibenzothiophene group.

In an exemplary embodiment of the present specification, R101 is hydrogen; deuterium; a methyl group; CD₃; an ethyl group; an i-propyl group; a t-butyl group; a cyclohexyl group; an adamantyl group; a phenyl group that is unsubstituted or substituted with deuterium, a cyano group, a fluoro group, a methyl group, a t-butyl group, —OCF₃, a trimethylsilyl group, a triphenylsilyl group or a phenyl group; a biphenyl group; a naphthyl group that is unsubstituted or substituted with deuterium; a dimethylfluorenyl group; a tetrahydronaphthalene group that is unsubstituted or substituted with a methyl group; a dibenzofuran group; or a dibenzothiophene group.

In an exemplary embodiment of the present specification, R101 is hydrogen; deuterium; a methyl group; a t-butyl group; or a phenyl group that is unsubstituted or substituted with a cyano group.

In an exemplary embodiment of the present specification, R101 is a methyl group; or a t-butyl group.

In an exemplary embodiment of the present specification, R102 and R103 are the same as or different from each other, and are each independently hydrogen; deuterium; a substituted or unsubstituted aryl group; or a substituted or unsubstituted heterocyclic group.

In an exemplary embodiment of the present specification, R102 and R103 are the same as or different from each other, and are each independently a substituted or unsubstituted phenyl group; a substituted or unsubstituted biphenyl group; a substituted or unsubstituted naphthyl group; a substituted or unsubstituted fluorenyl group; a substituted or unsubstituted tetrahydronaphthalene group; a substituted or unsubstituted dibenzofuran group; or a substituted or unsubstituted dibenzothiophene group.

In an exemplary embodiment of the present specification, R102 and R103 are the same as or different from each other, and are each independently a phenyl group that is unsubstituted or substituted with one or more groups selected from the group consisting of deuterium, a cyano group, a fluoro group, a methyl group, a propyl group, a butyl group, a methoxy group, a silyl group and a phenyl group or a group in which two or more selected from the above group are linked together; a biphenyl group that is unsubstituted or substituted with one or more groups selected from the group consisting of deuterium, a cyano group, a fluoro group, a methyl group, a propyl group, a butyl group, a methoxy group, a silyl group and a phenyl group or a group in which two or more selected from the above group are linked together; a naphthyl group that is unsubstituted or substituted with one or more groups selected from the group consisting of deuterium, a cyano group, a fluoro group, a methyl group, a propyl group, a butyl group, a methoxy group, a silyl group and a phenyl group or a group in which two or more selected from the above group are linked together; a fluorenyl group that is unsubstituted or substituted with one or more groups selected from the group consisting of deuterium, a cyano group, a fluoro group, a methyl group, a propyl group, a butyl group, a methoxy group, a silyl group and a phenyl group or a group in which two or more selected from the above group are linked together; a tetrahydronaphthalene group that is unsubstituted or substituted with one or more groups selected from the group consisting of deuterium, a cyano group, a fluoro group, a methyl group, a propyl group, a butyl group, a methoxy group, a silyl group and a phenyl group or a group in which two or more selected from the above group are linked together; a dibenzofuran group that is unsubstituted or substituted with one or more groups selected from the consisting of deuterium, a cyano group, a fluoro group, a methyl group, a propyl group, a butyl group, a methoxy group, a silyl group and a phenyl group or a group in which two or more selected from the above group are linked together; or a dibenzothiophene group that is unsubstituted or substituted with one or more groups selected from the group consisting of deuterium, a cyano group, a fluoro group, a methyl group, a propyl group, a butyl group, a methoxy group, a silyl group and a phenyl group or a group in which two or more selected from the above group are linked together.

In an exemplary embodiment of the present specification, R102 and R103 are the same as or different from each other, and are each independently a phenyl group that is unsubstituted or substituted with one or more groups selected from the group consisting of deuterium, a cyano group, a fluoro group, a methyl group, a propyl group, a butyl group, a methoxy group, a silyl group and a phenyl group or a group in which two or more selected from the above group are linked together; a biphenyl group that is unsubstituted or substituted with deuterium; a naphthyl group unsubstituted or substituted with deuterium; a fluorenyl group unsubstituted or substituted with a methyl group or a phenyl group; a tetrahydronaphthalene group that is unsubstituted or substituted with a methyl group; a dibenzofuran group; or a dibenzothiophene group.

In an exemplary embodiment of the present specification, R102 and R103 are the same as or different from each other, and are each independently a phenyl group that is unsubstituted or substituted with deuterium, a cyano group, a fluoro group, a methyl group, CD₃, CF₃, an i-propyl group, a t-butyl group, a trimethylsilyl group, a triphenylsilyl group or a phenylpropyl group; a biphenyl group that is unsubstituted or substituted withy deuterium; a naphthyl group; a dimethylfluorenyl group; a tetrahydronaphthalene group that is unsubstituted or substituted with a methyl group; a dibenzofuran group; or a dibenzothiophene group.

In an exemplary embodiment of the present specification, R102 and R103 are the same as or different from each other, and are each independently a phenyl group that is unsubstituted or substituted with a C1-C10 alkylsilyl group.

In an exemplary embodiment of the present specification, R102 and R103 are the same as or different from each other, and are each independently a phenyl group that is unsubstituted or substituted with a trimethylsilyl group.

In an exemplary embodiment of the present specification, G4 to G7 are the same as or different from each other, and are each independently hydrogen; deuterium; a substituted or unsubstituted alkyl group; a substituted or unsubstituted silyl group; or a substituted or unsubstituted aryl group, or are bonded to an adjacent substituent to form a substituted or unsubstituted ring.

In an exemplary embodiment of the present specification, G4 to G7 are the same as or different from each other, and are each independently hydrogen; deuterium; a substituted or unsubstituted C1-C10 alkyl group; a substituted or unsubstituted C1-C30 [symbol] alkylsilyl group; a substituted or unsubstituted C6-C30 arylsilyl group; or a substituted or unsubstituted C6-C30 aryl group, or are bonded to an adjacent substituent to form a substituted or unsubstituted C3-C30 aliphatic hydrocarbon ring or a substituted or unsubstituted C6-C30 aromatic hydrocarbon ring.

In an exemplary embodiment of the present specification, G4 to G7 are the same as or different from each other, and are each independently hydrogen; deuterium; a C1-C6 alkyl group that is unsubstituted or substituted with deuterium; a C1-C18 alkylsilyl group; a C6-C60 arylsilyl group; or a C6-C30 aryl group that is unsubstituted or substituted with deuterium or a C1-C6 alkyl group, or are bonded to an adjacent substituent to form a C3-C20 aliphatic hydrocarbon ring that is unsubstituted or substituted with deuterium or an alkyl group, or a C6-C20 aromatic hydrocarbon ring that is unsubstituted or substituted with deuterium or an alkyl group.

In an exemplary embodiment of the present specification, G4 and G5 are the same as or different from each other, and are each independently a methyl group that is unsubstituted or substituted with deuterium.

In an exemplary embodiment of the present specification, G4 and G5 are a methyl group.

In an exemplary embodiment of the present specification, G6 and G7 are the same as or different from each other, and are each independently hydrogen; deuterium; a substituted or unsubstituted methyl group; a substituted or unsubstituted tert-butyl group; a substituted or unsubstituted trimethylsilyl group; or a substituted or unsubstituted phenyl group, or are bonded to an adjacent substituent to form a substituted or unsubstituted cyclohexene ring or a substituted or unsubstituted benzene ring.

In an exemplary embodiment of the present specification, G6 and G7 are the same as or different from each other, and are each independently hydrogen; deuterium; a methyl group; a tert-butyl group; a trimethylsilyl group; or a phenyl group, or are bonded to an adjacent substituent to form a cyclohexene ring that is unsubstituted or substituted with a methyl group.

In an exemplary embodiment of the present specification, G6 is hydrogen; deuterium; a methyl group; a t-butyl group; a trimethylsilyl group; or a phenyl group, or is bonded to an adjacent substituent to form a cyclohexene ring that is unsubstituted or substituted with a methyl group.

In an exemplary embodiment of the present specification, G6 is hydrogen; deuterium; or a t-butyl group.

In an exemplary embodiment of the present specification, G7 is hydrogen or deuterium.

In an exemplary embodiment of the present specification, G7 is hydrogen.

In an exemplary embodiment of the present specification, Chemical Formula 1-B-3 is any one of the following structural formulae.

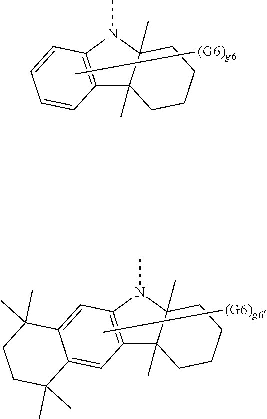

In the structural formulae, the definitions of dotted line, G6 and g6 are the same as the definitions in Chemical Formula 1-B-3, and

g6′ is an integer from 0 to 10, and when g6′ is 2 or higher, two or more G6's are the same as or different from each other.

In an exemplary embodiment of the present specification, Chemical Formula 1-B-4 is any one of the following structural formulae.

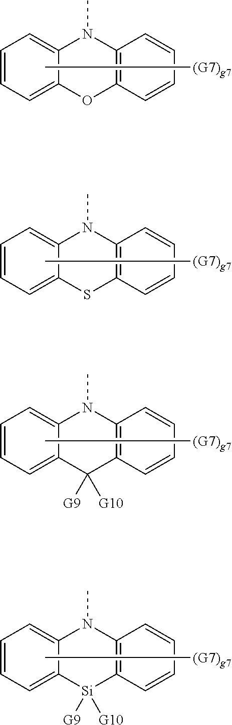

In the structural formulae, the definitions of dotted line, G7, G9, G10 and g7 are the same as the definitions in Chemical Formula 1-B-4.

In an exemplary embodiment of the present specification, when R5 or R10 forms a ring, the ring is any one of the following structural formulae.

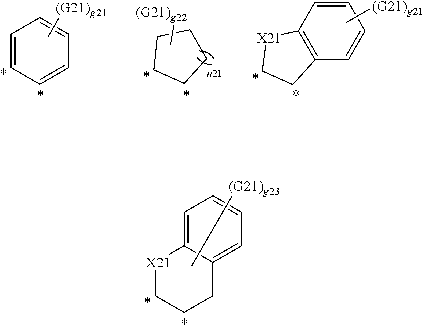

In the structural formulae,
X21 is O; S; or CG201G202,
G21, G201 and G202 are the same as or different from each other, and are each independently hydrogen; deuterium; a substituted or unsubstituted alkyl group; or a substituted or unsubstituted aryl group,
n21 is 1 or 2, g21 is an integer from 0 to 4, g22 is an integer from 0 to 8, and g23 is an integer from 0 to 6,
when n21, g21, g22 and g23 are each 2 or higher, two or more G21's are the same as or different from each other, and
* means a position condensed to Chemical Formula 1.

In an exemplary embodiment of the present specification, G21, G201 and G202 are the same as or different from each other, and are hydrogen; deuterium; or a substituted or unsubstituted alkyl group.

In an exemplary embodiment of the present specification, G21, G201 and G202 are the same as or different from each other, and are hydrogen; deuterium; or a substituted or unsubstituted C1-C30 alkyl group.

In an exemplary embodiment of the present specification, G21, G201 and G202 are the same as or different from each other, and are hydrogen; deuterium; or a substituted or unsubstituted C1-C20 alkyl group.

In an exemplary embodiment of the present specification, G21, G201 and G202 are the same as or different from each other, and are hydrogen; deuterium; or a substituted or unsubstituted methyl group.

In an exemplary embodiment of the present specification, G21, G201 and G202 are the same as or different from each other, and are hydrogen; deuterium; or a methyl group that is unsubstituted or substituted with deuterium.

In an exemplary embodiment of the present specification, G21, G201 and G202 are the same as or different from each other, and are hydrogen; deuterium; or a methyl group.

In an exemplary embodiment of the present specification, n21 is 2.

In an exemplary embodiment of the present specification, g21 is an integer from 1 to 4.

In an exemplary embodiment of the present specification, g22 is an integer from 1 to 4.

In an exemplary embodiment of the present specification, g23 is an integer from 1 to 4.

In an exemplary embodiment of the present specification, when R5 or R10 forms a ring, the ring is any one of the following structural formulae.

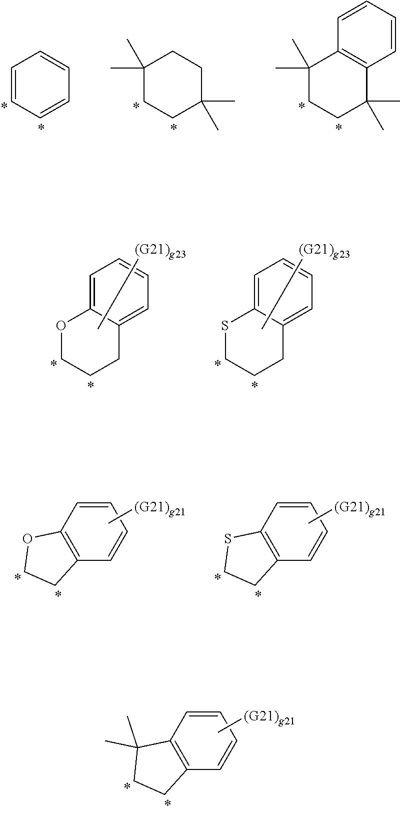

In the structural formulae, the definition of the substituent is the same as that described above.

In an exemplary embodiment of the present specification, in Chemical Formulae 2 and 3,

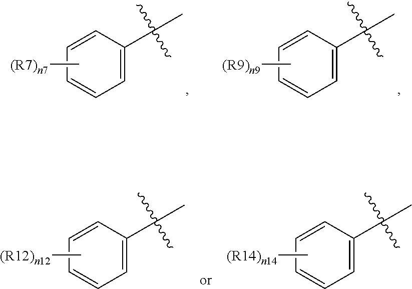

is the same as or different from each other, and is each independently any one of the following Chemical Formulae 1-A-1 to 1-A-3.

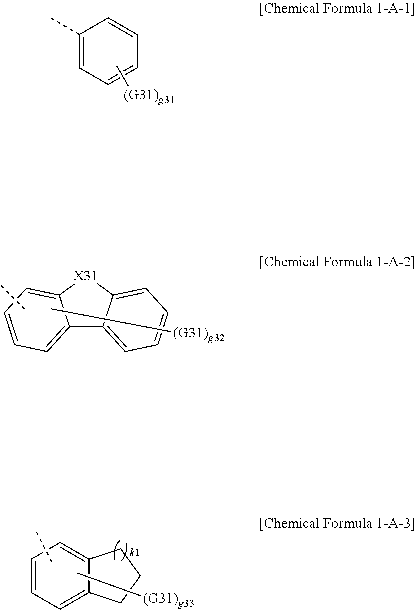

In Chemical Formulae 1-A-1 to 1-A-3,
G31's are the same as or different from each other, and are each independently hydrogen; deuterium; a cyano group; a halogen group; a substituted or unsubstituted alkyl group; a substituted or unsubstituted alkoxy group; a substituted or unsubstituted alkylthio group; a substituted or unsubstituted cycloalkyl group; a substituted or unsubstituted silyl group; a substituted or unsubstituted aryl group; a substituted or unsubstituted aryloxy group; a substituted or unsubstituted arylthio group; a substituted or unsubstituted heterocyclic group; or a substituted or unsubstituted amine group, or are bonded to an adjacent substituent to form a substituted or unsubstituted ring,
X31 is —O—; —S—; —NG41-; —CG41G42-; or —SiG41G42-,
G41 and G42 are the same as or different from each other, and are each independently hydrogen; deuterium; a substituted or unsubstituted alkyl group; or a substituted or unsubstituted aryl group, or are bonded to an adjacent substituent to form a substituted or unsubstituted ring,
k1 is 1 or 2,
g31 is an integer from 0 to 5, g32 is an integer from 0 to 7, and g33 is an integer from 0 to 11,
when g31 to g33 are each 2 or higher, two or more G31's are the same as or different from each other, and
the dotted line means a position bonded to Chemical Formula 2 or 3.

In an exemplary embodiment of the present specification, X31 is —O—; —S—; or —CG41G42-.

In an exemplary embodiment of the present specification, G31 is hydrogen; deuterium; a cyano group; a halogen group; a substituted or unsubstituted alkyl group; a substituted or unsubstituted cycloalkyl group; a substituted or unsubstituted silyl group; a substituted or unsubstituted aryl group; a substituted or unsubstituted heterocyclic group; or a substituted or unsubstituted amine group, or are bonded to an adjacent substituent to form a substituted or unsubstituted ring.

In an exemplary embodiment of the present specification, G31 is hydrogen; deuterium; a cyano group; a halogen group; a substituted or unsubstituted C1-C60 alkyl group; a substituted or unsubstituted C3-C60 cycloalkyl group; a substituted or unsubstituted silyl group; a substituted or unsubstituted C6-C60 aryl group; a substituted or unsubstituted C2-C60 heterocyclic group; or a substituted or unsubstituted amine group, or is bonded to an adjacent substituent to form a substituted or unsubstituted C2-C60 ring.

In an exemplary embodiment of the present specification, R5 is hydrogen; deuterium; a cyano group; a halogen group; a substituted or unsubstituted C1-C30 alkyl group; a substituted or unsubstituted C3-C30 cycloalkyl group; a substituted or unsubstituted silyl group; a substituted or unsubstituted C6-C30 aryl group; a substituted or unsubstituted C2-C30 heterocyclic group; or a substituted or unsubstituted amine group, or is bonded to an adjacent substituent to form a substituted or unsubstituted C2-C30 ring.

In an exemplary embodiment of the present specification, G31 is hydrogen; deuterium; a cyano group; a halogen group; a substituted or unsubstituted C1-C20 alkyl group; a substituted or unsubstituted C3-C20 cycloalkyl group; a substituted or unsubstituted silyl group; a substituted or unsubstituted C6-C20 aryl group; a substituted or unsubstituted C2-C20 heterocyclic group; or a substituted or unsubstituted amine group, or is bonded to an adjacent substituent to form a substituted or unsubstituted C2-C20 ring.

In an exemplary embodiment of the present specification, G31 is hydrogen; deuterium; a cyano group; a halogen group; a C1-C20 alkyl group that is unsubstituted or substituted with deuterium; a C6-C20 arylalkyl group that is unsubstituted or substituted with deuterium; a C3-C20 cycloalkyl group that is unsubstituted or substituted with deuterium; a silyl group that is unsubstituted or substituted with a C1-C20 alkyl group or a C6-C20 aryl group; a C6-C20 aryl group that is unsubstituted or substituted with one or more groups selected from the group consisting of deuterium, a cyano group, a halogen group, a C1-C20 alkyl group, a silyl group, a C3-C20 cycloalkyl group and a C6-C20 aryl group or a group in which two or more selected from the above group are linked together; or an amine group that is unsubstituted or substituted with a C6-C20 aryl group, or is bonded to an adjacent substituent to form a C2-C30 ring that is unsubstituted or substituted with one or more groups selected from the group consisting of deuterium, a cyano group, a halogen group, a C1-C20 alkyl group, a silyl group and a C6-C20 aryl group or a group in which two or more selected from the above group are linked together.

In an exemplary embodiment of the present specification, G31 is hydrogen; deuterium; a cyano group; a fluoro group; a substituted or unsubstituted methyl group; a substituted or unsubstituted propyl group; a substituted or unsubstituted butyl group; a substituted or unsubstituted phenylpropyl group; a substituted or unsubstituted cyclohexyl group; a substituted or unsubstituted adamantyl group; a substituted or unsubstituted silyl group; a substituted or unsubstituted phenyl group; a substituted or unsubstituted biphenyl group; a substituted or unsubstituted naphthyl group; a substituted or unsubstituted tetrahydronaphthalene group; or a substituted or unsubstituted amine group, or is bonded to a benzene ring to form a substituted or unsubstituted naphthalene ring; a substituted or unsubstituted phenanthrene ring; a substituted or unsubstituted fluorene ring; a substituted or unsubstituted benzofluorene ring; a substituted or unsubstituted tetrahydronaphthalene ring; a substituted or unsubstituted dibenzofuran ring; a substituted or unsubstituted dibenzothiophene ring; a substituted or unsubstituted dibenzosilole ring; a substituted or unsubstituted naphthobenzofuran ring; a substituted or unsubstituted naphthobenzothiophene ring; or a substituted or unsubstituted naphthobenzosilole ring.

In an exemplary embodiment of the present specification, G31 is hydrogen; deuterium; a cyano group; a fluoro group; a substituted or unsubstituted methyl group; a substituted or unsubstituted propyl group; a substituted or unsubstituted butyl group; a substituted or unsubstituted phenylpropyl group; a substituted or unsubstituted cyclohexyl group; a substituted or unsubstituted adamantyl group; a substituted or unsubstituted silyl group; a substituted or unsubstituted phenyl group; a substituted or unsubstituted biphenyl group; a substituted or unsubstituted naphthyl group; a substituted or unsubstituted tetrahydronaphthalene group; or a substituted or unsubstituted amine group, or is bonded to a benzene ring to form a substituted or unsubstituted naphthalene ring; a substituted or unsubstituted phenanthrene ring; a substituted or unsubstituted fluorene ring; a substituted or unsubstituted benzofluorene ring; a substituted or unsubstituted tetrahydronaphthalene ring; a substituted or unsubstituted dibenzofuran ring; a substituted or unsubstituted dibenzothiophene ring; a substituted or unsubstituted dibenzosilole ring; or a substituted or unsubstituted naphthobenzofuran ring.

In an exemplary embodiment of the present specification, G31 is hydrogen; deuterium; a cyano group; a fluoro group; a methyl group that is unsubstituted or substituted with deuterium; a propyl group that is unsubstituted or substituted with deuterium; a butyl group that is unsubstituted or substituted with deuterium; a phenylpropyl group that is unsubstituted or substituted with deuterium; a cyclohexyl group that is unsubstituted or substituted with deuterium; an adamantyl group that is unsubstituted or substituted with deuterium; a silyl group that is unsubstituted or substituted with a methyl group or a phenyl group; a phenyl group that is unsubstituted or substituted with one or more groups selected from the group consisting of deuterium, a cyano group, a fluoro group, a methyl group, a t-butyl group, a silyl group, a phenyl group, a biphenyl group, a naphthyl group and an adamantyl group or a group in which two or more selected from the above group are linked together; a biphenyl group that is unsubstituted or substituted with one or more groups selected from the group consisting of deuterium, a cyano group, a fluoro group, a methyl group, a t-butyl group, a silyl group, a phenyl group, a biphenyl group, a naphthyl group and an adamantyl group or a group in which two or more selected from the above group are linked together; a naphthyl group that is unsubstituted or substituted with one or more groups selected from the group consisting of deuterium, a cyano group, a fluoro group, a methyl group, a t-butyl group, a silyl group, a phenyl group, a biphenyl group, a naphthyl group and an adamantyl group or a group in which two or more selected from the above group are linked together; a tetrahydronaphthalene group that is unsubstituted or substituted with a methyl group; or an amine group that is unsubstituted or substituted with a phenyl group, or is bonded to a benzene ring to form a naphthalene ring, a phenanthrene ring, a dimethylfluorene ring, a diphenylfluorene ring, a benzofluorene ring, a tetrahydronaphthalene ring, a dibenzofuran ring, a dibenzothiophene ring, a dibenzosilole ring, or a naphthobenzofuran ring, and the ring is unsubstituted or substituted with one or more groups selected from the group consisting of deuterium, a cyano group, a fluoro group, a methyl group, a t-butyl group, a silyl group, a phenyl group, a biphenyl group and a naphthyl group or a group in which two or more selected from the above group are linked together.

In an exemplary embodiment of the present specification, G31 is hydrogen; deuterium; a cyano group; a fluoro group; a methyl group; CD₃; an i-propyl group; a t-butyl group; a sec-butyl group; a phenylpropyl group; a cyclohexyl group; a trimethylsilyl group; a triphenylsilyl group; a phenyl group that is unsubstituted or substituted with deuterium, a cyano group, a fluoro group, a methyl group, CD₃, CF₃, a t-butyl group, a trimethylsilyl group, a phenyl group, a biphenyl group, a naphthyl group or an adamantyl group; a biphenyl group; a naphthyl group; a tetrahydronaphthalene group that is substituted with a methyl group; an adamantyl group; or a diphenylamine group, or forms a naphthalene ring that is unsubstituted or substituted with a phenyl group; a phenanthrene ring; a dimethylfluorene ring that is unsubstituted or substituted with a t-butyl group; a diphenylfluorene ring that is unsubstituted or substituted with a t-butyl group; a benzofluorene ring that is unsubstituted or substituted with a methyl group; a tetrahydronaphthalene ring that is unsubstituted or substituted with a methyl group; a dibenzofuran ring that is unsubstituted or substituted with a t-butyl group; a dibenzothiophene ring that is unsubstituted or substituted with a t-butyl group; a dibenzosilole ring that is unsubstituted or substituted with a phenyl group; or a naphthobenzofuran ring. In this case, the tetrahydronaphthalene ring substituted with a methyl group is unsubstituted or substituted with deuterium, a methyl group, CD₃, CF₃, a t-butyl group, a trimethylsilyl group, a phenyl group, a biphenyl group or a phenyl group that is unsubstituted or substituted with a naphthyl group.

In an exemplary embodiment of the present specification, G31 is hydrogen; deuterium; a halogen group; a C1-C10 alkyl group; a silyl group that is unsubstituted or substituted with a C1-C10 alkyl group or a C6-C20 aryl group; a phenyl group that is unsubstituted or substituted with deuterium, a halogen group, a C1-C10 alkyl group or a C3-C20 cycloalkyl group; or a C3-C20 cycloalkyl group, or is bonded to a benzene ring to form a fluorene ring that is unsubstituted or substituted with a C1-C10 alkyl group or a C6-C20 aryl group; a tetrahydronaphthalene ring that is substituted with a C1-C10 alkyl group or a C6-C20 aryl group; or a dibenzofuran ring.

In an exemplary embodiment of the present specification, G31 is hydrogen; deuterium; a fluoro group; a methyl group; a t-butyl group; a trimethylsilyl group; an adamantyl group; or a phenyl group that is unsubstituted or substituted with deuterium, a fluoro group, a methyl group, a t-butyl group or an adamantyl group, or is bonded to a benzene ring to form a dimethylfluorene ring, a tetrahydronaphthalene ring substituted with a methyl group or a phenyl group, or a dibenzofuran ring.

In an exemplary embodiment of the present specification, G41 and G42 are the same as or different from each other, and are each independently hydrogen; deuterium; a substituted or unsubstituted alkyl group; or a substituted or unsubstituted aryl group, or are bonded to an adjacent substituent to form a substituted or unsubstituted ring.

In an exemplary embodiment of the present specification, G41 and G42 are the same as or different from each other, and are each independently hydrogen; deuterium; a substituted or unsubstituted C1-C10 alkyl group; or a substituted or unsubstituted C6-C30 aryl group, or are bonded to an adjacent substituent to form a substituted or unsubstituted C6-C30 aromatic hydrocarbon ring.

In an exemplary embodiment of the present specification, G41 and G42 are the same as or different from each other, and are each independently hydrogen; deuterium; a C1-C6 alkyl group which is unsubstituted or substituted with deuterium; or a C6-C30 aryl group which is unsubstituted or substituted with deuterium or a C1-C6 alkyl group, or are bonded to an adjacent substituent to form a C6-C20 aromatic hydrocarbon ring.

In an exemplary embodiment of the present specification, G41 and G42 are the same as or different from each other, and are each independently hydrogen; deuterium; a methyl group; or a phenyl group, or are bonded to each other to form a fluorene ring.

In an exemplary embodiment of the present specification, G41 and G42 are the same as or different from each other, and are each independently hydrogen; deuterium; a methyl group; or a phenyl group.

In an exemplary embodiment of the present specification, Chemical Formula 1-A-1 is selected from the following structures.

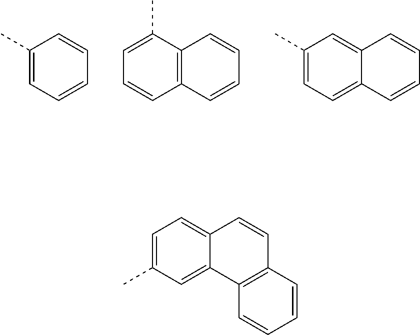

The structures are each independently unsubstituted or substituted with one or more groups selected from the group consisting of deuterium; a halogen group; a cyano group; a silyl group; an alkyl group; a cycloalkyl group; an aryl group; and a heterocyclic group having 2 to 30 carbon atoms or a group in which two or more selected from the above group are linked together.

The structures are each independently unsubstituted or substituted with one or more groups selected from the group consisting of deuterium; —F; a cyano group; a silyl group; a methyl group; an ethyl group; a propyl group; a butyl group; a cyclopentyl group; a cyclohexyl group; an adamantyl group; a phenyl group; a biphenyl group; a terphenyl group; a naphthyl group; a fluorenyl group; a tetrahydronaphthalene group; a dibenzofuran group; a dibenzothiophene group; a carbazole group; a hexahydrocarbazole group; a hexahydrocarbazole group to which cyclohexene is condensed; a hexahydrocarbazole group to which benzene is condensed; a phenoxazine group; a phenothiazine group; an amine group; a dihydroacridine group; and a dihydrodibenzoazasiline group or a group in which two or more selected from the above group are linked together.

In an exemplary embodiment of the present specification, Chemical Formula 1-A-1 may have the following structure.

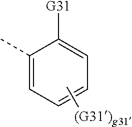

In the structure, the definitions of dotted line and G31 are the same as those defined in Chemical Formula 1-A-1,
G31′ is hydrogen; deuterium; a cyano group; a halogen group; a substituted or unsubstituted alkyl group; a substituted or unsubstituted alkoxy group; a substituted or unsubstituted alkylthio group; a substituted or unsubstituted cycloalkyl group; a substituted or unsubstituted silyl group; a substituted or unsubstituted aryl group; a substituted or unsubstituted aryloxy group; a substituted or unsubstituted arylthio group; a substituted or unsubstituted heterocyclic group; or a substituted or unsubstituted amine group, or is bonded to an adjacent substituent to form a substituted or unsubstituted ring,
g31′ is an integer from 0 to 4, and
when g31′ is 2 or higher, two or more G31's are the same as or different from each other.

In an exemplary embodiment of the present specification, the above-described definition of G31 may be applied to G31′.

In an exemplary embodiment of the present specification, Chemical Formula 1-A-2 is selected from the following structures.

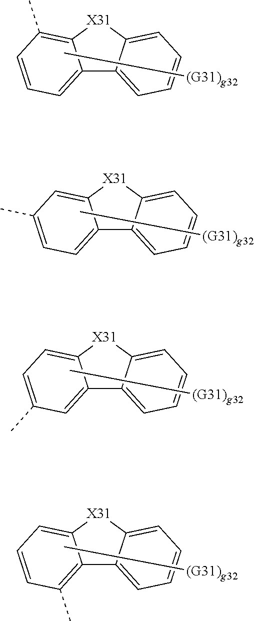

In the structures, the dotted line, X31, G31 and g32 are the same as those defined in Chemical Formula 1-A-2.

In an exemplary embodiment of the present specification, Chemical Formula 1-A-3 is selected from the following structures.

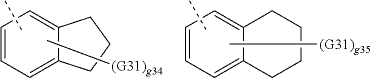

In the structures, the dotted line and G31 are the same as those defined in Chemical Formula 1-A-3,
g34 is an integer from 0 to 9, and g35 is an integer from 0 to 11, and
when g34 and g35 are each 2 or higher, G31's are the same as or different from each other.

In an exemplary embodiment of the present specification, Chemical Formula 1-A-3 is selected from the following structures.

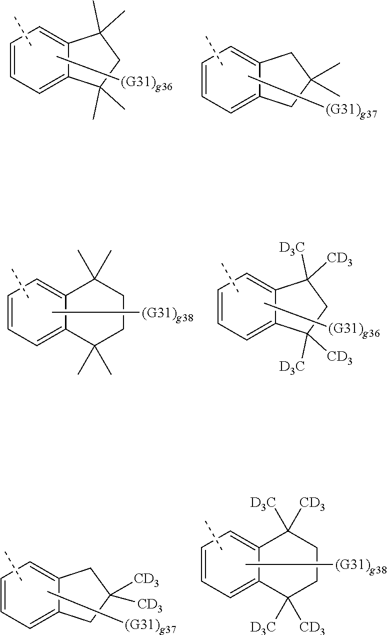

In the structures, the dotted line and G31 are the same as those defined in Chemical Formula 1-A-3,
g36 is an integer from 0 to 5, g37 is an integer from 0 to 7, and g38 is an integer from 0 to 7, and
when g36 to g38 are each 2 or higher, G31's are the same as or different from each other.

In an exemplary embodiment of the present specification, Chemical Formula 1-A-3 is selected from the following structures.

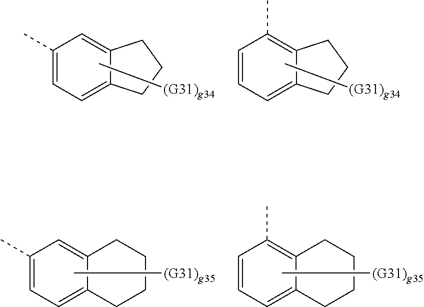

In the structures, the dotted line and G31 are the same as those defined in Chemical Formula 1-A-3,
g34 is an integer from 0 to 9, and g35 is an integer from 0 to 11, and
when g34 and g35 are each 2 or higher, G31's are the same as or different from each other.

In an exemplary embodiment of the present specification, Chemical Formula 1-A-3 is selected from the following structures.

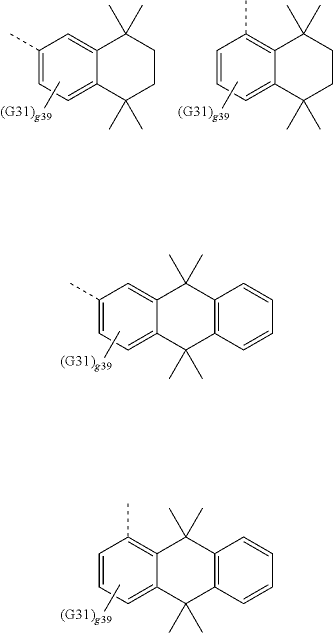

In the structures, the dotted line and G31 are the same as those defined in Chemical Formula 1-A-3, and
g39 is an integer from 0 to 3, and when g39 is 2 or higher, two or more G31's are the same as or different from each other.

In an exemplary embodiment of the present specification, in Chemical Formula 2, at least one of

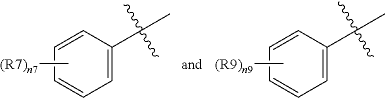

is a substituted or unsubstituted tetrahydronaphthalene ring.

In an exemplary embodiment of the present specification, in Chemical Formula 3, at least one of

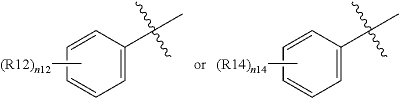

is a substituted or unsubstituted tetrahydronaphthalene ring.

In an exemplary embodiment of the present specification, Chemical Formula 2 is any one of the following Chemical Formulae 2-11 to 2-29.

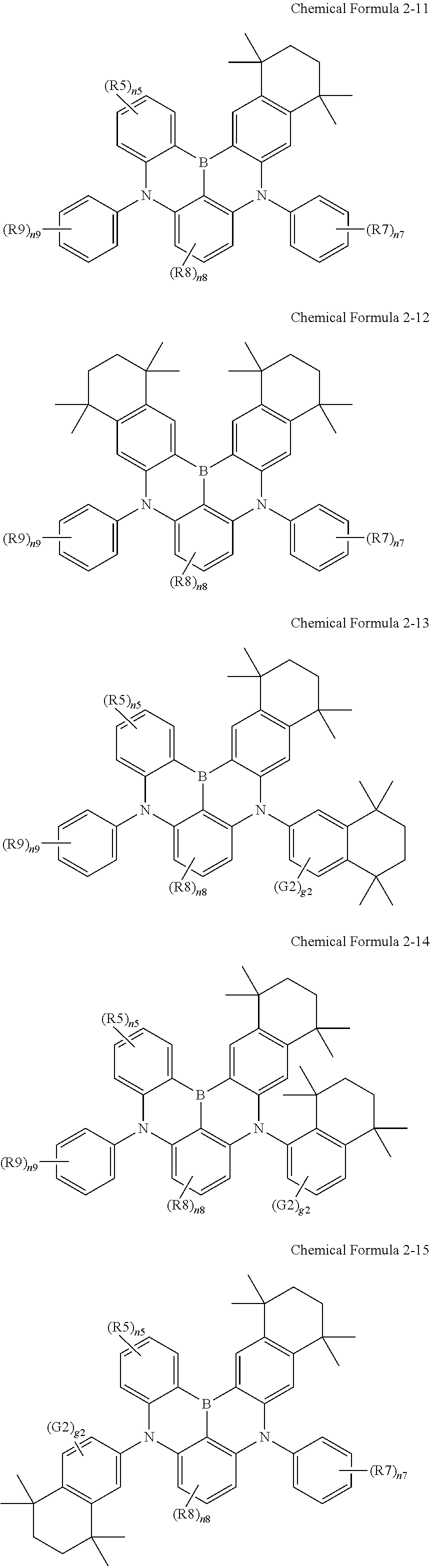

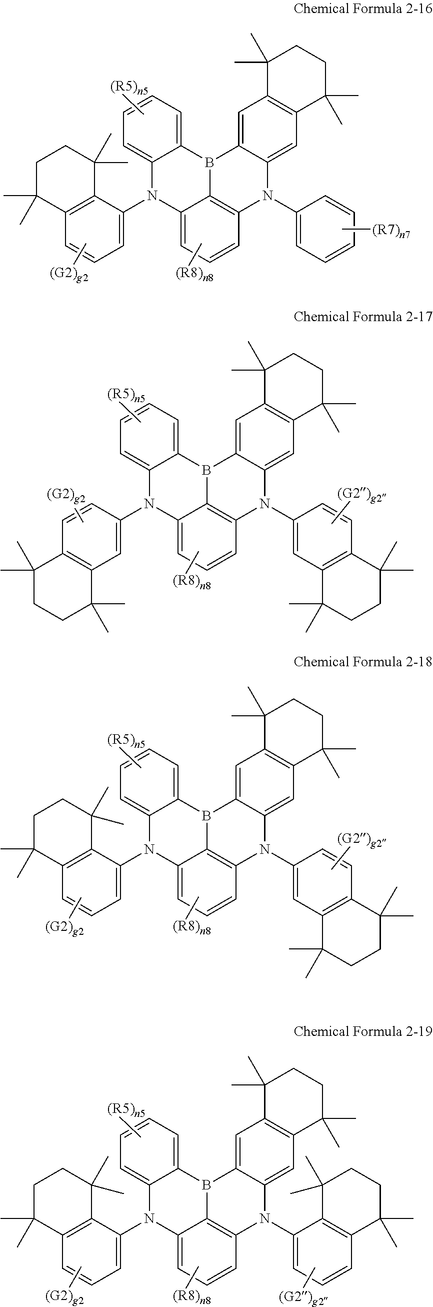

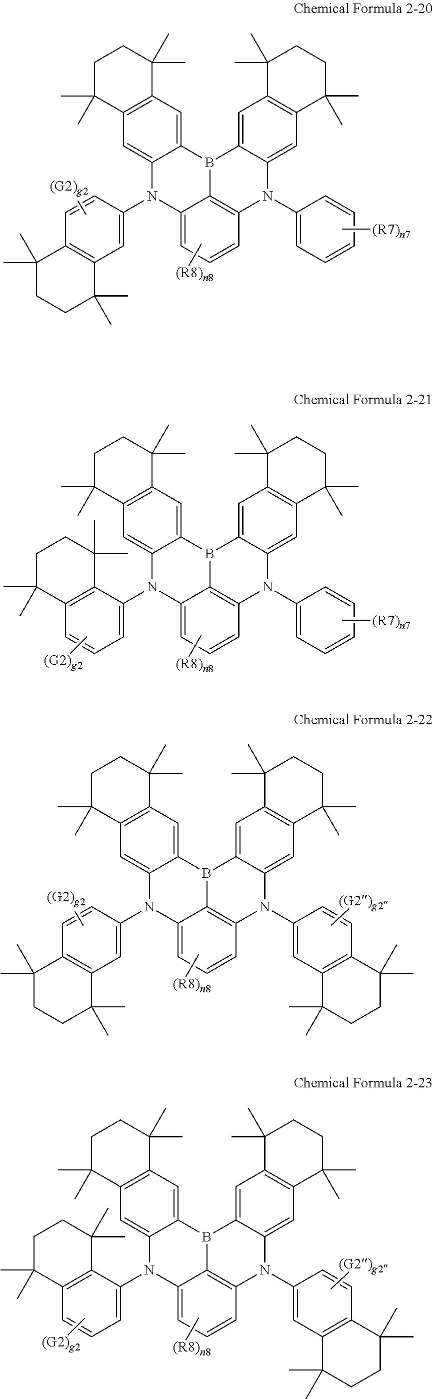

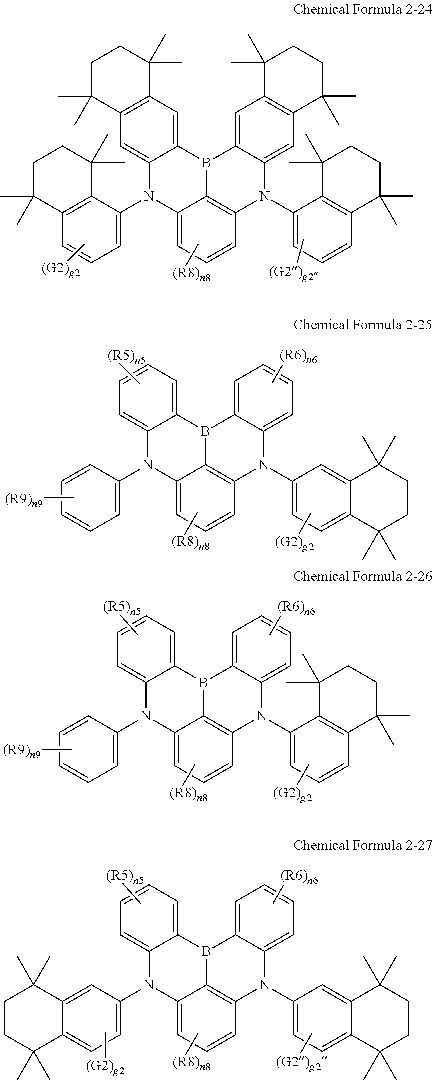

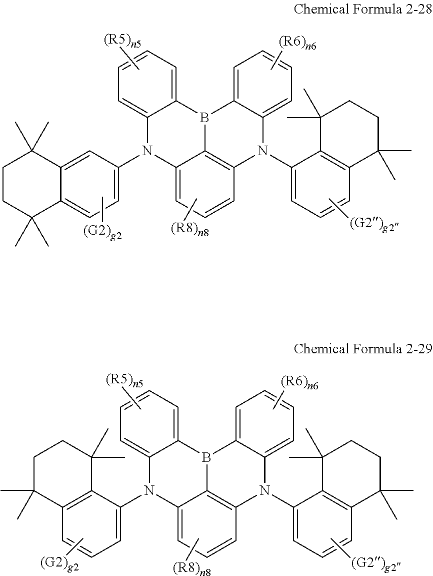

In Chemical Formulae 2-11 to 2-29,
the definitions of R5 to R9 and n5 to n9 are the same as the definitions in Chemical Formula 2,
G2 and G2″ are the same as or different from each other, and are each independently hydrogen; deuterium; a halogen group; a cyano group; a substituted or unsubstituted alkyl group; a substituted or unsubstituted cycloalkyl group; a substituted or unsubstituted silyl group; a substituted or unsubstituted alkenyl group; a substituted or unsubstituted aryl group; a substituted or unsubstituted heterocyclic group; a substituted or unsubstituted alkoxy group; a substituted or unsubstituted aryloxy group; a substituted or unsubstituted alkylthio group; a substituted or unsubstituted arylthio group; or a substituted or unsubstituted amine group, or are bonded to an adjacent substituent to form a substituted or unsubstituted ring, and
g2 and g2″ are each an integer from 0 to 3, and when g2 and g2″ are each 2 or higher, two or more G2's are the same as or different from each other.

In an exemplary embodiment of the present specification, the above-described contents on G2 may be applied to the definition of G2″.

In an exemplary embodiment of the present specification, Chemical Formula 2 includes at least one deuterium.

In an exemplary embodiment of the present specification, at least 30% of the compound of Chemical Formula 2 is substituted with deuterium. In another exemplary embodiment, 40% or more of the compound of Chemical Formula 2 is substituted with deuterium. In another exemplary embodiment, 50% or more of the compound of Chemical Formula 2 is substituted with deuterium. In still another exemplary embodiment, 60% or more of the compound of Chemical Formula 2 is substituted with deuterium. In yet another exemplary embodiment, 70% or more of the compound of Chemical Formula 2 is substituted with deuterium. In still yet another exemplary embodiment, 80% or more of the compound of Chemical Formula 2 is substituted with deuterium. In a further exemplary embodiment, 90% or more of the compound of Chemical Formula 2 is substituted with deuterium. In another further exemplary embodiment, 100% of the compound of Chemical Formula 2 is substituted with deuterium.

In an exemplary embodiment of the present specification, the compound of Chemical Formula 2 includes 40% to 60% of deuterium. In another exemplary embodiment, the compound of Chemical Formula 2 includes 40% to 80% of deuterium. In still another exemplary embodiment, the compound of Chemical Formula 2 includes 60% to 80% of deuterium. In yet another exemplary embodiment, the compound of Chemical Formula 2 includes 80% to 100% of deuterium.

In an exemplary embodiment of the present specification, Chemical Formula 3 includes at least one deuterium.

In an exemplary embodiment of the present specification, at least 30% of the compound of Chemical Formula 3 is substituted with deuterium. In another exemplary embodiment, 40% or more of the compound of Chemical Formula 3 is substituted with deuterium. In still another exemplary embodiment, 50% or more of the compound of Chemical Formula 3 is substituted with deuterium. In yet another exemplary embodiment, 60% or more of the compound of Chemical Formula 3 is substituted with deuterium. In still yet another exemplary embodiment, 70% or more of the compound of Chemical Formula 3 is substituted with deuterium. In a further exemplary embodiment, 80% or more of the compound of Chemical Formula 3 is substituted with deuterium. In another further exemplary embodiment, 90% or more of the compound of Chemical Formula 3 is substituted with deuterium. In still another further exemplary embodiment, 100% of the compound of Chemical Formula 3 is substituted with deuterium.

In an exemplary embodiment of the present specification, the compound of Chemical Formula 3 includes 40% to 60% of deuterium. In another exemplary embodiment, the compound of Chemical Formula 3 includes 40% to 80% of deuterium. In still another exemplary embodiment, the compound of Chemical Formula 3 includes 60% to 80% of deuterium. In yet another exemplary embodiment, the compound of Chemical Formula 3 includes 80% to 100% of deuterium.

In an exemplary embodiment of the present specification, the compound of Chemical Formula 2 is any one of the following compounds.

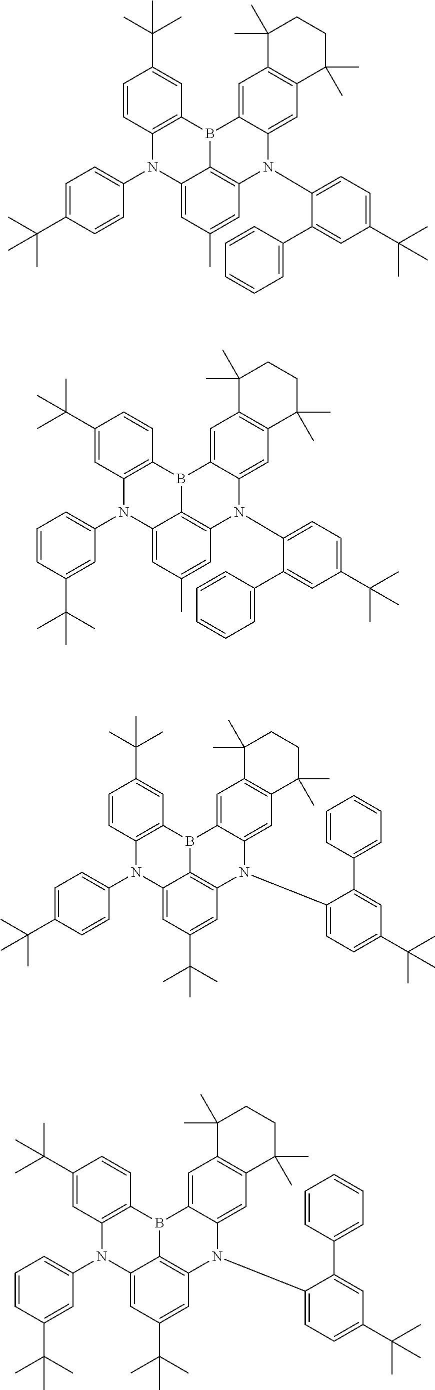

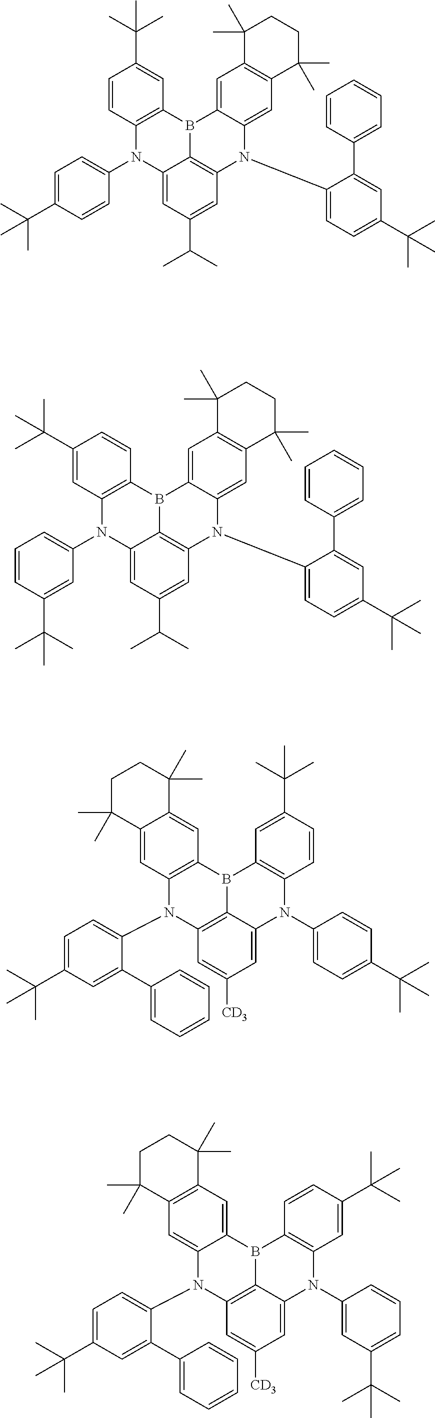

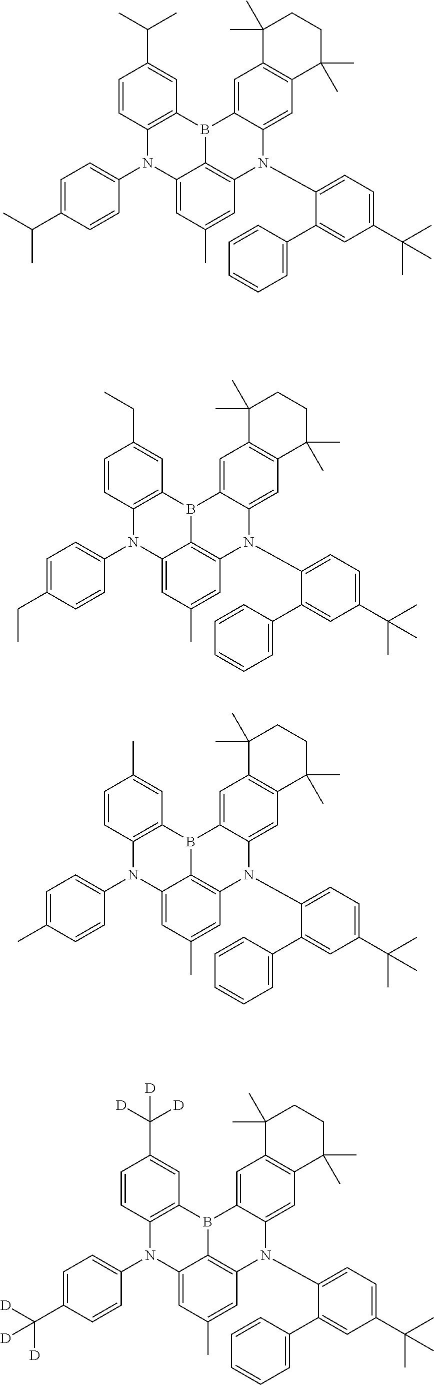

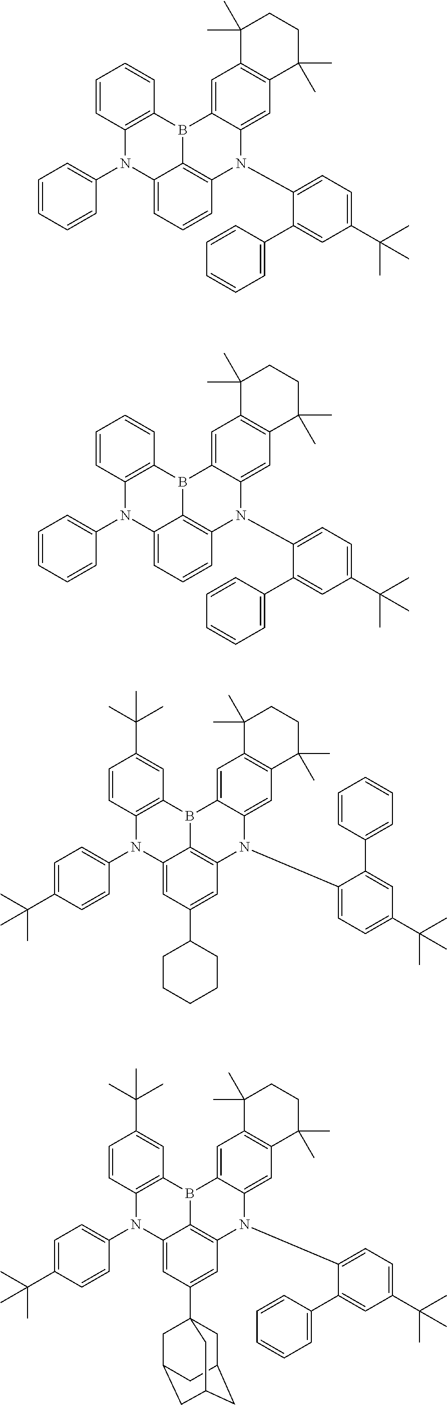

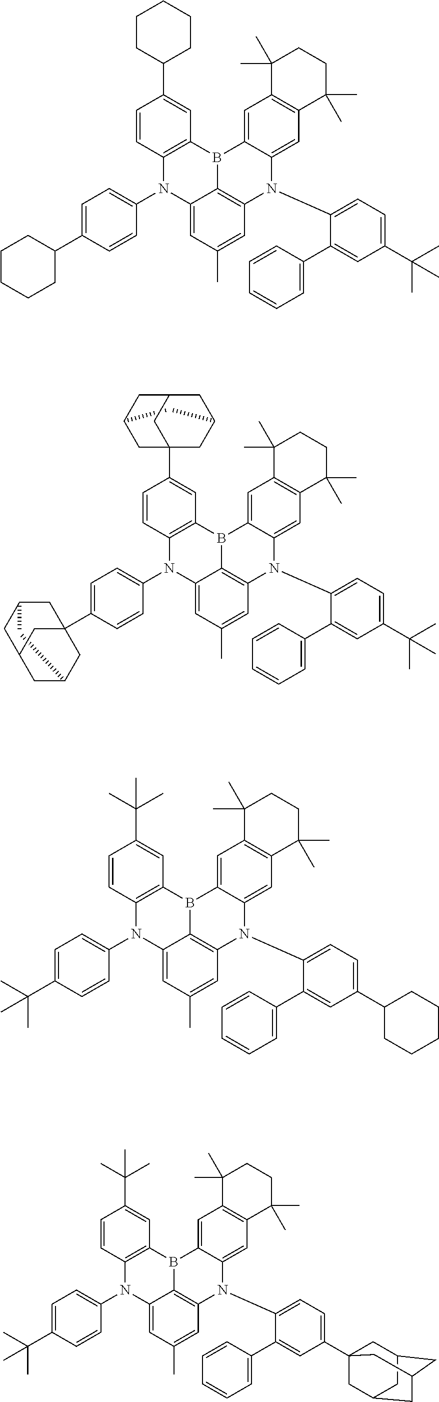

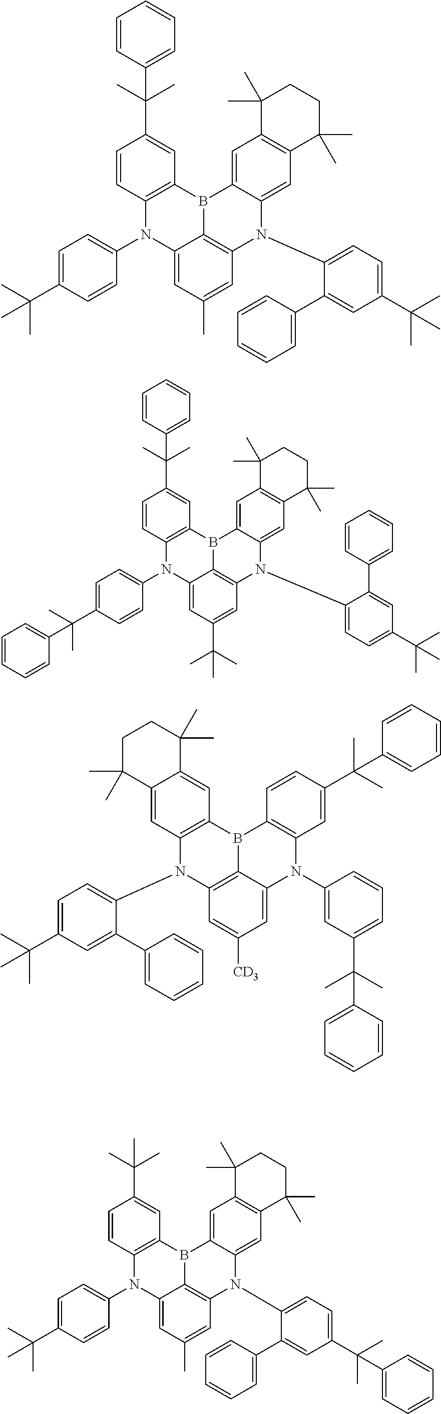

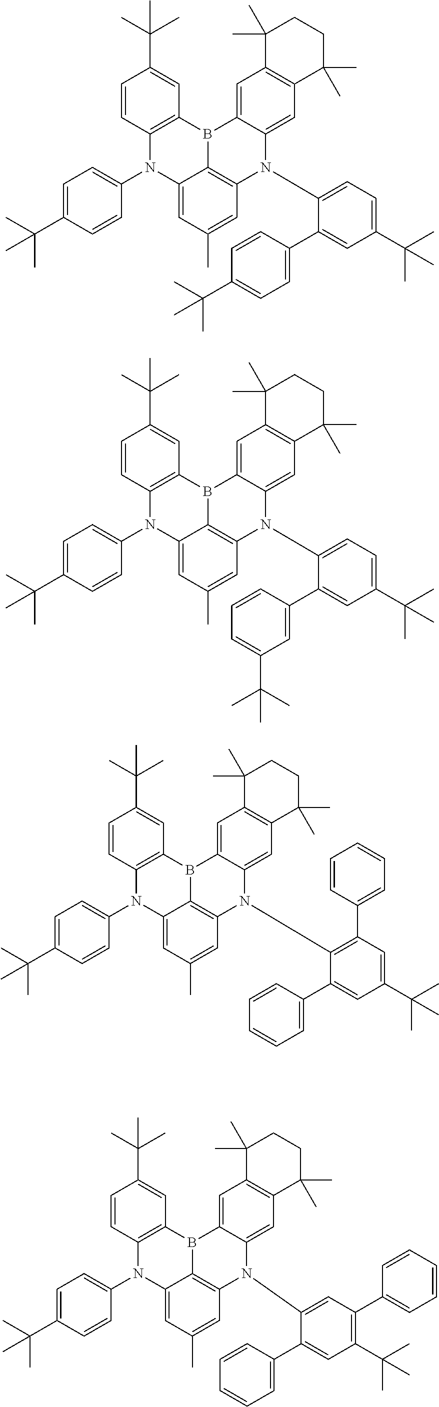

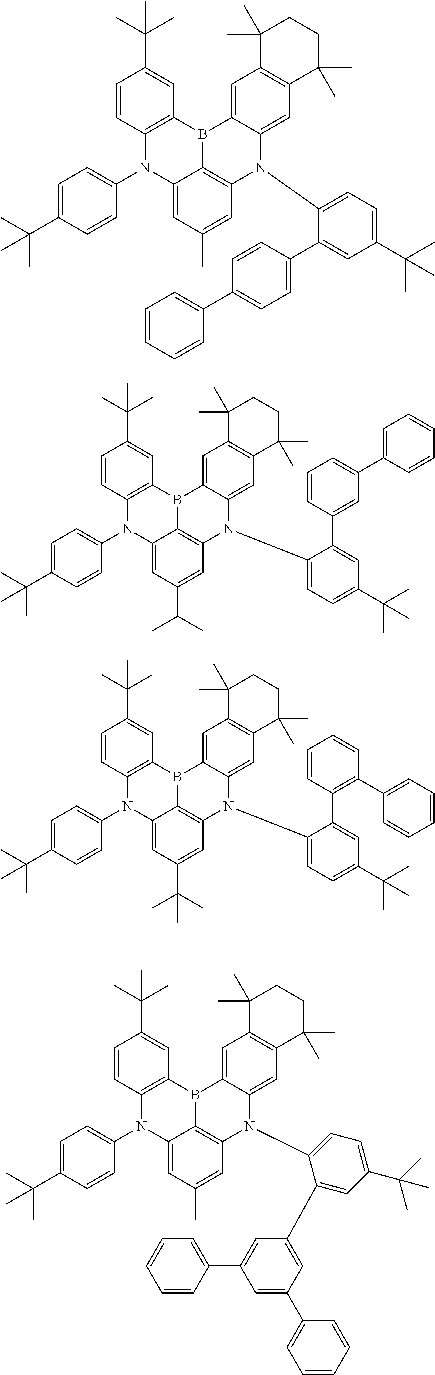

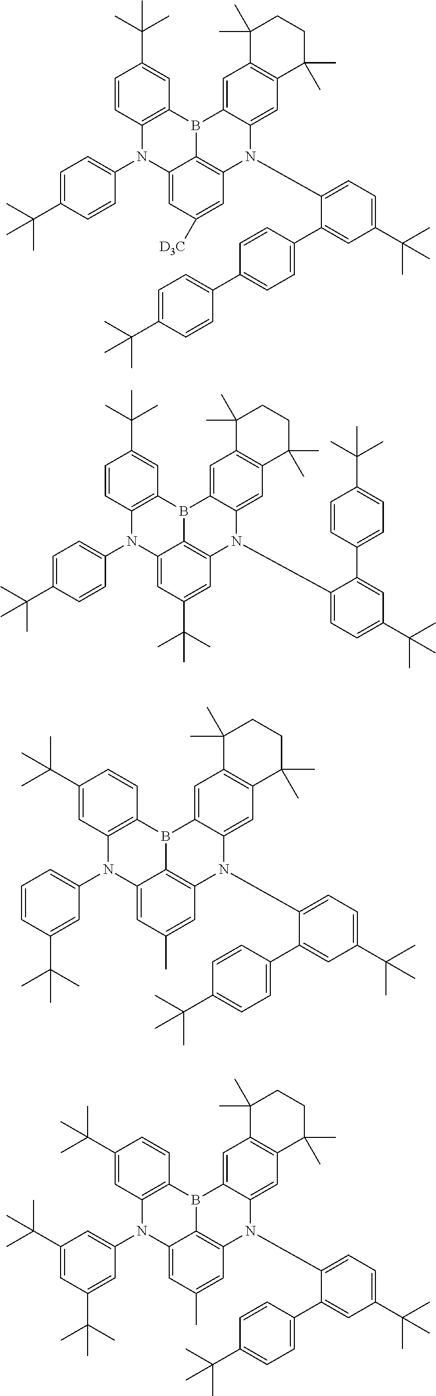

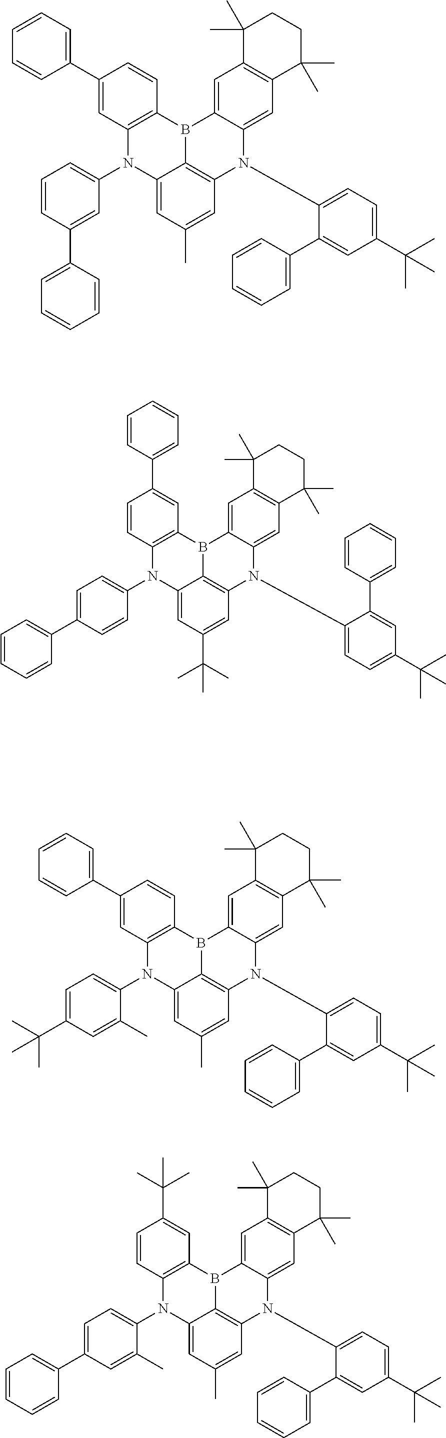

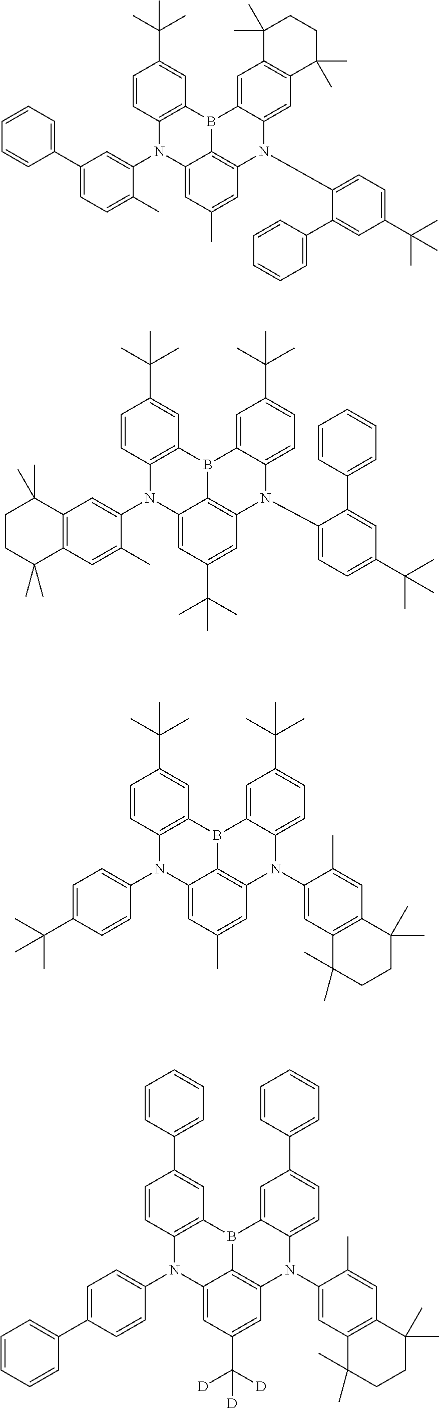

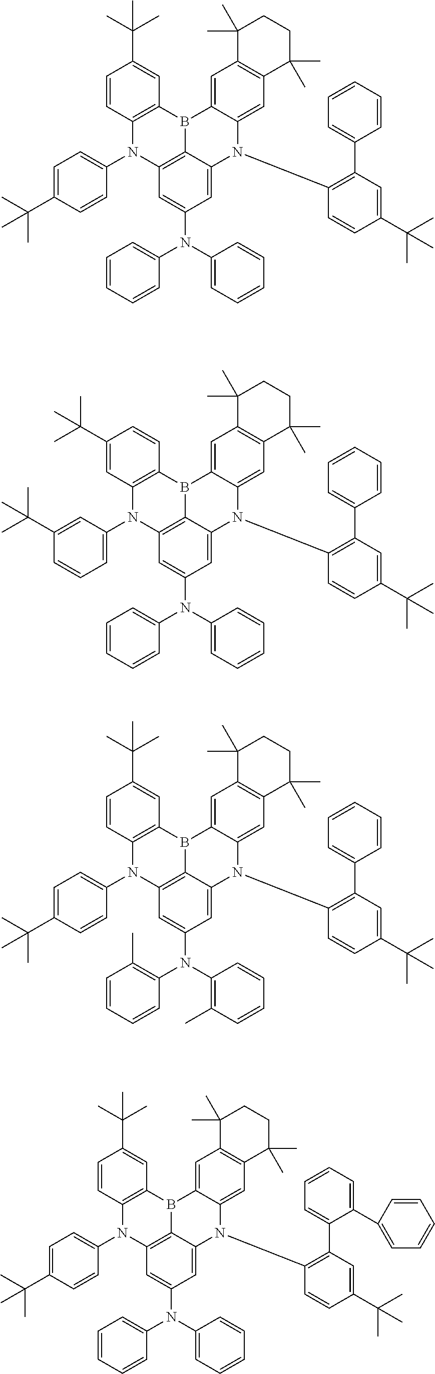

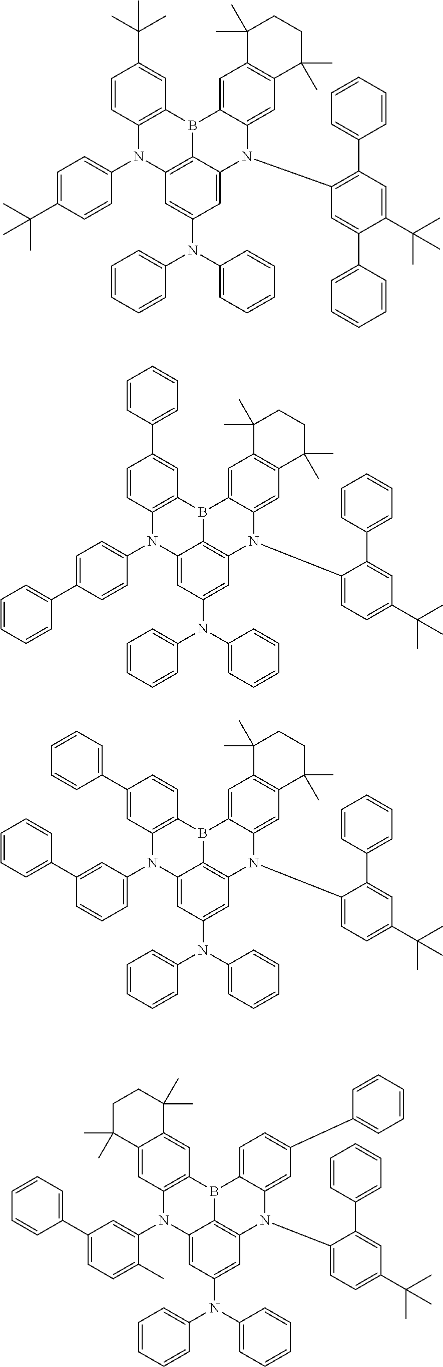

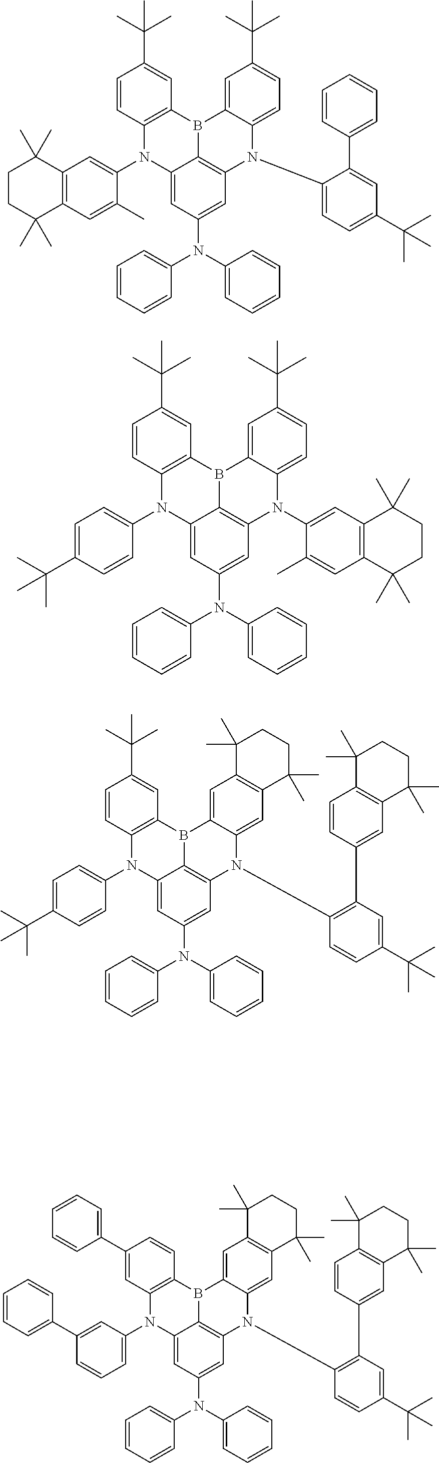

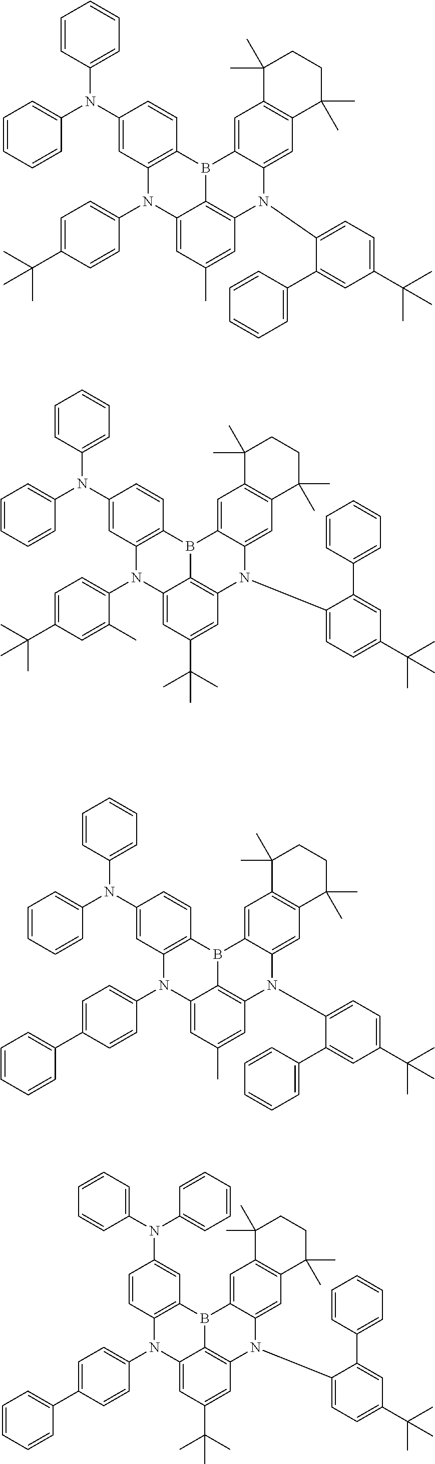

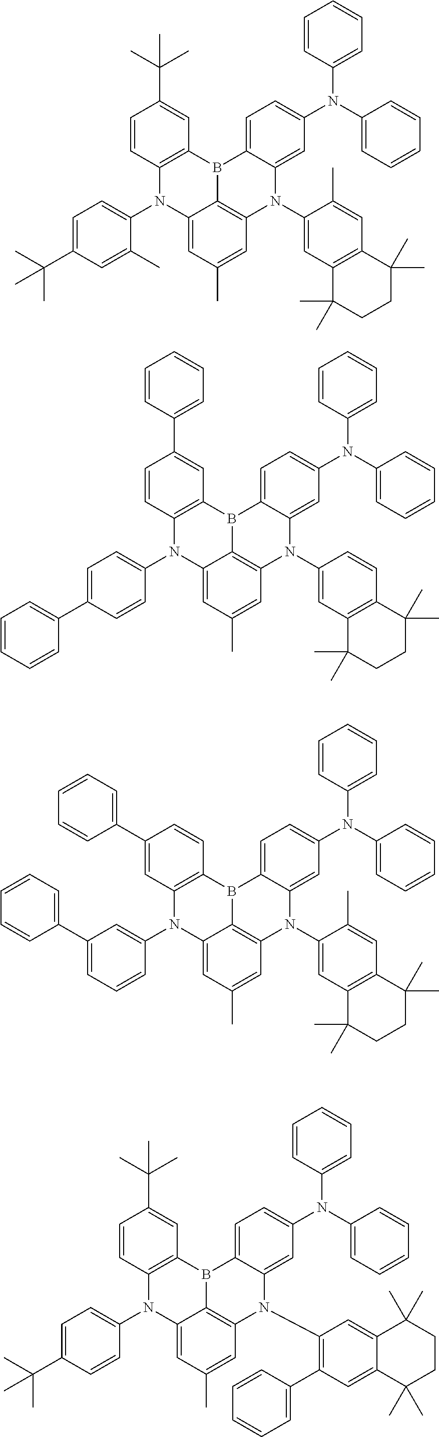

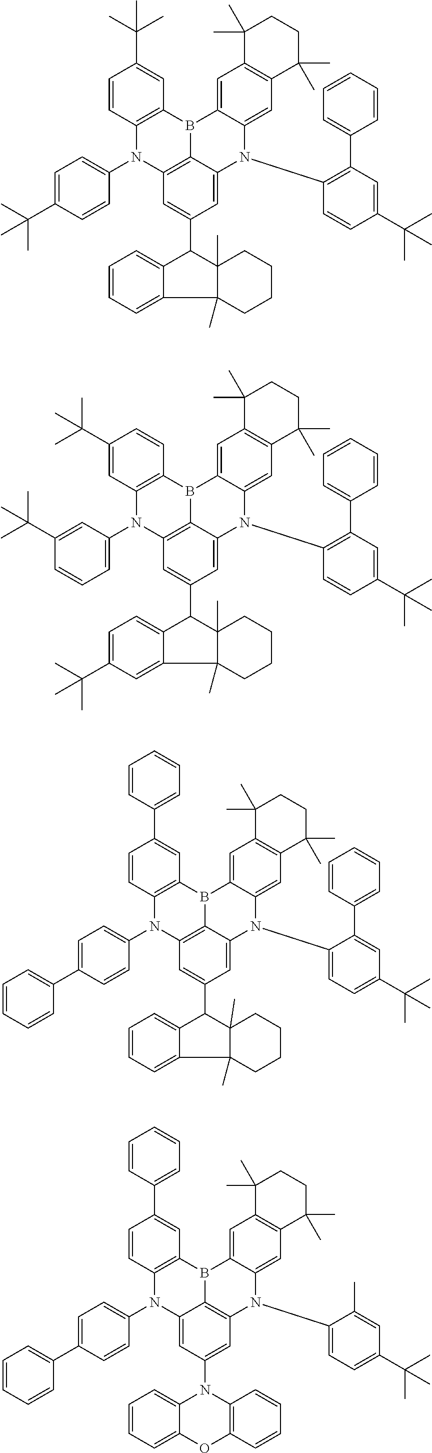

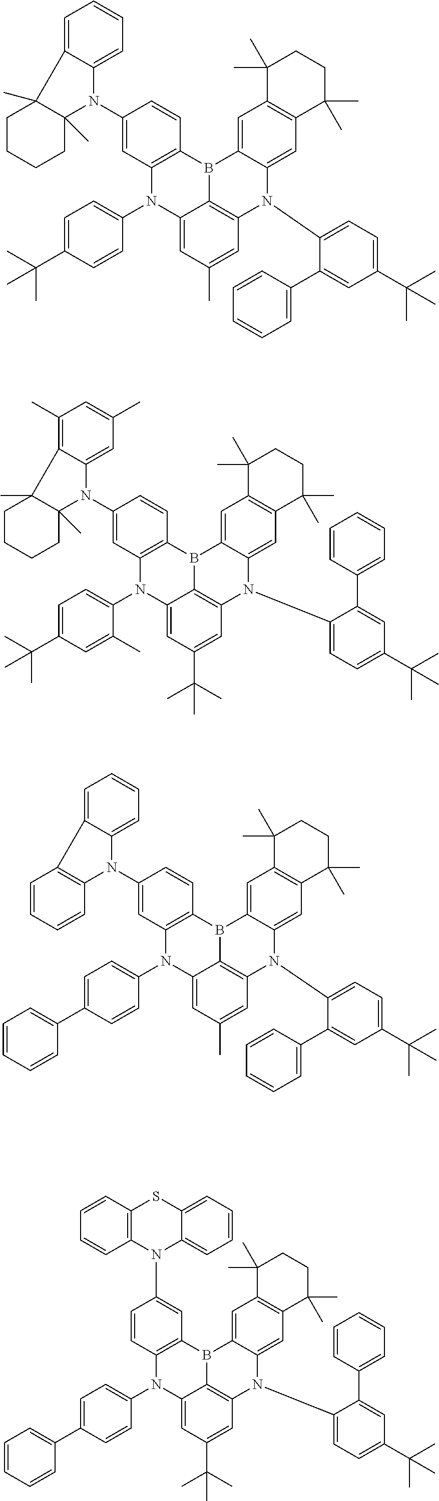

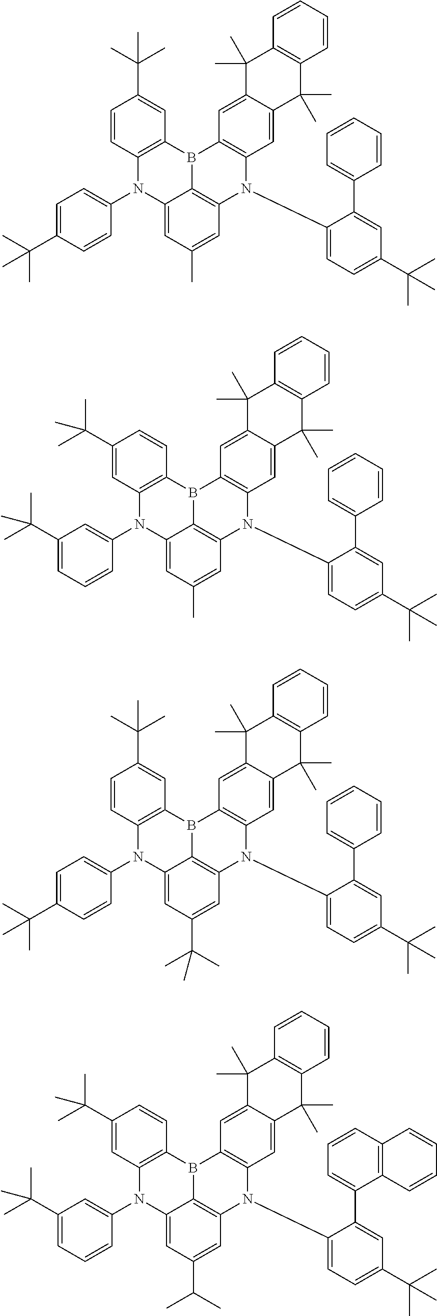

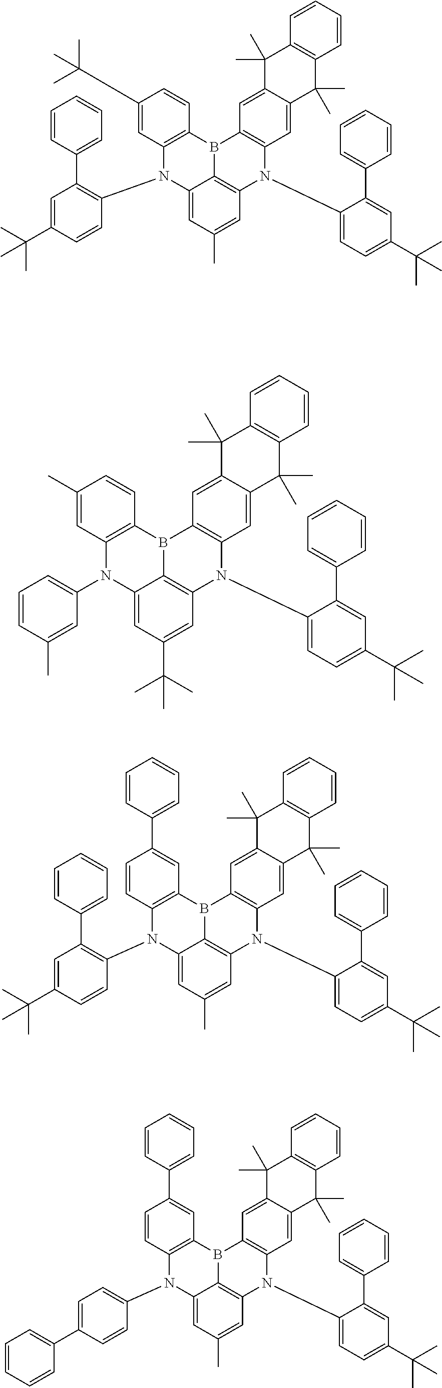

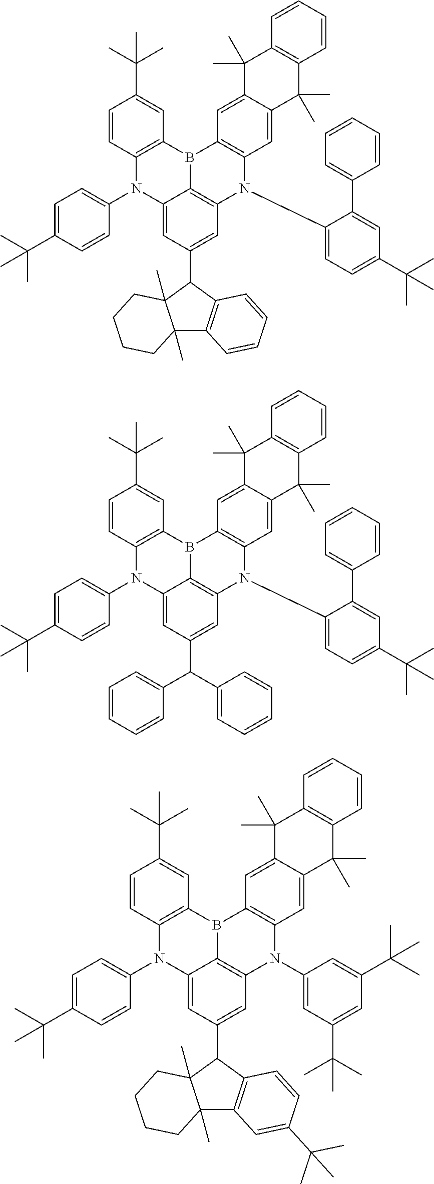

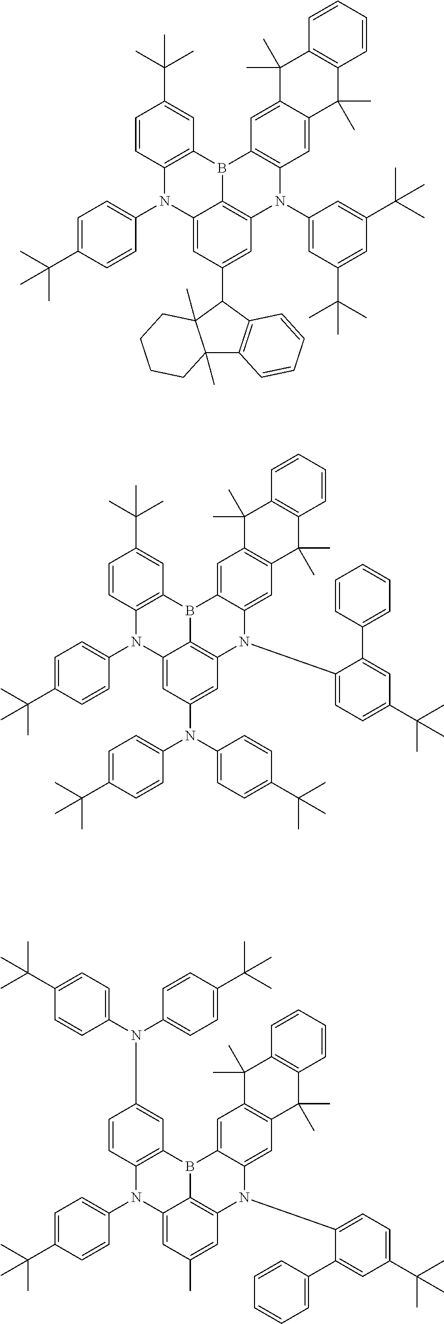

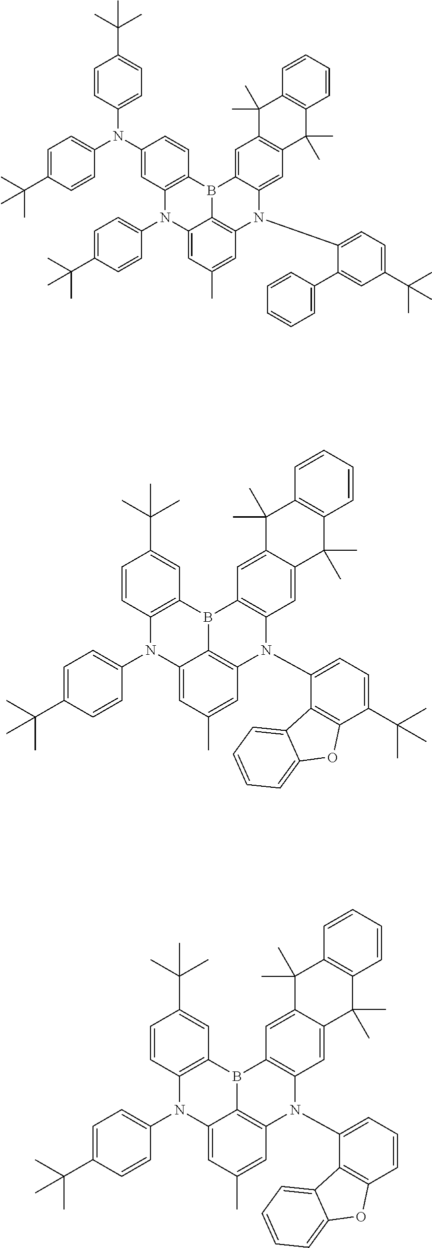

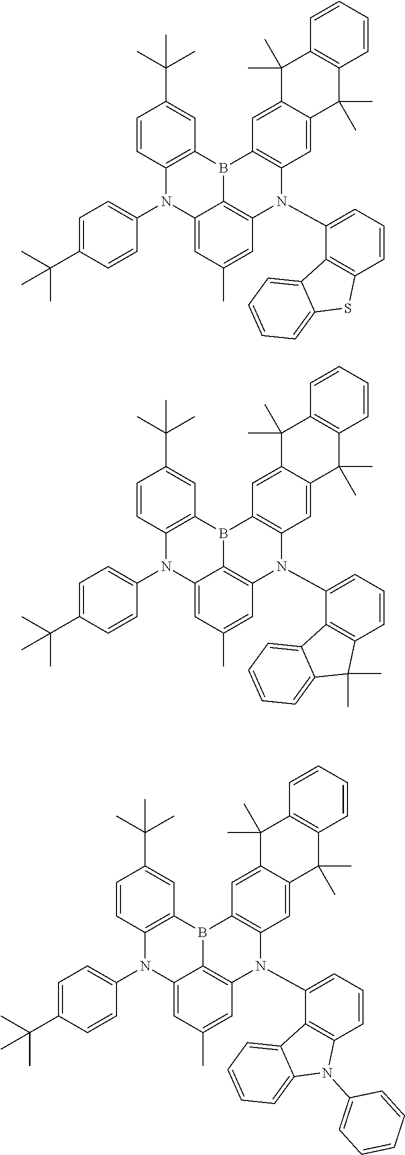 [SMILES: Cc1cc2c3c(c1)N(c1cccc4sc5ccccc5c14)c1cc4c(cc1B3c1cc(C(C)(C)C)ccc1N2c1ccc(C(C)(C)C)cc1)C(C)(C)c1ccccc1C4(C)C ; Cc1cc2c3c(c1)N(c1cccc4c1-c1ccccc1C4(C)C)c1cc4c(cc1B3c1cc(C(C)(C)C)ccc1N2c1ccc(C(C)(C)C)cc1)C(C)(C)c1ccccc1C4(C)C ; Cc1cc2c3c(c1)N(c1cccc4c1c1ccccc1n4-c1ccccc1)c1cc4c(cc1B3c1cc(C(C)(C)C)ccc1N2c1ccc(C(C)(C)C)cc1)C(C)(C)c1ccccc1C4(C)C]

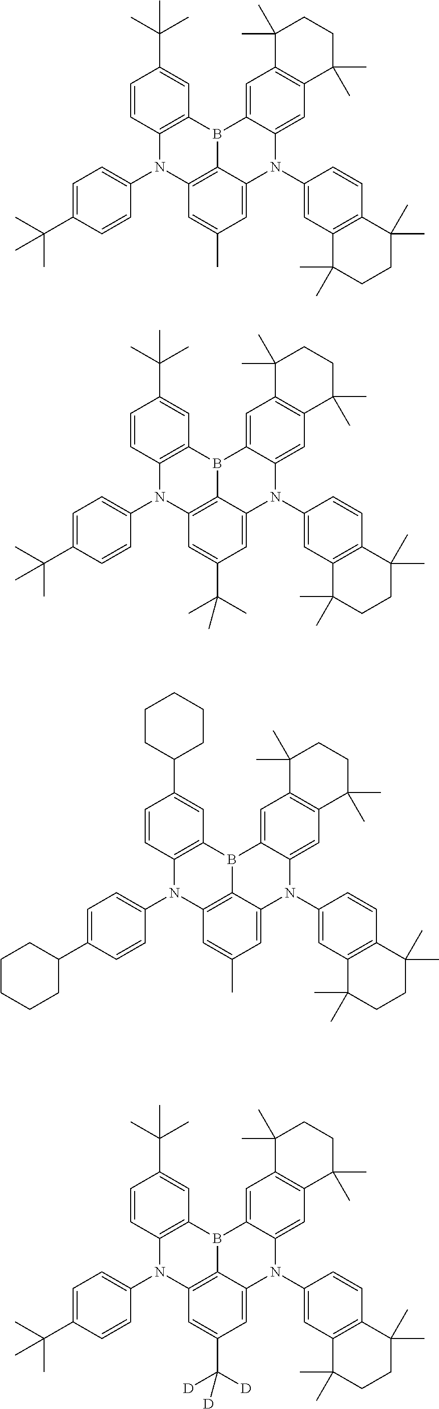

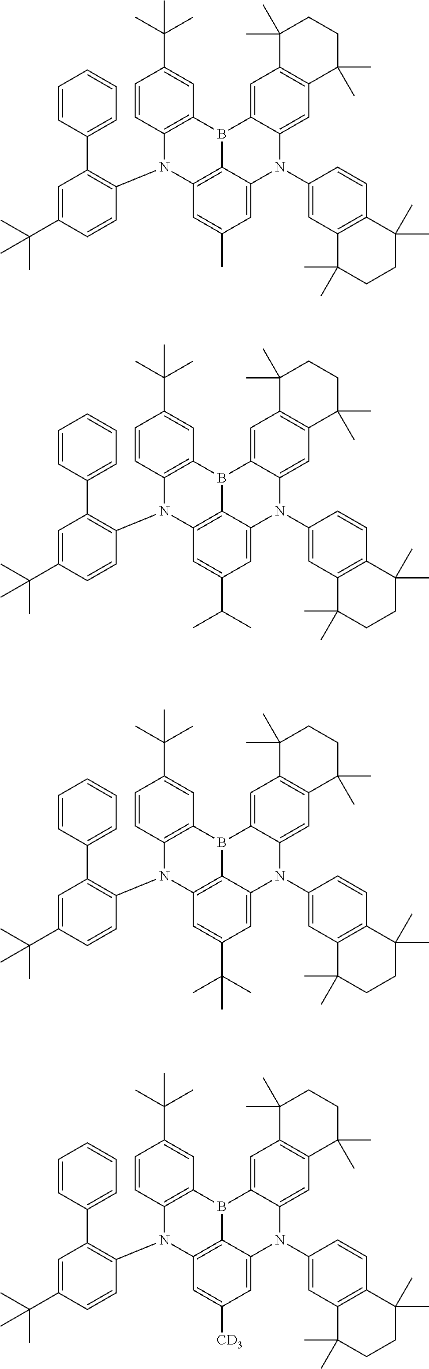

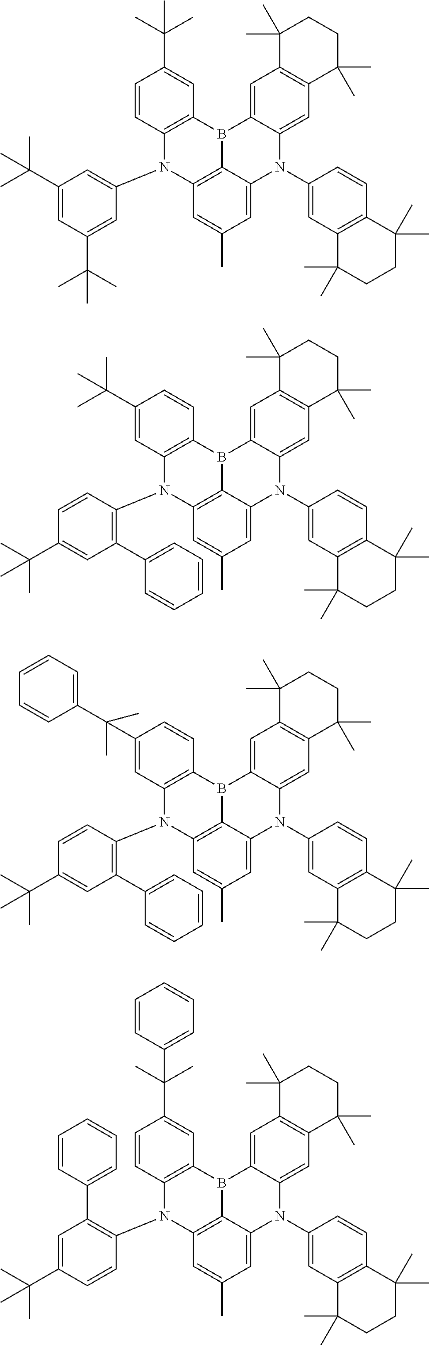

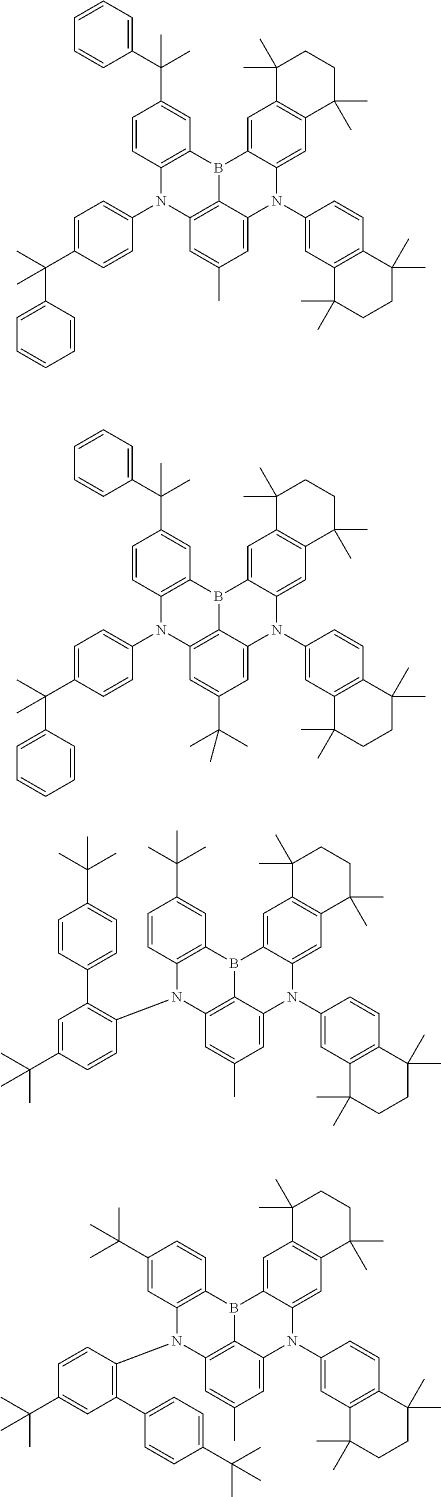

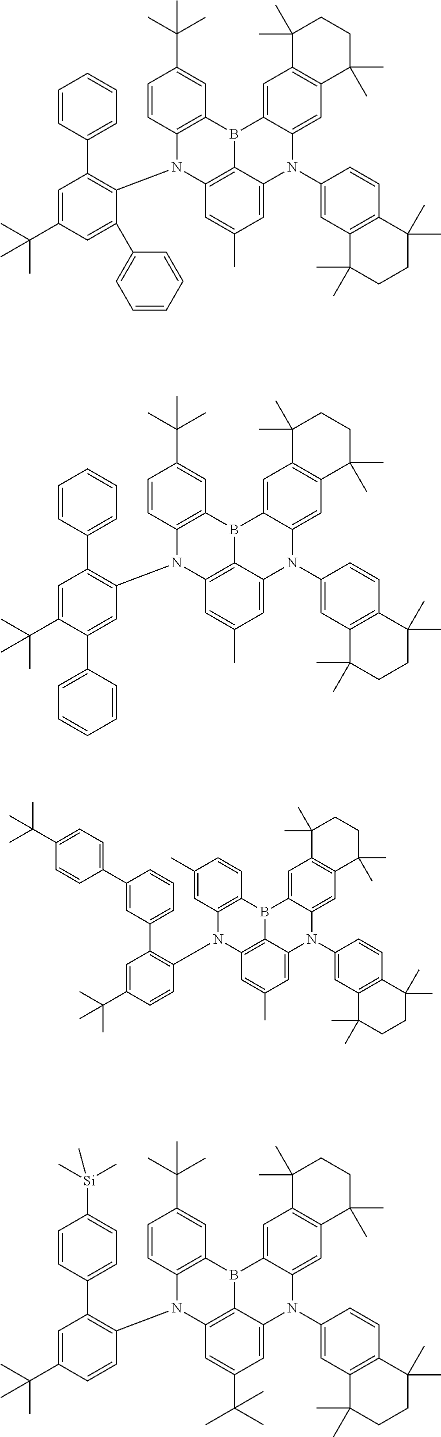

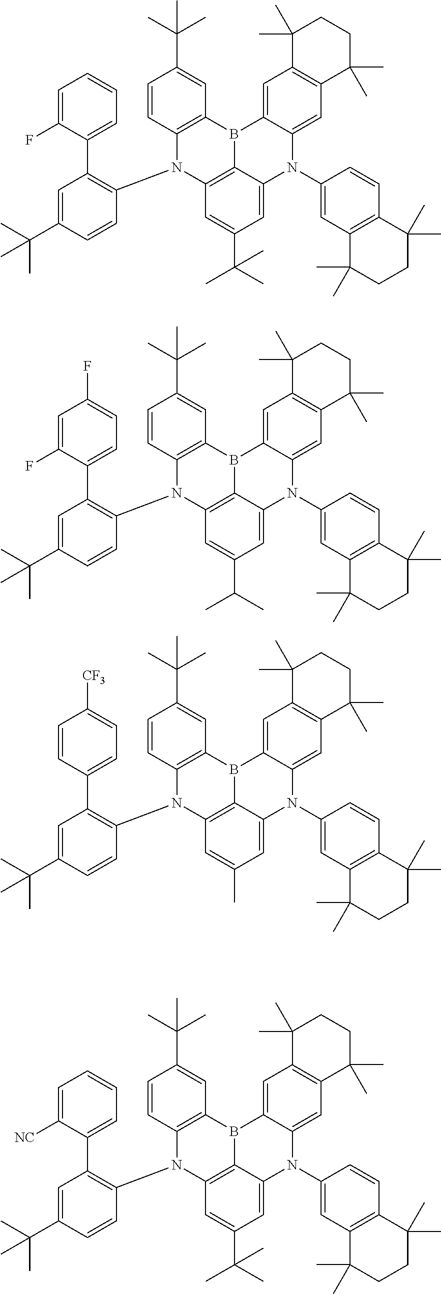

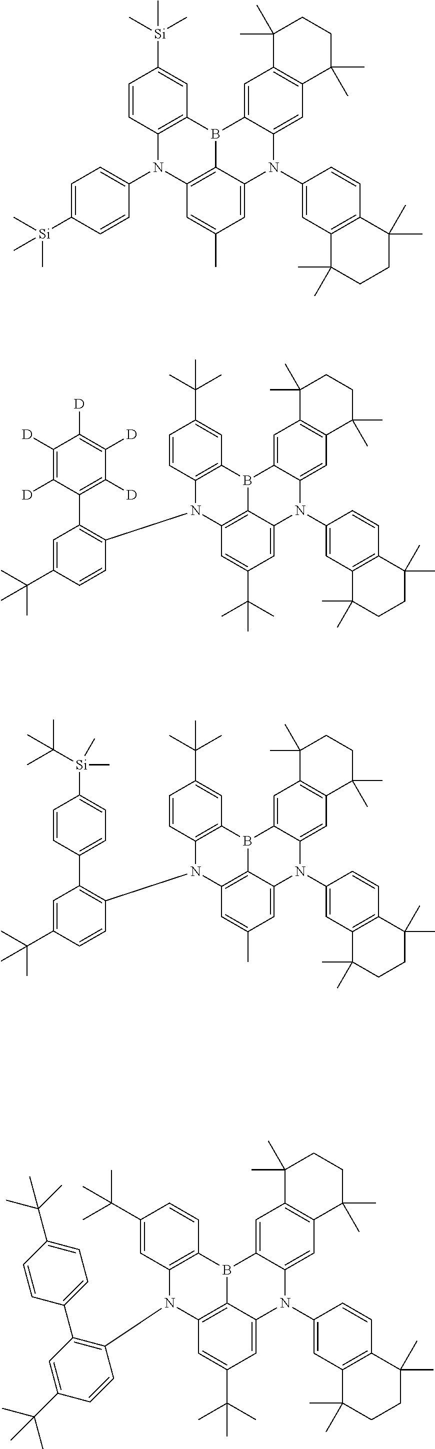

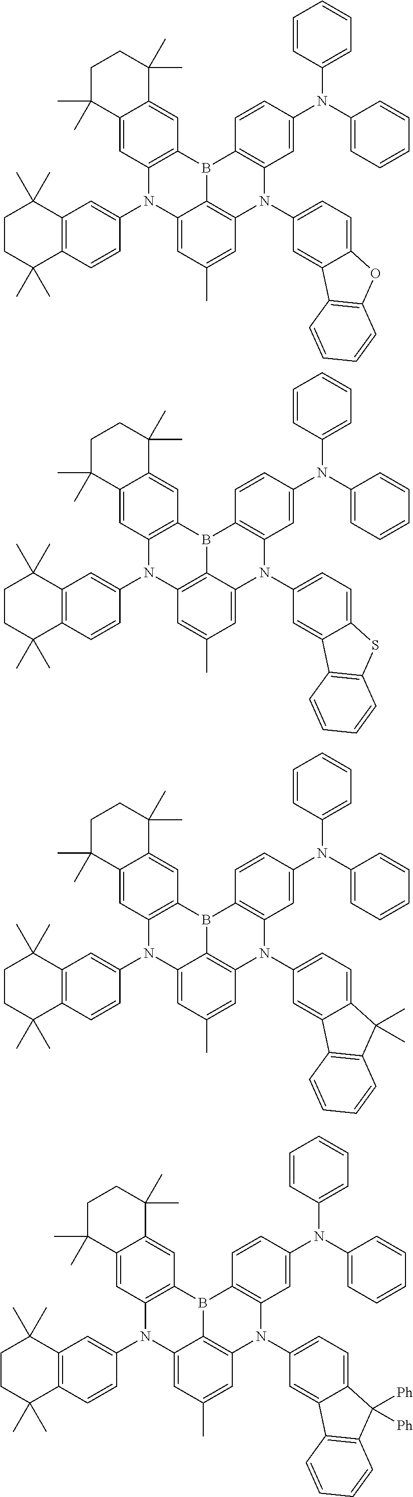

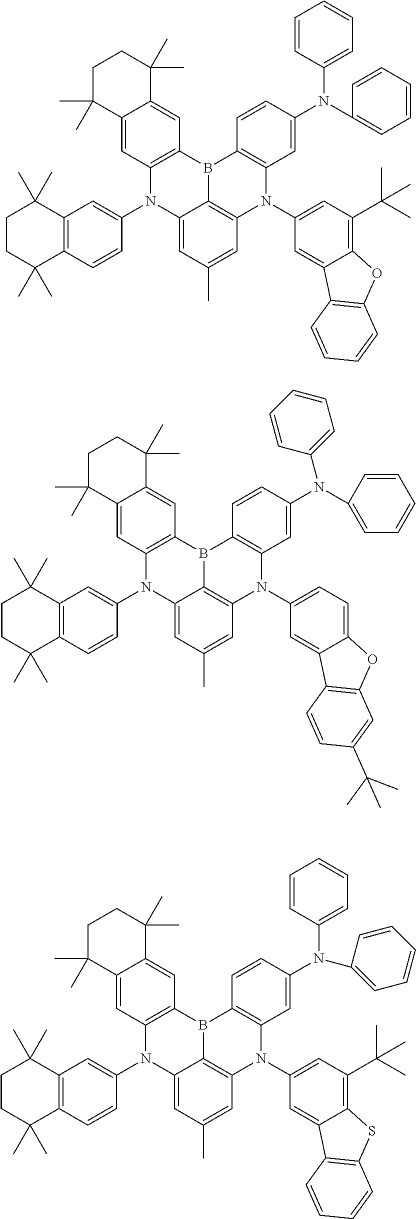

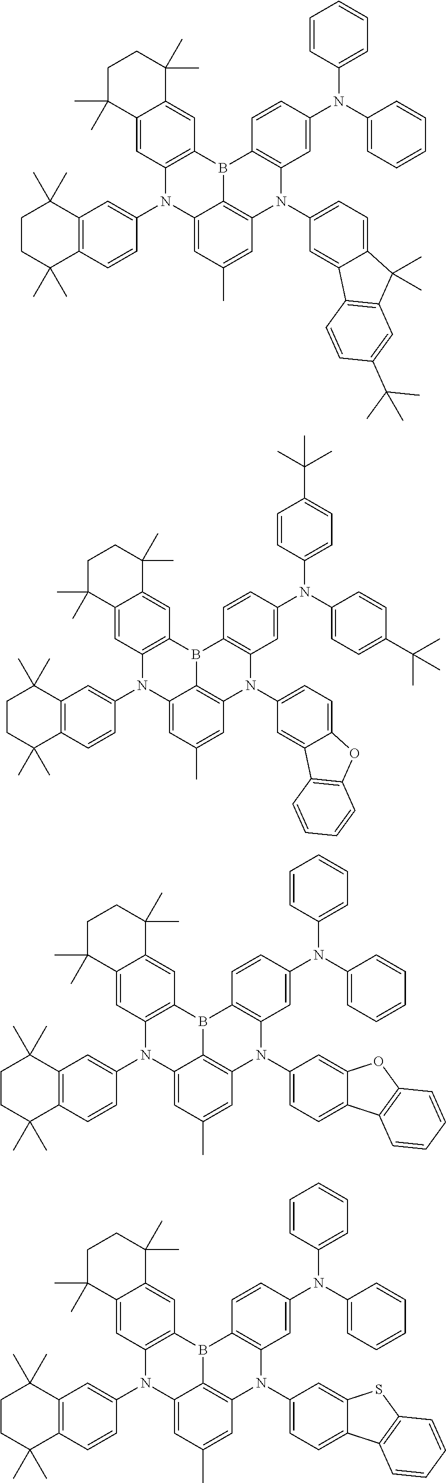

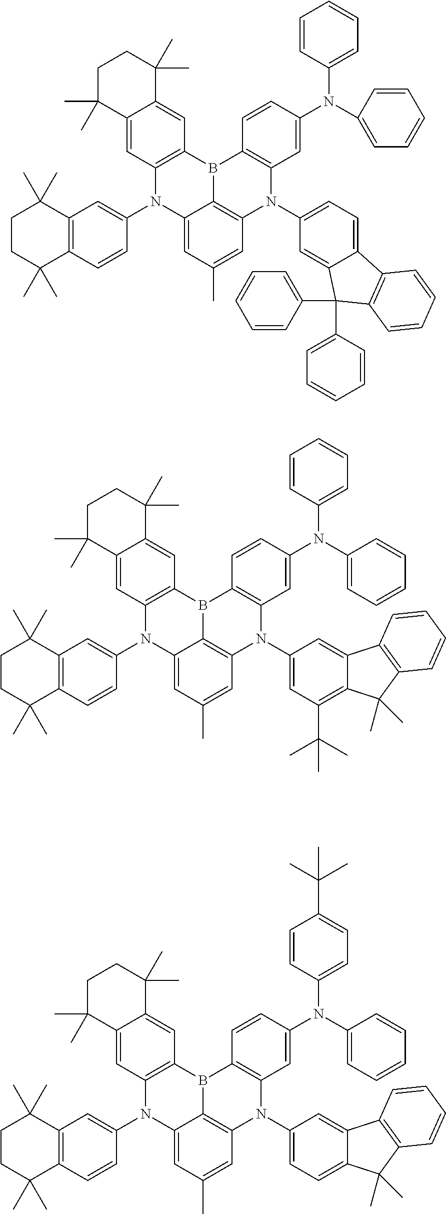

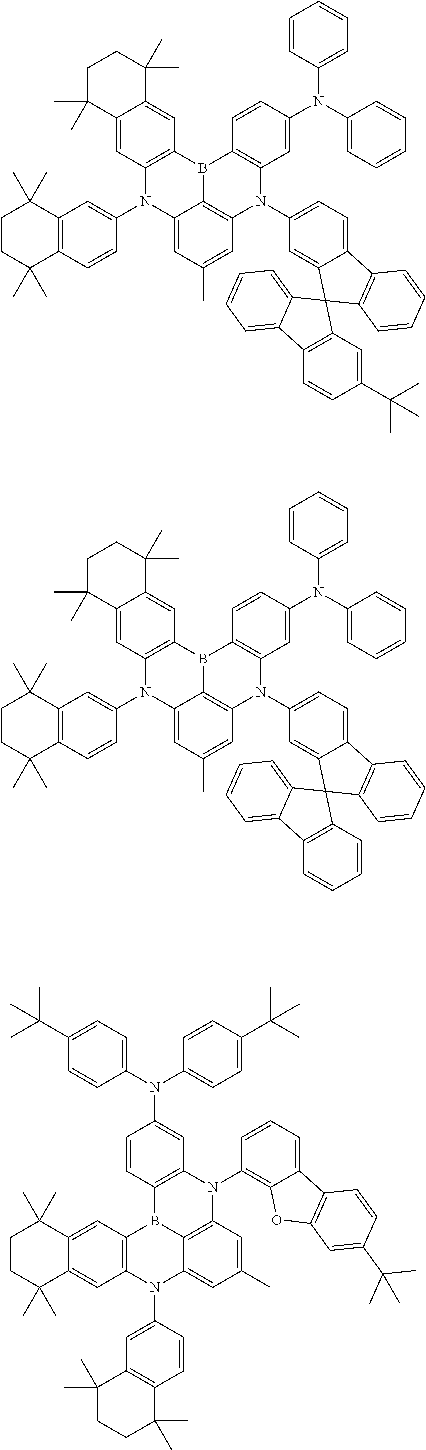 [SMILES: Cc1cc2c3c(c1)N(c1ccc4c(c1)C(C)(C)CCC4(C)C)c1cc4c(cc1B3c1ccc(N(c3ccccc3)c3ccccc3)cc1N2c1ccc2c(c1)C1(c3ccccc3-2)c2ccccc2-c2ccc(C(C)(C)C)cc21)C(C)(C)CCC4(C)C ; Cc1cc2c3c(c1)N(c1ccc4c(c1)C(C)(C)CCC4(C)C)c1cc4c(cc1B3c1ccc(N(c3ccccc3)c3ccccc3)cc1N2c1ccc2c(c1)C1(c3ccccc3-c3ccccc31)c1ccccc1-2)C(C)(C)CCC4(C)C ; Cc1cc2c3c(c1)N(c1cccc4c1oc1cc(C(C)(C)C)ccc14)c1cc(N(c4ccc(C(C)(C)C)cc4)c4ccc(C(C)(C)C)cc4)ccc1B3c1cc3c(cc1N2c1ccc2c(c1)C(C)(C)CCC2(C)C)C(C)(C)CCC3(C)C]

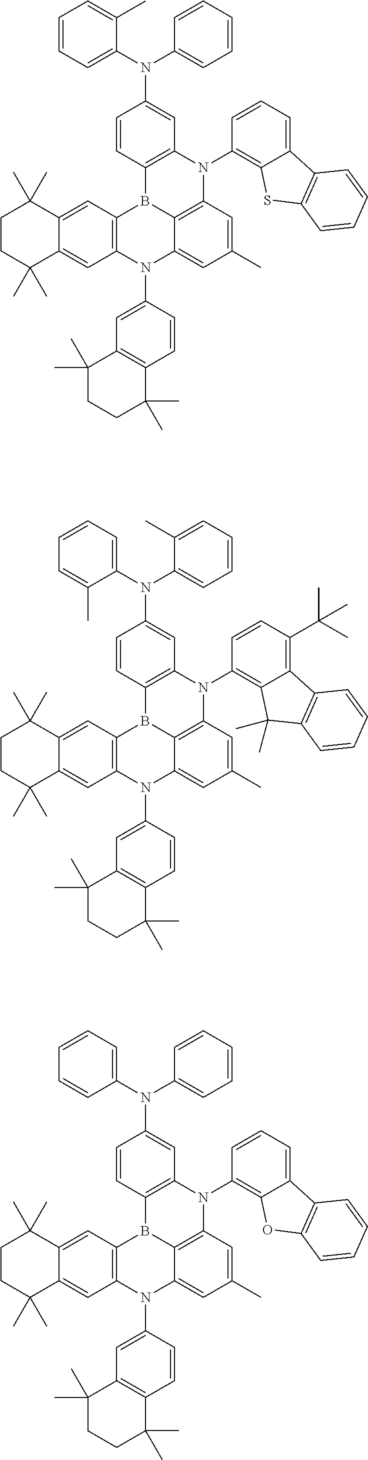 [SMILES: Cc1cc2c3c(c1)N(c1cccc4c1sc1ccccc14)c1cc(N(c4ccccc4)c4ccccc4C)ccc1B3c1cc3c(cc1N2c1ccc2c(c1)C(C)(C)CCC2(C)C)C(C)(C)CCC3(C)C ; Cc1cc2c3c(c1)N(c1ccc(C(C)(C)C)c4c1C(C)(C)c1ccccc1-4)c1cc(N(c4ccccc4C)c4ccccc4C)ccc1B3c1cc3c(cc1N2c1ccc2c(c1)C(C)(C)CCC2(C)C)C(C)(C)CCC3(C)C ; Cc1cc2c3c(c1)N(c1cccc4c1oc1ccccc14)c1cc(N(c4ccccc4)c4ccccc4)ccc1B3c1cc3c(cc1N2c1ccc2c(c1)C(C)(C)CCC2(C)C)C(C)(C)CCC3(C)C]

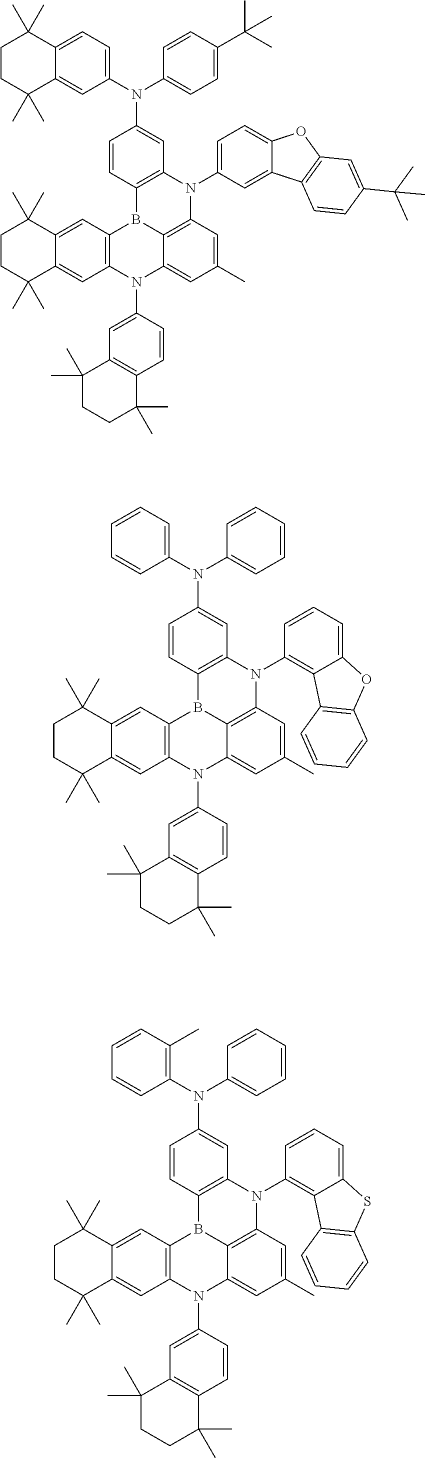 [SMILES: Cc1cc2c3c(c1)N(c1ccc4c(c1)C(C)(C)CCC4(C)C)c1cc4c(cc1B3c1ccc(N(c3ccc(C(C)(C)C)cc3)c3ccc5c(c3)C(C)(C)CCC5(C)C)cc1N2c1ccc2oc3cc(C(C)(C)C)ccc3c2c1)C(C)(C)CCC4(C)C ; Cc1cc2c3c(c1)N(c1cccc4oc5ccccc5c14)c1cc(N(c4ccccc4)c4ccccc4)ccc1B3c1cc3c(cc1N2c1ccc2c(c1)C(C)(C)CCC2(C)C)C(C)(C)CCC3(C)C ; Cc1cc2c3c(c1)N(c1cccc4sc5ccccc5c14)c1cc(N(c4ccccc4)c4ccccc4C)ccc1B3c1cc3c(cc1N2c1ccc2c(c1)C(C)(C)CCC2(C)C)C(C)(C)CCC3(C)C]

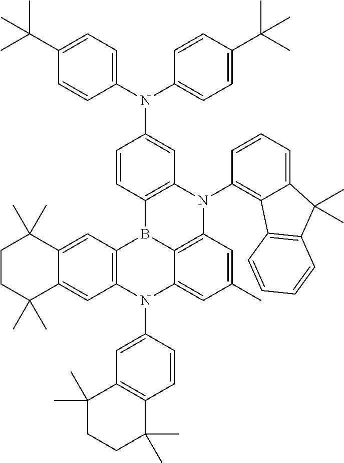 [SMILES: Cc1cc2c3c(c1)N(c1cccc4c1-c1ccccc1C4(C)C)c1cc(N(c4ccc(C(C)(C)C)cc4)c4ccc(C(C)(C)C)cc4)ccc1B3c1cc3c(cc1N2c1ccc2c(c1)C(C)(C)CCC2(C)C)C(C)(C)CCC3(C)C]

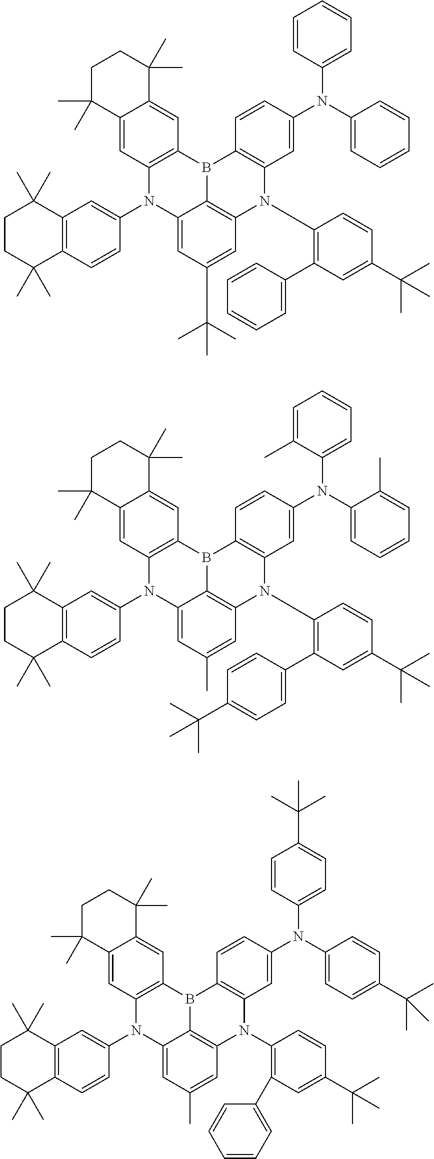 [SMILES: CC(C)(C)c1ccc(N2c3cc(N(c4ccccc4)c4ccccc4)ccc3B3c4cc5c(cc4N(c4ccc6c(c4)C(C)(C)CCC6(C)C)c4cc(C(C)(C)C)cc2c43)C(C)(C)CCC5(C)C)c(-c2ccccc2)c1 ; Cc1cc2c3c(c1)N(c1ccc(C(C)(C)C)cc1-c1ccc(C(C)(C)C)cc1)c1cc(N(c4ccccc4C)c4ccccc4C)ccc1B3c1cc3c(cc1N2c1ccc2c(c1)C(C)(C)CCC2(C)C)C(C)(C)CCC3(C)C ; Cc1cc2c3c(c1)N(c1ccc(C(C)(C)C)cc1-c1ccccc1)c1cc(N(c4ccc(C(C)(C)C)cc4)c4ccc(C(C)(C)C)cc4)ccc1B3c1cc3c(cc1N2c1ccc2c(c1)C(C)(C)CCC2(C)C)C(C)(C)CCC3(C)C]

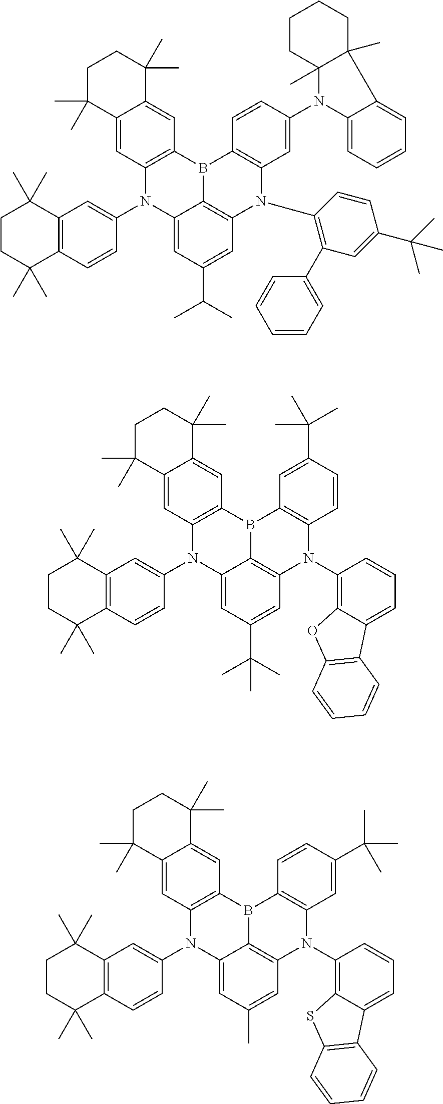 [SMILES: CC(C)c1cc2c3c(c1)N(c1ccc(C(C)(C)C)cc1-c1ccccc1)c1cc(N4c5ccccc5C5(C)CCCCC45C)ccc1B3c1cc3c(cc1N2c1ccc2c(c1)C(C)(C)CCC2(C)C)C(C)(C)CCC3(C)C ; CC(C)(C)c1ccc2c(c1)B1c3cc4c(cc3N(c3ccc5c(c3)C(C)(C)CCC5(C)C)c3cc(C(C)(C)C)cc(c31)N2c1cccc2c1oc1ccccc12)C(C)(C)CCC4(C)C ; Cc1cc2c3c(c1)N(c1cccc4c1sc1ccccc14)c1cc(C(C)(C)C)ccc1B3c1cc3c(cc1N2c1ccc2c(c1)C(C)(C)CCC2(C)C)C(C)(C)CCC3(C)C]

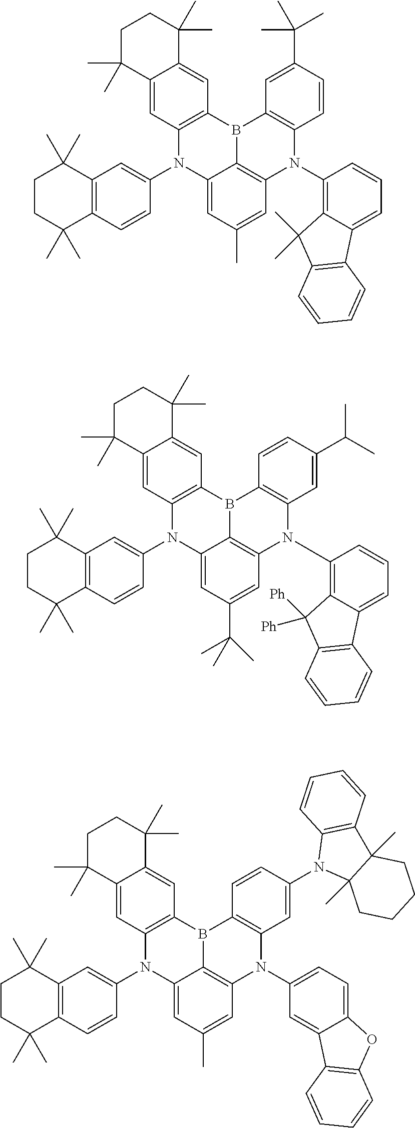 [SMILES: Cc1cc2c3c(c1)N(c1cccc4c1C(C)(C)c1ccccc1-4)c1ccc(C(C)(C)C)cc1B3c1cc3c(cc1N2c1ccc2c(c1)C(C)(C)CCC2(C)C)C(C)(C)CCC3(C)C ; CC(C)c1ccc2c(c1)N(c1cccc3c1C(c1ccccc1)(c1ccccc1)c1ccccc1-3)c1cc(C(C)(C)C)cc3c1B2c1cc2c(cc1N3c1ccc3c(c1)C(C)(C)CCC3(C)C)C(C)(C)CCC2(C)C ; Cc1cc2c3c(c1)N(c1ccc4c(c1)C(C)(C)CCC4(C)C)c1cc4c(cc1B3c1ccc(N3c5ccccc5C5(C)CCCCC35C)cc1N2c1ccc2oc3ccccc3c2c1)C(C)(C)CCC4(C)C]

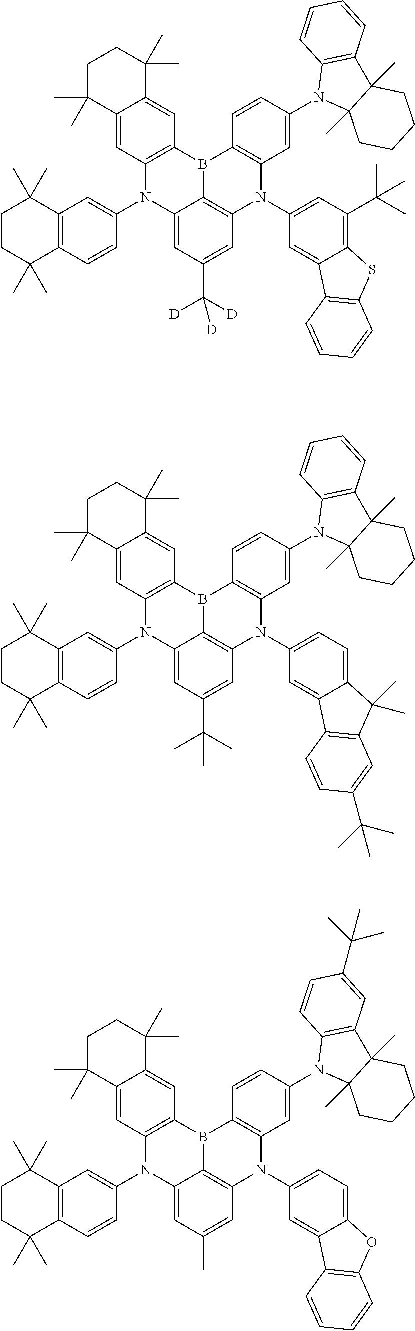 [SMILES: [2H]C([2H])([2H])c1cc2c3c(c1)N(c1ccc4c(c1)C(C)(C)CCC4(C)C)c1cc4c(cc1B3c1ccc(N3c5ccccc5C5(C)CCCCC35C)cc1N2c1cc(C(C)(C)C)c2sc3ccccc3c2c1)C(C)(C)CCC4(C)C ; CC(C)(C)c1cc2c3c(c1)N(c1ccc4c(c1)C(C)(C)CCC4(C)C)c1cc4c(cc1B3c1ccc(N3c5ccccc5C5(C)CCCCC35C)cc1N2c1ccc2c(c1)-c1ccc(C(C)(C)C)cc1C2(C)C)C(C)(C)CCC4(C)C ; Cc1cc2c3c(c1)N(c1ccc4c(c1)C(C)(C)CCC4(C)C)c1cc4c(cc1B3c1ccc(N3c5ccc(C(C)(C)C)cc5C5(C)CCCCC35C)cc1N2c1ccc2oc3ccccc3c2c1)C(C)(C)CCC4(C)C]

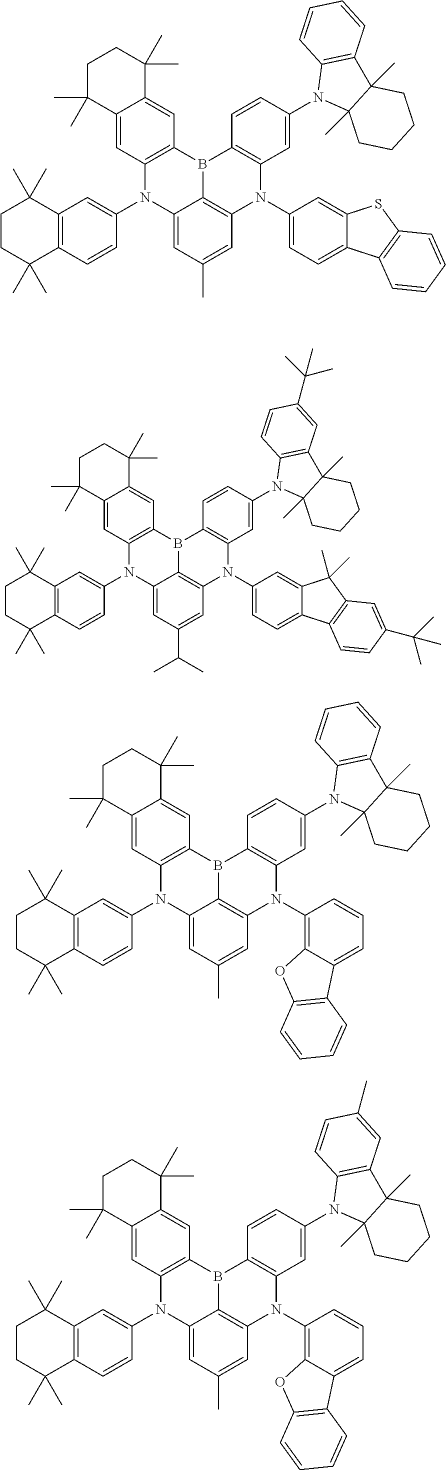

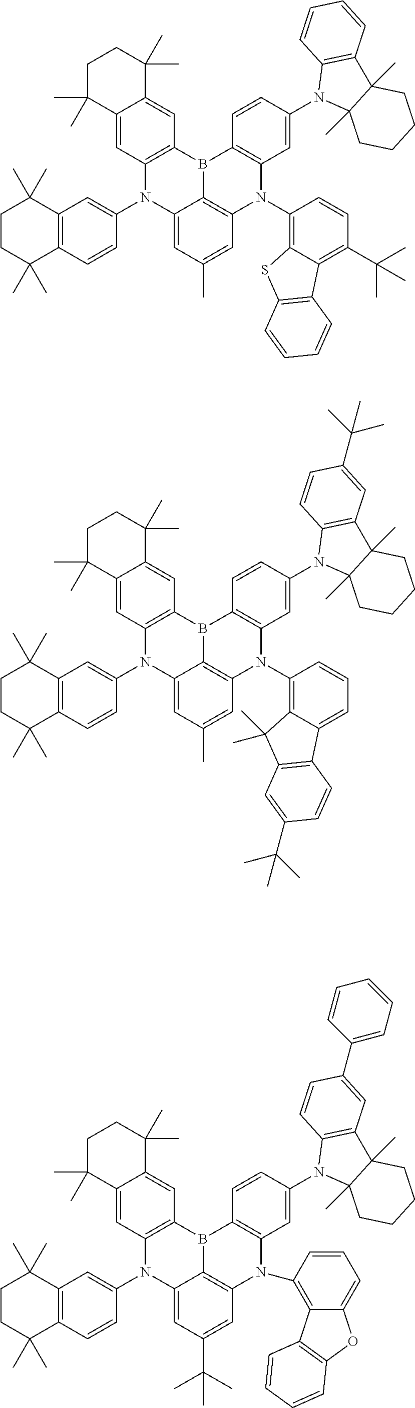 [SMILES: Cc1cc2c3c(c1)N(c1ccc(C(C)(C)C)c4c1sc1ccccc14)c1cc(N4c5ccccc5C5(C)CCCCC45C)ccc1B3c1cc3c(cc1N2c1ccc2c(c1)C(C)(C)CCC2(C)C)C(C)(C)CCC3(C)C ; Cc1cc2c3c(c1)N(c1cccc4c1C(C)(C)c1cc(C(C)(C)C)ccc1-4)c1cc(N4c5ccc(C(C)(C)C)cc5C5(C)CCCCC45C)ccc1B3c1cc3c(cc1N2c1ccc2c(c1)C(C)(C)CCC2(C)C)C(C)(C)CCC3(C)C ; CC(C)(C)c1cc2c3c(c1)N(c1cccc4oc5ccccc5c14)c1cc(N4c5ccc(-c6ccccc6)cc5C5(C)CCCCC45C)ccc1B3c1cc3c(cc1N2c1ccc2c(c1)C(C)(C)CCC2(C)C)C(C)(C)CCC3(C)C]

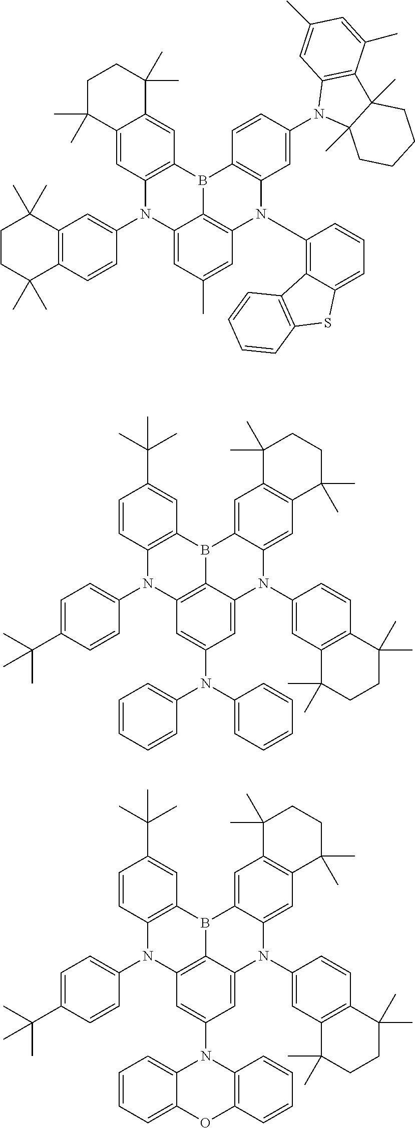

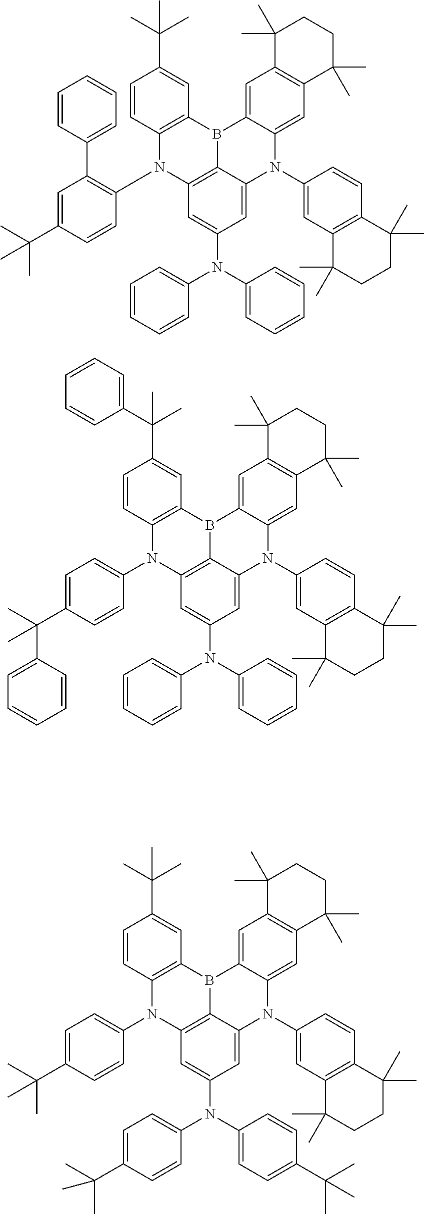

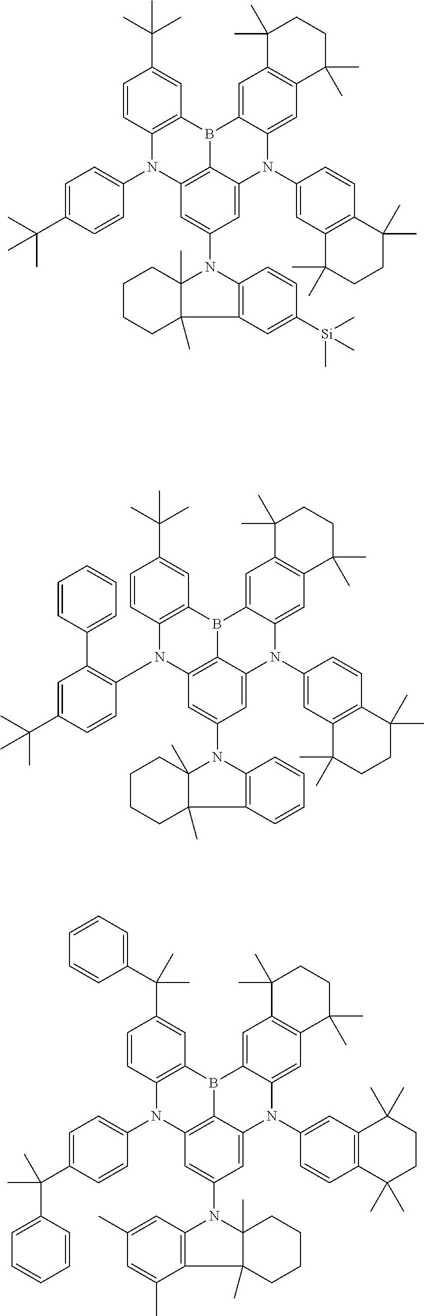

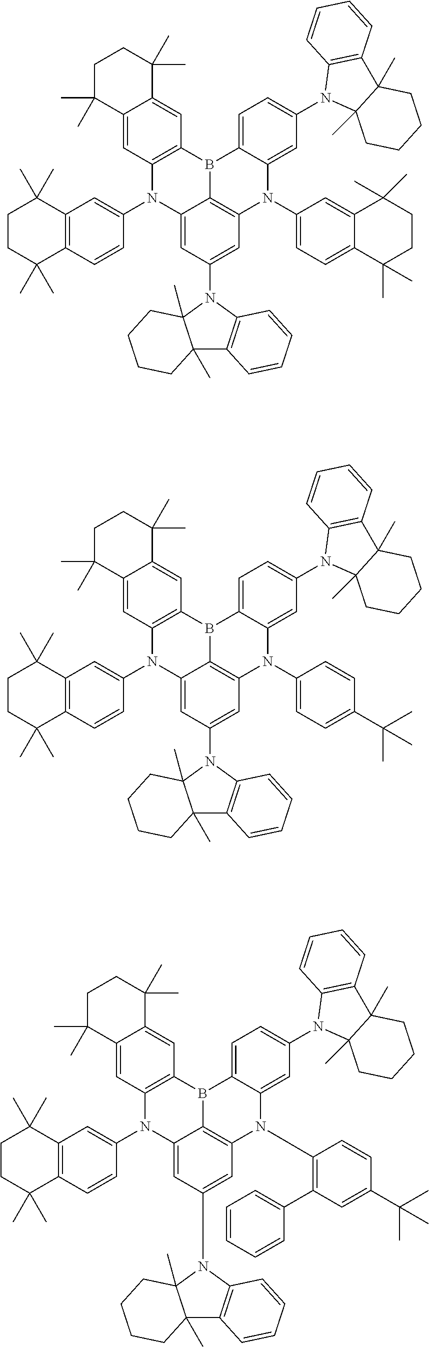 [SMILES: CC1(C)CCC(C)(C)c2cc(N3c4cc(N5c6ccccc6C6(C)CCCCC56C)ccc4B4c5cc6c(cc5N(c5ccc7c(c5)C(C)(C)CCC7(C)C)c5cc(N7c8ccccc8C8(C)CCCCC78C)cc3c54)C(C)(C)CCC6(C)C)ccc21 ; CC(C)(C)c1ccc(N2c3cc(N4c5ccccc5C5(C)CCCCC45C)ccc3B3c4cc5c(cc4N(c4ccc6c(c4)C(C)(C)CCC6(C)C)c4cc(N6c7ccccc7C7(C)CCCCC67C)cc2c43)C(C)(C)CCC5(C)C)cc1 ; CC(C)(C)c1ccc(N2c3cc(N4c5ccccc5C5(C)CCCCC45C)ccc3B3c4cc5c(cc4N(c4ccc6c(c4)C(C)(C)CCC6(C)C)c4cc(N6c7ccccc7C7(C)CCCCC67C)cc2c43)C(C)(C)CCC5(C)C)c(-c2ccccc2)c1]

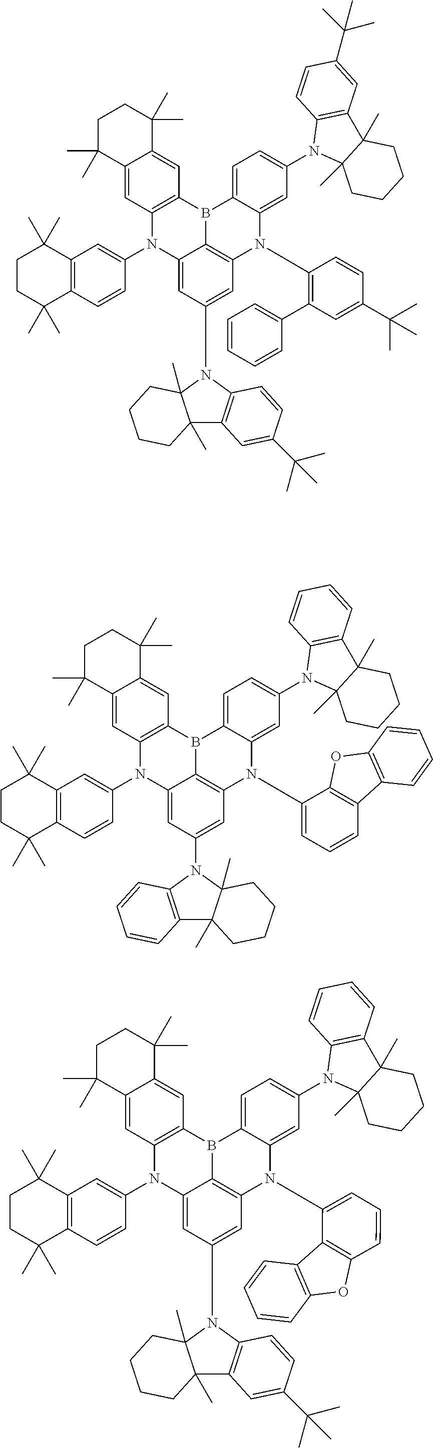 [SMILES: CC(C)(C)c1ccc(N2c3cc(N4c5ccc(C(C)(C)C)cc5C5(C)CCCCC45C)ccc3B3c4cc5c(cc4N(c4ccc6c(c4)C(C)(C)CCC6(C)C)c4cc(N6c7ccc(C(C)(C)C)cc7C7(C)CCCCC67C)cc2c43)C(C)(C)CCC5(C)C)c(-c2ccccc2)c1 ; CC1(C)CCC(C)(C)c2cc(N3c4cc5c(cc4B4c6ccc(N7c8ccccc8C8(C)CCCCC78C)cc6N(c6cccc7c6oc6ccccc67)c6cc(N7c8ccccc8C8(C)CCCCC78C)cc3c64)C(C)(C)CCC5(C)C)ccc21 ; CC(C)(C)c1ccc2c(c1)C1(C)CCCCC1(C)N2c1cc2c3c(c1)N(c1cccc4oc5ccccc5c14)c1cc(N4c5ccccc5C5(C)CCCCC45C)ccc1B3c1cc3c(cc1N2c1ccc2c(c1)C(C)(C)CCC2(C)C)C(C)(C)CCC3(C)C]

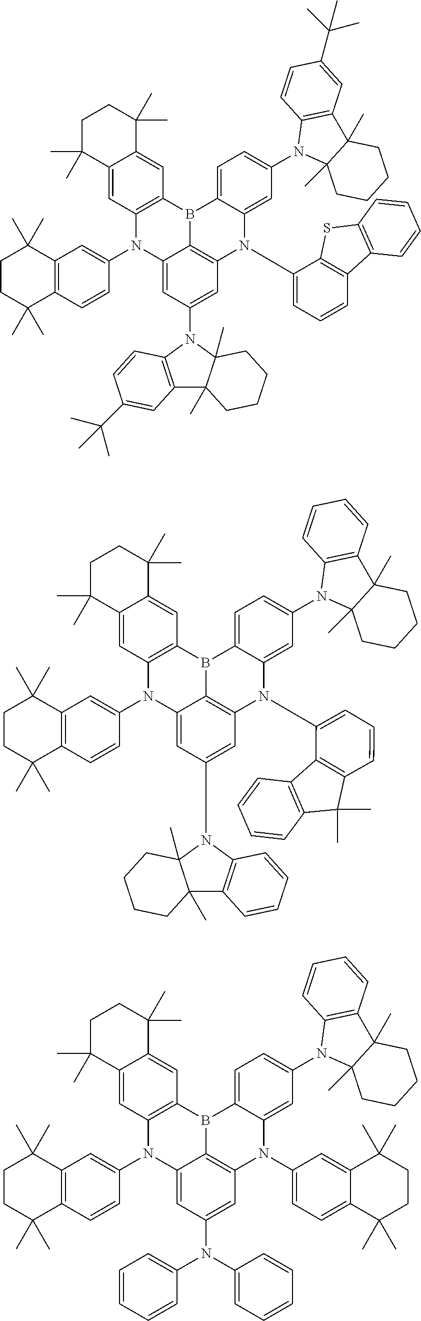 [SMILES: CC(C)(C)c1ccc2c(c1)C1(C)CCCCC1(C)N2c1ccc2c(c1)N(c1cccc3c1sc1ccccc13)c1cc(N3c4ccc(C(C)(C)C)cc4C4(C)CCCCC34C)cc3c1B2c1cc2c(cc1N3c1ccc3c(c1)C(C)(C)CCC3(C)C)C(C)(C)CCC2(C)C ; CC1(C)CCC(C)(C)c2cc(N3c4cc5c(cc4B4c6ccc(N7c8ccccc8C8(C)CCCCC78C)cc6N(c6cccc7c6-c6ccccc6C7(C)C)c6cc(N7c8ccccc8C8(C)CCCCC78C)cc3c64)C(C)(C)CCC5(C)C)ccc21 ; CC1(C)CCC(C)(C)c2cc(N3c4cc(N5c6ccccc6C6(C)CCCCC56C)ccc4B4c5cc6c(cc5N(c5ccc7c(c5)C(C)(C)CCC7(C)C)c5cc(N(c7ccccc7)c7ccccc7)cc3c54)C(C)(C)CCC6(C)C)ccc21]

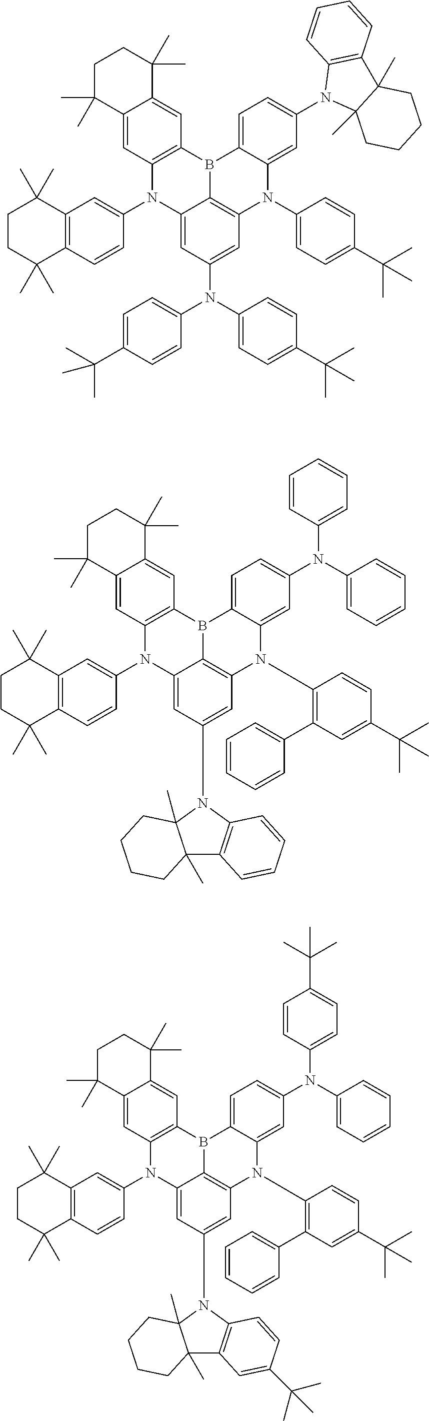 [SMILES: CC(C)(C)c1ccc(N(c2ccc(C(C)(C)C)cc2)c2cc3c4c(c2)N(c2ccc5c(c2)C(C)(C)CCC5(C)C)c2cc5c(cc2B4c2ccc(N4c6ccccc6C6(C)CCCCC46C)cc2N3c2ccc(C(C)(C)C)cc2)C(C)(C)CCC5(C)C)cc1 ; CC(C)(C)c1ccc(N2c3cc(N(c4ccccc4)c4ccccc4)ccc3B3c4cc5c(cc4N(c4ccc6c(c4)C(C)(C)CCC6(C)C)c4cc(N6c7ccccc7C7(C)CCCCC67C)cc2c43)C(C)(C)CCC5(C)C)c(-c2ccccc2)c1 ; CC(C)(C)c1ccc(N(c2ccccc2)c2ccc3c(c2)N(c2ccc(C(C)(C)C)cc2-c2ccccc2)c2cc(N4c5ccc(C(C)(C)C)cc5C5(C)CCCCC45C)cc4c2B3c2cc3c(cc2N4c2ccc4c(c2)C(C)(C)CCC4(C)C)C(C)(C)CCC3(C)C)cc1]

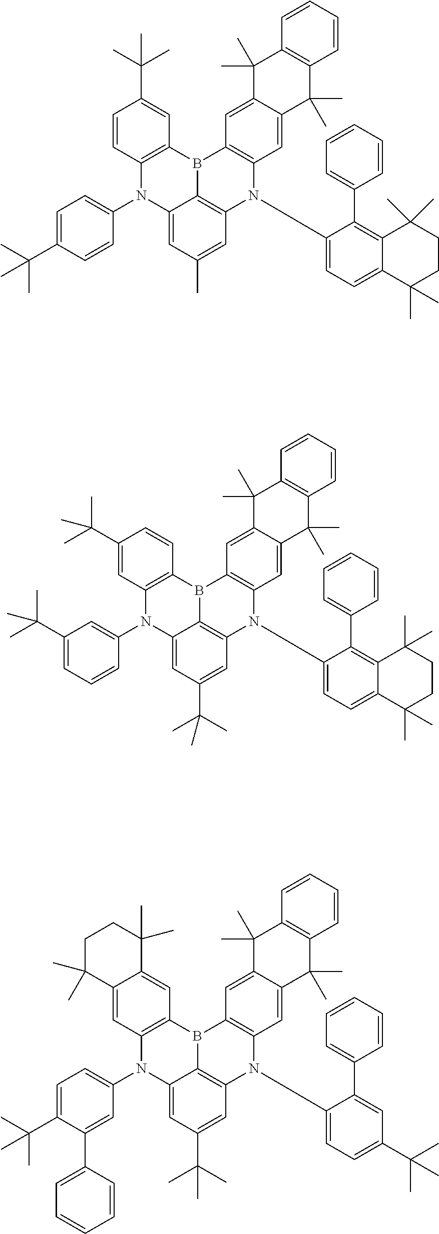

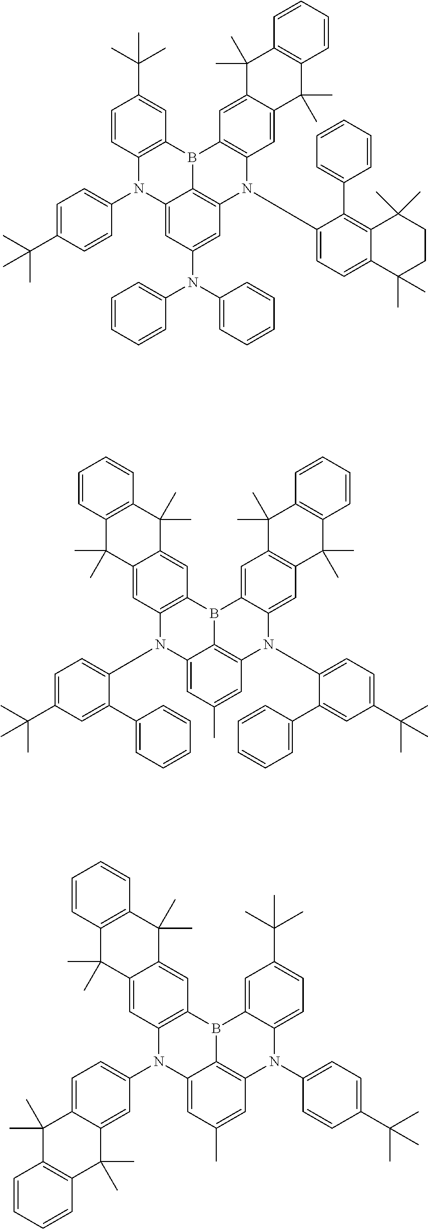

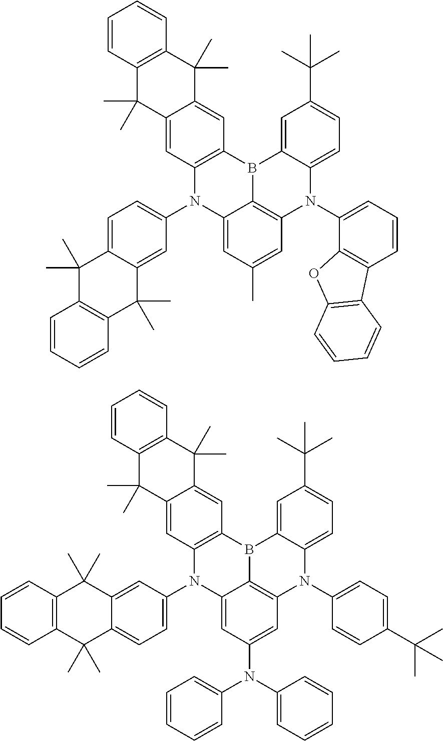 [SMILES: Cc1cc2c3c(c1)N(c1cccc4c1oc1ccccc14)c1ccc(C(C)(C)C)cc1B3c1cc3c(cc1N2c1ccc2c(c1)C(C)(C)c1ccccc1C2(C)C)C(C)(C)c1ccccc1C3(C)C ; CC(C)(C)c1ccc(N2c3ccc(C(C)(C)C)cc3B3c4cc5c(cc4N(c4ccc6c(c4)C(C)(C)c4ccccc4C6(C)C)c4cc(N(c6ccccc6)c6ccccc6)cc2c43)C(C)(C)c2ccccc2C5(C)C)cc1]

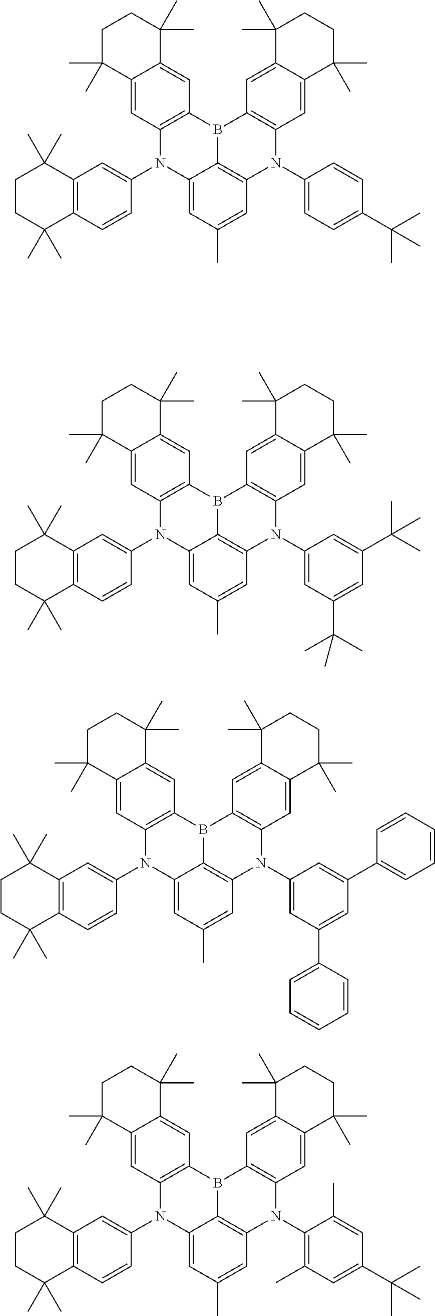

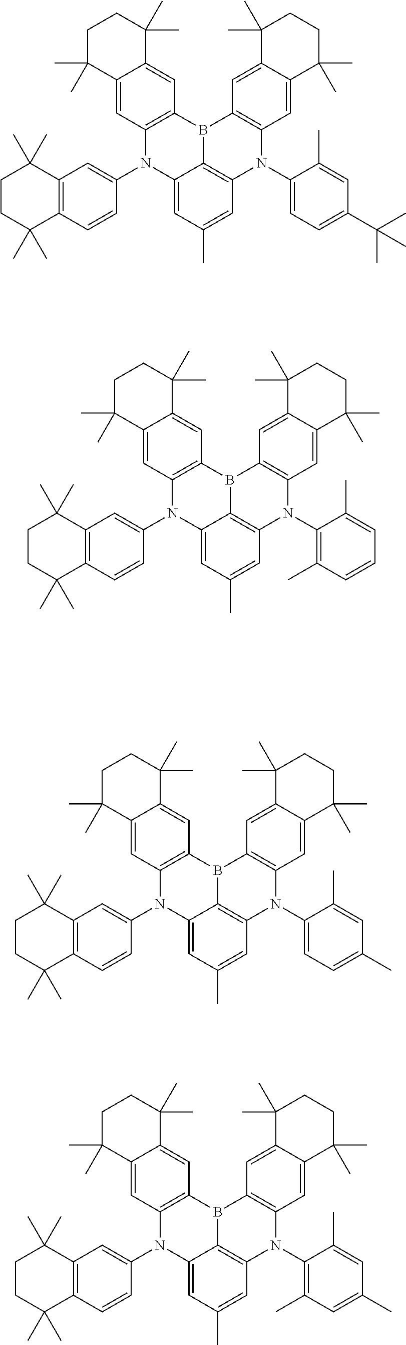 [SMILES: Cc1cc2c3c(c1)N(c1ccc(C(C)(C)C)cc1C)c1cc4c(cc1B3c1cc3c(cc1N2c1ccc2c(c1)C(C)(C)CCC2(C)C)C(C)(C)CCC3(C)C)C(C)(C)CCC4(C)C ; Cc1cc2c3c(c1)N(c1c(C)cccc1C)c1cc4c(cc1B3c1cc3c(cc1N2c1ccc2c(c1)C(C)(C)CCC2(C)C)C(C)(C)CCC3(C)C)C(C)(C)CCC4(C)C ; Cc1ccc(N2c3cc4c(cc3B3c5cc6c(cc5N(c5ccc7c(c5)C(C)(C)CCC7(C)C)c5cc(C)cc2c53)C(C)(C)CCC6(C)C)C(C)(C)CCC4(C)C)c(C)c1 ; Cc1cc(C)c(N2c3cc4c(cc3B3c5cc6c(cc5N(c5ccc7c(c5)C(C)(C)CCC7(C)C)c5cc(C)cc2c53)C(C)(C)CCC6(C)C)C(C)(C)CCC4(C)C)c(C)c1]

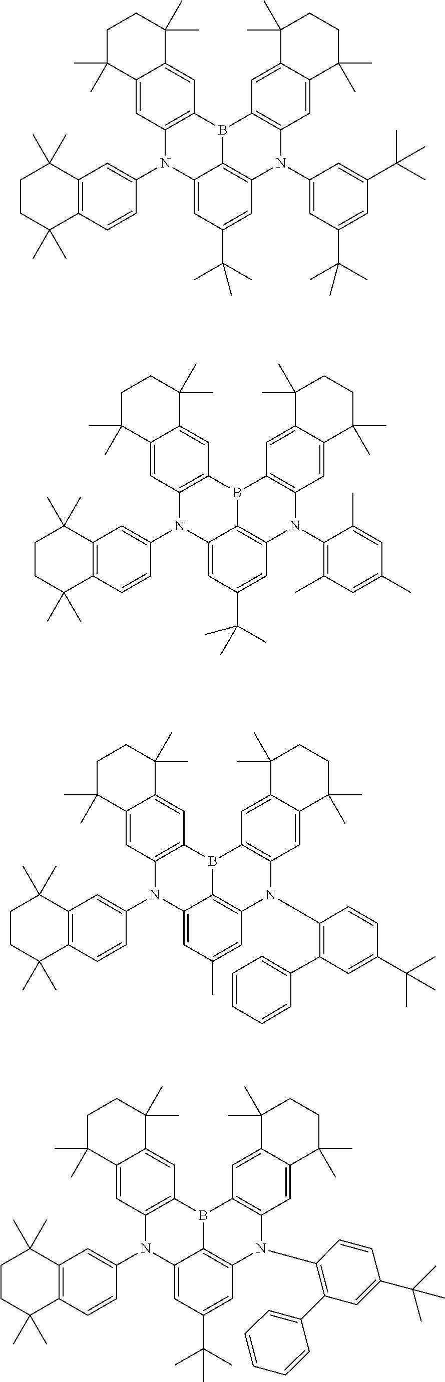

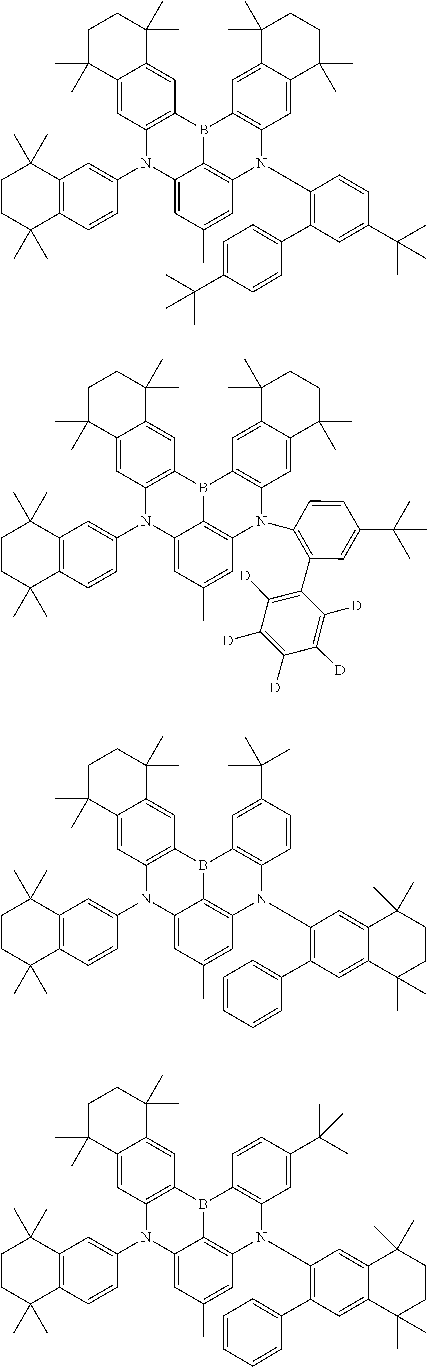

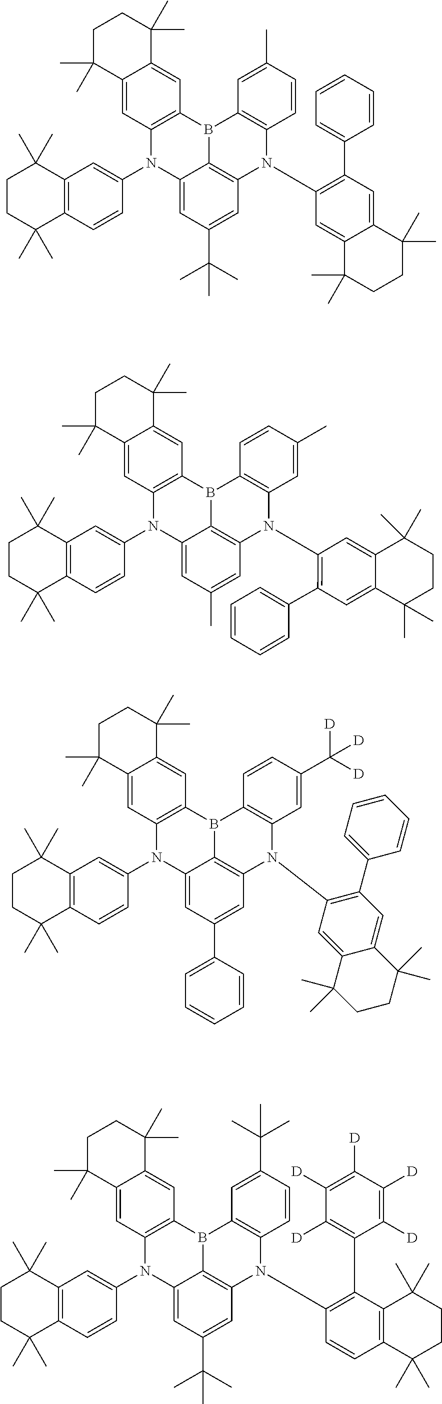

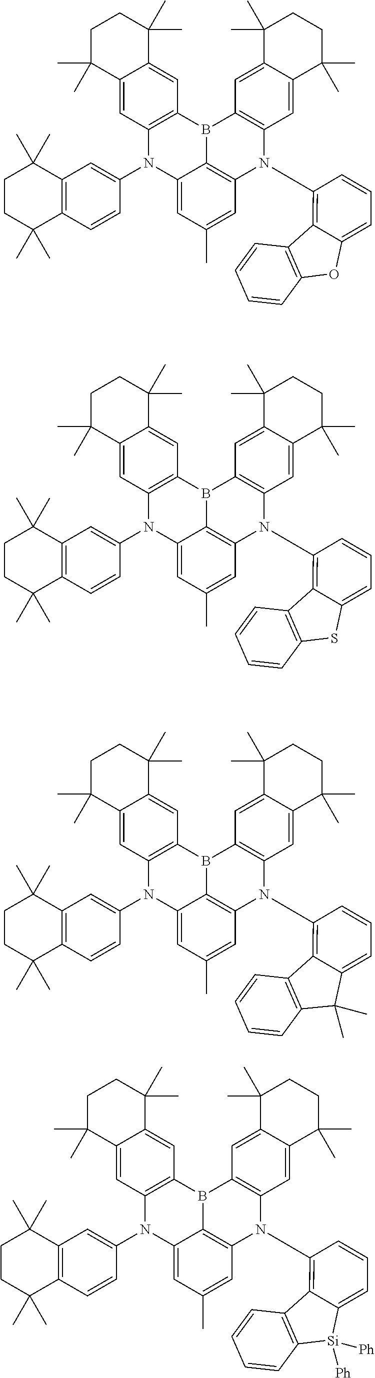

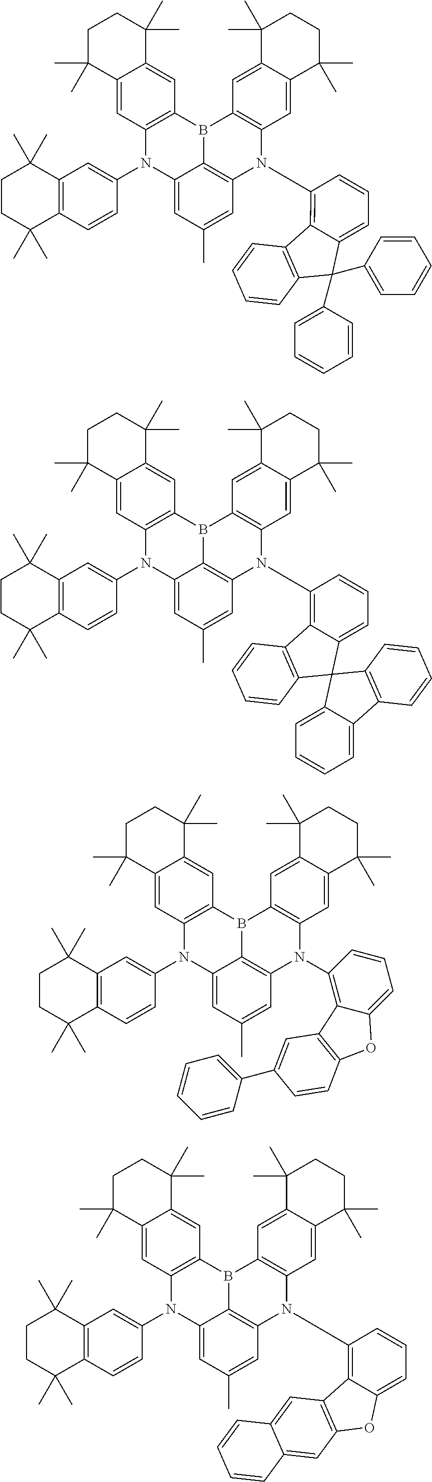

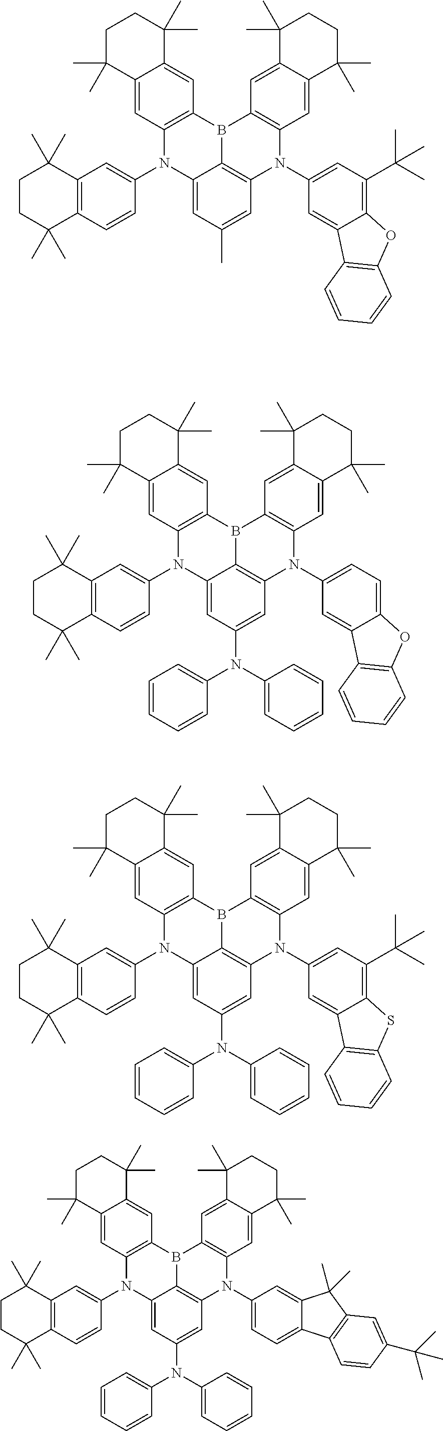

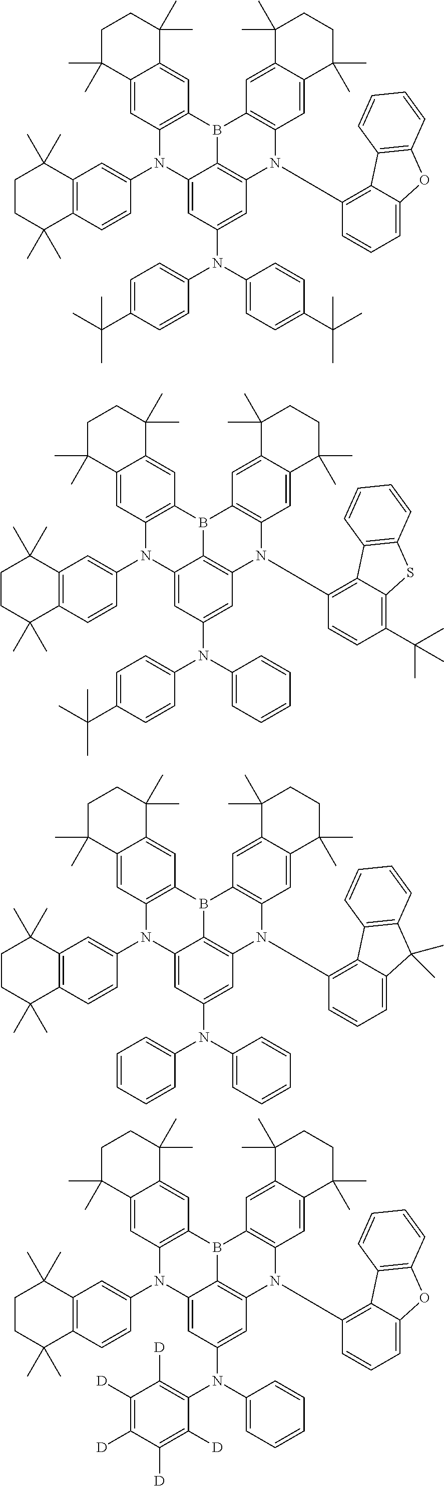

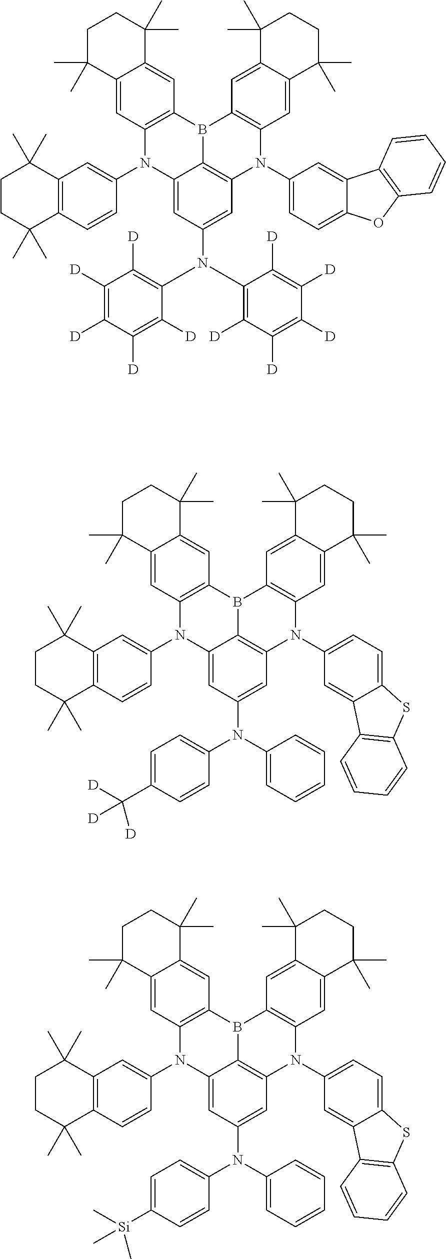 [SMILES: [2H]c1c([2H])c([2H])c(N(c2cc3c4c(c2)N(c2ccc5oc6ccccc6c5c2)c2cc5c(cc2B4c2cc4c(cc2N3c2ccc3c(c2)C(C)(C)CCC3(C)C)C(C)(C)CCC4(C)C)C(C)(C)CCC5(C)C)c2c([2H])c([2H])c([2H])c([2H])c2[2H])c([2H])c1[2H] ; [2H]C([2H])([2H])c1ccc(N(c2ccccc2)c2cc3c4c(c2)N(c2ccc5sc6ccccc6c5c2)c2cc5c(cc2B4c2cc4c(cc2N3c2ccc3c(c2)C(C)(C)CCC3(C)C)C(C)(C)CCC4(C)C)C(C)(C)CCC5(C)C)cc1 ; CC1(C)CCC(C)(C)c2cc(N3c4cc5c(cc4B4c6cc7c(cc6N(c6ccc8sc9ccccc9c8c6)c6cc(N(c8ccccc8)c8ccc([Si](C)(C)C)cc8)cc3c64)C(C)(C)CCC7(C)C)C(C)(C)CCC5(C)C)ccc21]

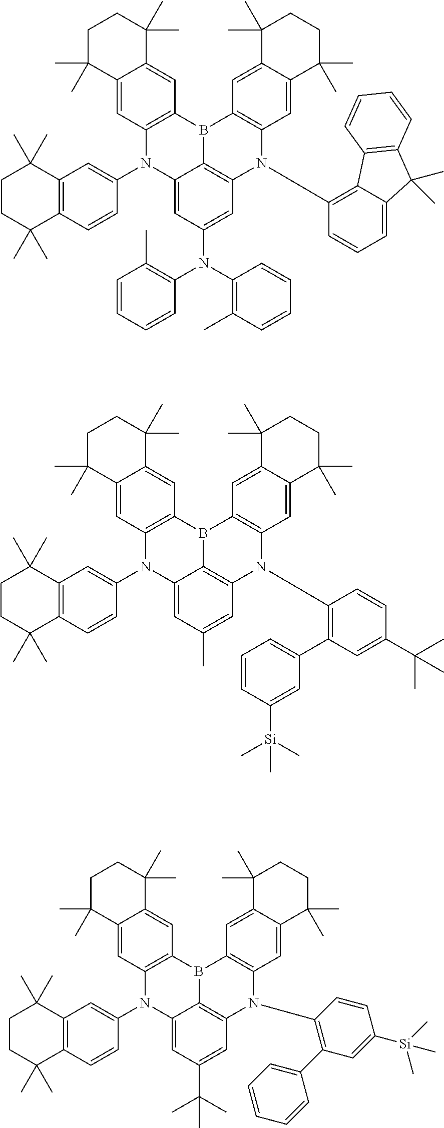 [SMILES: Cc1ccccc1N(c1cc2c3c(c1)N(c1cccc4c1-c1ccccc1C4(C)C)c1cc4c(cc1B3c1cc3c(cc1N2c1ccc2c(c1)C(C)(C)CCC2(C)C)C(C)(C)CCC3(C)C)C(C)(C)CCC4(C)C)c1ccccc1C ; Cc1cc2c3c(c1)N(c1ccc(C(C)(C)C)cc1-c1cccc([Si](C)(C)C)c1)c1cc4c(cc1B3c1cc3c(cc1N2c1ccc2c(c1)C(C)(C)CCC2(C)C)C(C)(C)CCC3(C)C)C(C)(C)CCC4(C)C ; CC(C)(C)c1cc2c3c(c1)N(c1ccc([Si](C)(C)C)cc1-c1ccccc1)c1cc4c(cc1B3c1cc3c(cc1N2c1ccc2c(c1)C(C)(C)CCC2(C)C)C(C)(C)CCC3(C)C)C(C)(C)CCC4(C)C]

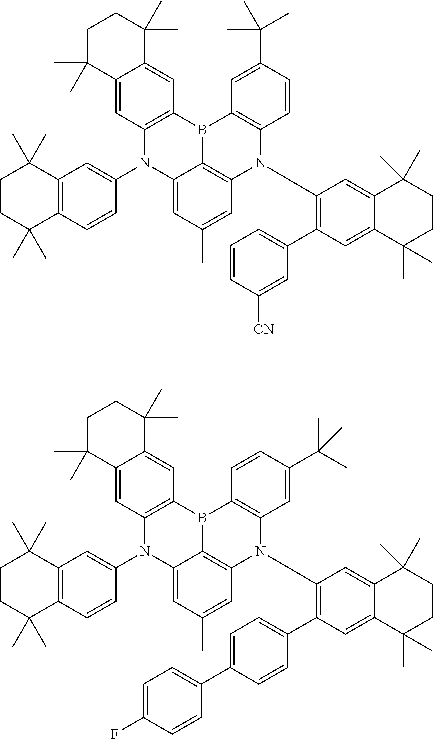 [SMILES: Cc1cc2c3c(c1)N(c1cc4c(cc1-c1cccc(C#N)c1)C(C)(C)CCC4(C)C)c1ccc(C(C)(C)C)cc1B3c1cc3c(cc1N2c1ccc2c(c1)C(C)(C)CCC2(C)C)C(C)(C)CCC3(C)C ; Cc1cc2c3c(c1)N(c1cc4c(cc1-c1ccc(-c5ccc(F)cc5)cc1)C(C)(C)CCC4(C)C)c1cc(C(C)(C)C)ccc1B3c1cc3c(cc1N2c1ccc2c(c1)C(C)(C)CCC2(C)C)C(C)(C)CCC3(C)C]

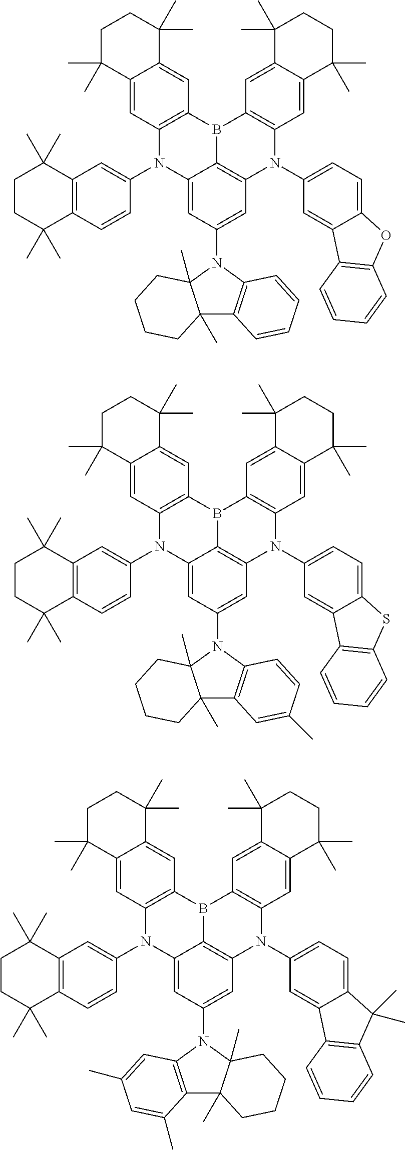

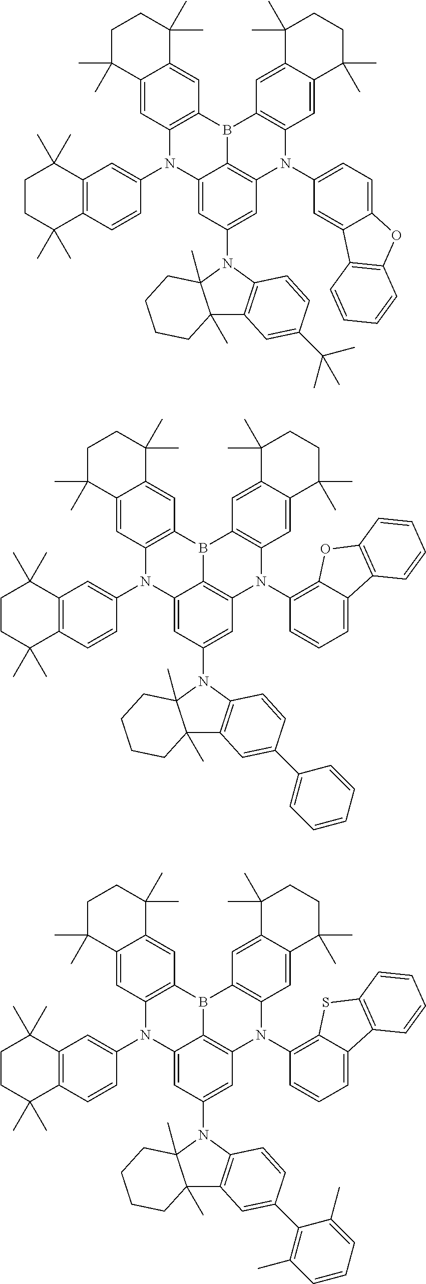 [SMILES: CC(C)(C)c1ccc2c(c1)C1(C)CCCCC1(C)N2c1cc2c3c(c1)N(c1ccc4oc5ccccc5c4c1)c1cc4c(cc1B3c1cc3c(cc1N2c1ccc2c(c1)C(C)(C)CCC2(C)C)C(C)(C)CCC3(C)C)C(C)(C)CCC4(C)C ; CC1(C)CCC(C)(C)c2cc(N3c4cc5c(cc4B4c6cc7c(cc6N(c6cccc8c6oc6ccccc68)c6cc(N8c9ccc(-c%10ccccc%10)cc9C9(C)CCCCC89C)cc3c64)C(C)(C)CCC7(C)C)C(C)(C)CCC5(C)C)ccc21 ; Cc1cccc(C)c1-c1ccc2c(c1)C1(C)CCCCC1(C)N2c1cc2c3c(c1)N(c1cccc4c1sc1ccccc14)c1cc4c(cc1B3c1cc3c(cc1N2c1ccc2c(c1)C(C)(C)CCC2(C)C)C(C)(C)CCC3(C)C)C(C)(C)CCC4(C)C]

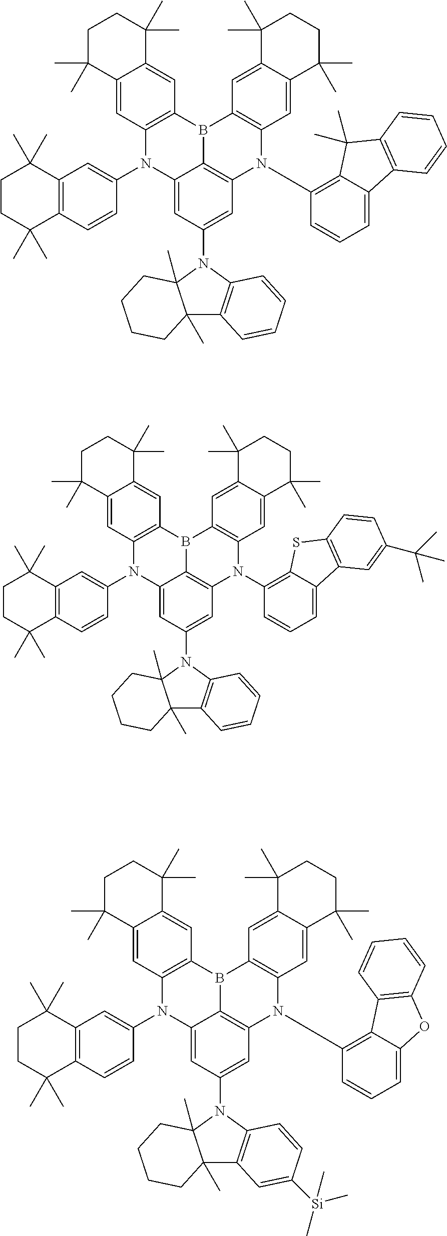 [SMILES: CC1(C)CCC(C)(C)c2cc(N3c4cc5c(cc4B4c6cc7c(cc6N(c6cccc8c6C(C)(C)c6ccccc6-8)c6cc(N8c9ccccc9C9(C)CCCCC89C)cc3c64)C(C)(C)CCC7(C)C)C(C)(C)CCC5(C)C)ccc21 ; CC(C)(C)c1ccc2sc3c(N4c5cc6c(cc5B5c7cc8c(cc7N(c7ccc9c(c7)C(C)(C)CCC9(C)C)c7cc(N9c%10ccccc%10C%10(C)CCCCC9%10C)cc4c75)C(C)(C)CCC8(C)C)C(C)(C)CCC6(C)C)cccc3c2c1 ; CC1(C)CCC(C)(C)c2cc(N3c4cc5c(cc4B4c6cc7c(cc6N(c6cccc8oc9ccccc9c68)c6cc(N8c9ccc([Si](C)(C)C)cc9C9(C)CCCCC89C)cc3c64)C(C)(C)CCC7(C)C)C(C)(C)CCC5(C)C)ccc21]

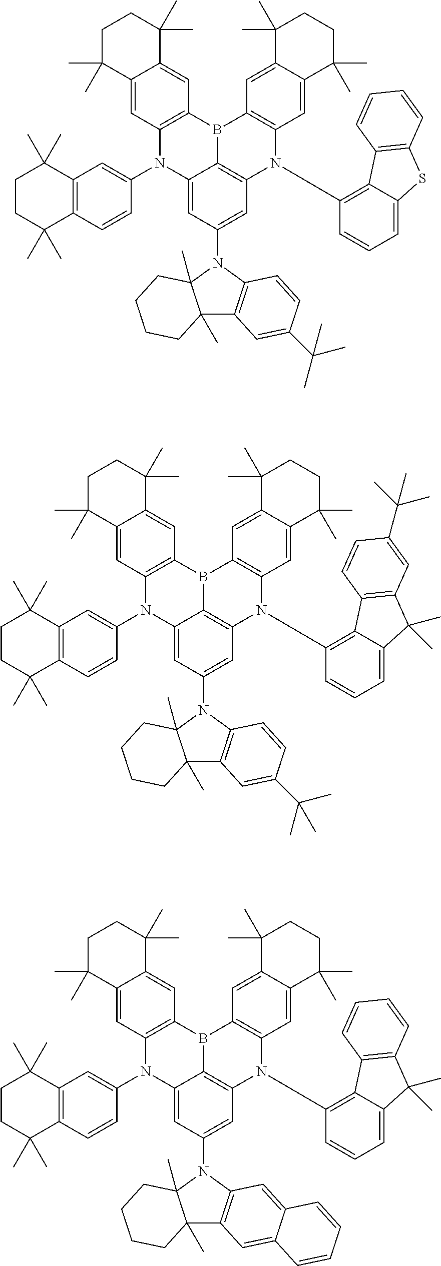 [SMILES: CC(C)(C)c1ccc2c(c1)C1(C)CCCCC1(C)N2c1cc2c3c(c1)N(c1cccc4sc5ccccc5c14)c1cc4c(cc1B3c1cc3c(cc1N2c1ccc2c(c1)C(C)(C)CCC2(C)C)C(C)(C)CCC3(C)C)C(C)(C)CCC4(C)C ; CC(C)(C)c1ccc2c(c1)C(C)(C)c1cccc(N3c4cc5c(cc4B4c6cc7c(cc6N(c6ccc8c(c6)C(C)(C)CCC8(C)C)c6cc(N8c9ccc(C(C)(C)C)cc9C9(C)CCCCC89C)cc3c64)C(C)(C)CCC7(C)C)C(C)(C)CCC5(C)C)c1-2 ; CC1(C)CCC(C)(C)c2cc(N3c4cc5c(cc4B4c6cc7c(cc6N(c6cccc8c6-c6ccccc6C8(C)C)c6cc(N8c9cc%10ccccc%10cc9C9(C)CCCCC89C)cc3c64)C(C)(C)CCC7(C)C)C(C)(C)CCC5(C)C)ccc21]

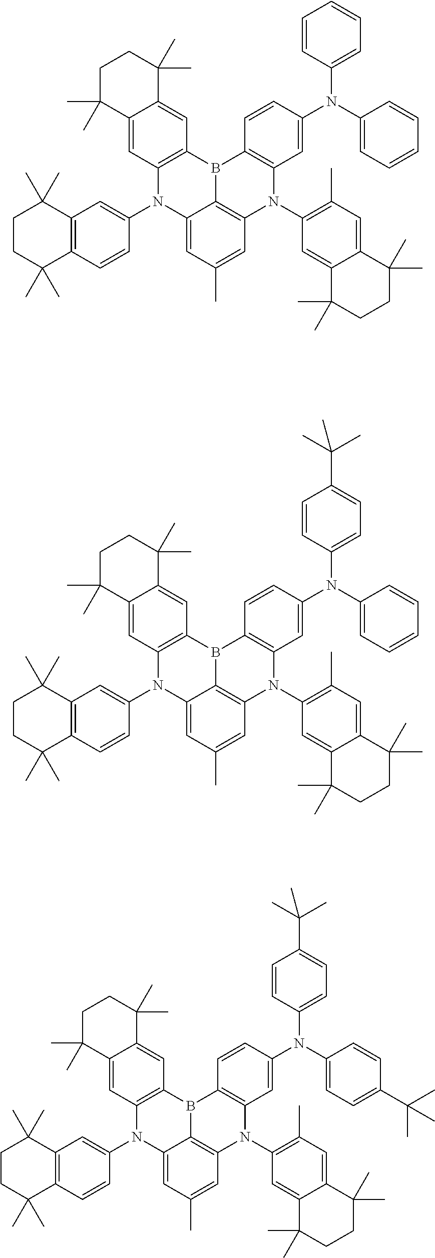 [SMILES: Cc1cc2c3c(c1)N(c1cc4c(cc1C)C(C)(C)CCC4(C)C)c1cc(N(c4ccccc4)c4ccccc4)ccc1B3c1cc3c(cc1N2c1ccc2c(c1)C(C)(C)CCC2(C)C)C(C)(C)CCC3(C)C ; Cc1cc2c3c(c1)N(c1cc4c(cc1C)C(C)(C)CCC4(C)C)c1cc(N(c4ccccc4)c4ccc(C(C)(C)C)cc4)ccc1B3c1cc3c(cc1N2c1ccc2c(c1)C(C)(C)CCC2(C)C)C(C)(C)CCC3(C)C ; Cc1cc2c3c(c1)N(c1cc4c(cc1C)C(C)(C)CCC4(C)C)c1cc(N(c4ccc(C(C)(C)C)cc4)c4ccc(C(C)(C)C)cc4)ccc1B3c1cc3c(cc1N2c1ccc2c(c1)C(C)(C)CCC2(C)C)C(C)(C)CCC3(C)C]

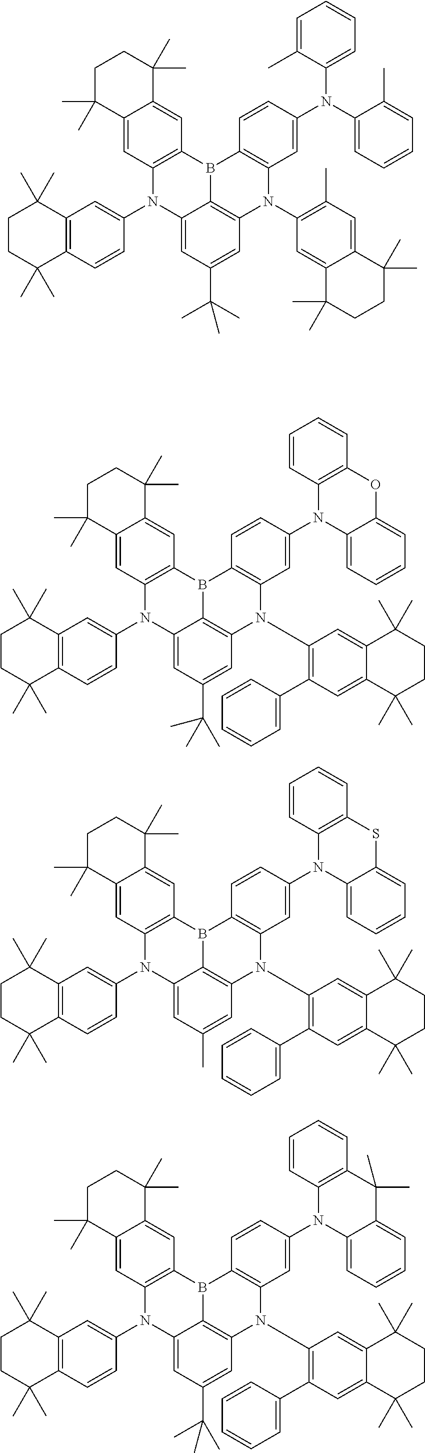

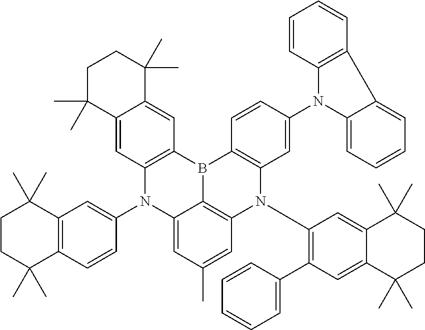 [SMILES: Cc1cc2c3c(c1)N(c1cc4c(cc1-c1ccccc1)C(C)(C)CCC4(C)C)c1cc(-n4c5ccccc5c5ccccc54)ccc1B3c1cc3c(cc1N2c1ccc2c(c1)C(C)(C)CCC2(C)C)C(C)(C)CCC3(C)C]

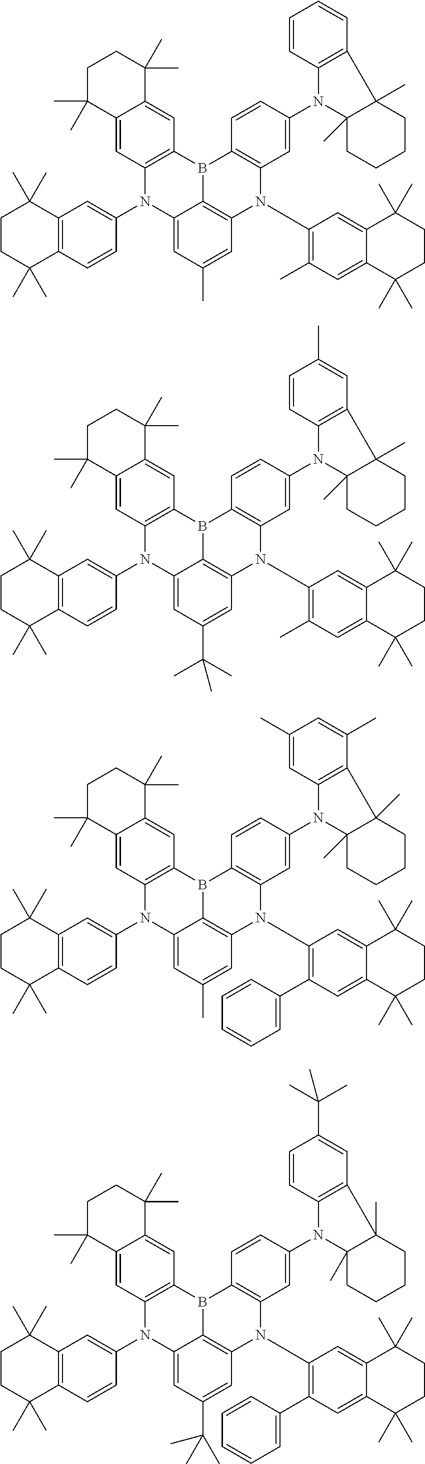

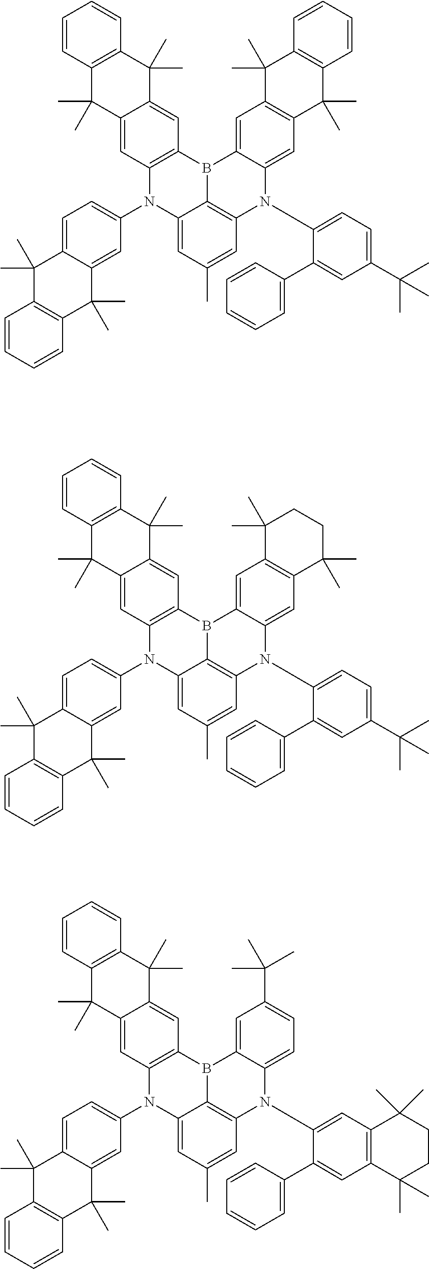

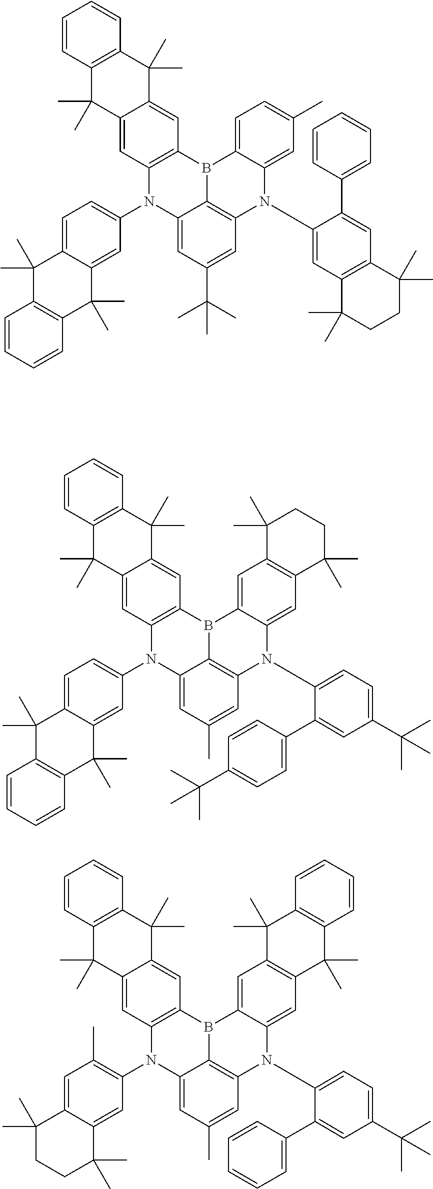

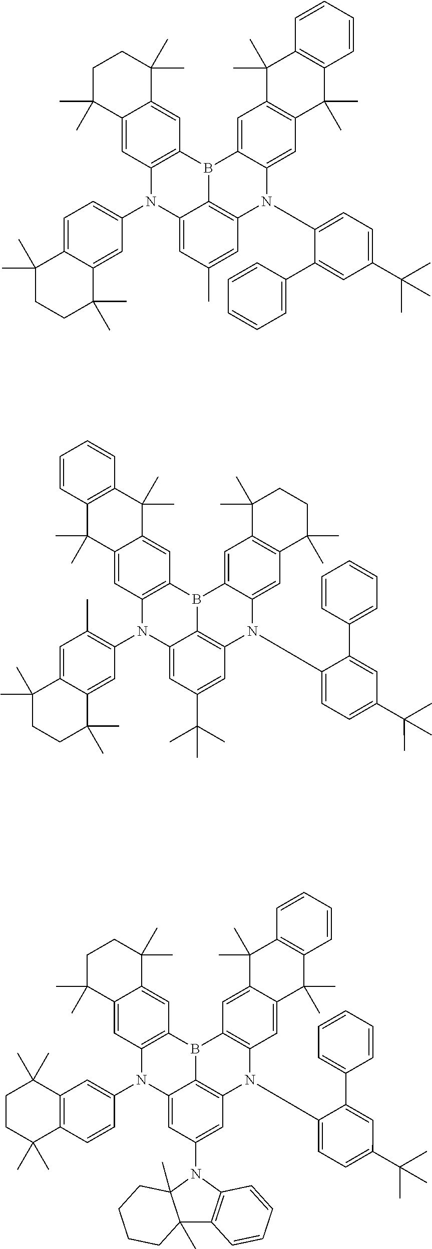

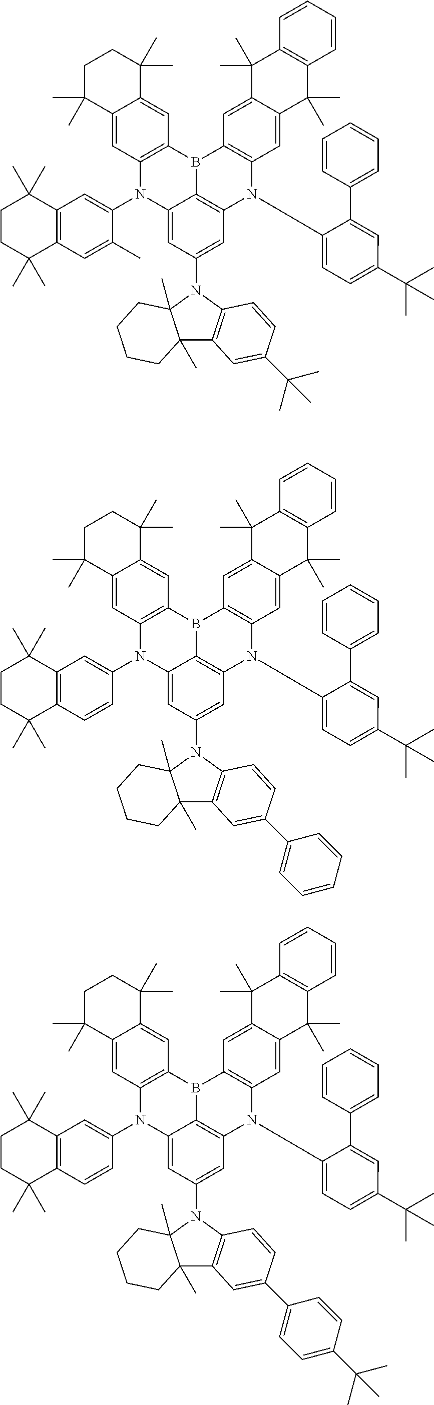

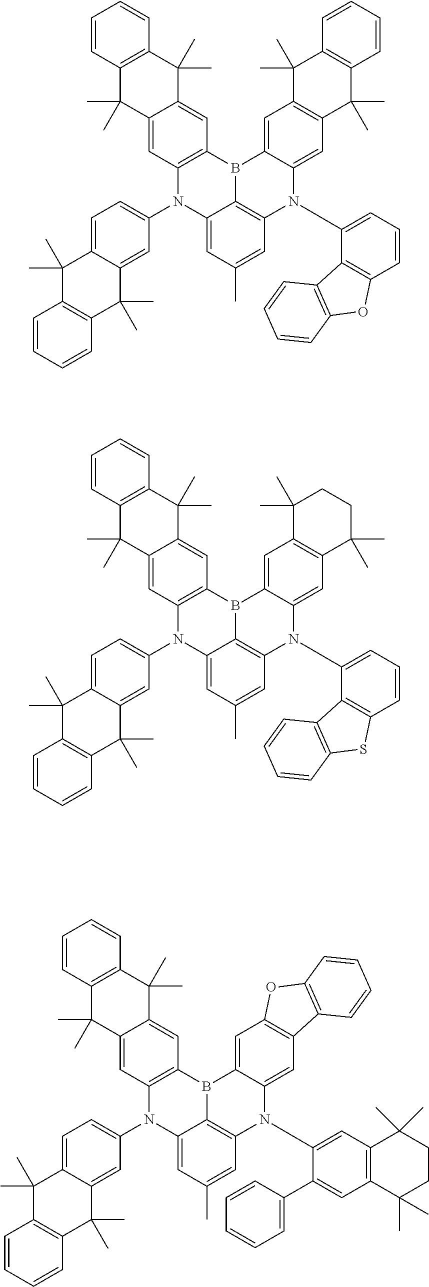

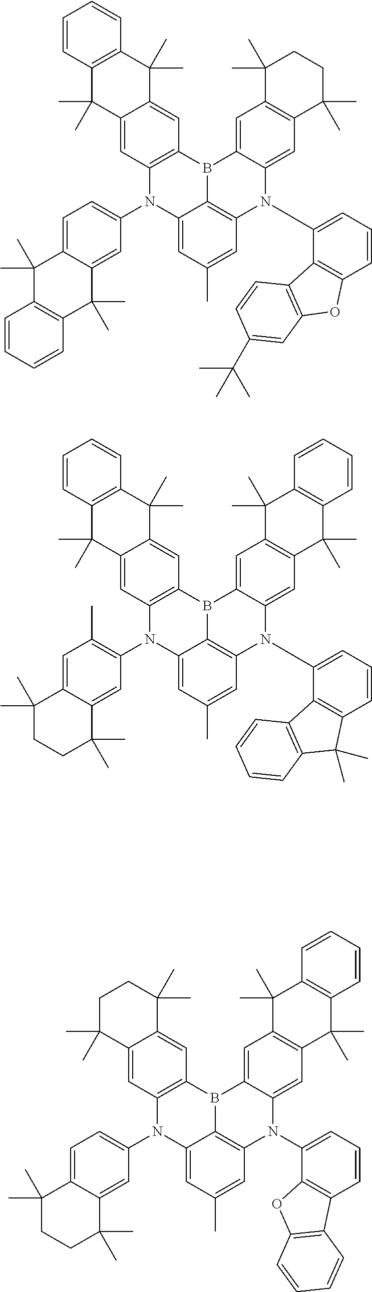

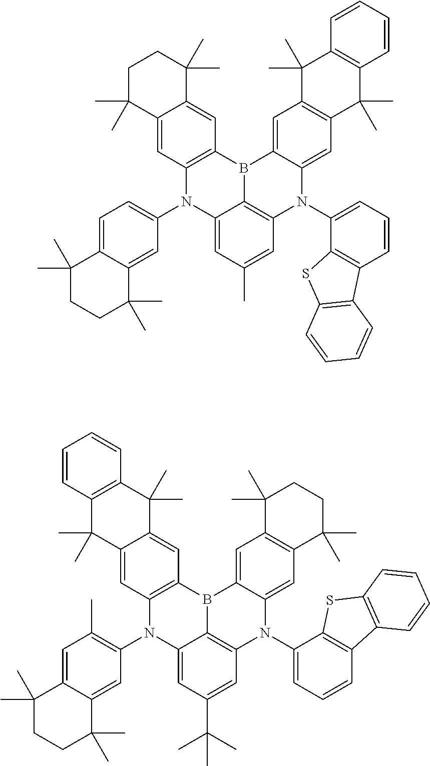

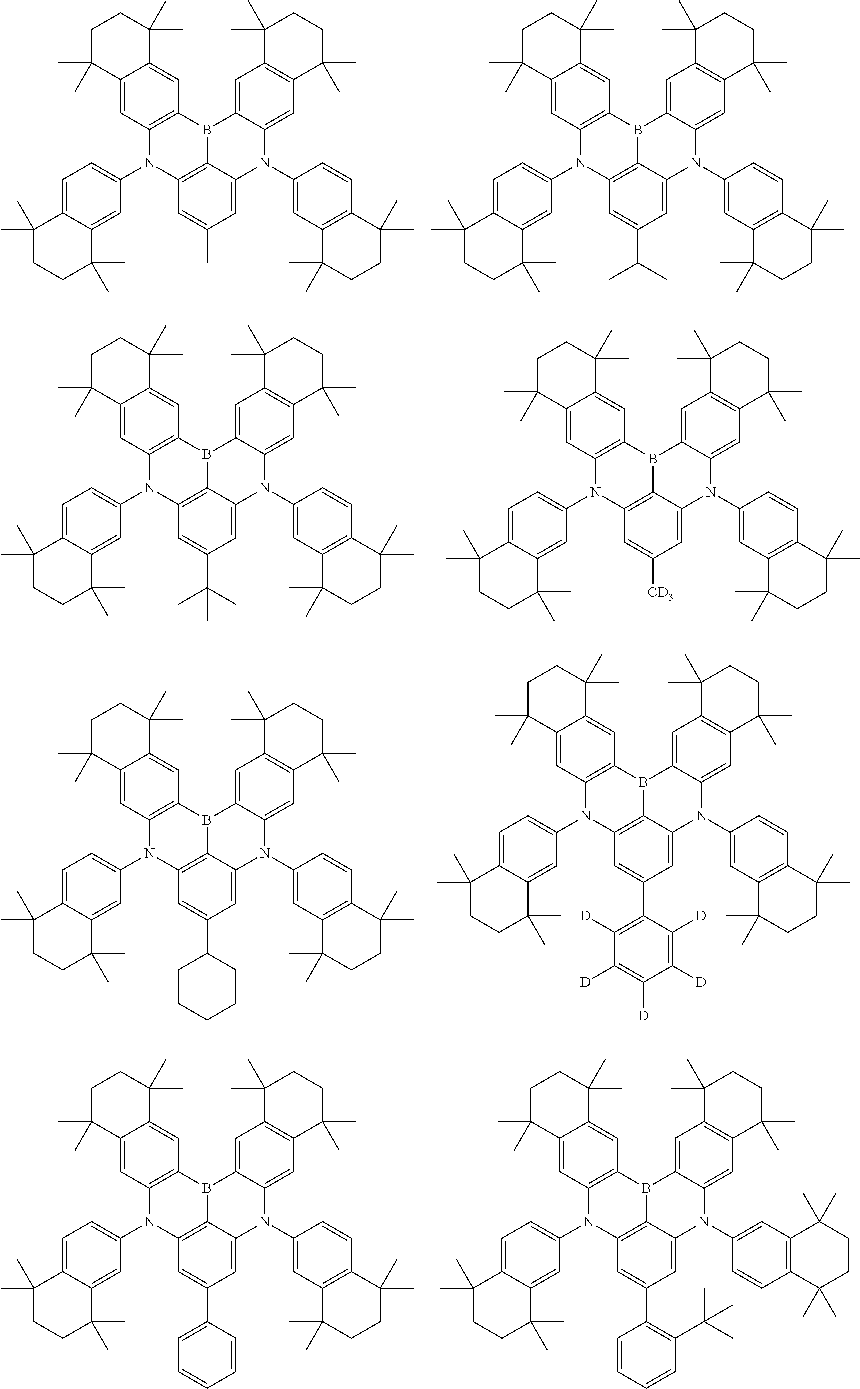

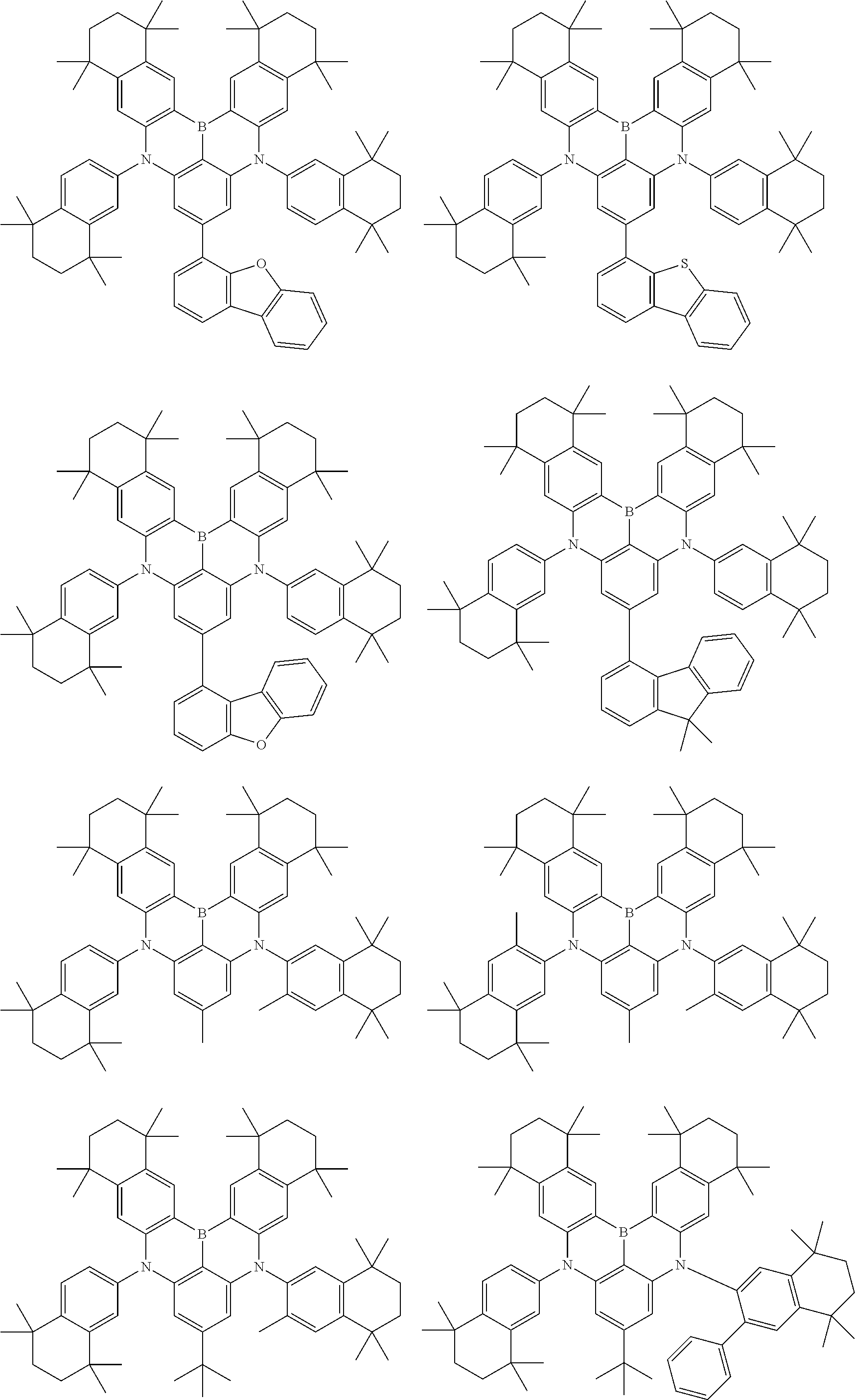

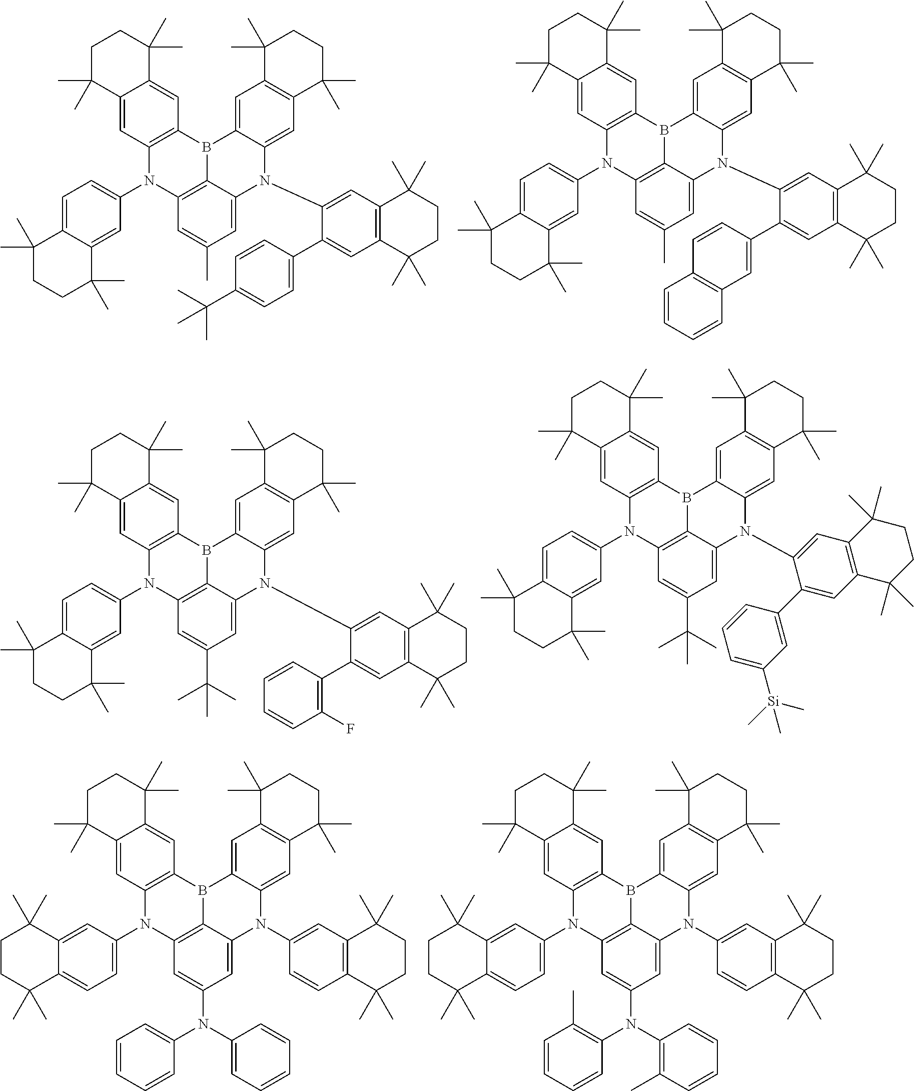

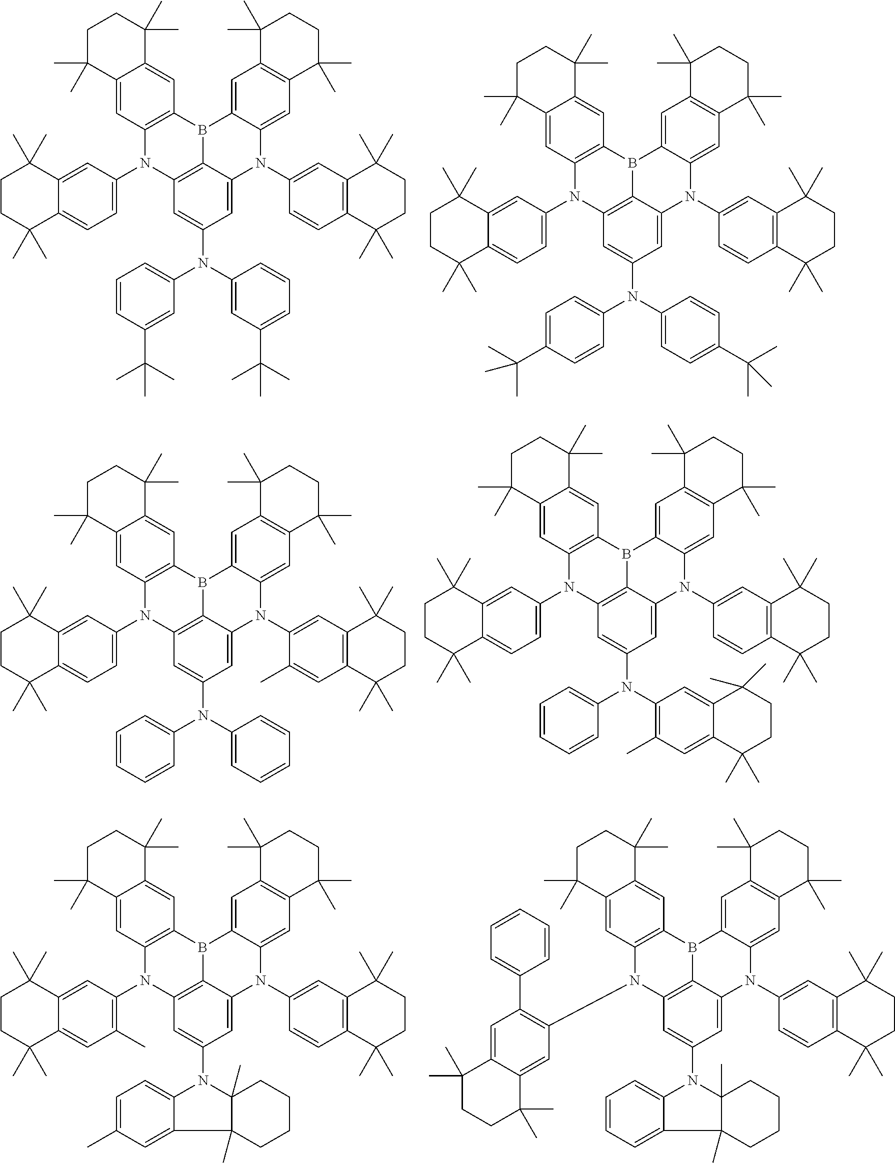

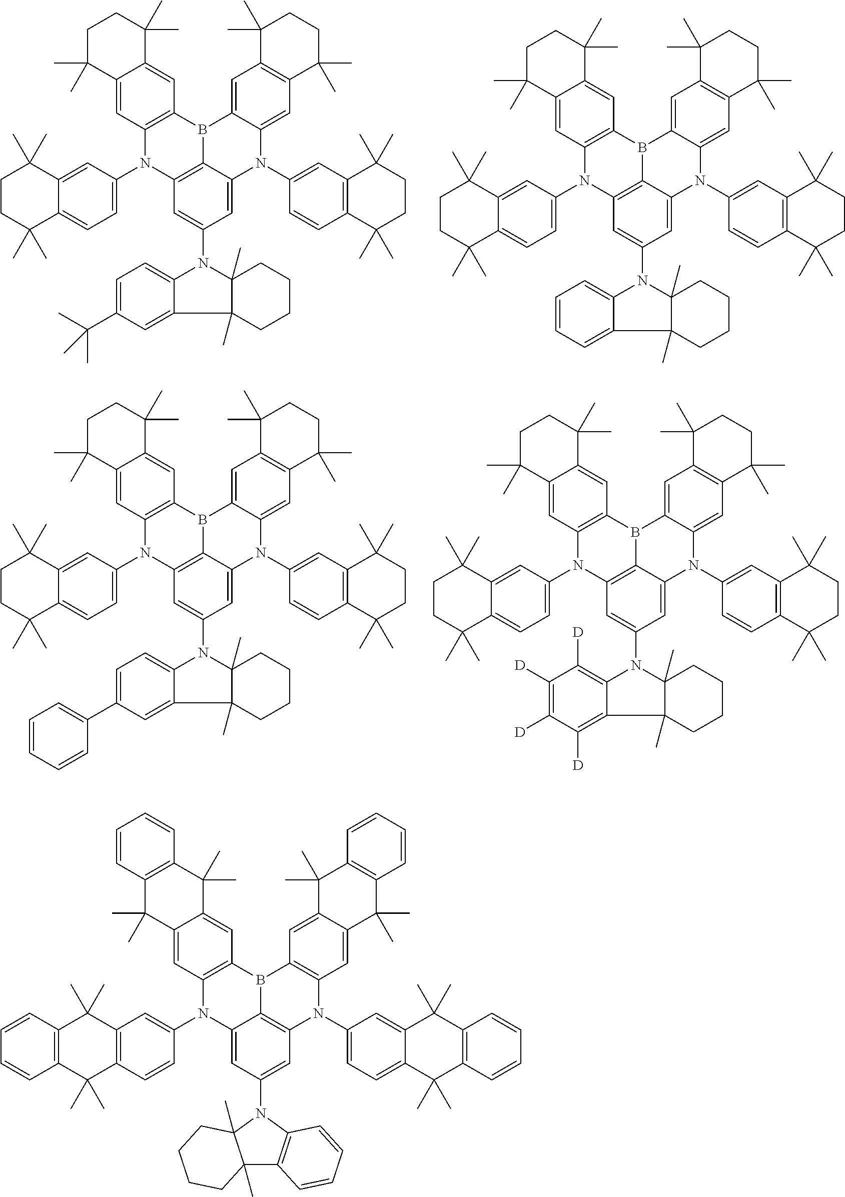

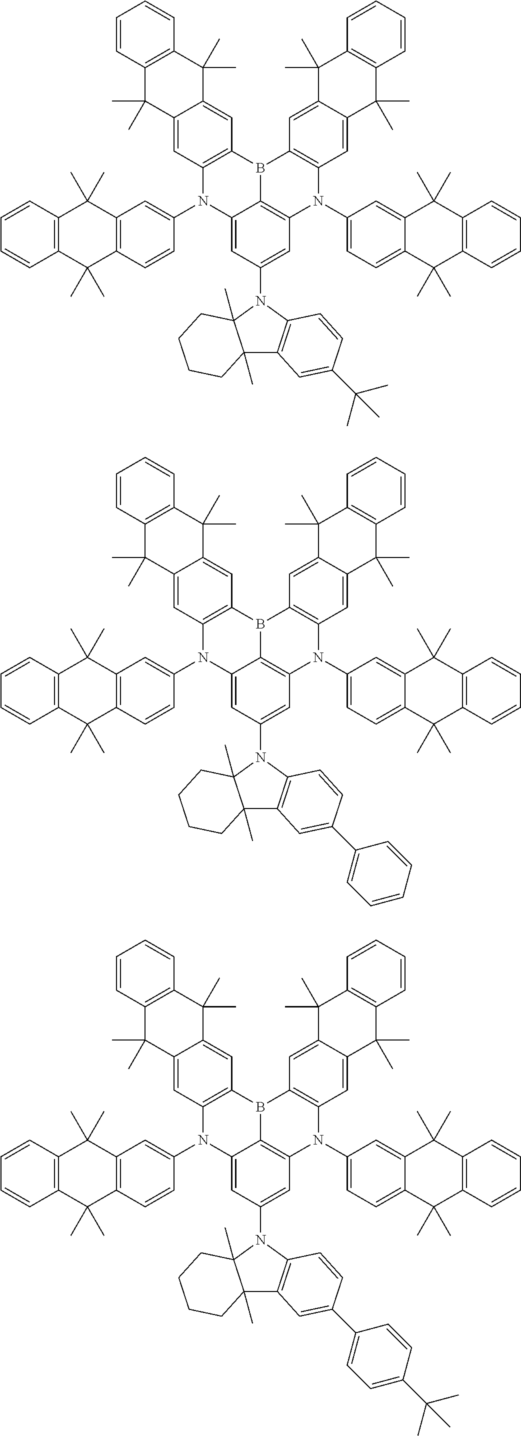

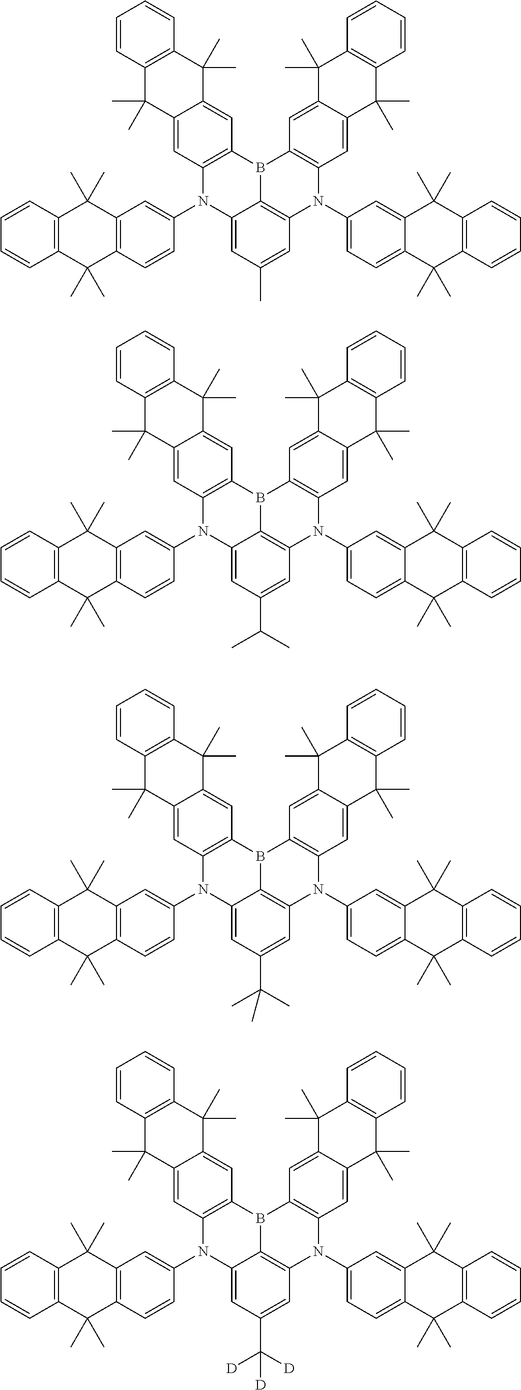

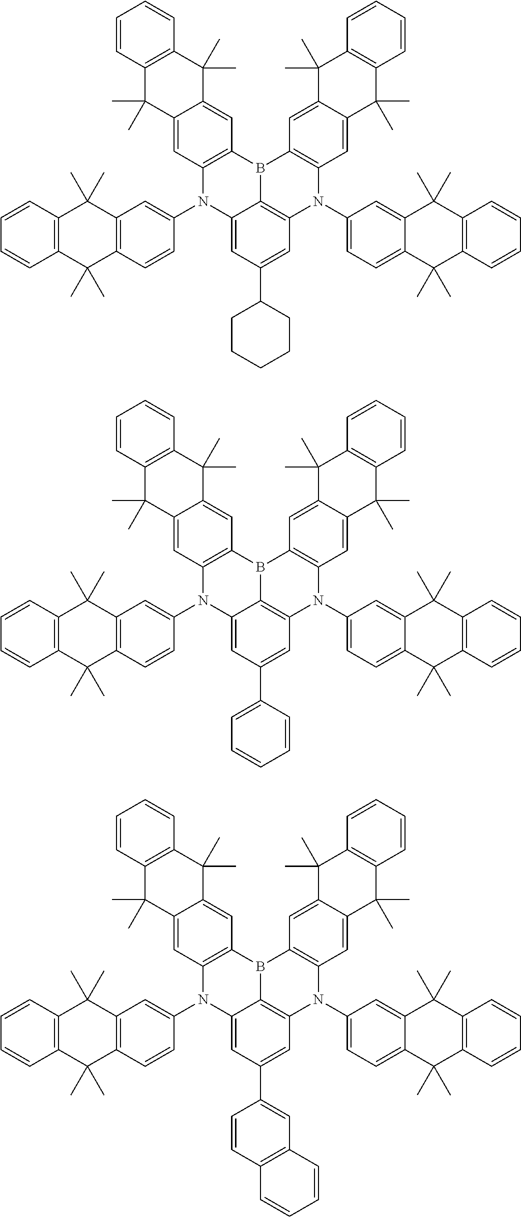 [SMILES: CC1(C)c2ccccc2C(C)(C)c2cc(N3c4cc5c(cc4B4c6cc7c(cc6N(c6ccc8c(c6)C(C)(C)c6ccccc6C8(C)C)c6cc(C8CCCCC8)cc3c64)C(C)(C)c3ccccc3C7(C)C)C(C)(C)c3ccccc3C5(C)C)ccc21 ; CC1(C)c2ccccc2C(C)(C)c2cc(N3c4cc5c(cc4B4c6cc7c(cc6N(c6ccc8c(c6)C(C)(C)c6ccccc6C8(C)C)c6cc(-c8ccccc8)cc3c64)C(C)(C)c3ccccc3C7(C)C)C(C)(C)c3ccccc3C5(C)C)ccc21 ; CC1(C)c2ccccc2C(C)(C)c2cc(N3c4cc5c(cc4B4c6cc7c(cc6N(c6ccc8c(c6)C(C)(C)c6ccccc6C8(C)C)c6cc(-c8ccc9ccccc9c8)cc3c64)C(C)(C)c3ccccc3C7(C)C)C(C)(C)c3ccccc3C5(C)C)ccc21]

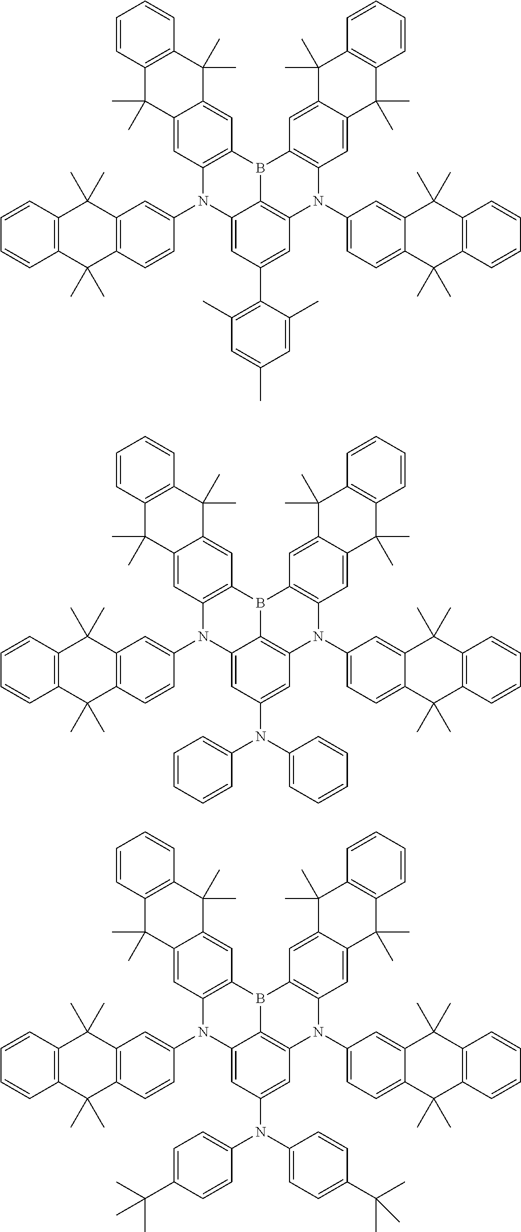

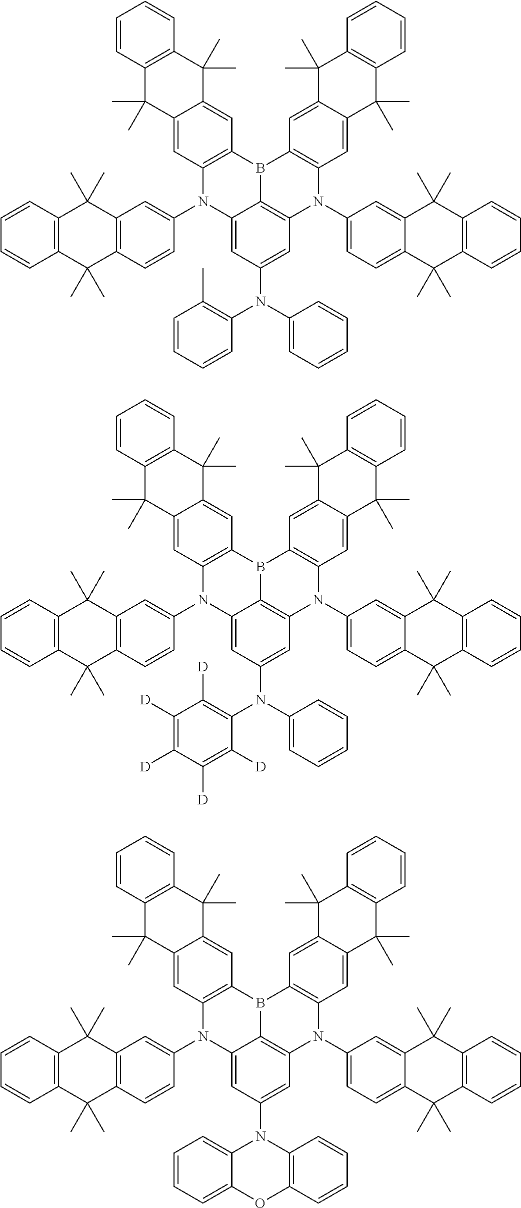

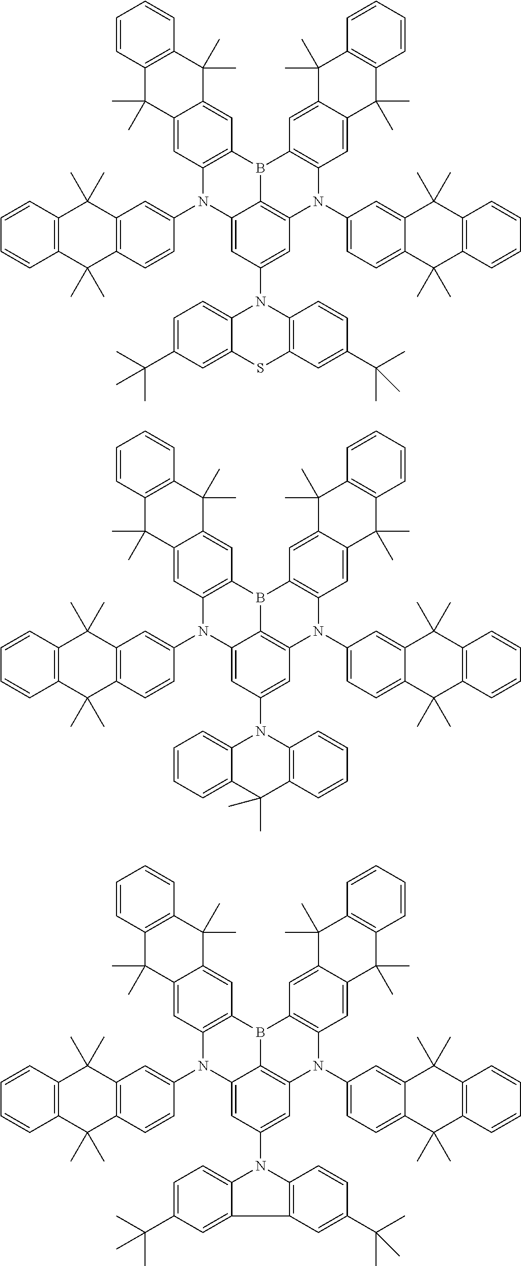

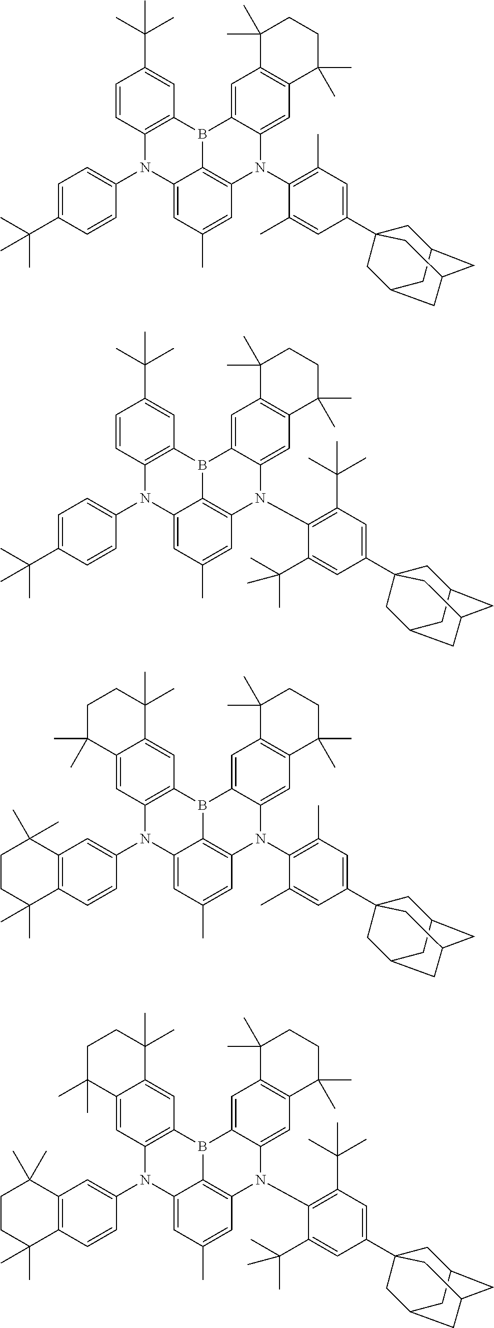

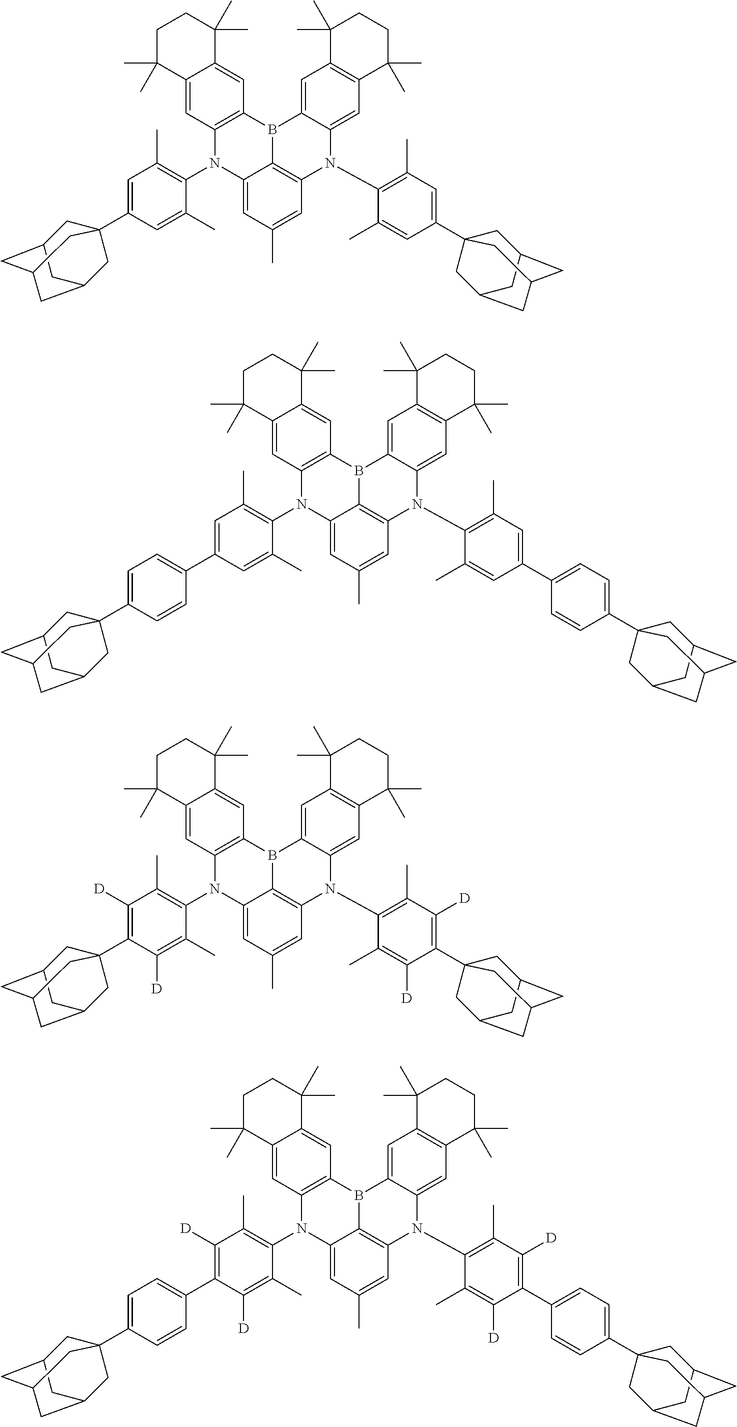

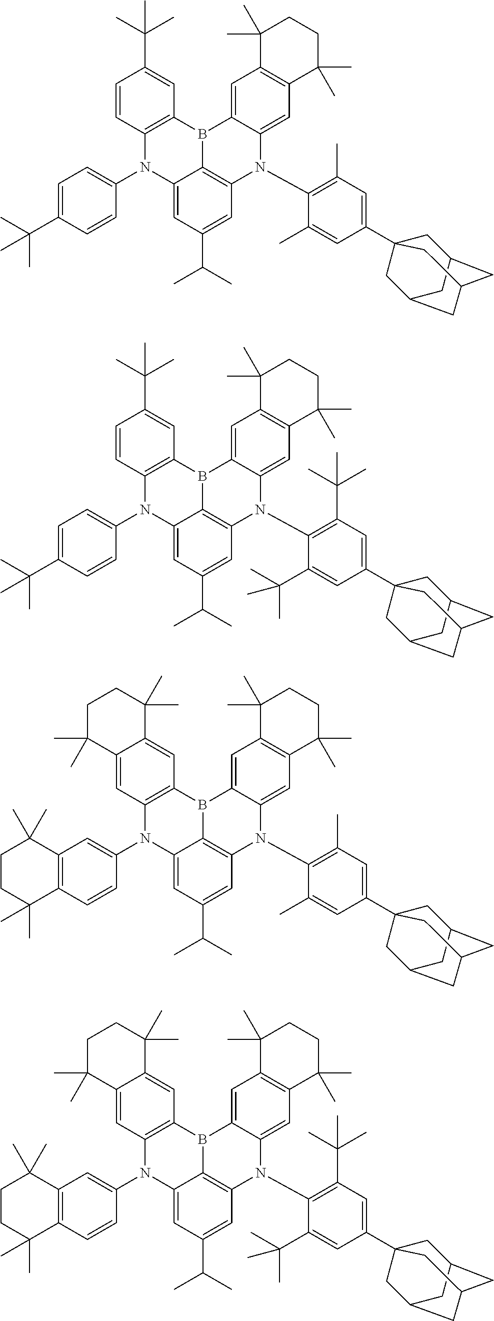

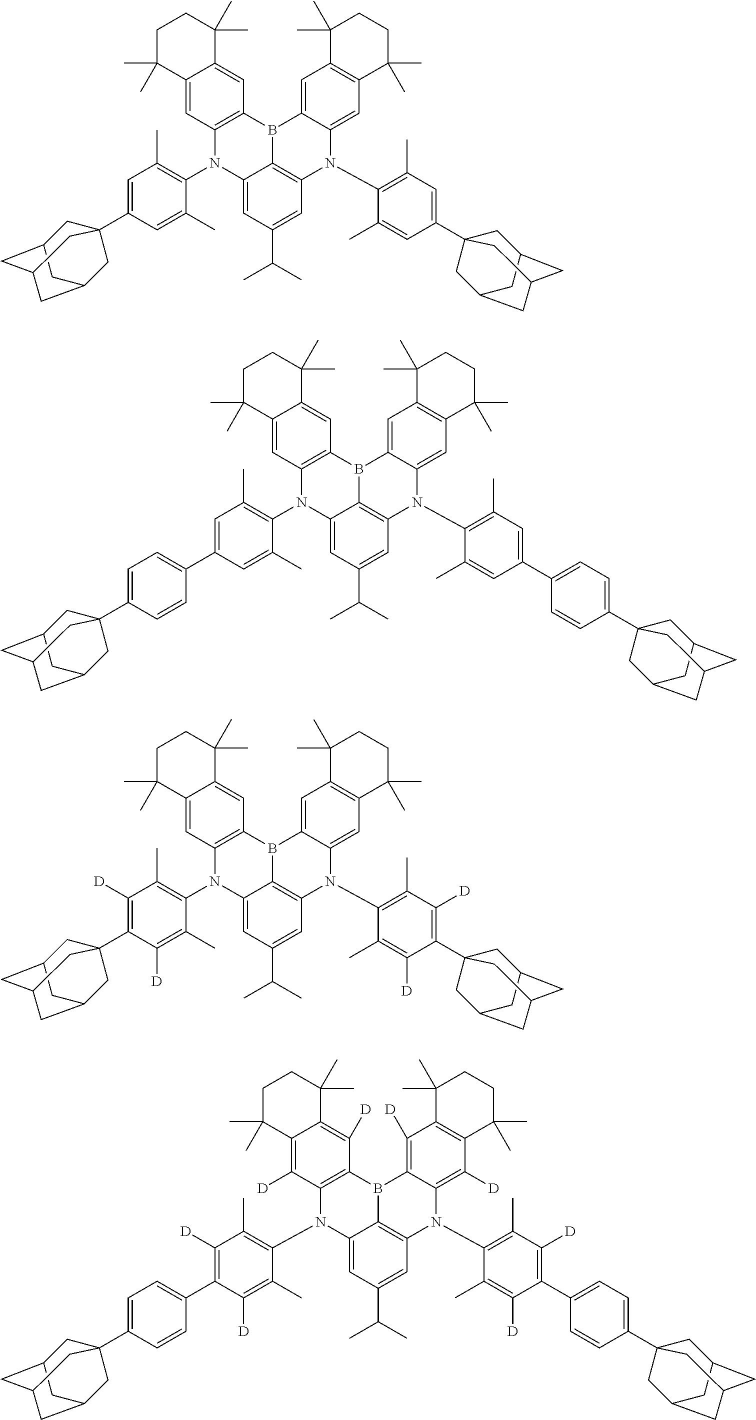

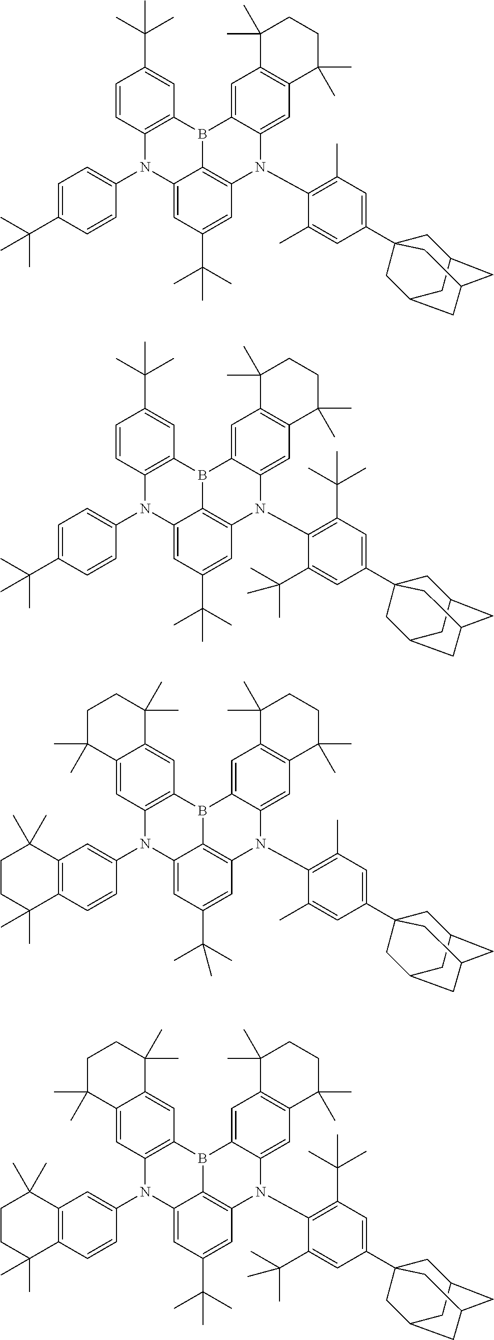

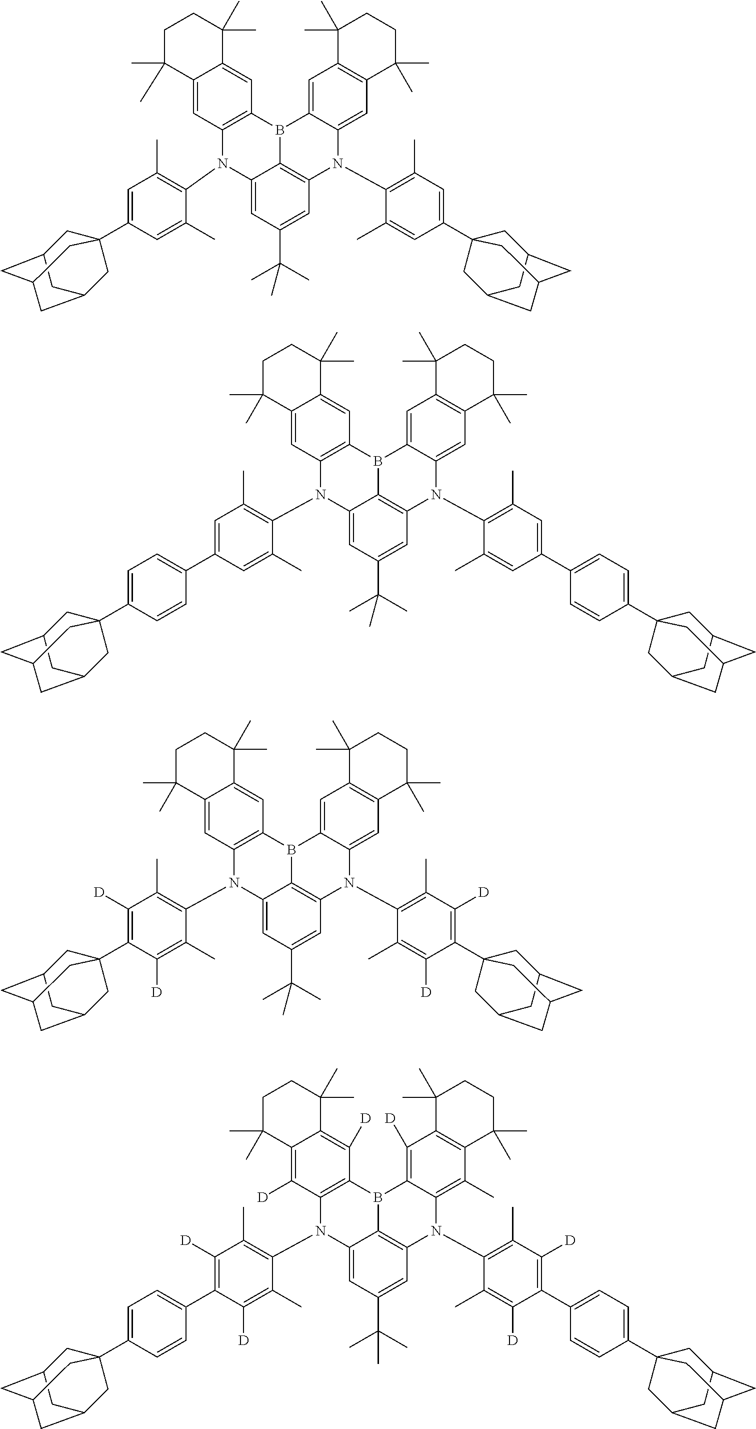

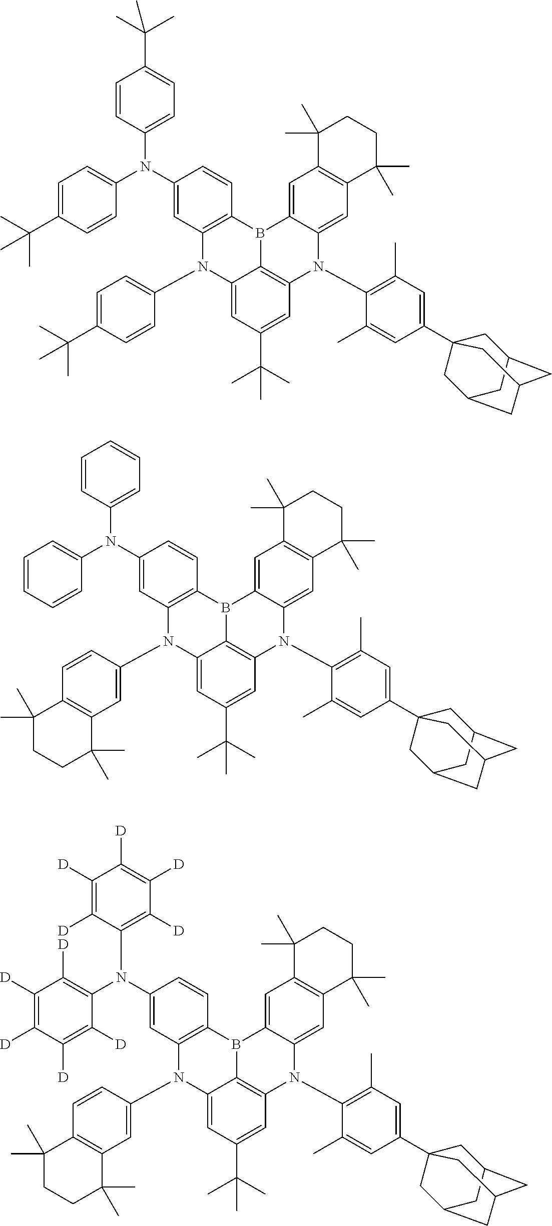 [SMILES: Cc1cc(C23CC4CC(CC(C4)C2)C3)cc(C)c1N1c2cc3c(cc2B2c4ccc(N(c5ccc(C(C)(C)C)cc5)c5ccc(C(C)(C)C)cc5)cc4N(c4ccc(C(C)(C)C)cc4)c4cc(C(C)(C)C)cc1c42)C(C)(C)CCC3(C)C ; Cc1cc(C23CC4CC(CC(C4)C2)C3)cc(C)c1N1c2cc3c(cc2B2c4ccc(N(c5ccccc5)c5ccccc5)cc4N(c4ccc5c(c4)C(C)(C)CCC5(C)C)c4cc(C(C)(C)C)cc1c42)C(C)(C)CCC3(C)C ; [2H]c1c([2H])c([2H])c(N(c2ccc3c(c2)N(c2ccc4c(c2)C(C)(C)CCC4(C)C)c2cc(C(C)(C)C)cc4c2B3c2cc3c(cc2N4c2c(C)cc(C45CC6CC(CC(C6)C4)C5)cc2C)C(C)(C)CCC3(C)C)c2c([2H])c([2H])c([2H])c([2H])c2[2H])c([2H])c1[2H]]

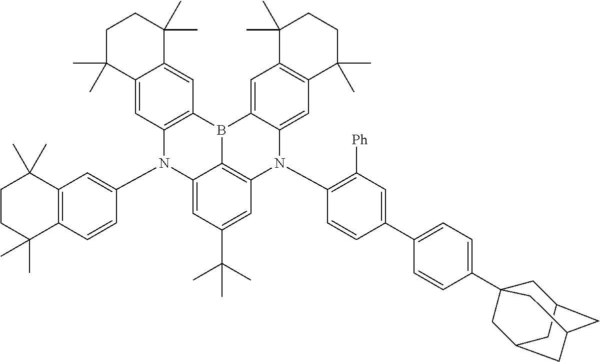 [SMILES: CC(C)(C)c1cc2c3c(c1)N(c1ccc(-c4ccc(C56CC7CC(CC(C7)C5)C6)cc4)cc1-c1ccccc1)c1cc4c(cc1B3c1cc3c(cc1N2c1ccc2c(c1)C(C)(C)CCC2(C)C)C(C)(C)CCC3(C)C)C(C)(C)CCC4(C)C]

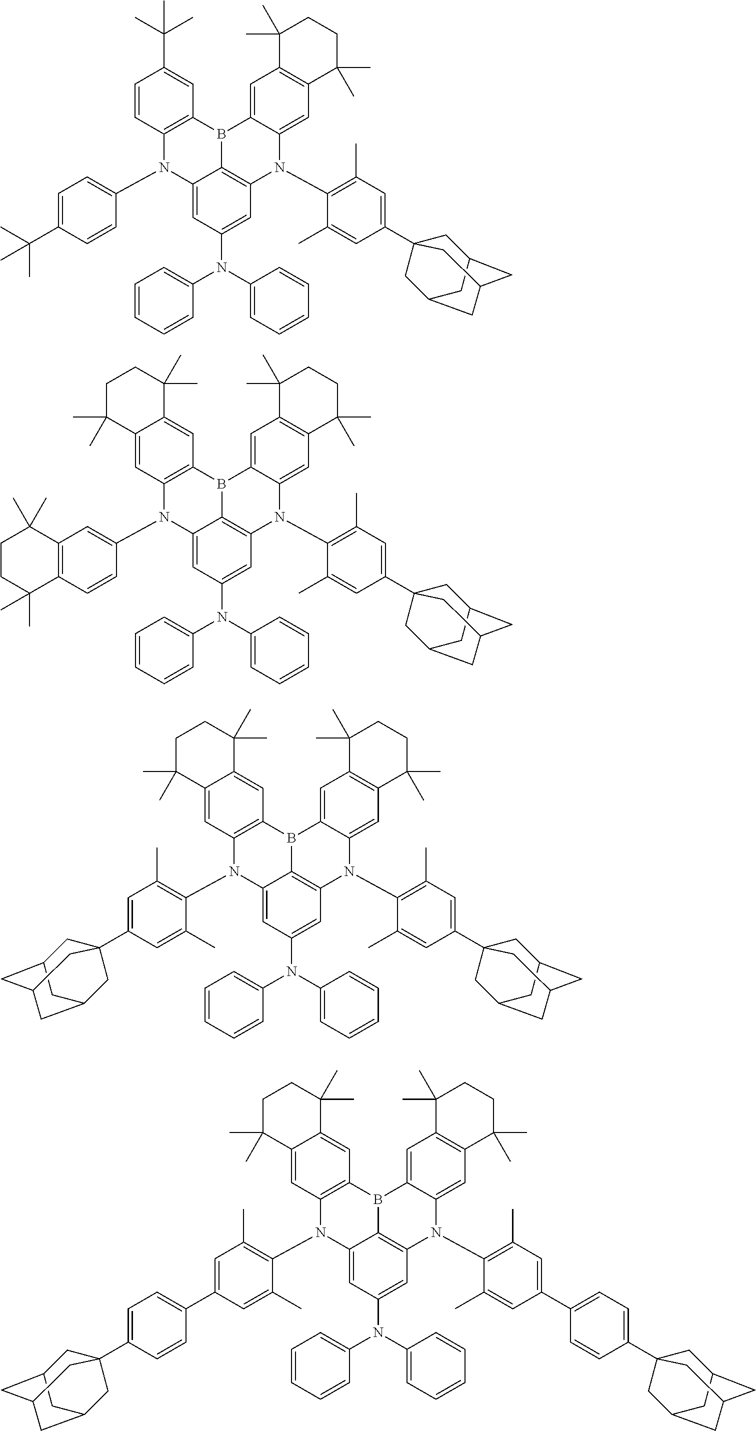

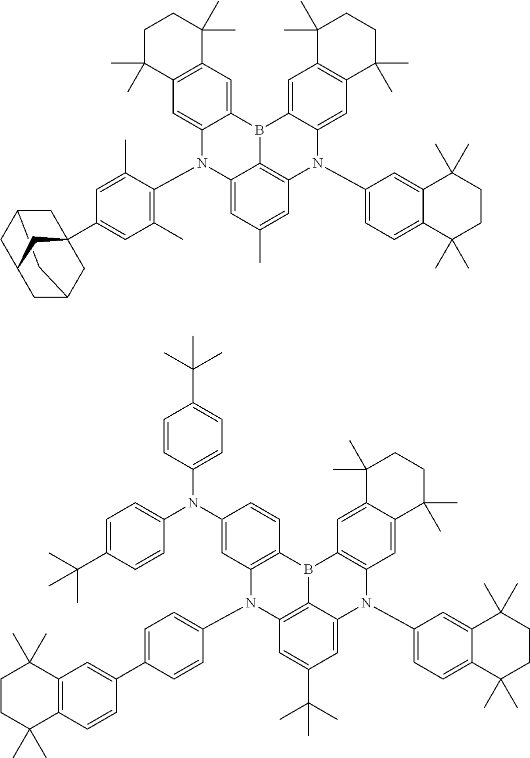 [SMILES: Cc1cc2c3c(c1)N(c1c(C)cc([C@]45CC6CC(C[C@H](C6)C4)C5)cc1C)c1cc4c(cc1B3c1cc3c(cc1N2c1ccc2c(c1)C(C)(C)CCC2(C)C)C(C)(C)CCC3(C)C)C(C)(C)CCC4(C)C ; CC(C)(C)c1ccc(N(c2ccc(C(C)(C)C)cc2)c2ccc3c(c2)N(c2ccc(-c4ccc5c(c4)C(C)(C)CCC5(C)C)cc2)c2cc(C(C)(C)C)cc4c2B3c2cc3c(cc2N4c2ccc4c(c2)C(C)(C)CCC4(C)C)C(C)(C)CCC3(C)C)cc1]

In an exemplary embodiment of the present specification, the compound of Chemical Formula 3 is any one of the following compounds.

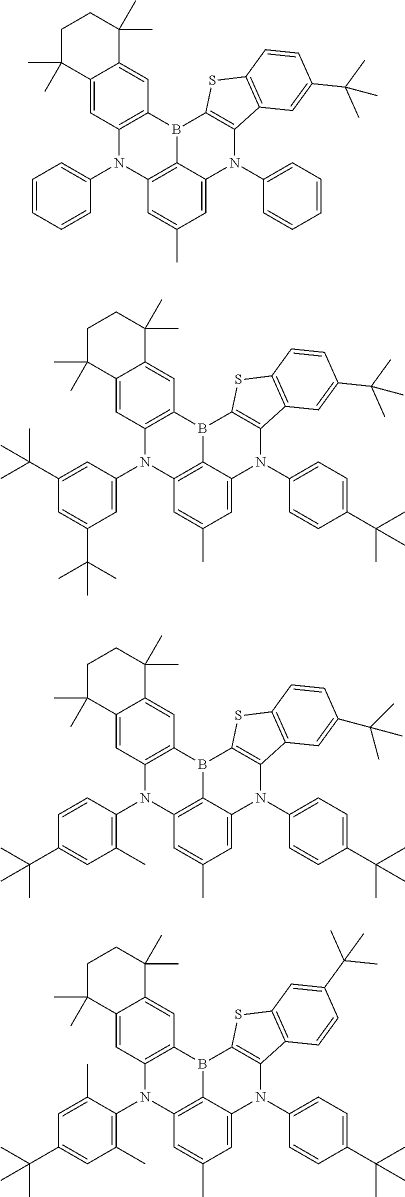

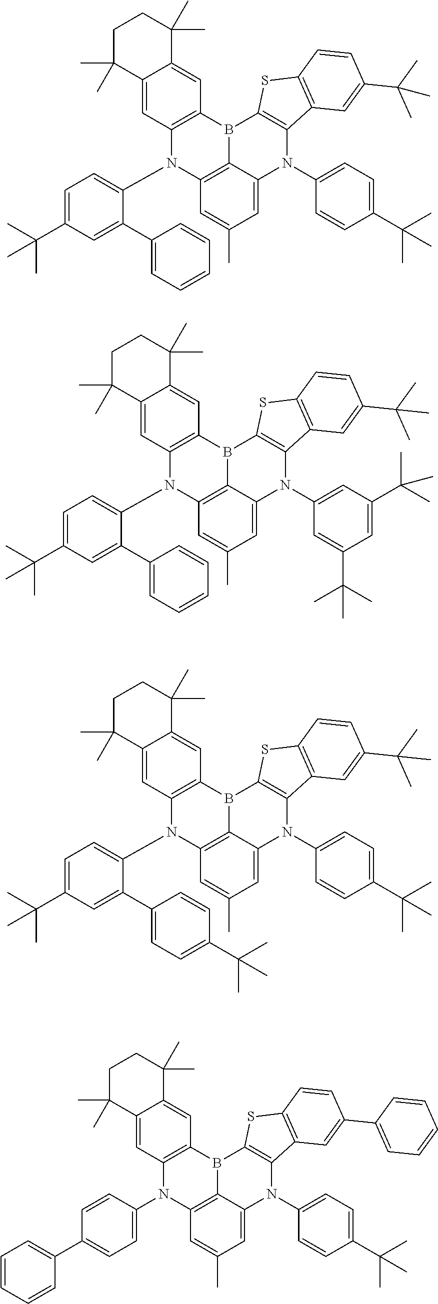

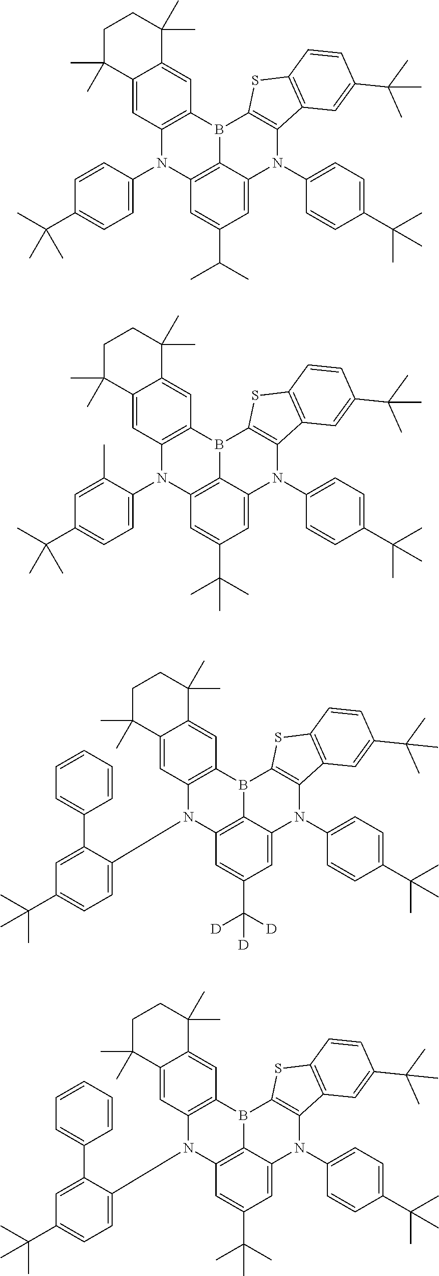

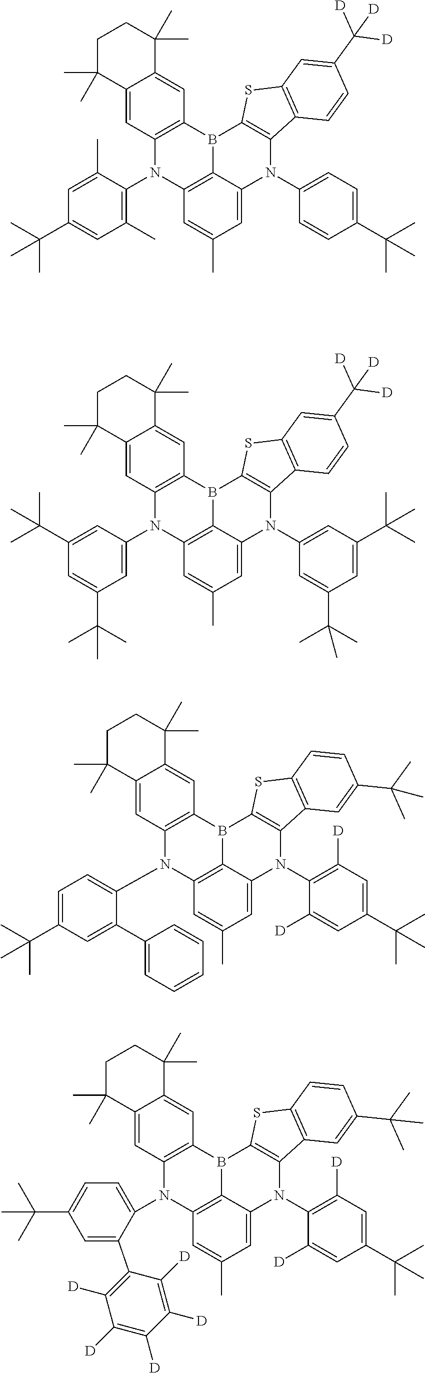

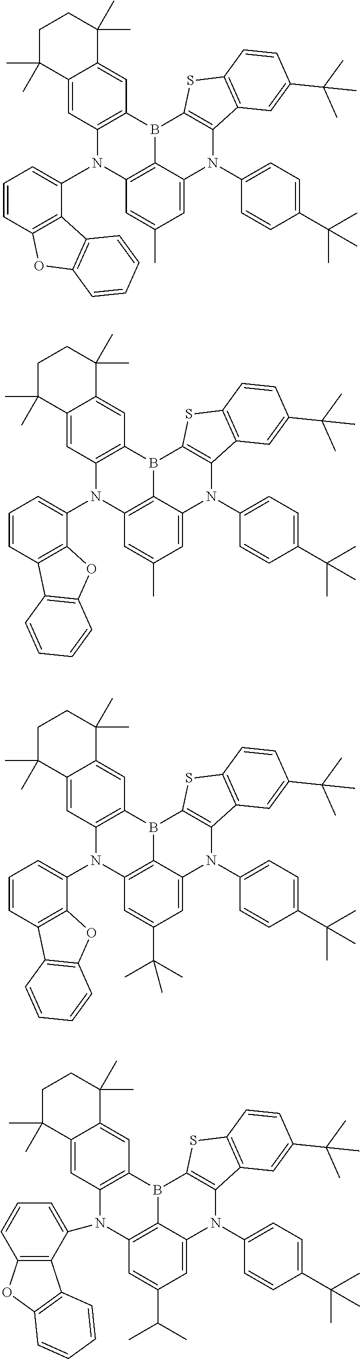

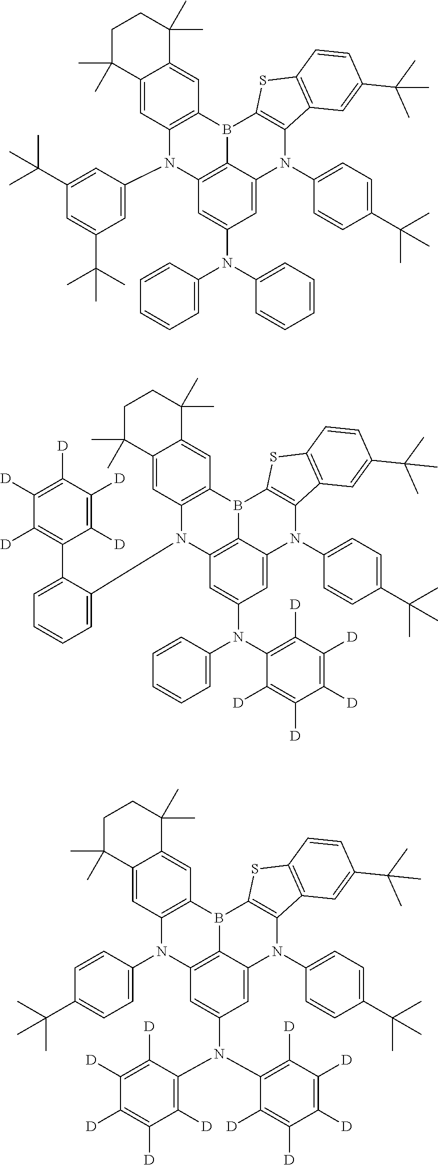

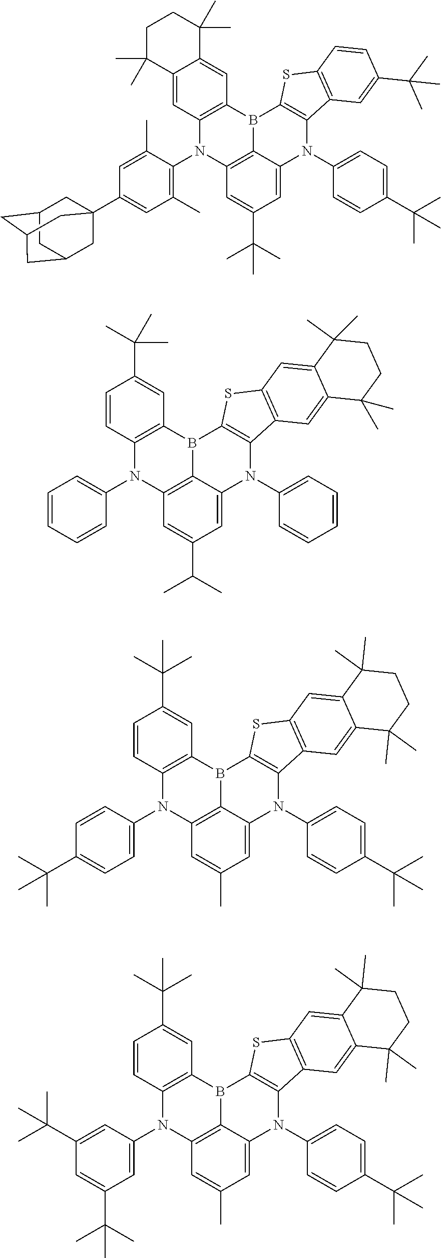

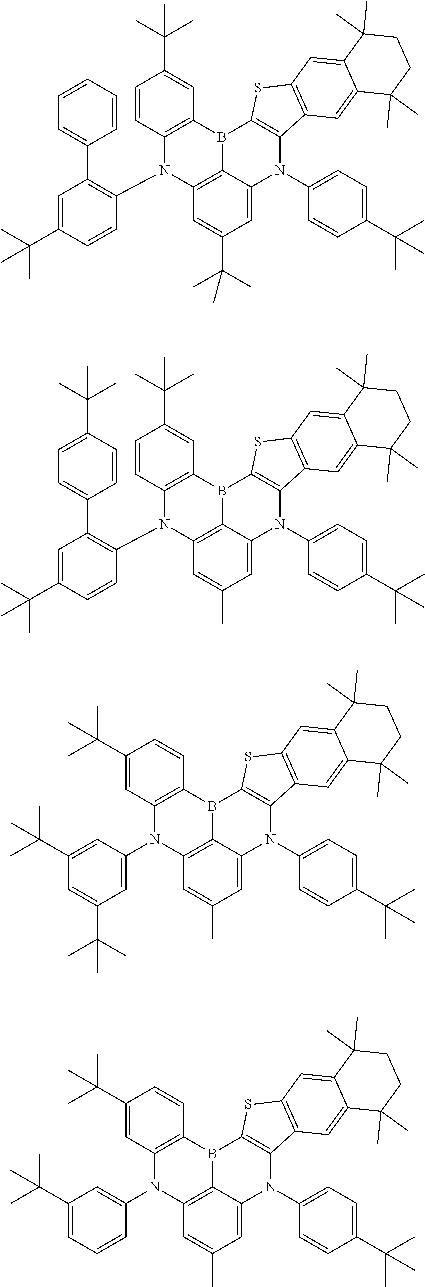

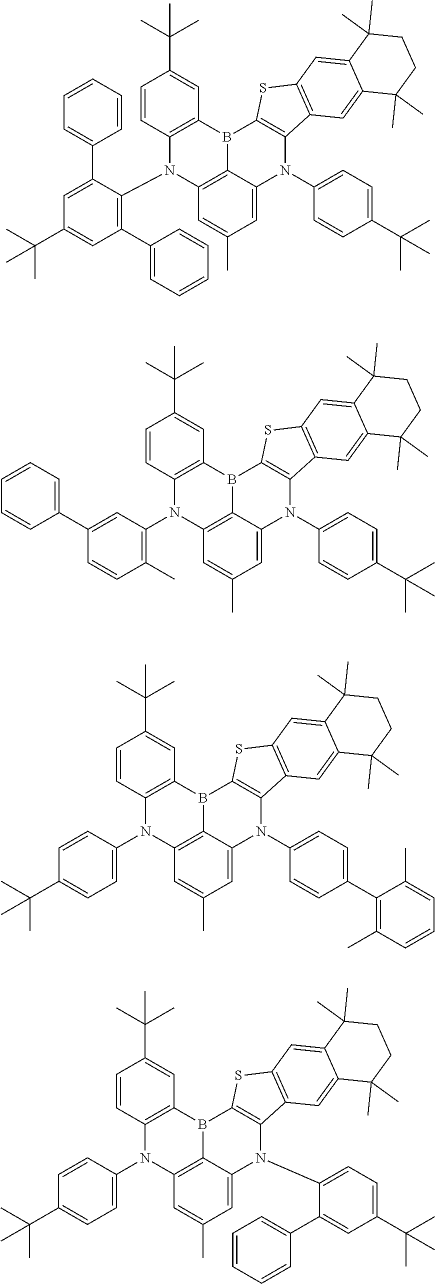

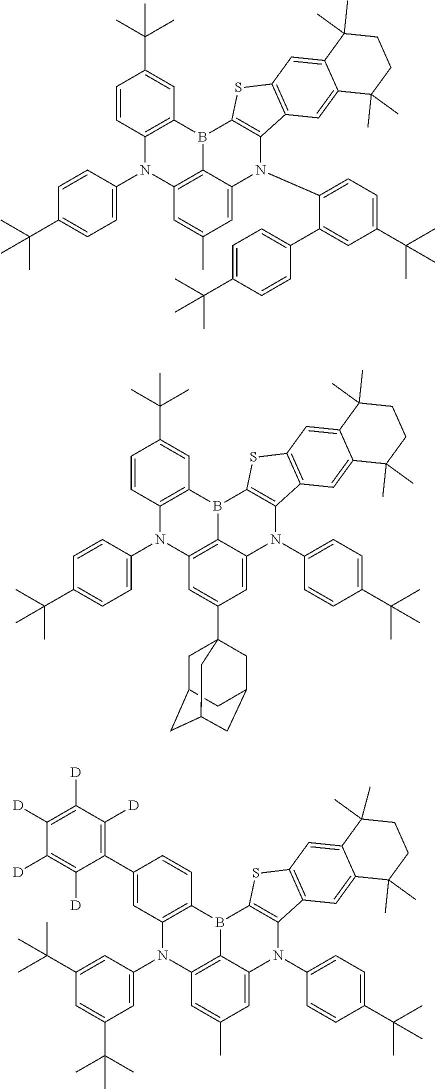

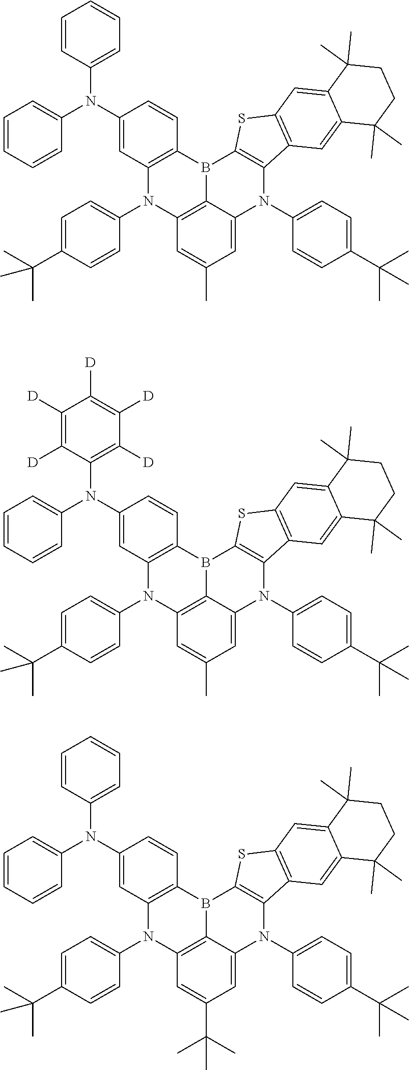

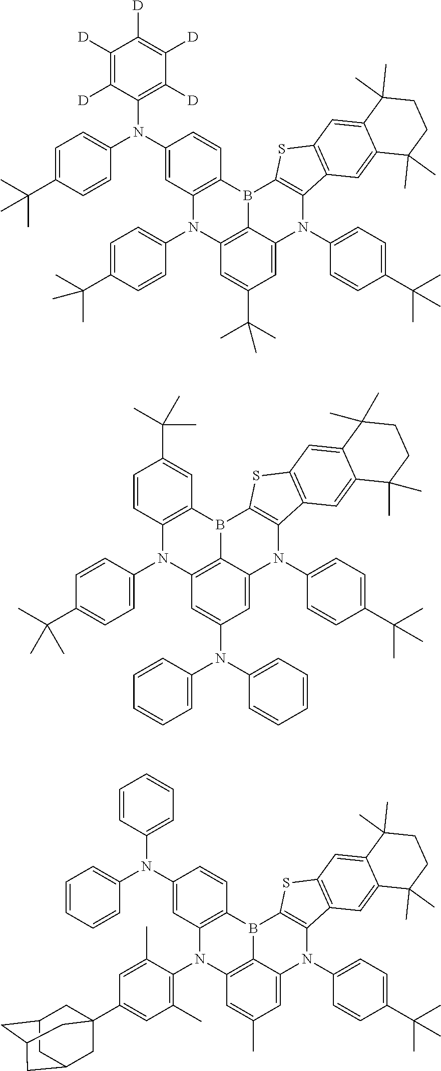

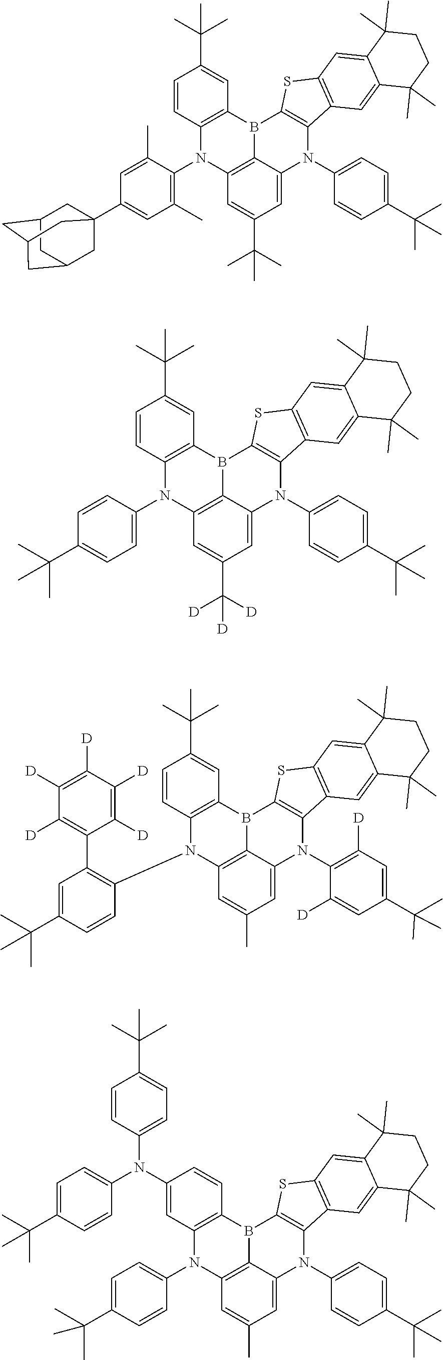

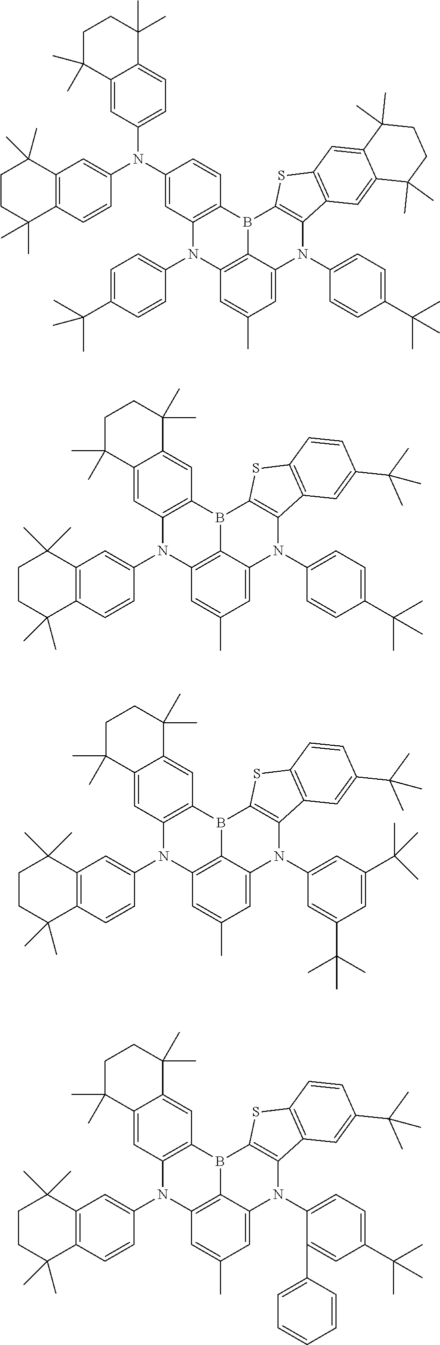

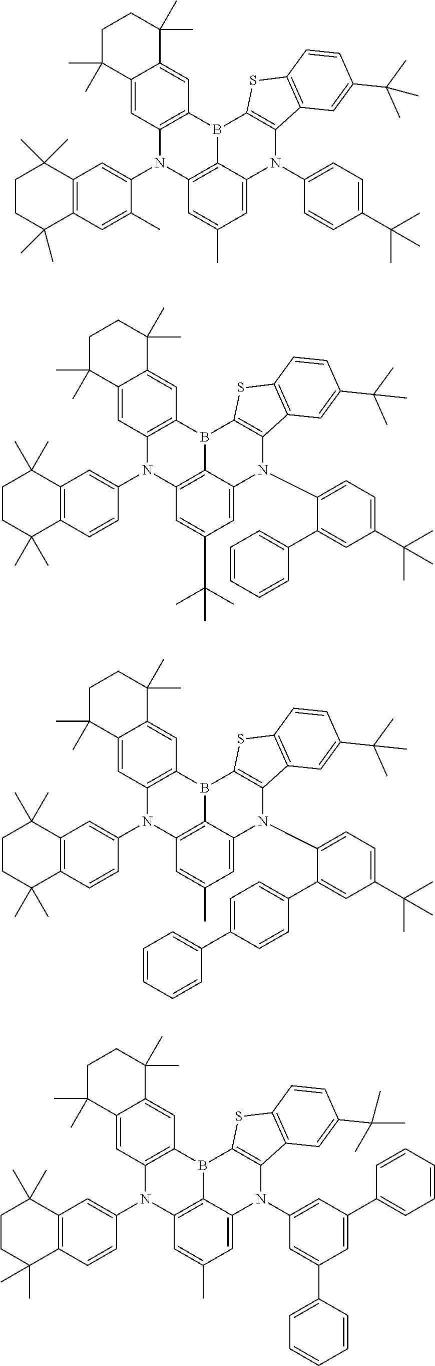

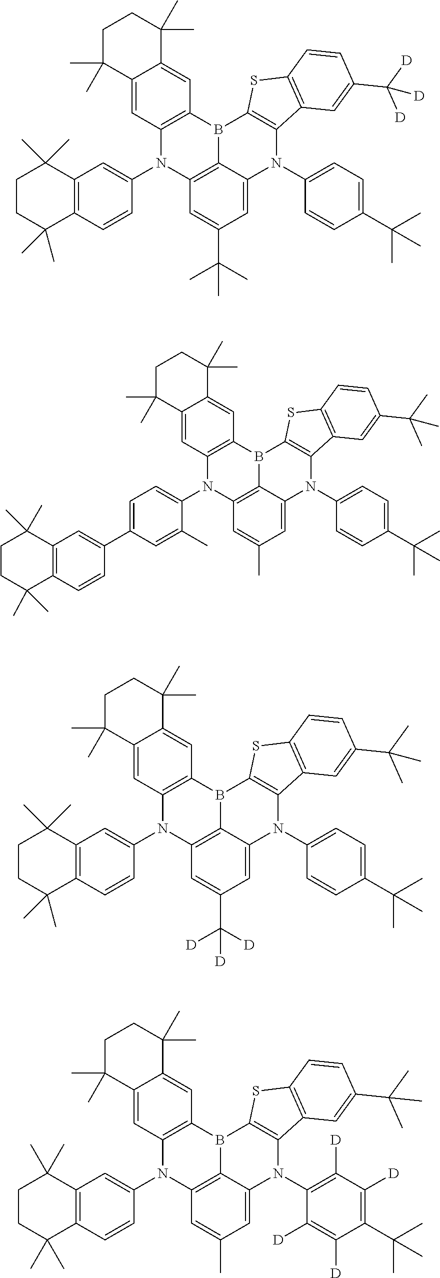

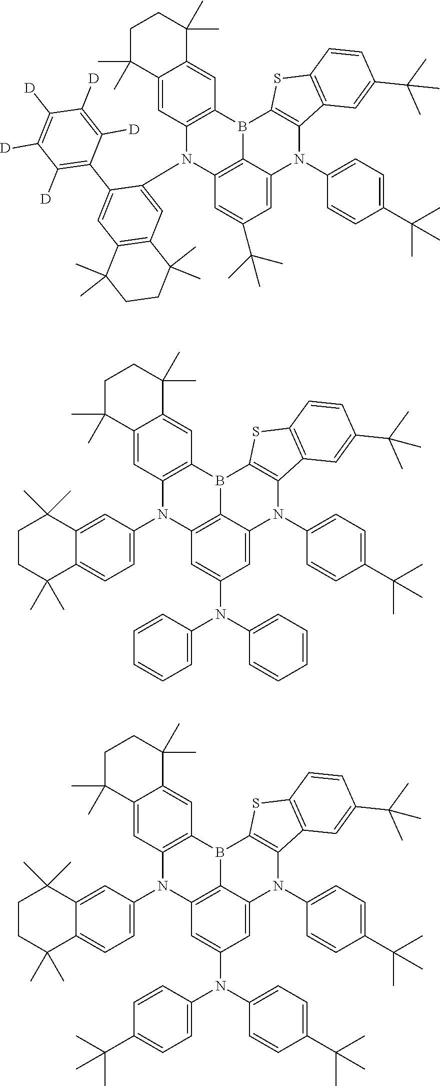

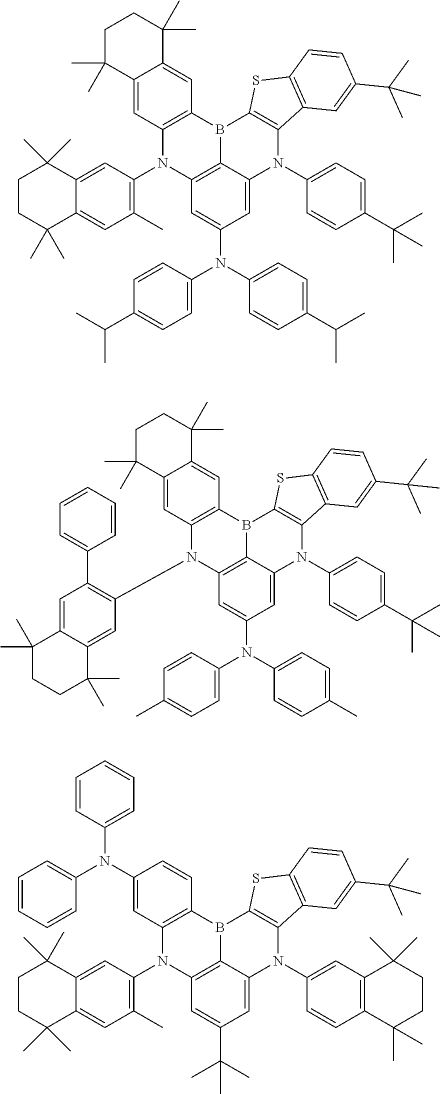

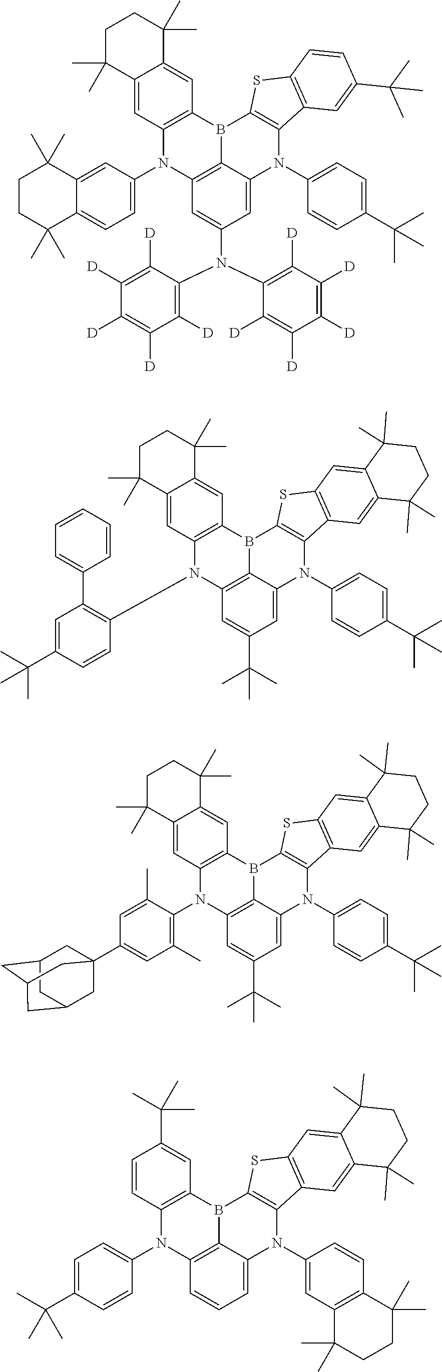

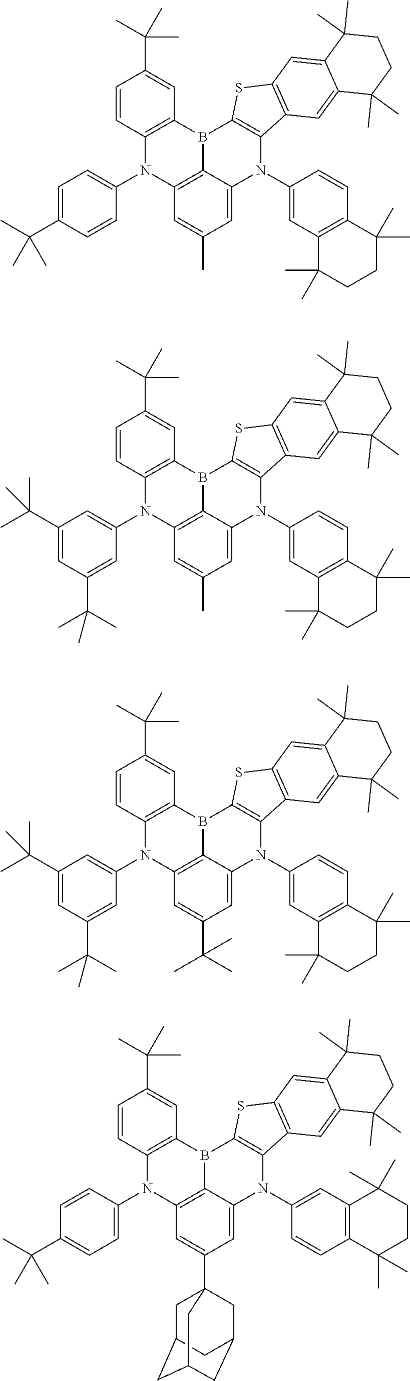

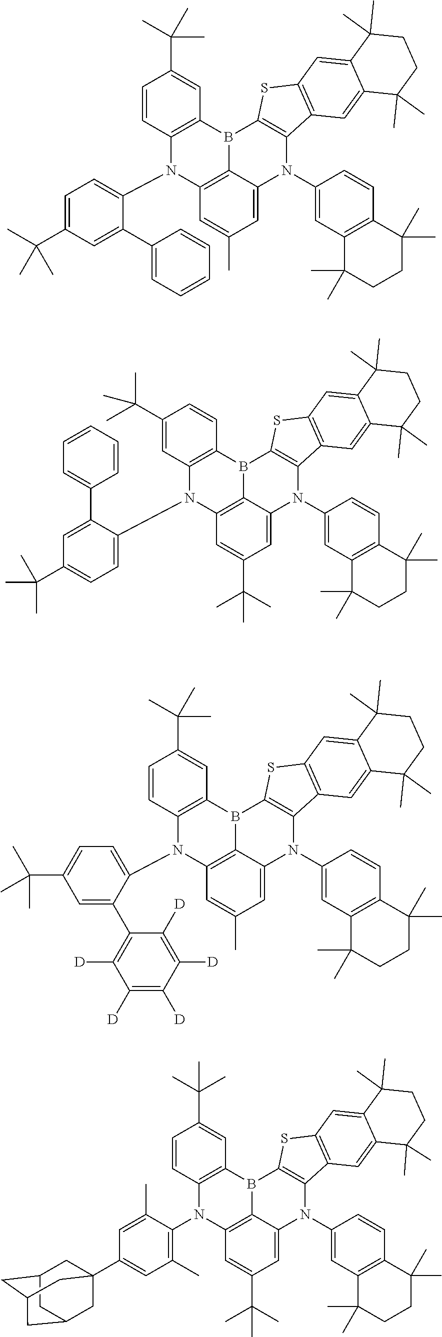

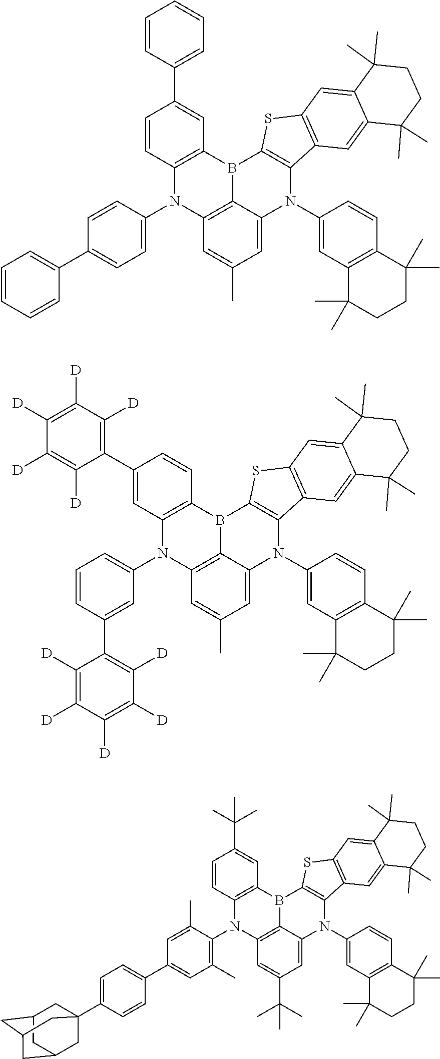 [SMILES: Cc1cc2c3c(c1)N(c1ccc4c(c1)C(C)(C)CCC4(C)C)c1c(sc4cc5c(cc14)C(C)(C)CCC5(C)C)B3c1cc(-c3ccccc3)ccc1N2c1ccc(-c2ccccc2)cc1 ; [2H]c1c([2H])c([2H])c(-c2cccc(N3c4cc(-c5c([2H])c([2H])c([2H])c([2H])c5[2H])ccc4B4c5sc6cc7c(cc6c5N(c5ccc6c(c5)C(C)(C)CCC6(C)C)c5cc(C)cc3c54)C(C)(C)CCC7(C)C)c2)c([2H])c1[2H] ; Cc1cc(-c2ccc(C34CC5CC(CC(C5)C3)C4)cc2)cc(C)c1N1c2ccc(C(C)(C)C)cc2B2c3sc4cc5c(cc4c3N(c3ccc4c(c3)C(C)(C)CCC4(C)C)c3cc(C(C)(C)C)cc1c32)C(C)(C)CCC5(C)C]

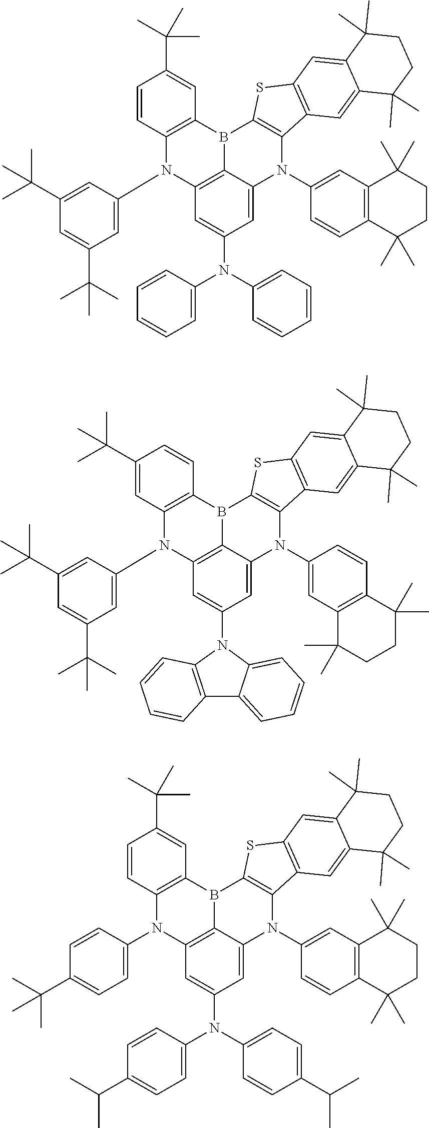

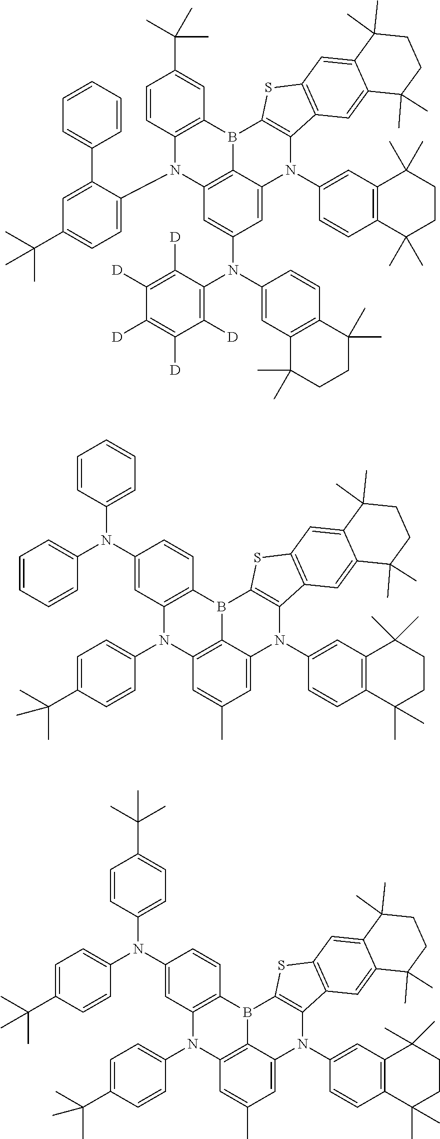

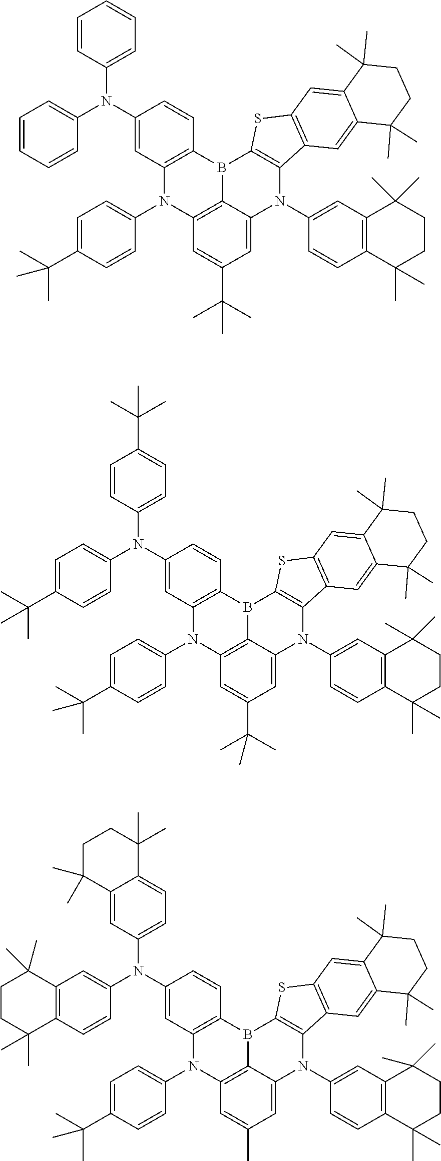

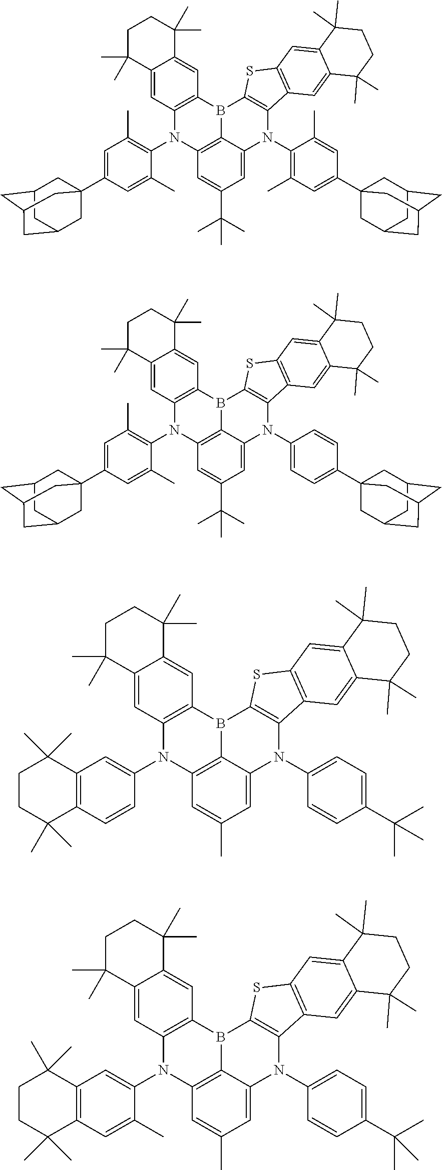

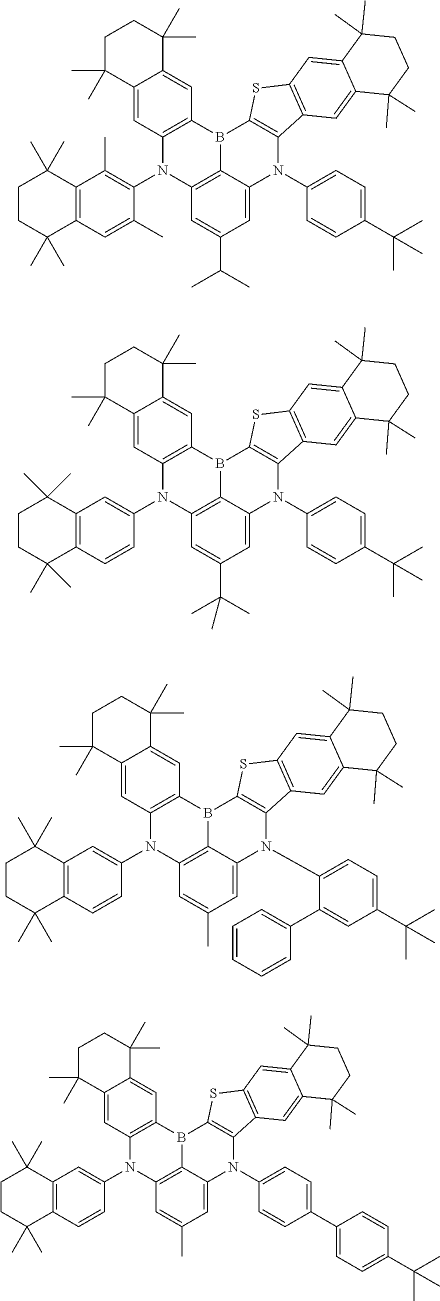

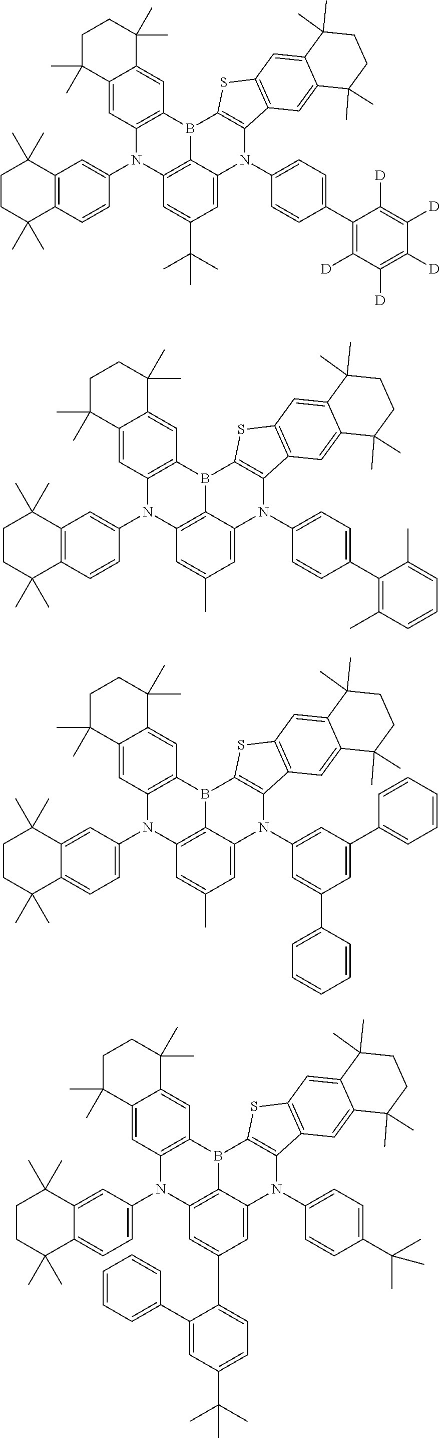

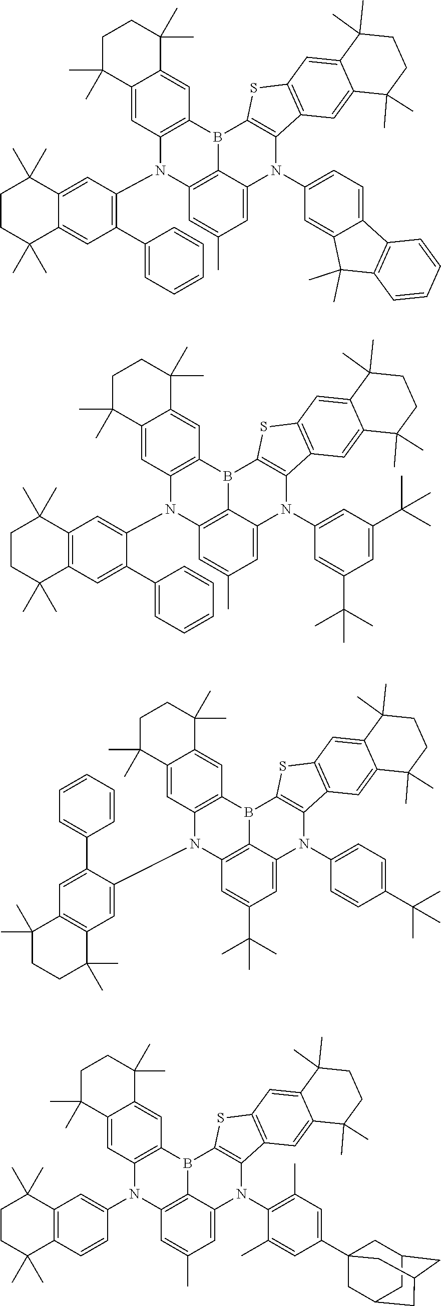

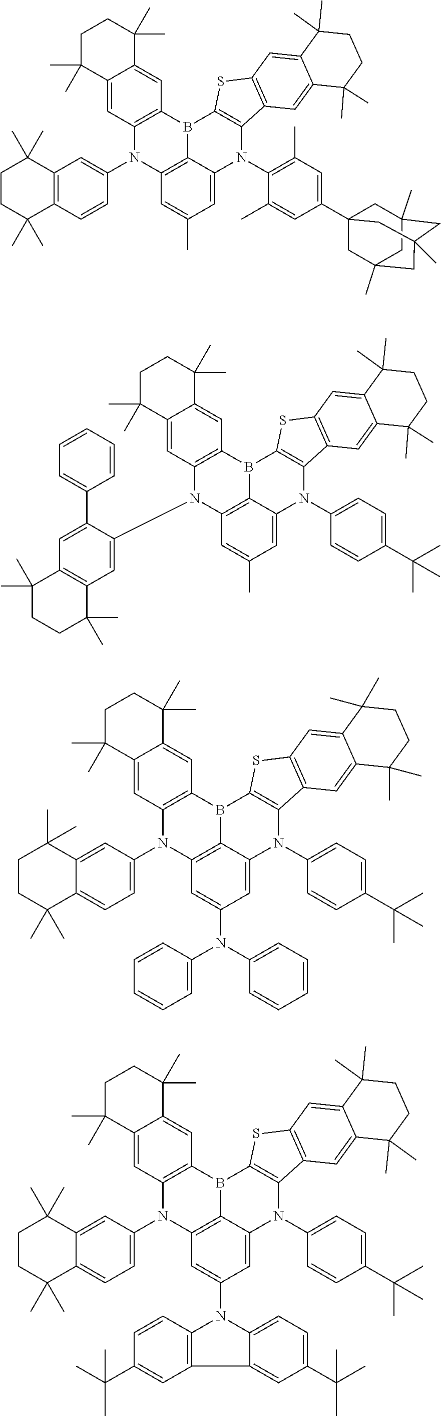

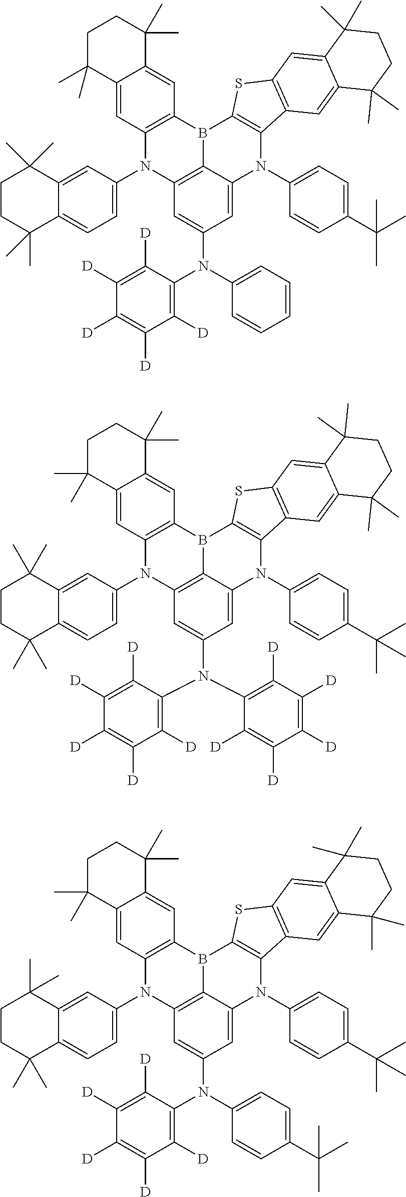

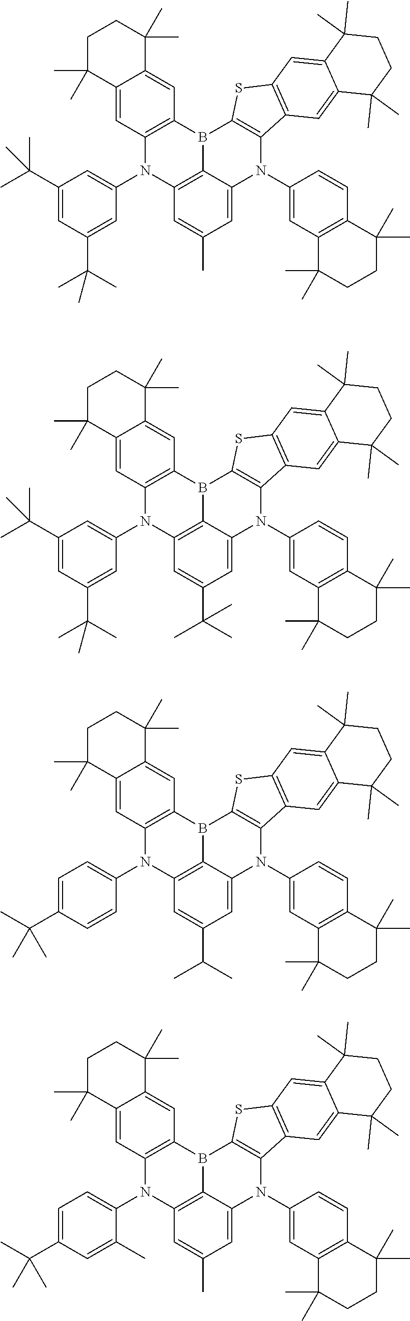

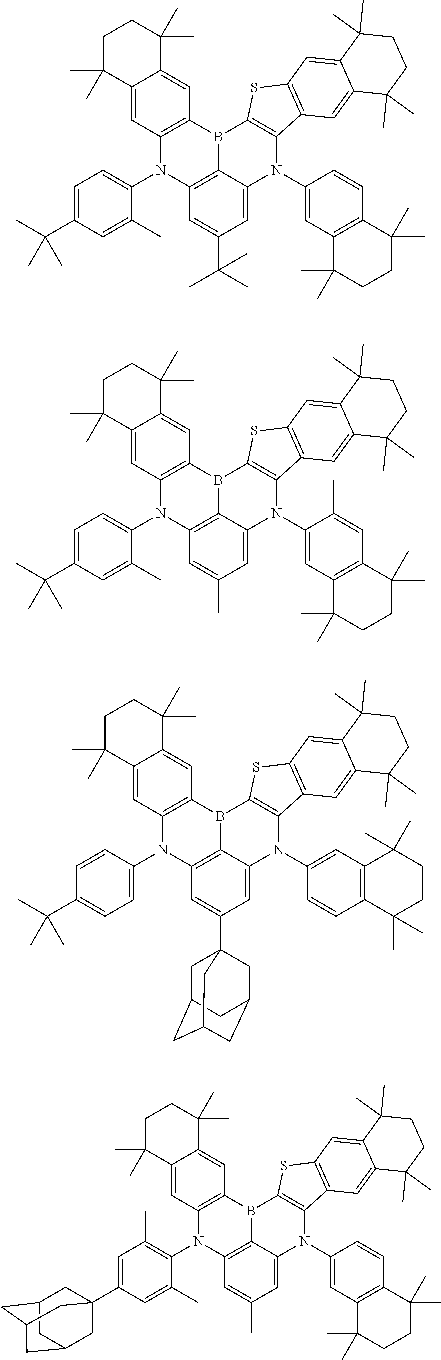

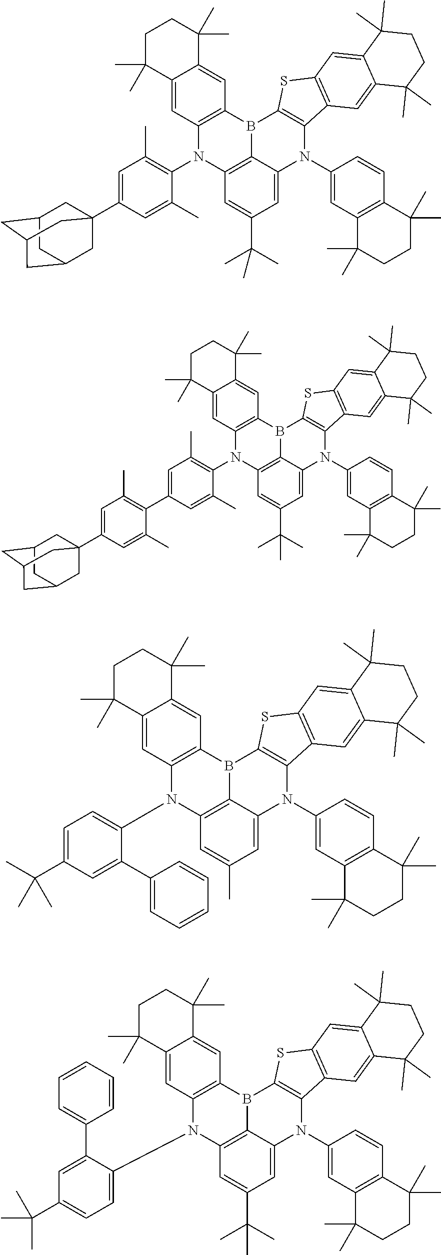

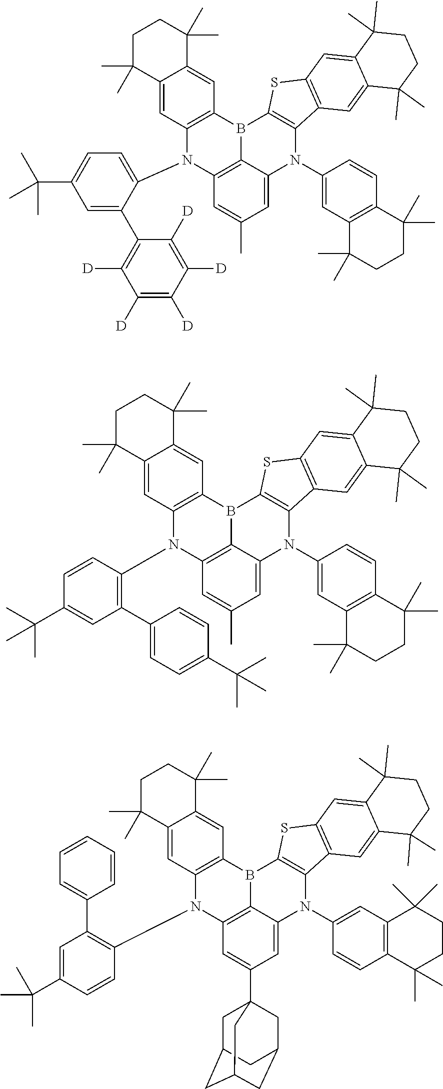

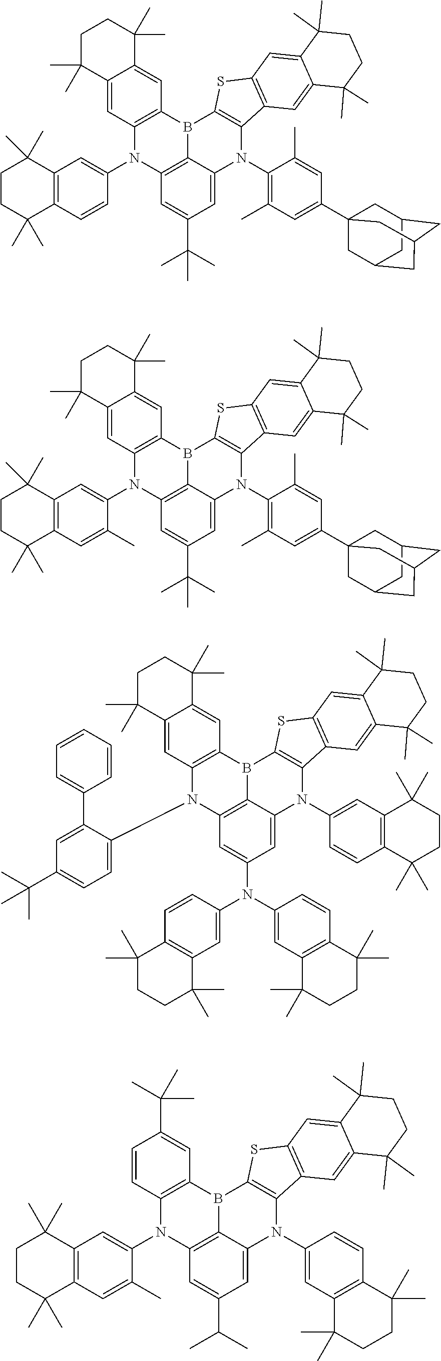

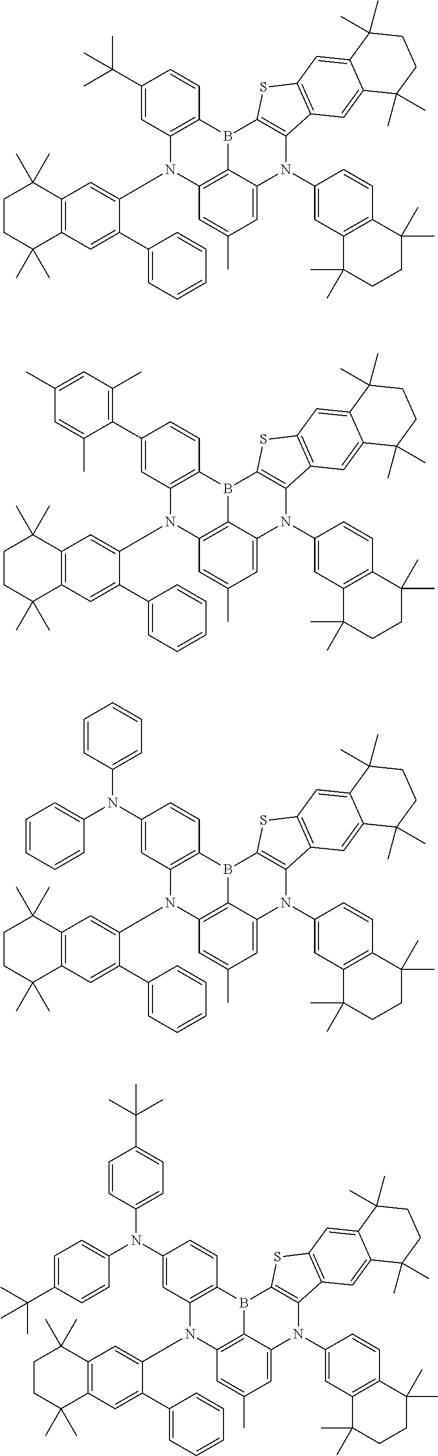

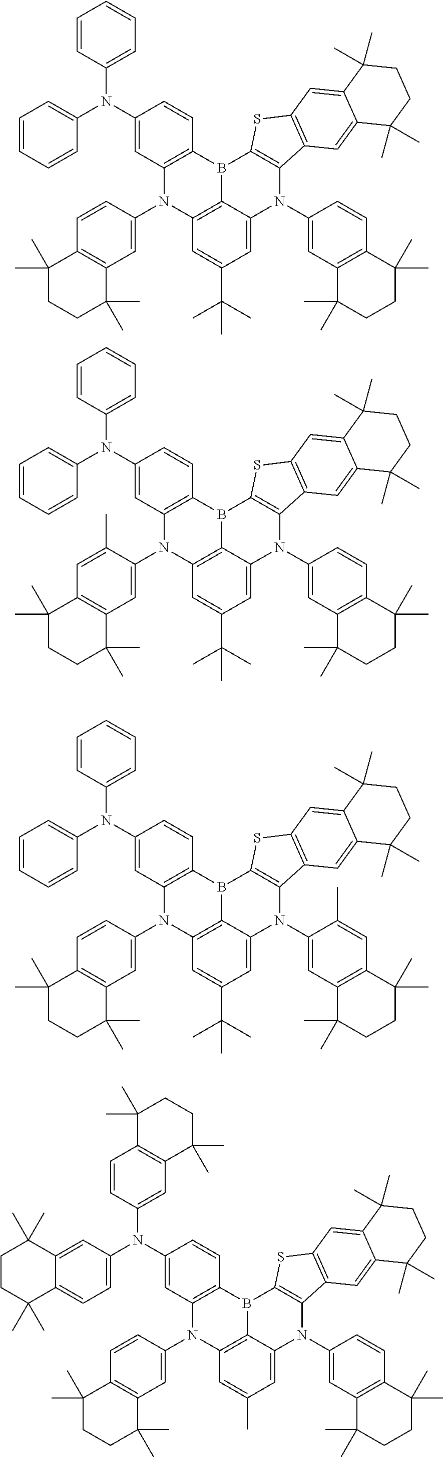

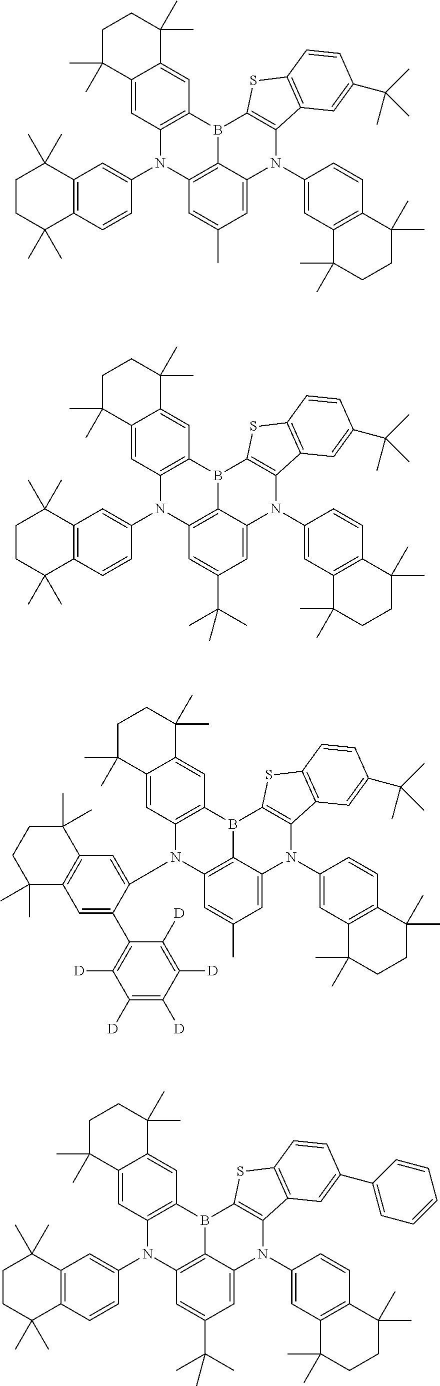

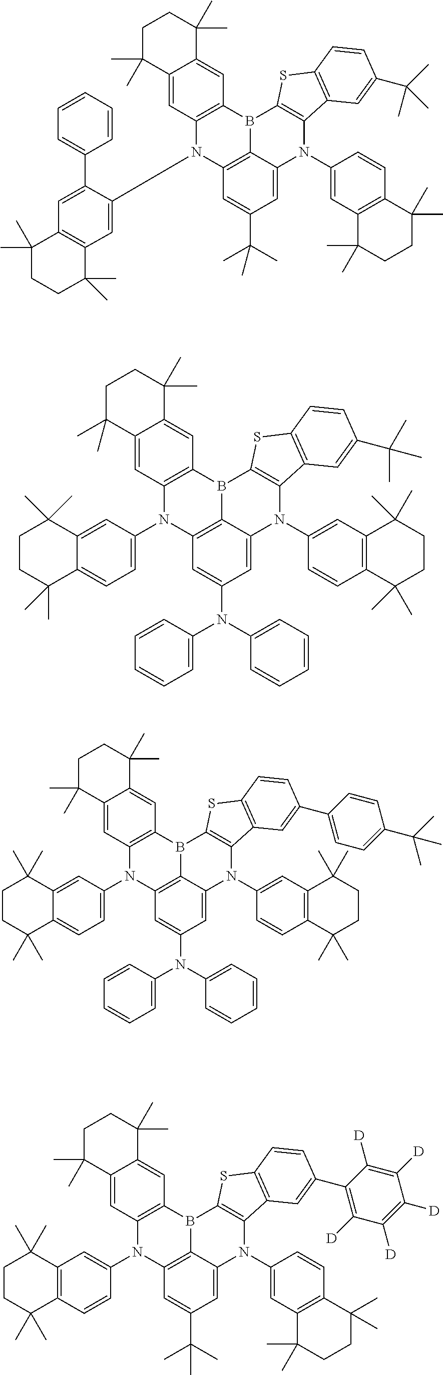

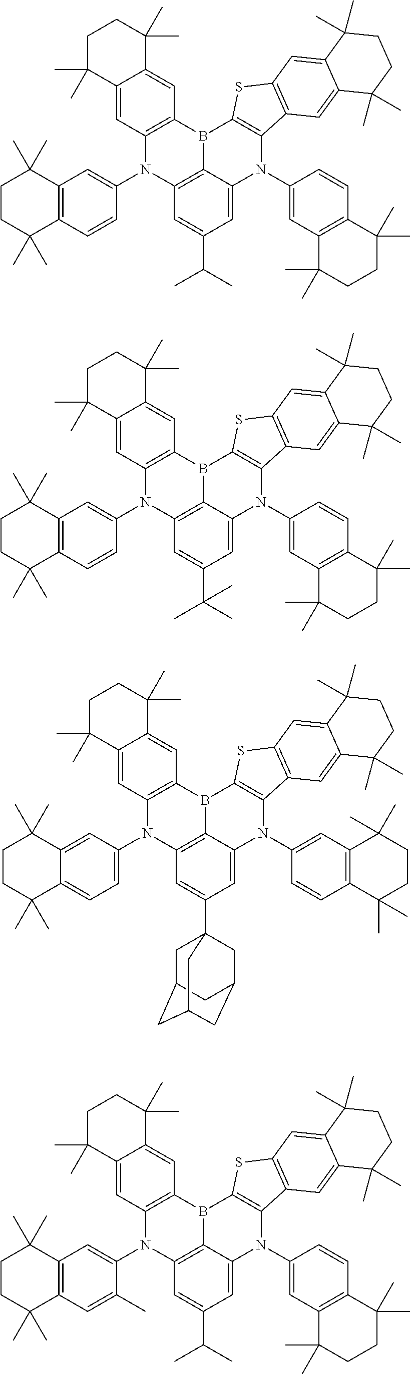

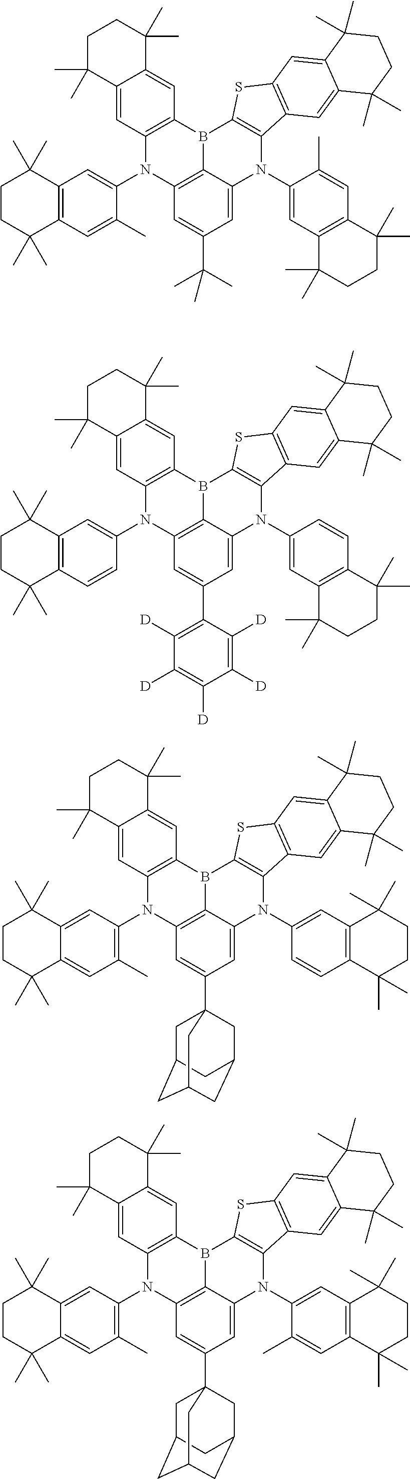

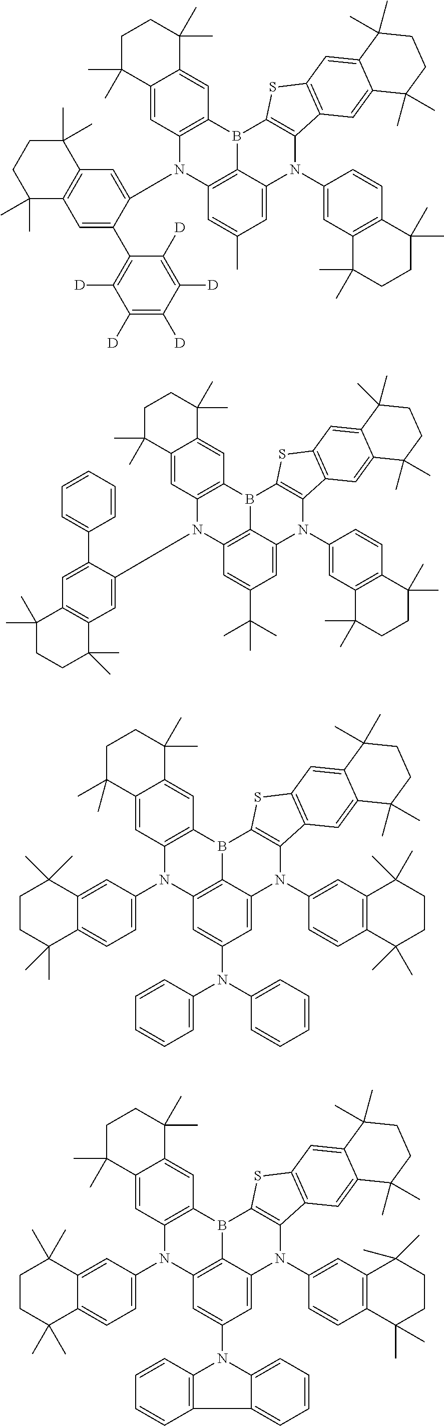

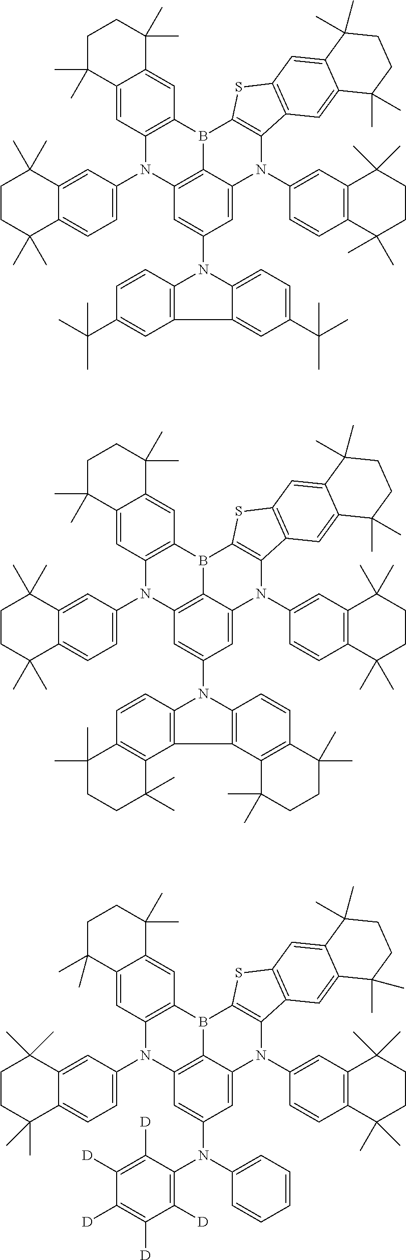

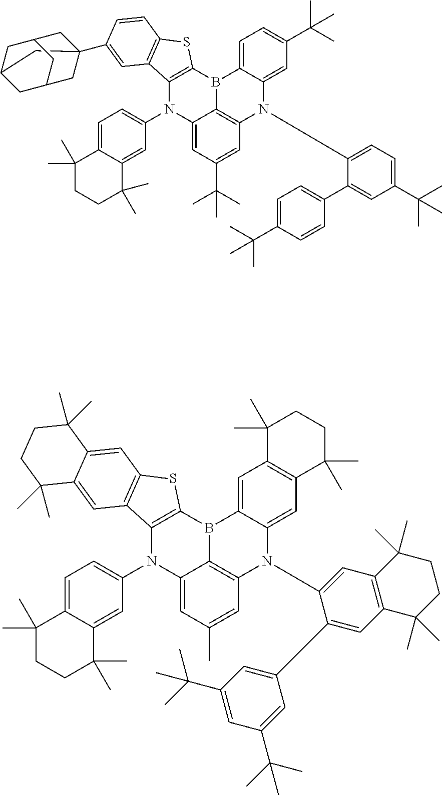

According to an exemplary embodiment of the present invention, the compound of Chemical Formula 1 may be prepared as in the following Reaction Scheme of Chemical Formula 1, and the compounds of Chemical Formulae 2 and 3 may be prepared as in the following Reaction Scheme of Chemical Formula 2 and the following Reaction Scheme of Chemical Formula 3. The following reaction schemes describe the general synthesis procedures of Chemical Formulae 1 to 3 of the present invention, but various compounds included in Chemical Formulae 1 to 3 of the present invention may be synthesized using the synthesis procedure as in the following reaction schemes, a substituent may be bonded by methods known in the art, and the type and position of substituent and the number of substituents may be changed according to the technology known in the art.

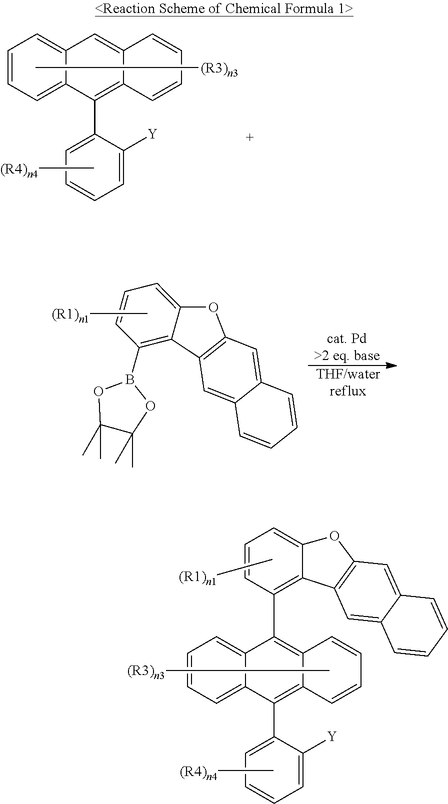

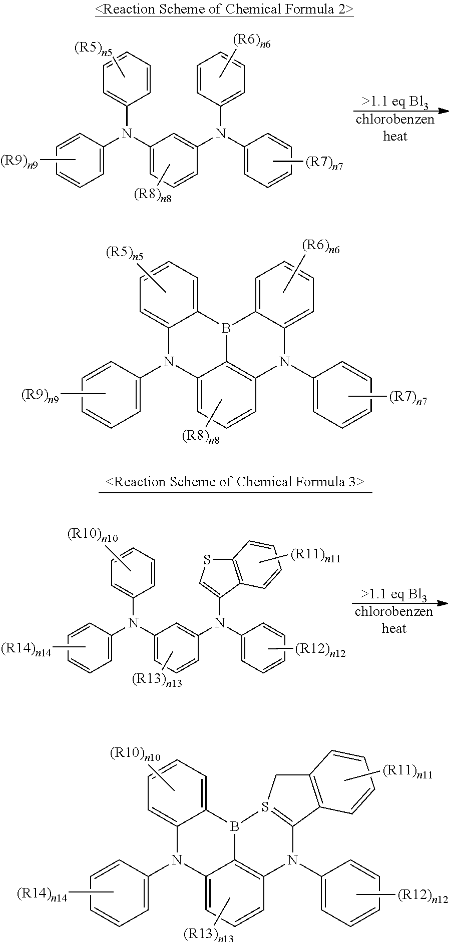

A core structure of the compounds of Chemical Formulae 1 to 3 according to an exemplary embodiment of the present specification may be prepared as in the method of the Preparation Example to be described below. The substituent may be bonded by a method known in the art, and the kind and position of the substituent or the number of substituents may be changed according to the technology known in the art.

In the present specification, compounds having various energy band gaps may be synthesized by introducing various substituents into the core structures of the compounds of Chemical Formulae 1 to 3. Further, in the present specification, various substituents may be introduced into the core structures having the structure described above to adjust the HOMO and LUMO energy levels of a compound.

Hereinafter, an organic light emitting device will be described.

When one member is disposed “on” another member in the present specification, this includes not only a case where the one member is brought into contact with another member, but also a case where still another member is present between the two members.

When one part “includes” one constituent element in the present specification, unless otherwise specifically described, this does not mean that another constituent element is excluded, but means that another constituent element may be further included.

The organic light emitting device according to the present specification is an organic light emitting device including: an anode; a cathode; and a light emitting layer provided between the anode and the cathode, in which the light emitting layer includes a compound of Chemical Formula 1 and a compound of Chemical Formula 2 or Chemical Formula 3.

The organic light emitting device of the present invention may be manufactured by typical methods and materials for manufacturing an organic light emitting device, except that a light emitting layer is formed using the above-described compound of Chemical Formula 1 and the above-described compound of Chemical Formula 2 or 3.

The compound may be formed as an organic material layer by not only a vacuum deposition method, but also a solution application method when an organic light emitting device is manufactured. Here, the solution application method means spin coating, dip coating, inkjet printing, screen printing, a spray method, roll coating, and the like, but is not limited thereto.

The organic material layer of the organic light emitting device of the present specification may also have a single-layered structure, but may have a multi-layered structure in which two or more organic material layers are stacked. For example, the organic light emitting device of the present invention may have a structure including one or more layers of a hole injection layer, a hole transport layer, an electron blocking layer, a light emitting layer, a hole injection and transport layer, an electron transport layer, an electron injection layer, a hole blocking layer, and an electron transport and injection layer as organic material layers. However, the structure of the organic light emitting device of the present specification is not limited thereto, and may include a fewer or greater number of organic material layers.

In the organic light emitting device according to an exemplary embodiment of the present specification, the light emitting layer includes the compound of Chemical Formula 1 as a host.

In the organic light emitting device according to an exemplary embodiment of the present specification, the light emitting layer includes two or more of the compound of Chemical Formula 1 as a host.

In the organic light emitting device according to an exemplary embodiment of the present specification, the light emitting layer includes the compound of Chemical Formula 2 or Chemical Formula 3 as a dopant.

In the organic light emitting device according to an exemplary embodiment of the present specification, the light emitting layer includes two or more of the compound of Chemical Formula 2 or Chemical Formula 3 as a dopant.

In the organic light emitting device according to an exemplary embodiment of the present specification, the dopant in the light emitting layer may be included in an amount of 1 part by weight to 50 parts by weight, preferably 0.1 parts by weight to 30 parts by weight, and more preferably 1 part by weight to 10 parts by weight, based on 100 parts by weight of the host. Within the above range, energy transfer from the host to the dopant occurs efficiently.

In the organic light emitting device according to an exemplary embodiment of the present specification, it is possible to further include a fluorescent host, a phosphorescent host, a fluorescent dopant or a phosphorescent dopant, in addition to the compound of Chemical Formula 1 and the compound of Chemical Formula 2 or 3.

In an exemplary embodiment of the present specification, the organic material layer includes a light emitting layer having two or more layers, and one or more layers of the light emitting layer having two or more layers include the compound of Chemical Formula 1 and the compound of Chemical Formula 2 or 3.

In an exemplary embodiment of the present specification, the organic material layer includes a light emitting layer having two or more layers, and the light emitting layer having two or more layers each includes the compound of Chemical Formula 1 and the compound of Chemical Formula 2 or 3.

In an exemplary embodiment of the present specification, the maximum light emission peaks of the light emitting layer having two or more layers are different from each other. The light emitting layer including the compound of Chemical Formula 1 and the compound of Chemical Formula 2 or 3 takes on a blue color, and a light emitting layer which does not include the compound of Chemical Formula 1 may include a blue, red, or green light emitting compound known in the art.

In an exemplary embodiment of the present specification, the maximum light emission peak of the light emitting layer including the compound of Chemical Formula 1 and the compound of Chemical Formula 2 or 3 is 400 nm to 500 nm. That is, the light emitting layer including the compound of Chemical Formula 1 and the compound of Chemical Formula 2 or 3 emits blue light.

The organic material layer of the organic light emitting device according to an exemplary embodiment of the present specification includes a light emitting layer having two or more layers, a light emitting layer having one layer (Light emitting layer 1) has a maximum light emission peak of 400 nm to 500 nm, and the maximum light emission peak of a light emitting layer having the other layer (Light emitting layer 2) may exhibit a maximum light emission peak of 510 nm to 580 nm; or 610 nm to 680 nm. In this case, Light emitting layer 1 may include the compound of Chemical Formula 1 and the compound of Chemical Formula 2 or 3. Furthermore, Light emitting layer 2 may include the compound of Chemical Formula 1 and the compound of Chemical Formula 2 or 3.

In an exemplary embodiment of the present specification, the organic light emitting device may be a normal type organic light emitting device in which a positive electrode, an organic material layer having one or more layers, and a negative electrode are sequentially stacked on a substrate.

In an exemplary embodiment of the present specification, the organic light emitting device may be an inverted type organic light emitting device in which a positive electrode, an organic material layer having one or more layers, and a negative electrode are sequentially stacked on a substrate.

The structure of the organic light emitting device of the present specification may have a structure as illustrated in FIGS. 1, 2, and 8, but is not limited thereto.

FIG. 1 illustrates a structure of an organic light emitting device in which a substrate 1, a positive electrode 2, a hole injection layer 3, a hole transport layer 4, a light emitting layer 6, a hole blocking layer 7, an electron injection and transport layer 8, and a negative electrode 11 are sequentially stacked. In the structure as described above, the compound of Chemical Formula 1 and the compound of Chemical Formula 2 or 3 may be included in the light emitting layer 6.

FIG. 2 illustrates a structure of an organic light emitting device in which a substrate 1, a positive electrode 2, a hole injection layer 3, a hole transport layer 4, an electron blocking layer 5, a light emitting layer 6, an electron injection and transport layer 8, and a negative electrode 11 are sequentially stacked. In the structure as described above, the compound of Chemical Formula 1 and the compound of Chemical Formula 2 or 3 may be included in the light emitting layer 6.

FIG. 8 illustrates a structure of an organic light emitting device in which a substrate 1, a positive electrode 2, a p-doped hole transport layer 4p, hole transport layers 4R, 4G, and 4B, light emitting layers 6RP, 6GP, and 6BF, a first electron transport layer 9a, a second electron transport layer 9b, an electron injection layer 10, a negative electrode 11, and a capping layer 14 are sequentially stacked. In the structure as described above, the compound of Chemical Formula 1 and the compound of Chemical Formula 2 or 3 may be included in the light emitting layers 6RP, 6GP, and 6BF.

According to an exemplary embodiment of the present specification, the organic light emitting device may have a tandem structure in which two or more independent devices are connected in series. In an exemplary embodiment, the tandem structure may be in the form of each organic light emitting device joined by a charge generating layer. Since a device having a tandem structure can be driven with a current lower than that of a unit device based on the same brightness, there is an advantage in that the service life characteristic of the device is significantly improved.

According to an exemplary embodiment of the present specification, the organic material layer includes: a first stack including a light emitting layer having one or more layers; a second stack including a light emitting layer having one or more layers; and a charge generating layer having one or more layers provided between the first stack and the second stack.

According to an exemplary embodiment of the present specification, the organic material layer includes: a first stack including a light emitting layer having one or more layers; a second stack including a light emitting layer having one or more layers; and a third stack including a light emitting layer having one or more layer, and includes a charge generating layer having one or more layers, between the first stack and the second stack; and between the second stack and the third stack, respectively.

In the present specification, the charge generating layer means a layer in which holes and electrons are generated when a voltage is applied. The charge generating layer may be an N-type charge generating layer or a P-type charge generating layer. In the present specification, an N-type charge generating layer means a charge generating layer located closer to a positive electrode than a P-type charge generating layer, and a P-type charge generating layer means a charge generating layer located closer to a negative electrode than an N-type charge generating layer.

The N-type charge generating layer and the P-type charge generating layer may be provided to be brought into contact with each other, and in this case, form an NP junction. Holes and electrons are easily formed in the P-type charge generating layer and the N-type charge generating layer, respectively by the NP junction. Electrons are transported toward the positive electrode through the LUMO level of the N-type charge generating layer, and holes are transported toward the negative electrode through the HOMO level of the P-type organic material layer.

The first stack, the second stack, and the third stack each include a light emitting layer having one or more layers, and may further include one or more layers of a hole injection layer, a hole transport layer, an electron blocking layer, an electron injection layer, an electron transport layer, a hole blocking layer, a layer which simultaneously transports and injects holes (a hole injection and transport layer), and a layer which simultaneously transports and injects electrons (an electron injection and transport layer).

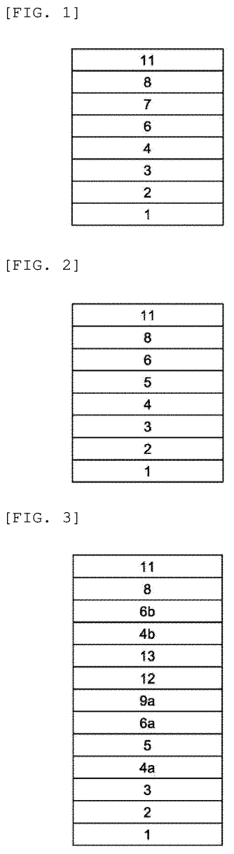

An organic light emitting device including the first stack and the second stack is illustrated in FIG. 3.

FIG. 3 illustrates the structure of an organic light emitting device in which a substrate 1, a positive electrode 2, a hole injection layer 3, a first hole transport layer 4a, an electron blocking layer 5, a first light emitting layer 6a, a first electron transport layer 9a, an N-type charge generating layer 12, a P-type charge generating layer 13, a second hole transport layer 4b, a second light emitting layer 6b, an electron injection and transport layer 8, and a negative electrode 11 are sequentially stacked. In the structure as described above, the compound of Chemical Formula 1 and the compound of Chemical Formula 2 or 3 may be included in the first light emitting layers 6a or the second light emitting layer 6b.

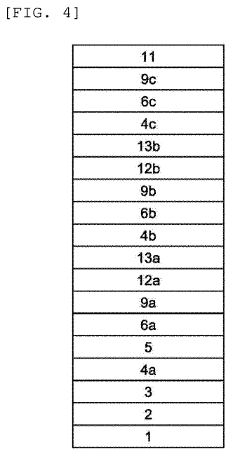

An organic light emitting device including the first stack to the third stack is illustrated in FIGS. 4 to 7.

FIG. 4 illustrates the structure of an organic light emitting device in which a substrate 1, a positive electrode 2, a hole injection layer 3, a first hole transport layer 4a, an electron blocking layer 5, a first light emitting layer 6a, a first electron transport layer 9a, a first N-type charge generating layer 12a, a first P-type charge generating layer 13a, a second hole transport layer 4b, a second light emitting layer 6b, a second electron transport layer 9b, a second N-type charge generating layer 12b, a second P-type charge generating layer 13b, a third hole transport layer 4c, a third light emitting layer 6c, a third electron transport layer 9c, and a negative electrode 11 are sequentially stacked. In the structure as described above, the compound of Chemical Formula 1 and the compound of Chemical Formula 2 or 3 may be included in the first light emitting layers 6a, the second light emitting layer 6b, and the third light emitting layer 6c.

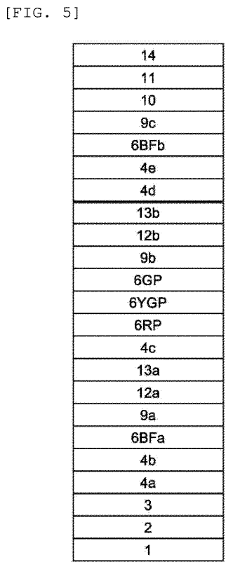

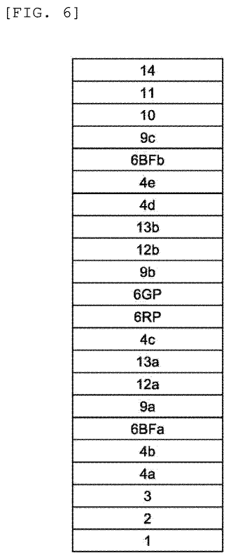

FIG. 5 illustrates the structure of an organic light emitting device in which a substrate 1, a positive electrode 2, a hole injection layer 3, a first hole transport layer 4a, a second hole transport layer 4b, a first blue fluorescent light emitting layer 6BFa, a first electron transport layer 9a, a first N-type charge generating layer 12a, a first P-type charge generating layer 13a, a third hole transport layer 4c, a red phosphorescent light emitting layer 6RP, a yellow green phosphorescent light emitting layer 6YGP, a green phosphorescent light emitting layer 6GP, a second electron transport layer 9b, a second N-type charge generating layer 12b, a second P-type charge generating layer 13b, a fourth hole transport layer 4d, a fifth hole transport layer 4e, a second blue fluorescent light emitting layer 6BFb, a third electron transport layer 9c, an electron injection layer 10, a negative electrode 11, and a capping layer 14 are sequentially stacked. In the structure as described above, the compound of Chemical Formula 1 and the compound of Chemical Formula 2 or 3 may be included in the first blue fluorescent light emitting layers 6BFa or the second blue fluorescent light emitting layer 6BFb.

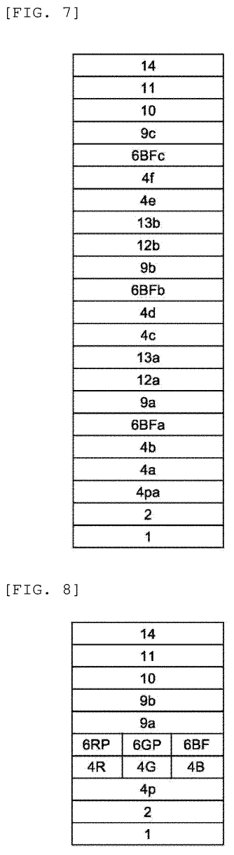

FIG. 6 illustrates the structure of an organic light emitting device in which a substrate 1, a positive electrode 2, a hole injection layer 3, a first hole transport layer 4a, a second hole transport layer 4b, a first blue fluorescent light emitting layer 6BFa, a first electron transport layer 9a, a first N-type charge generating layer 12a, a first P-type charge generating layer 13a, a third hole transport layer 4c, a red phosphorescent light emitting layer 6RP, a green phosphorescent light emitting layer 6GP, a second electron transport layer 9b, a second N-type charge generating layer 12b, a second P-type charge generating layer 13b, a fourth hole transport layer 4d, a fifth hole transport layer 4e, a second blue fluorescent light emitting layer 6BFb, a third electron transport layer 9c, an electron injection layer 10, a negative electrode 11, and a capping layer 14 are sequentially stacked. In the structure as described above, the compound of Chemical Formula 1 and the compound of Chemical Formula 2 or 3 may be included in the first blue fluorescent light emitting layers 6BFa or the second blue fluorescent light emitting layer 6BFb.

FIG. 7 illustrates the structure of an organic light emitting device in which a substrate 1, a positive electrode 2, a first p-doped hole transport layer 4pa, a first hole transport layer 4a, a second hole transport layer 4b, a first blue fluorescent light emitting layer 6BFa, a first electron transport layer 9a, a first N-type charge generating layer 12a, a first P-type charge generating layer 13a, a third hole transport layer 4c, a fourth hole transport layer 4d, a second blue fluorescent light emitting layer 6BFb, a second electron transport layer 9b, a second N-type charge generating layer 12b, a second P-type charge generating layer 13b, a fifth hole transport layer 4e, a sixth hole transport layer 4f, a third blue fluorescent light emitting layer 6BFc, a third electron transport layer 9c, an electron injection layer 10, a negative electrode 11, and a capping layer 14 are sequentially stacked. In the structure as described above, the compound of Chemical Formula 1 and the compound of Chemical Formula 2 or 3 may be included in one or more layers of the first blue fluorescent light emitting layers 6BFa, the second blue fluorescent light emitting layer 6BFb, and the third blue fluorescent light emitting layer 6BFc.

The N-type charge generating layer may be 2,3,5,6-tetrafluoro-7,7,8,8-tetracyanoquinodimethane (F4TCNQ), fluorine-substituted 3,4,9,10-perylenetetracarboxylic dianhydride (PTCDA), cyano-substituted PTCDA, naphthalene tetracarboxylic dianhydride (NTCDA), fluorine-substituted NTCDA, cyano-substituted NTCDA, hexaazatriphenylene derivatives, and the like, but is not limited thereto. In an exemplary embodiment, the N-type charge generating layer may include both benzoimidazophenanthridine-based derivatives and Li metal.

The P-type charge generating layer may include both arylamine-based derivatives and a compound including a cyano group.

The organic light emitting device of the present specification may be manufactured by materials and methods known in the art, except that the organic material layer includes the compound.

When the organic light emitting device includes a plurality of organic material layers, the organic material layers may be formed of the same material or different materials. The organic light emitting device according to the present specification may be manufactured by depositing a metal or a metal oxide having conductivity, or an alloy thereof on a substrate to form a positive electrode, forming an organic material layer including the first organic material layer and the second organic material layer described above thereon, and then depositing a material, which may be used as a negative electrode, thereon. In addition to the method described above, an organic light emitting device may also be made by sequentially depositing a negative electrode material, an organic material layer, and a positive electrode material on a substrate.

The organic material layer including the first organic material layer and the second organic material layer may have a multi-layered structure further including a hole injection layer, a hole transport layer, an electron injection and transport layer, an electron blocking layer, a light emitting layer, an electron transport layer, an electron injection layer, an electron injection and transport layer, a hole blocking layer, and the like. Further, the organic material layer may be manufactured to include a fewer number of layers by a method such as a solvent process, for example, spin coating, dip coating, doctor blading, screen printing, inkjet printing, or a thermal transfer method instead of a deposition method, using various polymer materials.

The positive electrode is an electrode which injects holes, and as a positive electrode material, materials having a high work function are usually preferred so as to facilitate the injection of holes into an organic material layer. Specific examples of the positive electrode material which may be used in the present invention include: a metal, such as vanadium, chromium, copper, zinc, and gold, or an alloy thereof; a metal oxide, such as zinc oxide, indium oxide, indium tin oxide (ITO), and indium zinc oxide (IZO); a combination of a metal and an oxide, such as ZnO:Al or SnO₂:Sb; a conductive polymer, such as poly(3-methylthiophene), poly[3,4-(ethylene-1,2-dioxy)thiophene] (PEDOT), polypyrrole, and polyaniline; and the like, but are not limited thereto.

The negative electrode is an electrode which injects electrons, and as a negative electrode material, materials having a low work function are usually preferred so as to facilitate the injection of electrons into an organic material layer. Specific examples of the negative electrode material include: a metal such as magnesium, calcium, sodium, potassium, titanium, indium, yttrium, lithium, gadolinium, aluminum, silver, tin, and lead, or an alloy thereof; a multi-layer structured material, such as LiF/Al or LiO₂/Al; and the like, but are not limited thereto.

The hole injection layer is a layer serving to facilitate the injection of holes from the positive electrode to the light emitting layer, and has a single-layered or multi-layered structure of two or more layers. A hole injection material is a material which may proficiently receive holes from a positive electrode at low voltage, and the highest occupied molecular orbital (HOMO) of the hole injection material is preferably a value between the work function of the positive electrode material and the HOMO of the neighboring organic material layer. Specific examples of the hole injection material include metal porphyrin, oligothiophene, arylamine-based organic materials, hexanitrile hexaazatriphenylene-based organic materials, quinacridone-based organic materials, perylene-based organic materials, anthraquinone, polyaniline-based and polythiophene-based conductive polymers, and the like, but are not limited thereto. In an exemplary embodiment of the present specification, a hole injection layer has a structure of two layers, and each layer includes a material which is the same as or different from each other.

The hole transport layer may serve to facilitate the transportation of holes, and has a single-layered or multi-layered structure of two or more layers. A hole transport material is suitably a material having high hole mobility which may receive holes from a positive electrode or a hole injection layer and transfer the holes to a light emitting layer. Specific examples thereof include arylamine-based organic materials, conductive polymers, block copolymers having both conjugated portions and non-conjugated portions, and the like, but are not limited thereto. In an exemplary embodiment of the present specification, a hole transport layer has a structure of two layers, and each layer includes a material which is the same as or different from each other.

The hole injection and transport layer is a layer which simultaneously transports and injects holes, and a hole transport layer material and/or a hole injection layer material known in the art may be used.

The electron injection and transport layer is a layer which simultaneously transports and injects electrons, and an electron transport layer material and/or an electron injection layer material known in the art may be used.

An electron blocking layer may be provided between the hole transport layer and the light emitting layer. For the electron blocking layer, materials known in the art may be used.

The light emitting layer may emit red, green, or blue light, and may be composed of a phosphorescent material or a fluorescent material. The light emitting material is a material which may accept holes and electrons from a hole transport layer and an electron transport layer, respectively, and combine the holes and the electrons to emit light in a visible ray region, and is preferably a material having high quantum efficiency to fluorescence or phosphorescence. Specific examples thereof include: 8-hydroxy-quinoline aluminum complexes (Alq₃); carbazole-based compounds; dimerized styryl compounds; BAlq; 10-hydroxybenzoquinoline-metal compounds; benzoxazole-based, benzothiazole-based and benzimidazole-based compounds; poly(p-phenylenevinylene) (PPV)-based polymers; spiro compounds; polyfluorene, rubrene, and the like, but are not limited thereto.

Examples of the host material for the light emitting layer include condensed aromatic ring derivatives, or hetero ring-containing compounds, and the like. Specifically, examples of the condensed aromatic ring derivative include anthracene derivatives, pyrene derivatives, naphthalene derivatives, pentacene derivatives, phenanthrene compounds, fluoranthene compounds, and the like, and examples of the hetero ring-containing compound include carbazole derivatives, dibenzofuran derivatives, ladder-type furan compounds, pyrimidine derivatives, and the like, but the examples thereof are not limited thereto.

When the light emitting layer emits red light, it is possible to use a phosphorescent material such as bis(1-phenylisoquinoline)acetylacetonate iridium (PIQIr(acac)), bis(1-phenylquinoline)acetylacetonate iridium (PQIr(acac)), tris(1-phenylquinoline)iridium (PQIr), or octaethylporphyrin platinum (PtOEP), or a fluorescent material such as tris(8-hydroxyquinolino)aluminum (Alq₃) as a light emitting dopant, but the light emitting dopant is not limited thereto. When the light emitting layer emits green light, it is possible to use a phosphorescent material such as fac tris(2-phenylpyridine)iridium (Ir(ppy)₃), or a fluorescent material such as tris(8-hydroxyquinolino)aluminum (Alq₃), as the light emitting dopant, but the light emitting dopant is not limited thereto. When the light emitting layer emits blue light, it is possible to use a phosphorescent material such as (4,6-F₂ppy)₂Irpic, or a fluorescent material such as spiro-DPVBi, spiro-6P, distyryl benzene (DSB), distyryl arylene (DSA), a PFO-based polymer or a PPV-based polymer as the light emitting dopant, but the light emitting dopant is not limited thereto.

A hole blocking layer may be provided between the electron transport layer and the light emitting layer, and materials known in the art may be used.

The electron transport layer serves to facilitate the transport of electrons. An electron transport material is suitably a material having high electron mobility which may proficiently accept electrons from a negative electrode and transfer the electrons to a light emitting layer. Specific examples thereof include: Al complexes of 8-hydroxyquinoline; complexes including Alq₃; organic radical compounds; hydroxyflavone-metal complexes; and the like, but are not limited thereto.

The electron injection layer serves to facilitate the injection of electrons. An electron injection material is preferably a compound which has a capability of transporting electrons, an effect of injecting electrons from a negative electrode, and an excellent effect of injecting electrons into a light emitting layer or a light emitting material, and is also excellent in the ability to form a thin film. Specific examples thereof include fluorenone, anthraquinodimethane, diphenoquinone, thiopyran dioxide, oxazole, oxadiazole, triazole, imidazole, perylenetetracarboxylic acid, fluorenylidene methane, anthrone, and the like, and derivatives thereof, metal complex compounds, nitrogen-containing 5-membered ring derivatives, and the like, but are not limited thereto.

Examples of the metal complex compounds include 8-hydroxyquinolinato lithium, bis(8-hydroxyquinolinato) zinc, bis(8-hydroxyquinolinato) copper, bis(8-hydroxyquinolinato) manganese, tris(8-hydroxyquinolinato) aluminum, tris(2-methyl-8-hydroxyquinolinato) aluminum, tris(8-hydroxyquinolinato) gallium, bis(10-hydroxybenzo[h]quinolinato) beryllium, bis(10-hydroxybenzo[h]quinolinato) zinc, bis(2-methyl-8-quinolinato) chlorogallium, bis(2-methyl-8-quinolinato) (o-cresolato) gallium, bis(2-methyl-8-quinolinato) (1-naphtholato) aluminum, bis(2-methyl-8-quinolinato) (2-naphtholato) gallium, and the like, but are not limited thereto.

The organic light emitting device according to the present specification may be a top emission type, a bottom emission type, or a dual emission type according to the material to be used.

The organic light emitting device according to the present specification may be included and used in various electronic devices. For example, the electronic device may be a display panel, a touch panel, a solar module, a lighting device, and the like, and is not limited thereto.

### EXAMPLES

Hereinafter, the present specification will be described in detail with reference to Examples, Comparative Examples, and the like for specifically describing the present specification. However, the Examples and the Comparative Examples according to the present specification may be modified in various forms, and it is not interpreted that the scope of the present specification is limited to the Examples and the Comparative Examples described below in detail. The Examples and the Comparative Examples of the present specification are provided to more completely explain the present specification to a person with ordinary skill in the art.

### SYNTHESIS EXAMPLES

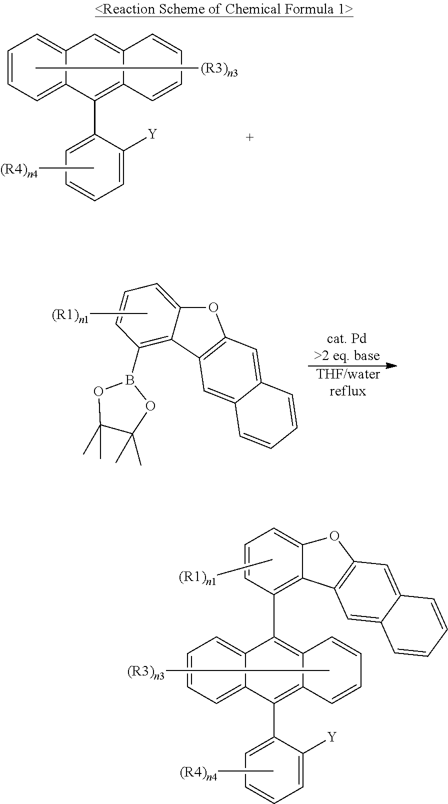

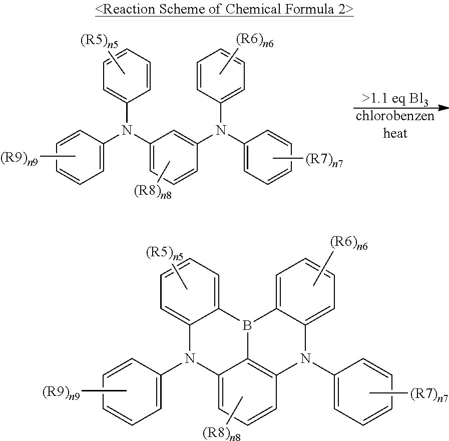

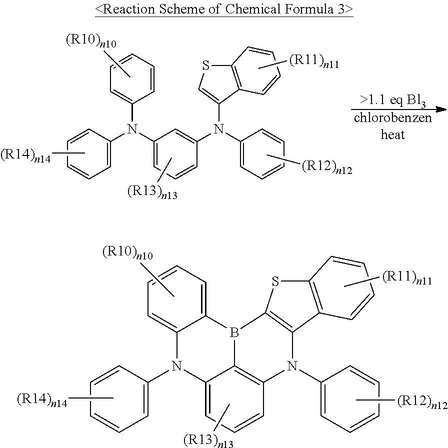

The compounds of Chemical Formulae 1 to 3 according to the present invention were synthesized by the reaction schemes or by partially modifying the reaction schemes.

### Synthesis Example 1: Preparation of Compound 1-1

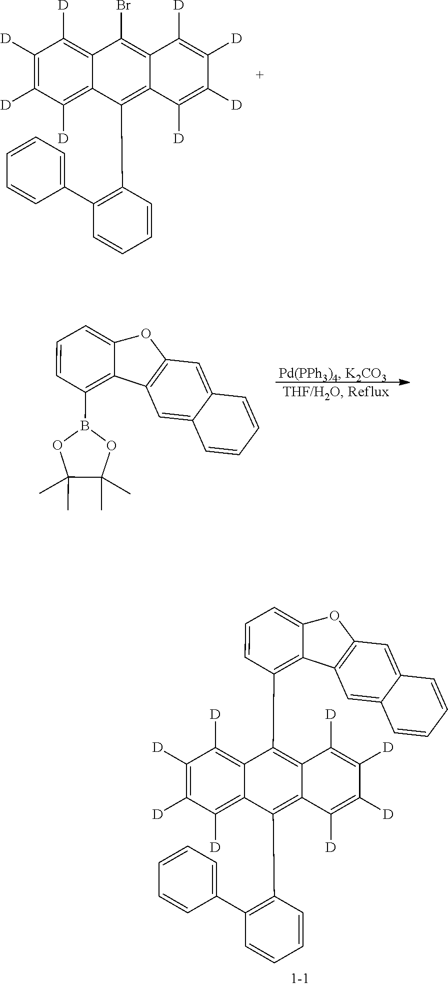 [SMILES: [2H]c1c([2H])c([2H])c2c(-c3ccccc3-c3ccccc3)c3c([2H])c([2H])c([2H])c([2H])c3c(Br)c2c1[2H] ; CC1(C)OB(c2cccc3oc4cc5ccccc5cc4c23)OC1(C)C ; [2H]c1c([2H])c([2H])c2c(-c3cccc4oc5cc6ccccc6cc5c34)c3c([2H])c([2H])c([2H])c([2H])c3c(-c3ccccc3-c3ccccc3)c2c1[2H]]

After Compound 9-([1,1′-biphenyl]-2-yl)-10-bromoanthracene-1,2,3,4,5,6,7,8-d8 (6.54 g, 15.67 mmol) and 4,4,5,5-tetramethyl-2-(naphtho[2,3-b]benzofuran-1-yl)-1,3,2-dioxaborolane (5.93 g, 17.23 mmol) were completely dissolved in 240 ml of tetrahydrofuran in a 500-ml round bottom flask under a nitrogen atmosphere, an aqueous 2 M potassium carbonate solution (120 ml) was added thereto, tetrakis-(triphenylphosphine)palladium (0.54 g, 0.47 mmol) was added thereto, and then the resulting mixture was heated and stirred for 4 hours. The temperature was lowered to room temperature, the aqueous layer was removed, and the residue was dried over anhydrous magnesium sulfate, and then concentrated under reduced pressure, and recrystallized with 320 ml of ethyl acetate to prepare Compound 1-1 (5.91 g, 68%).

MS [M+H]⁺=555

### Synthesis Example 2: Preparation of Compound 3-1

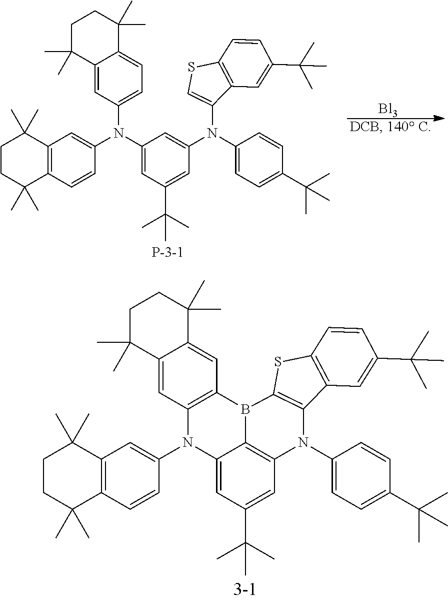 [SMILES: CC(C)(C)c1ccc(N(c2cc(N(c3ccc4c(c3)C(C)(C)CCC4(C)C)c3ccc4c(c3)C(C)(C)CCC4(C)C)cc(C(C)(C)C)c2)c2csc3ccc(C(C)(C)C)cc23)cc1 ; CC(C)(C)c1ccc(N2c3cc(C(C)(C)C)cc4c3B(c3cc5c(cc3N4c3ccc4c(c3)C(C)(C)CCC4(C)C)C(C)(C)CCC5(C)C)c3sc4ccc(C(C)(C)C)cc4c32)cc1]

After Compound P-3-1 (34.99 mmol, 30 g, and 1 eq.) was dissolved in 1,2-dichlorobenzene (0.1 M, 350 ml) in a three-neck flask and boron triiodide (56 mmol, 21.9 g, and 1.6 eq.) was added thereto, the resulting mixture was stirred while being heated under an argon atmosphere at 140° C. for 3 hours. The reaction product was cooled to 0° C., N,N-diisopropylethylamine (315 mmol, 40.7 g, and 9 eq.) was added thereto, and then the resulting mixture was stirred for 1 hour. Extraction was performed in a separatory funnel using toluene and H₂O. The extract was dried over MgSO₄ and concentrated, and the sample was purified by silica gel column chromatography, and then subjected to sublimation purification to obtain 6 g of Compound 3-1. (Yield 20%, MS [M+H]+=865)

Compounds 1-1 to 1-13, 2-1 to 2-3, and 3-1 to 3-4 were synthesized based on the synthesis method and known synthesis methods.

### Experimental Example 1: Measurement of Maximum Light Emission Wavelength

The maximum light emission wavelengths of Compound 1-12 of Chemical Formula 1 of the present invention and the following Compounds BH-5 to BH-7 in which Y is not bonded or has a different bonding position in Chemical Formula 1 in a film state were measured.

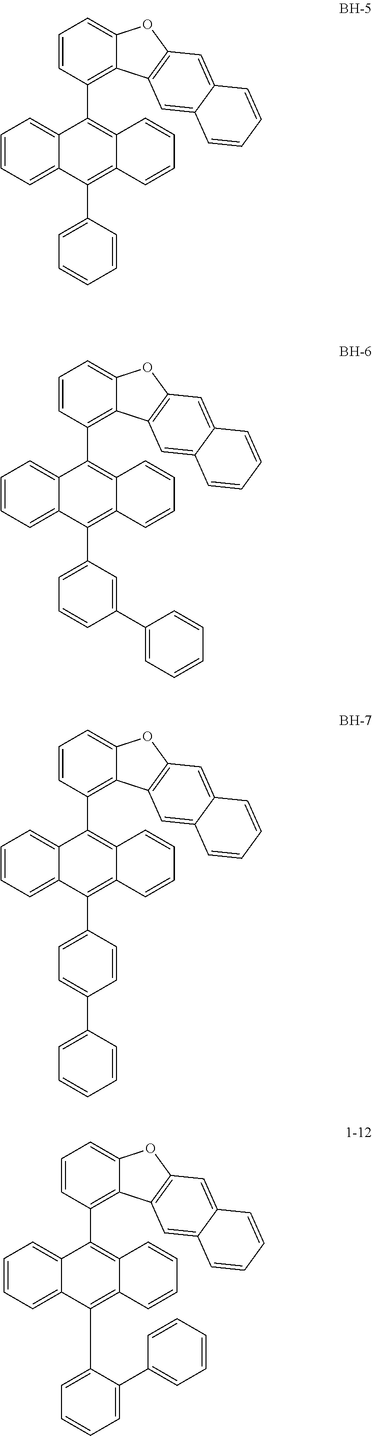

Specifically, the maximum light emission wavelengths and maximum absorption wavelengths of the compounds in a film state were obtained as follows. A light emitting layer film having a thickness of 1,000 Å was manufactured by vacuum depositing a host compound onto a glass substrate. In the aforementioned procedure, the deposition rate of the organic material was maintained at 0.1 nm/sec. The manufactured film was measured at room temperature (300K) using the following measuring apparatus, and then the results are described as in the following Table 1.

The maximum light emission wavelength of the compound was obtained using a JASCO FP-8600 fluorescence spectrometer, and the maximum absorption wavelength was obtained by measuring the transmittance of the compound using a JASCO V-770 UV/visible spectrometer.

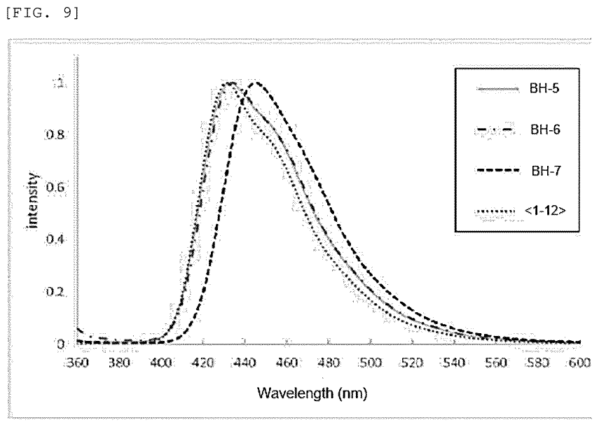

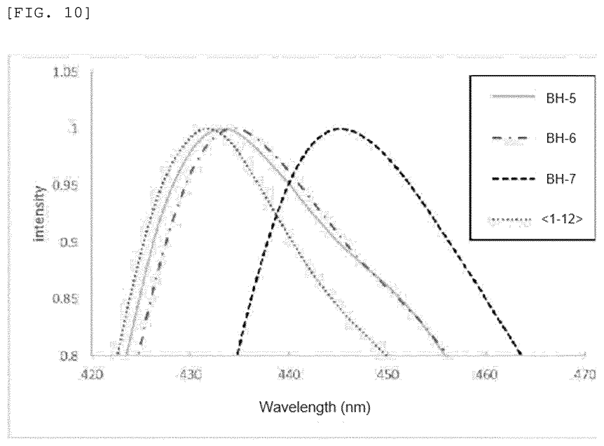

In this case, the wavelength value (nm) of the maximum light emission peak may be obtained, and the light emission graph is illustrated in FIG. 9. FIG. 10 is a graph in which the maximum light emission peak portion of FIG. 9 is enlarged.

TABLE 1

| | Film state | | |
|---|---|---|---|
| | UV-vis | Maximum light emission | Stoke |
| Compound | Abs. (nm) | wavelength (nm) | shift |
| BH-5 | 403 | 433 | 30 |
| BH-6 | 403 | 435 | 32 |
| BH-7 | 402 | 445 | 43 |
| 1-12 | 404 | 432 | 28 |

Referring to Table 1, it can be confirmed that Compounds BH-5 to BH-7 and Compound 1-12 have very similar functional groups that make up their molecules, and thus, the absorption wavelengths are very similar. However, it can be seen that when a film is manufactured using the compound of Chemical Formula 1 according to the present invention, the distance between the materials is longer, and thus, the Stoke shift is smaller than when a film is manufactured using a material other than the compound of Chemical Formula 1. In particular, in the case of BH-5, the conjugation thereof is shorter than the other compounds because BH-5 has one less phenyl group than the other compounds, but it can be confirmed that the maximum light emission wavelength of BH-5 is 1 nm larger than that of Compound 1-12.

### Experimental Example 2: Device Example 1

### Comparative Example 1-1

A glass substrate thinly coated with indium tin oxide (ITO) to have a thickness of 1,000 Å was put into distilled water in which a detergent was dissolved, and ultrasonically washed. In this case, a product manufactured by the Fischer Co., was used as the detergent, and distilled water twice filtered using a filter manufactured by Millipore Co., was used as the distilled water. After the ITO was washed for 30 minutes, ultrasonic washing was repeated twice by using distilled water for 10 minutes. After the washing using distilled water was completed, ultrasonic washing was conducted by using isopropyl alcohol, acetone, and methanol solvents, and the resulting product was dried and then transported to a plasma washing machine. Furthermore, the substrate was cleaned by using oxygen plasma for 5 minutes, and then was transported to a vacuum deposition machine.

The following Compound [HI-1] and the following Compound [HI-2] were thermally vacuum deposited to have a thickness of 100 Å at a ratio of 98:2 (molar ratio) on the transparent ITO electrode thus prepared, thereby forming a hole injection layer.

The following Compound [HI-1] (1,150 Å) as a material which transports holes was vacuum deposited on the hole injection layer, thereby forming a hole transport layer.

Subsequently, the following Compound [EB-1] was vacuum deposited to have a film thickness of 50 Å on the hole transport layer, thereby forming an electron blocking layer.

Subsequently, the following Compounds [BH-1] and [BD-1] were vacuum deposited at a weight ratio of 40:1 to have a film thickness of 200 Å on the electron blocking layer, thereby forming a light emitting layer.

The following Compound [HB-1] was vacuum deposited to have a film thickness of 50 Å on the light emitting layer, thereby forming a hole blocking layer.

Subsequently, the following Compound [ET-1] and lithium quinolate (Liq) were vacuum deposited at a weight ratio of 1:1 on the hole blocking layer, thereby forming an electron transport and injection layer having a thickness of 300 Å.

Lithium fluoride (LiF) and aluminum were subsequently deposited to have a thickness of 12 Å and 2,000 Å, respectively, on the electron transport and injection layer, thereby forming a negative electrode.

In the aforementioned procedure, the deposition rate of the organic material was maintained at 0.4 to 0.7 Å/sec, the deposition rates of lithium fluoride and aluminum of the negative electrode were maintained at 0.3 Å/sec and at 2 Å/sec, respectively, and the degree of vacuum during the deposition was maintained at 2×10⁻⁷ to 5×10⁻⁶ torr, thereby manufacturing an organic light emitting device.

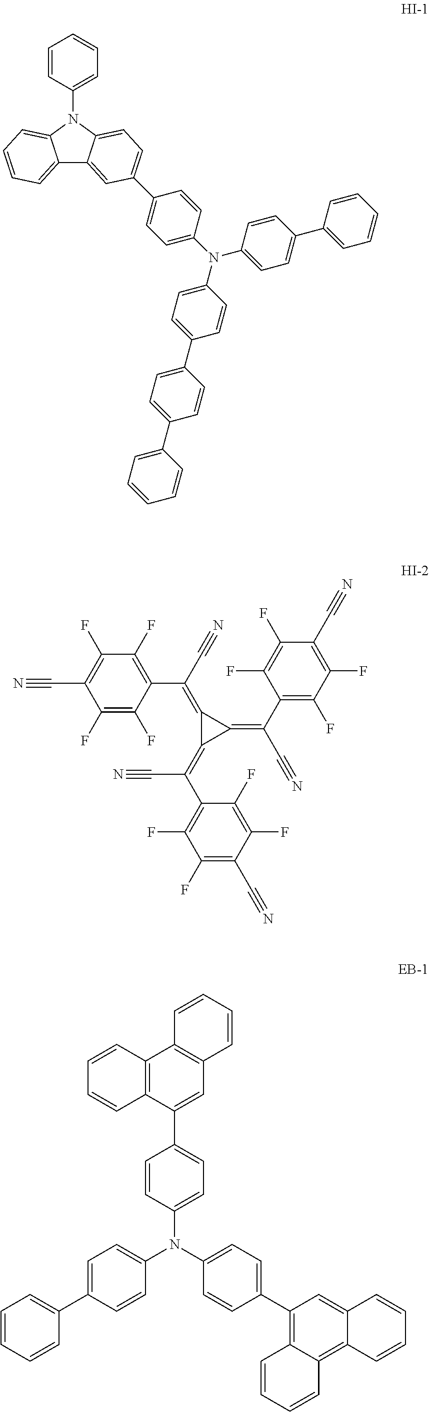 [SMILES: c1ccc(-c2ccc(-c3ccc(N(c4ccc(-c5ccccc5)cc4)c4ccc(-c5ccc6c(c5)c5ccccc5n6-c5ccccc5)cc4)cc3)cc2)cc1 ; N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; c1ccc(-c2ccc(N(c3ccc(-c4cc5ccccc5c5ccccc45)cc3)c3ccc(-c4cc5ccccc5c5ccccc45)cc3)cc2)cc1]

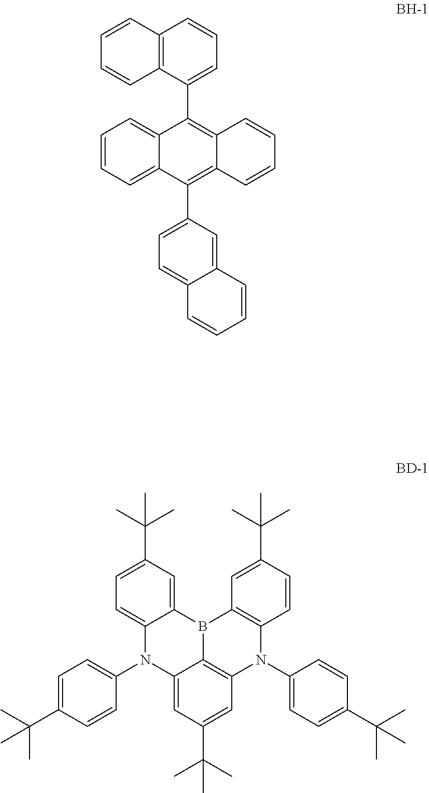

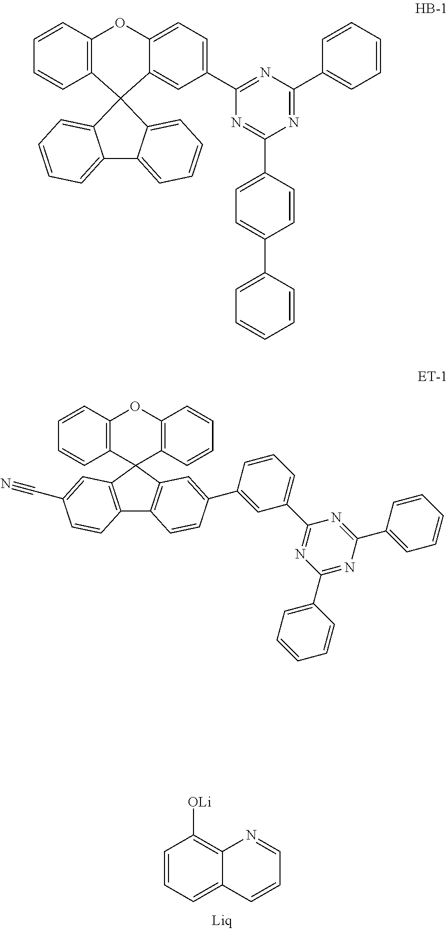

### Comparative Examples 1-2 to 1-14 and Comparative Examples 2-1 to 2-11

Organic light emitting devices were manufactured in the same manner as in Comparative Example 1-1, except that the compounds described in the following Tables 2 and 3 were used instead of [BH-1] and [BD-1] in Comparative Example 1-1.

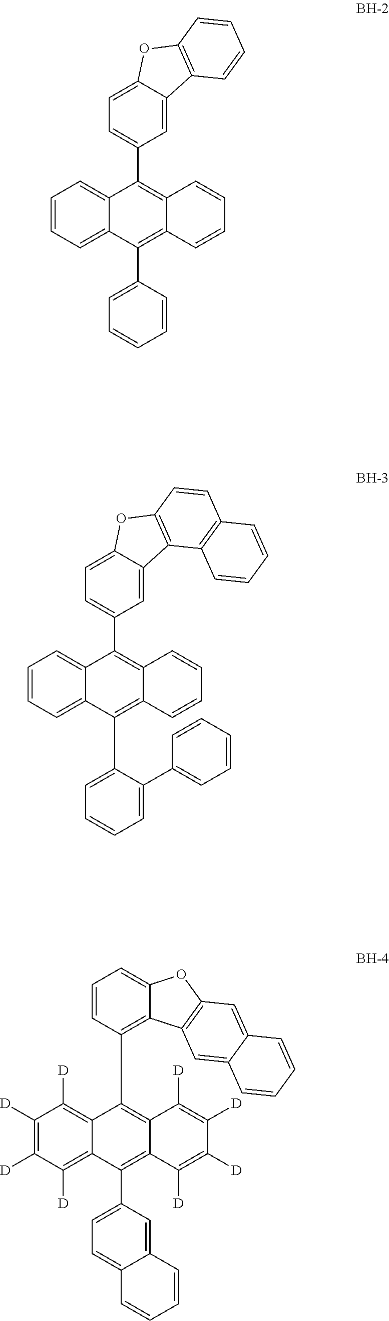 [SMILES: c1ccc(-c2c3ccccc3c(-c3ccc4oc5ccccc5c4c3)c3ccccc23)cc1 ; c1ccc(-c2ccccc2-c2c3ccccc3c(-c3ccc4oc5ccc6ccccc6c5c4c3)c3ccccc23)cc1 ; [2H]c1c([2H])c([2H])c2c(-c3cccc4oc5cc6ccccc6cc5c34)c3c([2H])c([2H])c([2H])c([2H])c3c(-c3ccc4ccccc4c3)c2c1[2H]]

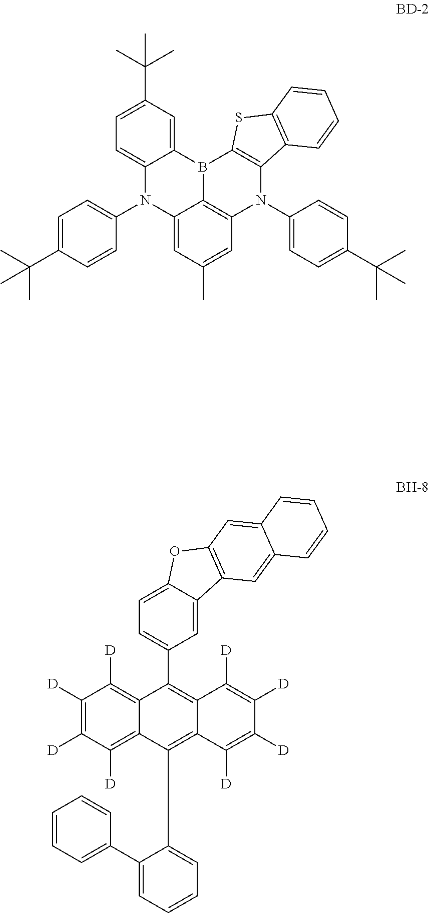 [SMILES: Cc1cc2c3c(c1)N(c1ccc(C(C)(C)C)cc1)c1c(sc4ccccc14)B3c1cc(C(C)(C)C)ccc1N2c1ccc(C(C)(C)C)cc1 ; [2H]c1c([2H])c([2H])c2c(-c3ccccc3-c3ccccc3)c3c([2H])c([2H])c([2H])c([2H])c3c(-c3ccc4oc5cc6ccccc6cc5c4c3)c2c1[2H]]

### Examples 1-1 to 1-7 and 2-1 to 2-9

Organic light emitting devices were manufactured in the same manner as in Comparative Example 1-1, except that the compounds described in the following Tables 2 and 3 were used instead of [BH-1] and [BD-1] in Comparative Example 1-1.

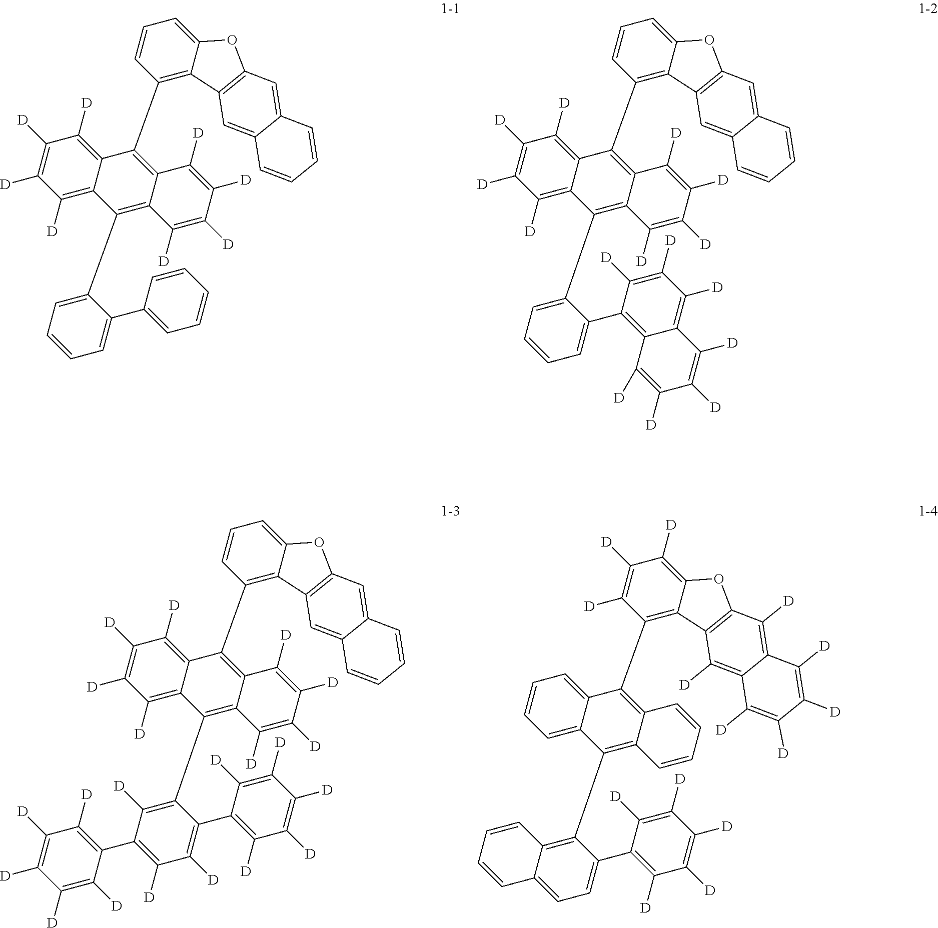

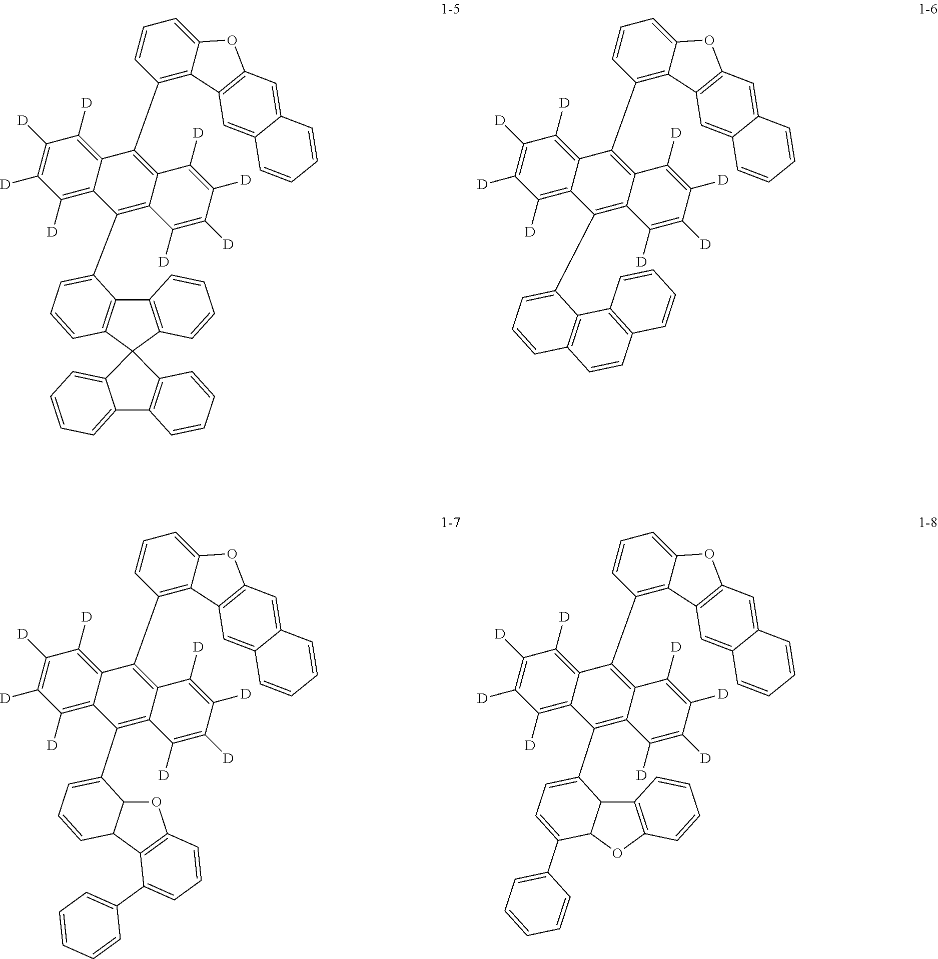

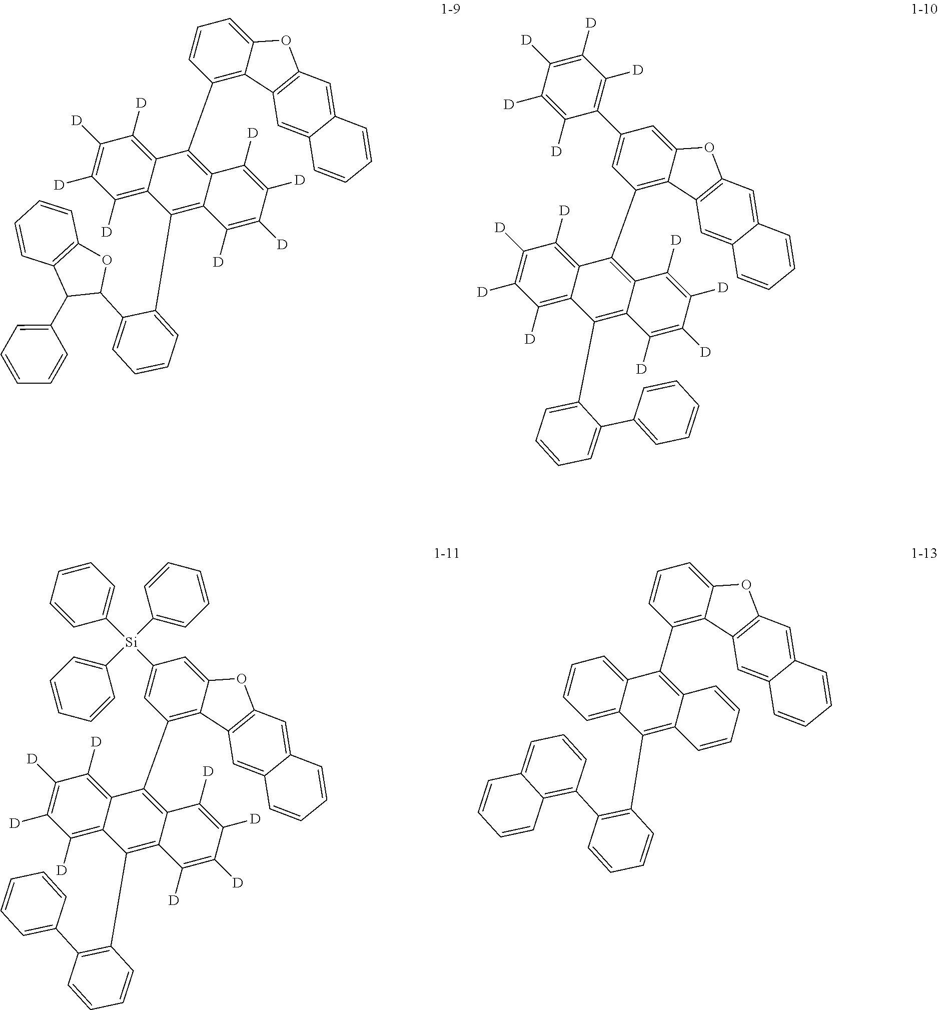

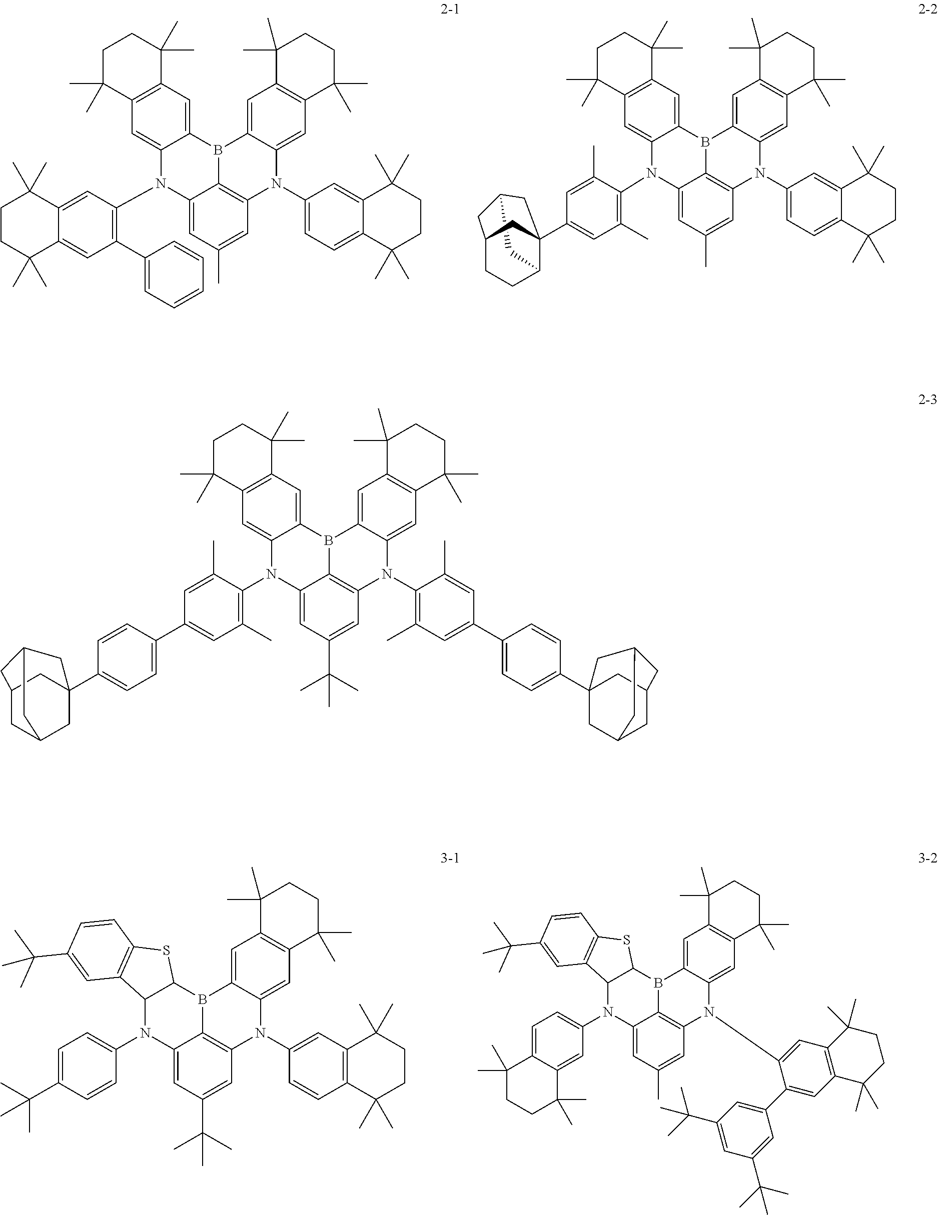

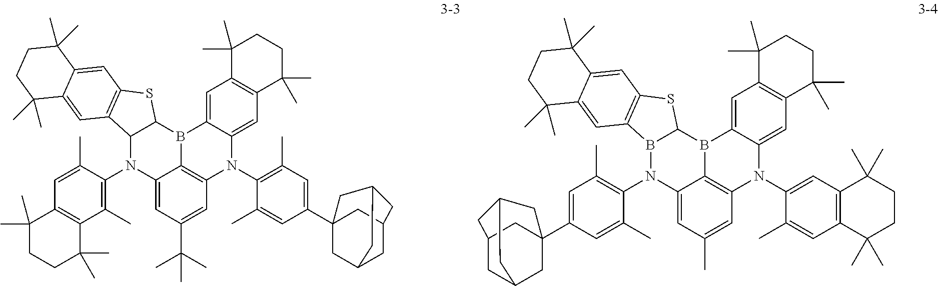 [SMILES: Cc1cc(C23CC4CC(CC(C4)C2)C3)cc(C)c1N1c2cc3c(cc2B2c4c1cc(C(C)(C)C)cc4N(c1c(C)cc4c(c1C)C(C)(C)CCC4(C)C)C1c4cc5c(cc4SC21)C(C)(C)CCC5(C)C)C(C)(C)CCC3(C)C ; Cc1cc2c3c(c1)N(c1cc4c(cc1C)C(C)(C)CCC4(C)C)c1cc4c(cc1B3C1Sc3cc5c(cc3B1N2c1c(C)cc(C23CC6CC(CC(C6)C2)C3)cc1C)C(C)(C)CCC5(C)C)C(C)(C)CCC4(C)C]

For the organic light emitting devices manufactured as described above, the driving voltage, the light emitting efficiency and the color coordinate were measured at a current density of 10 mA/cm², and a time (T95) for reaching a 95% value compared to the initial luminance was measured at a current density of 20 mA/cm². The results are shown in the following Tables 2 and 3.

TABLE 2

| | Light | | 10 mA/cm² | | 20 |
|---|---|---|---|---|---|
| | emitting | | Driving | Current | mA/cm² |
| | layer | | voltage | efficiency | T95 |
| entry | Host | Dopant | (V) | (cd/A) | (hr) |
| Comparative | BH-1 | BD-1 | 4.22 | 5.35 | 272 |
| Example 1-1 | | | | | |
| Comparative | BH-2 | BD-1 | 4.02 | 5.40 | 224 |
| Example 1-2 | | | | | |
| Comparative | BH-3 | BD-1 | 4.21 | 5.39 | 244 |
| Example 1-3 | | | | | |
| Comparative | BH-4 | BD-1 | 4.09 | 5.42 | 302 |
| Example 1-4 | | | | | |
| Comparative | BH-8 | BD-1 | 4.18 | 5.37 | 285 |
| Example 1-5 | | | | | |
| Comparative | 1-1 | BD-1 | 3.81 | 5.66 | 368 |
| Example 1-6 | | | | | |
| Comparative | 1-4 | BD-1 | 3.87 | 5.69 | 362 |
| Example 1-7 | | | | | |
| Comparative | 1-6 | BD-1 | 3.92 | 5.69 | 358 |
| Example 1-8 | | | | | |
| Comparative | 1-10 | BD-1 | 3.78 | 5.64 | 365 |
| Example 1-9 | | | | | |
| Comparative | 1-11 | BD-1 | 3.75 | 5.60 | 282 |
| Example 1-10 | | | | | |
| Comparative | 1-13 | BD-1 | 3.84 | 5.70 | 283 |
| Example 1-11 | | | | | |
| Comparative | BH-1 | 2-1 | 4.22 | 5.51 | 261 |
| Example 1-12 | | | | | |
| Comparative | BH-2 | 2-2 | 4.05 | 5.56 | 204 |
| Example 1-13 | | | | | |
| Comparative | BH-8 | 2-1 | 4.17 | 5.51 | 274 |
| Example 1-14 | | | | | |
| Example 1-1 | 1-1 | 2-2 | 3.80 | 6.06 | 390 |
| Example 1-2 | 1-3 | 2-2 | 3.82 | 6.17 | 453 |
| Example 1-3 | 1-4 | 2-3 | 3.86 | 6.34 | 372 |
| Example 1-4 | 1-6 | 2-1 | 3.92 | 6.11 | 383 |
| Example 1-5 | 1-7 | 2-2 | 3.71 | 5.94 | 379 |
| Example 1-6 | 1-10 | 2-3 | 3.82 | 6.40 | 393 |
| Example 1-7 | 1-11 | 2-1 | 3.75 | 5.86 | 316 |

TABLE 3

| | Light | | 10 mA/cm² | | 20 |
|---|---|---|---|---|---|
| | emitting | | Driving | Current | mA/cm² |
| | layer | | voltage | efficiency | T95 |
| entry | Host | Dopant | (V) | (cd/A) | (hr) |
| Comparative | BH-1 | BD-2 | 4.21 | 5.40 | 286 |
| Example 2-1 | | | | | |
| Comparative | BH-2 | BD-2 | 4.02 | 5.42 | 242 |
| Example 2-2 | | | | | |
| Comparative | BH-3 | BD-2 | 4.20 | 5.40 | 259 |
| Example 2-3 | | | | | |
| Comparative | BH-4 | BD-2 | 4.10 | 5.44 | 323 |
| Example 2-4 | | | | | |
| Comparative | 1-1 | BD-2 | 3.82 | 5.69 | 379 |
| Example 2-5 | | | | | |
| Comparative | 1-2 | BD-2 | 3.85 | 5.72 | 383 |
| Example 2-6 | | | | | |
| Comparative | 1-6 | BD-2 | 3.90 | 5.80 | 369 |
| Example 2-7 | | | | | |
| Comparative | 1-8 | BD-2 | 3.78 | 5.58 | 360 |
| Example 2-8 | | | | | |
| Comparative | 1-9 | BD-2 | 3.76 | 5.52 | 341 |
| Example 2-9 | | | | | |
| Comparative | BH-3 | 3-1 | 4.21 | 5.52 | 241 |
| Example 2-10 | | | | | |
| Comparative | BH-4 | 3-2 | 4.12 | 5.58 | 303 |
| Example 2-11 | | | | | |
| Example 2-1 | 1-3 | 3-1 | 3.85 | 6.03 | 451 |
| Example 2-2 | 1-5 | 3-2 | 3.79 | 6.32 | 387 |
| Example 2-3 | 1-6 | 3-2 | 3.89 | 6.54 | 390 |
| Example 2-4 | 1-8 | 3-4 | 3.78 | 6.09 | 383 |
| Example 2-5 | 1-9 | 3-1 | 3.77 | 5.92 | 390 |
| Example 2-6 | 1-9 | 3-3 | 3.76 | 6.17 | 383 |
| Example 2-7 | 1-10 | 3-4 | 3.80 | 6.37 | 402 |
| Example 2-8 | 1-11 | 3-2 | 3.74 | 5.97 | 375 |
| Example 2-9 | 1-13 | 3-3 | 3.89 | 6.20 | 312 |

In Tables 2 and 3, it can be confirmed that devices using the compound of Chemical Formula 1 according to the present invention and the compound of Chemical Formula 2 or 3 according to the present invention together have excellent performance in terms of lower voltage, higher efficiency and/or longer service life compared to devices using only the compound of Chemical Formula 1 and devices using only the compound of Chemical Formula 2 or 3.

Further, referring to Comparative Examples 1-1, 1-2, 1-5, 2-1 and 2-2 and Comparative Examples 1-12, 1-13, 1-14, 2-10 and 2-11, it can be confirmed that when the compound of Chemical Formula 2 or 3 was introduced, the efficiency was increased, but service life characteristics deteriorated to some extent. However, it can be confirmed that when the compound of Chemical Formula 2 was used together with the compound of Chemical Formula 1, the voltage, efficiency, and service life characteristics were all remarkably increased.

This is because a device using the compound of Chemical Formula 1 according to the present invention and the compound of Chemical Formula 2 or 3 according to the present invention together may have strengthened characteristics of low voltage, high efficiency and/or long service life of the device due to a synergistic effect in the organic light emitting device without deteriorating other properties.

This is considered to be because by using the compound of Chemical Formula 1 with a small Stoke shift together with the compounds of Chemical Formulae 2 and 3 including an aliphatic hydrocarbon ring as measured in Experimental Example 1, the effect of extending the distance between the compounds is further strengthened without any deterioration in other characteristics, and the average distance between a host and a dopant is effectively increased to reduce the Dexter transition between molecules.

Therefore, when the compound of Chemical Formula 1 of the present invention and the compound of Chemical Formula 2 or 3 of the present invention are used together, the characteristics of low voltage, high efficiency and/or long service life of the device may be remarkably improved.

### Experimental Example 3: Device Example 2

### Comparative Example 3-1

The following Compound [HI-1] and the following Compound [HI-2] were thermally vacuum deposited to have a thickness of 100 Å at a ratio of 98:2 on a transparent ITO electrode thus prepared in the same manner as in Comparative Example 1-1, thereby forming a hole injection layer.

The following Compound [HI-1] (300 Å) as a material which transports holes was vacuum deposited on the hole injection layer, thereby forming a hole transport layer.

Subsequently, the following Compound [EB-1] was vacuum deposited to have a film thickness of 50 Å on the hole transport layer, thereby forming an electron blocking layer.

Subsequently, the following BH-2 and BD-1 were vacuum deposited at a weight ratio of 98:2 to have a film thickness of 250 Å on the electron blocking layer, thereby forming a first light emitting layer.

Compound [HB-1] was vacuum deposited to have a film thickness of 50 Å on the first light emitting layer, thereby forming a hole blocking layer.

Subsequently, Compound [ET-2] and the following compound Liq were vacuum deposited at a weight ratio of 95:5 on the hole blocking layer to have a thickness of 150 Å, and subsequently, the compounds of the following Compounds [HI-1] and [HI-2] were deposited at a ratio of 90:10 (weight ratio) to have a thickness of 50 Å, thereby forming a charge generating layer.

The following Compound [HI-1] (400 Å) as a material which transports holes was vacuum deposited on the charge generating layer, thereby forming a hole transport layer.

Subsequently, the following Compound [EB-1] was vacuum deposited to have a film thickness of 50 Å on the hole transport layer, thereby forming an electron blocking layer.

Subsequently, [BH-2] and [BD-1] as described below were vacuum deposited at a weight ratio of 98:2 to have a film thickness of 250 Å on the electron blocking layer, thereby forming a second light emitting layer.

The following Compound [HB-1] was vacuum deposited to have a film thickness of 50 Å on the light emitting layer, thereby forming a hole blocking layer.

Subsequently, Compound [ET-1] and the compound Liq were vacuum deposited at a weight ratio of 1:1 on the hole blocking layer to have a thickness of 250 Å to form an electron transport layer, lithium fluoride (LiF) and Yb were sequentially deposited at a weight ratio of 1:1 to have a thickness of 30 Å, Ag and Mg were deposited at a weight ratio of 10:1 to have a thickness of 100 Å thereon, and Compound [HT-2] was deposited to have a thickness of 600 Å, thereby forming a negative electrode.

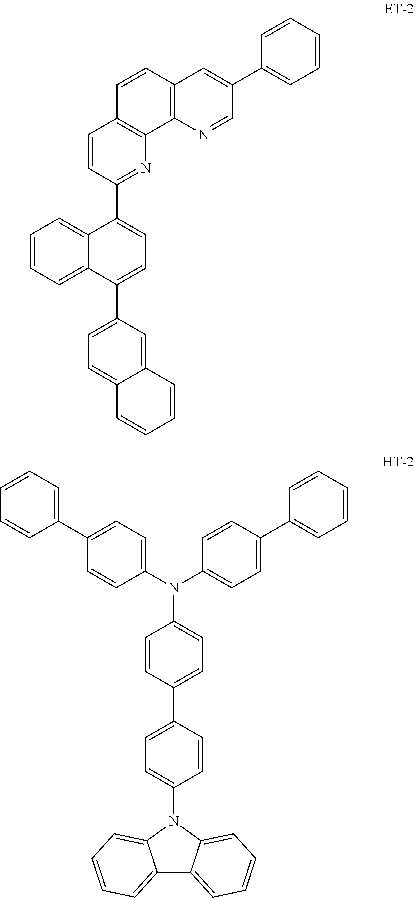 [SMILES: c1ccc(-c2cnc3c(ccc4ccc(-c5ccc(-c6ccc7ccccc7c6)c6ccccc56)nc43)c2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

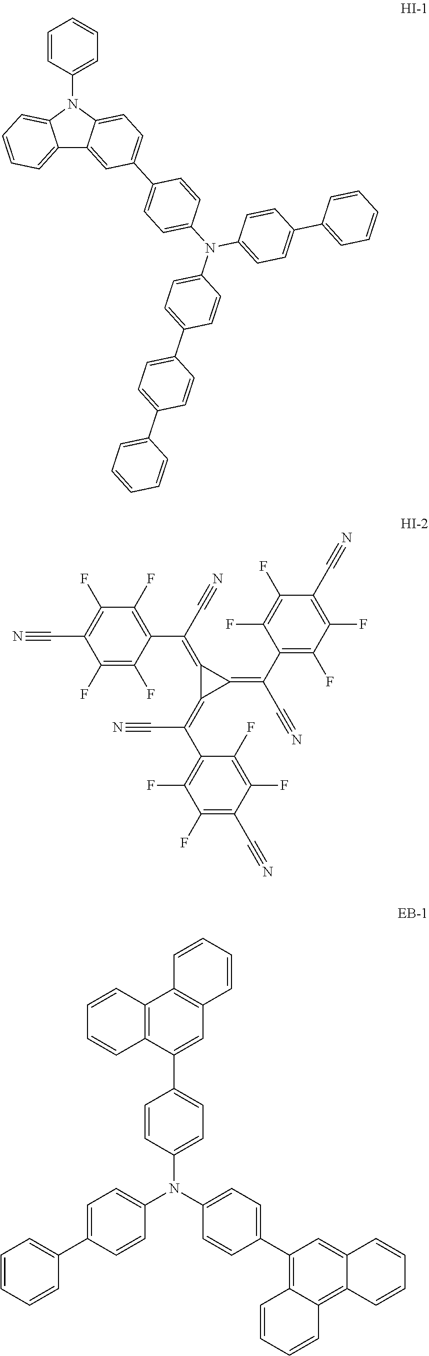 [SMILES: c1ccc(-c2ccc(-c3ccc(N(c4ccc(-c5ccccc5)cc4)c4ccc(-c5ccc6c(c5)c5ccccc5n6-c5ccccc5)cc4)cc3)cc2)cc1 ; N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; c1ccc(-c2ccc(N(c3ccc(-c4cc5ccccc5c5ccccc45)cc3)c3ccc(-c4cc5ccccc5c5ccccc45)cc3)cc2)cc1]

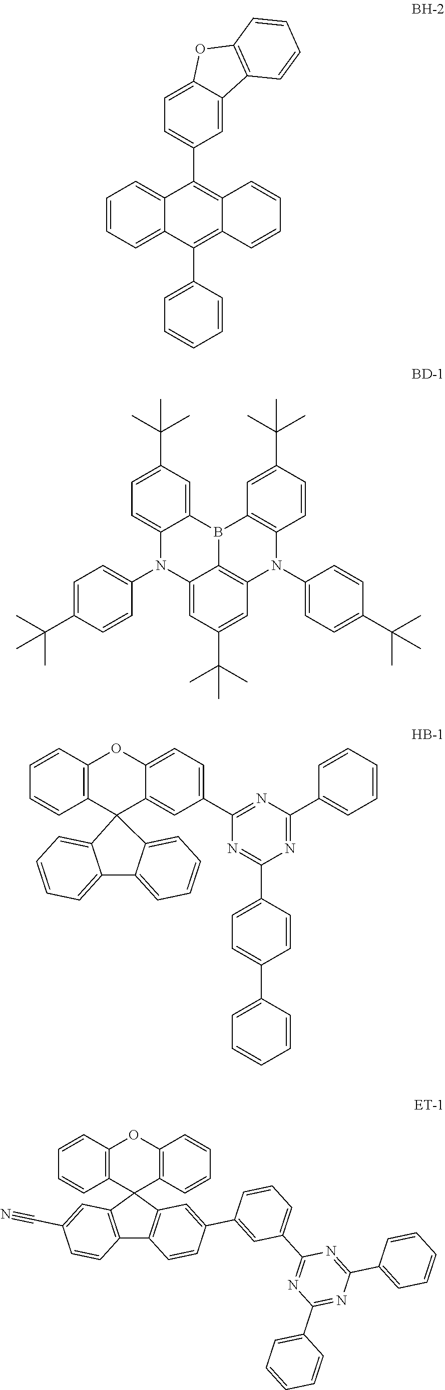 [SMILES: c1ccc(-c2c3ccccc3c(-c3ccc4oc5ccccc5c4c3)c3ccccc23)cc1 ; CC(C)(C)c1ccc(N2c3ccc(C(C)(C)C)cc3B3c4cc(C(C)(C)C)ccc4N(c4ccc(C(C)(C)C)cc4)c4cc(C(C)(C)C)cc2c43)cc1 ; c1ccc(-c2ccc(-c3nc(-c4ccccc4)nc(-c4ccc5c(c4)C4(c6ccccc6O5)c5ccccc5-c5ccccc54)n3)cc2)cc1 ; N#Cc1ccc2c(c1)C1(c3ccccc3Oc3ccccc31)c1cc(-c3cccc(-c4nc(-c5ccccc5)nc(-c5ccccc5)n4)c3)ccc1-2]

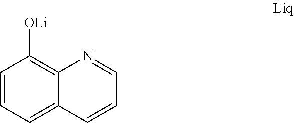

In the aforementioned procedure, the deposition rate of the organic material was maintained at 0.4 to 0.7 Å/sec, the deposition rate of lithium fluoride of the negative electrode and the deposition rates of Yb, Mg, and Ag of the negative electrode were maintained at 0.3 Å/sec and at 2 Å/sec, respectively, and the degree of vacuum during the deposition was maintained at 2×10⁻⁷ to 5×10⁻⁶ torr, thereby manufacturing an organic light emitting device.

### Comparative Examples 3-2 to 3-5 and 4-1 and 4-2

Organic light emitting devices were manufactured in the same manner as in Comparative Example 3-1, except that the compounds described in the following Tables 4 and 5 were used instead of [BH-2] and [BD-1] of the first light emitting layer and the second light emitting layer in Comparative Example 3-1.

### Examples 3-1 to 3-4 and 4-1 and 4-2

Organic light emitting devices were manufactured in the same manner as in Comparative Example 3-1, except that the compounds described in the following Tables 4 and 5 were used instead of [BH-2] and [BD-1] of the first light emitting layer and the second light emitting layer in Comparative Example 3-1.

For the organic light emitting devices manufactured as described above, the driving voltage, the light emitting efficiency and the color coordinate were measured at a current density of 10 mA/cm², and a relative value (LT95 ratio) based on Comparative Example 3-1 was calculated by measuring a time for reaching a 95% value compared to the initial luminance at a current density of 20 mA/cm², and is shown in Tables 4 and 5.

TABLE 4

| | 42: First light | | 32: Second light | | 10 mA/cm² | | 20 mA/cm² |
|---|---|---|---|---|---|---|---|
| | emitting layer | | emitting layer | | Driving | Efficiency | LT95 |
| Entry | Host | Dopant | Host | Dopant | voltage (V) | (cd/A/y) | ratio |
| Comparative | BH-2 | BD-1 | BH-2 | BD-1 | 7.21 | 251.30 | 1.00 |
| Example 3-1 | | | | | | | |
| Comparative | BH-1 | BD-1 | BH-2 | BD-1 | 7.54 | 258.84 | 0.83 |
| Example 3-2 | | | | | | | |
| Comparative | 1-1 | BD-1 | BH-2 | BD-1 | 7.08 | 252.56 | 1.06 |
| Example 3-3 | | | | | | | |
| Comparative | BH-2 | BD-1 | 1-1 | BD-1 | 7.13 | 250.80 | 1.08 |
| Example 3-4 | | | | | | | |
| Comparative | 1-10 | BD-1 | BH-3 | BD-1 | 7.16 | 256.33 | 1.10 |
| Example 3-5 | | | | | | | |
| Example 3-1 | 1-1 | 2-2 | BH-2 | BD-1 | 7.07 | 263.87 | 1.05 |
| Example 3-2 | BH-2 | BD-1 | 1-1 | 2-3 | 7.15 | 270.86 | 1.09 |
| Example 3-3 | 1-10 | 2-3 | BH-1 | 2-3 | 7.13 | 269.14 | 0.98 |
| Example 3-4 | BH-3 | BD-1 | 1-4 | 2-2 | 7.20 | 274.93 | 1.04 |

TABLE 5

| | 42: First light | | 32: Second light | | 10 mA/cm² | | 20 mA/cm² |
|---|---|---|---|---|---|---|---|
| | emitting layer | | emitting layer | | Driving | Efficiency | LT95 |
| entry | Host | Dopant | Host | Dopant | voltage (V) | (cd/A/y) | ratio |
| Comparative | BH-3 | BD-2 | 1-2 | BD-2 | 7.19 | 250.18 | 1.26 |
| Example 4-1 | | | | | | | |
| Comparative | 1-10 | BD-1 | BH-4 | BD-2 | 7.08 | 252.69 | 1.16 |
| Example 4-2 | | | | | | | |
| Example 4-1 | 1-10 | 3-3 | 1-4 | 2-1 | 7.11 | 291.51 | 1.21 |
| Example 4-2 | 1-1 | 3-1 | 1-6 | 3-2 | 7.14 | 281.46 | 1.34 |

In Tables 4 and 5, it can be confirmed that devices using the compound of Chemical Formula 1 according to the present invention and the compound of Chemical Formula 2 or 3 according to the present invention in the first light emitting layer or the second light emitting layer have excellent performance in terms of lower voltage, higher efficiency and/or longer service life compared to devices using only the compound of Chemical Formula 1 and devices using only the compound of Chemical Formula 2 or 3, and among them, particularly, the efficiency of the device can be remarkably improved.

### EXPLANATION OF REFERENCE NUMERALS AND SYMBOLS

1: Substrate/2: Positive electrode/3: Hole injection layer/4: Hole transport layer/4a: First hole transport layer/4b: Second hole transport layer/4c: Third hole transport layer/4d: Fourth hole transport layer/4e: Fifth hole transport layer/4f: Sixth hole transport layer/4p: p-doped hole transport layer/4R: Red hole transport layer/4G: Green hole transport layer/4B: Blue hole transport layer/5: Electron blocking layer/6: Light emitting layer/6a: First light emitting layer/6b: Second light emitting layer/6c: Third light emitting layer/6BF: Blue fluorescent light emitting layer/6BFa: First blue fluorescent light emitting layer/6BFb: Second blue fluorescent light emitting layer/6YGP: Yellow green phosphorescent light emitting layer/6RP: Red phosphorescent light emitting layer/6GP: Green phosphorescent light emitting layer/7: Hole blocking layer/8: Electron injection and transport layer/9: Electron transport layer/9a: First electron transport layer/9b: Second electron transport layer/9c: Third electron transport layer/10: Electron injection layer/11: Negative electrode/12: N-type charge generating layer/12a: First N-type charge generating layer/12b: Second N-type charge generating layer/13: P-type charge generating layer/13a: First P-type charge generating layer/13b: Second P-type charge generating layer/14: Capping layer

1. An organic light emitting device comprising:
an anode;
a cathode; and
a light emitting layer between the anode and the cathode,
wherein the light emitting layer comprises a compound of the following Chemical Formula 1 and a compound of the following Chemical Formula 2 or the following Chemical Formula 3: 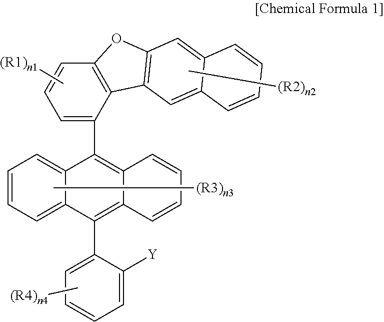
wherein in Chemical Formula 1:
Y is a substituted or unsubstituted aryl group, or a substituted or unsubstituted heteroaryl group, or is bonded to an adjacent substituent to form a substituted or unsubstituted ring;
R1 and R2 are the same as or different from each other, and are each independently hydrogen, deuterium, a substituted or unsubstituted alkyl group, a substituted or unsubstituted silyl group, a substituted or unsubstituted aryl group, or a substituted or unsubstituted heteroaryl group;
R3 is hydrogen or deuterium;
R4 is hydrogen, deuterium, a substituted or unsubstituted alkyl group, a substituted or unsubstituted silyl group, a substituted or unsubstituted aryl group, or a substituted or unsubstituted heteroaryl group, or is bonded to an adjacent substituent to form a substituted or unsubstituted ring;
n1 is an integer from 0 to 3;
n2 is an integer from 0 to 6;
n3 is an integer from 0 to 8;
n4 is an integer from 0 to 4; and
when n1 to n4 are each 2 or higher, two or more of R1 to R4 are each the same as or different from each other; 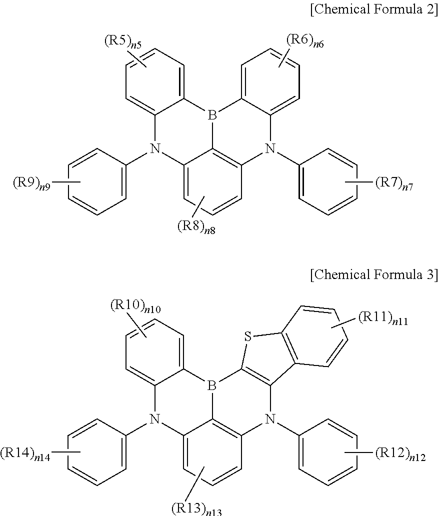
wherein in Chemical Formulae 2 and 3:
R5 to R14 are the same as or different from each other, and are each independently hydrogen, deuterium, a halogen group, a cyano group, a substituted or unsubstituted alkyl group, a substituted or unsubstituted cycloalkyl group, a substituted or unsubstituted silyl group, a substituted or unsubstituted alkenyl group, a substituted or unsubstituted aryl group, a substituted or unsubstituted heterocyclic group, a substituted or unsubstituted alkoxy group, a substituted or unsubstituted aryloxy group, a substituted or unsubstituted alkylthio group, a substituted or unsubstituted arylthio group, or a substituted or unsubstituted amine group, or are bonded to an adjacent substituent to form a substituted or unsubstituted ring;
Chemical Formulae 2 and 3 necessarily include the following Ring A or Ring B;
n5, n6, n10 and n11 are each an integer from 0 to 4;
n8 and n13 are each an integer from 0 to 3;
n7, n9, n12 and n14 are each an integer from 0 to 5; and
when n5 to n14 are each 2 or higher, two or more of R5 to R14 are each the same as or different from each other; 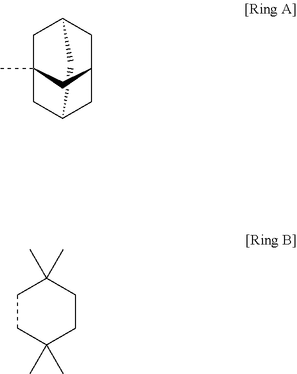
wherein in Rings A and B, the dotted line (---) is a site linked to or condensed to Chemical Formula 2 or 3, and an additional substituent is linked to or an additional ring is condensed to Ring A or B.

2. The organic light emitting device of claim 1, wherein the 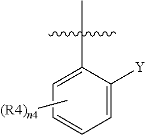
moiety of Chemical Formula 1 is represented by the following Formula Y-1 or Y-2: 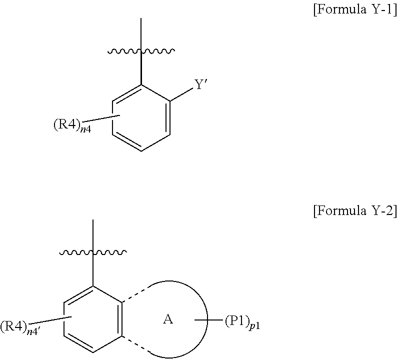
wherein in Formula Y-1 or Y-2:
R4 and n4 are the same as the definitions in Chemical Formula 1;
Y′ is a substituted or unsubstituted aryl group or a substituted or unsubstituted heteroaryl group;
A is an aromatic hydrocarbon ring or an aromatic hetero ring;
P1 is deuterium or a substituted or unsubstituted aryl group;
n4′ is 0 to 3, and when n4′ is 2 or higher, two or more R4s are the same as or different from each other;
p1 is 0 to 6, and when p1 is 2 or higher, two or more P1s are the same as or different from each other, and 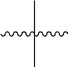
means a position linked to Chemical Formula 1.

3. The organic light emitting device of claim 1, wherein Y is a substituted or unsubstituted aryl group having 6 to 30 carbon atoms.

4. The organic light emitting device of claim 1, wherein Chemical Formula 1 comprises at least one or more deuterium(s).

5. The organic light emitting device of claim 1, wherein Chemical Formula 2 or Chemical Formula 3 comprises at least one of a structure of the following Formula D-1 or a structure of the following Formula D-2: 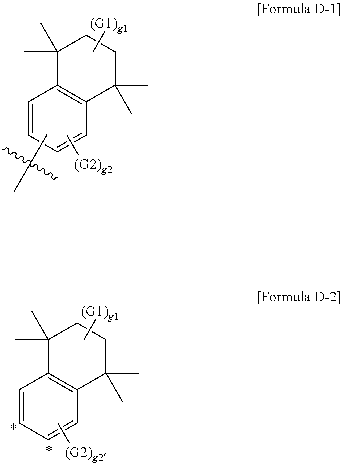
wherein in Formulae D-1 and D-2:
G1 and G2 are the same as or different from each other, and are each independently hydrogen, deuterium, a halogen group, a cyano group, a substituted or unsubstituted alkyl group, a substituted or unsubstituted cycloalkyl group, a substituted or unsubstituted silyl group, a substituted or unsubstituted alkenyl group, a substituted or unsubstituted aryl group, a substituted or unsubstituted heterocyclic group, a substituted or unsubstituted alkoxy group, a substituted or unsubstituted aryloxy group, a substituted or unsubstituted alkylthio group, a substituted or unsubstituted arylthio group, or a substituted or unsubstituted amine group, or are bonded to an adjacent substituent to form a substituted or unsubstituted ring;
g1 is an integer from 0 to 4, and when g1 is 2 or higher, two or more G1s are the same as or different from each other;
g2 is an integer from 0 to 3, and when g2 is 2 or higher, two or more G2s are the same as or different from each other;
g2′ is an integer from 0 to 2, and when g2′ is 2, two G2′s are the same as or different from each other;
the 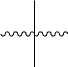
means a position linked to Chemical Formula 2 or 3; and
the * means a position condensed to Chemical Formula 2 or 3.

6. The organic light emitting device of claim 1, wherein at least one of R5, R6, R7 and R9 is bonded to an adjacent substituent to form a ring of the following Formula C: 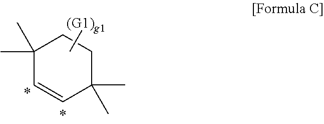
wherein in Formula C:
G1 is hydrogen, deuterium, a halogen group, a cyano group, a substituted or unsubstituted alkyl group, a substituted or unsubstituted cycloalkyl group, a substituted or unsubstituted silyl group, a substituted or unsubstituted alkenyl group, a substituted or unsubstituted aryl group, a substituted or unsubstituted heterocyclic group, a substituted or unsubstituted alkoxy group, a substituted or unsubstituted aryloxy group, a substituted or unsubstituted alkylthio group, a substituted or unsubstituted arylthio group, or a substituted or unsubstituted amine group, or are bonded to an adjacent substituent to form a substituted or unsubstituted ring, and g1 is an integer from 0 to 4, and when g1 is 2 or higher, two or more G1s are the same as or different from each other, and
the * means a position where Formula C is condensed.

7. The organic light emitting device of claim 1, wherein at least one of R10, R11, R12 and R14 is bonded to an adjacent substituent to form a ring of the following Formula C: 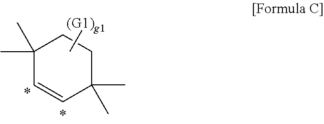
wherein in Formula C:
G1 is hydrogen, deuterium, a halogen group, a cyano group, a substituted or unsubstituted alkyl group, a substituted or unsubstituted cycloalkyl group, a substituted or unsubstituted silyl group, a substituted or unsubstituted alkenyl group, a substituted or unsubstituted aryl group, a substituted or unsubstituted heterocyclic group, a substituted or unsubstituted alkoxy group, a substituted or unsubstituted aryloxy group, a substituted or unsubstituted alkylthio group, a substituted or unsubstituted arylthio group, or a substituted or unsubstituted amine group, or are bonded to an adjacent substituent to form a substituted or unsubstituted ring; and
g1 is an integer from 0 to 4, and when g1 is 2 or higher, two or more G1s are the same as or different from each other, and
the * means a position where Formula C is condensed.

8. The organic light emitting device of claim 1, wherein at least one of R5 to R9 comprises an adamantyl group.

9. The organic light emitting device of claim 1, wherein at least one of R10 to R14 comprises an adamantyl group.

10. The organic light emitting device of claim 1, wherein Chemical Formula 2 is the following Chemical Formula 2-A or 2-B: 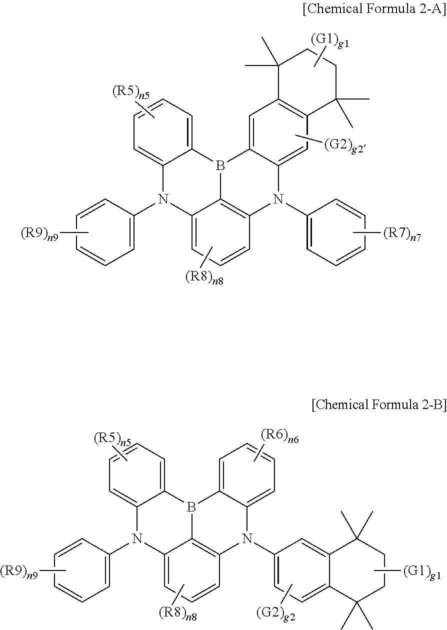
wherein in Chemical Formula 2-A or 2-B:
the definitions of R5 to R9 and n5 to n9 are the same as the definitions in Chemical Formula 2;
G1 and G2 are the same as or different from each other, and are each independently hydrogen, deuterium, a halogen group, a cyano group, a substituted or unsubstituted alkyl group, a substituted or unsubstituted cycloalkyl group, a substituted or unsubstituted silyl group, a substituted or unsubstituted alkenyl group, a substituted or unsubstituted aryl group, a substituted or unsubstituted heterocyclic group, a substituted or unsubstituted alkoxy group, a substituted or unsubstituted aryloxy group, a substituted or unsubstituted alkylthio group, a substituted or unsubstituted arylthio group, or a substituted or unsubstituted amine group, or are bonded to an adjacent substituent to form a substituted or unsubstituted ring;
g1 is an integer from 0 to 4, and when g1 is 2 or higher, two or more G1s are the same as or different from each other;
g2 is an integer from 0 to 3, and when g2 is 2 or higher, two or more G2s are the same as or different from each other; and
g2′ is an integer from 0 to 2, and when g2′ is 2, two G2s are the same as or different from each other.

11. The organic light emitting device of claim 1, wherein Chemical Formula 3 is the following Chemical Formula 3-A or 3-B: 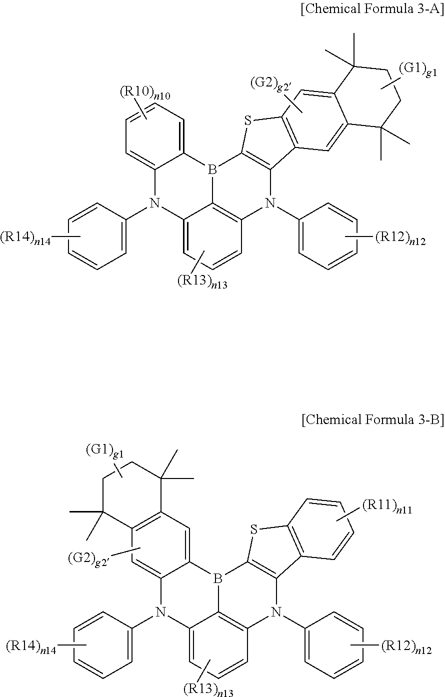
wherein in Chemical Formulae 3-A and 3-B:
the definitions of R10 to R14 and n10 to n14 are the same as the definitions in Chemical Formula 3;
G1 and G2 are the same as or different from each other, and are each independently hydrogen, deuterium, a halogen group, a cyano group, a substituted or unsubstituted alkyl group, a substituted or unsubstituted cycloalkyl group, a substituted or unsubstituted silyl group, a substituted or unsubstituted alkenyl group, a substituted or unsubstituted aryl group, a substituted or unsubstituted heterocyclic group, a substituted or unsubstituted alkoxy group, a substituted or unsubstituted aryloxy group, a substituted or unsubstituted alkylthio group, a substituted or unsubstituted arylthio group, or a substituted or unsubstituted amine group, or are bonded to an adjacent substituent to form a substituted or unsubstituted ring;
g1 is an integer from 0 to 4, and when g1 is 2 or higher, two or more G1s are the same as or different from each other; and
g2′ is an integer from 0 to 2, and when g2′ is 2, two G2s are the same as or different from each other.

12. The organic light emitting device of claim 1, wherein the light emitting layer comprises the compound of Chemical Formula 1 as a host.

13. The organic light emitting device of claim 1, wherein the light emitting layer comprises two or more of the compound of Chemical Formula 1 as a host.

14. The organic light emitting device of claim 1, wherein the light emitting layer comprises the compound of Chemical Formula 2 or Chemical Formula 3 as a dopant.

15. The organic light emitting device of claim 1, wherein the light emitting layer comprises two or more of the compound of Chemical Formula 2 or Chemical Formula 3 as a dopant.

16. The organic light emitting device of claim 1, wherein the compound of Chemical Formula 1 is any one of the following compounds:

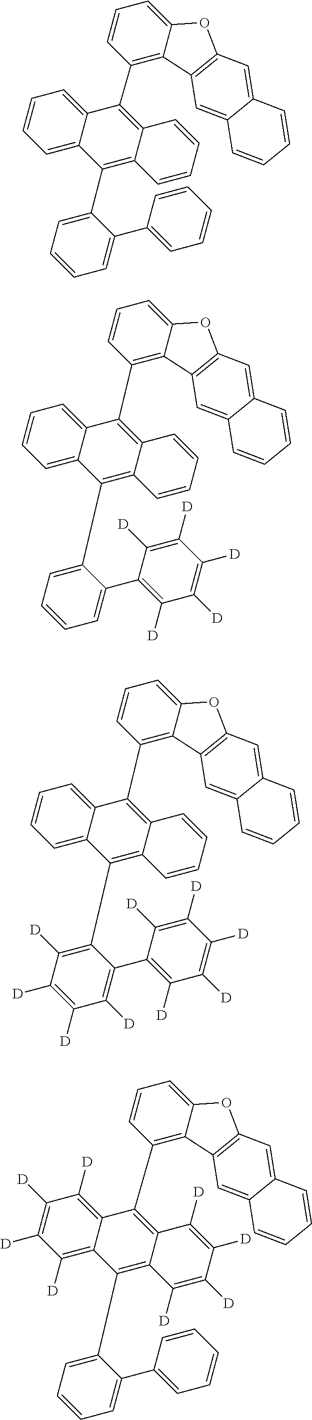

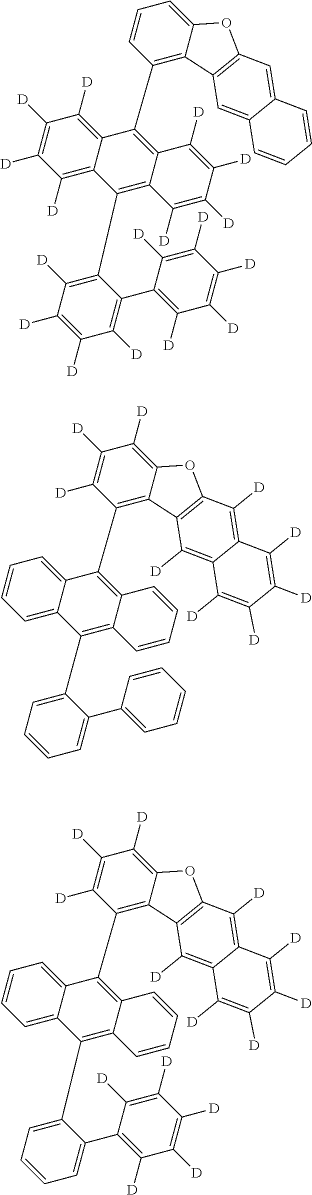 [SMILES: [2H]c1c([2H])c([2H])c(-c2c([2H])c([2H])c([2H])c([2H])c2-c2c3c([2H])c([2H])c([2H])c([2H])c3c(-c3cccc4oc5cc6ccccc6cc5c34)c3c([2H])c([2H])c([2H])c([2H])c23)c([2H])c1[2H] ; [2H]c1c([2H])c(-c2c3ccccc3c(-c3ccccc3-c3ccccc3)c3ccccc23)c2c(oc3c([2H])c4c([2H])c([2H])c([2H])c([2H])c4c([2H])c32)c1[2H] ; [2H]c1c([2H])c([2H])c(-c2ccccc2-c2c3ccccc3c(-c3c([2H])c([2H])c([2H])c4oc5c([2H])c6c([2H])c([2H])c([2H])c([2H])c6c([2H])c5c34)c3ccccc23)c([2H])c1[2H]]

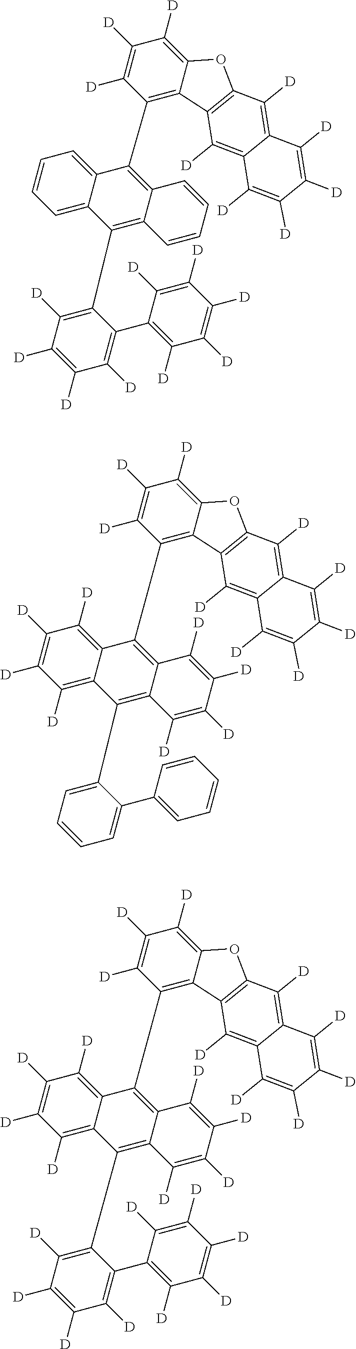

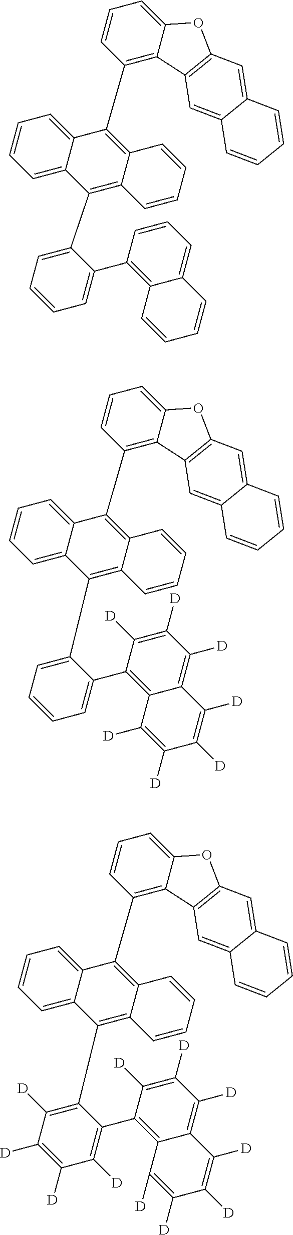 [SMILES: c1ccc(-c2c3ccccc3c(-c3cccc4oc5cc6ccccc6cc5c34)c3ccccc23)c(-c2cccc3ccccc23)c1 ; [2H]c1c([2H])c([2H])c2c(-c3ccccc3-c3c4ccccc4c(-c4cccc5oc6cc7ccccc7cc6c45)c4ccccc34)c([2H])c([2H])c([2H])c2c1[2H] ; [2H]c1c([2H])c([2H])c(-c2c([2H])c([2H])c([2H])c3c([2H])c([2H])c([2H])c([2H])c23)c(-c2c3ccccc3c(-c3cccc4oc5cc6ccccc6cc5c34)c3ccccc23)c1[2H]]

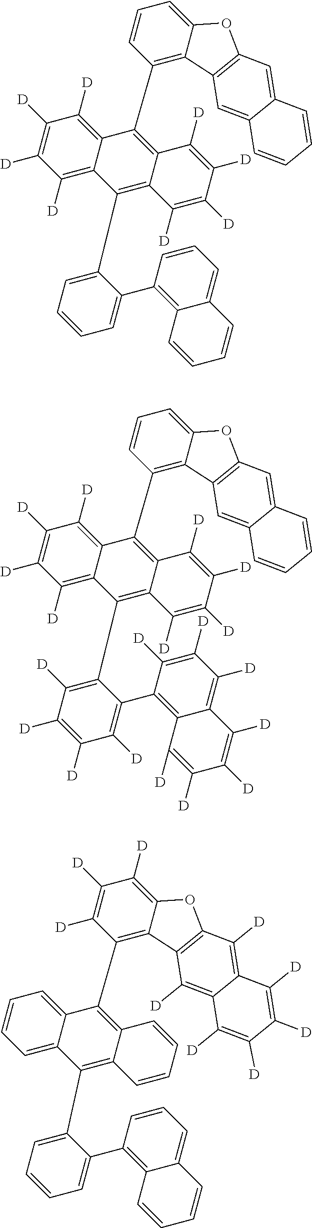 [SMILES: [2H]c1c([2H])c([2H])c2c(-c3cccc4oc5cc6ccccc6cc5c34)c3c([2H])c([2H])c([2H])c([2H])c3c(-c3ccccc3-c3cccc4ccccc34)c2c1[2H] ; [2H]c1c([2H])c([2H])c(-c2c3c([2H])c([2H])c([2H])c([2H])c3c(-c3cccc4oc5cc6ccccc6cc5c34)c3c([2H])c([2H])c([2H])c([2H])c23)c(-c2c([2H])c([2H])c([2H])c3c([2H])c([2H])c([2H])c([2H])c23)c1[2H] ; [2H]c1c([2H])c(-c2c3ccccc3c(-c3ccccc3-c3cccc4ccccc34)c3ccccc23)c2c(oc3c([2H])c4c([2H])c([2H])c([2H])c([2H])c4c([2H])c32)c1[2H]]

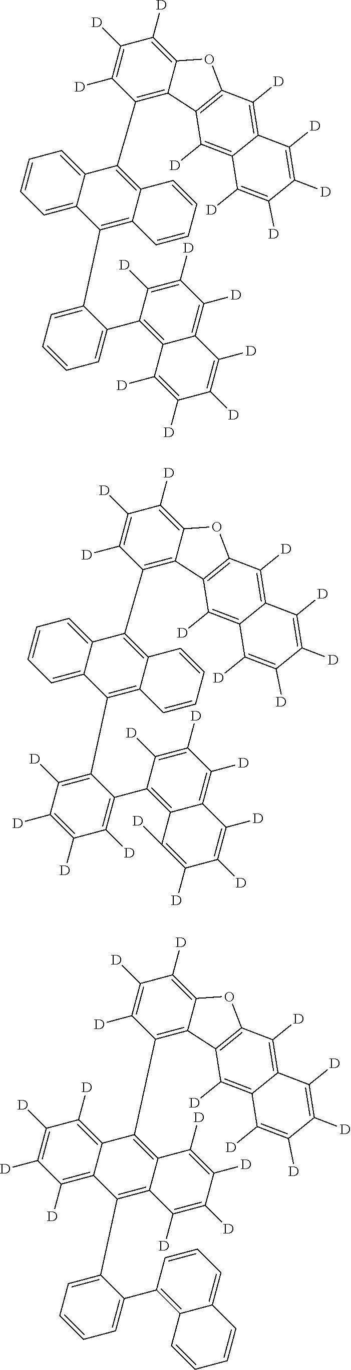

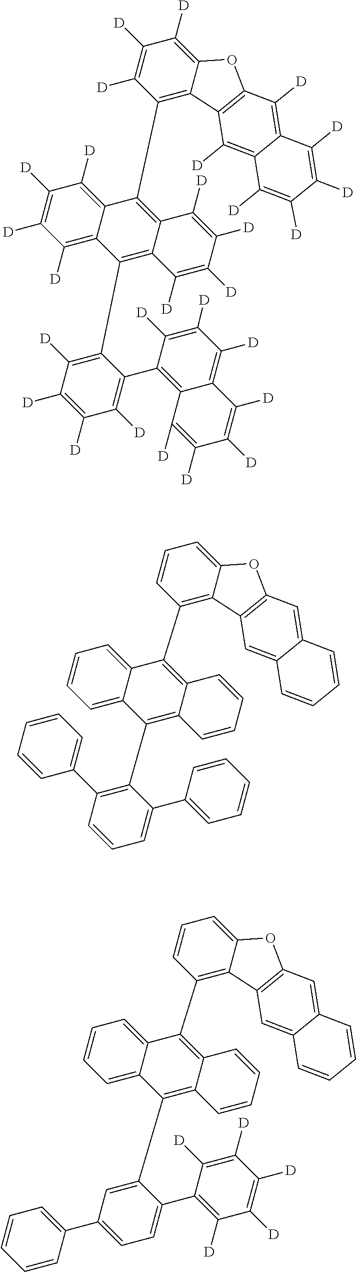 [SMILES: [2H]c1c([2H])c([2H])c(-c2c3c([2H])c([2H])c([2H])c([2H])c3c(-c3c([2H])c([2H])c([2H])c4oc5c([2H])c6c([2H])c([2H])c([2H])c([2H])c6c([2H])c5c34)c3c([2H])c([2H])c([2H])c([2H])c23)c(-c2c([2H])c([2H])c([2H])c3c([2H])c([2H])c([2H])c([2H])c23)c1[2H] ; c1ccc(-c2cccc(-c3ccccc3)c2-c2c3ccccc3c(-c3cccc4oc5cc6ccccc6cc5c34)c3ccccc23)cc1 ; [2H]c1c([2H])c([2H])c(-c2ccc(-c3ccccc3)cc2-c2c3ccccc3c(-c3cccc4oc5cc6ccccc6cc5c34)c3ccccc23)c([2H])c1[2H]]

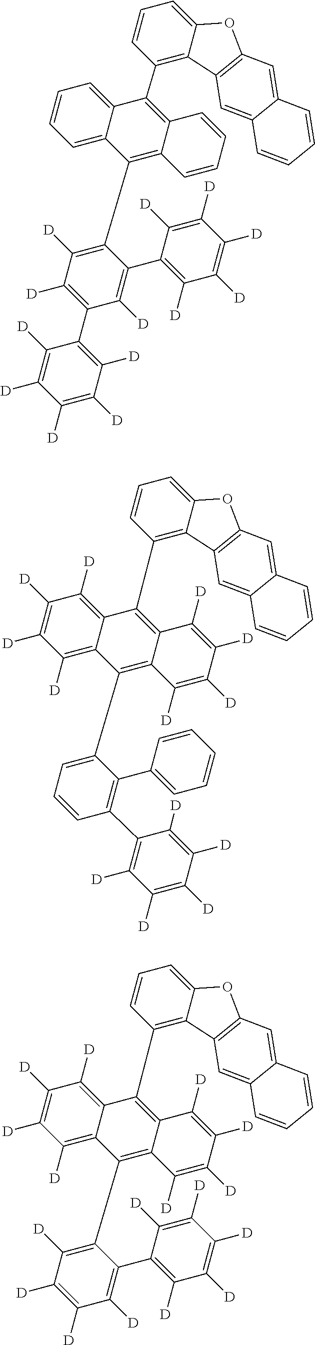 [SMILES: [2H]c1c([2H])c([2H])c(-c2c([2H])c([2H])c(-c3c4ccccc4c(-c4cccc5oc6cc7ccccc7cc6c45)c4ccccc34)c(-c3c([2H])c([2H])c([2H])c([2H])c3[2H])c2[2H])c([2H])c1[2H] ; [2H]c1c([2H])c([2H])c(-c2cccc(-c3c4c([2H])c([2H])c([2H])c([2H])c4c(-c4cccc5oc6cc7ccccc7cc6c45)c4c([2H])c([2H])c([2H])c([2H])c34)c2-c2ccccc2)c([2H])c1[2H] ; [2H]c1c([2H])c([2H])c(-c2c([2H])c([2H])c([2H])c([2H])c2-c2c3c([2H])c([2H])c([2H])c([2H])c3c(-c3cccc4oc5cc6ccccc6cc5c34)c3c([2H])c([2H])c([2H])c([2H])c23)c([2H])c1[2H]]

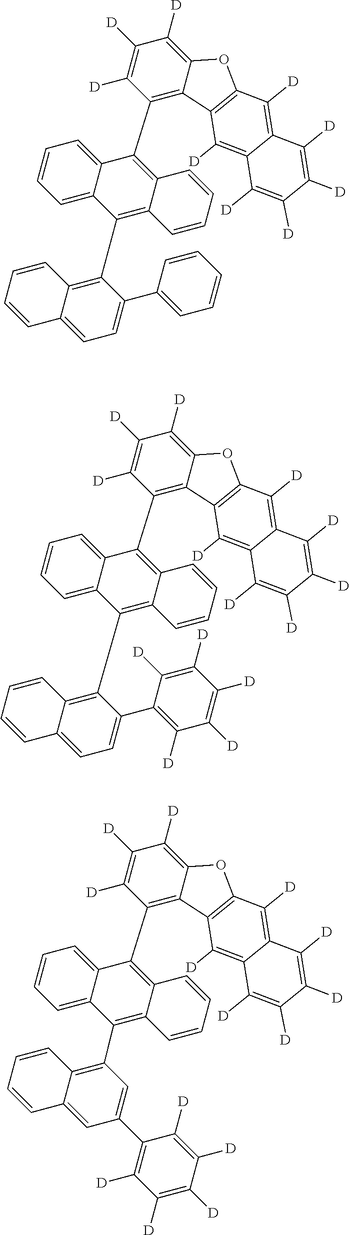 [SMILES: [2H]c1c([2H])c(-c2c3ccccc3c(-c3c(-c4ccccc4)ccc4ccccc34)c3ccccc23)c2c(oc3c([2H])c4c([2H])c([2H])c([2H])c([2H])c4c([2H])c32)c1[2H] ; [2H]c1c([2H])c([2H])c(-c2ccc3ccccc3c2-c2c3ccccc3c(-c3c([2H])c([2H])c([2H])c4oc5c([2H])c6c([2H])c([2H])c([2H])c([2H])c6c([2H])c5c34)c3ccccc23)c([2H])c1[2H] ; [2H]c1c([2H])c([2H])c(-c2cc(-c3c4ccccc4c(-c4c([2H])c([2H])c([2H])c5oc6c([2H])c7c([2H])c([2H])c([2H])c([2H])c7c([2H])c6c45)c4ccccc34)c3ccccc3c2)c([2H])c1[2H]]

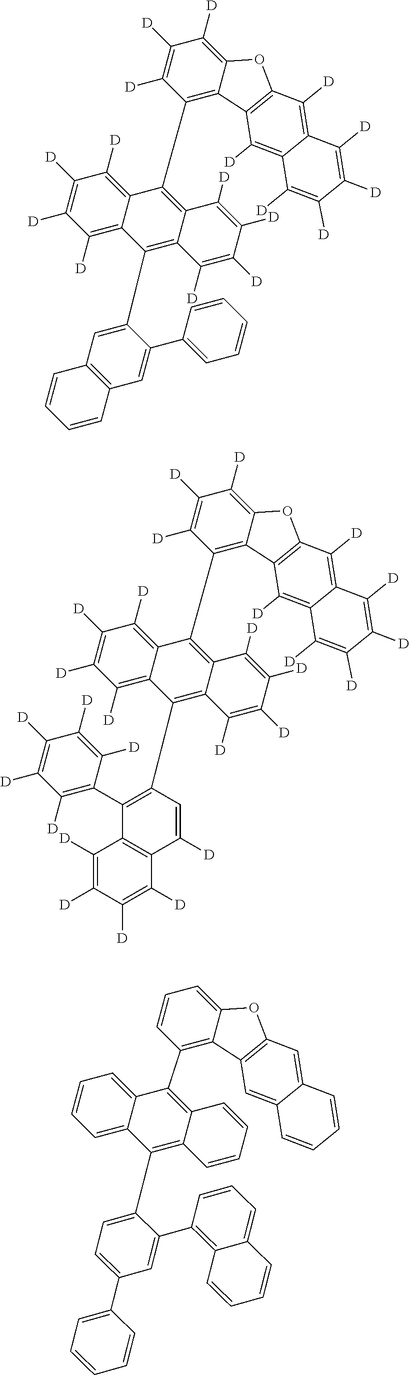

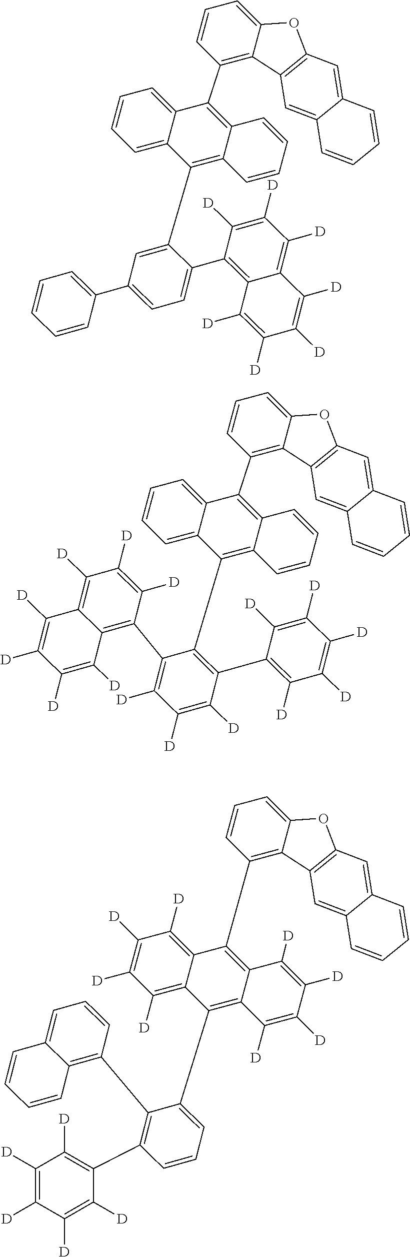

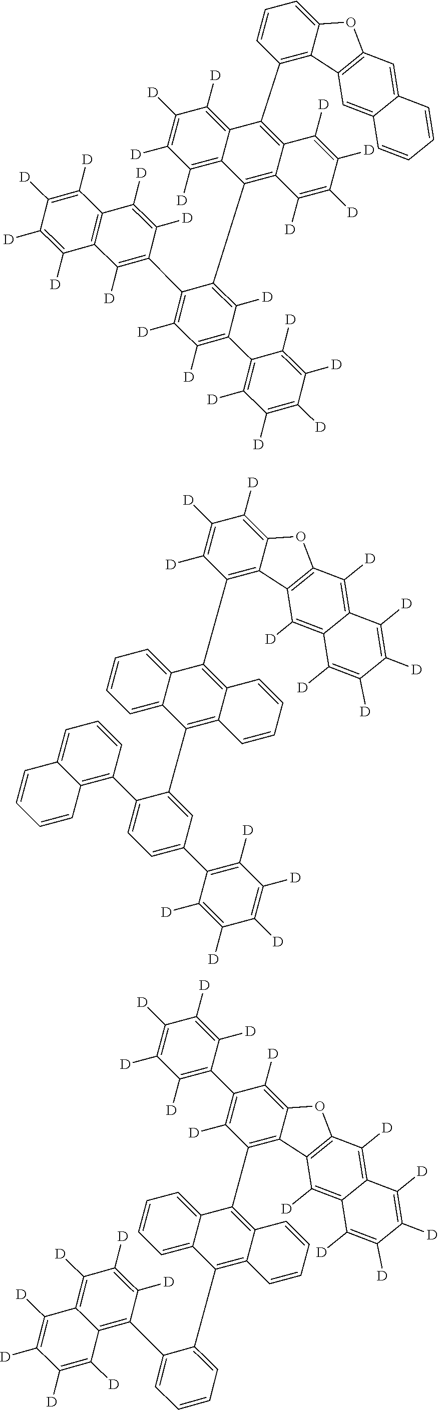

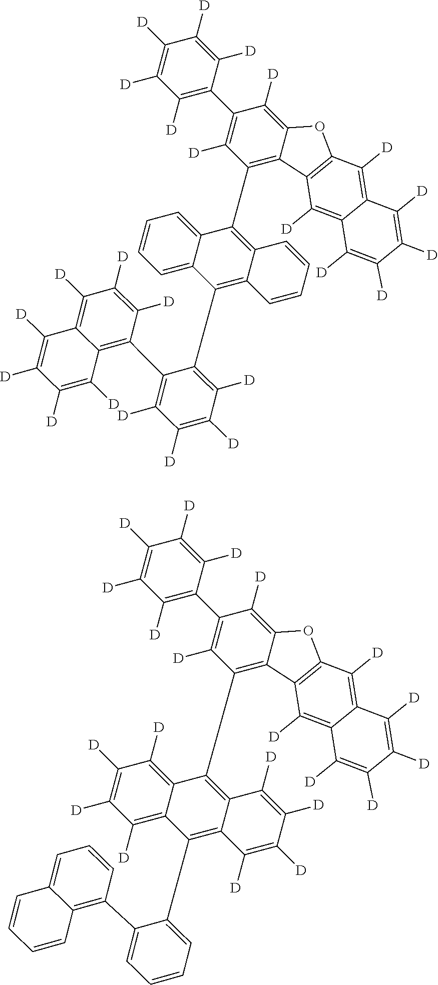 [SMILES: [2H]c1c([2H])c([2H])c(-c2c([2H])c(-c3c4ccccc4c(-c4c([2H])c([2H])c([2H])c([2H])c4-c4c([2H])c([2H])c([2H])c5c([2H])c([2H])c([2H])c([2H])c45)c4ccccc34)c3c(oc4c([2H])c5c([2H])c([2H])c([2H])c([2H])c5c([2H])c43)c2[2H])c([2H])c1[2H] ; [2H]c1c([2H])c([2H])c(-c2c([2H])c(-c3c4c([2H])c([2H])c([2H])c([2H])c4c(-c4ccccc4-c4cccc5ccccc45)c4c([2H])c([2H])c([2H])c([2H])c34)c3c(oc4c([2H])c5c([2H])c([2H])c([2H])c([2H])c5c([2H])c43)c2[2H])c([2H])c1[2H]]

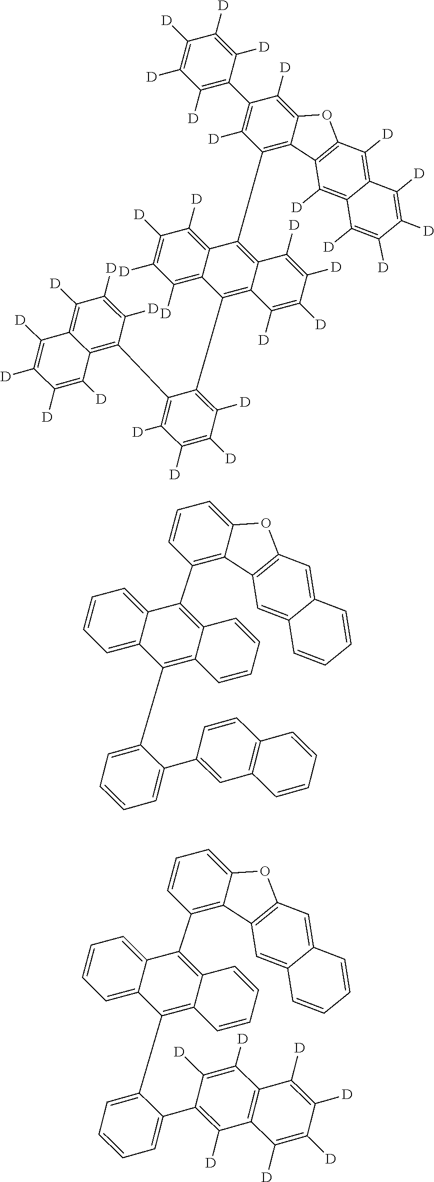

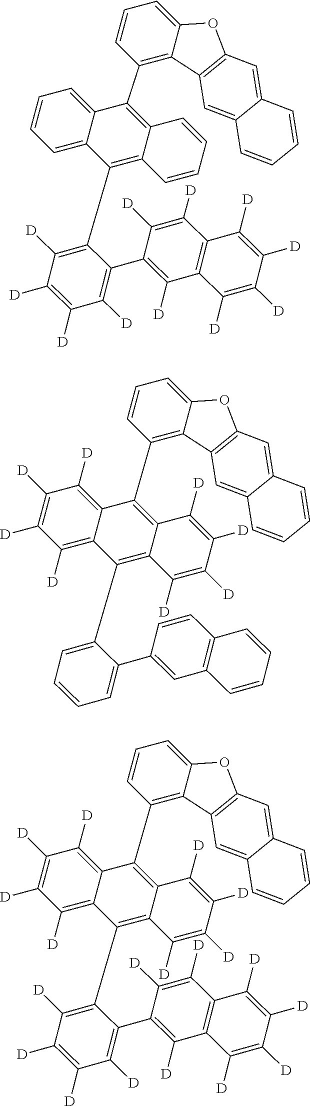 [SMILES: [2H]c1c([2H])c([2H])c(-c2c3ccccc3c(-c3cccc4oc5cc6ccccc6cc5c34)c3ccccc23)c(-c2c([2H])c([2H])c3c([2H])c([2H])c([2H])c([2H])c3c2[2H])c1[2H] ; [2H]c1c([2H])c([2H])c2c(-c3cccc4oc5cc6ccccc6cc5c34)c3c([2H])c([2H])c([2H])c([2H])c3c(-c3ccccc3-c3ccc4ccccc4c3)c2c1[2H] ; [2H]c1c([2H])c([2H])c(-c2c3c([2H])c([2H])c([2H])c([2H])c3c(-c3cccc4oc5cc6ccccc6cc5c34)c3c([2H])c([2H])c([2H])c([2H])c23)c(-c2c([2H])c([2H])c3c([2H])c([2H])c([2H])c([2H])c3c2[2H])c1[2H]]

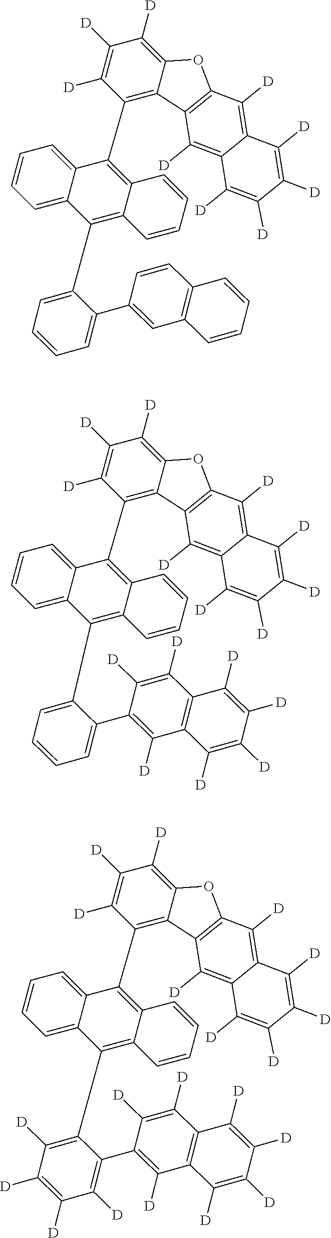 [SMILES: [2H]c1c([2H])c(-c2c3ccccc3c(-c3ccccc3-c3ccc4ccccc4c3)c3ccccc23)c2c(oc3c([2H])c4c([2H])c([2H])c([2H])c([2H])c4c([2H])c32)c1[2H] ; [2H]c1c([2H])c(-c2c3ccccc3c(-c3ccccc3-c3c([2H])c([2H])c4c([2H])c([2H])c([2H])c([2H])c4c3[2H])c3ccccc23)c2c(oc3c([2H])c4c([2H])c([2H])c([2H])c([2H])c4c([2H])c32)c1[2H] ; [2H]c1c([2H])c([2H])c(-c2c3ccccc3c(-c3c([2H])c([2H])c([2H])c4oc5c([2H])c6c([2H])c([2H])c([2H])c([2H])c6c([2H])c5c34)c3ccccc23)c(-c2c([2H])c([2H])c3c([2H])c([2H])c([2H])c([2H])c3c2[2H])c1[2H]]

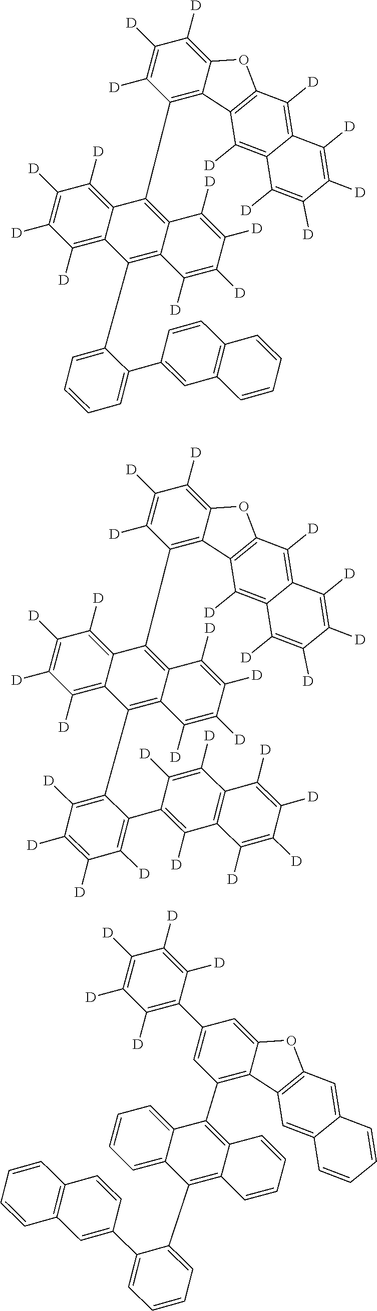

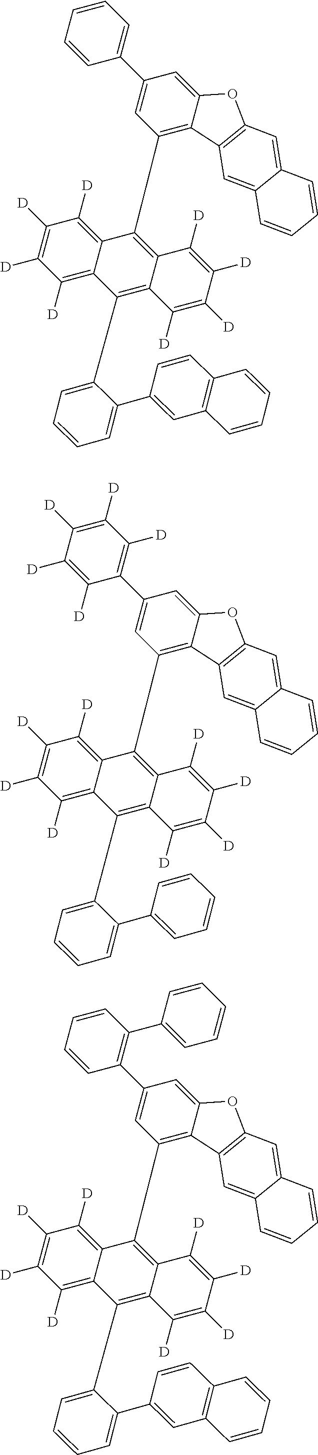 [SMILES: [2H]c1c([2H])c([2H])c2c(-c3cc(-c4ccccc4)cc4oc5cc6ccccc6cc5c34)c3c([2H])c([2H])c([2H])c([2H])c3c(-c3ccccc3-c3ccc4ccccc4c3)c2c1[2H] ; [2H]c1c([2H])c([2H])c(-c2cc(-c3c4c([2H])c([2H])c([2H])c([2H])c4c(-c4ccccc4-c4ccccc4)c4c([2H])c([2H])c([2H])c([2H])c34)c3c(c2)oc2cc4ccccc4cc23)c([2H])c1[2H] ; [2H]c1c([2H])c([2H])c2c(-c3cc(-c4ccccc4-c4ccccc4)cc4oc5cc6ccccc6cc5c34)c3c([2H])c([2H])c([2H])c([2H])c3c(-c3ccccc3-c3ccc4ccccc4c3)c2c1[2H]]

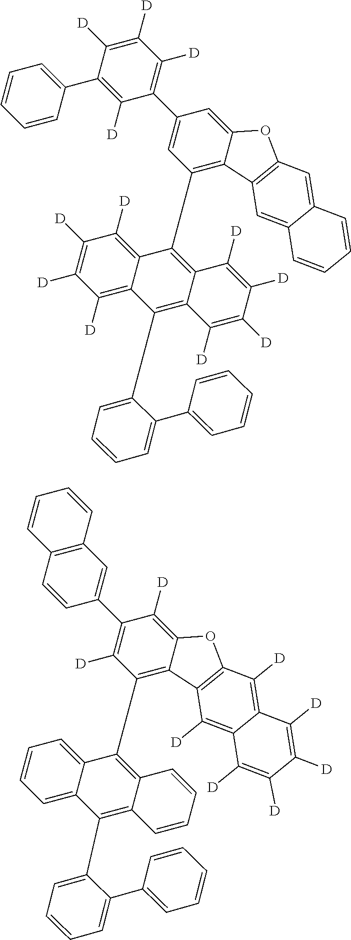 [SMILES: [2H]c1c([2H])c(-c2ccccc2)c([2H])c(-c2cc(-c3c4c([2H])c([2H])c([2H])c([2H])c4c(-c4ccccc4-c4ccccc4)c4c([2H])c([2H])c([2H])c([2H])c34)c3c(c2)oc2cc4ccccc4cc23)c1[2H] ; [2H]c1c([2H])c([2H])c2c([2H])c3c(oc4c([2H])c(-c5ccc6ccccc6c5)c([2H])c(-c5c6ccccc6c(-c6ccccc6-c6ccccc6)c6ccccc56)c43)c([2H])c2c1[2H]]

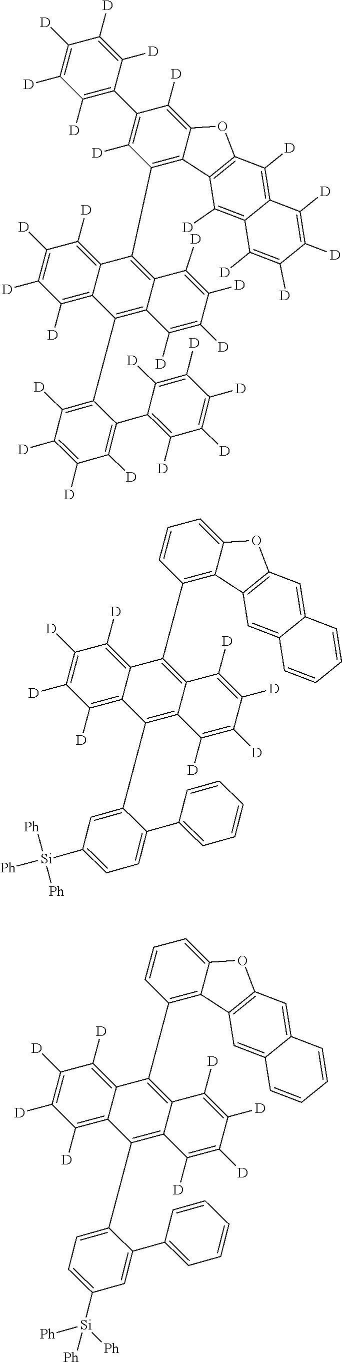

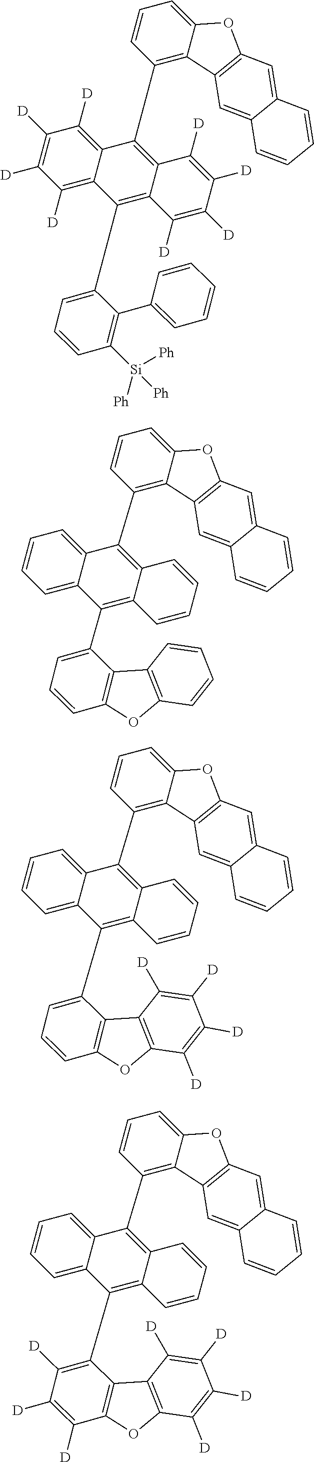

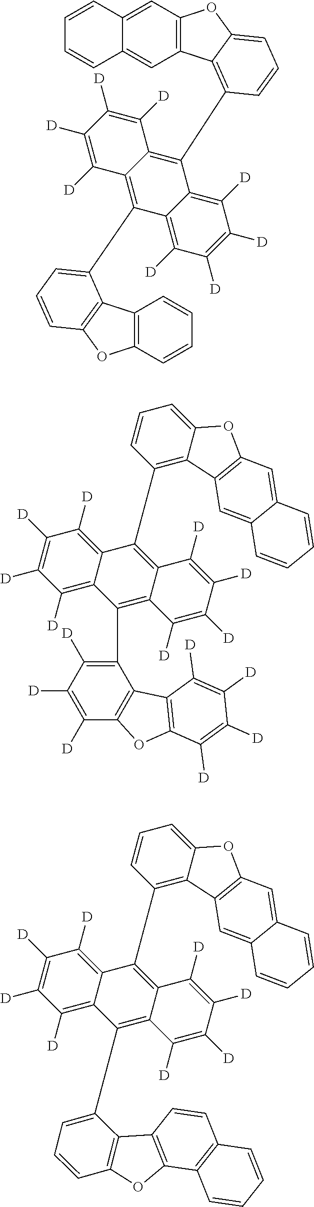

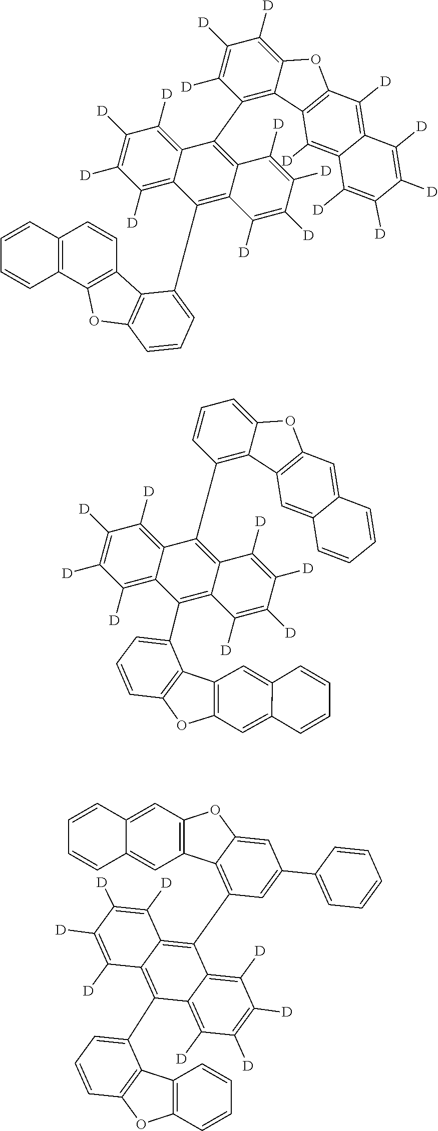 [SMILES: [2H]c1c([2H])c(-c2c3c([2H])c([2H])c([2H])c([2H])c3c(-c3cccc4oc5c6ccccc6ccc5c34)c3c([2H])c([2H])c([2H])c([2H])c23)c2c(oc3c([2H])c4c([2H])c([2H])c([2H])c([2H])c4c([2H])c32)c1[2H] ; [2H]c1c([2H])c([2H])c2c(-c3cccc4oc5cc6ccccc6cc5c34)c3c([2H])c([2H])c([2H])c([2H])c3c(-c3cccc4oc5cc6ccccc6cc5c34)c2c1[2H] ; [2H]c1c([2H])c([2H])c2c(-c3cc(-c4ccccc4)cc4oc5cc6ccccc6cc5c34)c3c([2H])c([2H])c([2H])c([2H])c3c(-c3cccc4oc5ccccc5c34)c2c1[2H]]

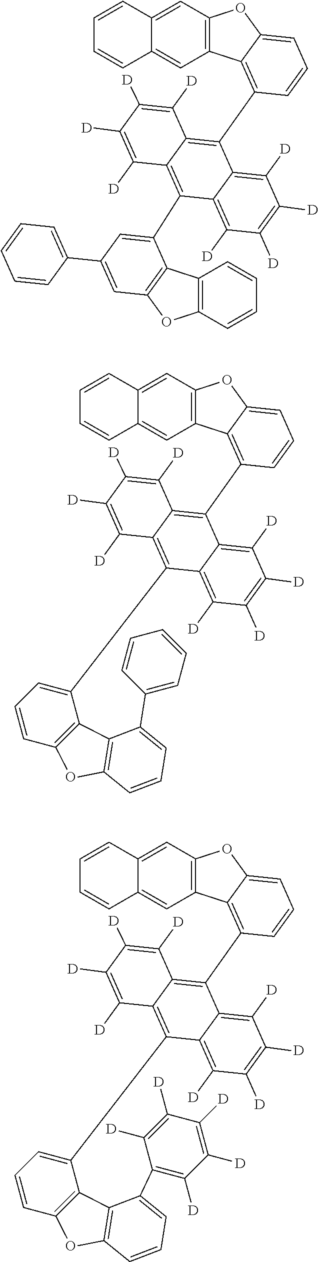 [SMILES: [2H]c1c([2H])c([2H])c2c(-c3cccc4oc5cc6ccccc6cc5c34)c3c([2H])c([2H])c([2H])c([2H])c3c(-c3cc(-c4ccccc4)cc4oc5ccccc5c34)c2c1[2H] ; [2H]c1c([2H])c([2H])c2c(-c3cccc4oc5cccc(-c6ccccc6)c5c34)c3c([2H])c([2H])c([2H])c([2H])c3c(-c3cccc4oc5cc6ccccc6cc5c34)c2c1[2H] ; [2H]c1c([2H])c([2H])c(-c2cccc3oc4cccc(-c5c6c([2H])c([2H])c([2H])c([2H])c6c(-c6cccc7oc8cc9ccccc9cc8c67)c6c([2H])c([2H])c([2H])c([2H])c56)c4c23)c([2H])c1[2H]]

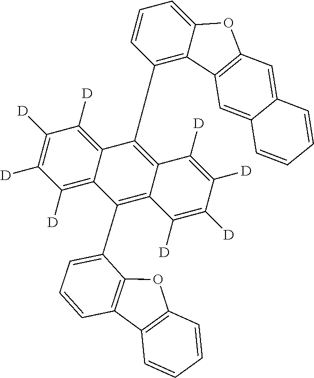 [SMILES: [2H]c1c([2H])c([2H])c2c(-c3cccc4oc5cc6ccccc6cc5c34)c3c([2H])c([2H])c([2H])c([2H])c3c(-c3cccc4c3oc3ccccc34)c2c1[2H]]

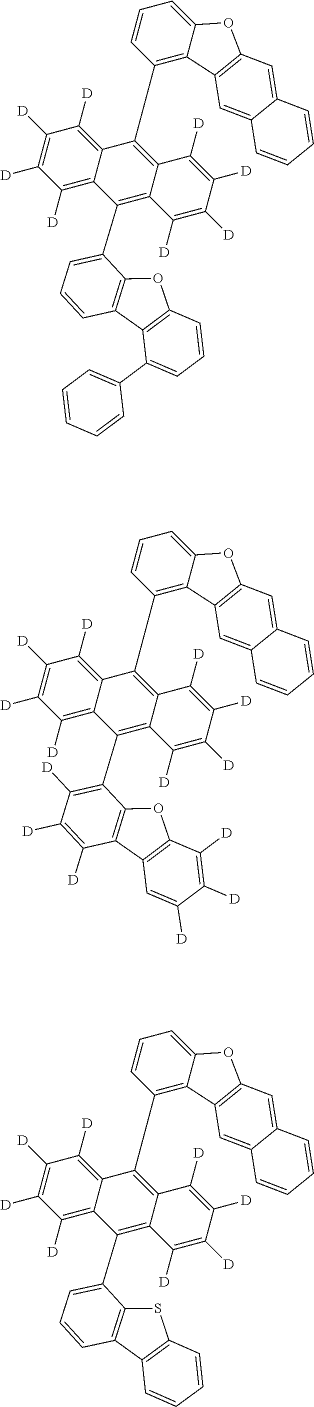 [SMILES: [2H]c1c([2H])c([2H])c2c(-c3cccc4oc5cc6ccccc6cc5c34)c3c([2H])c([2H])c([2H])c([2H])c3c(-c3cccc4c3oc3cccc(-c5ccccc5)c34)c2c1[2H] ; [2H]c1cc2c(oc3c(-c4c5c([2H])c([2H])c([2H])c([2H])c5c(-c5cccc6oc7cc8ccccc8cc7c56)c5c([2H])c([2H])c([2H])c([2H])c45)c([2H])c([2H])c([2H])c32)c([2H])c1[2H] ; [2H]c1c([2H])c([2H])c2c(-c3cccc4oc5cc6ccccc6cc5c34)c3c([2H])c([2H])c([2H])c([2H])c3c(-c3cccc4c3sc3ccccc34)c2c1[2H]]

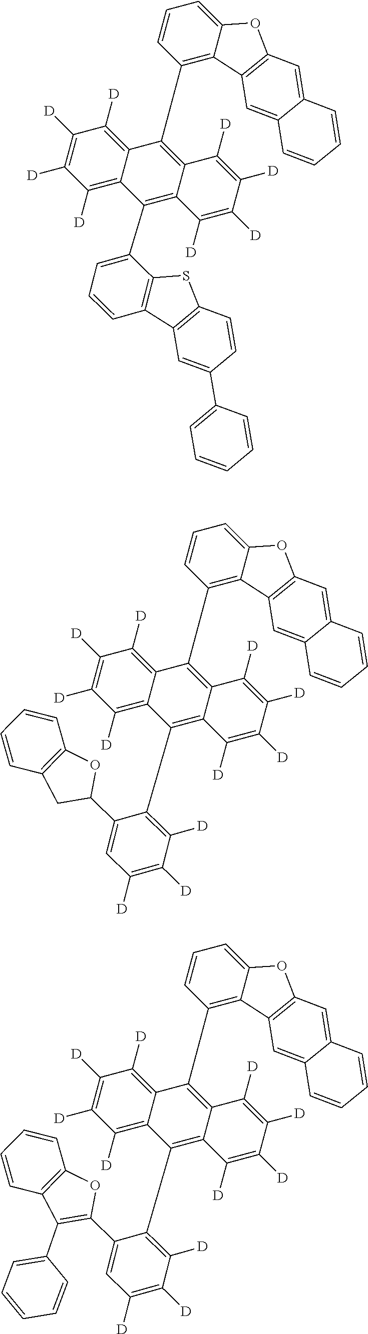 [SMILES: [2H]c1c([2H])c([2H])c2c(-c3cccc4oc5cc6ccccc6cc5c34)c3c([2H])c([2H])c([2H])c([2H])c3c(-c3cccc4c3sc3ccc(-c5ccccc5)cc34)c2c1[2H] ; [2H]c1cc(C2Cc3ccccc3O2)c(-c2c3c([2H])c([2H])c([2H])c([2H])c3c(-c3cccc4oc5cc6ccccc6cc5c34)c3c([2H])c([2H])c([2H])c([2H])c23)c([2H])c1[2H] ; [2H]c1cc(-c2oc3ccccc3c2-c2ccccc2)c(-c2c3c([2H])c([2H])c([2H])c([2H])c3c(-c3cccc4oc5cc6ccccc6cc5c34)c3c([2H])c([2H])c([2H])c([2H])c23)c([2H])c1[2H]]

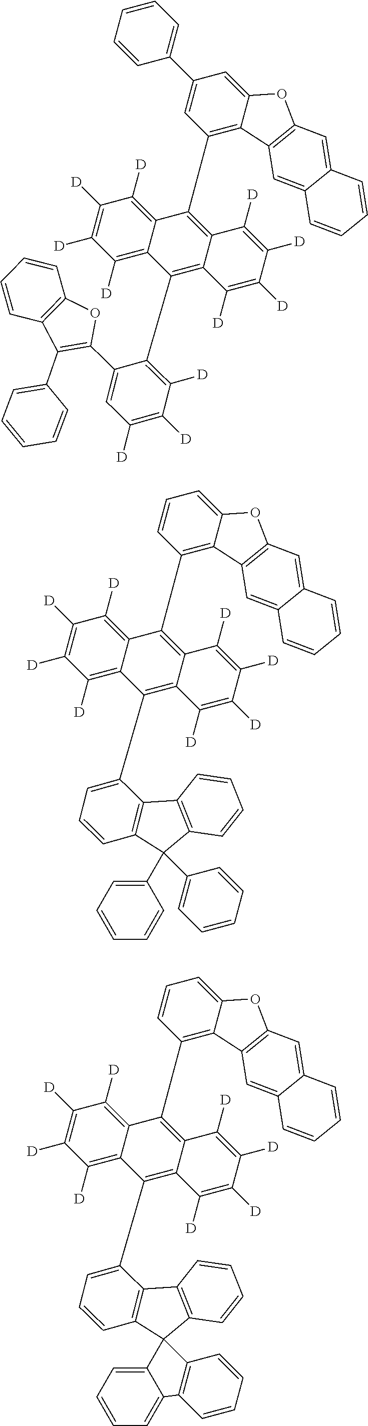

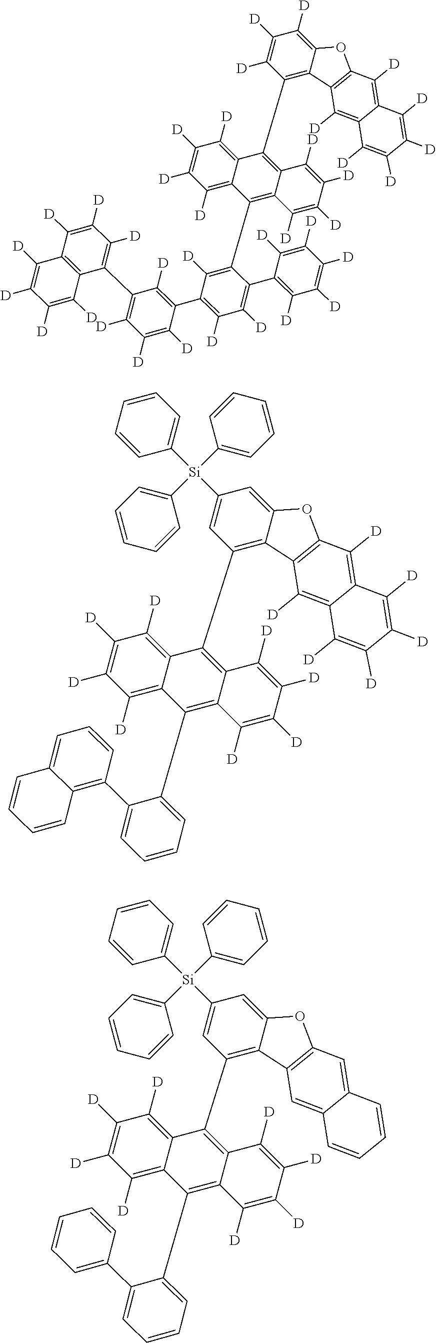

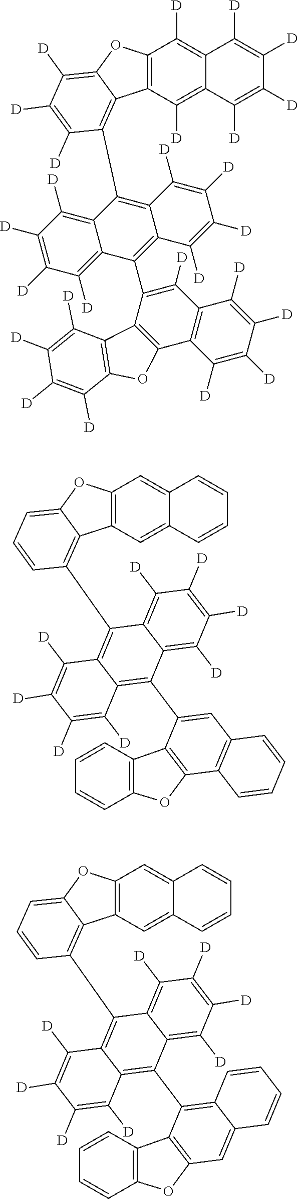 [SMILES: [2H]c1c([2H])c(-c2c3c([2H])c([2H])c([2H])c([2H])c3c(-c3c([2H])c4c([2H])c([2H])c([2H])c([2H])c4c4oc5c([2H])c([2H])c([2H])c([2H])c5c34)c3c([2H])c([2H])c([2H])c([2H])c23)c2c(oc3c([2H])c4c([2H])c([2H])c([2H])c([2H])c4c([2H])c32)c1[2H] ; [2H]c1c([2H])c([2H])c2c(-c3cc4ccccc4c4oc5ccccc5c34)c3c([2H])c([2H])c([2H])c([2H])c3c(-c3cccc4oc5cc6ccccc6cc5c34)c2c1[2H] ; [2H]c1c([2H])c([2H])c2c(-c3c4ccccc4cc4oc5ccccc5c34)c3c([2H])c([2H])c([2H])c([2H])c3c(-c3cccc4oc5cc6ccccc6cc5c34)c2c1[2H]]

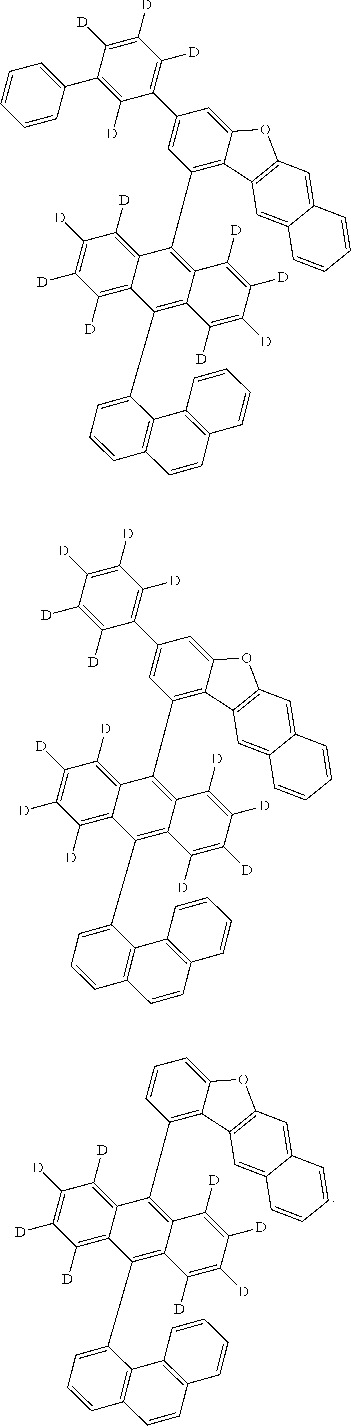 [SMILES: [2H]c1c([2H])c(-c2ccccc2)c([2H])c(-c2cc(-c3c4c([2H])c([2H])c([2H])c([2H])c4c(-c4cccc5ccc6ccccc6c45)c4c([2H])c([2H])c([2H])c([2H])c34)c3c(c2)oc2cc4ccccc4cc23)c1[2H] ; [2H]c1c([2H])c([2H])c(-c2cc(-c3c4c([2H])c([2H])c([2H])c([2H])c4c(-c4cccc5ccc6ccccc6c45)c4c([2H])c([2H])c([2H])c([2H])c34)c3c(c2)oc2cc4ccccc4cc23)c([2H])c1[2H] ; [2H]c1c([2H])c([2H])c2c(-c3cccc4oc5cc6ccccc6cc5c34)c3c([2H])c([2H])c([2H])c([2H])c3c(-c3cccc4ccc5ccccc5c34)c2c1[2H]]

17. The organic light emitting device of claim 1, wherein the compound of Chemical Formula 2 is any one of the following compounds:

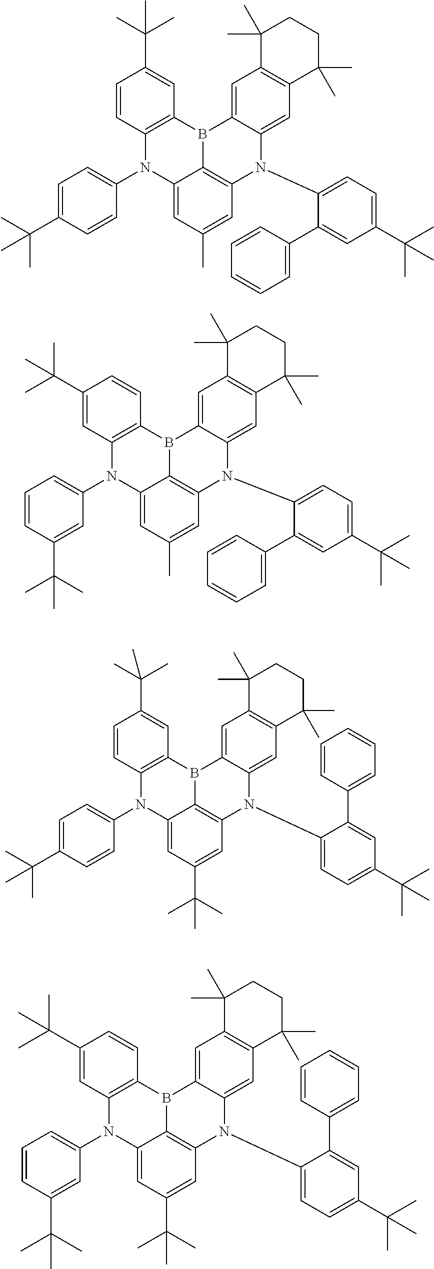

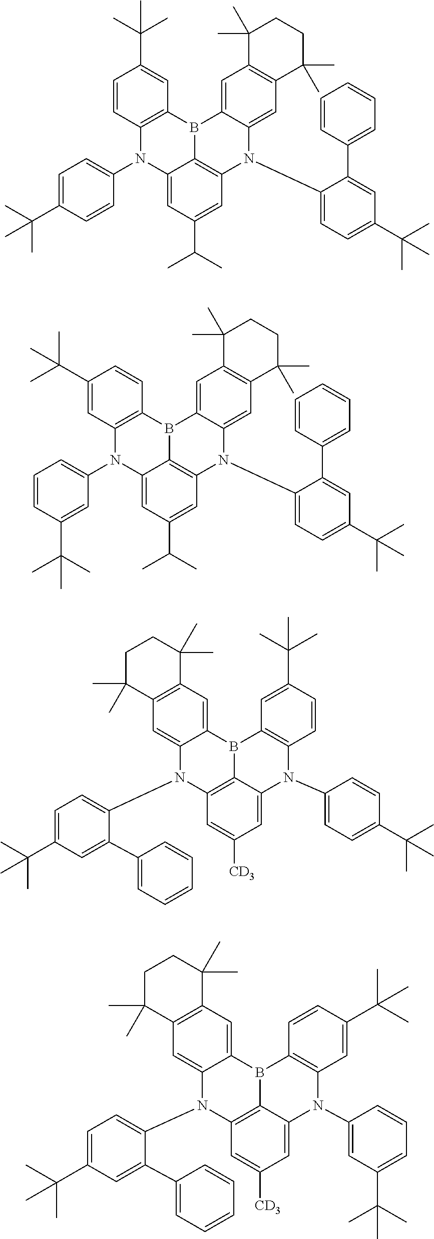

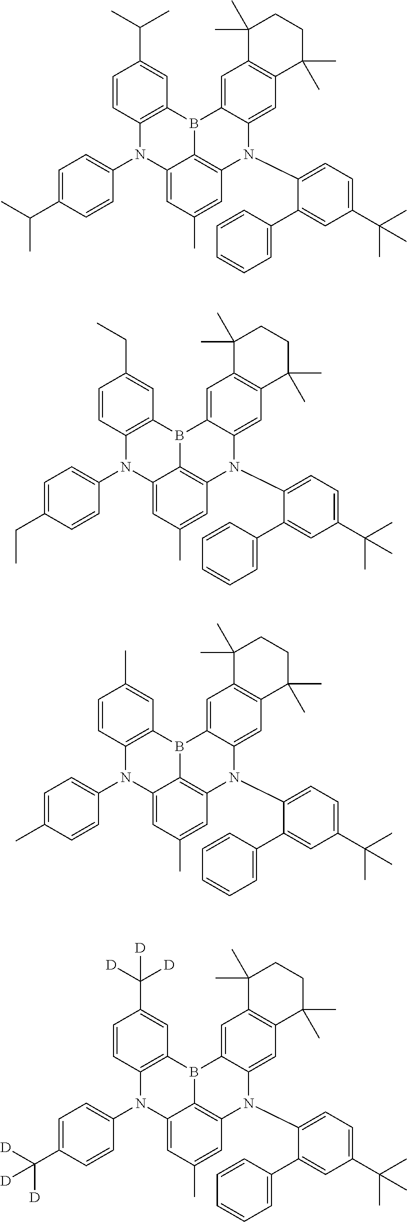

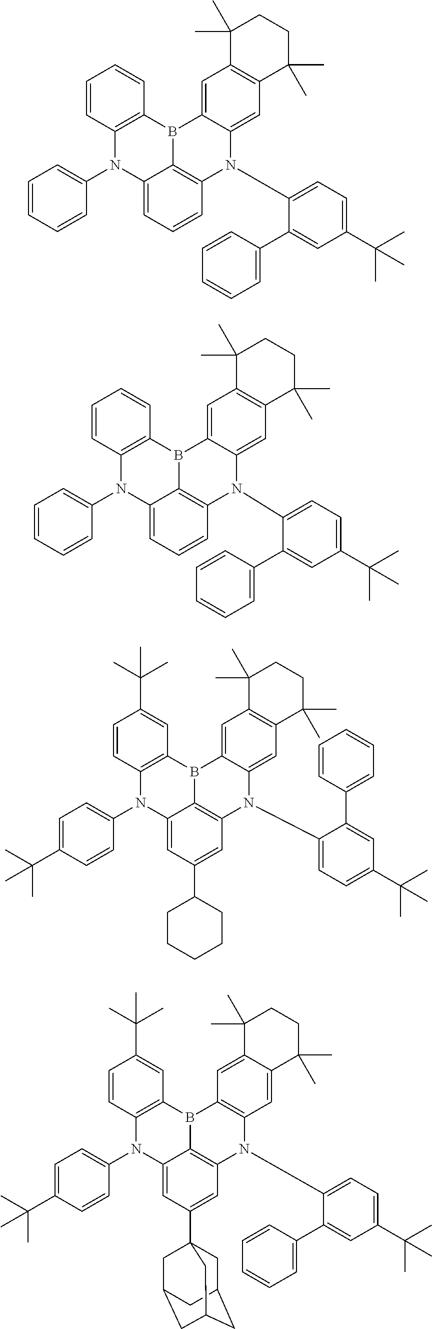

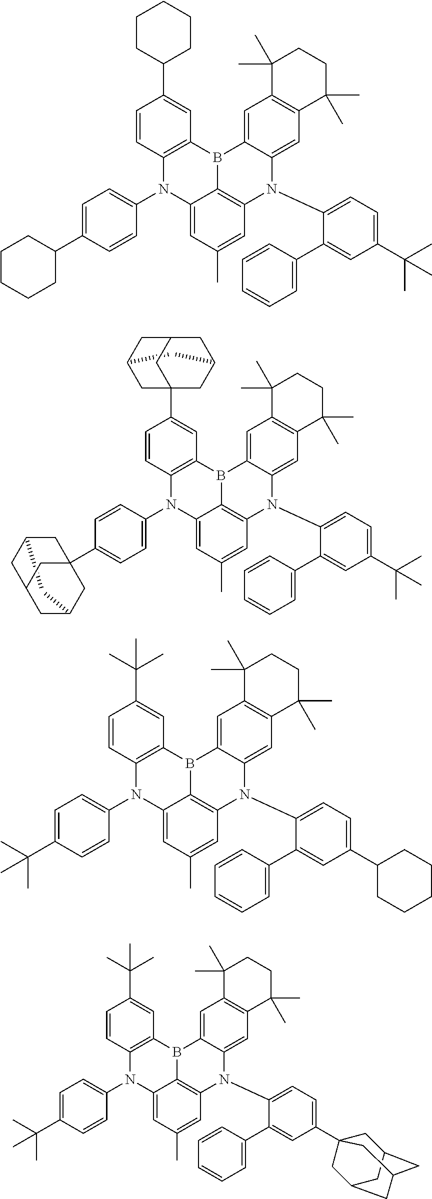

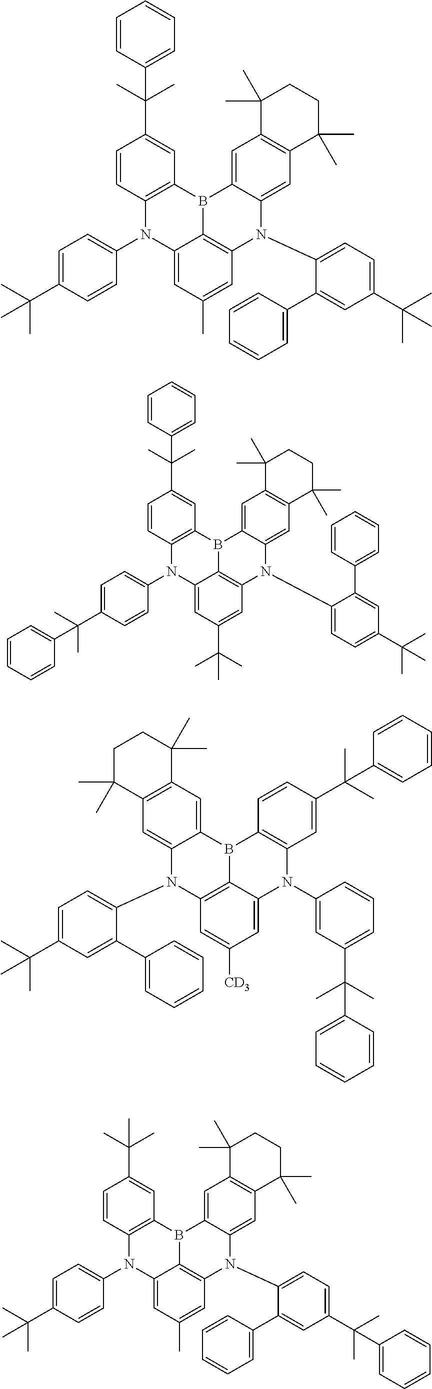

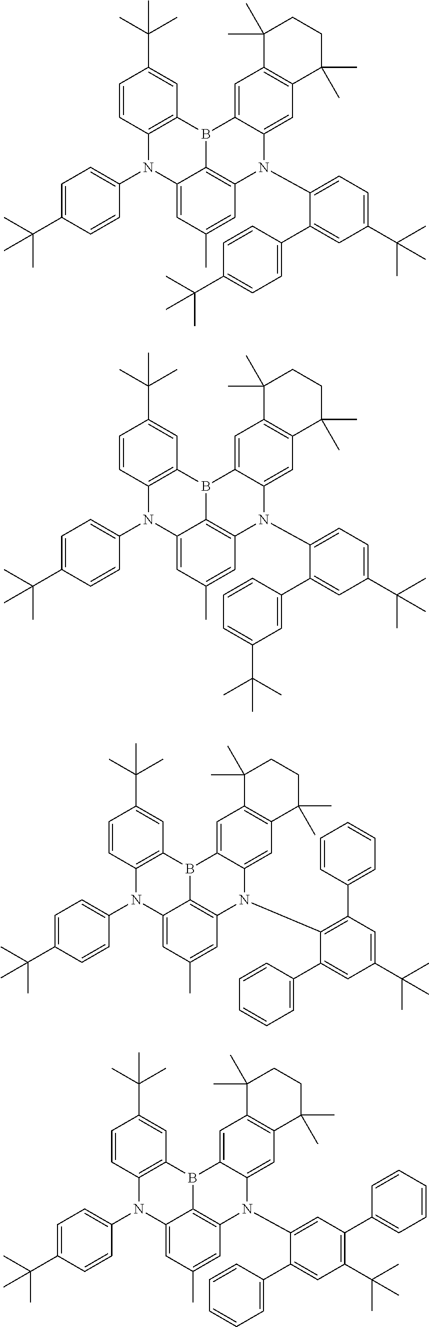

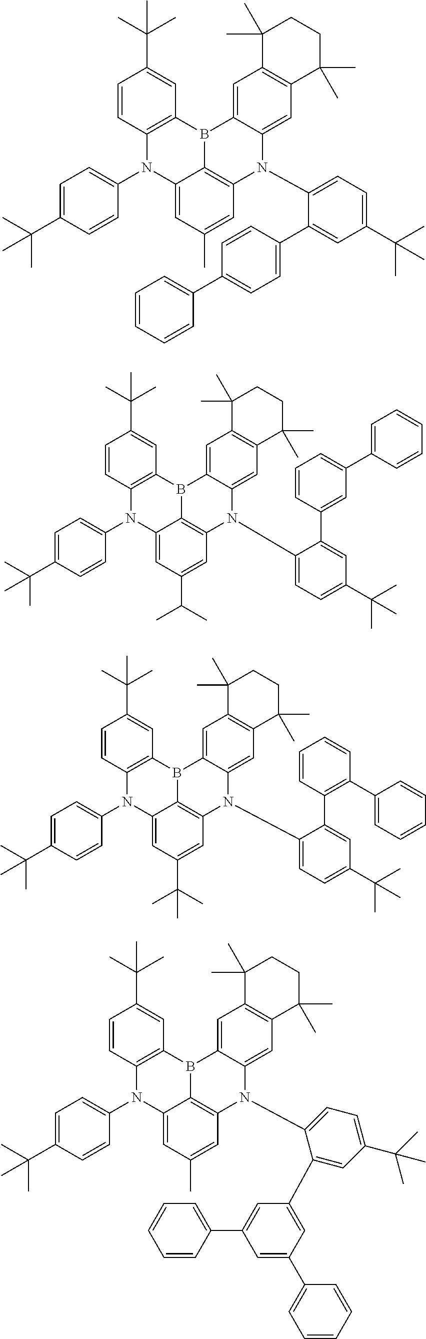

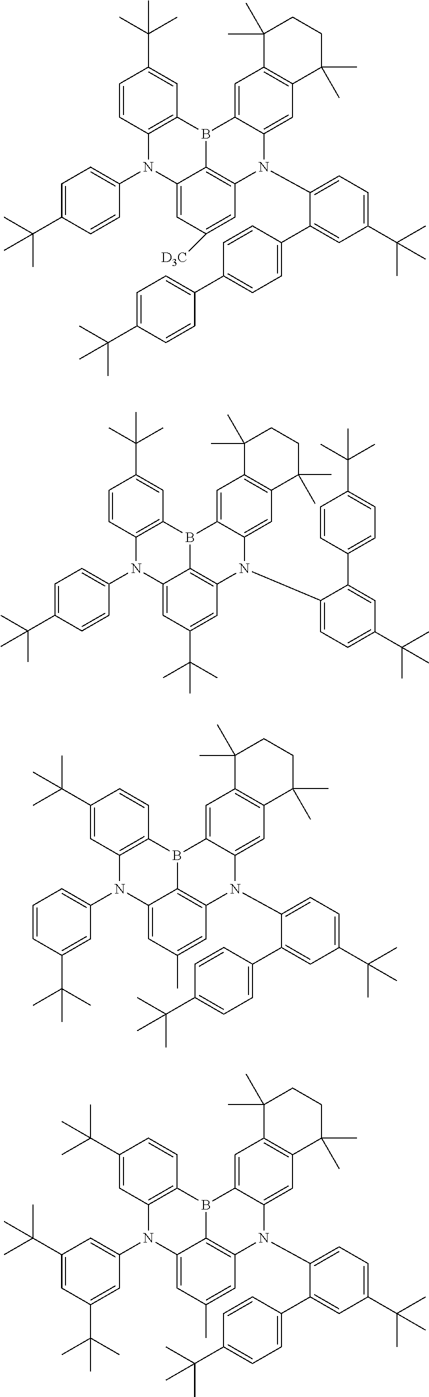

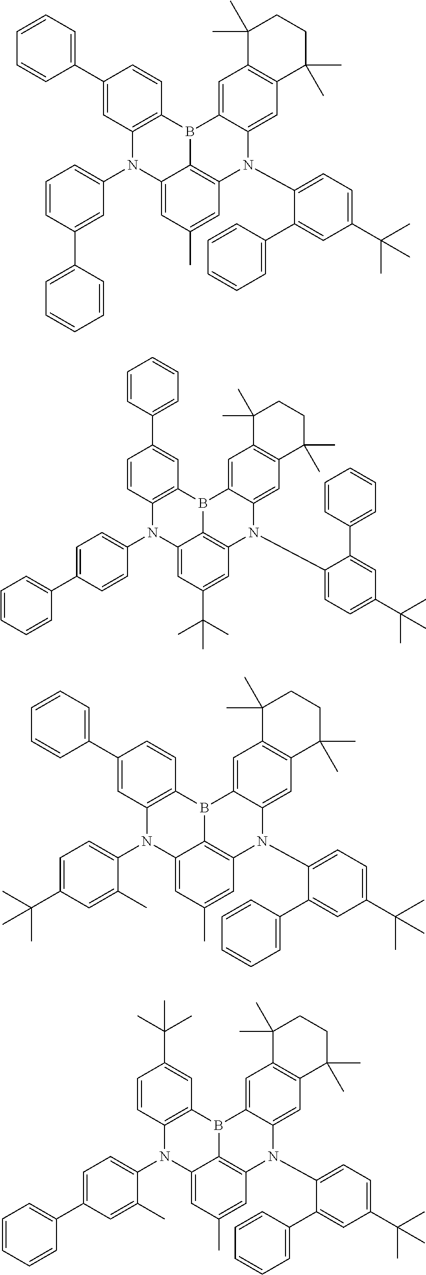

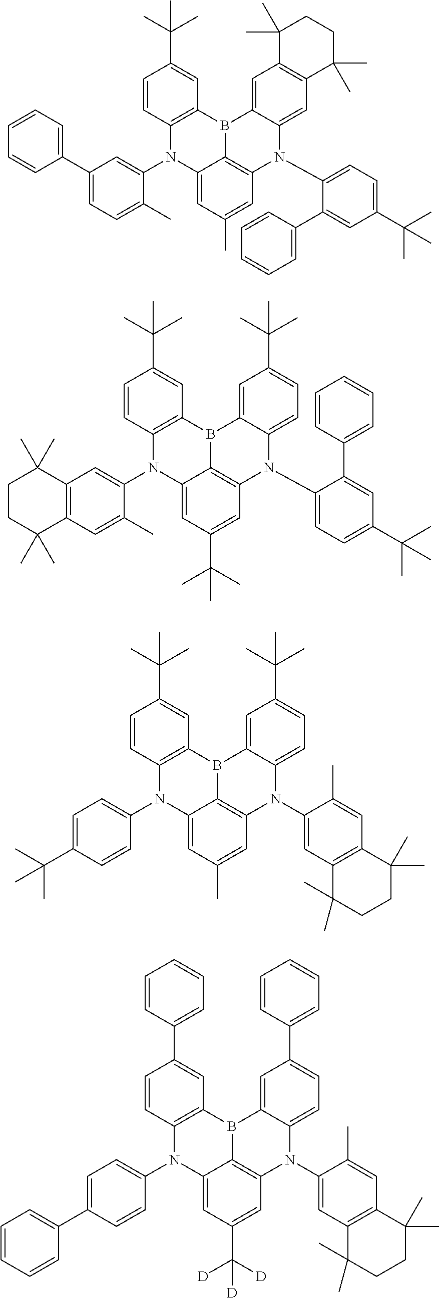

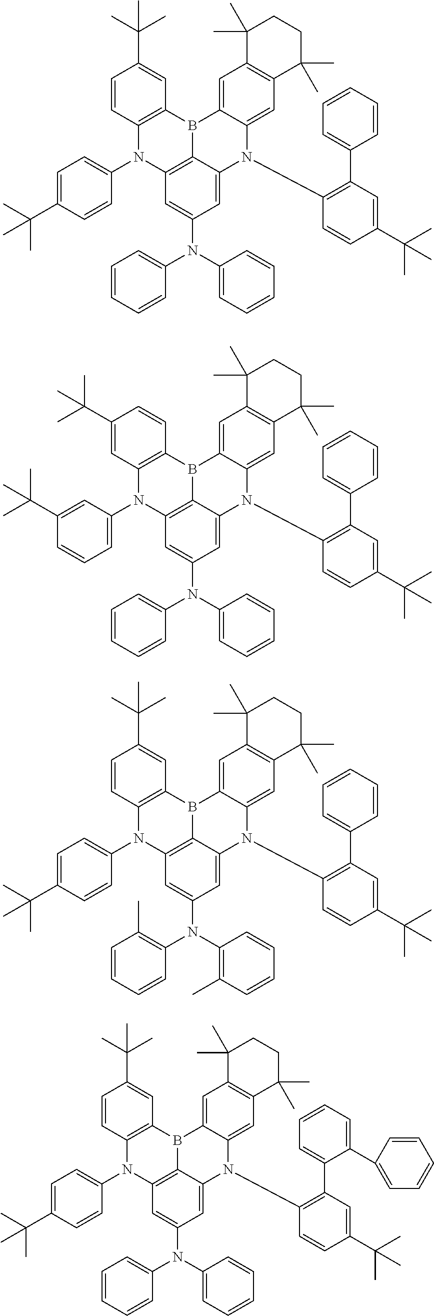

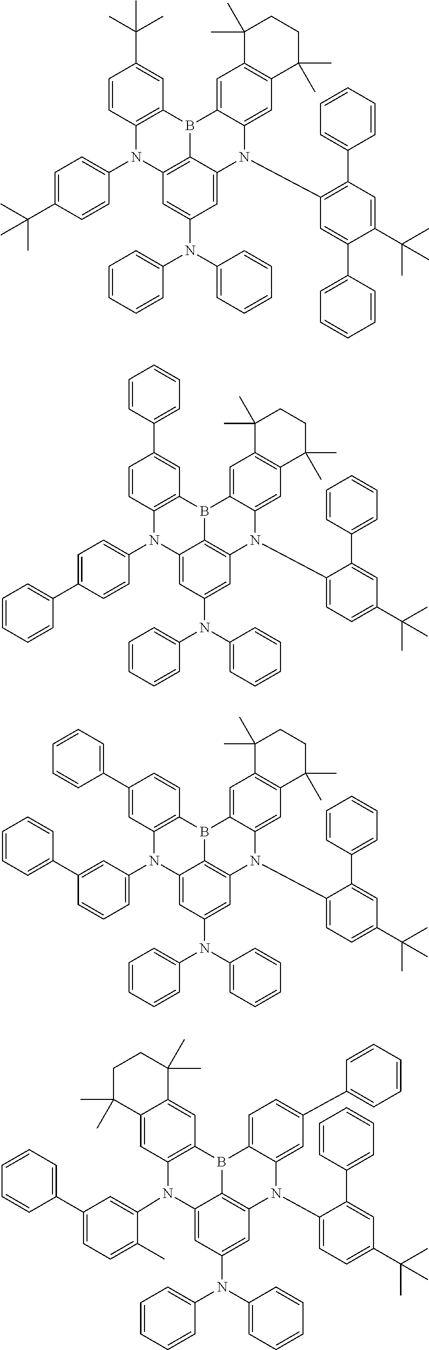

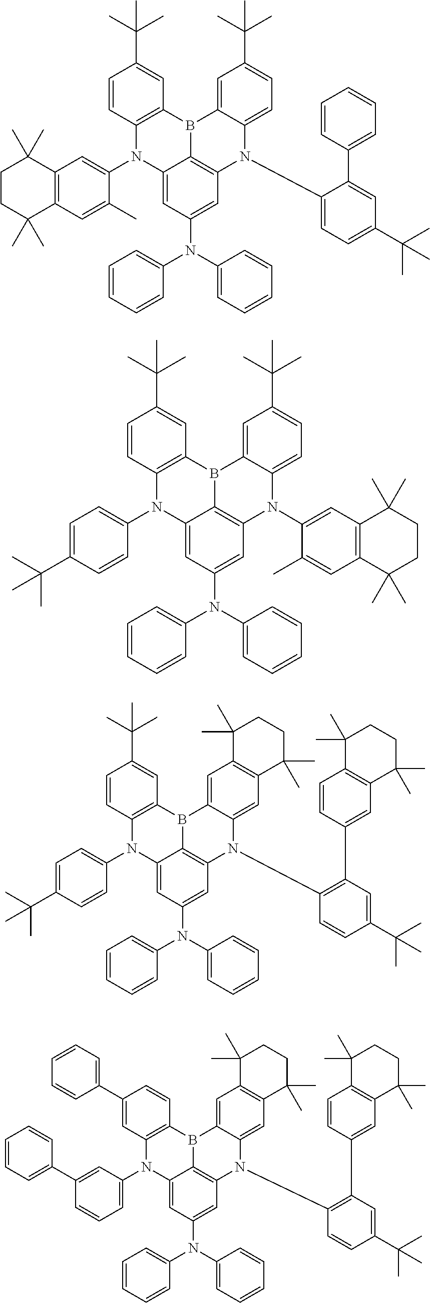

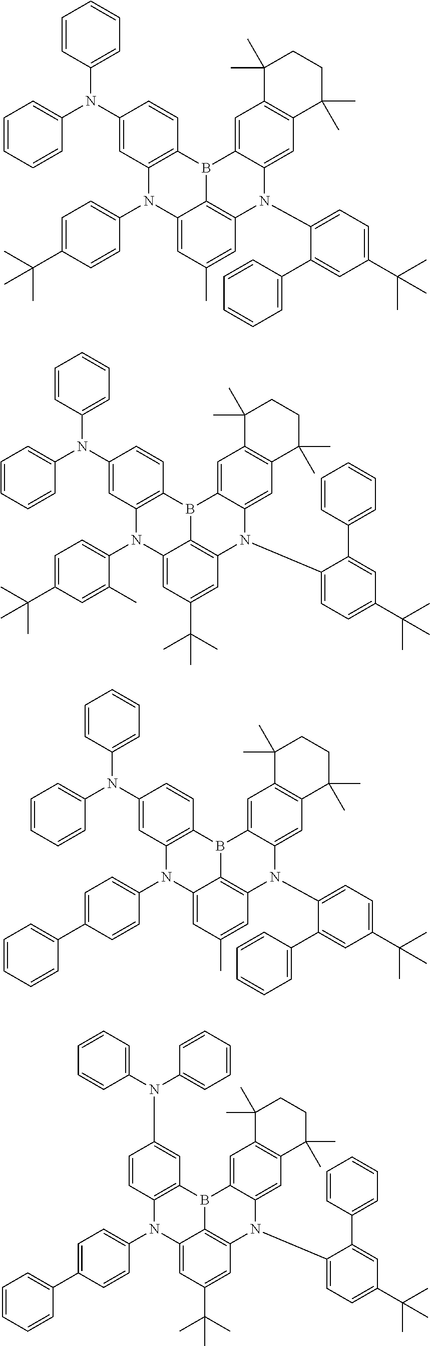

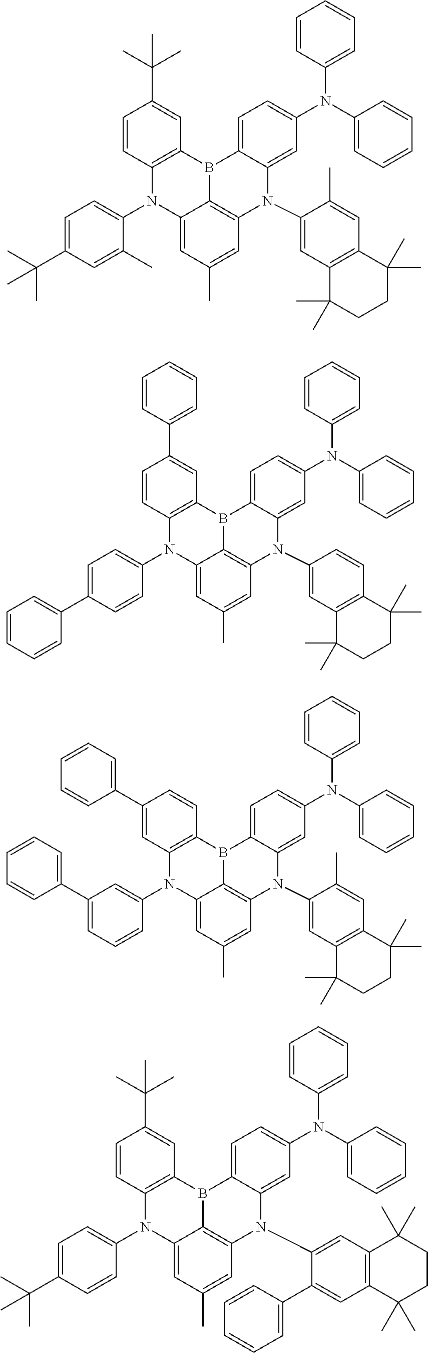

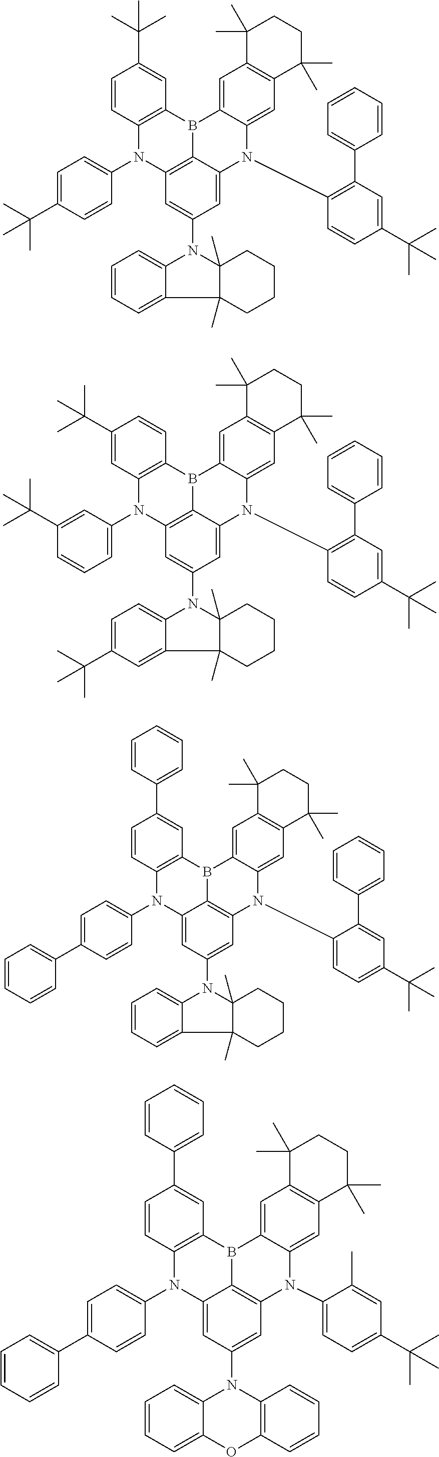

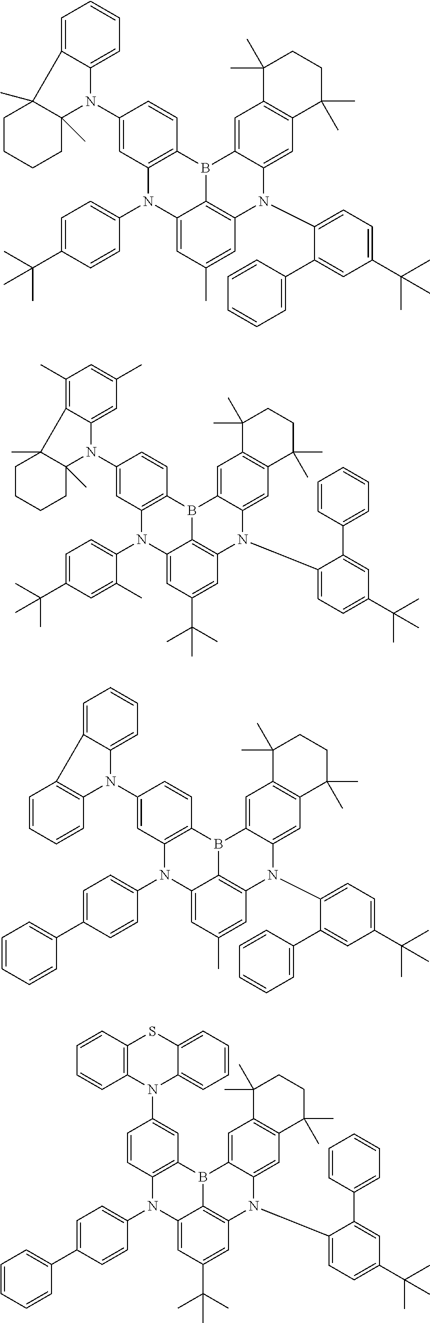

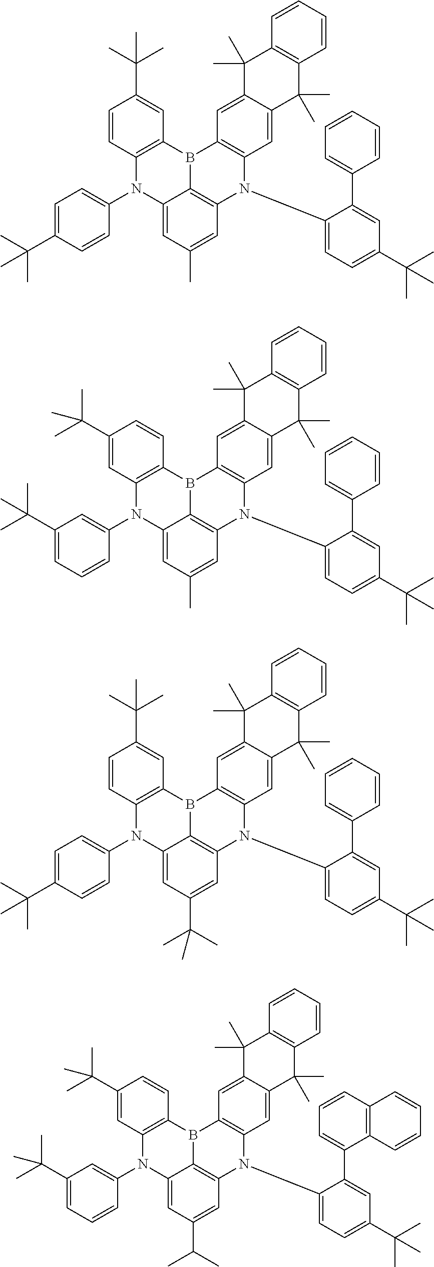

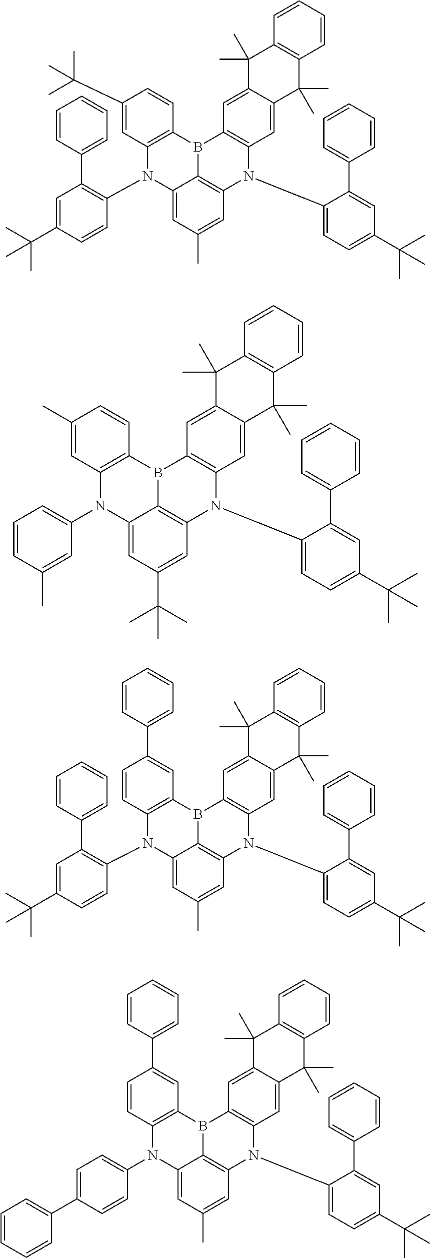

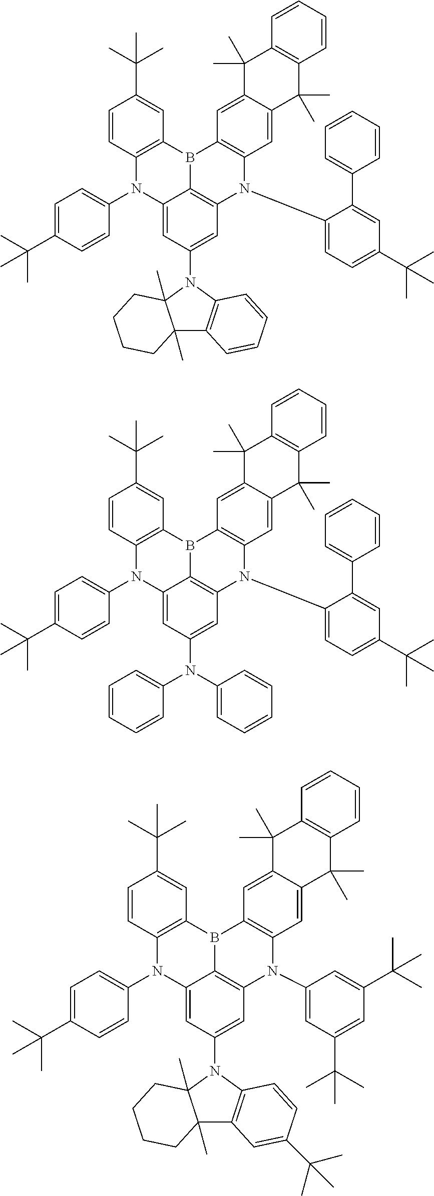

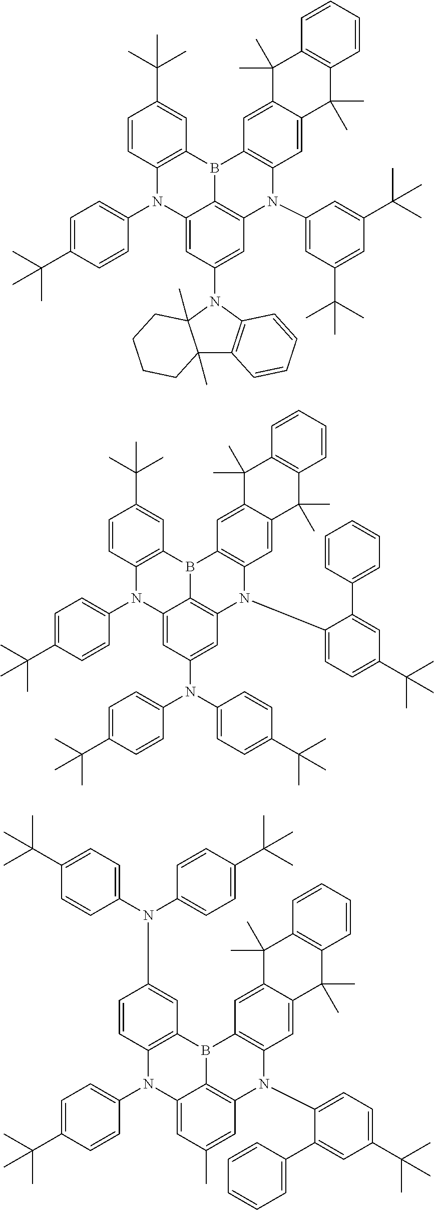

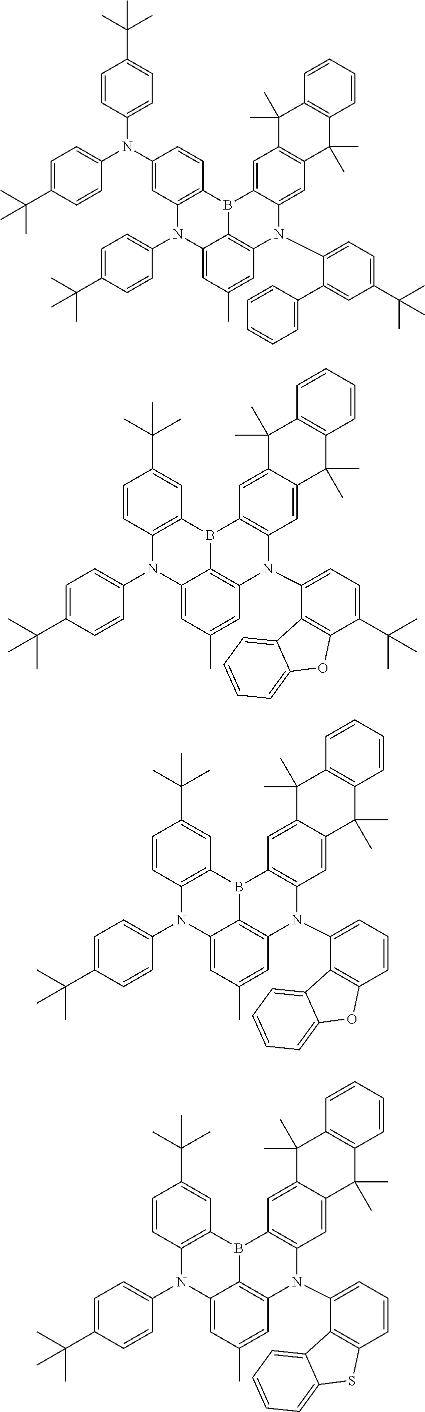

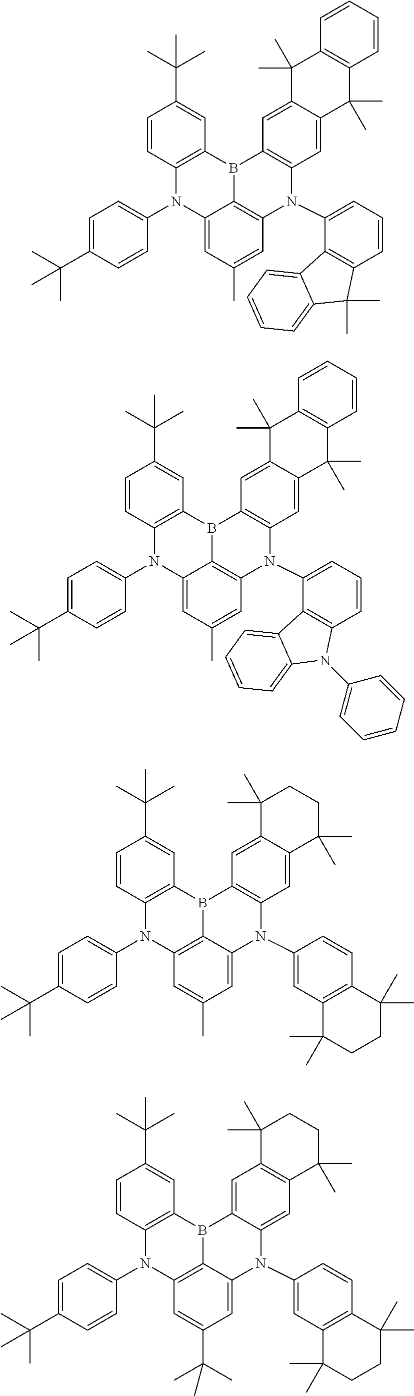

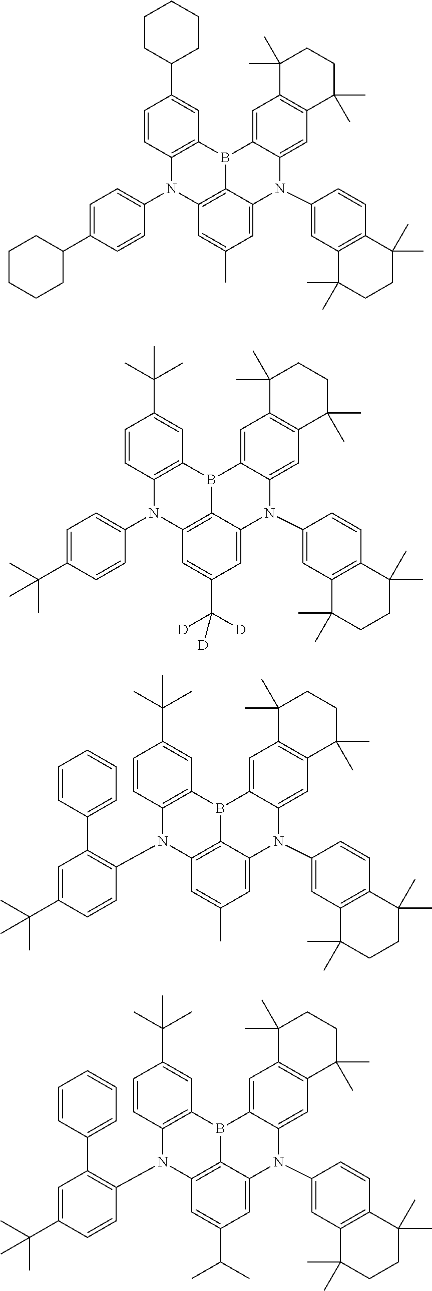

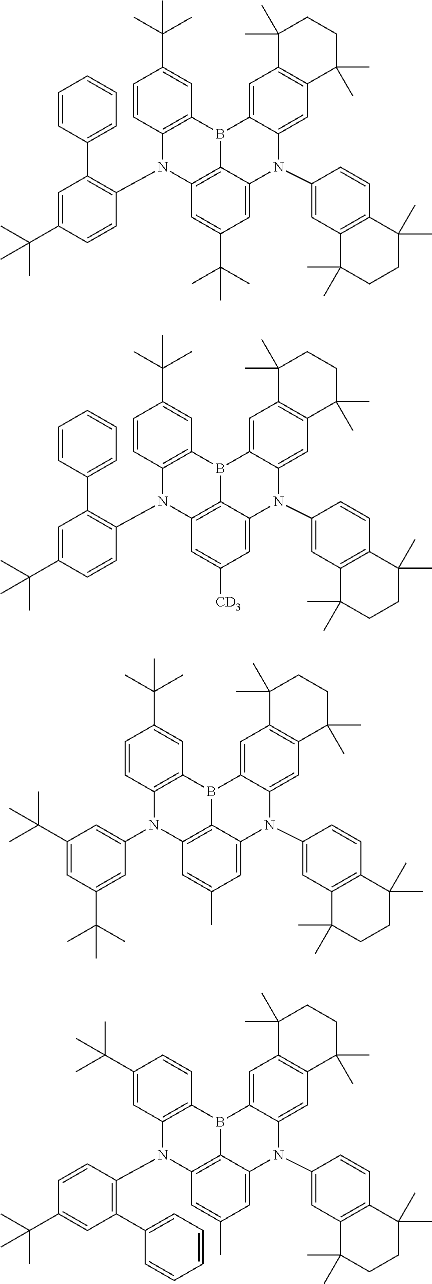

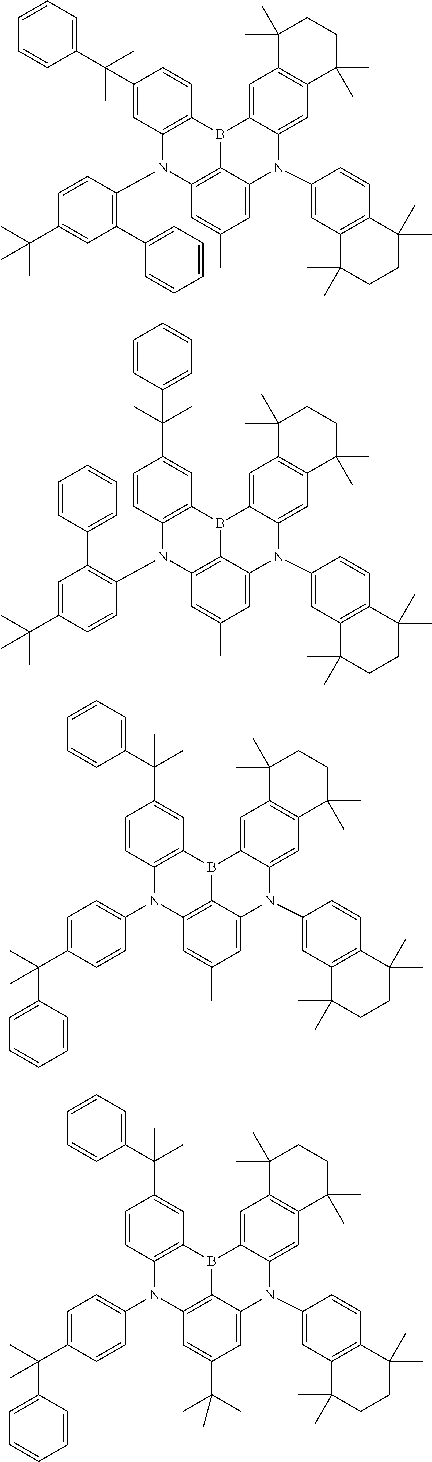

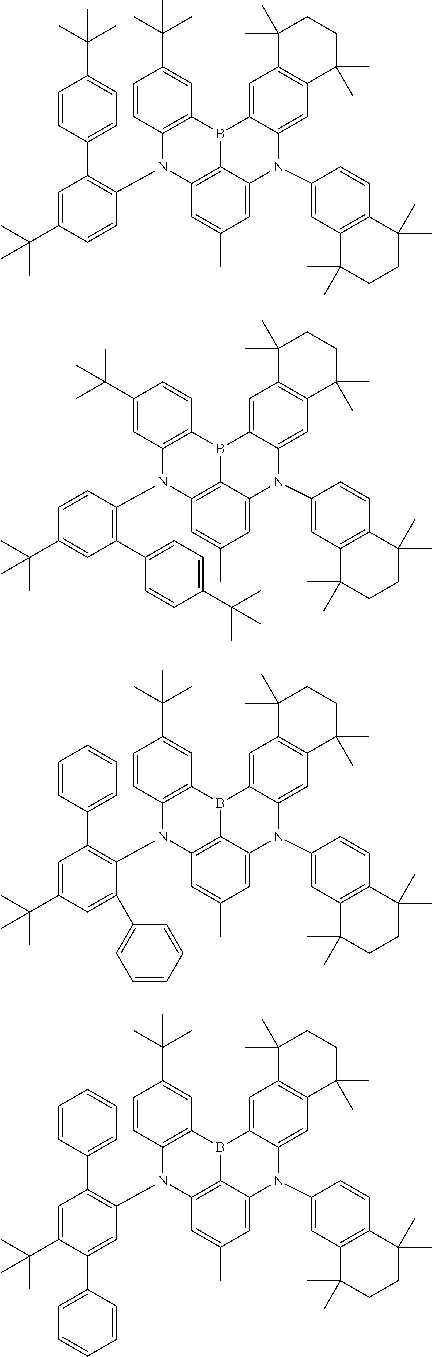

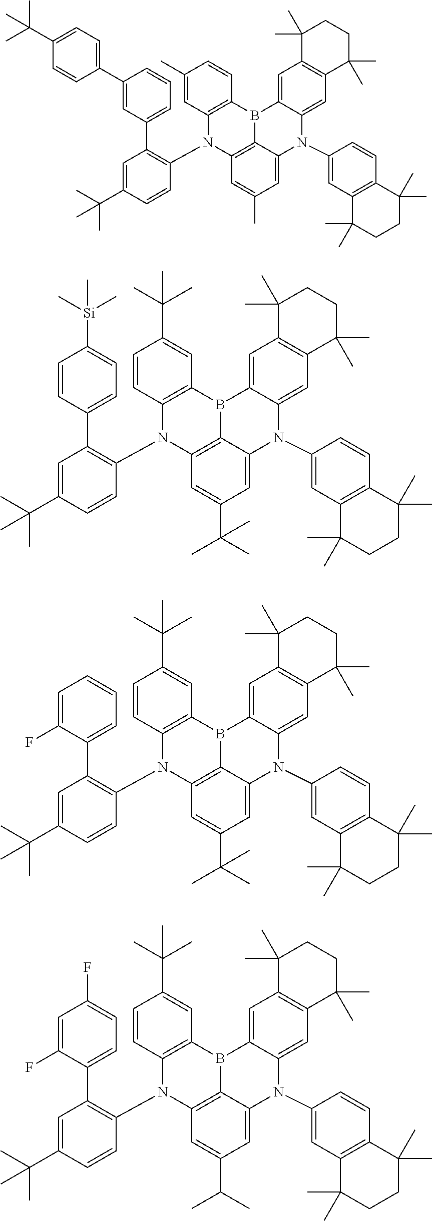

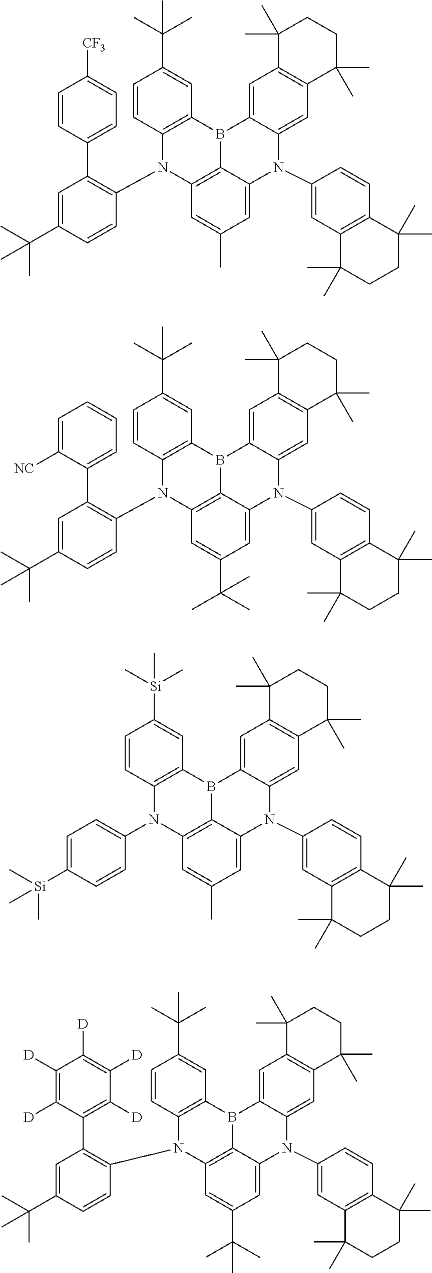

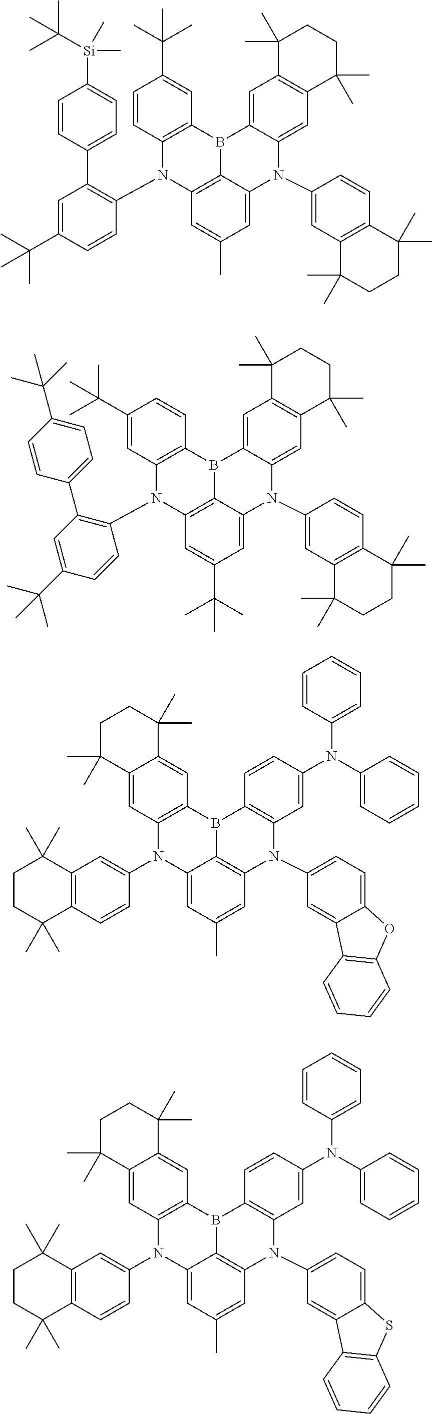

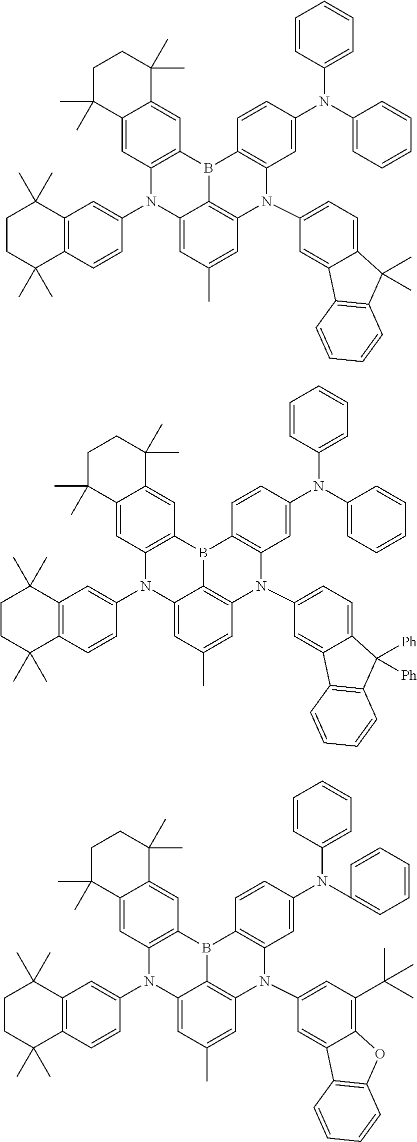

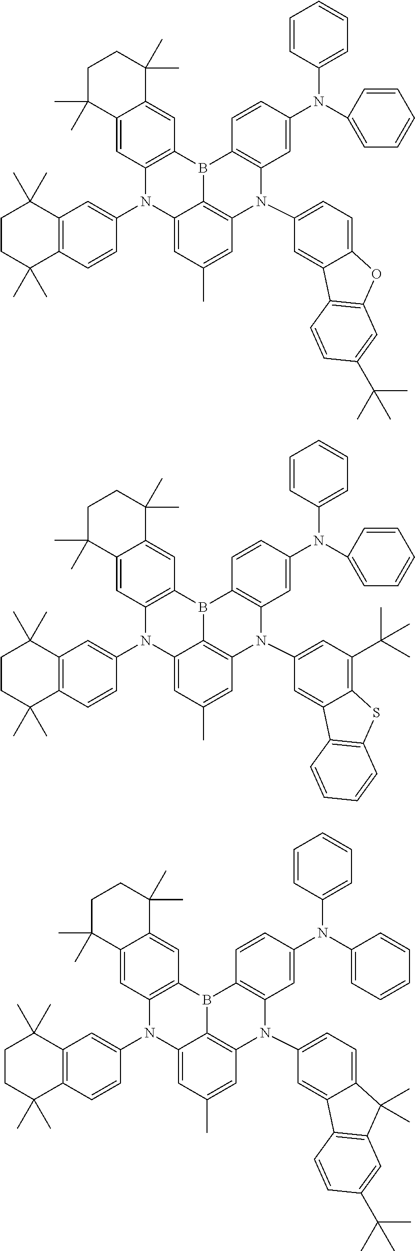

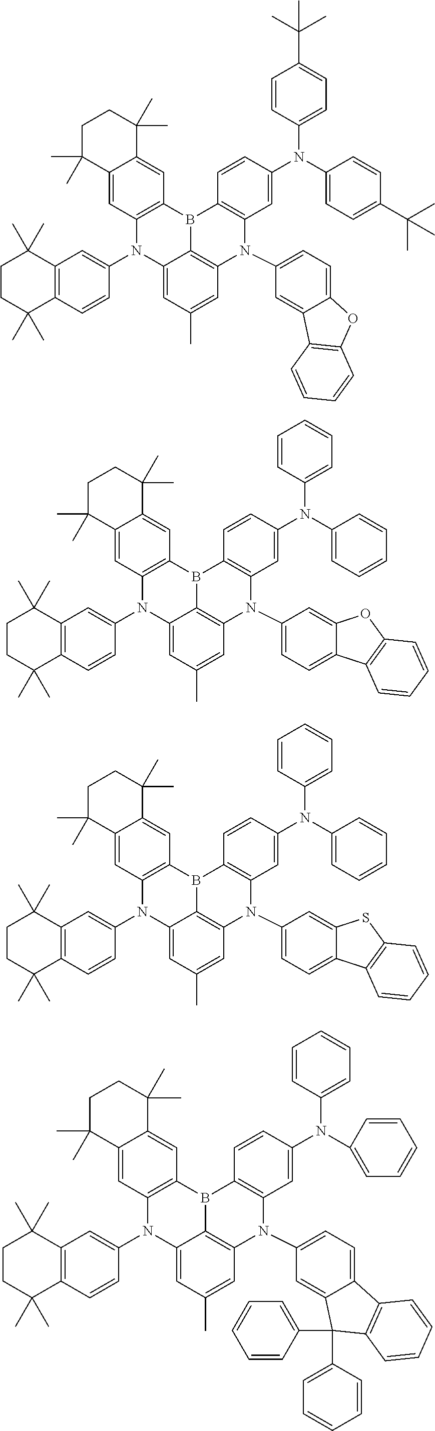

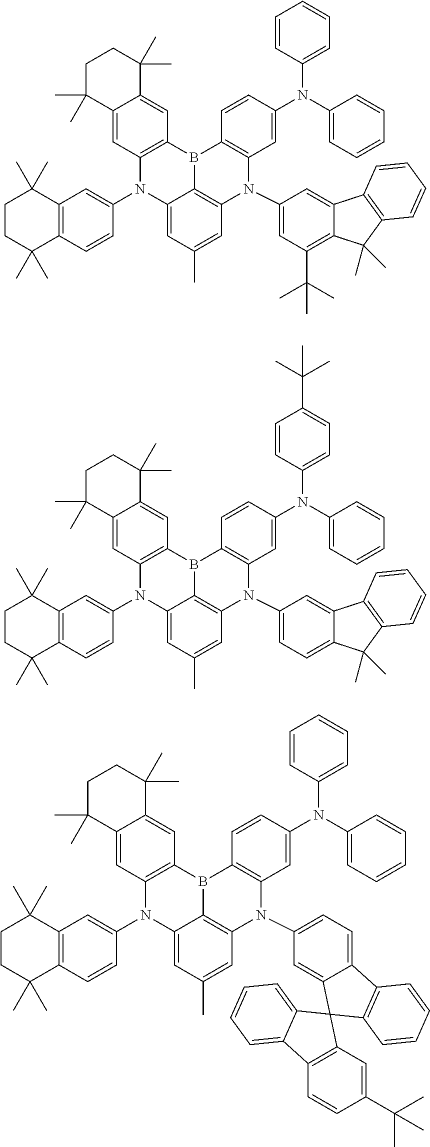

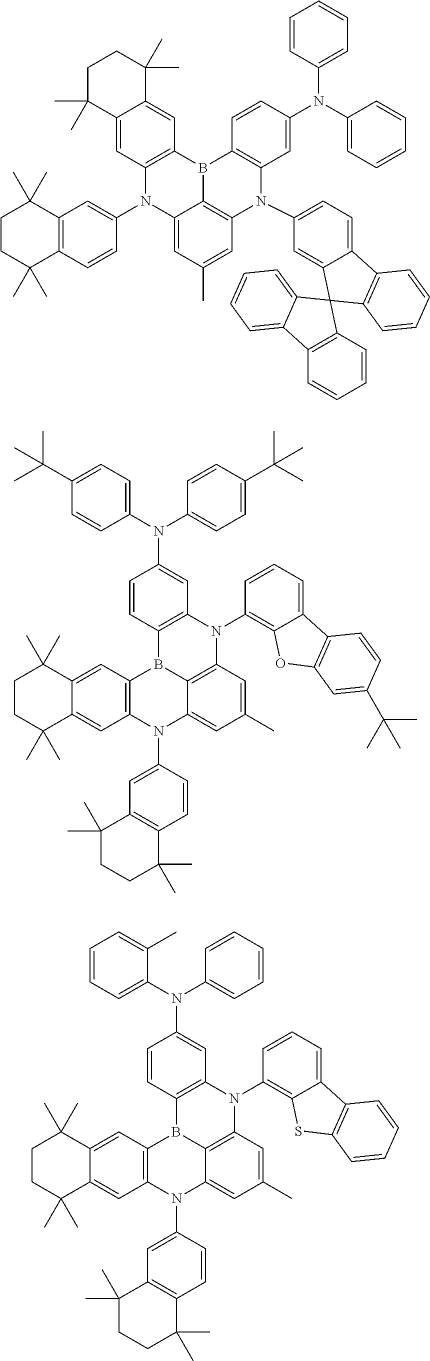

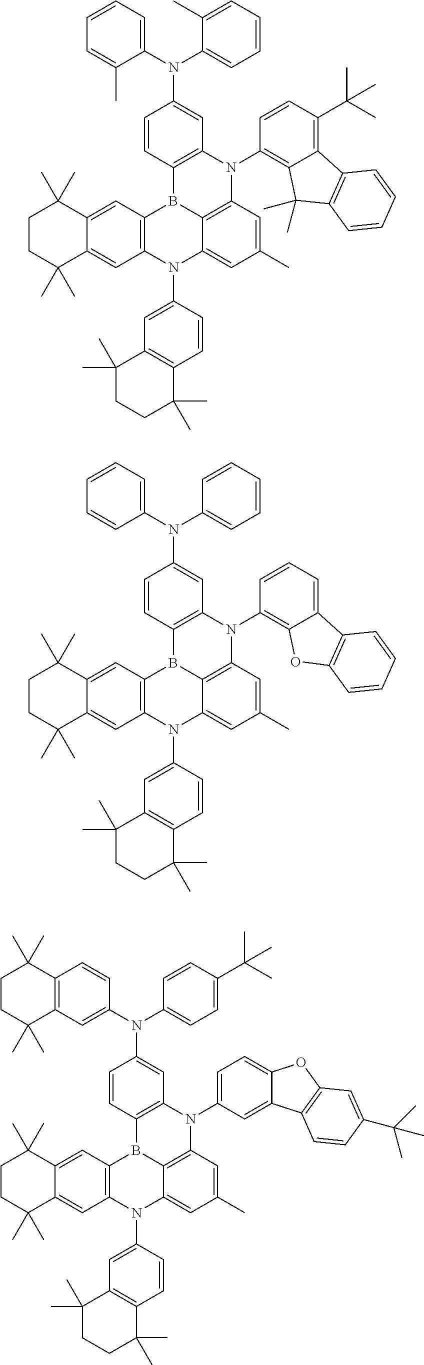 [SMILES: Cc1cc2c3c(c1)N(c1ccc(C(C)(C)C)c4c1C(C)(C)c1ccccc1-4)c1cc(N(c4ccccc4C)c4ccccc4C)ccc1B3c1cc3c(cc1N2c1ccc2c(c1)C(C)(C)CCC2(C)C)C(C)(C)CCC3(C)C ; Cc1cc2c3c(c1)N(c1cccc4c1oc1ccccc14)c1cc(N(c4ccccc4)c4ccccc4)ccc1B3c1cc3c(cc1N2c1ccc2c(c1)C(C)(C)CCC2(C)C)C(C)(C)CCC3(C)C ; Cc1cc2c3c(c1)N(c1ccc4c(c1)C(C)(C)CCC4(C)C)c1cc4c(cc1B3c1ccc(N(c3ccc(C(C)(C)C)cc3)c3ccc5c(c3)C(C)(C)CCC5(C)C)cc1N2c1ccc2oc3cc(C(C)(C)C)ccc3c2c1)C(C)(C)CCC4(C)C]

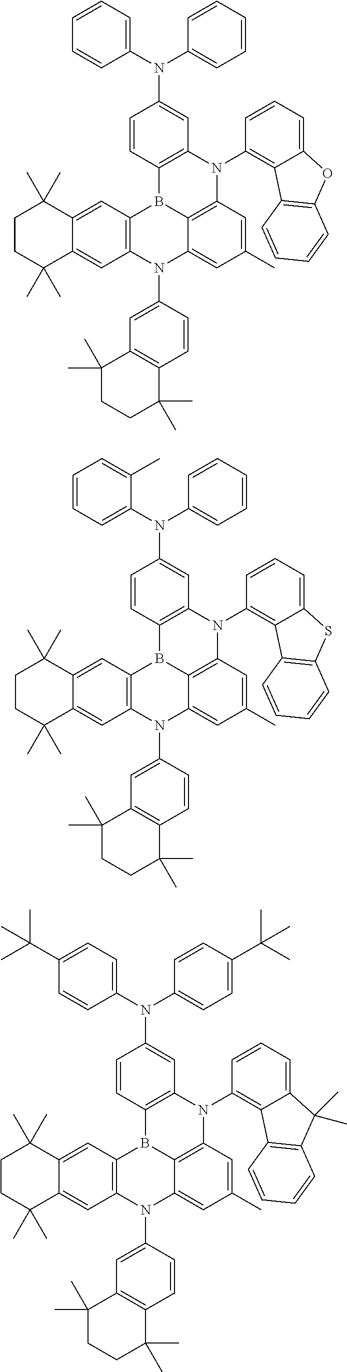

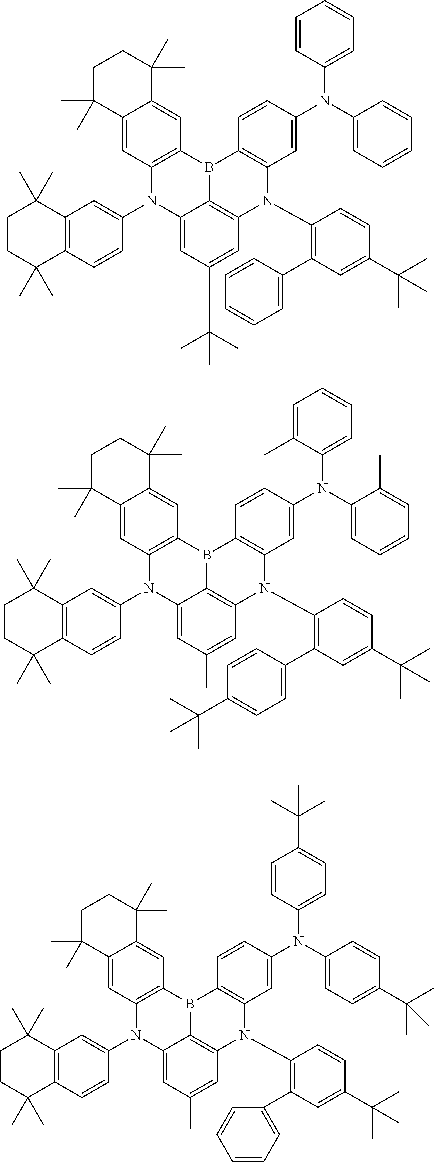 [SMILES: CC(C)(C)c1ccc(N2c3cc(N(c4ccccc4)c4ccccc4)ccc3B3c4cc5c(cc4N(c4ccc6c(c4)C(C)(C)CCC6(C)C)c4cc(C(C)(C)C)cc2c43)C(C)(C)CCC5(C)C)c(-c2ccccc2)c1 ; Cc1cc2c3c(c1)N(c1ccc(C(C)(C)C)cc1-c1ccc(C(C)(C)C)cc1)c1cc(N(c4ccccc4C)c4ccccc4C)ccc1B3c1cc3c(cc1N2c1ccc2c(c1)C(C)(C)CCC2(C)C)C(C)(C)CCC3(C)C ; Cc1cc2c3c(c1)N(c1ccc(C(C)(C)C)cc1-c1ccccc1)c1cc(N(c4ccc(C(C)(C)C)cc4)c4ccc(C(C)(C)C)cc4)ccc1B3c1cc3c(cc1N2c1ccc2c(c1)C(C)(C)CCC2(C)C)C(C)(C)CCC3(C)C]

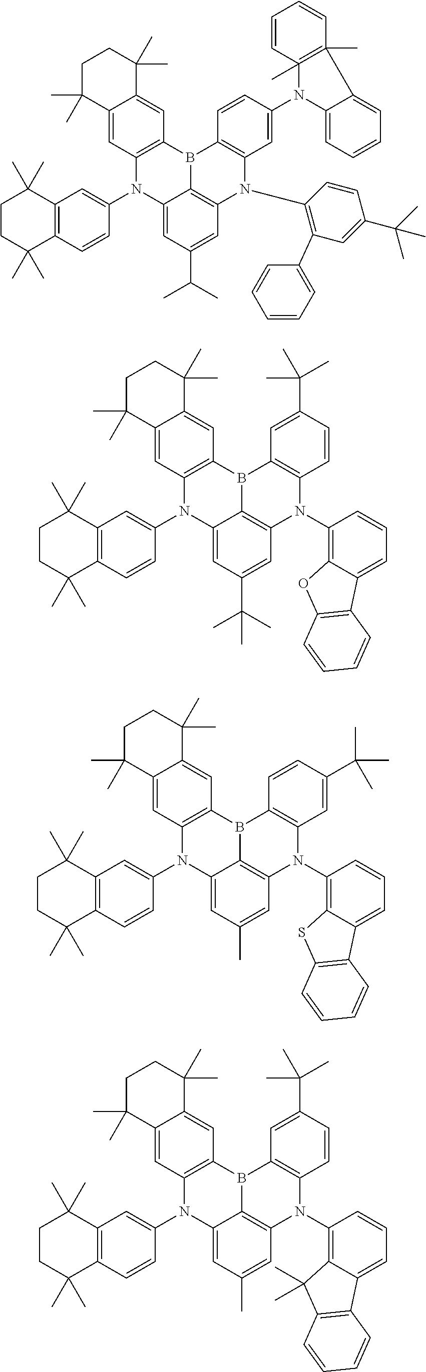

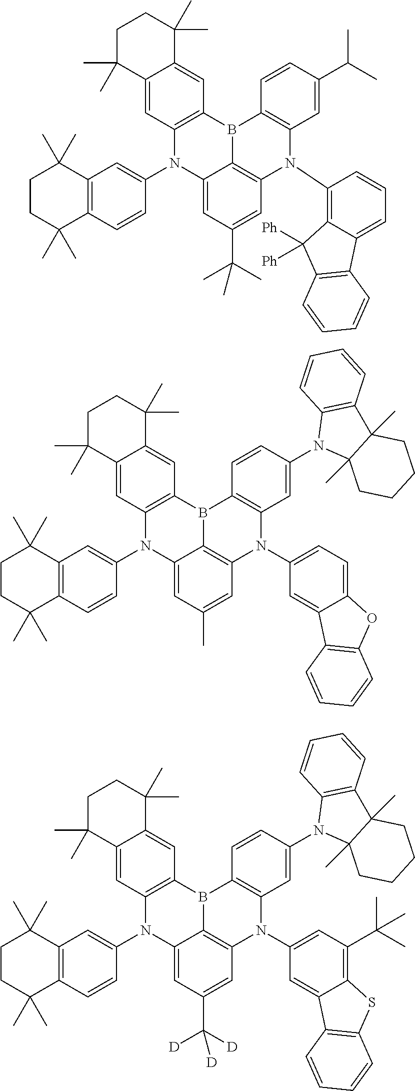

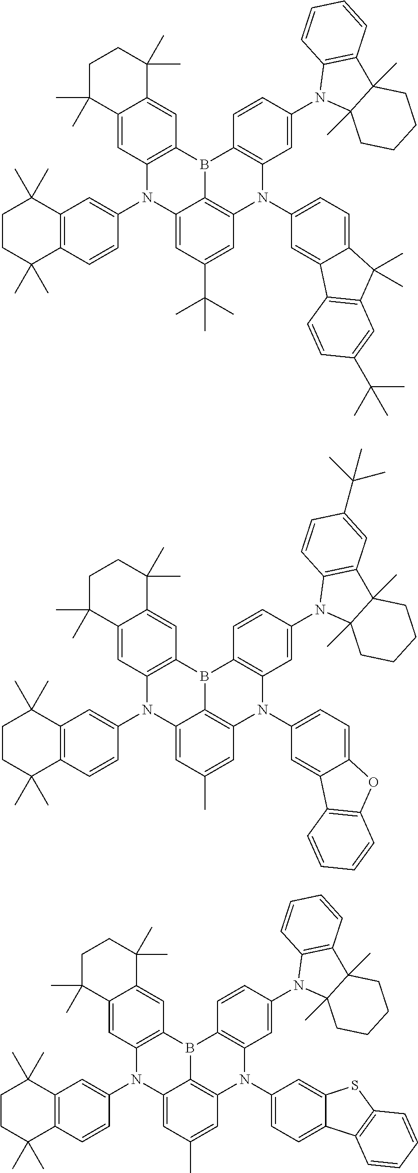

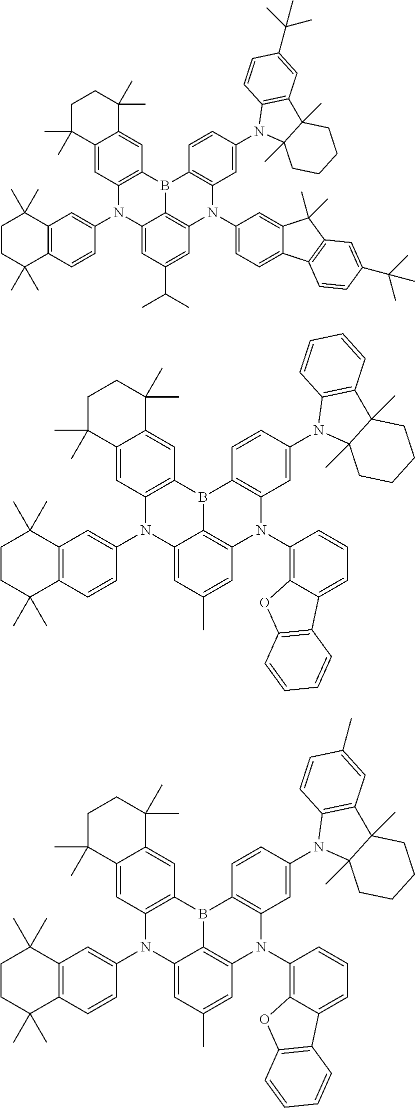

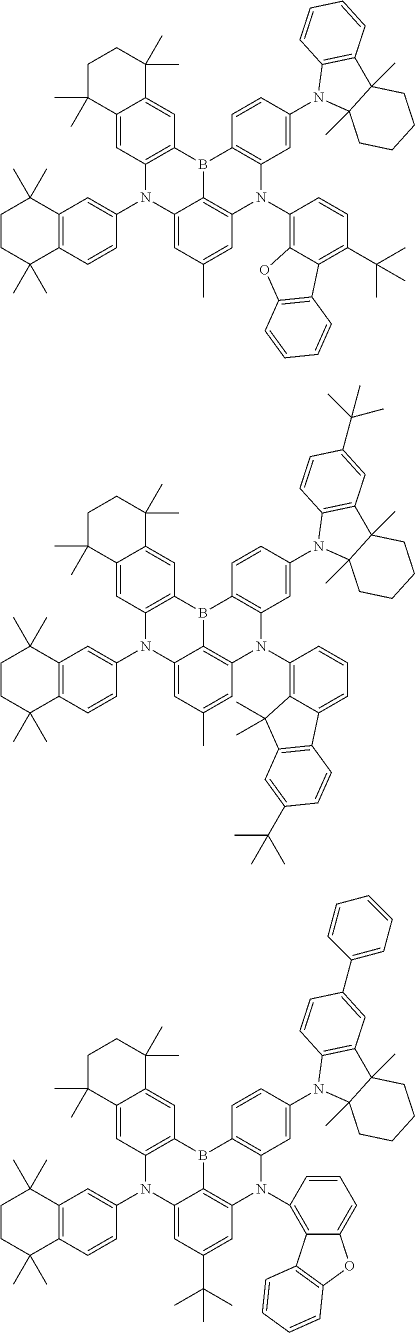

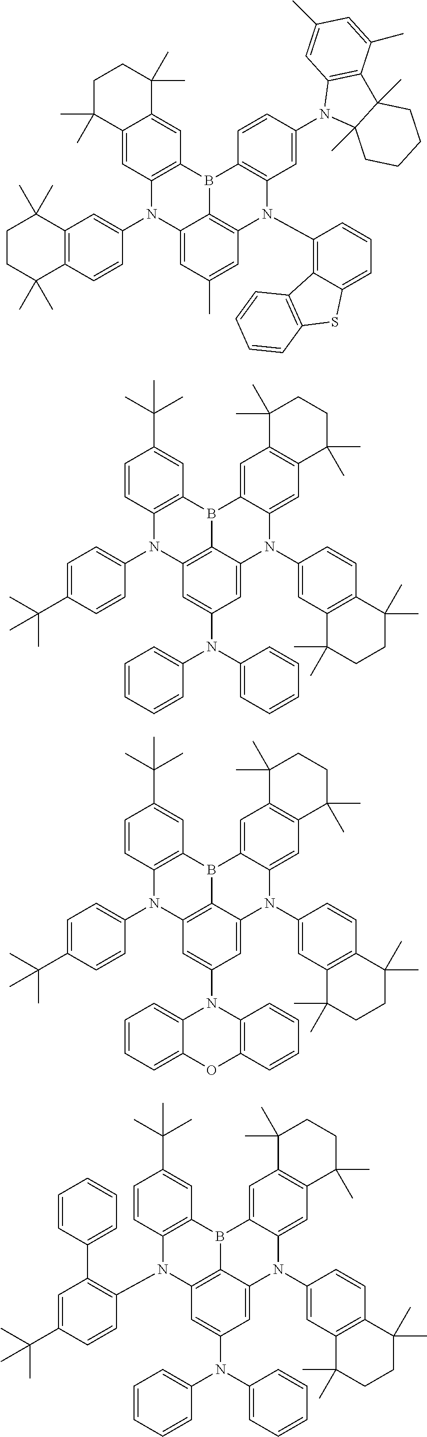

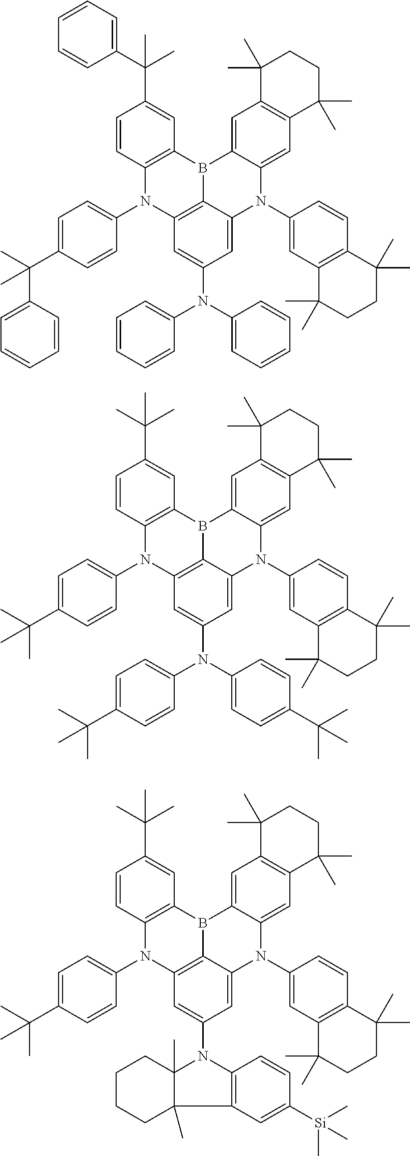

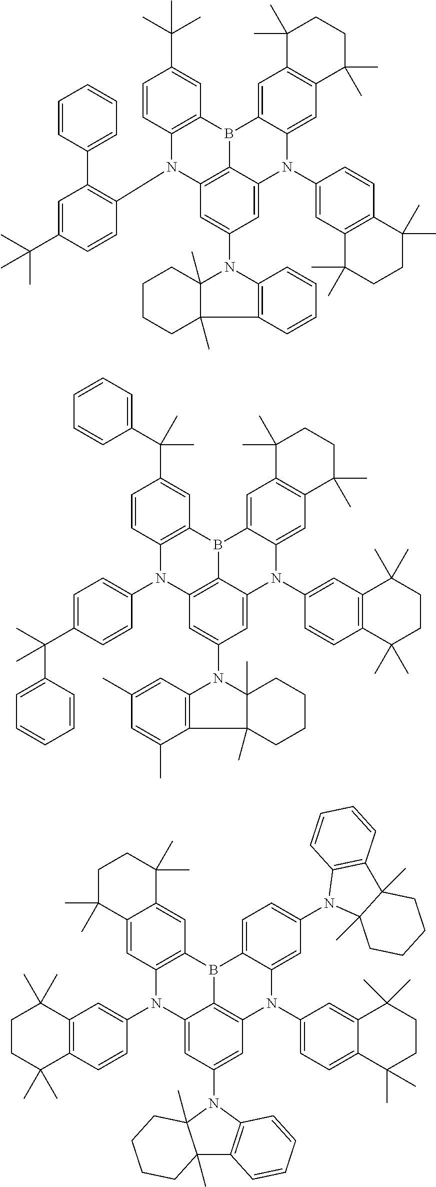

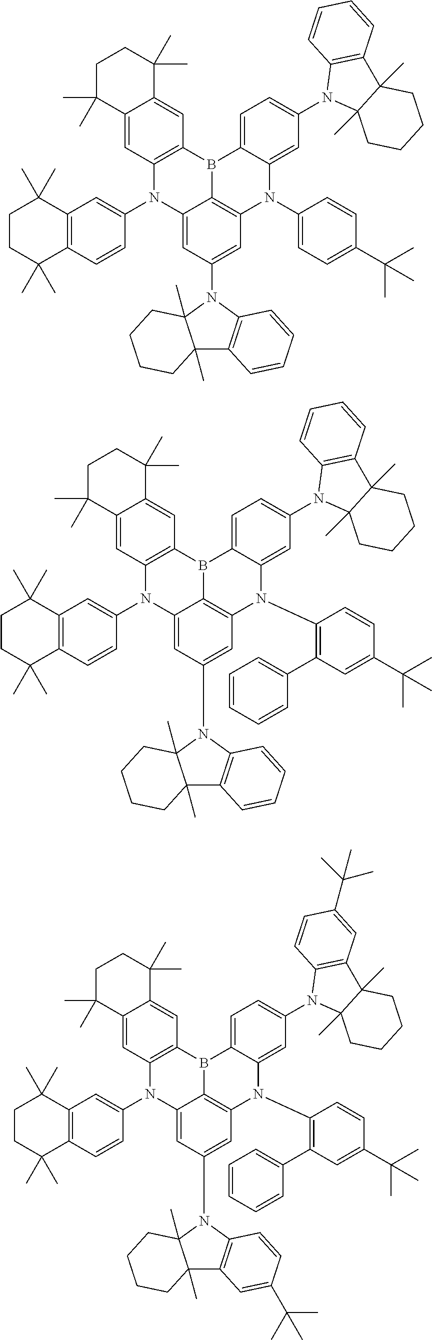 [SMILES: CC(C)(C)c1ccc(N2c3cc(N4c5ccccc5C5(C)CCCCC45C)ccc3B3c4cc5c(cc4N(c4ccc6c(c4)C(C)(C)CCC6(C)C)c4cc(N6c7ccccc7C7(C)CCCCC67C)cc2c43)C(C)(C)CCC5(C)C)cc1 ; CC(C)(C)c1ccc(N2c3cc(N4c5ccccc5C5(C)CCCCC45C)ccc3B3c4cc5c(cc4N(c4ccc6c(c4)C(C)(C)CCC6(C)C)c4cc(N6c7ccccc7C7(C)CCCCC67C)cc2c43)C(C)(C)CCC5(C)C)c(-c2ccccc2)c1 ; CC(C)(C)c1ccc(N2c3cc(N4c5ccc(C(C)(C)C)cc5C5(C)CCCCC45C)ccc3B3c4cc5c(cc4N(c4ccc6c(c4)C(C)(C)CCC6(C)C)c4cc(N6c7ccc(C(C)(C)C)cc7C7(C)CCCCC67C)cc2c43)C(C)(C)CCC5(C)C)c(-c2ccccc2)c1]

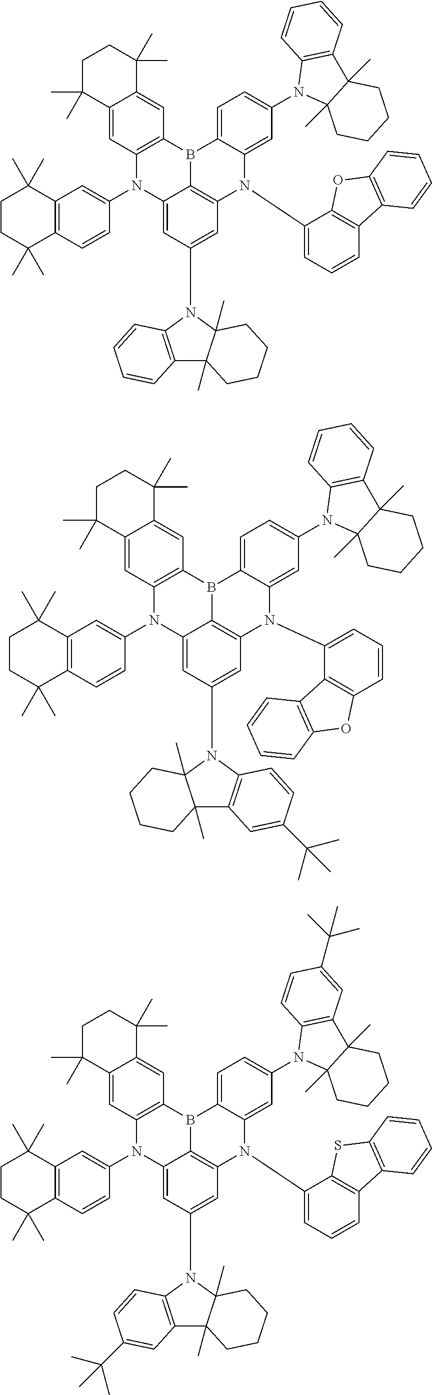

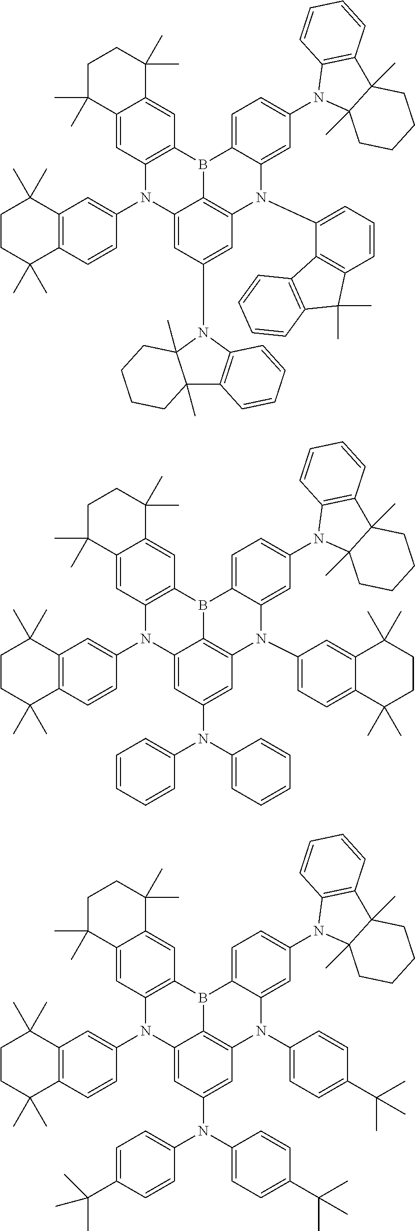 [SMILES: CC1(C)CCC(C)(C)c2cc(N3c4cc5c(cc4B4c6ccc(N7c8ccccc8C8(C)CCCCC78C)cc6N(c6cccc7c6-c6ccccc6C7(C)C)c6cc(N7c8ccccc8C8(C)CCCCC78C)cc3c64)C(C)(C)CCC5(C)C)ccc21 ; CC1(C)CCC(C)(C)c2cc(N3c4cc(N5c6ccccc6C6(C)CCCCC56C)ccc4B4c5cc6c(cc5N(c5ccc7c(c5)C(C)(C)CCC7(C)C)c5cc(N(c7ccccc7)c7ccccc7)cc3c54)C(C)(C)CCC6(C)C)ccc21 ; CC(C)(C)c1ccc(N(c2ccc(C(C)(C)C)cc2)c2cc3c4c(c2)N(c2ccc5c(c2)C(C)(C)CCC5(C)C)c2cc5c(cc2B4c2ccc(N4c6ccccc6C6(C)CCCCC46C)cc2N3c2ccc(C(C)(C)C)cc2)C(C)(C)CCC5(C)C)cc1]

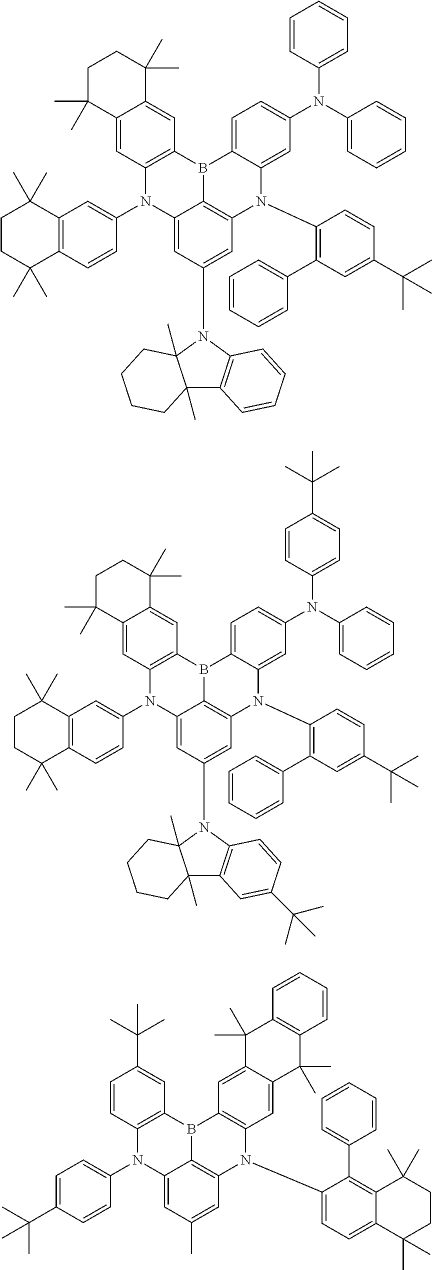

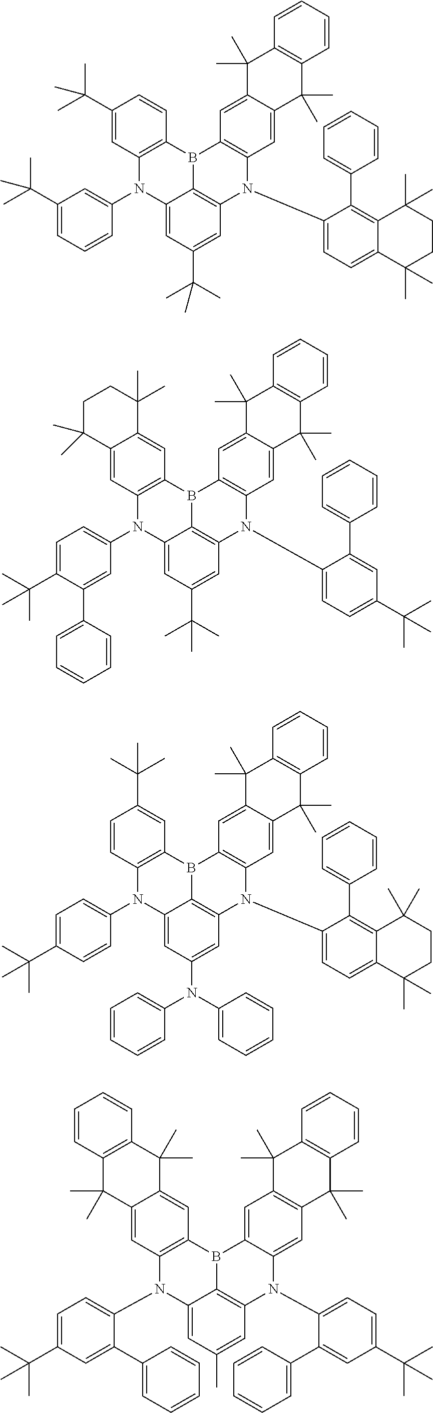

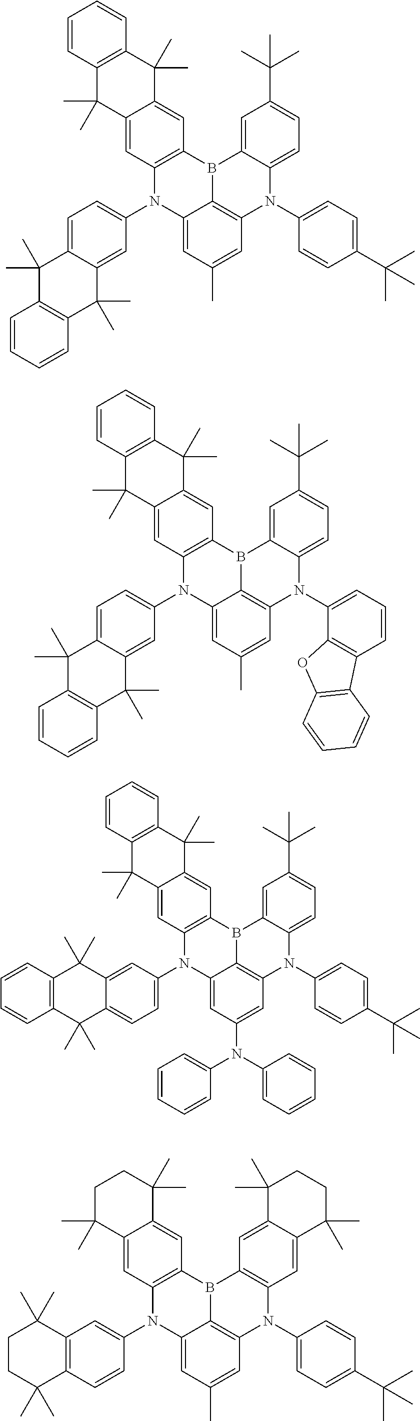

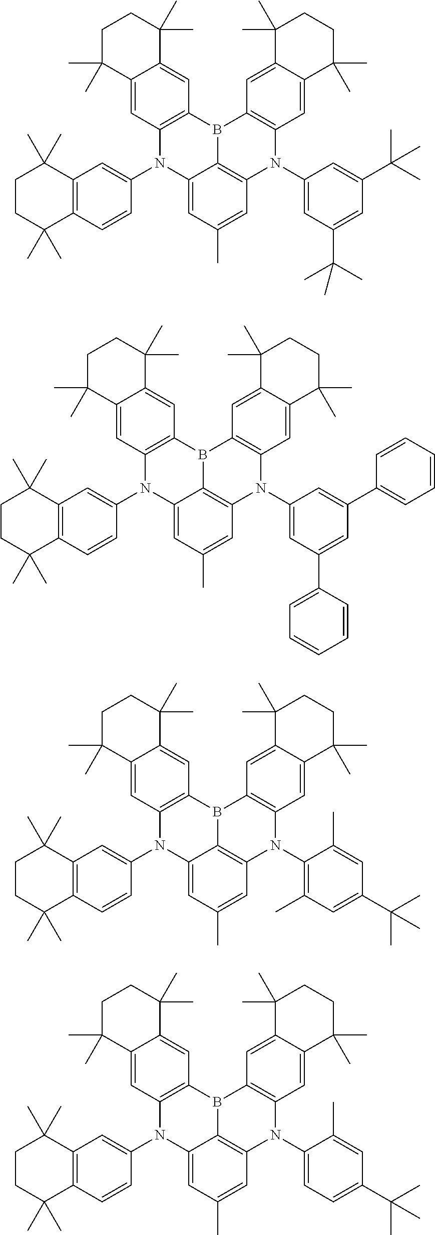

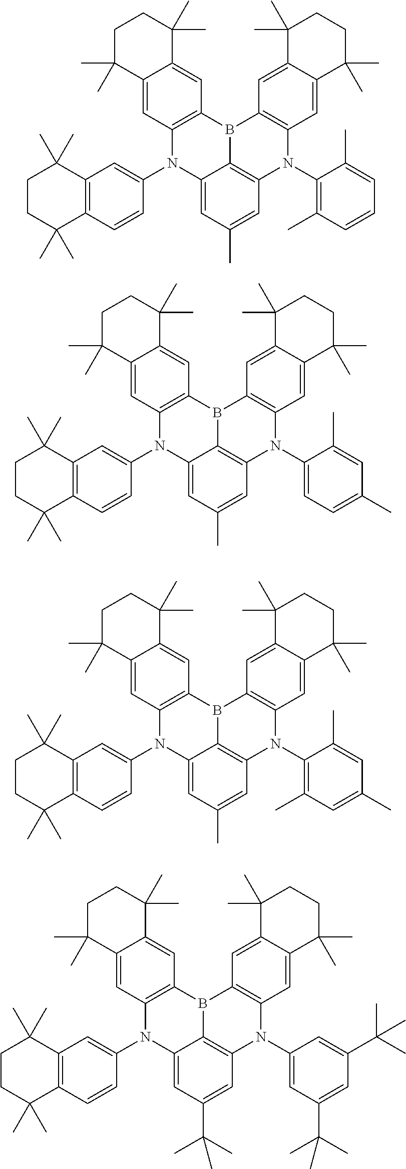

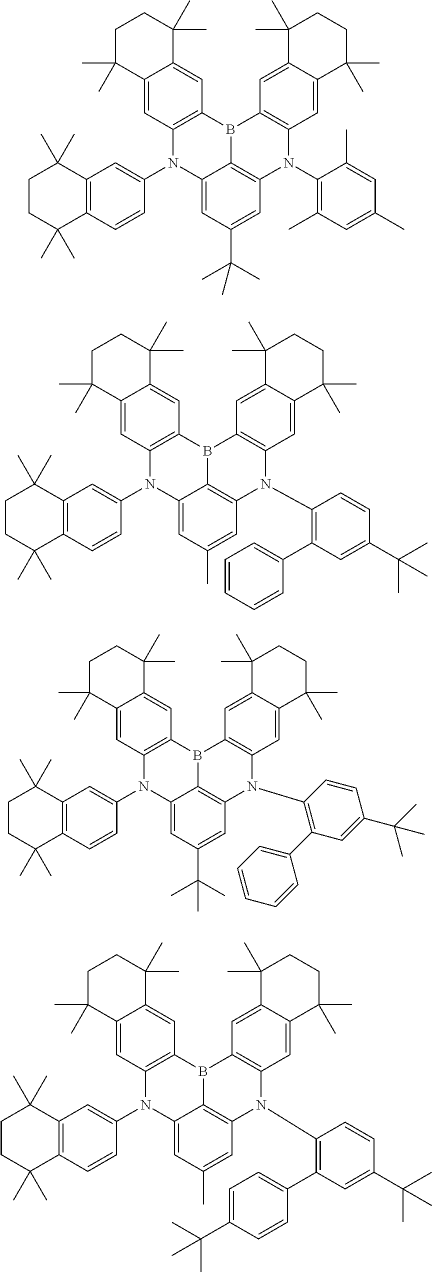

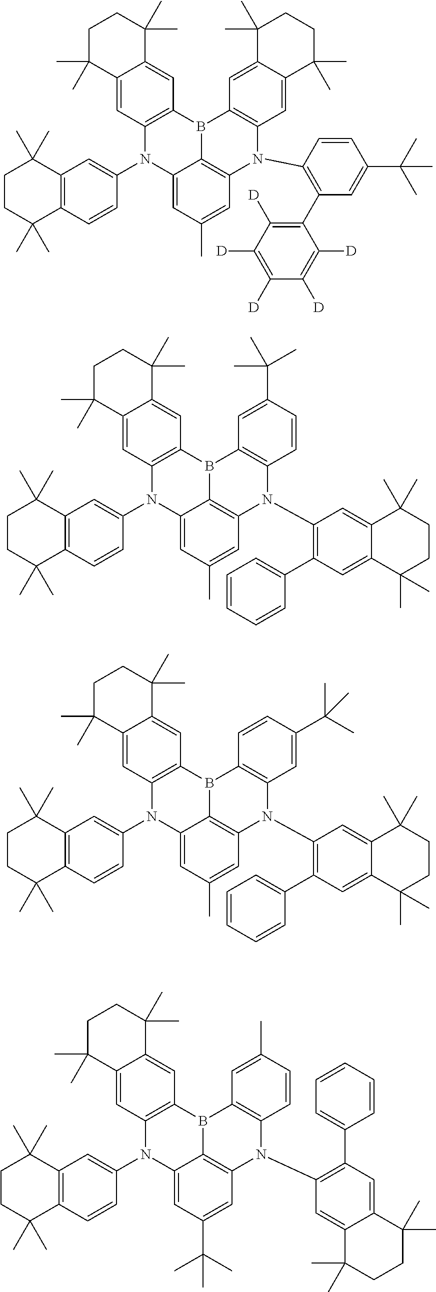

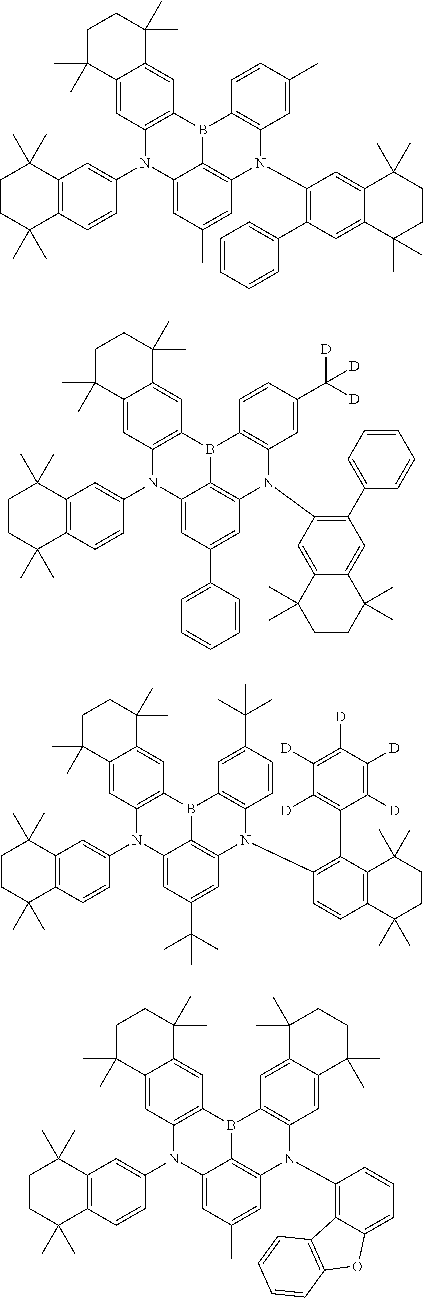

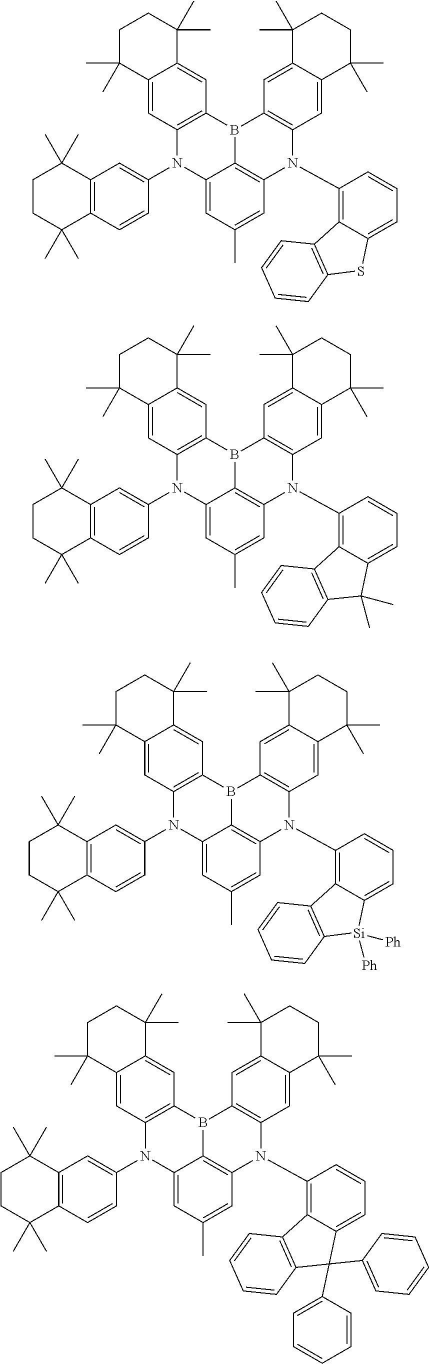

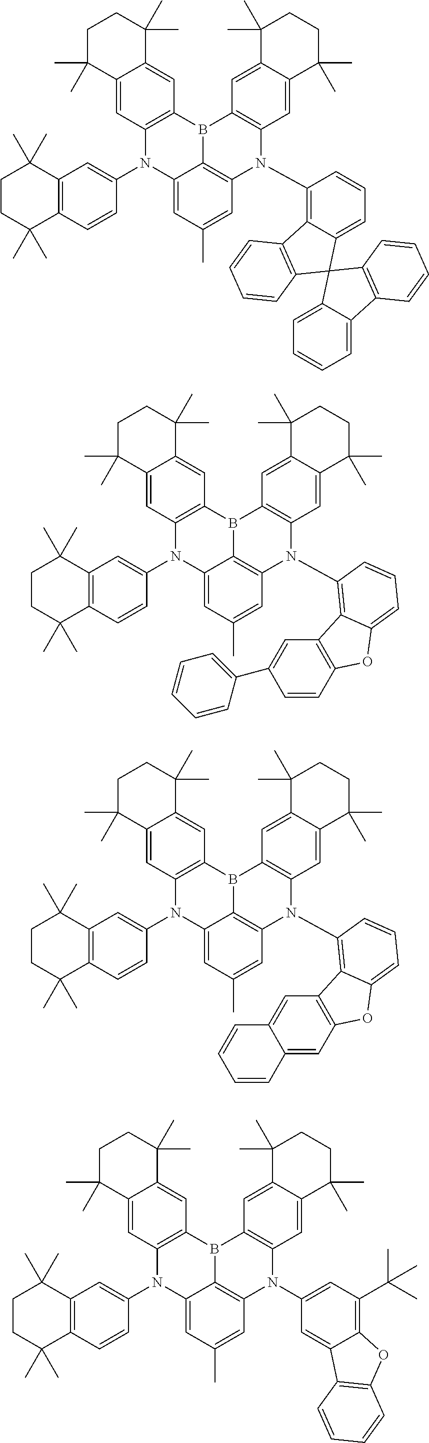

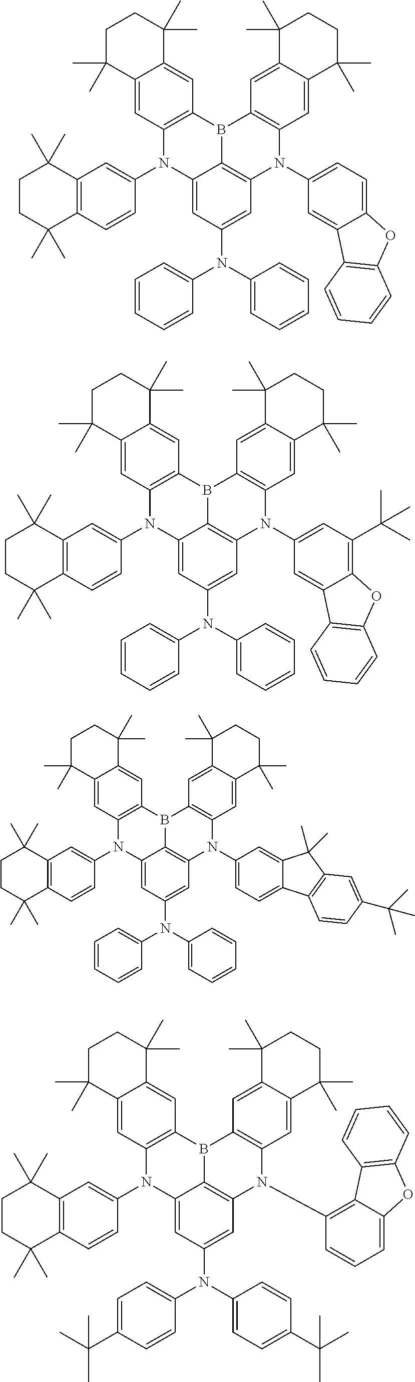

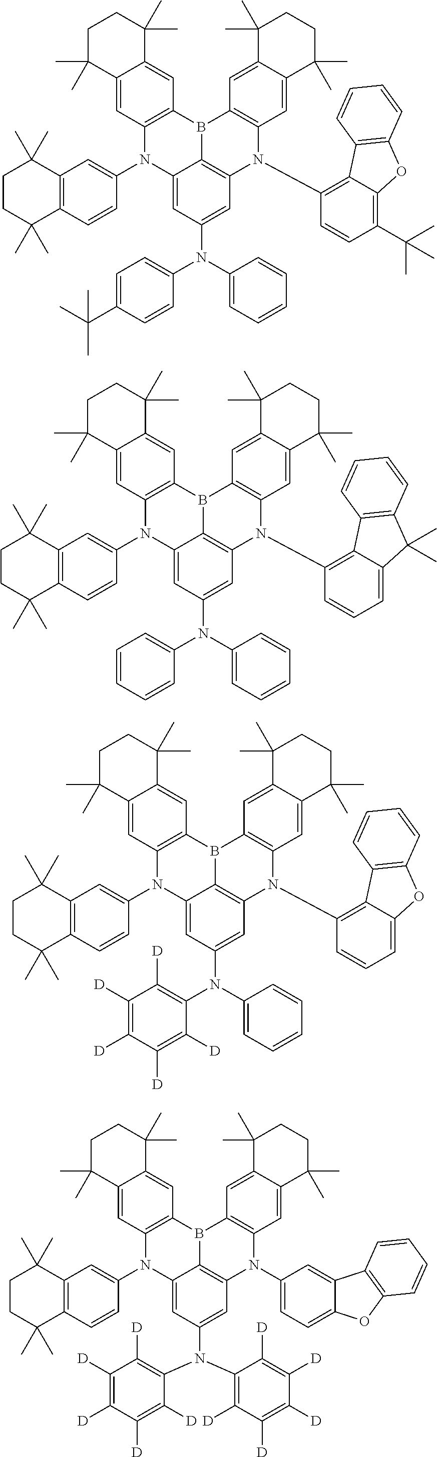

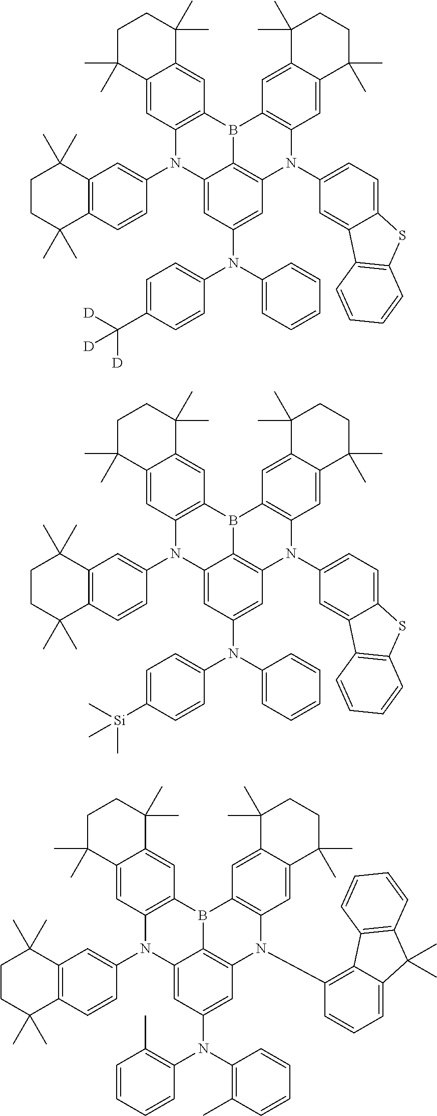

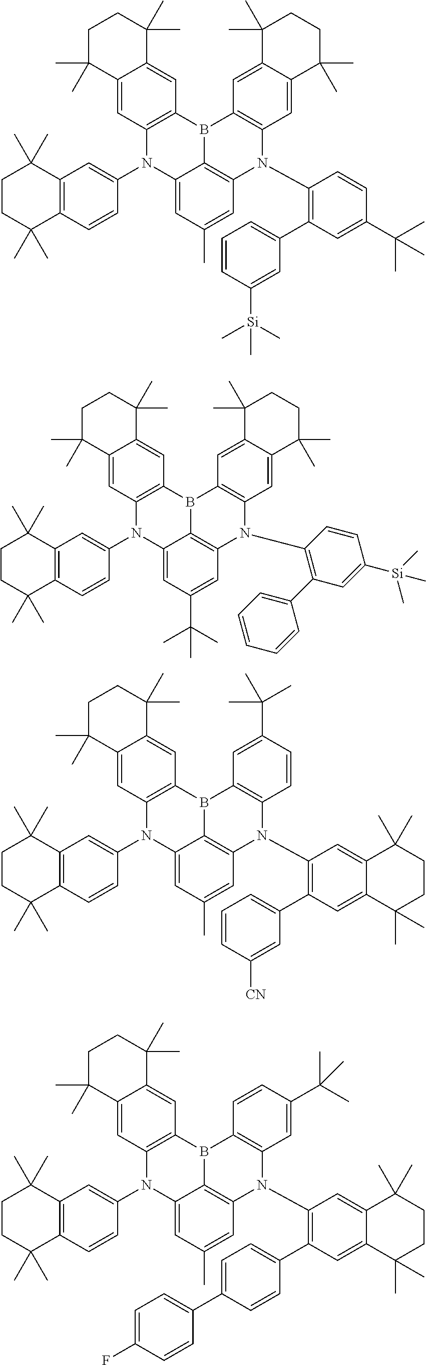

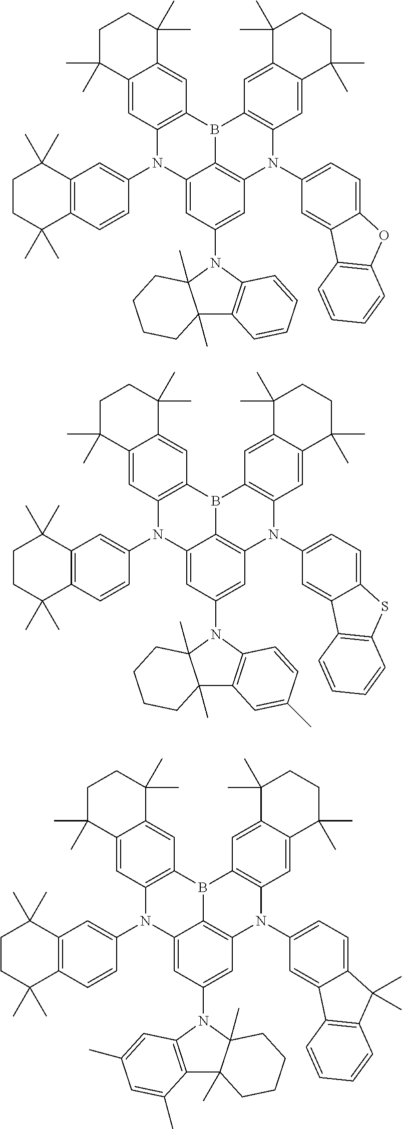

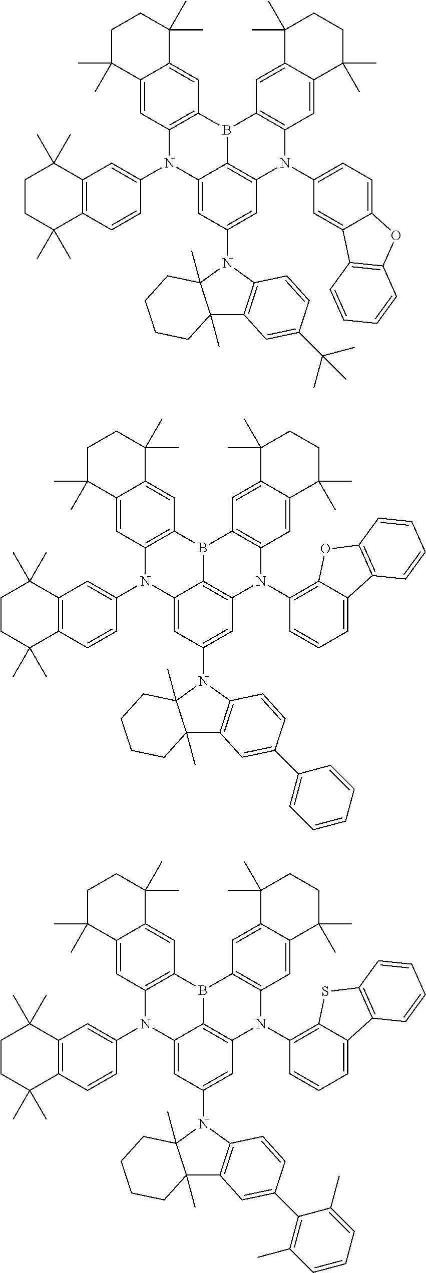 [SMILES: CC(C)(C)c1ccc2c(c1)C1(C)CCCCC1(C)N2c1cc2c3c(c1)N(c1ccc4oc5ccccc5c4c1)c1cc4c(cc1B3c1cc3c(cc1N2c1ccc2c(c1)C(C)(C)CCC2(C)C)C(C)(C)CCC3(C)C)C(C)(C)CCC4(C)C ; CC1(C)CCC(C)(C)c2cc(N3c4cc5c(cc4B4c6cc7c(cc6N(c6cccc8c6oc6ccccc68)c6cc(N8c9ccc(-c%10ccccc%10)cc9C9(C)CCCCC89C)cc3c64)C(C)(C)CCC7(C)C)C(C)(C)CCC5(C)C)ccc21 ; Cc1cccc(C)c1-c1ccc2c(c1)C1(C)CCCCC1(C)N2c1cc2c3c(c1)N(c1cccc4c1sc1ccccc14)c1cc4c(cc1B3c1cc3c(cc1N2c1ccc2c(c1)C(C)(C)CCC2(C)C)C(C)(C)CCC3(C)C)C(C)(C)CCC4(C)C]

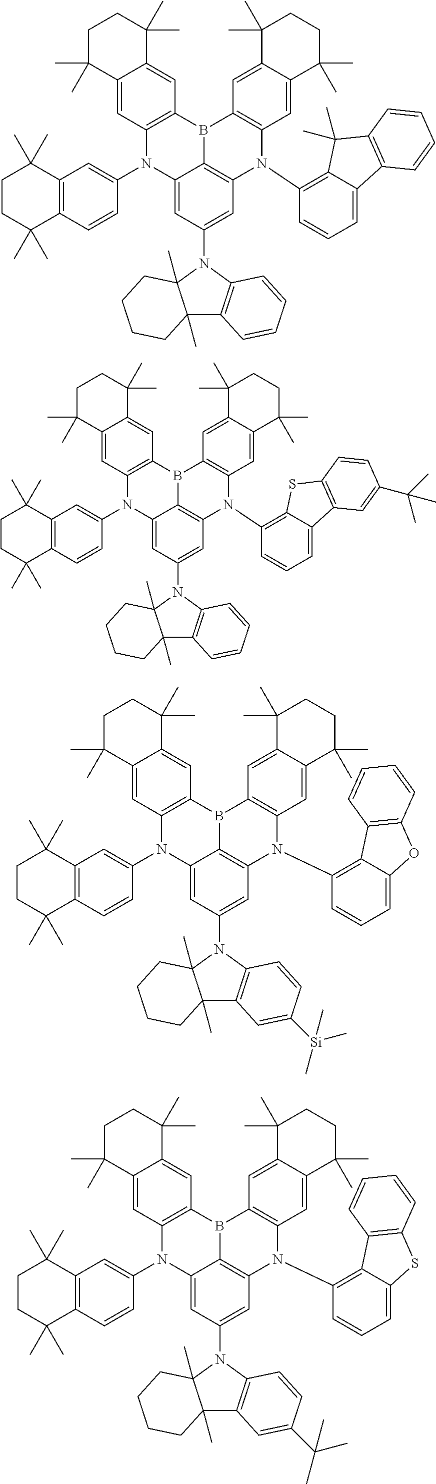

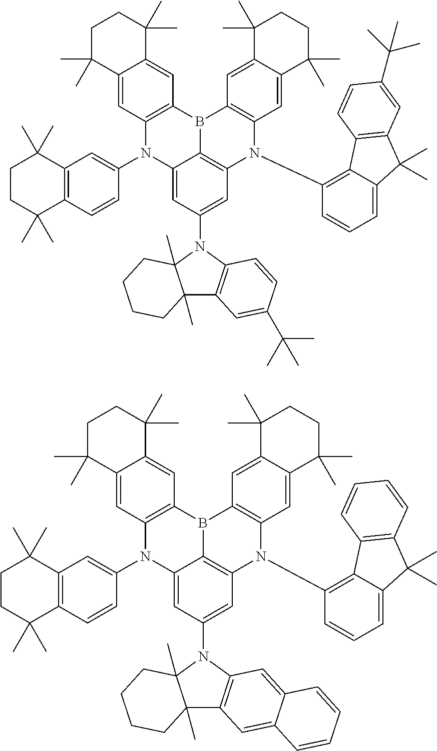

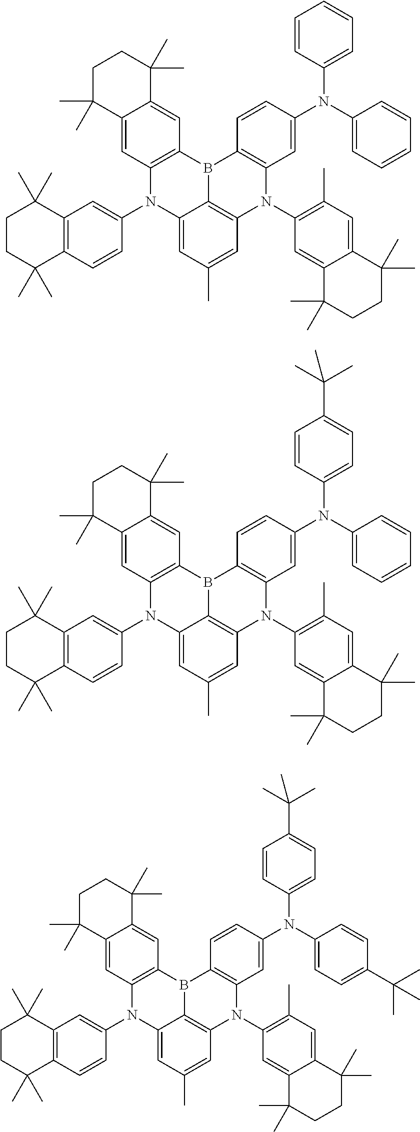

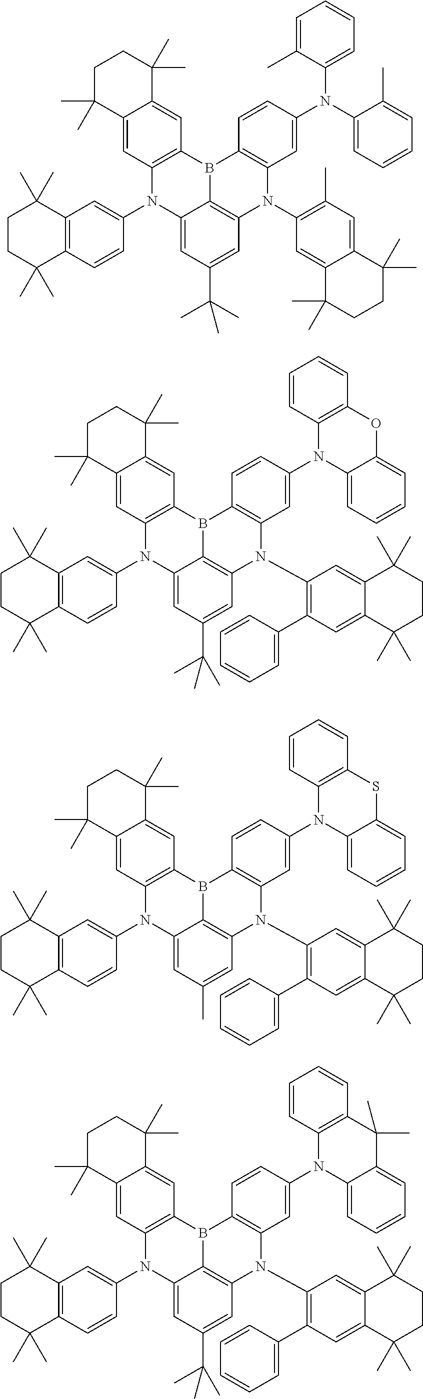

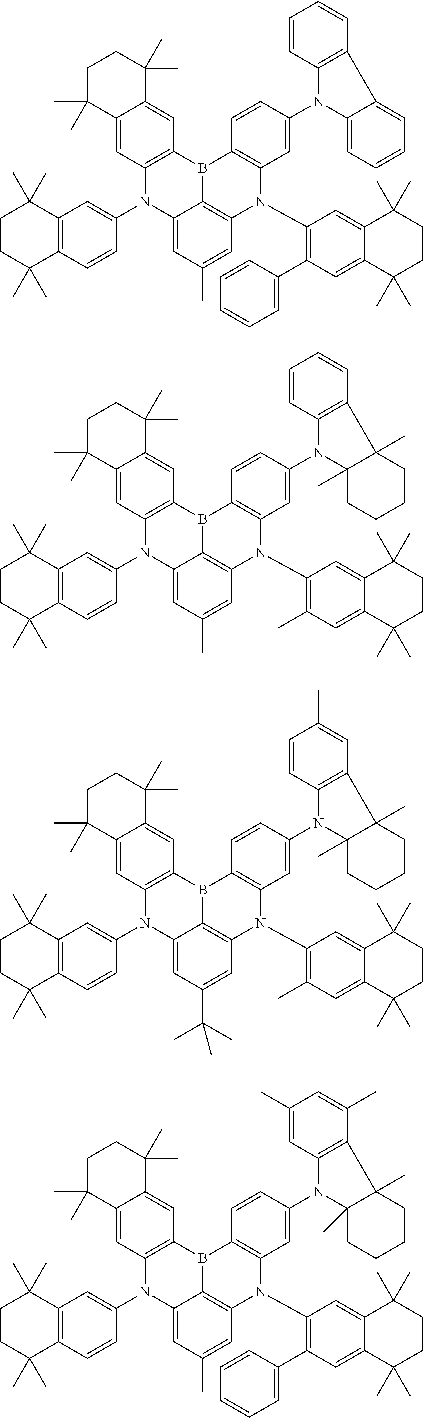

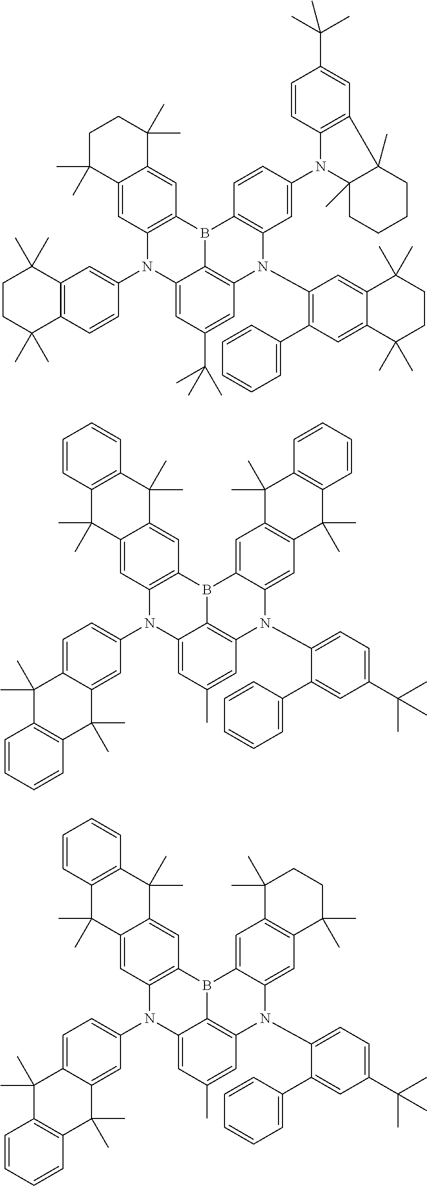

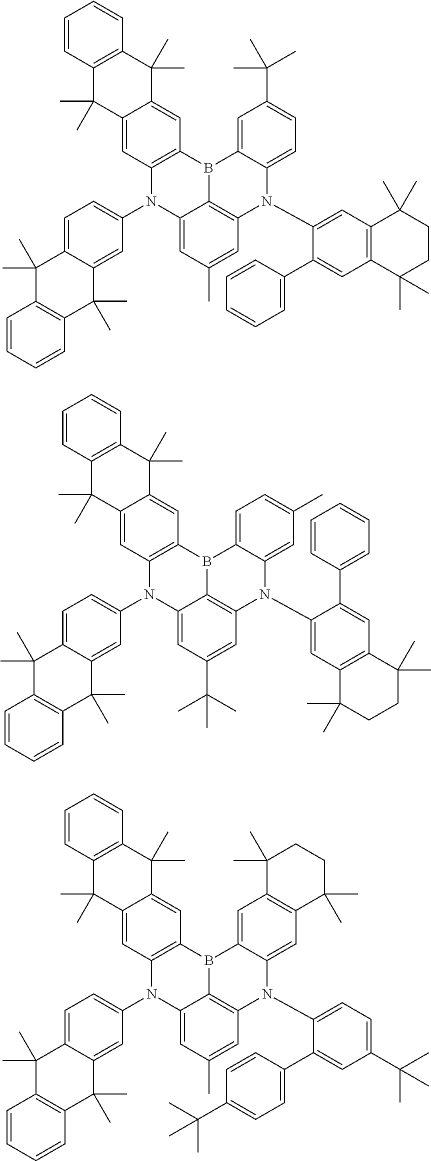

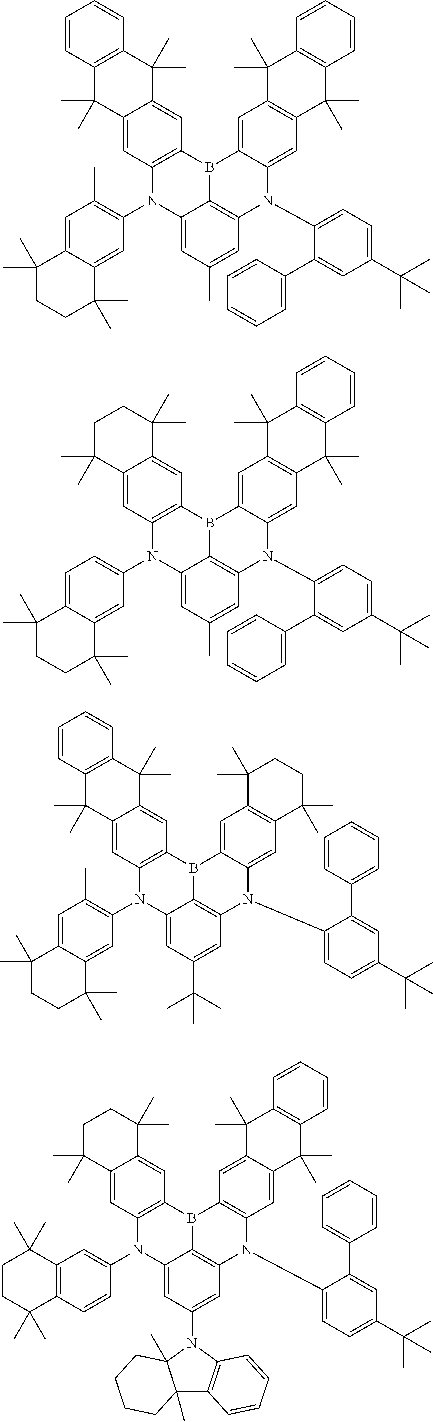

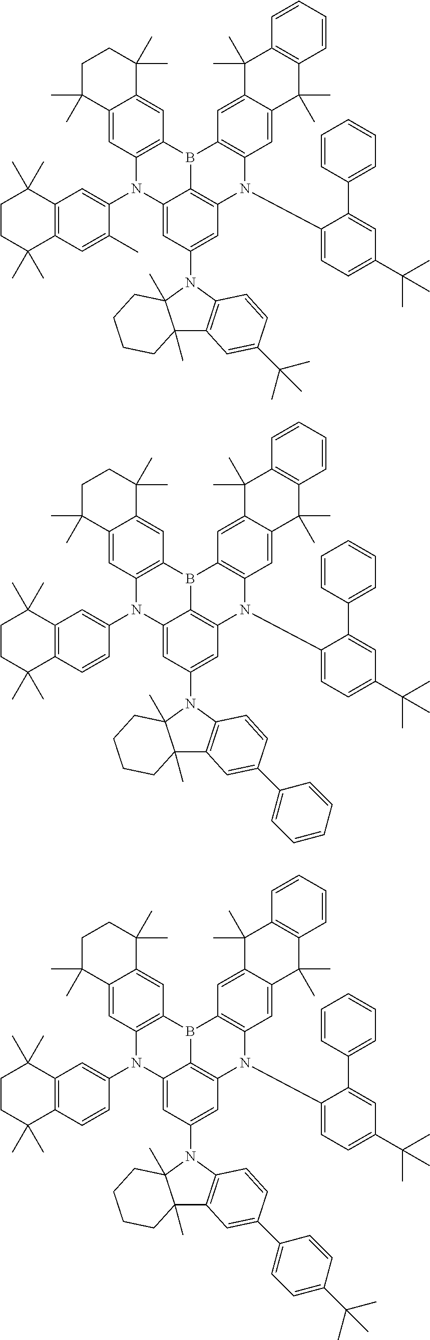

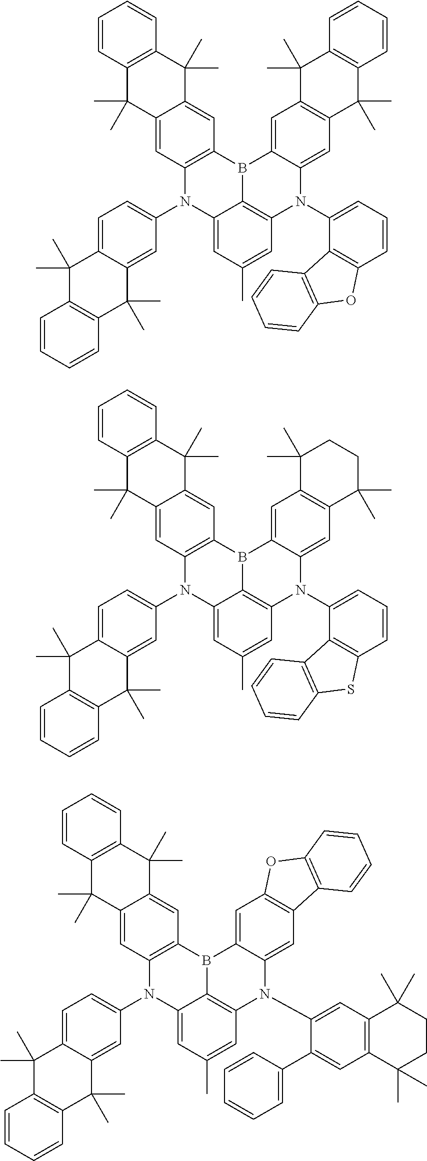

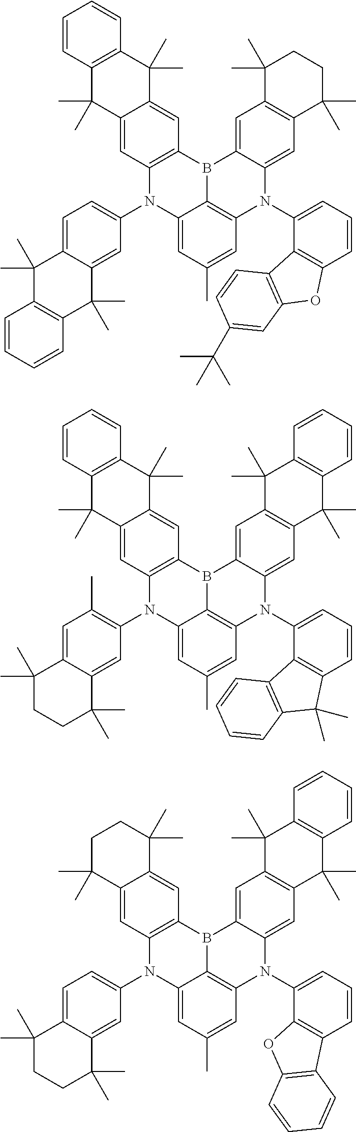

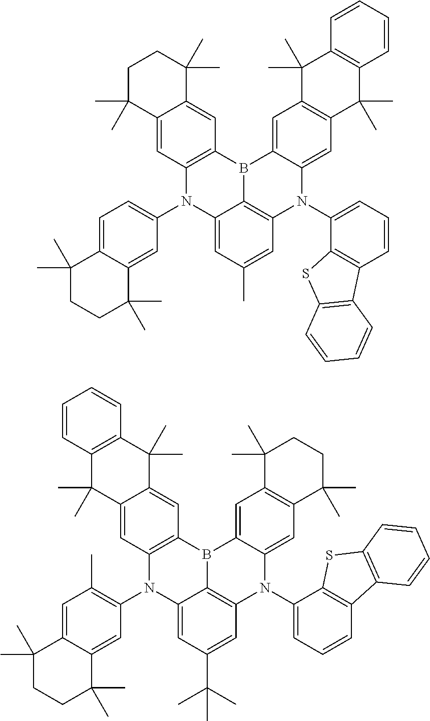

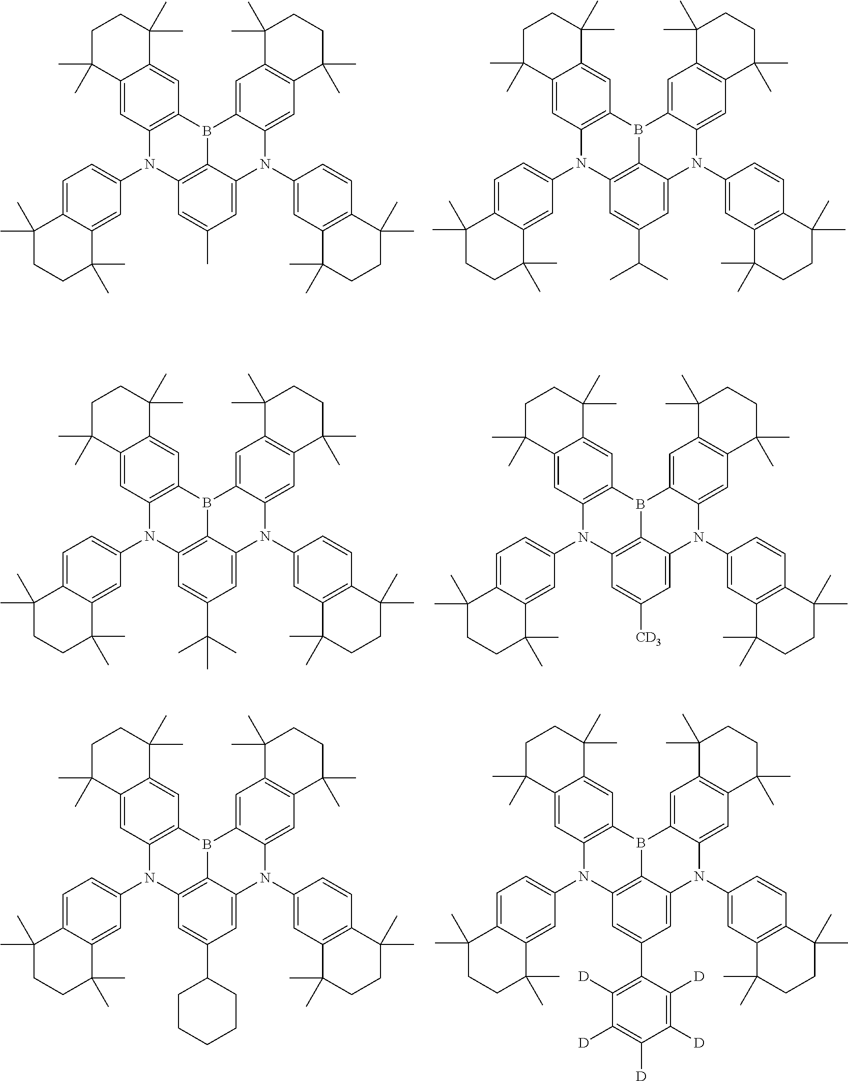

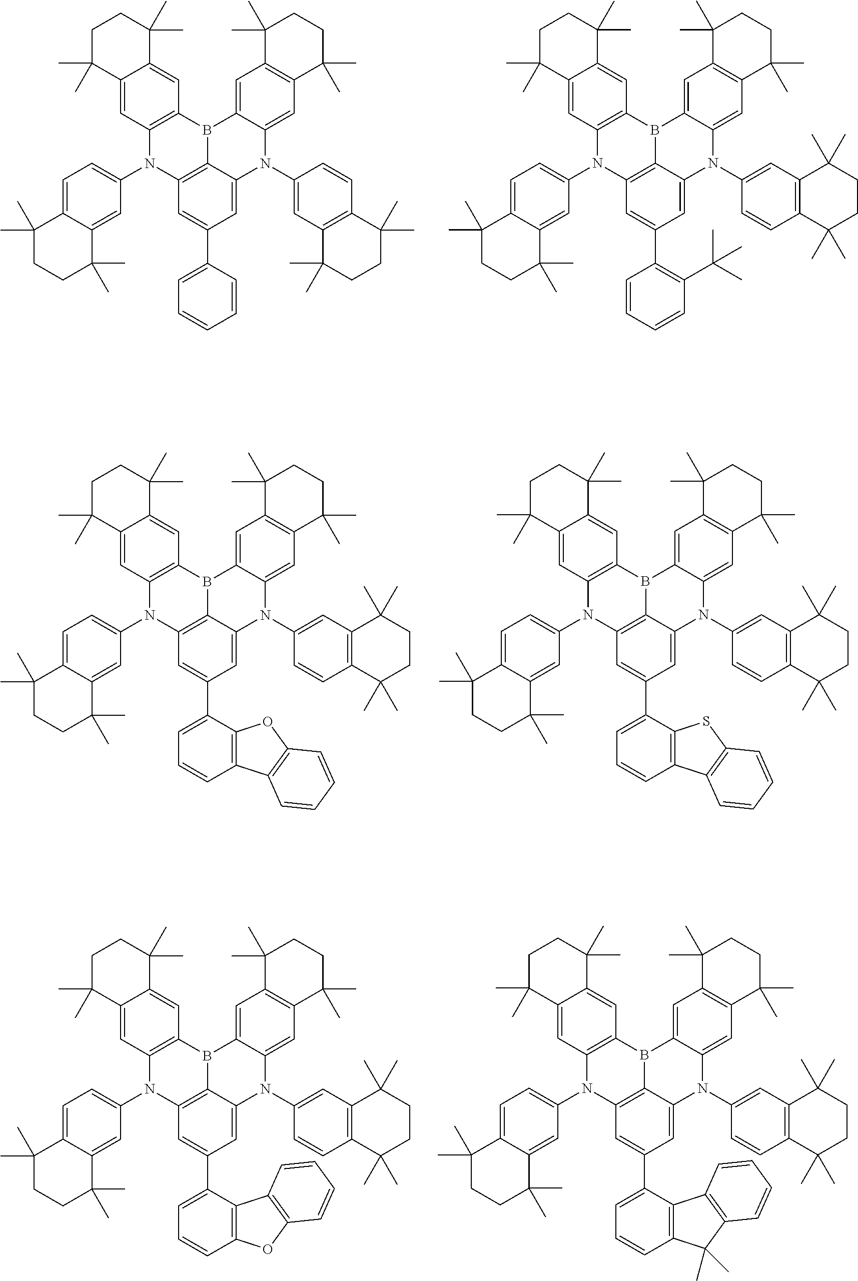

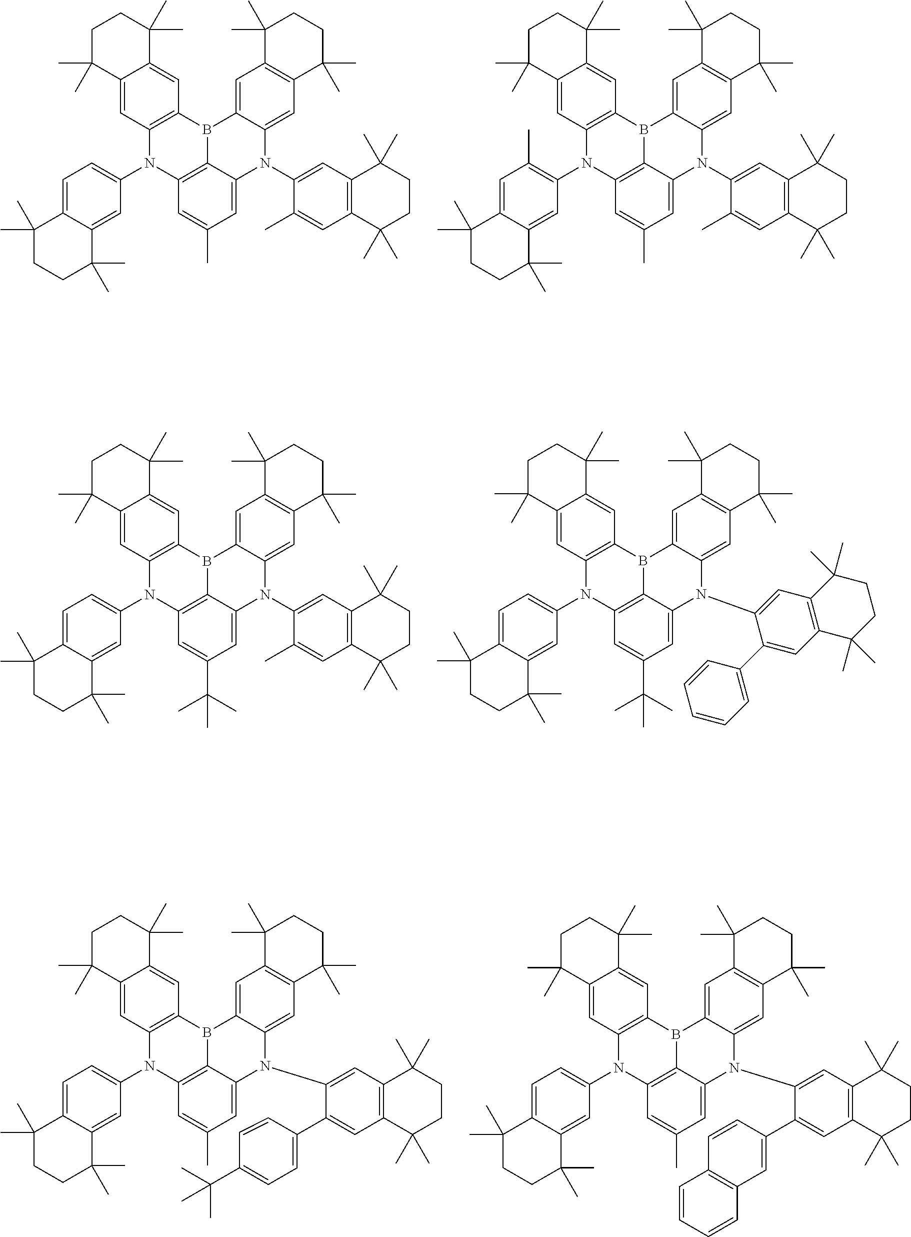

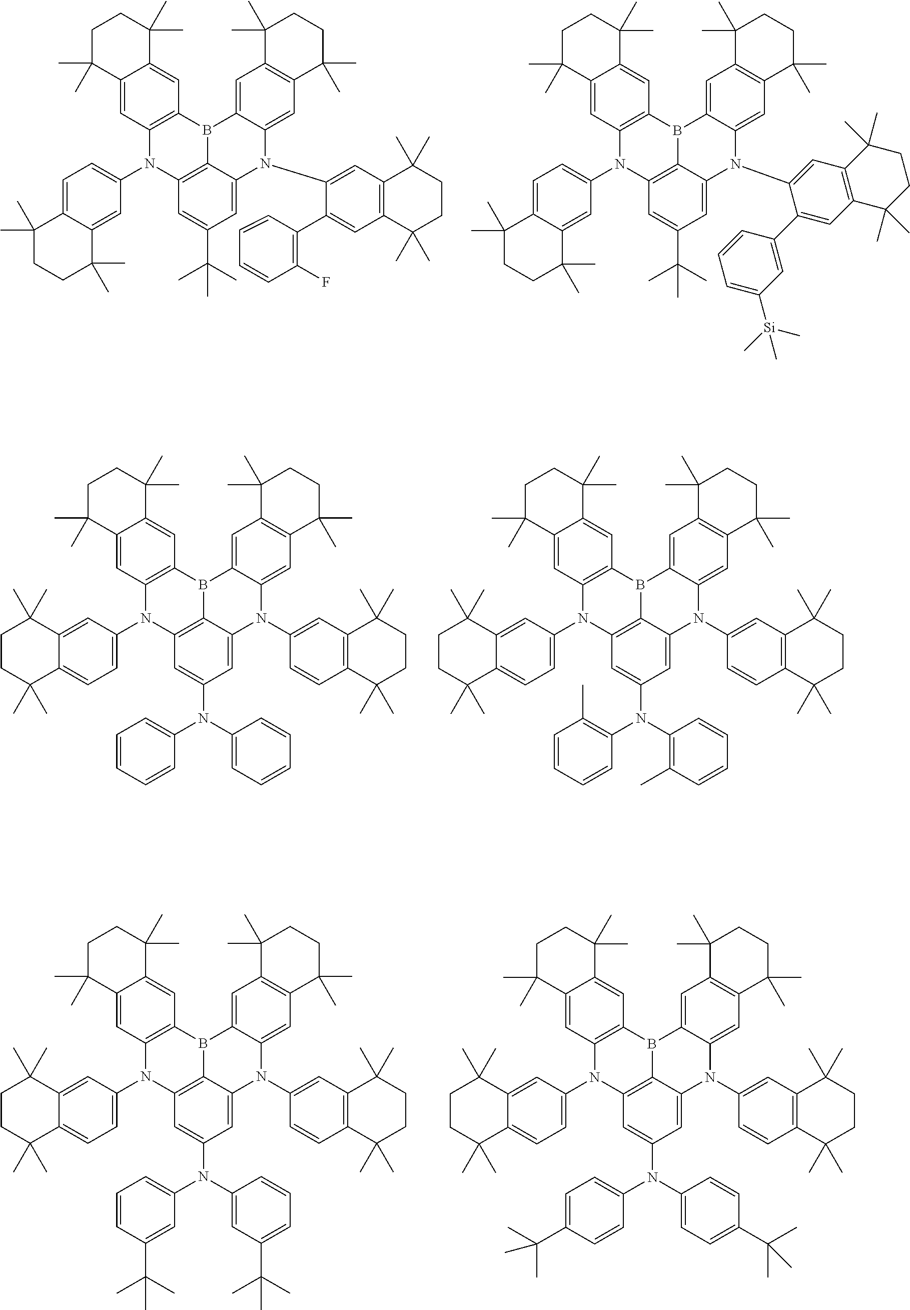

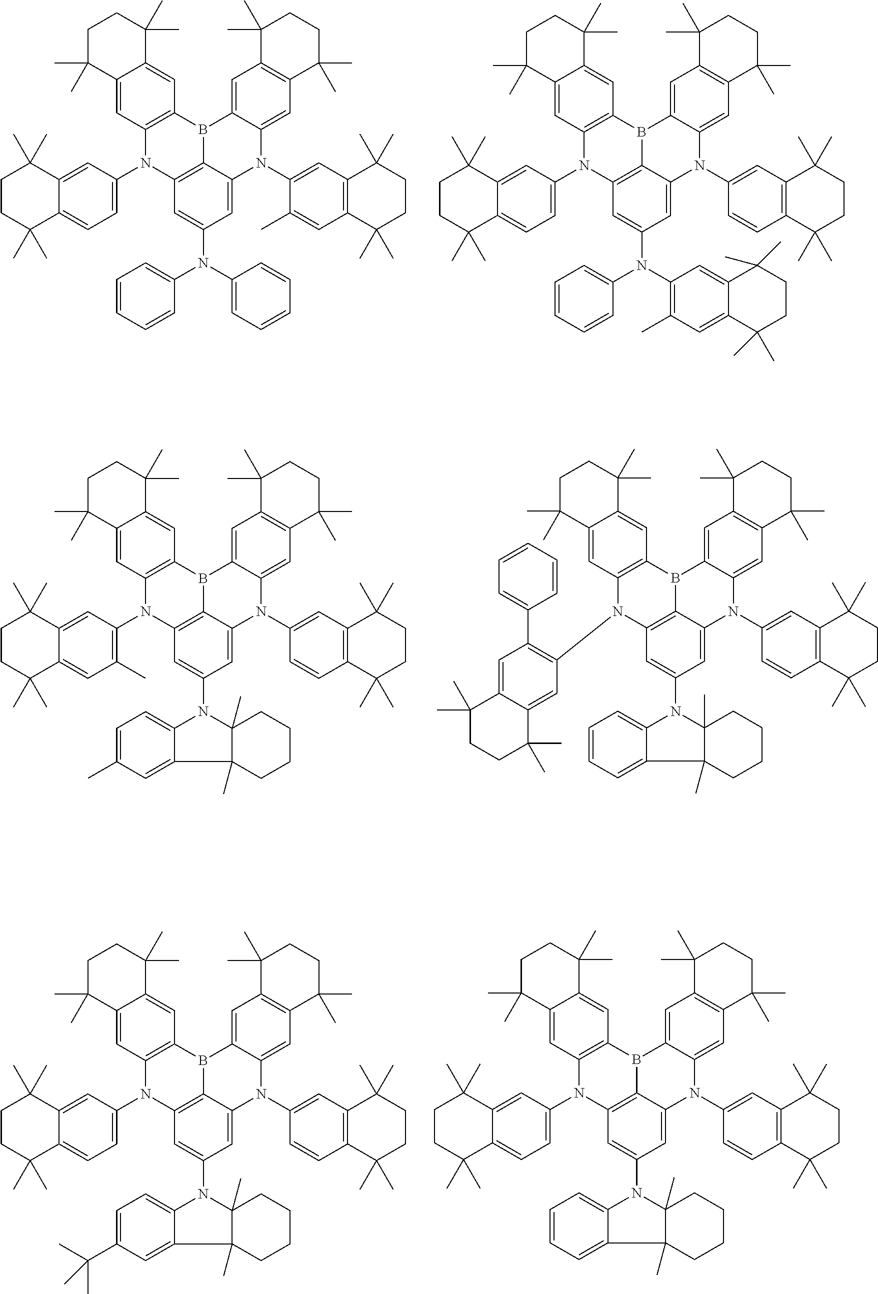

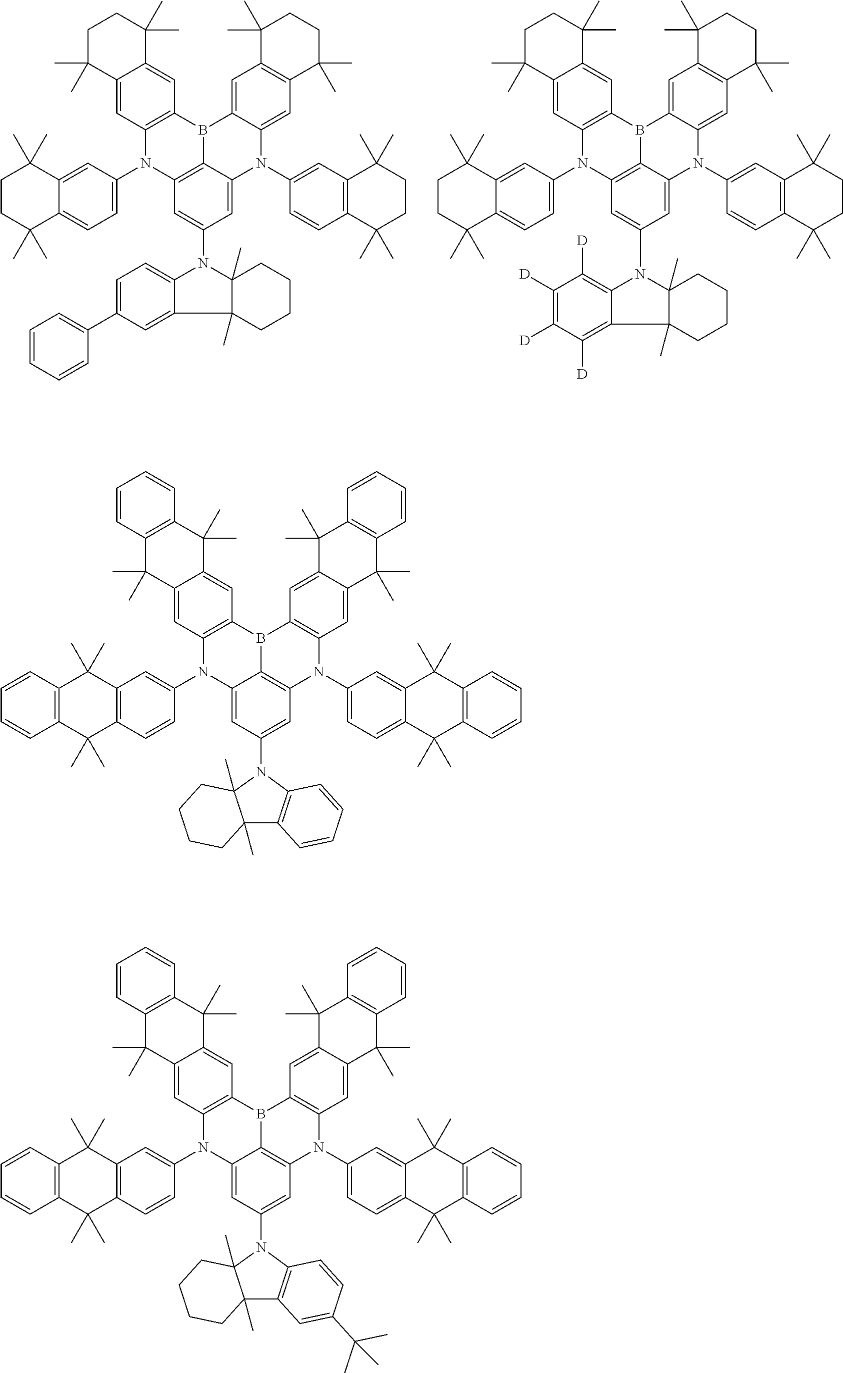

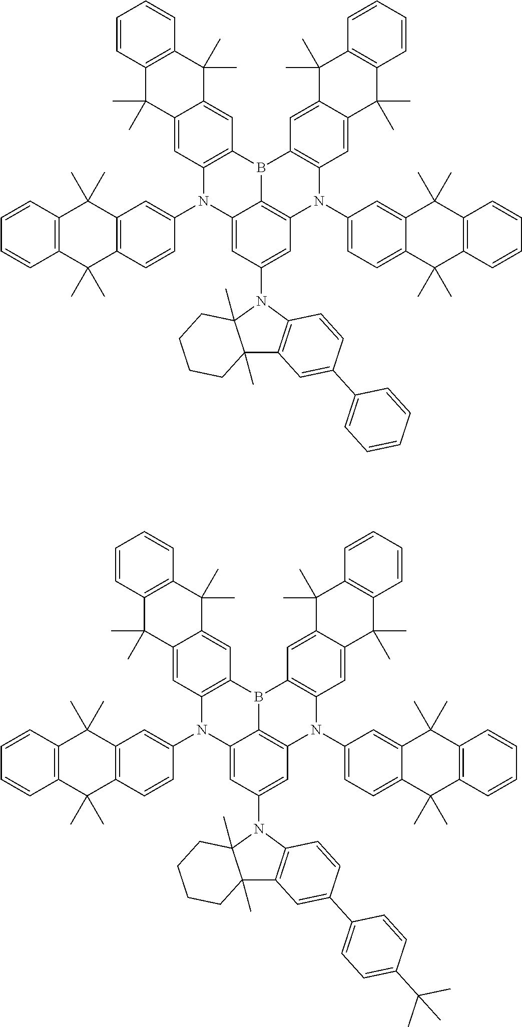 [SMILES: CC1(C)c2ccccc2C(C)(C)c2cc(N3c4cc5c(cc4B4c6cc7c(cc6N(c6ccc8c(c6)C(C)(C)c6ccccc6C8(C)C)c6cc(N8c9ccc(-c%10ccccc%10)cc9C9(C)CCCCC89C)cc3c64)C(C)(C)c3ccccc3C7(C)C)C(C)(C)c3ccccc3C5(C)C)ccc21 ; CC(C)(C)c1ccc(-c2ccc3c(c2)C2(C)CCCCC2(C)N3c2cc3c4c(c2)N(c2ccc5c(c2)C(C)(C)c2ccccc2C5(C)C)c2cc5c(cc2B4c2cc4c(cc2N3c2ccc3c(c2)C(C)(C)c2ccccc2C3(C)C)C(C)(C)c2ccccc2C4(C)C)C(C)(C)c2ccccc2C5(C)C)cc1]

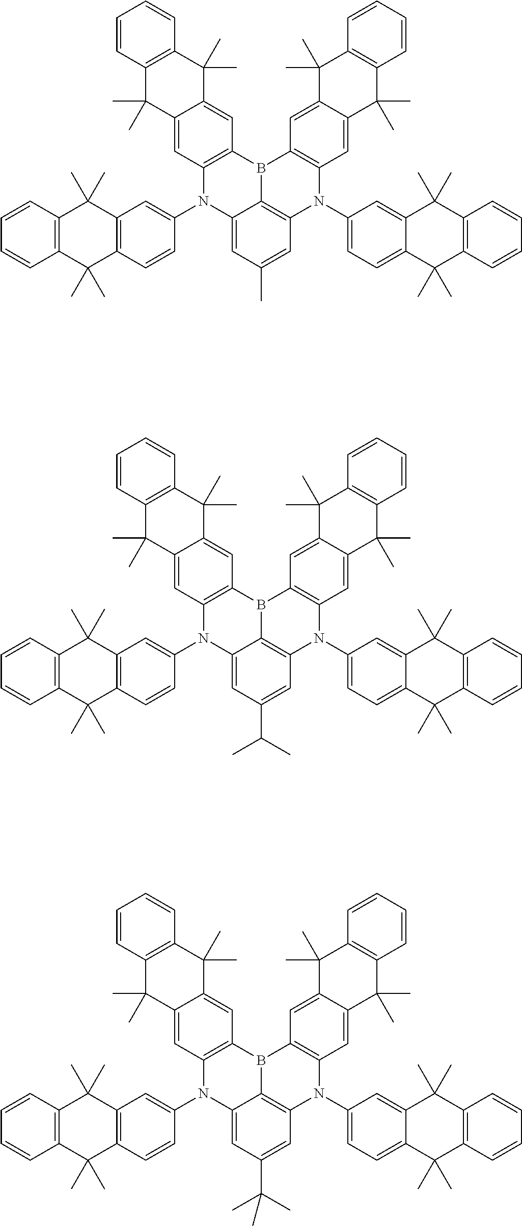 [SMILES: Cc1cc2c3c(c1)N(c1ccc4c(c1)C(C)(C)c1ccccc1C4(C)C)c1cc4c(cc1B3c1cc3c(cc1N2c1ccc2c(c1)C(C)(C)c1ccccc1C2(C)C)C(C)(C)c1ccccc1C3(C)C)C(C)(C)c1ccccc1C4(C)C ; CC(C)c1cc2c3c(c1)N(c1ccc4c(c1)C(C)(C)c1ccccc1C4(C)C)c1cc4c(cc1B3c1cc3c(cc1N2c1ccc2c(c1)C(C)(C)c1ccccc1C2(C)C)C(C)(C)c1ccccc1C3(C)C)C(C)(C)c1ccccc1C4(C)C ; CC(C)(C)c1cc2c3c(c1)N(c1ccc4c(c1)C(C)(C)c1ccccc1C4(C)C)c1cc4c(cc1B3c1cc3c(cc1N2c1ccc2c(c1)C(C)(C)c1ccccc1C2(C)C)C(C)(C)c1ccccc1C3(C)C)C(C)(C)c1ccccc1C4(C)C]

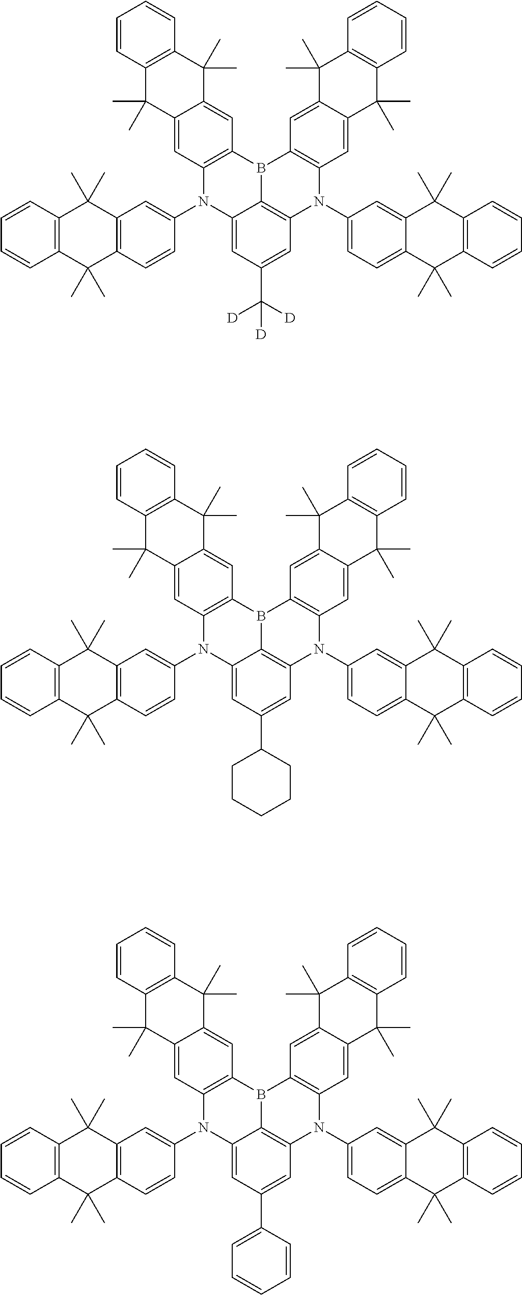 [SMILES: [2H]C([2H])([2H])c1cc2c3c(c1)N(c1ccc4c(c1)C(C)(C)c1ccccc1C4(C)C)c1cc4c(cc1B3c1cc3c(cc1N2c1ccc2c(c1)C(C)(C)c1ccccc1C2(C)C)C(C)(C)c1ccccc1C3(C)C)C(C)(C)c1ccccc1C4(C)C ; CC1(C)c2ccccc2C(C)(C)c2cc(N3c4cc5c(cc4B4c6cc7c(cc6N(c6ccc8c(c6)C(C)(C)c6ccccc6C8(C)C)c6cc(C8CCCCC8)cc3c64)C(C)(C)c3ccccc3C7(C)C)C(C)(C)c3ccccc3C5(C)C)ccc21 ; CC1(C)c2ccccc2C(C)(C)c2cc(N3c4cc5c(cc4B4c6cc7c(cc6N(c6ccc8c(c6)C(C)(C)c6ccccc6C8(C)C)c6cc(-c8ccccc8)cc3c64)C(C)(C)c3ccccc3C7(C)C)C(C)(C)c3ccccc3C5(C)C)ccc21]

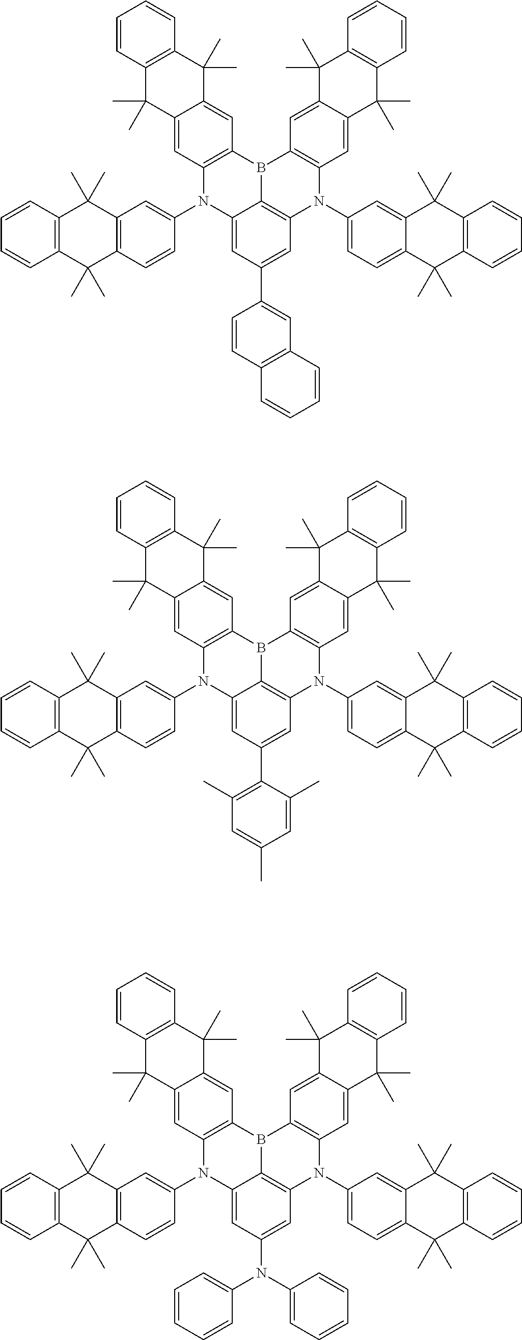 [SMILES: CC1(C)c2ccccc2C(C)(C)c2cc(N3c4cc5c(cc4B4c6cc7c(cc6N(c6ccc8c(c6)C(C)(C)c6ccccc6C8(C)C)c6cc(-c8ccc9ccccc9c8)cc3c64)C(C)(C)c3ccccc3C7(C)C)C(C)(C)c3ccccc3C5(C)C)ccc21 ; Cc1cc(C)c(-c2cc3c4c(c2)N(c2ccc5c(c2)C(C)(C)c2ccccc2C5(C)C)c2cc5c(cc2B4c2cc4c(cc2N3c2ccc3c(c2)C(C)(C)c2ccccc2C3(C)C)C(C)(C)c2ccccc2C4(C)C)C(C)(C)c2ccccc2C5(C)C)c(C)c1 ; CC1(C)c2ccccc2C(C)(C)c2cc(N3c4cc5c(cc4B4c6cc7c(cc6N(c6ccc8c(c6)C(C)(C)c6ccccc6C8(C)C)c6cc(N(c8ccccc8)c8ccccc8)cc3c64)C(C)(C)c3ccccc3C7(C)C)C(C)(C)c3ccccc3C5(C)C)ccc21]

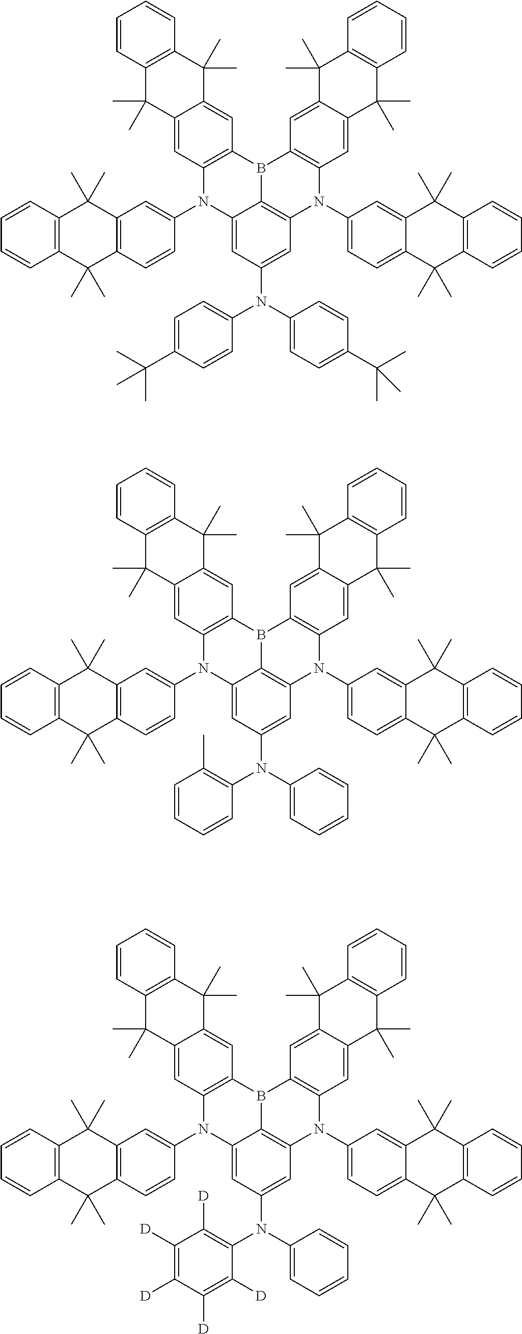

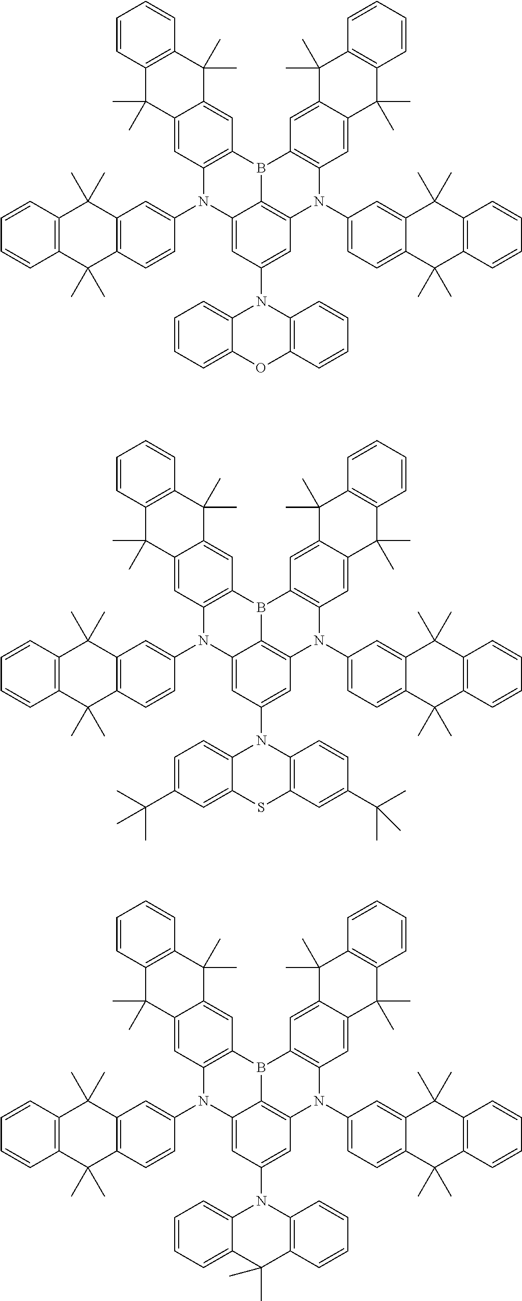

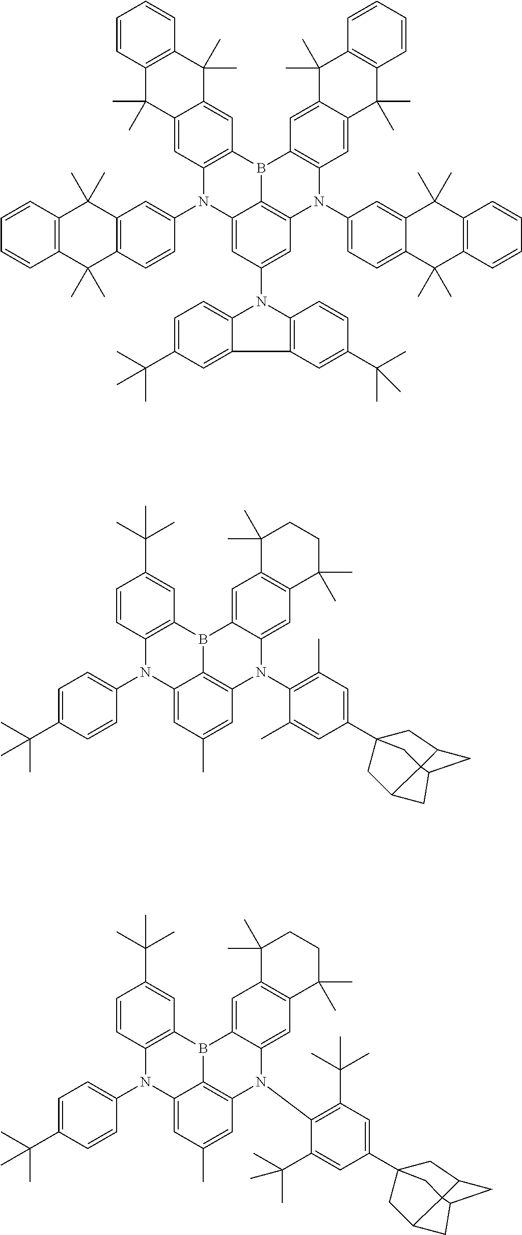 [SMILES: CC(C)(C)c1ccc2c(c1)c1cc(C(C)(C)C)ccc1n2-c1cc2c3c(c1)N(c1ccc4c(c1)C(C)(C)c1ccccc1C4(C)C)c1cc4c(cc1B3c1cc3c(cc1N2c1ccc2c(c1)C(C)(C)c1ccccc1C2(C)C)C(C)(C)c1ccccc1C3(C)C)C(C)(C)c1ccccc1C4(C)C ; Cc1cc2c3c(c1)N(c1c(C)cc(C45CC6CC7CC(C4)C76C5)cc1C)c1cc4c(cc1B3c1cc(C(C)(C)C)ccc1N2c1ccc(C(C)(C)C)cc1)C(C)(C)CCC4(C)C ; Cc1cc2c3c(c1)N(c1c(C(C)(C)C)cc(C45CC6CC7CC(C4)C76C5)cc1C(C)(C)C)c1cc4c(cc1B3c1cc(C(C)(C)C)ccc1N2c1ccc(C(C)(C)C)cc1)C(C)(C)CCC4(C)C]

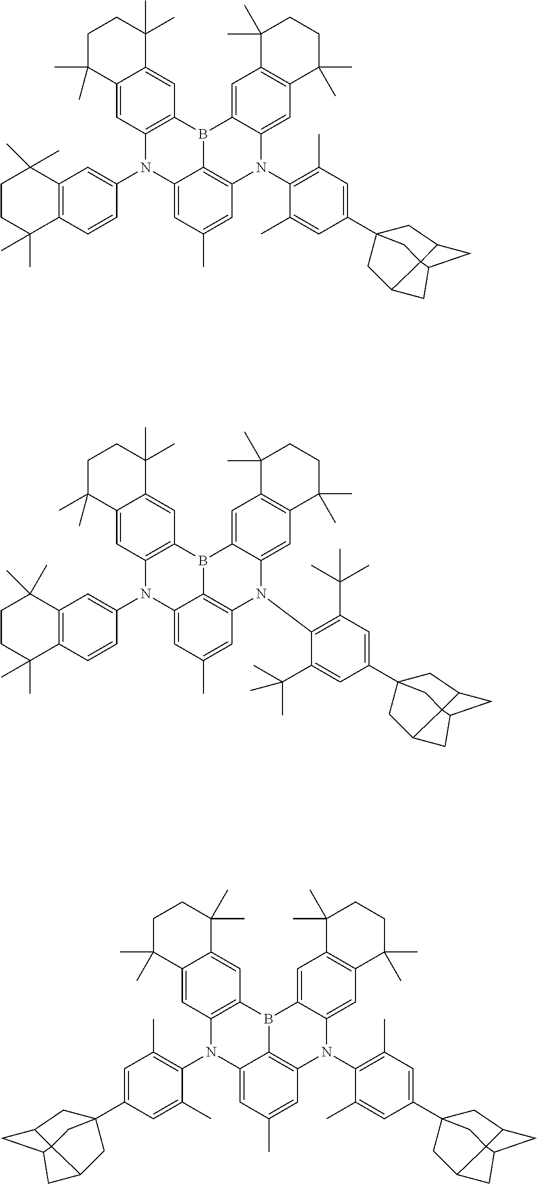 [SMILES: Cc1cc2c3c(c1)N(c1c(C)cc(C45CC6CC7CC(C4)C76C5)cc1C)c1cc4c(cc1B3c1cc3c(cc1N2c1ccc2c(c1)C(C)(C)CCC2(C)C)C(C)(C)CCC3(C)C)C(C)(C)CCC4(C)C ; Cc1cc2c3c(c1)N(c1c(C(C)(C)C)cc(C45CC6CC7CC(C4)C76C5)cc1C(C)(C)C)c1cc4c(cc1B3c1cc3c(cc1N2c1ccc2c(c1)C(C)(C)CCC2(C)C)C(C)(C)CCC3(C)C)C(C)(C)CCC4(C)C ; Cc1cc2c3c(c1)N(c1c(C)cc(C45CC6CC7CC(C4)C76C5)cc1C)c1cc4c(cc1B3c1cc3c(cc1N2c1c(C)cc(C25CC6CC7CC(C2)C76C5)cc1C)C(C)(C)CCC3(C)C)C(C)(C)CCC4(C)C]

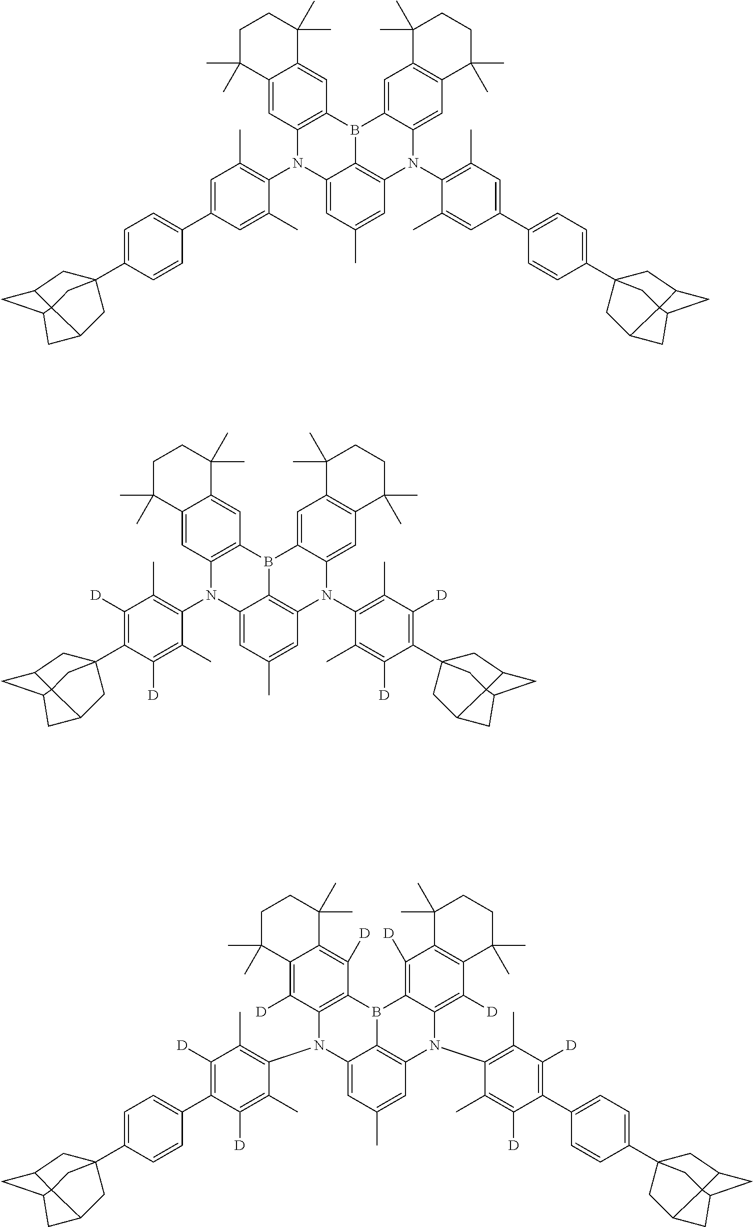

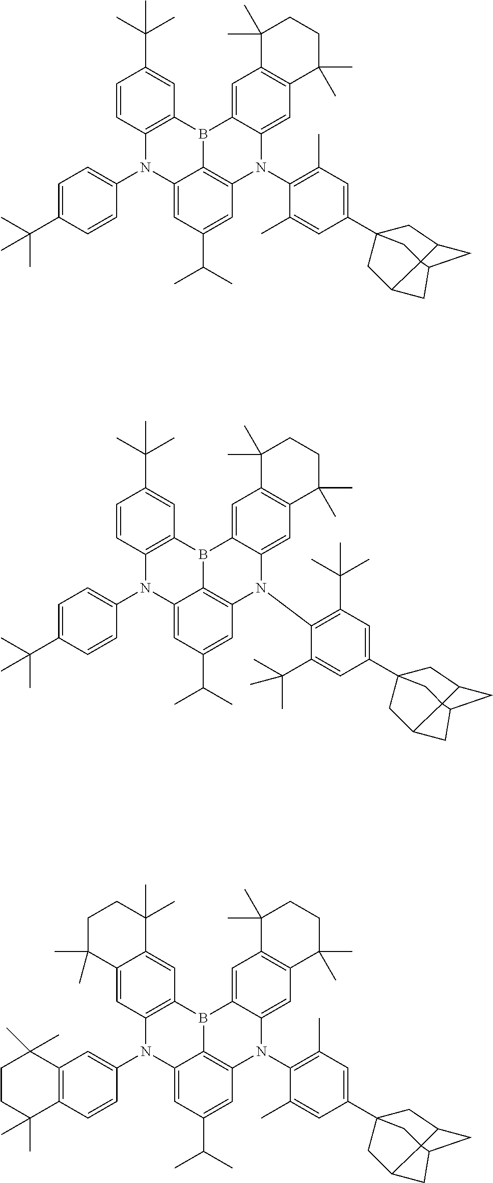 [SMILES: Cc1cc(C23CC4CC5CC(C2)C54C3)cc(C)c1N1c2cc3c(cc2B2c4cc(C(C)(C)C)ccc4N(c4ccc(C(C)(C)C)cc4)c4cc(C(C)C)cc1c42)C(C)(C)CCC3(C)C ; CC(C)c1cc2c3c(c1)N(c1c(C(C)(C)C)cc(C45CC6CC7CC(C4)C76C5)cc1C(C)(C)C)c1cc4c(cc1B3c1cc(C(C)(C)C)ccc1N2c1ccc(C(C)(C)C)cc1)C(C)(C)CCC4(C)C ; Cc1cc(C23CC4CC5CC(C2)C54C3)cc(C)c1N1c2cc3c(cc2B2c4cc5c(cc4N(c4ccc6c(c4)C(C)(C)CCC6(C)C)c4cc(C(C)C)cc1c42)C(C)(C)CCC5(C)C)C(C)(C)CCC3(C)C]

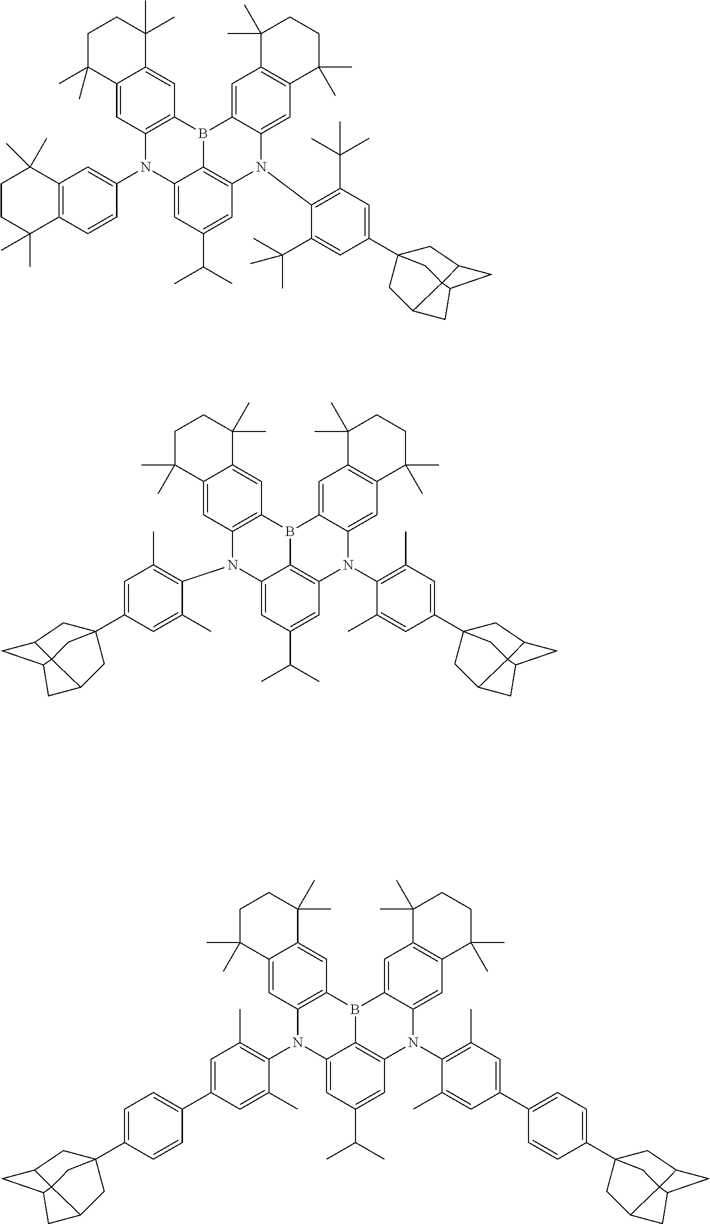 [SMILES: CC(C)c1cc2c3c(c1)N(c1c(C(C)(C)C)cc(C45CC6CC7CC(C4)C76C5)cc1C(C)(C)C)c1cc4c(cc1B3c1cc3c(cc1N2c1ccc2c(c1)C(C)(C)CCC2(C)C)C(C)(C)CCC3(C)C)C(C)(C)CCC4(C)C ; Cc1cc(C23CC4CC5CC(C2)C54C3)cc(C)c1N1c2cc3c(cc2B2c4cc5c(cc4N(c4c(C)cc(C67CC8CC9CC(C6)C98C7)cc4C)c4cc(C(C)C)cc1c42)C(C)(C)CCC5(C)C)C(C)(C)CCC3(C)C ; Cc1cc(-c2ccc(C34CC5CC6CC(C3)C65C4)cc2)cc(C)c1N1c2cc3c(cc2B2c4cc5c(cc4N(c4c(C)cc(-c6ccc(C78CC9CC%10CC(C7)C%109C8)cc6)cc4C)c4cc(C(C)C)cc1c42)C(C)(C)CCC5(C)C)C(C)(C)CCC3(C)C]

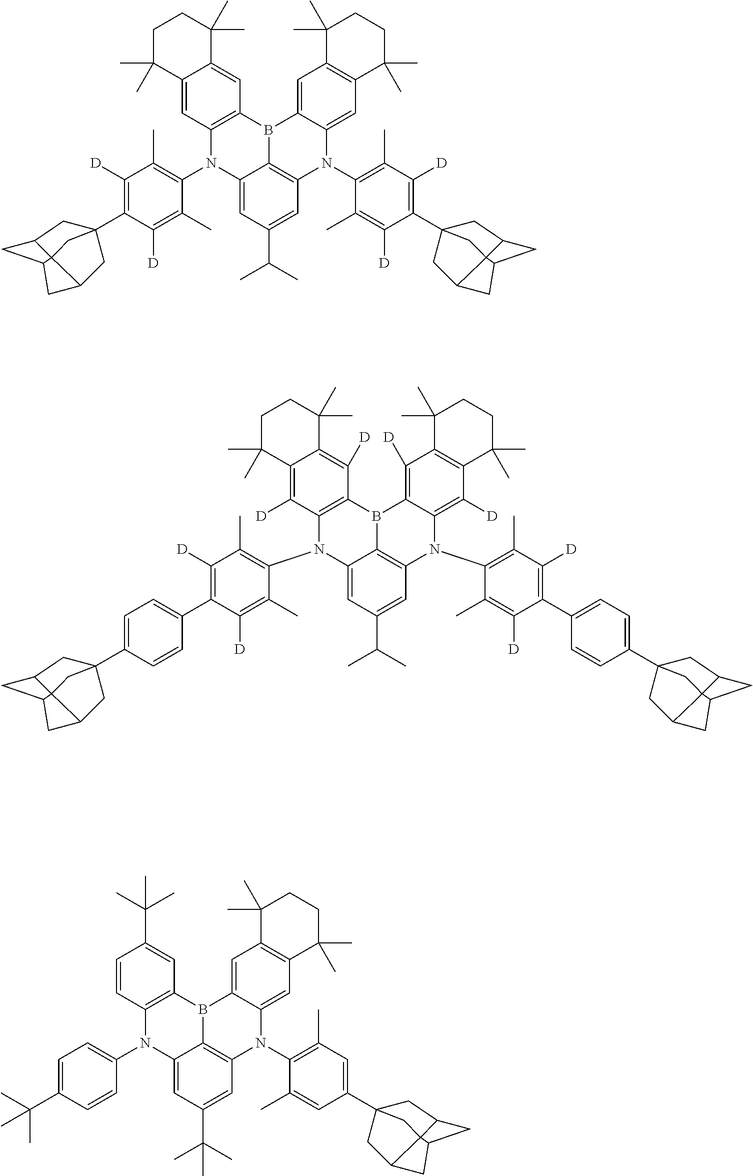

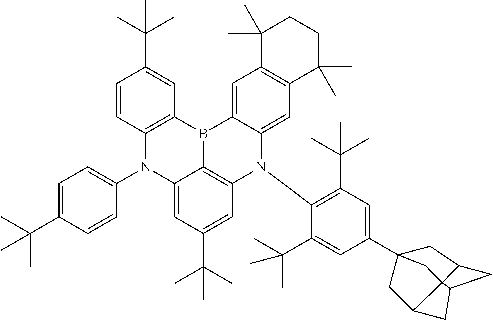 [SMILES: CC(C)(C)c1ccc(N2c3ccc(C(C)(C)C)cc3B3c4cc5c(cc4N(c4c(C(C)(C)C)cc(C67CC8CC9CC(C6)C98C7)cc4C(C)(C)C)c4cc(C(C)(C)C)cc2c43)C(C)(C)CCC5(C)C)cc1]

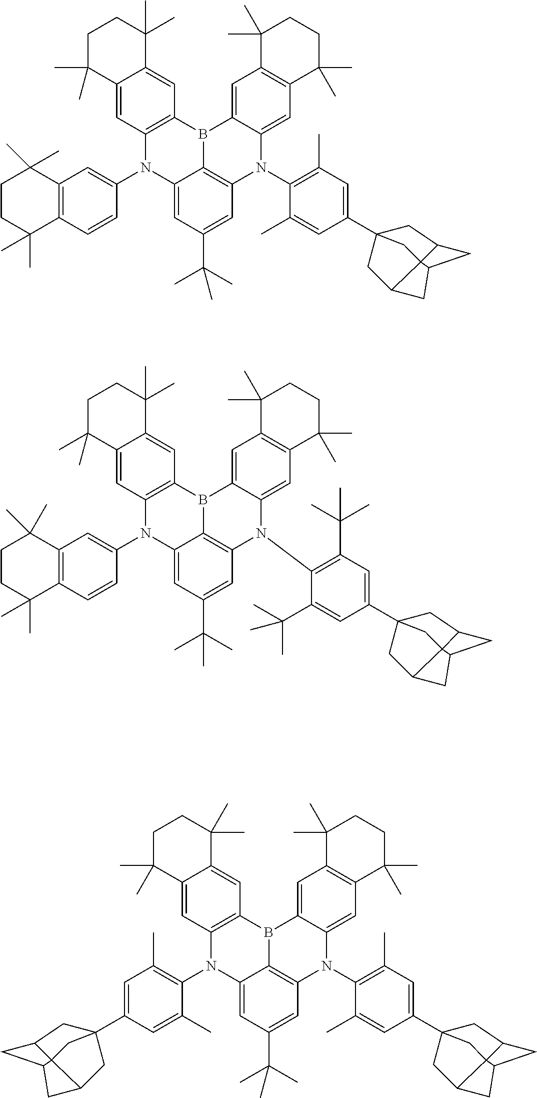 [SMILES: Cc1cc(C23CC4CC5CC(C2)C54C3)cc(C)c1N1c2cc3c(cc2B2c4cc5c(cc4N(c4ccc6c(c4)C(C)(C)CCC6(C)C)c4cc(C(C)(C)C)cc1c42)C(C)(C)CCC5(C)C)C(C)(C)CCC3(C)C ; CC(C)(C)c1cc2c3c(c1)N(c1c(C(C)(C)C)cc(C45CC6CC7CC(C4)C76C5)cc1C(C)(C)C)c1cc4c(cc1B3c1cc3c(cc1N2c1ccc2c(c1)C(C)(C)CCC2(C)C)C(C)(C)CCC3(C)C)C(C)(C)CCC4(C)C ; Cc1cc(C23CC4CC5CC(C2)C54C3)cc(C)c1N1c2cc3c(cc2B2c4cc5c(cc4N(c4c(C)cc(C67CC8CC9CC(C6)C98C7)cc4C)c4cc(C(C)(C)C)cc1c42)C(C)(C)CCC5(C)C)C(C)(C)CCC3(C)C]

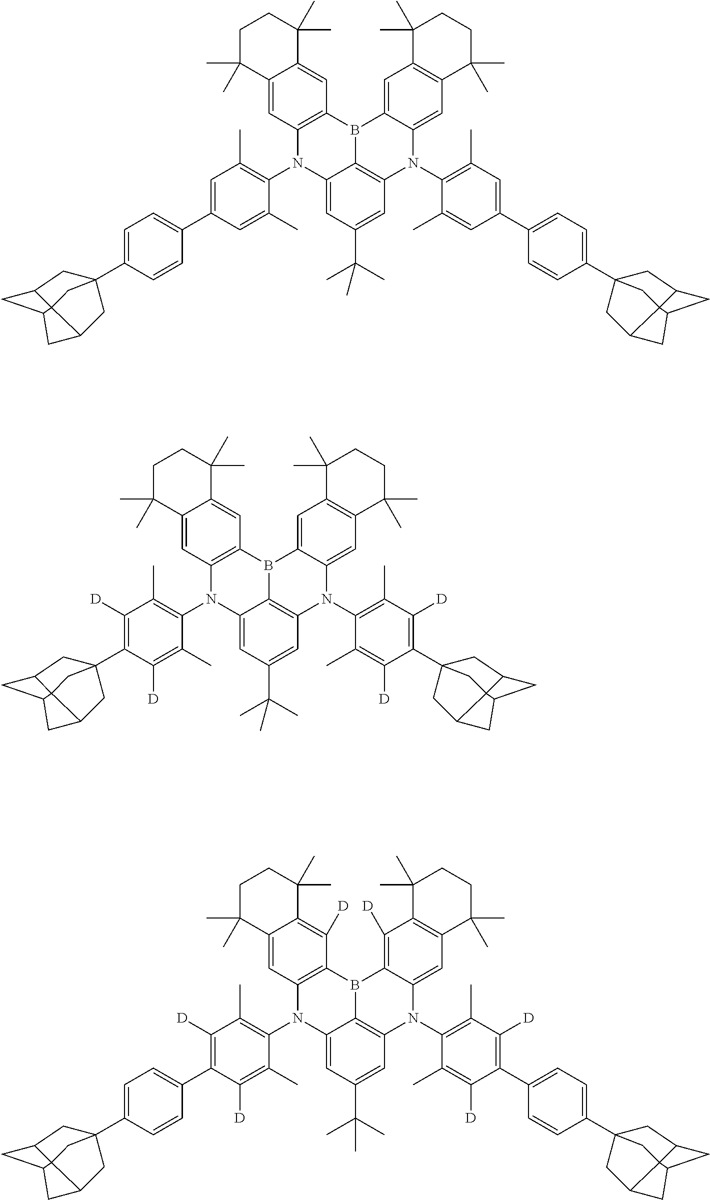

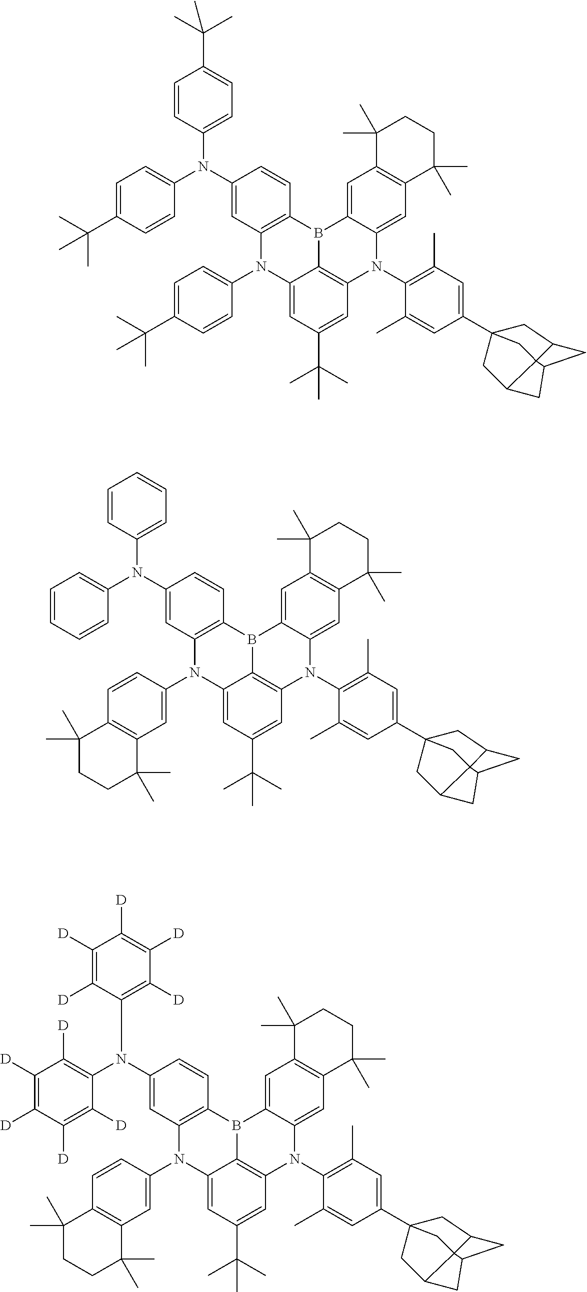 [SMILES: Cc1cc(C23CC4CC5CC(C2)C54C3)cc(C)c1N1c2cc3c(cc2B2c4ccc(N(c5ccc(C(C)(C)C)cc5)c5ccc(C(C)(C)C)cc5)cc4N(c4ccc(C(C)(C)C)cc4)c4cc(C(C)(C)C)cc1c42)C(C)(C)CCC3(C)C ; Cc1cc(C23CC4CC5CC(C2)C54C3)cc(C)c1N1c2cc3c(cc2B2c4ccc(N(c5ccccc5)c5ccccc5)cc4N(c4ccc5c(c4)C(C)(C)CCC5(C)C)c4cc(C(C)(C)C)cc1c42)C(C)(C)CCC3(C)C ; [2H]c1c([2H])c([2H])c(N(c2ccc3c(c2)N(c2ccc4c(c2)C(C)(C)CCC4(C)C)c2cc(C(C)(C)C)cc4c2B3c2cc3c(cc2N4c2c(C)cc(C45CC6CC7CC(C4)C76C5)cc2C)C(C)(C)CCC3(C)C)c2c([2H])c([2H])c([2H])c([2H])c2[2H])c([2H])c1[2H]]

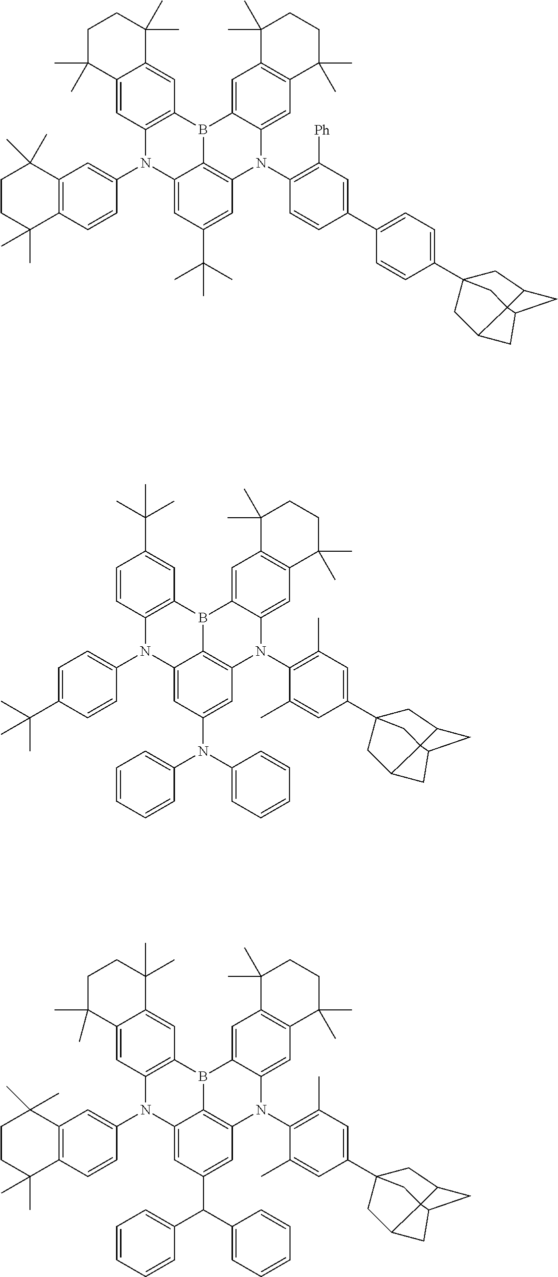 [SMILES: CC(C)(C)c1cc2c3c(c1)N(c1ccc(-c4ccc(C56CC7CC8CC(C5)C87C6)cc4)cc1-c1ccccc1)c1cc4c(cc1B3c1cc3c(cc1N2c1ccc2c(c1)C(C)(C)CCC2(C)C)C(C)(C)CCC3(C)C)C(C)(C)CCC4(C)C ; Cc1cc(C23CC4CC5CC(C2)C54C3)cc(C)c1N1c2cc3c(cc2B2c4cc(C(C)(C)C)ccc4N(c4ccc(C(C)(C)C)cc4)c4cc(N(c5ccccc5)c5ccccc5)cc1c42)C(C)(C)CCC3(C)C ; Cc1cc(C23CC4CC5CC(C2)C54C3)cc(C)c1N1c2cc3c(cc2B2c4cc5c(cc4N(c4ccc6c(c4)C(C)(C)CCC6(C)C)c4cc(C(c6ccccc6)c6ccccc6)cc1c42)C(C)(C)CCC5(C)C)C(C)(C)CCC3(C)C]

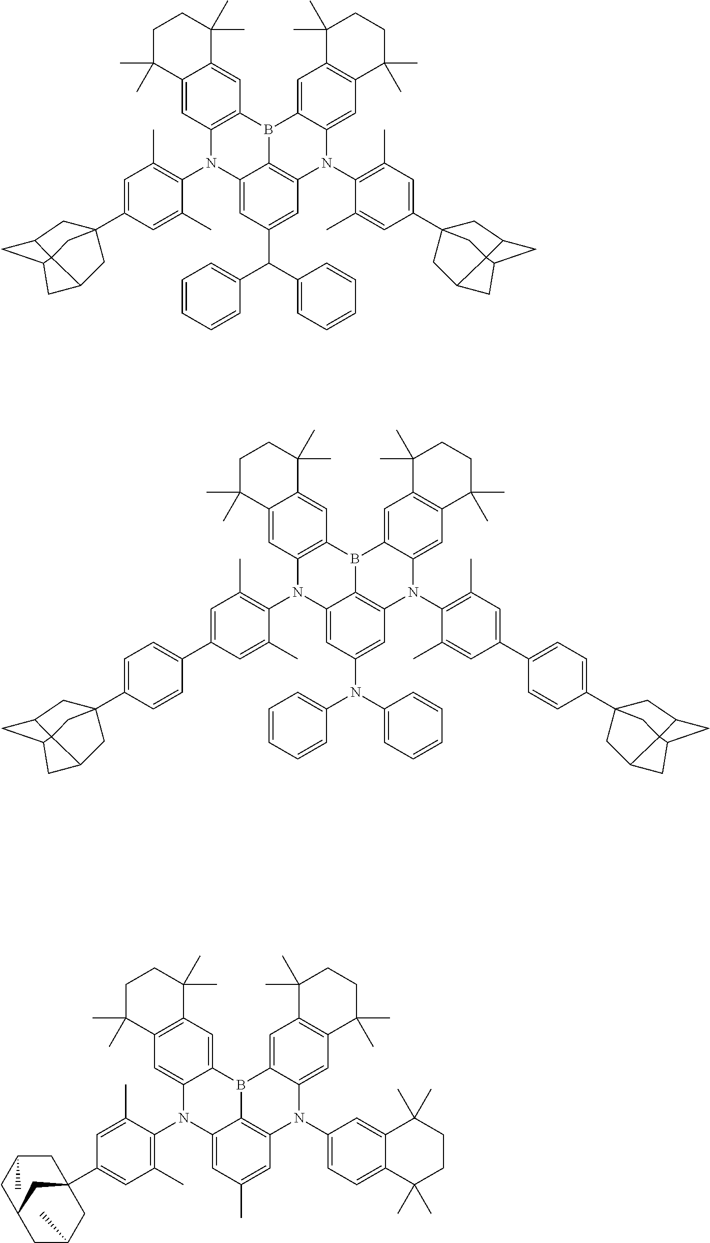 [SMILES: Cc1cc(C23CC4CC5CC(C2)C54C3)cc(C)c1N1c2cc3c(cc2B2c4cc5c(cc4N(c4c(C)cc(C67CC8CC9CC(C6)C98C7)cc4C)c4cc(C(c6ccccc6)c6ccccc6)cc1c42)C(C)(C)CCC5(C)C)C(C)(C)CCC3(C)C ; Cc1cc(-c2ccc(C34CC5CC6CC(C3)C65C4)cc2)cc(C)c1N1c2cc3c(cc2B2c4cc5c(cc4N(c4c(C)cc(-c6ccc(C78CC9CC%10CC(C7)C%109C8)cc6)cc4C)c4cc(N(c6ccccc6)c6ccccc6)cc1c42)C(C)(C)CCC5(C)C)C(C)(C)CCC3(C)C ; Cc1cc2c3c(c1)N(c1c(C)cc([C@]45C[C@H](C)C[C@H](C[C@H](C)C4)C5)cc1C)c1cc4c(cc1B3c1cc3c(cc1N2c1ccc2c(c1)C(C)(C)CCC2(C)C)C(C)(C)CCC3(C)C)C(C)(C)CCC4(C)C]

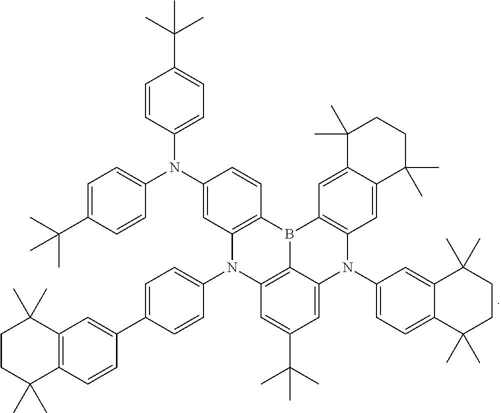 [SMILES: CC(C)(C)c1ccc(N(c2ccc(C(C)(C)C)cc2)c2ccc3c(c2)N(c2ccc(-c4ccc5c(c4)C(C)(C)CCC5(C)C)cc2)c2cc(C(C)(C)C)cc4c2B3c2cc3c(cc2N4c2ccc4c(c2)C(C)(C)CCC4(C)C)C(C)(C)CCC3(C)C)cc1]

18. The organic light emitting device of claim 1, wherein the compound of Chemical Formula 3 is any one of the following compounds: 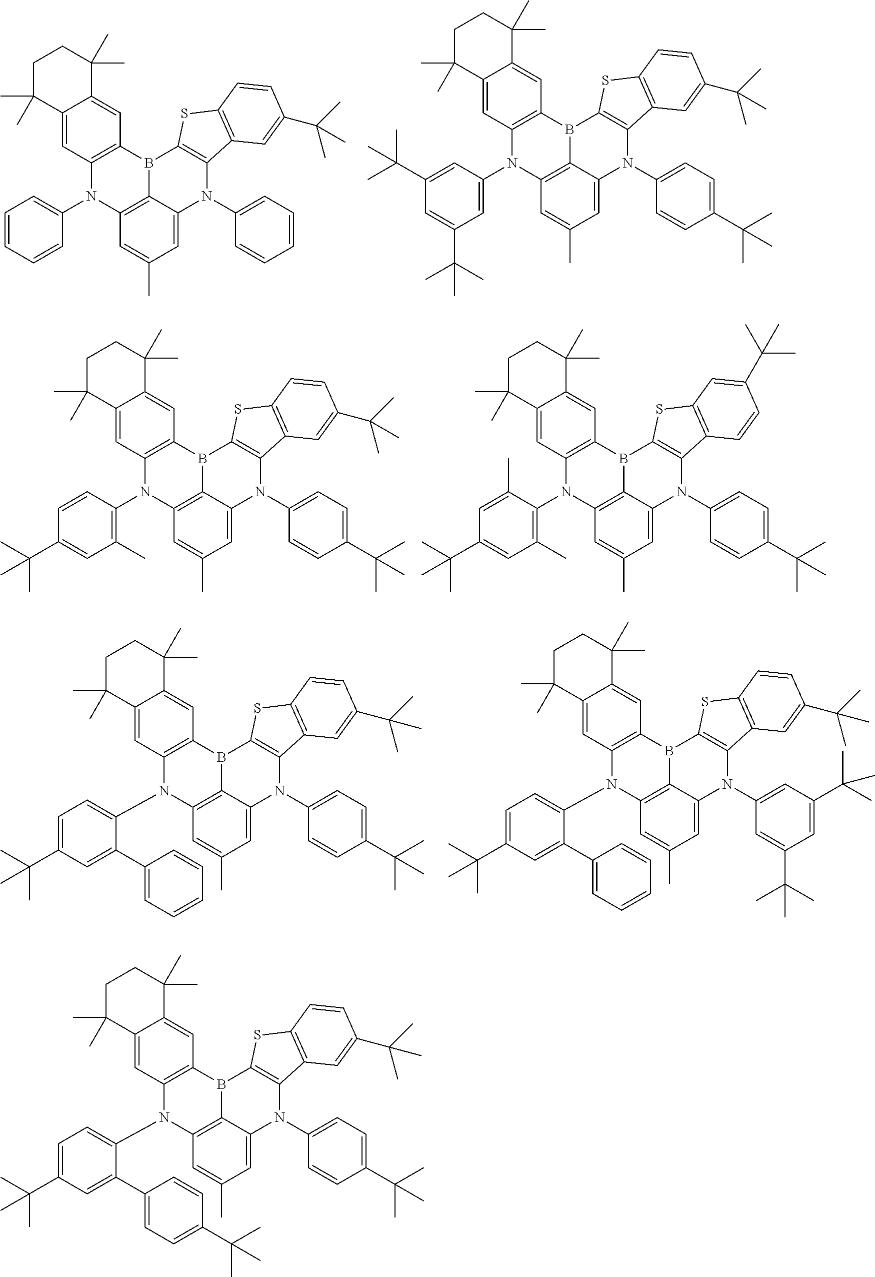 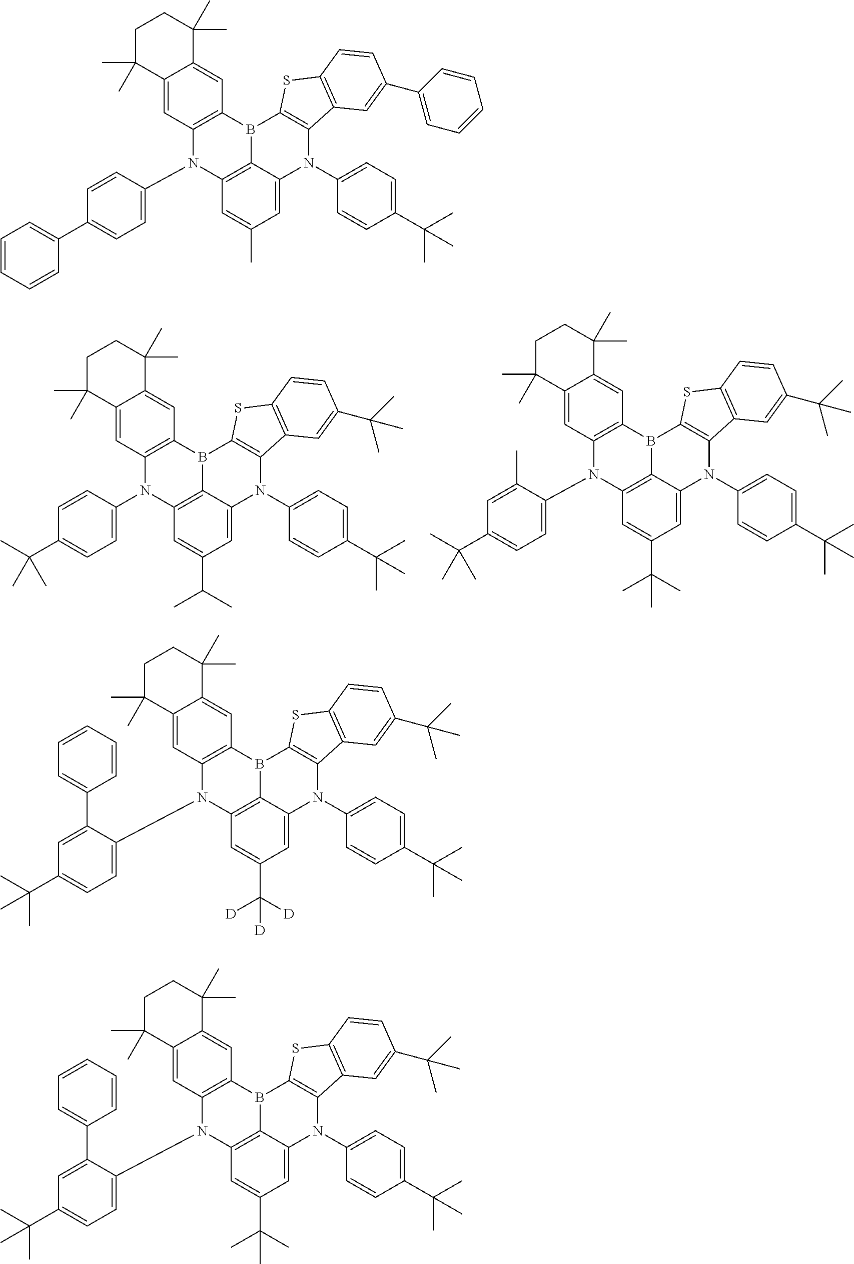 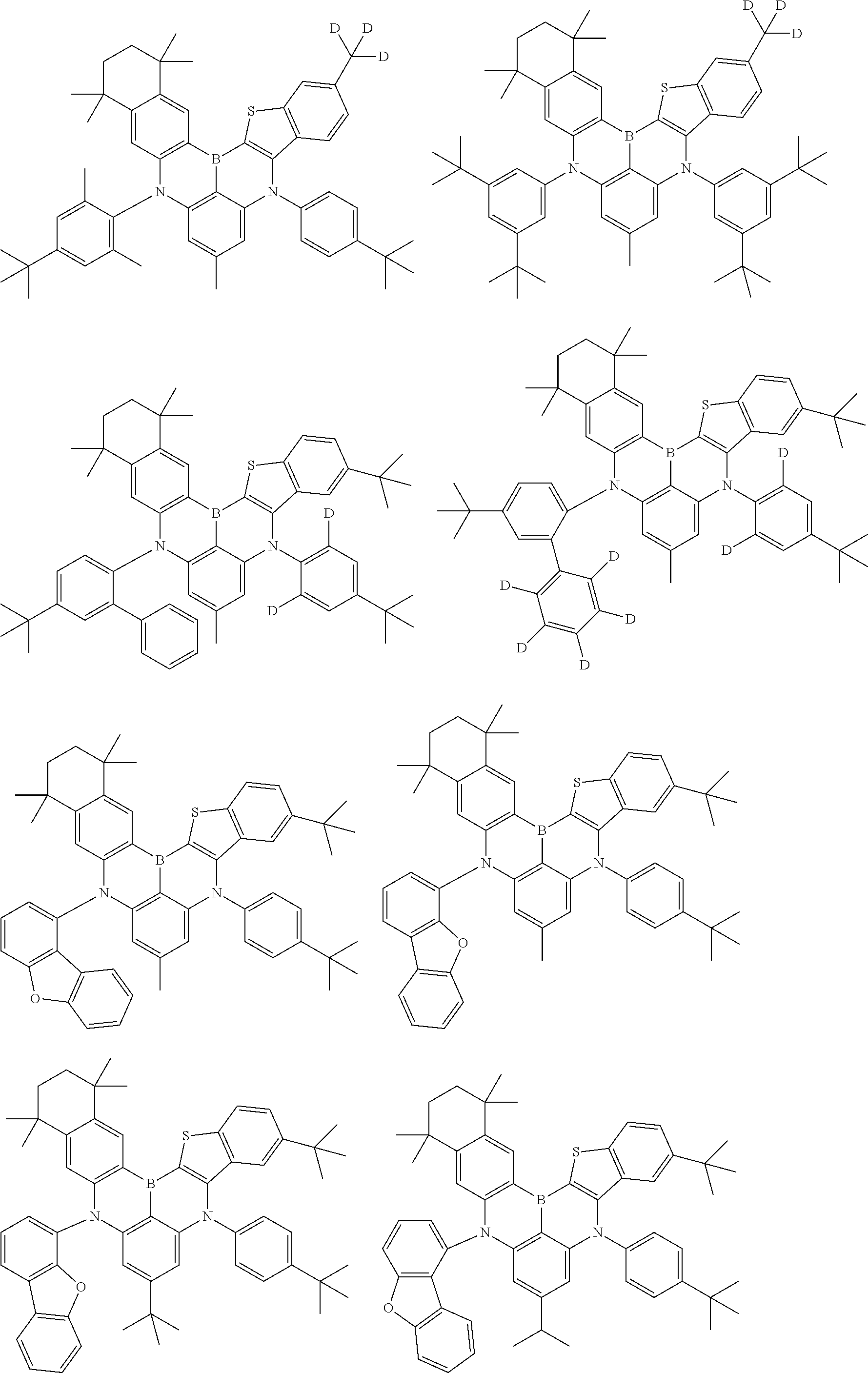 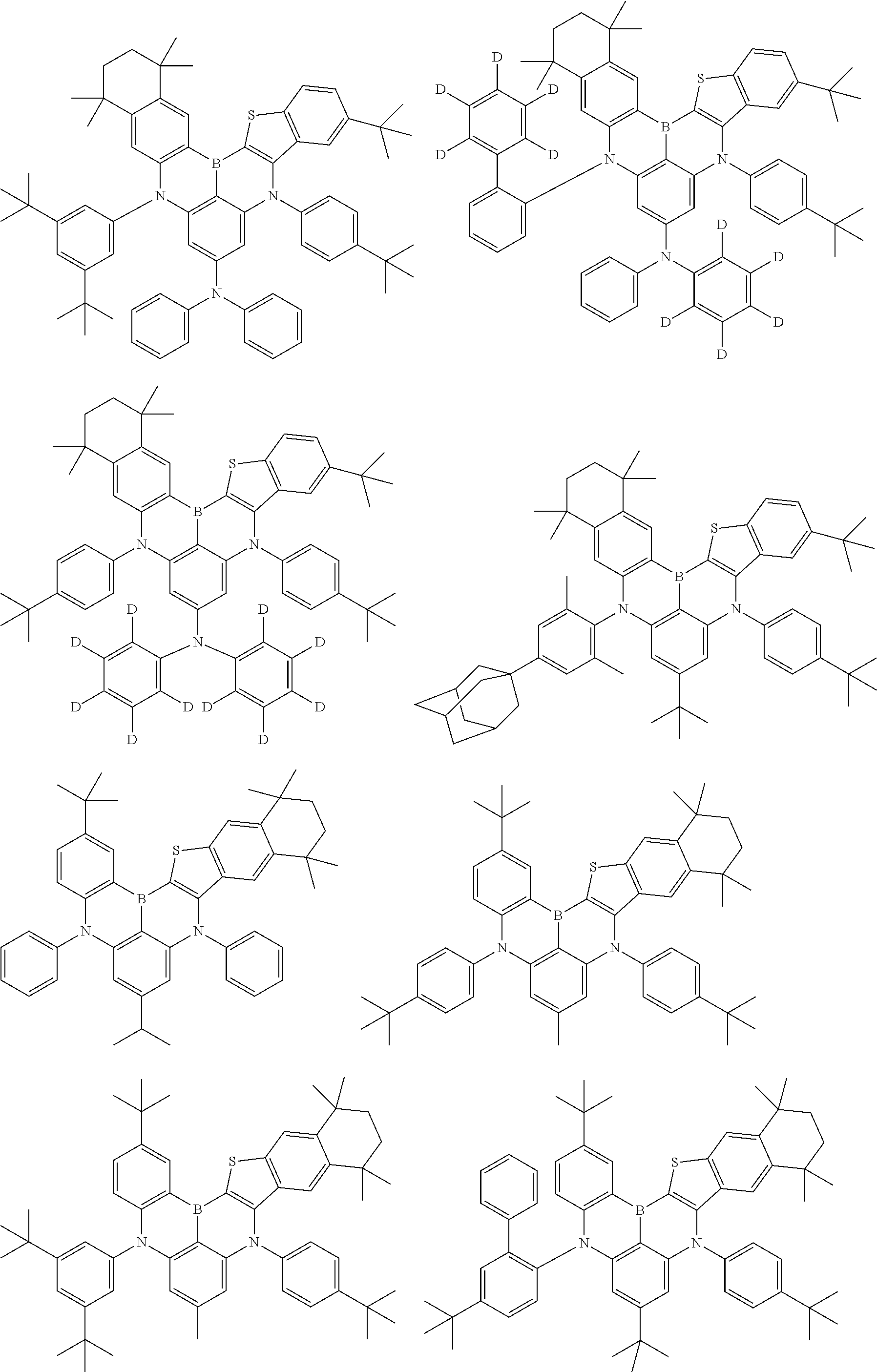 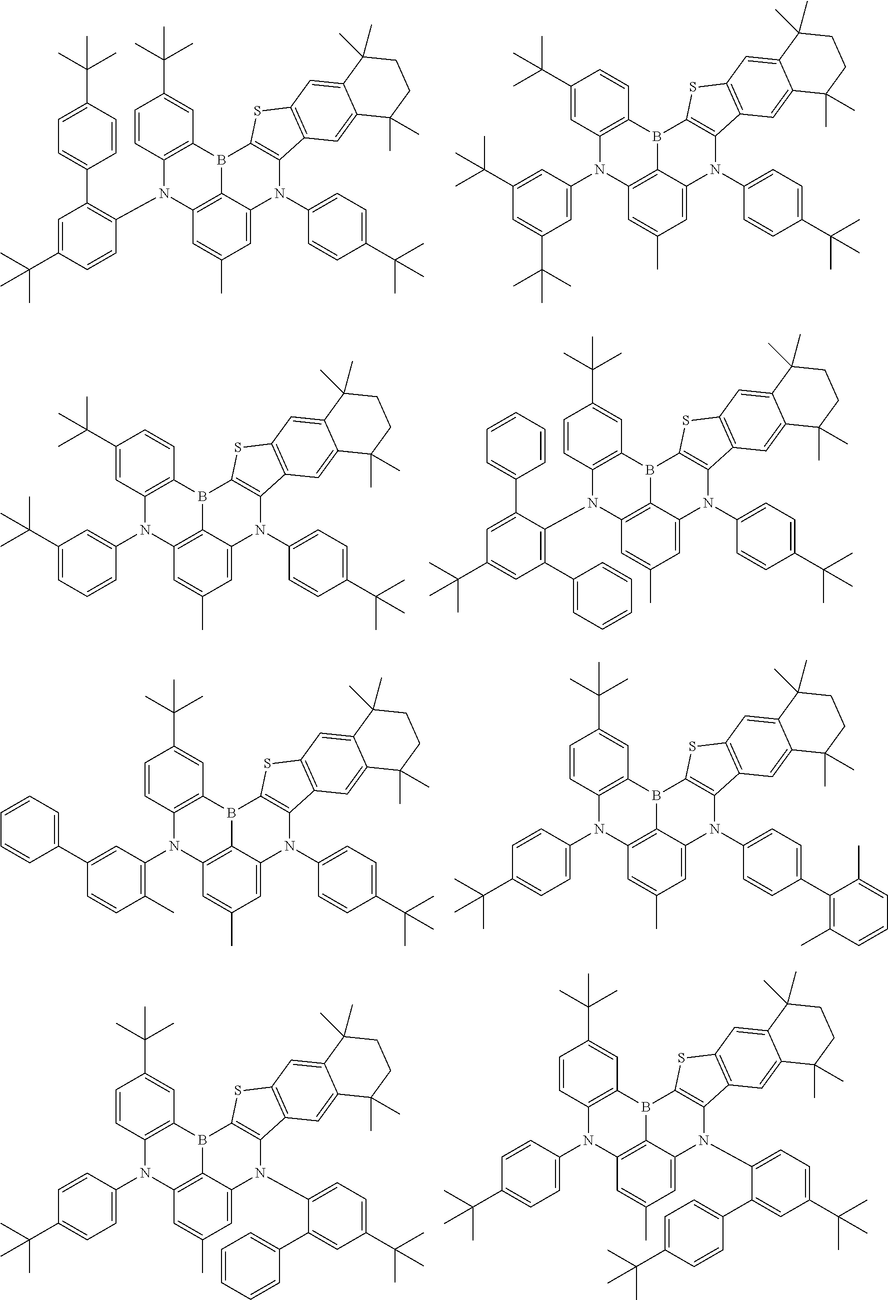 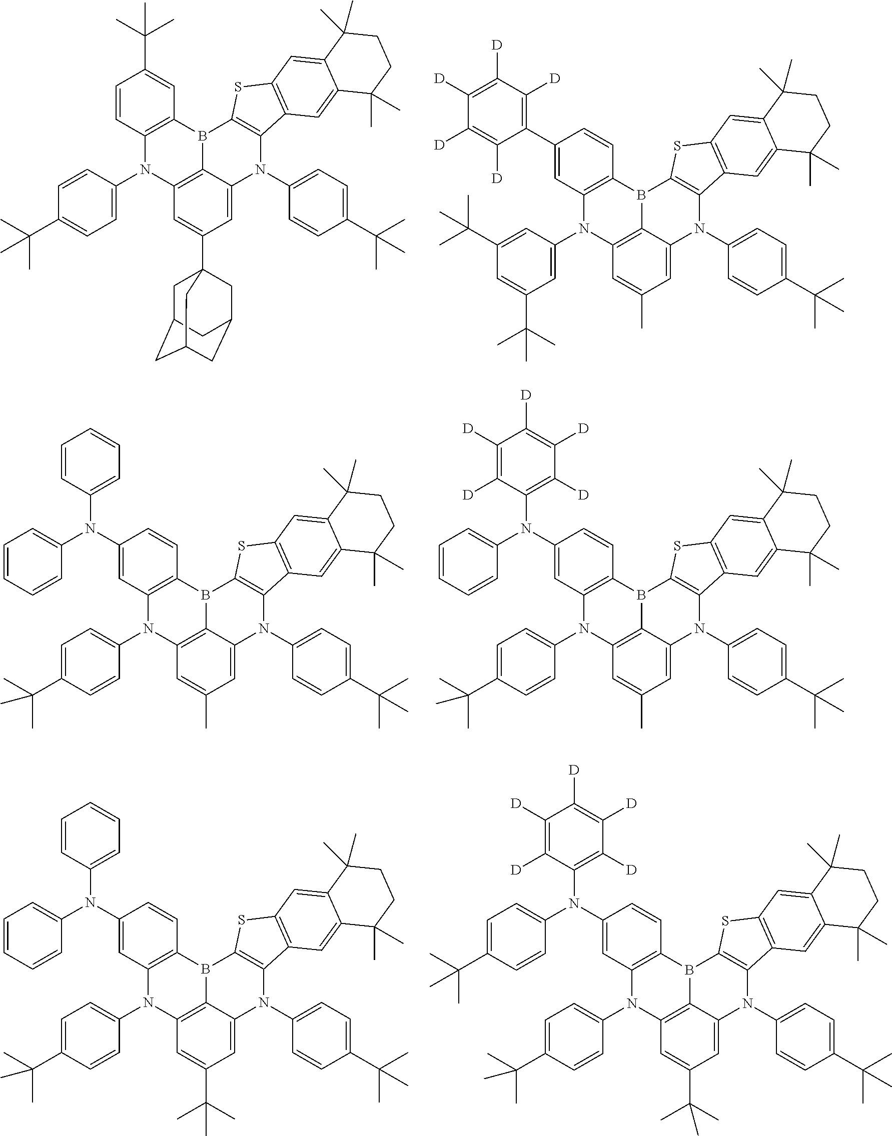 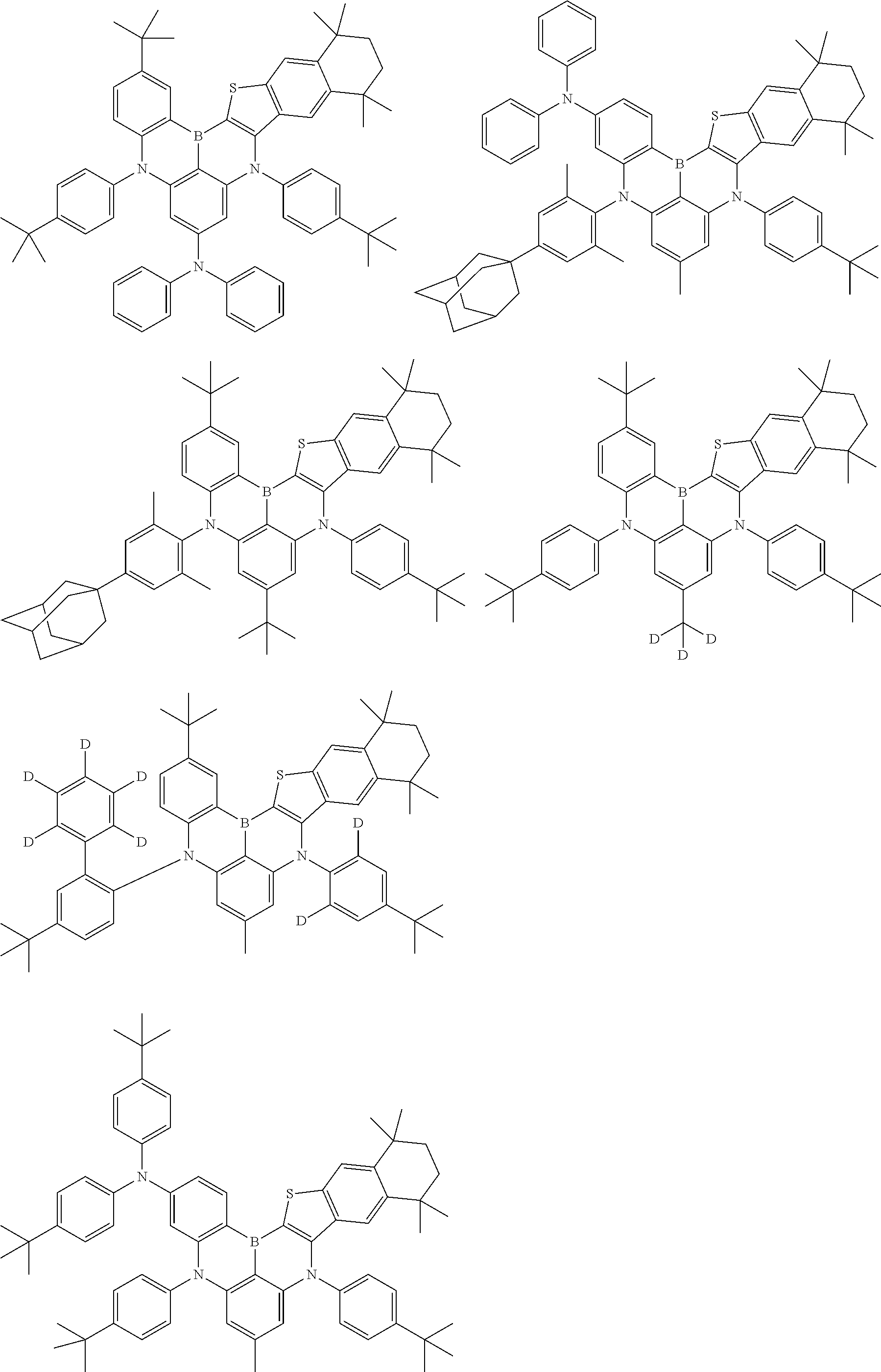 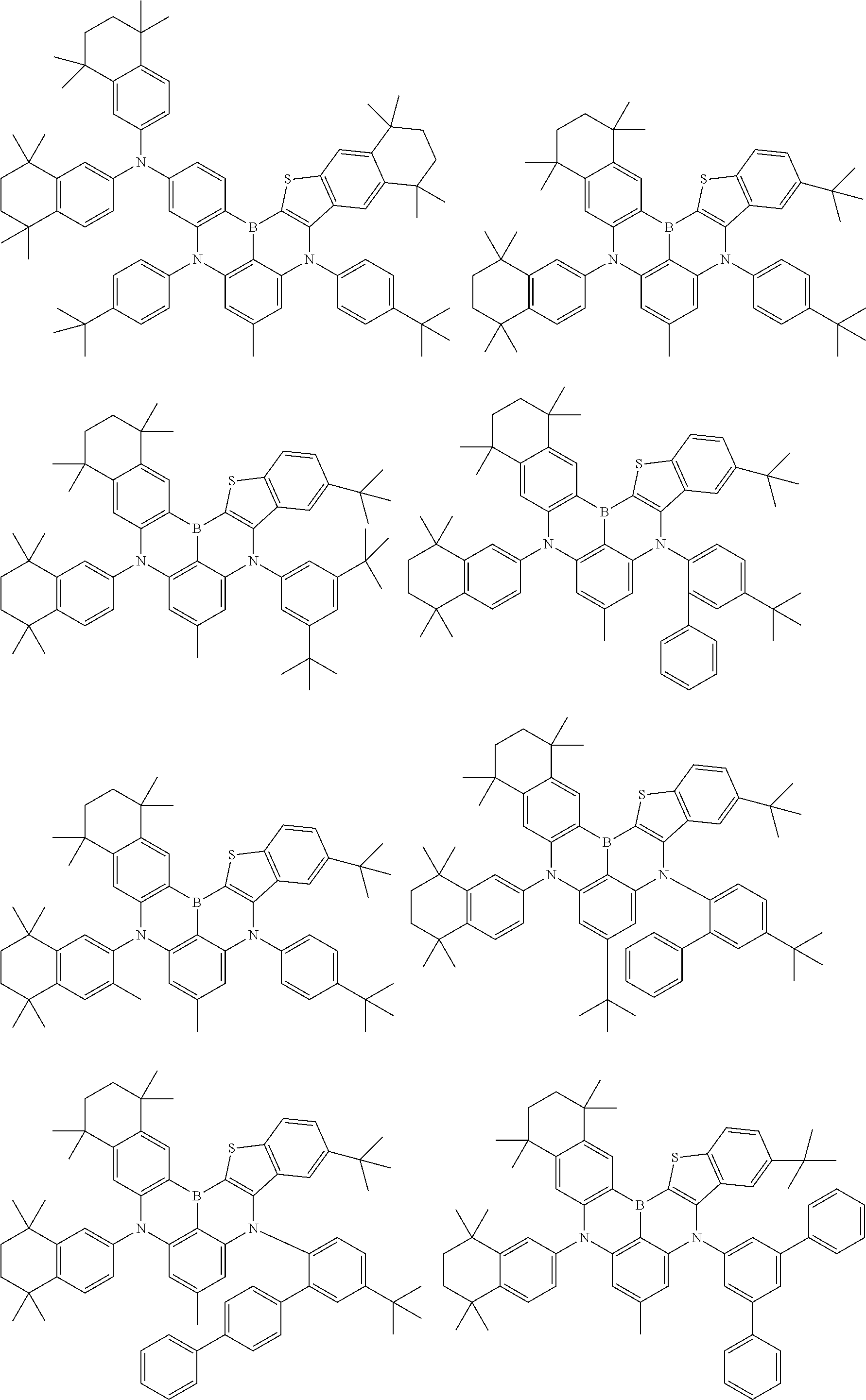 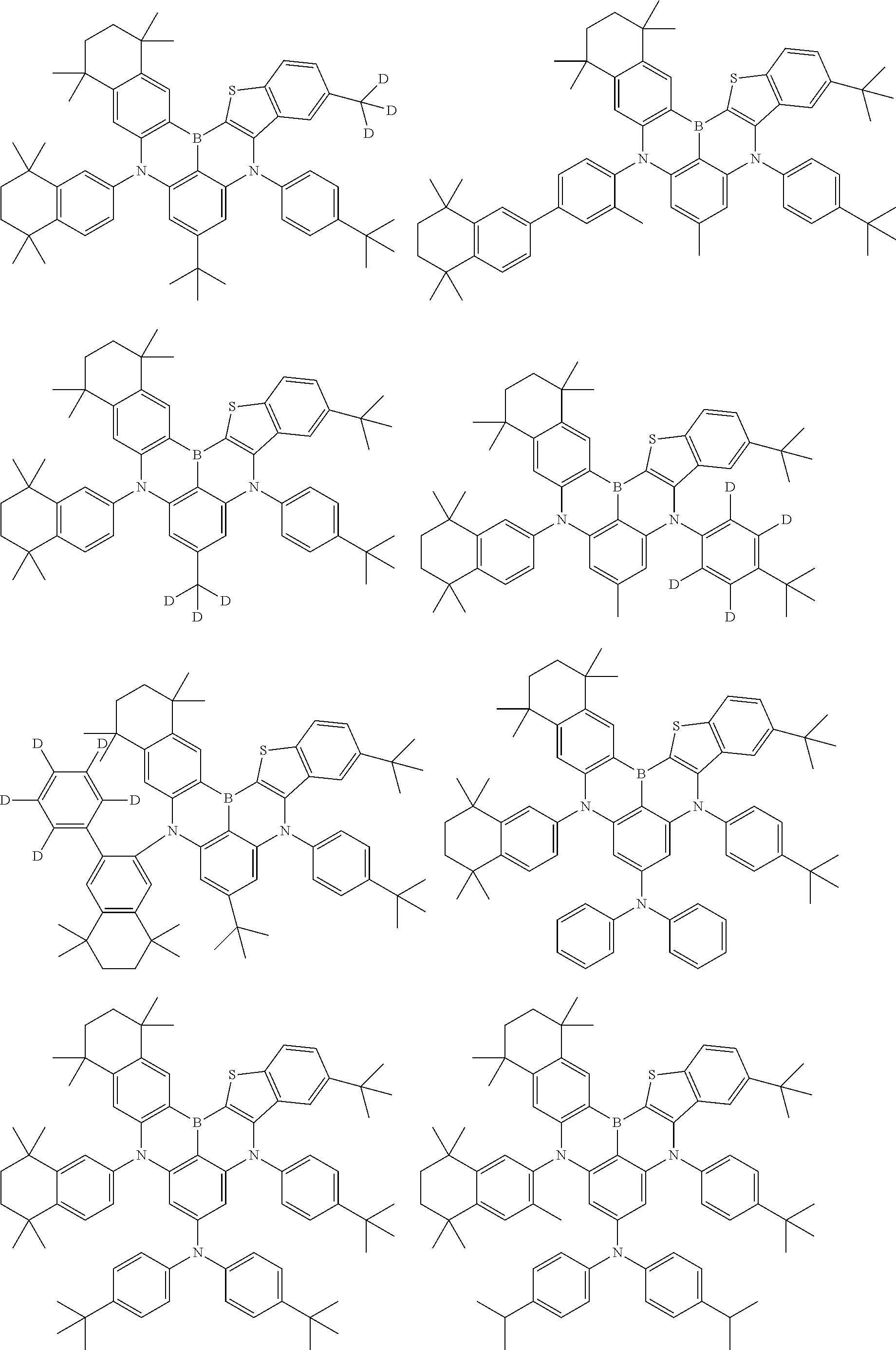 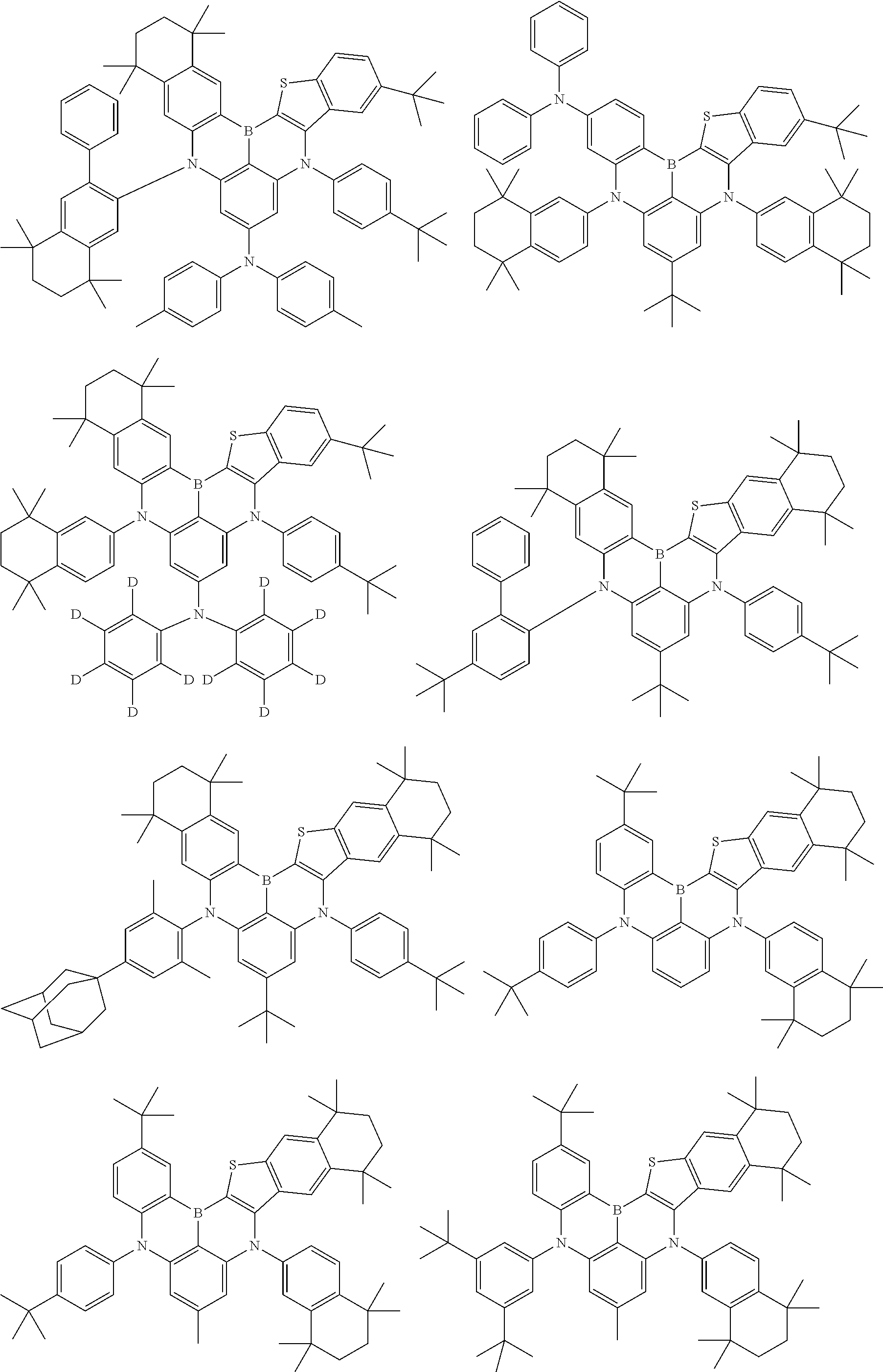 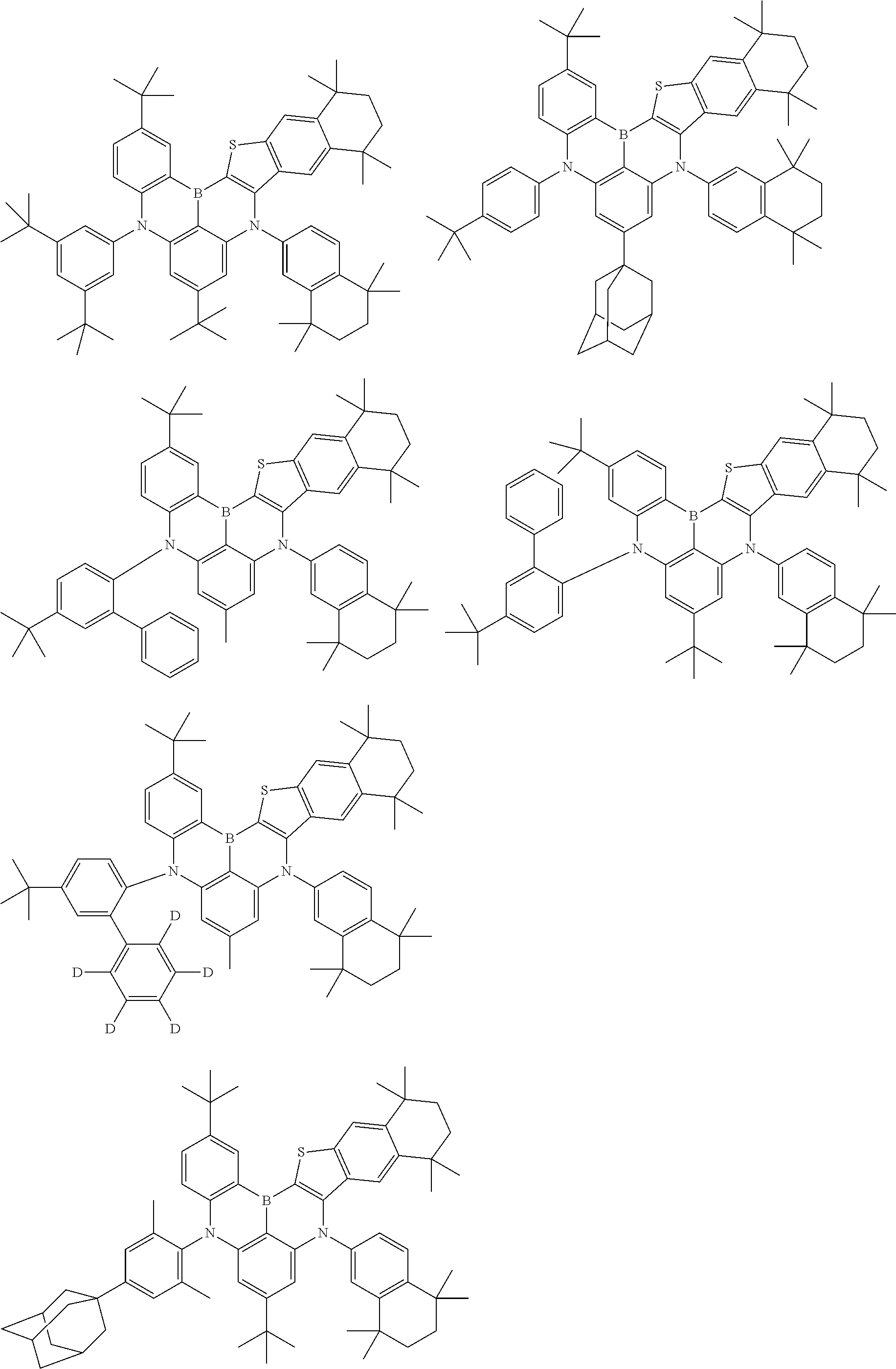 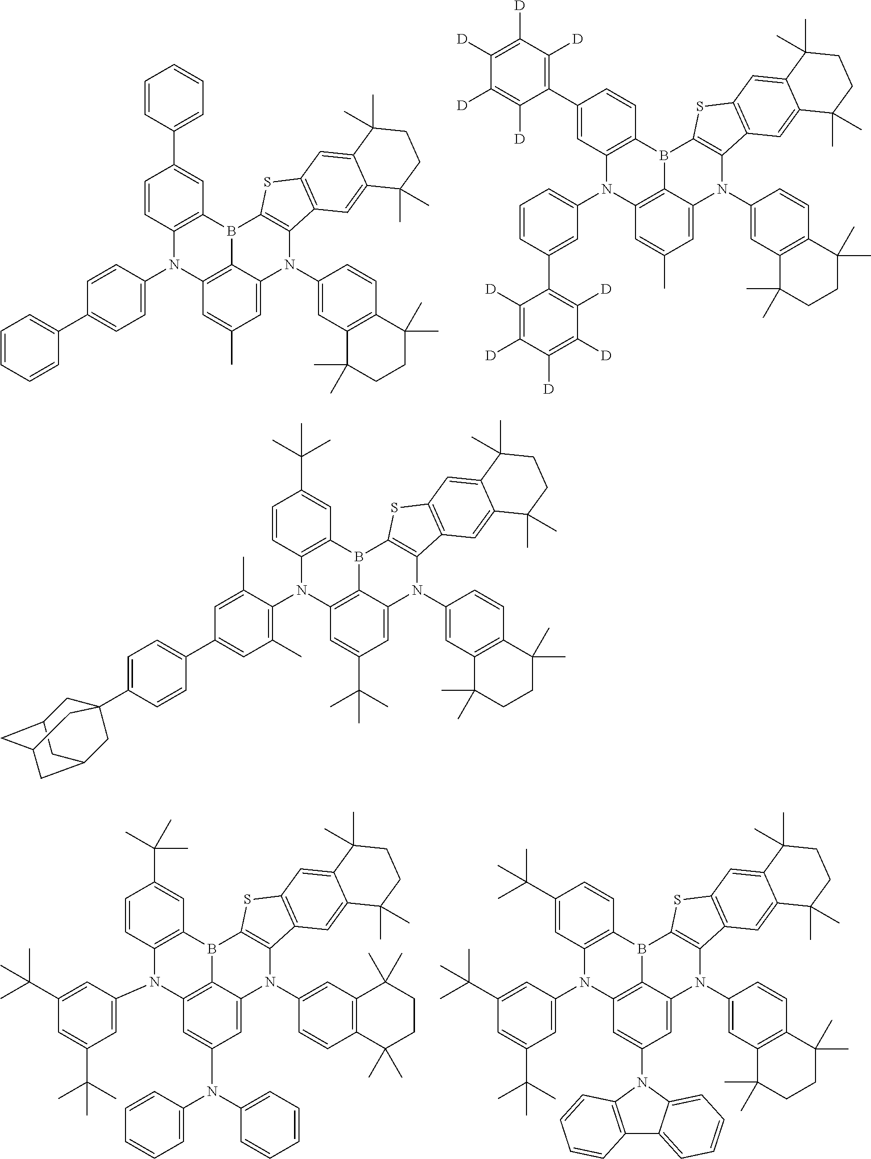 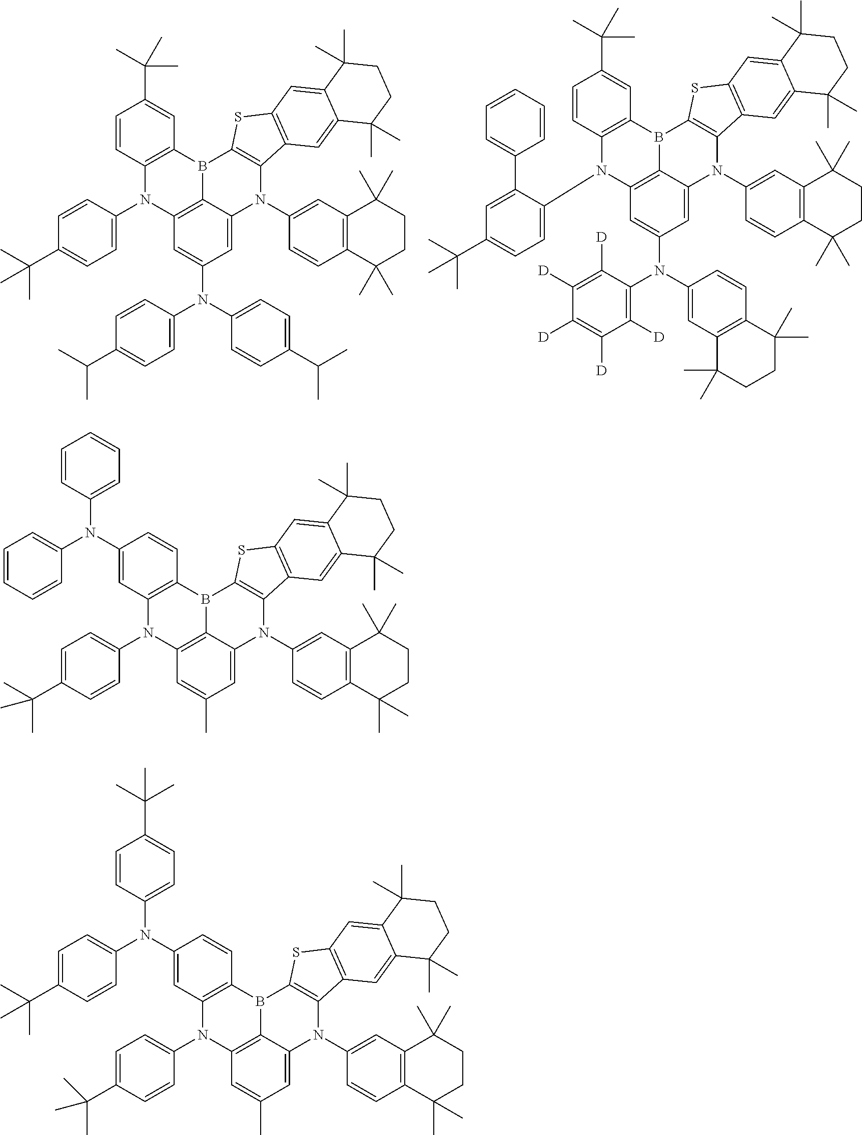 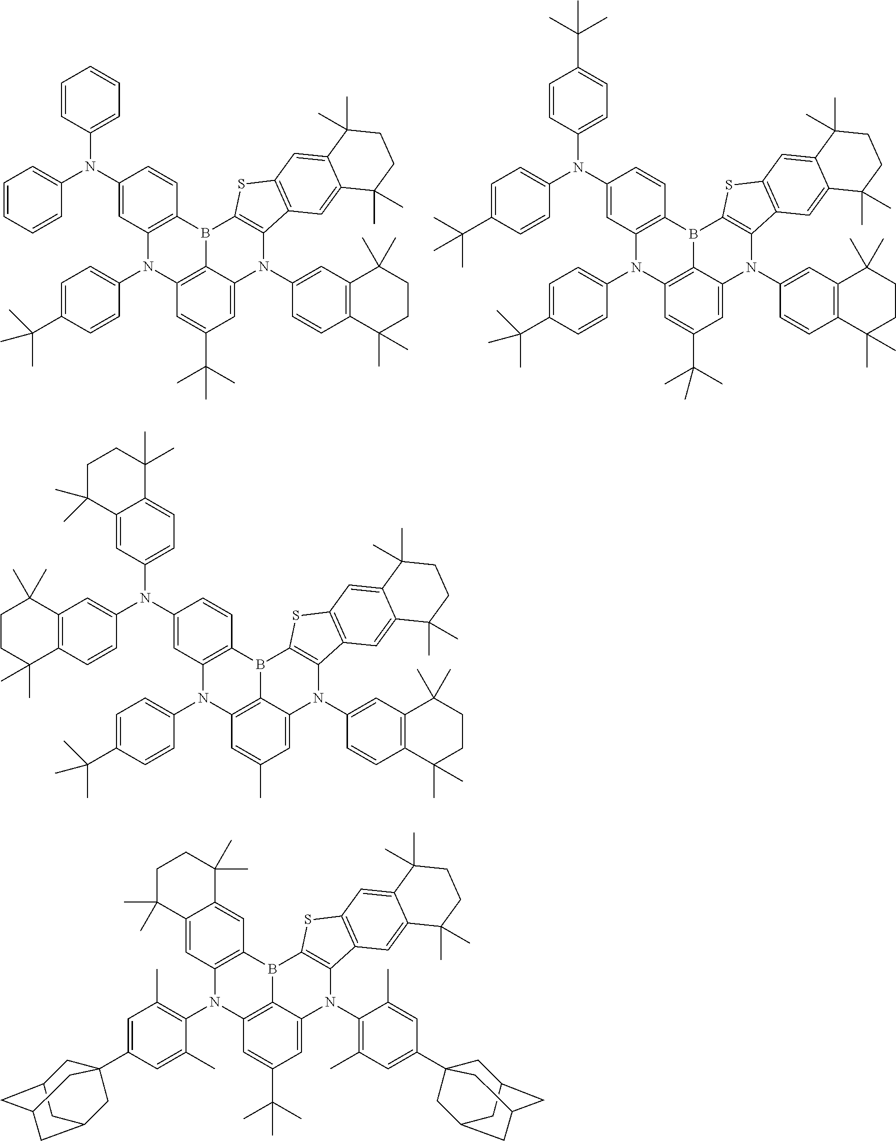 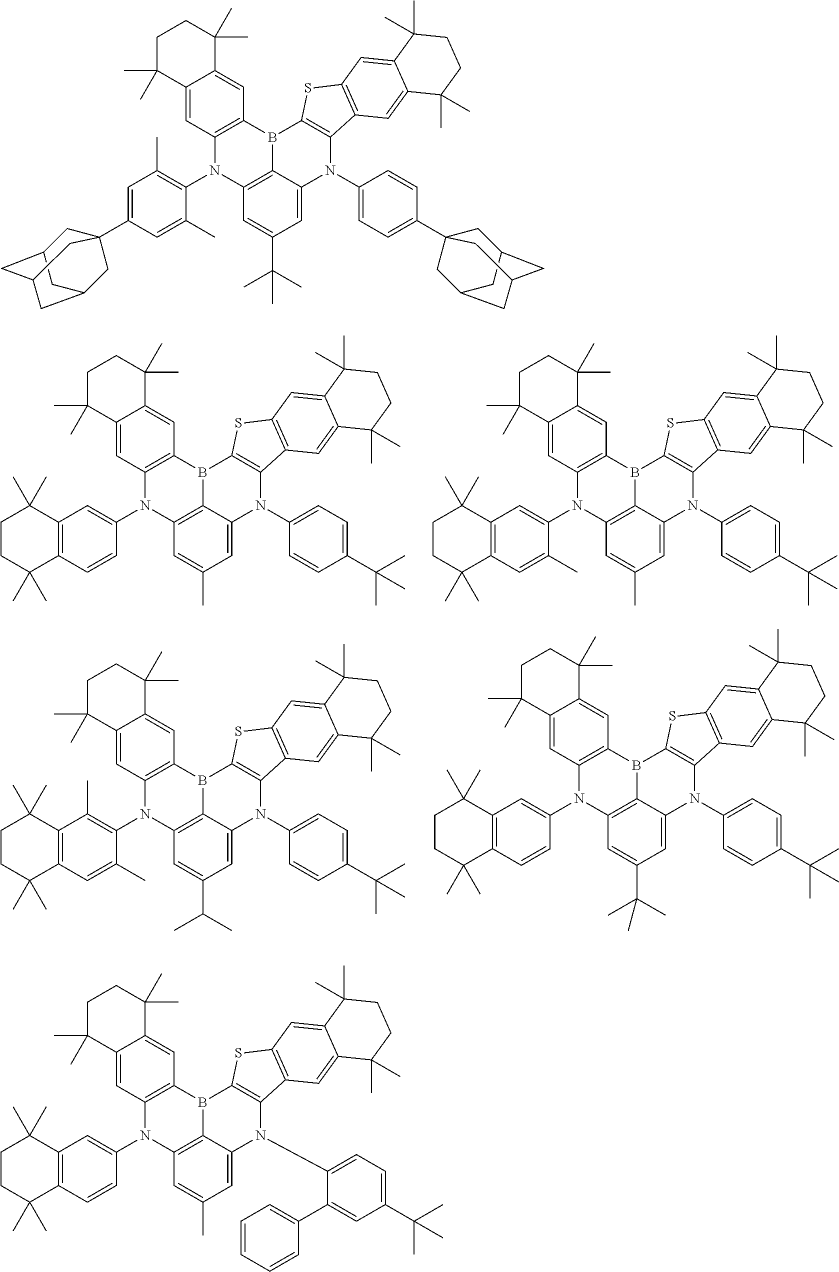 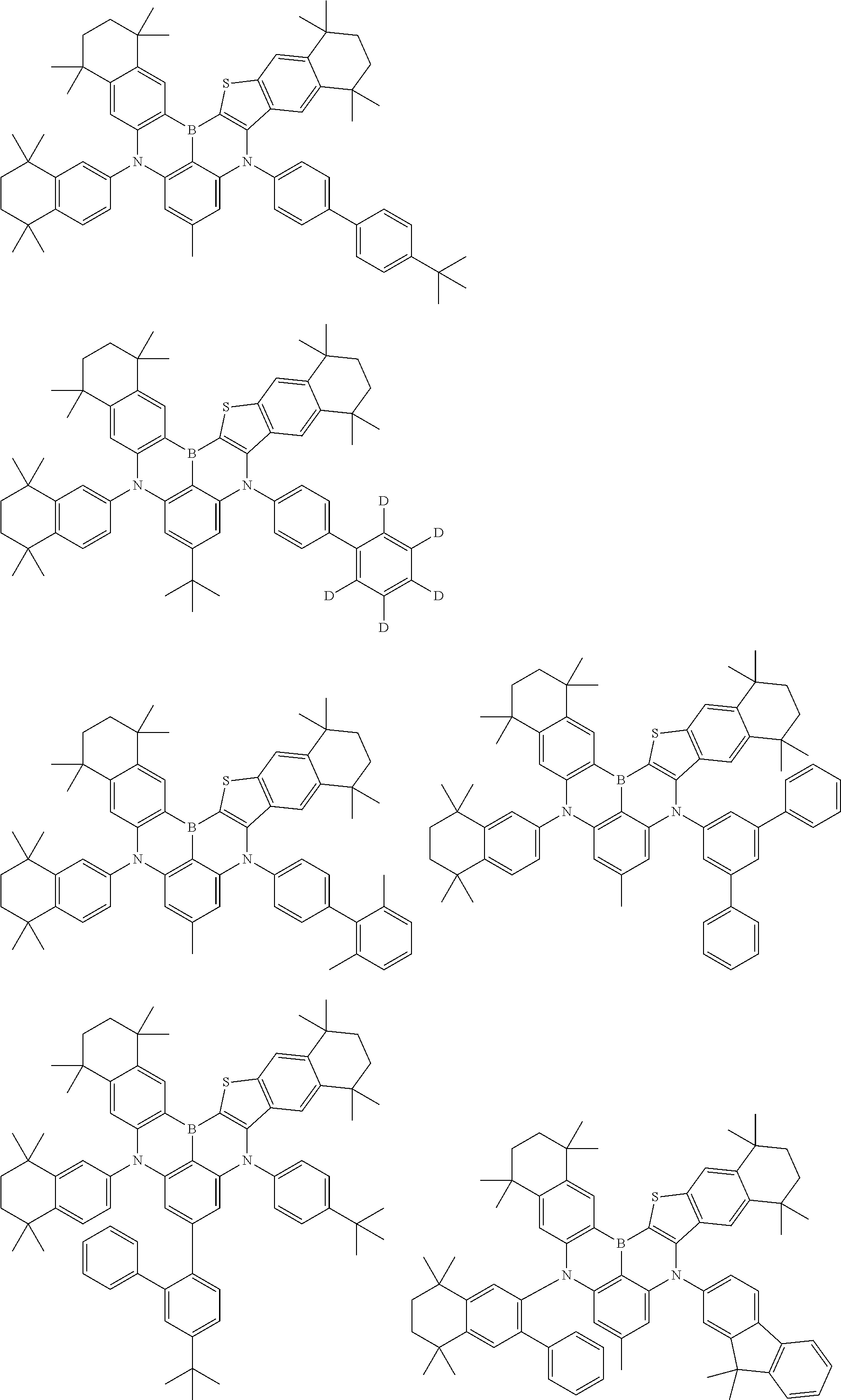 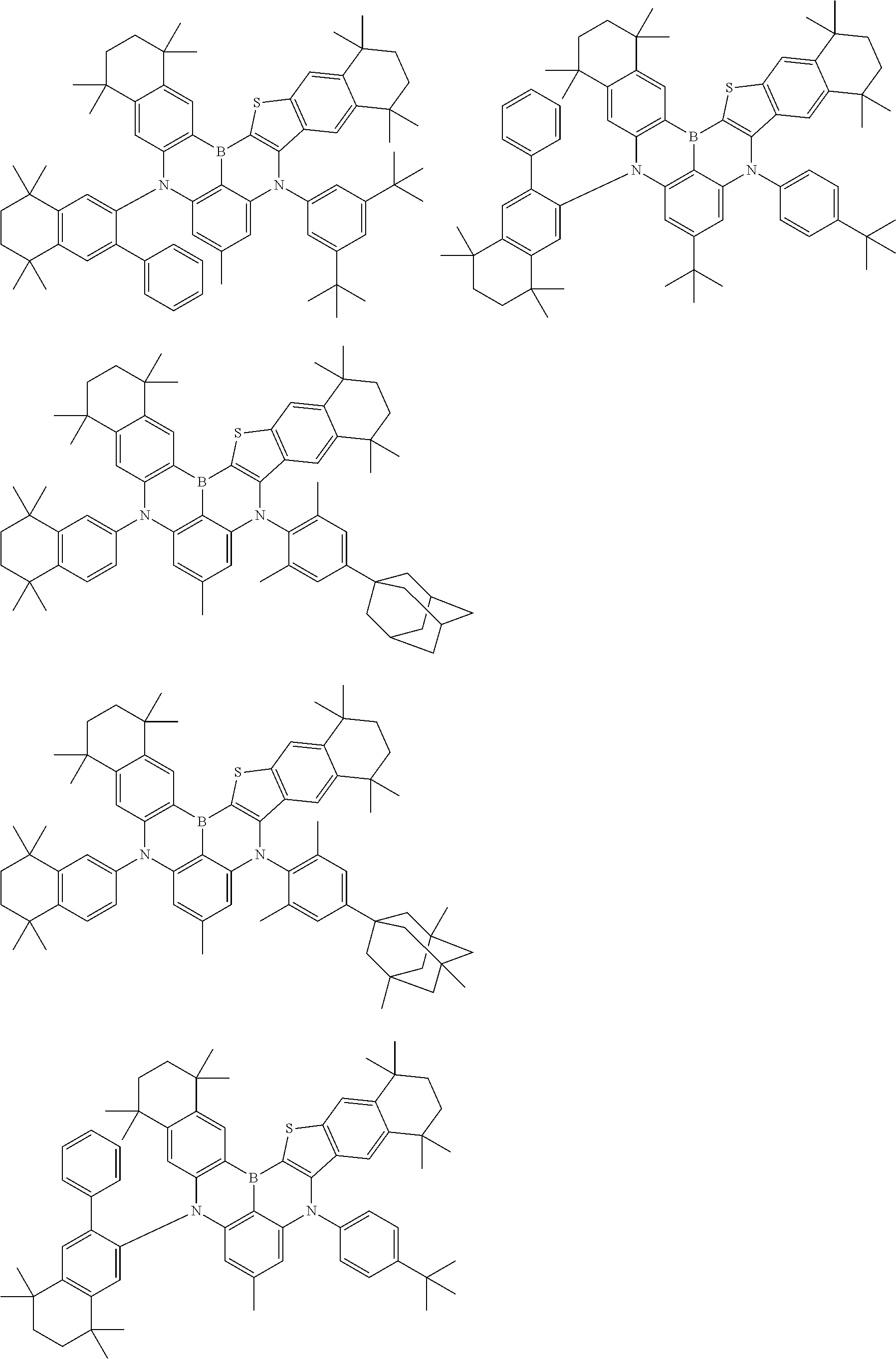 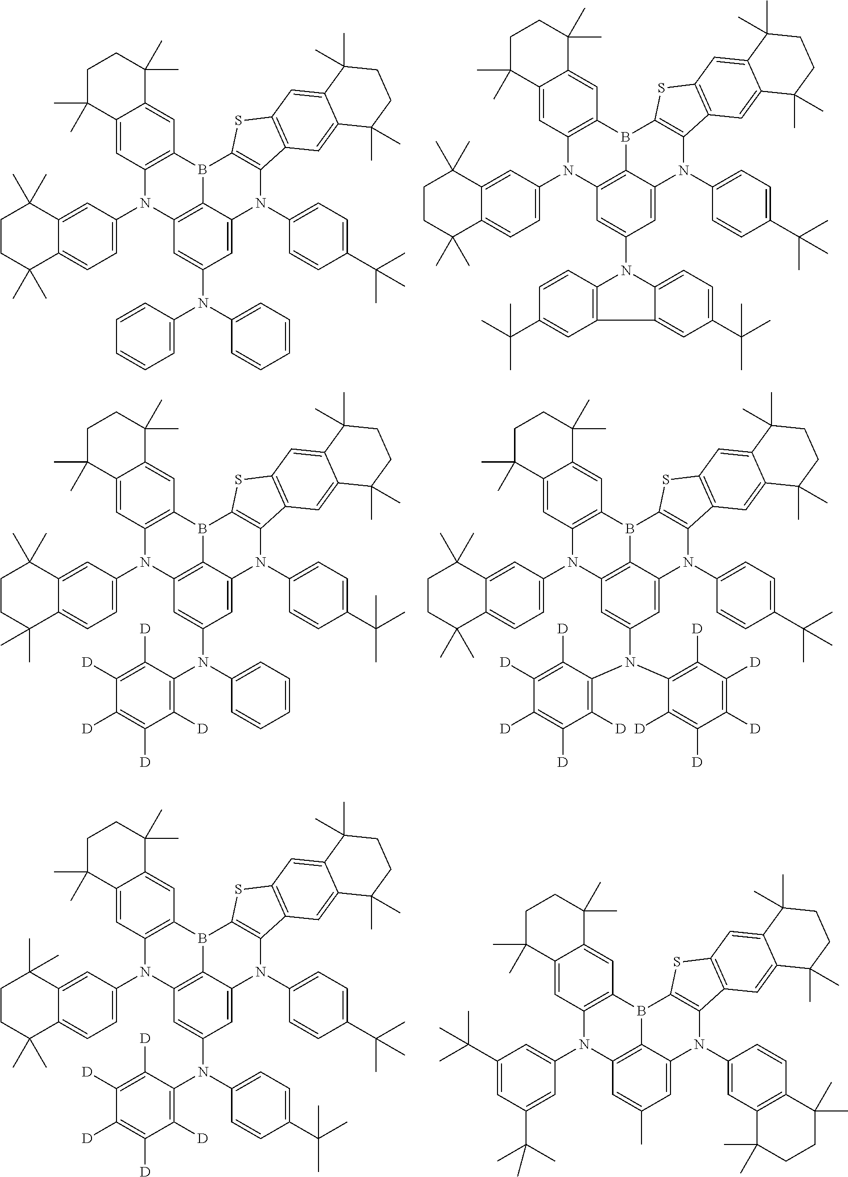 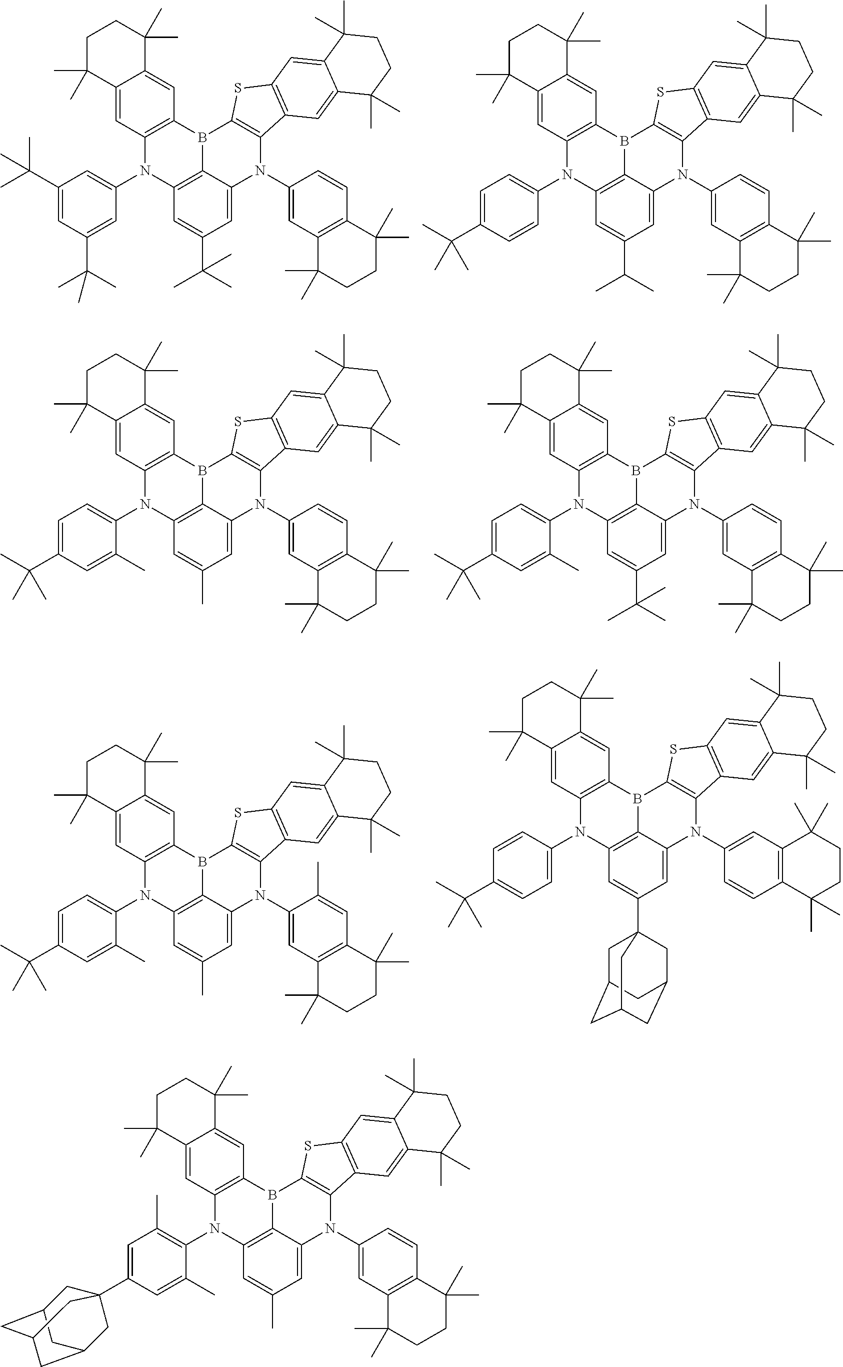 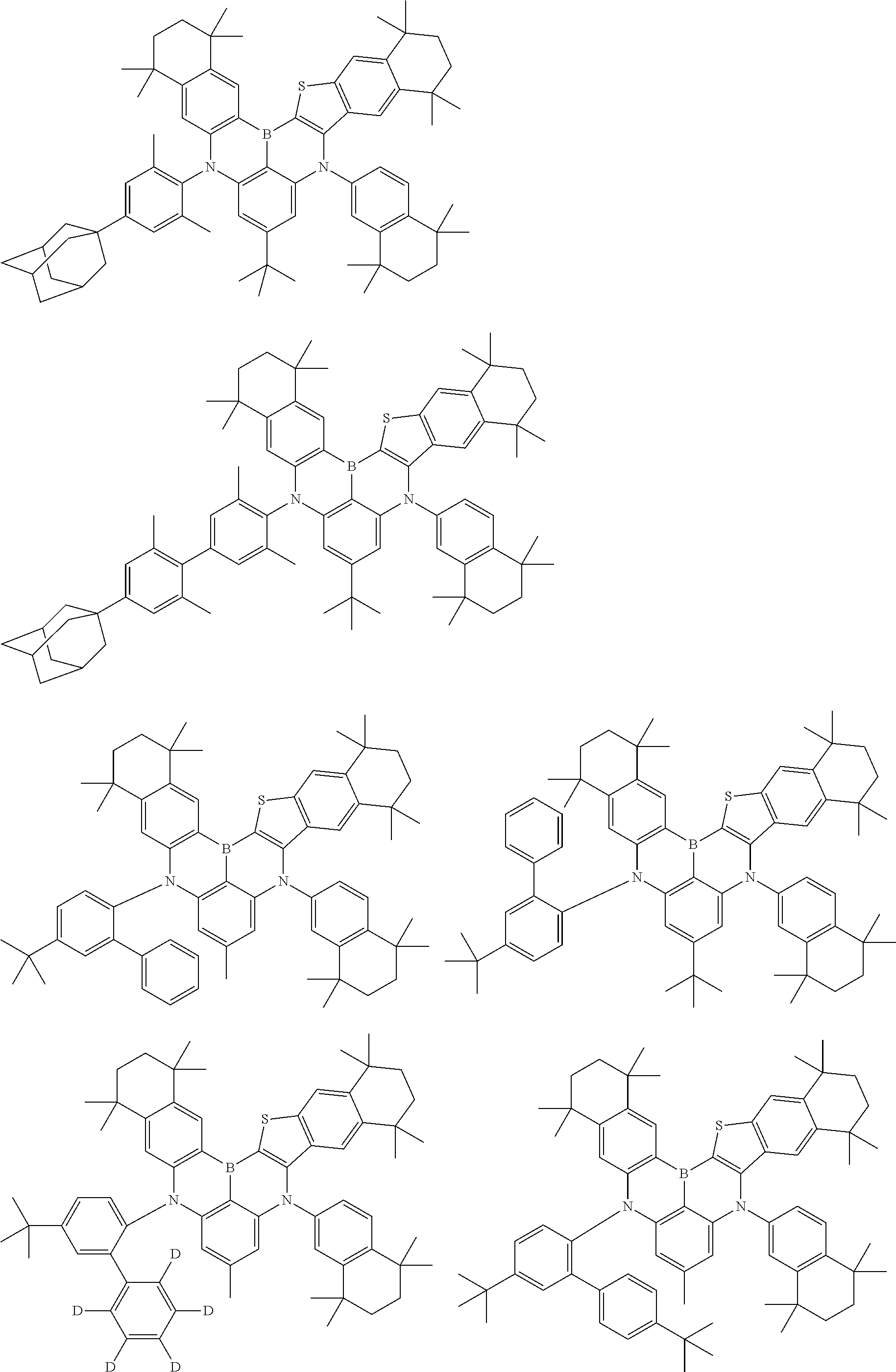 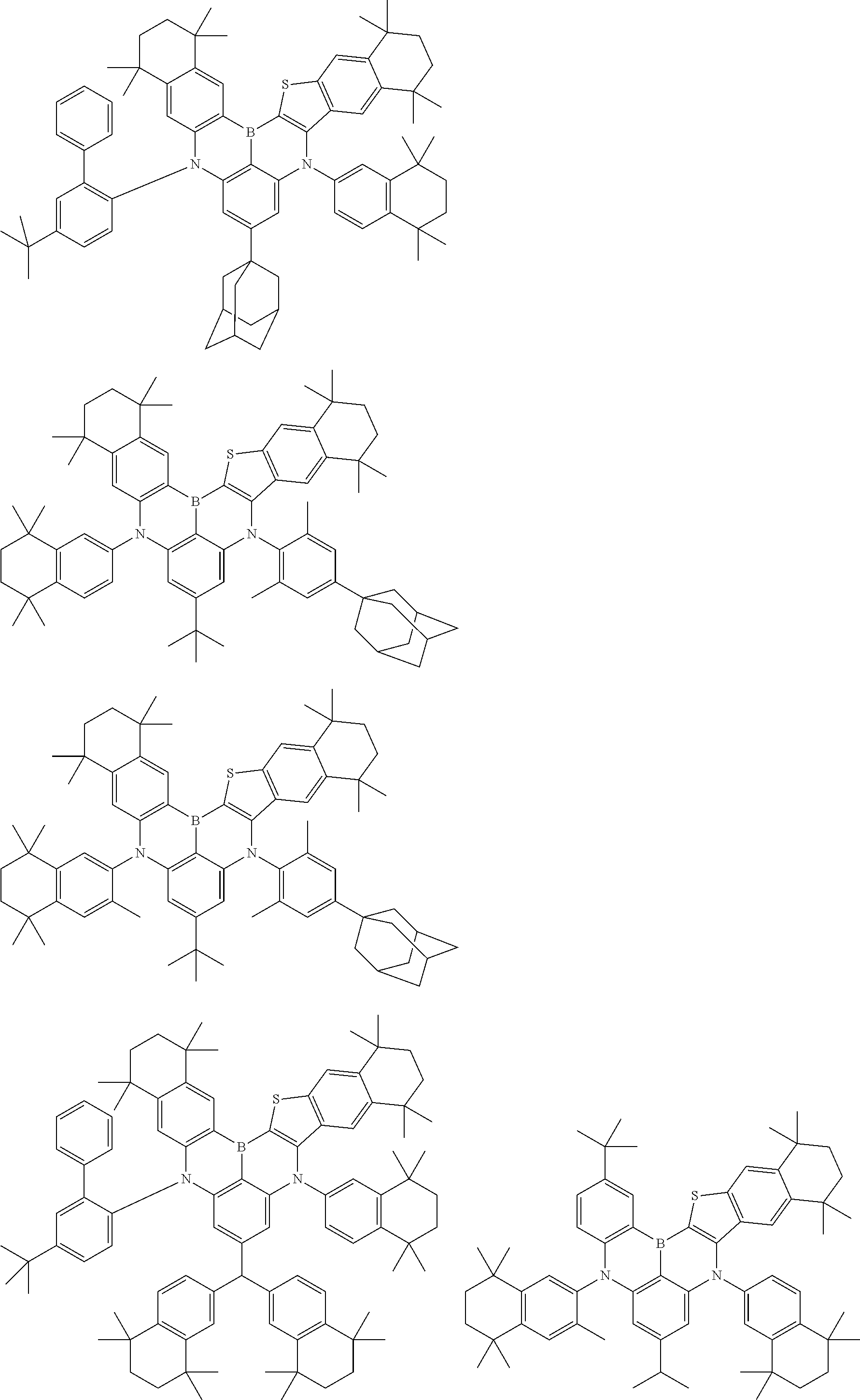 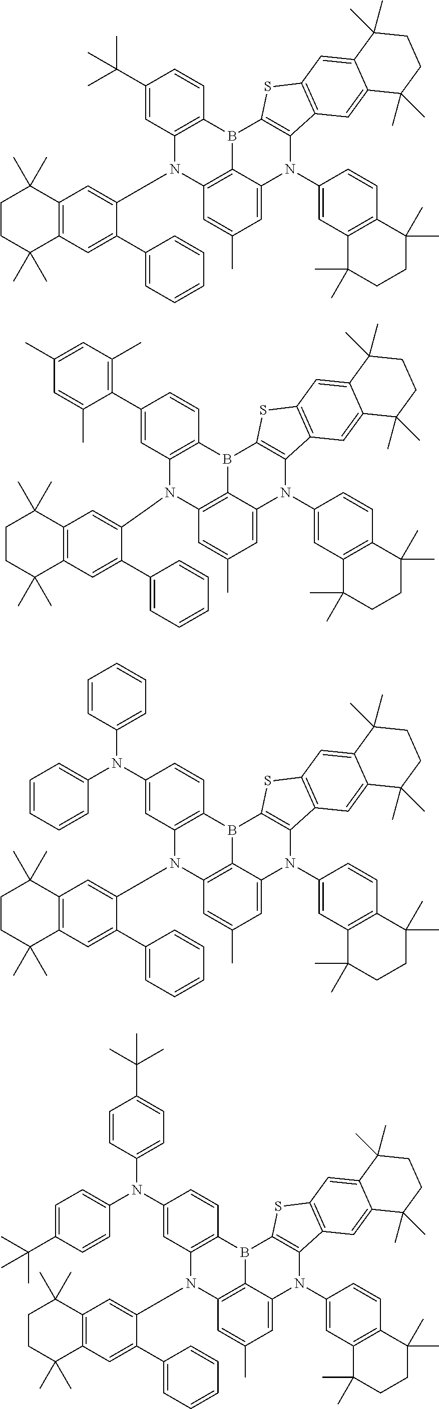 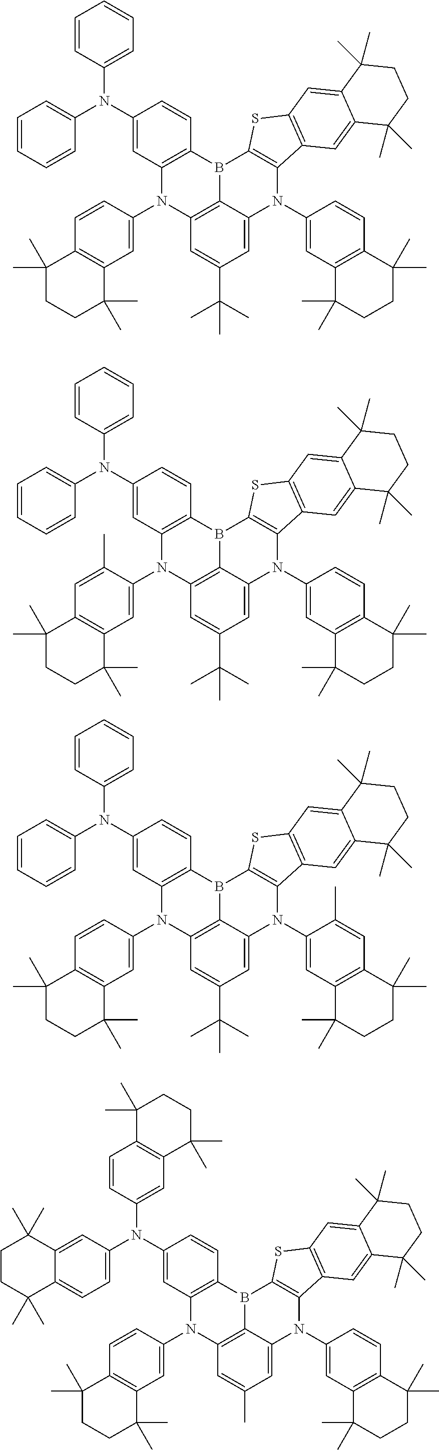 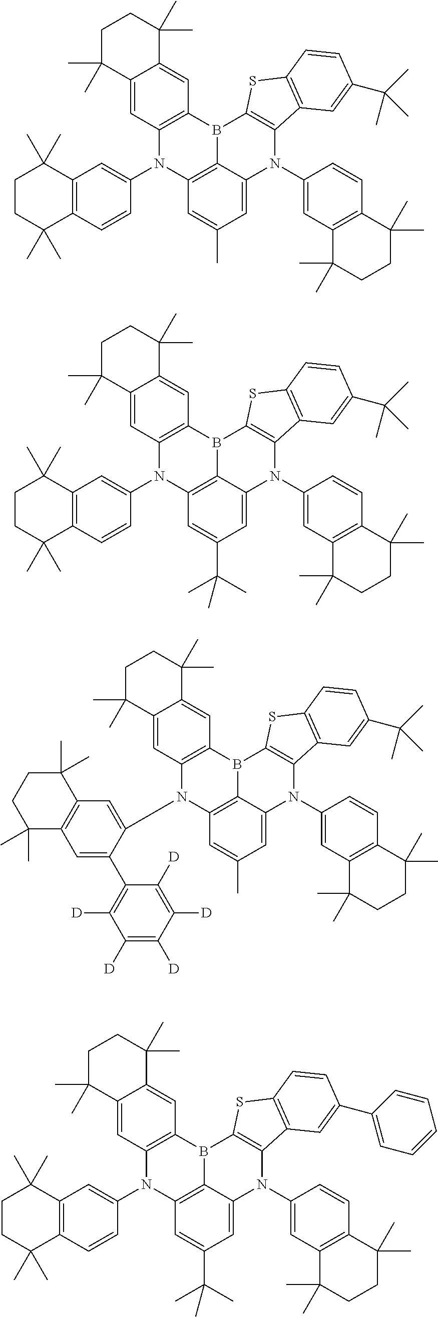 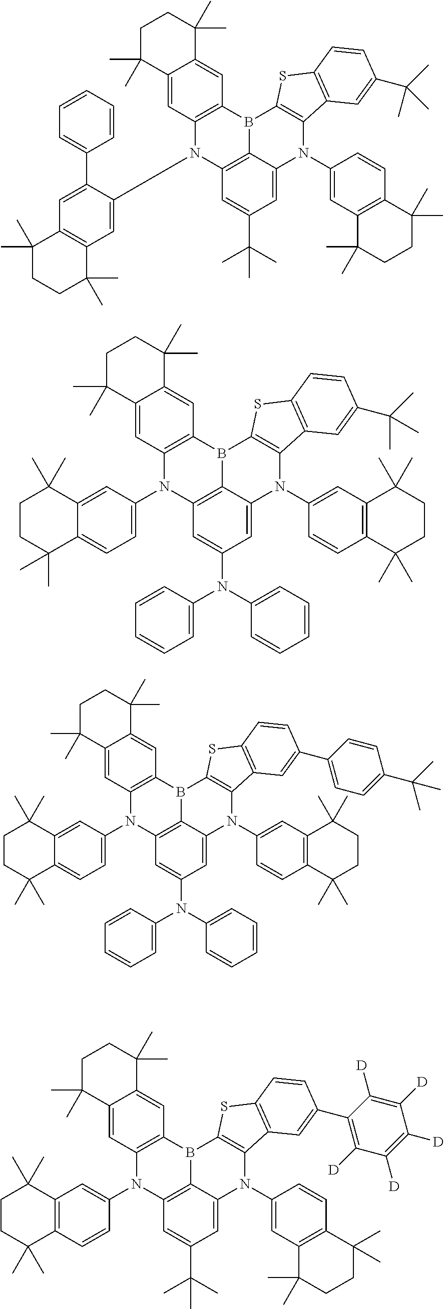 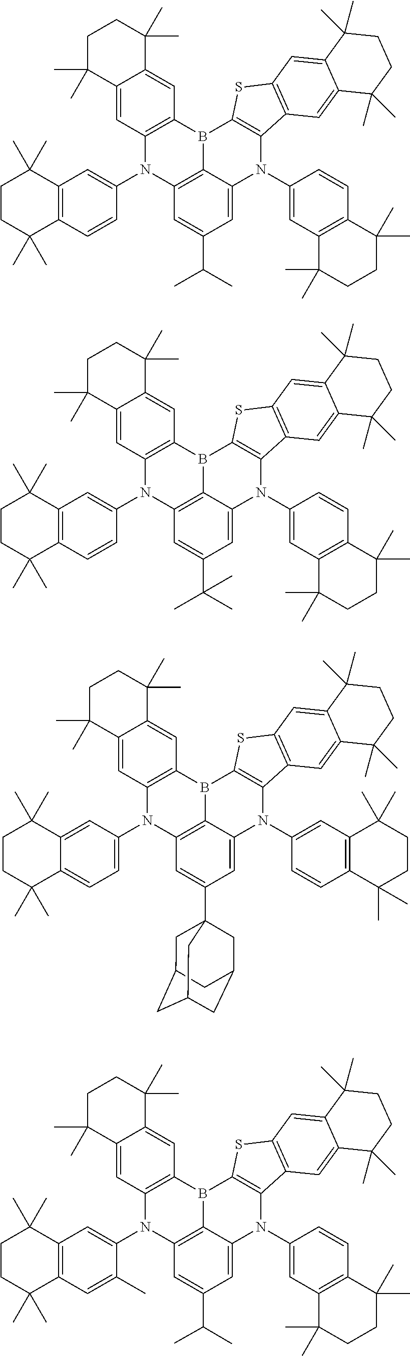 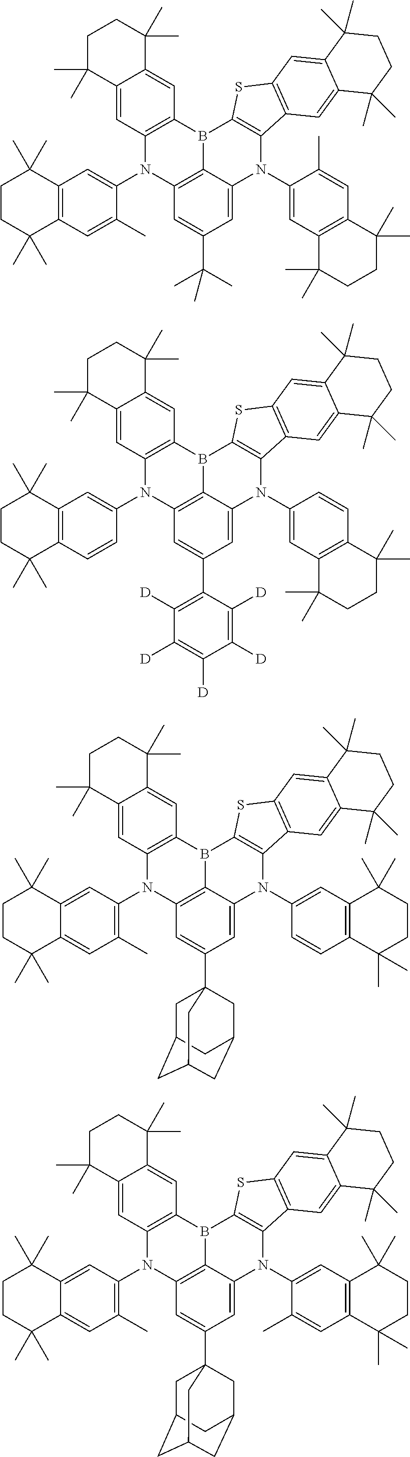 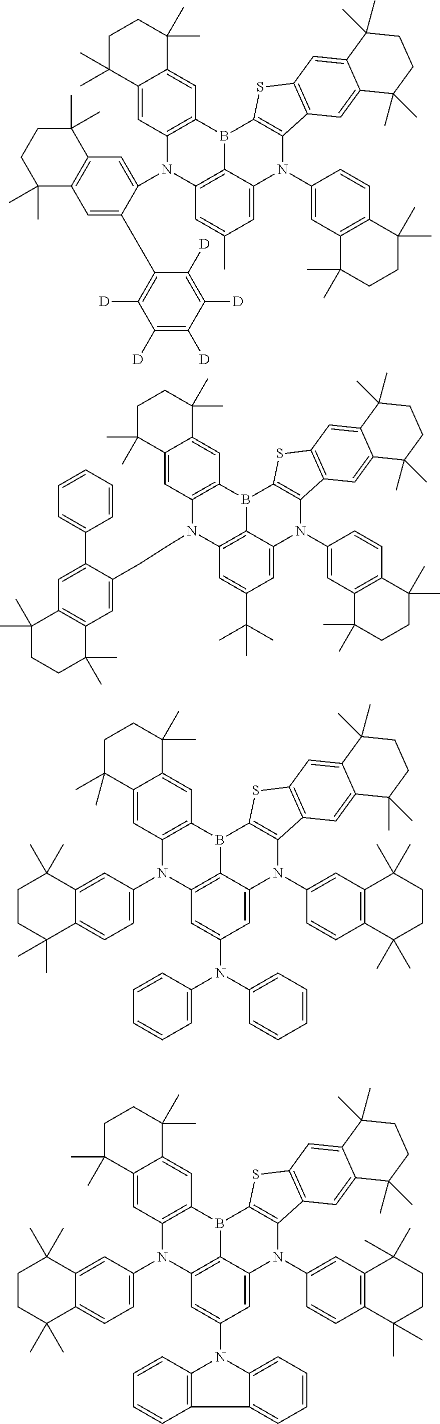 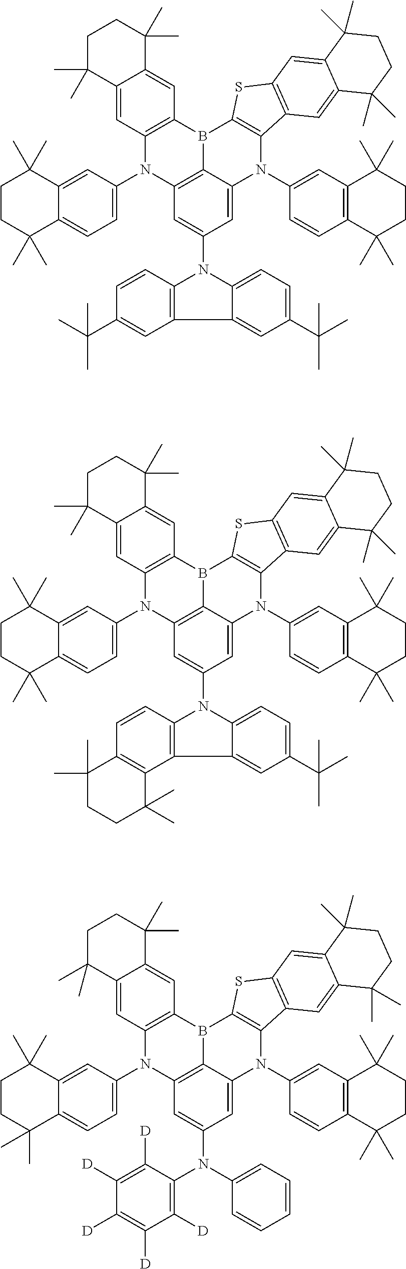 [chemical structure]
